(19) United States
(12) Patent Application Publication
(10) Pub. No.: US 2024/0260298 A1
(43) Pub. Date: Aug. 1, 2024

(54) ORGANIC LIGHT EMITTING DIODE

(71) Applicant: LG Display Co., Ltd., Seoul (KR)

(72) Inventors: Sun-Hee LEE, Paju-si (KR); Hong-Seok CHOI, Paju-si (KR); Sung-Min JO, Paju-si (KR)

(73) Assignee: LG Display Co., Ltd., Seoul (KR)

(21) Appl. No.: 18/235,577

(22) Filed: Aug. 18, 2023

(30) Foreign Application Priority Data
Dec. 1, 2022 (KR) 10-2022-0165605

(51) Int. Cl. H10K 50/13; H10K 50/805; H10K 85/60

(52) U.S. Cl. CPC H10K 50/13; H10K 50/805; H10K 85/6574

(57) ABSTRACT

The present disclosure relates to an organic light emitting diode (OLED) where an emissive layer comprises four emitting parts each of which is sequentially disposed between a first electrode and a second electrode; and charge generation layers each of which is disposed between emitting parts, where one emitting part comprises a red emitting material layer and a blue emitting material layer comprising a blue emitter and a host having a high HOMO and/or a LUMO energy levels. The OLED may implement efficient white emission by improving the blue emission intensity and/or blue temperature.

### CROSS-REFERENCE TO RELATED APPLICATION

This application claims the priority of Korean Patent Application No. 10-2022-0165605, filed on Dec. 1, 2022, which is hereby incorporated by reference in its entirety.

### BACKGROUND

### Description of the Background

A flat display device including an organic light emitting diode (OLED) has attracted attention as a display device that may replace a liquid crystal display device (LCD). The OLED may be formed as a thin organic film and the electrode configurations may implement unidirectional or bidirectional images. Also, the OLED may be formed even on a flexible transparent substrate such as a plastic substrate so that a flexible or a foldable display device may be realized with ease using the OLED. In addition, the OLED may be driven at a lower voltage and the OLED has advantageous high color purity compared to the LCD.

Since fluorescent material uses only singlet excitons in the luminous process, the related art fluorescent material shows low luminous efficiency. On the contrary, phosphorescent material may show high luminous efficiency since it uses triplet exciton as well as singlet excitons in the luminous process. However, examples of phosphorescent material include metal complexes, which have a short luminous lifespan for commercial use. In addition, there is need to improve luminous properties of an OLED by controlling property intensity of light emitted from the OLED.

### SUMMARY

The present disclosure relates to an organic light emitting diode, and more particularly to, an organic light emitting diode that can improve luminous property and an organic light emitting device including thereof.

Accordingly, embodiments of the present disclosure are directed to an organic light emitting diode and an organic light emitting device that substantially obviate one or more of the problems due to the limitations and disadvantages of the related art.

An aspect of the present disclosure is to provide an organic light emitting diode that may enhance blue emission intensity to improve emitted color temperature and an organic light emitting device including the organic light emitting diode.

Another aspect of the present disclosure is to provide an organic light emitting diode that may improve color viewing angle, may implement efficient white emission, and an organic light emitting device including the organic light emitting diode.

Additional features and aspects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides an organic light emitting diode includes a first electrode; a second electrode facing the first electrode; and an emissive layer disposed between the first electrode and the second electrode, wherein the emissive layer includes: a first emitting part disposed between the first electrode and the second electrode; a second emitting part disposed between the first emitting part and the second electrode; a third emitting part disposed between the second emitting part and the second electrode; a fourth emitting part disposed between the third emitting part and the second electrode; a first charge generation layer disposed between the first emitting part and the second emitting part; a second charge generation layer disposed between the second emitting part and the third emitting part; and a third charge generation layer disposed between the third emitting part and the fourth emitting part, wherein one of the first emitting part, the second emitting part, the third emitting part, and the fourth emitting part comprises a red-blue emitting material layer comprising: a red emitting material layer disposed between the first electrode and the second electrode; and a blue emitting material layer disposed between the red emitting material layer and the second electrode, and wherein the blue emitting material layer comprises a blue emitter and a first host having the following structure of Chemical Formula 1:

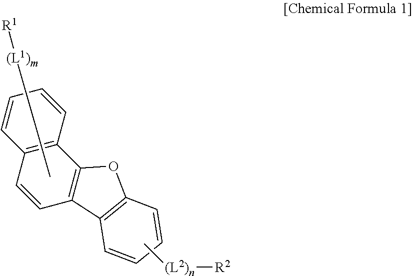

wherein
R¹ and R² are independently selected from a group consisting of an unsubstituted C₆-C₃₀ aryl group, a substituted C₆-C₃₀ aryl group, an unsubstituted C₃-C₃₀ hetero aryl group, a substituted C₃-C₃₀ hetero aryl group, an unsubstituted C₆-C₃₀ aryl amino group, a substituted C₆-C₃₀ aryl amino group, an unsubstituted C₆-C₃₀ aryl group, a substituted C₆-C₃₀ aryl group, an unsubstituted C₃-C₃₀ hetero aryl amino group, and a substituted C₃-C₃₀ hetero aryl amino group, where one of R¹ and R² is the unsubstituted C₆-C₃₀ aryl group, a substituted C₆-C₃₀ aryl group, the unsubstituted C₃-C₃₀ hetero aryl group, or the substituted C₃-C₃₀ hetero aryl group and another of R¹ and R² is the unsubstituted C₆-C₃₀ aryl amino group, the substituted C₆-C₃₀ aryl amino group, the unsubstituted C₃-C₃₀ hetero aryl amino group, or the substituted C₃-C₃₀ hetero aryl amino group;
L¹ and L² are independently selected from a group consisting of an unsubstituted C₆-C₃₀ arylene group, a substituted C₆-C₃₀ arylene group, an unsubstituted C₃-C₃₀ hetero arylene group, and substituted C₃-C₃₀ hetero arylene group; and
m and n are independently 0 or 1

In some embodiments, the first host may comprise at least one organic compound having the structure of Chemical Formula 2:

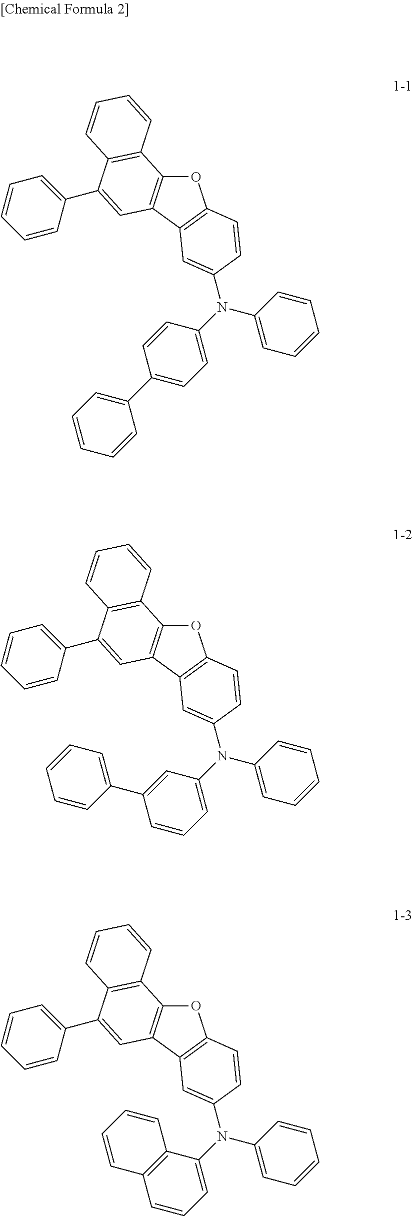 [SMILES: c1ccc(-c2ccc(N(c3ccccc3)c3ccc4oc5c6ccccc6c(-c6ccccc6)cc5c4c3)cc2)cc1 ; c1ccc(-c2cccc(N(c3ccccc3)c3ccc4oc5c6ccccc6c(-c6ccccc6)cc5c4c3)c2)cc1 ; c1ccc(-c2cc3c4cc(N(c5ccccc5)c5cccc6ccccc56)ccc4oc3c3ccccc23)cc1]

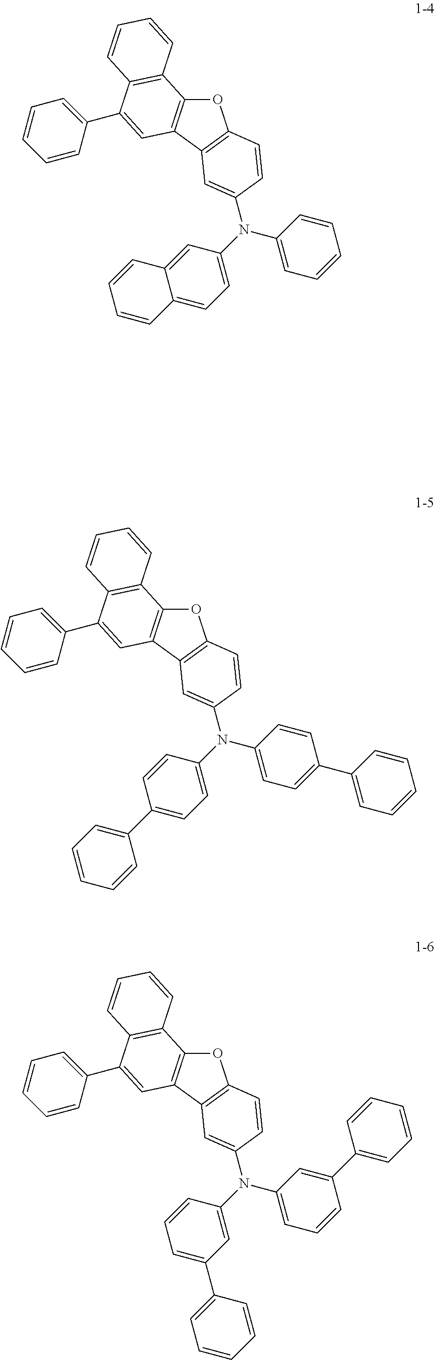 [SMILES: c1ccc(-c2cc3c4cc(N(c5ccccc5)c5ccc6ccccc6c5)ccc4oc3c3ccccc23)cc1 ; c1ccc(-c2ccc(N(c3ccc(-c4ccccc4)cc3)c3ccc4oc5c6ccccc6c(-c6ccccc6)cc5c4c3)cc2)cc1 ; c1ccc(-c2cccc(N(c3cccc(-c4ccccc4)c3)c3ccc4oc5c6ccccc6c(-c6ccccc6)cc5c4c3)c2)cc1]

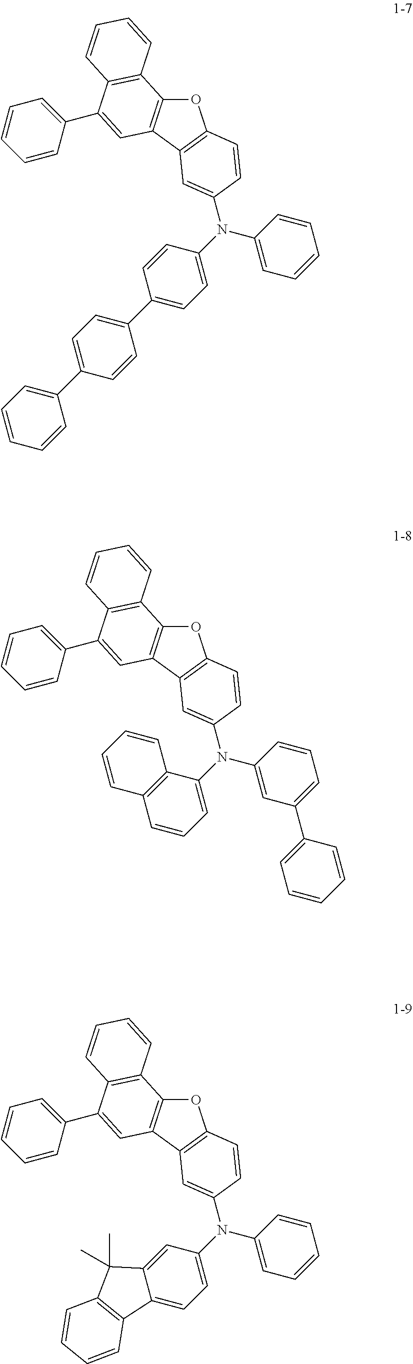 [SMILES: c1ccc(-c2ccc(-c3ccc(N(c4ccccc4)c4ccc5oc6c7ccccc7c(-c7ccccc7)cc6c5c4)cc3)cc2)cc1 ; c1ccc(-c2cccc(N(c3ccc4oc5c6ccccc6c(-c6ccccc6)cc5c4c3)c3cccc4ccccc34)c2)cc1 ; CC1(C)c2ccccc2-c2ccc(N(c3ccccc3)c3ccc4oc5c6ccccc6c(-c6ccccc6)cc5c4c3)cc21]

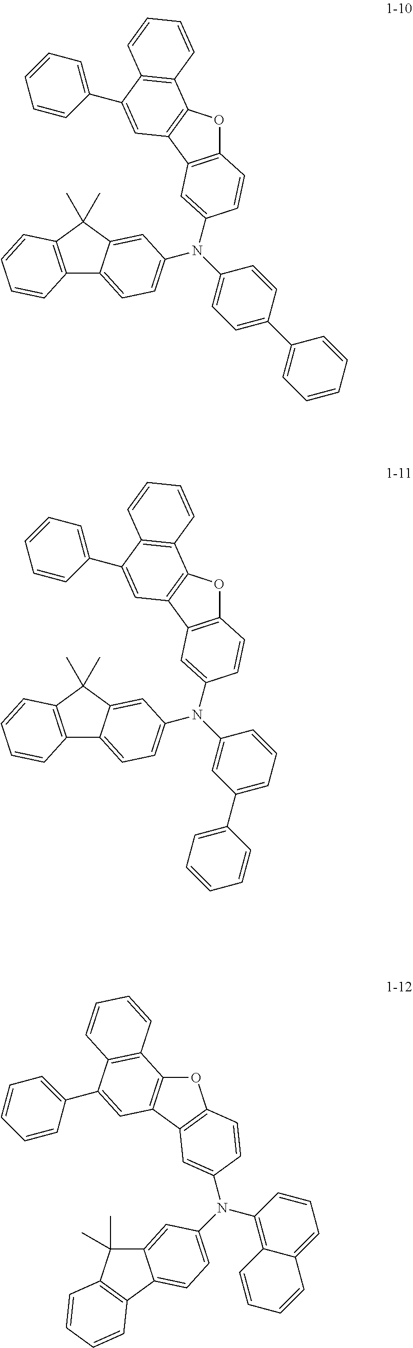 [SMILES: CC1(C)c2ccccc2-c2ccc(N(c3ccc(-c4ccccc4)cc3)c3ccc4oc5c6ccccc6c(-c6ccccc6)cc5c4c3)cc21 ; CC1(C)c2ccccc2-c2ccc(N(c3cccc(-c4ccccc4)c3)c3ccc4oc5c6ccccc6c(-c6ccccc6)cc5c4c3)cc21 ; CC1(C)c2ccccc2-c2ccc(N(c3ccc4oc5c6ccccc6c(-c6ccccc6)cc5c4c3)c3cccc4ccccc34)cc21]

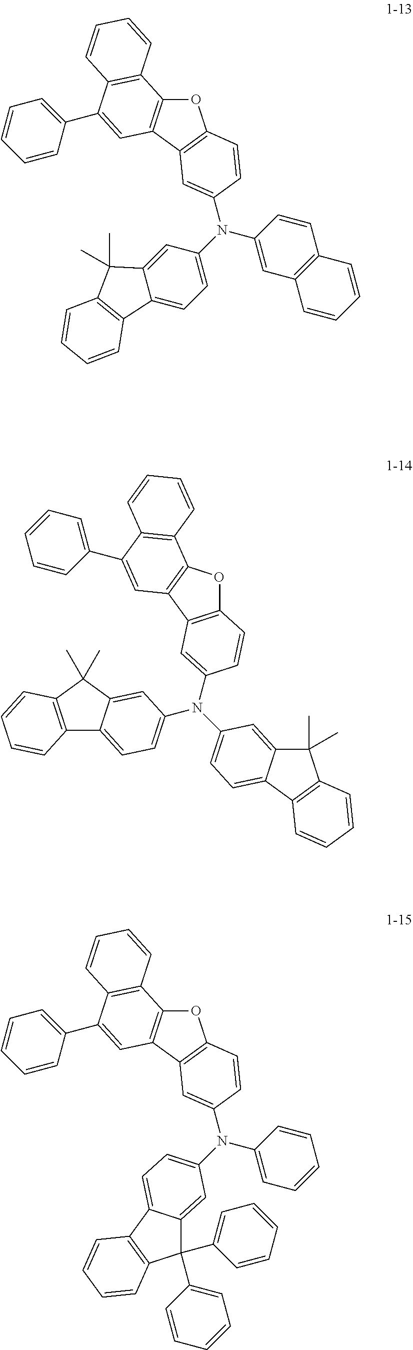 [SMILES: CC1(C)c2ccccc2-c2ccc(N(c3ccc4ccccc4c3)c3ccc4oc5c6ccccc6c(-c6ccccc6)cc5c4c3)cc21 ; CC1(C)c2ccccc2-c2ccc(N(c3ccc4c(c3)C(C)(C)c3ccccc3-4)c3ccc4oc5c6ccccc6c(-c6ccccc6)cc5c4c3)cc21 ; c1ccc(-c2cc3c4cc(N(c5ccccc5)c5ccc6c(c5)C(c5ccccc5)(c5ccccc5)c5ccccc5-6)ccc4oc3c3ccccc23)cc1]

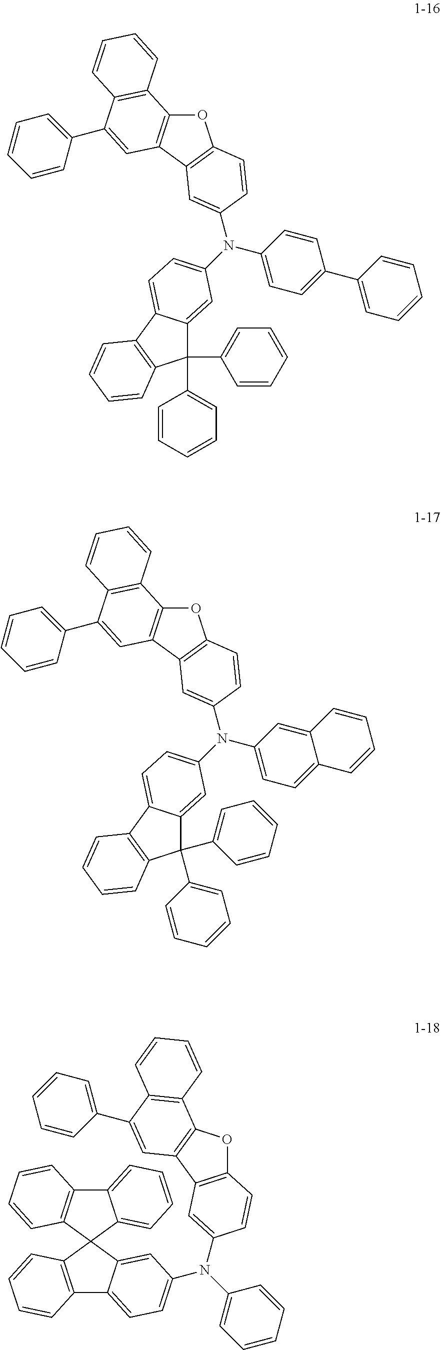 [SMILES: c1ccc(-c2ccc(N(c3ccc4c(c3)C(c3ccccc3)(c3ccccc3)c3ccccc3-4)c3ccc4oc5c6ccccc6c(-c6ccccc6)cc5c4c3)cc2)cc1 ; c1ccc(-c2cc3c4cc(N(c5ccc6c(c5)C(c5ccccc5)(c5ccccc5)c5ccccc5-6)c5ccc6ccccc6c5)ccc4oc3c3ccccc23)cc1 ; c1ccc(-c2cc3c4cc(N(c5ccccc5)c5ccc6c(c5)C5(c7ccccc7-c7ccccc75)c5ccccc5-6)ccc4oc3c3ccccc23)cc1]

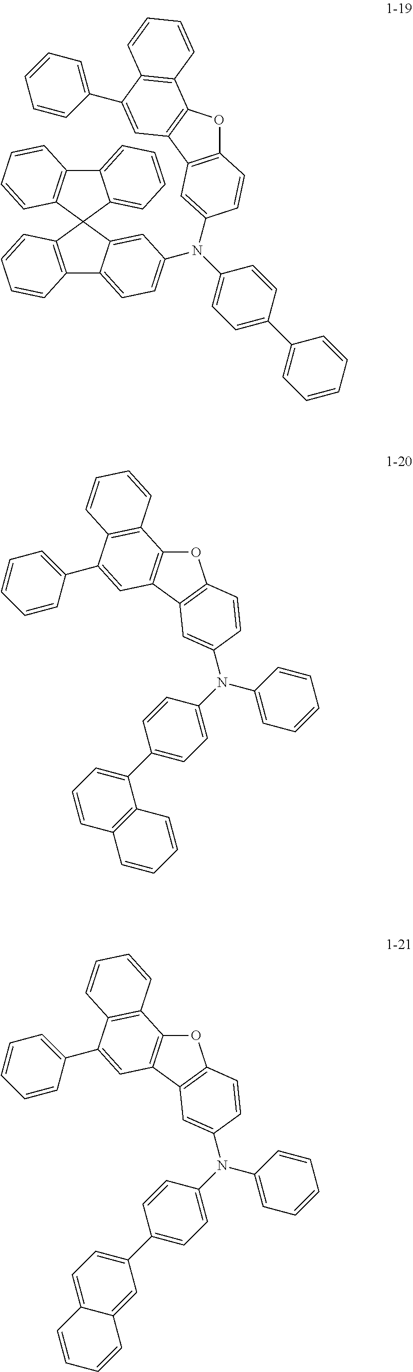 [SMILES: c1ccc(-c2ccc(N(c3ccc4c(c3)C3(c5ccccc5-c5ccccc53)c3ccccc3-4)c3ccc4oc5c6ccccc6c(-c6ccccc6)cc5c4c3)cc2)cc1 ; c1ccc(-c2cc3c4cc(N(c5ccccc5)c5ccc(-c6cccc7ccccc67)cc5)ccc4oc3c3ccccc23)cc1 ; c1ccc(-c2cc3c4cc(N(c5ccccc5)c5ccc(-c6ccc7ccccc7c6)cc5)ccc4oc3c3ccccc23)cc1]

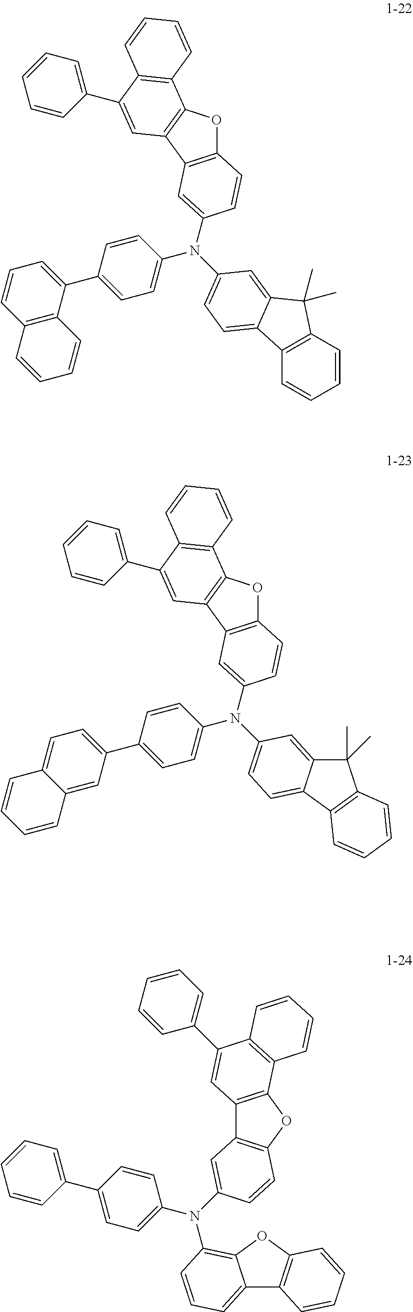 [SMILES: CC1(C)c2ccccc2-c2ccc(N(c3ccc(-c4cccc5ccccc45)cc3)c3ccc4oc5c6ccccc6c(-c6ccccc6)cc5c4c3)cc21 ; CC1(C)c2ccccc2-c2ccc(N(c3ccc(-c4ccc5ccccc5c4)cc3)c3ccc4oc5c6ccccc6c(-c6ccccc6)cc5c4c3)cc21 ; c1ccc(-c2ccc(N(c3ccc4oc5c6ccccc6c(-c6ccccc6)cc5c4c3)c3cccc4c3oc3ccccc34)cc2)cc1]

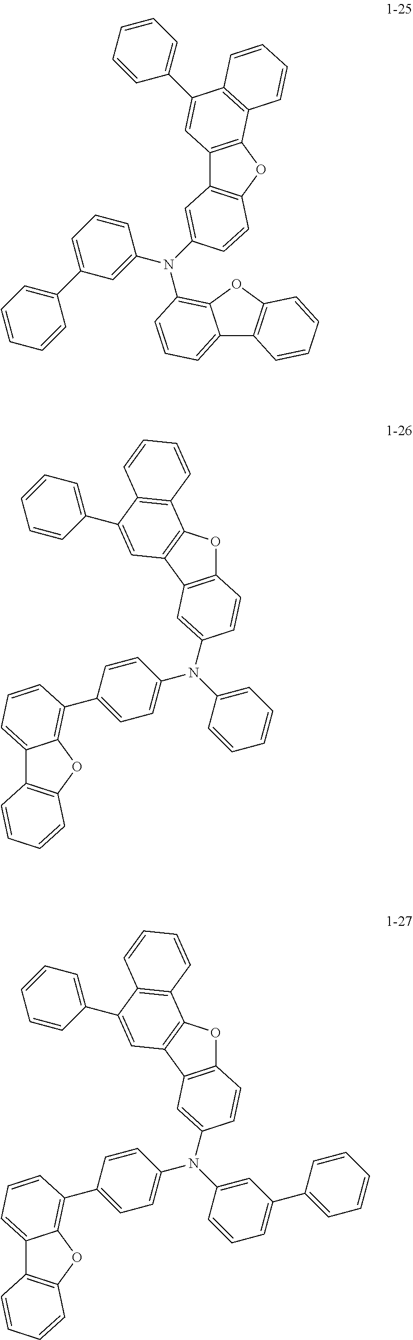 [SMILES: c1ccc(-c2cccc(N(c3ccc4oc5c6ccccc6c(-c6ccccc6)cc5c4c3)c3cccc4c3oc3ccccc34)c2)cc1 ; c1ccc(-c2cc3c4cc(N(c5ccccc5)c5ccc(-c6cccc7c6oc6ccccc67)cc5)ccc4oc3c3ccccc23)cc1 ; c1ccc(-c2cccc(N(c3ccc(-c4cccc5c4oc4ccccc45)cc3)c3ccc4oc5c6ccccc6c(-c6ccccc6)cc5c4c3)c2)cc1]

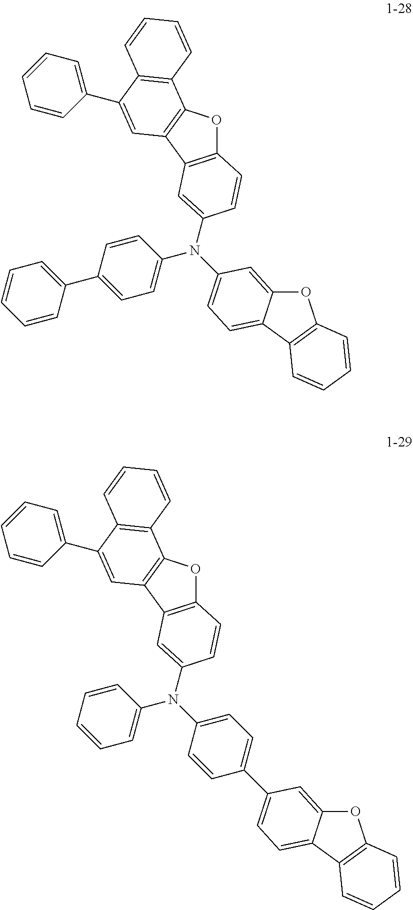 [SMILES: c1ccc(-c2ccc(N(c3ccc4c(c3)oc3ccccc34)c3ccc4oc5c6ccccc6c(-c6ccccc6)cc5c4c3)cc2)cc1 ; c1ccc(-c2cc3c4cc(N(c5ccccc5)c5ccc(-c6ccc7c(c6)oc6ccccc67)cc5)ccc4oc3c3ccccc23)cc1]

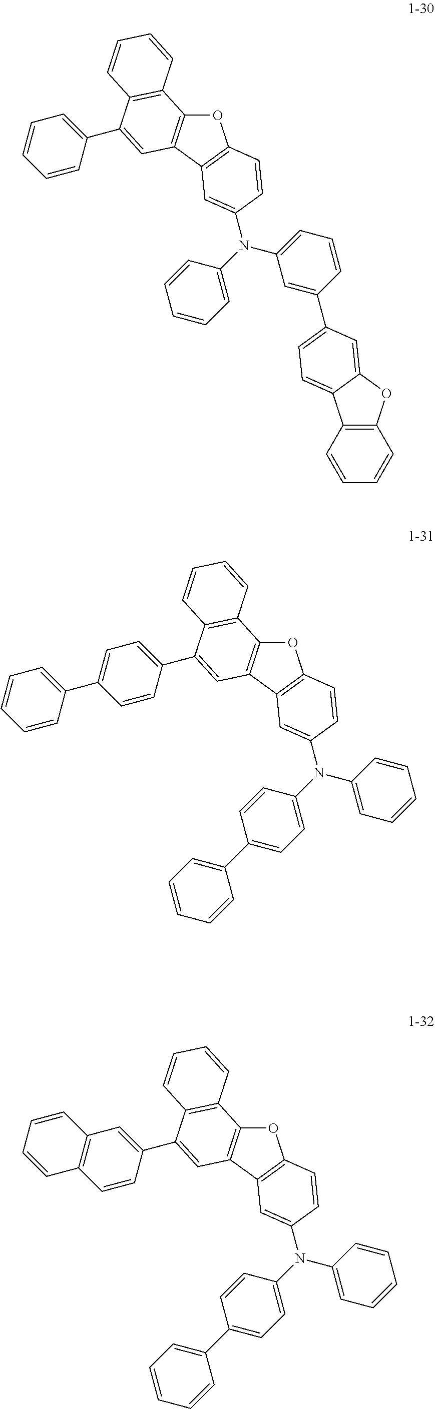 [SMILES: c1ccc(-c2cc3c4cc(N(c5ccccc5)c5cccc(-c6ccc7c(c6)oc6ccccc67)c5)ccc4oc3c3ccccc23)cc1 ; c1ccc(-c2ccc(-c3cc4c5cc(N(c6ccccc6)c6ccc(-c7ccccc7)cc6)ccc5oc4c4ccccc34)cc2)cc1 ; c1ccc(-c2ccc(N(c3ccccc3)c3ccc4oc5c6ccccc6c(-c6ccc7ccccc7c6)cc5c4c3)cc2)cc1]

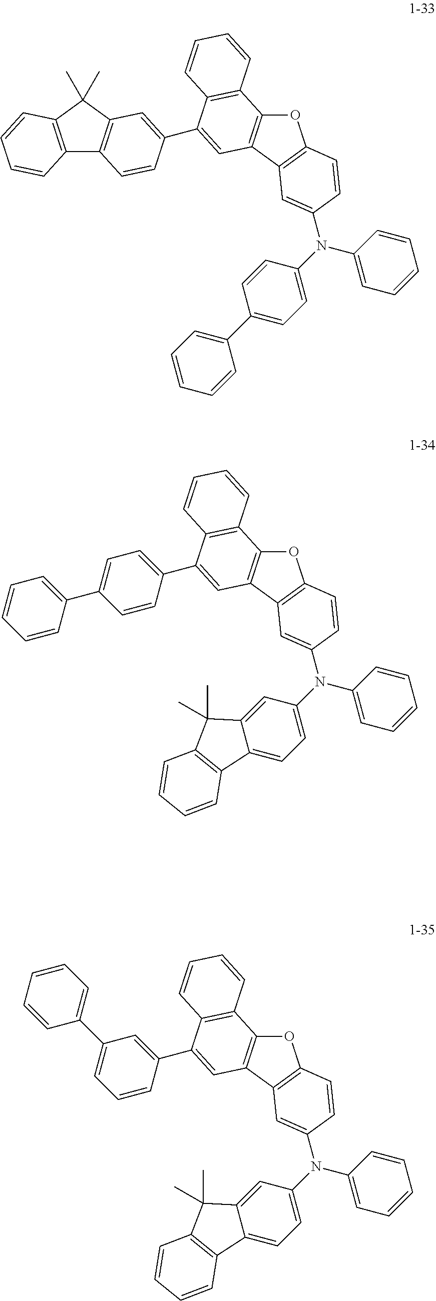 [SMILES: CC1(C)c2ccccc2-c2ccc(-c3cc4c5cc(N(c6ccccc6)c6ccc(-c7ccccc7)cc6)ccc5oc4c4ccccc34)cc21 ; CC1(C)c2ccccc2-c2ccc(N(c3ccccc3)c3ccc4oc5c6ccccc6c(-c6ccc(-c7ccccc7)cc6)cc5c4c3)cc21 ; CC1(C)c2ccccc2-c2ccc(N(c3ccccc3)c3ccc4oc5c6ccccc6c(-c6cccc(-c7ccccc7)c6)cc5c4c3)cc21]

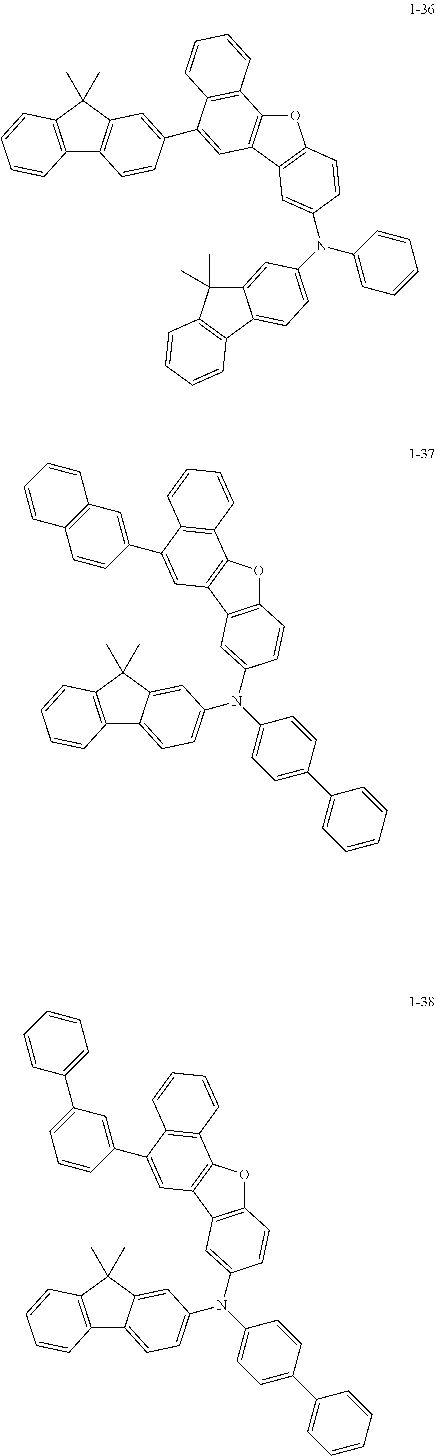 [SMILES: CC1(C)c2ccccc2-c2ccc(-c3cc4c5cc(N(c6ccccc6)c6ccc7c(c6)C(C)(C)c6ccccc6-7)ccc5oc4c4ccccc34)cc21 ; CC1(C)c2ccccc2-c2ccc(N(c3ccc(-c4ccccc4)cc3)c3ccc4oc5c6ccccc6c(-c6ccc7ccccc7c6)cc5c4c3)cc21 ; CC1(C)c2ccccc2-c2ccc(N(c3ccc(-c4ccccc4)cc3)c3ccc4oc5c6ccccc6c(-c6cccc(-c7ccccc7)c6)cc5c4c3)cc21]

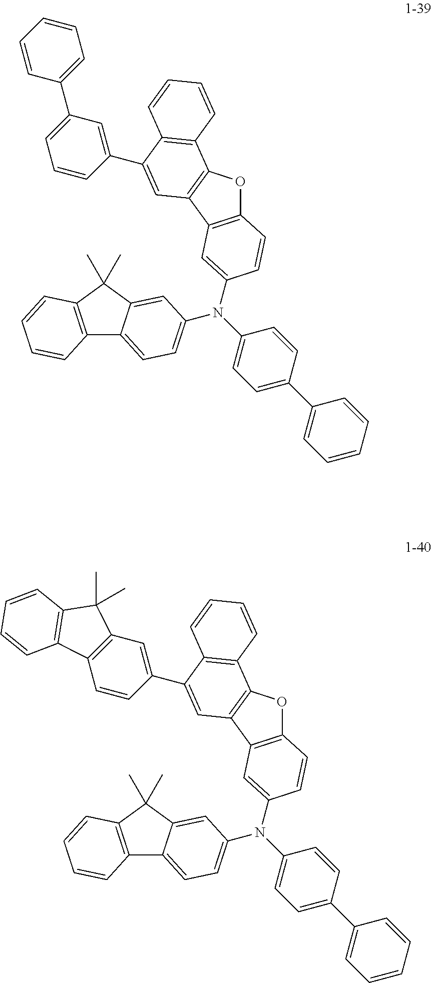 [SMILES: CC1(C)c2ccccc2-c2ccc(N(c3ccc(-c4ccccc4)cc3)c3ccc4oc5c6ccccc6c(-c6cccc(-c7ccccc7)c6)cc5c4c3)cc21 ; CC1(C)c2ccccc2-c2ccc(-c3cc4c5cc(N(c6ccc(-c7ccccc7)cc6)c6ccc7c(c6)C(C)(C)c6ccccc6-7)ccc5oc4c4ccccc34)cc21]

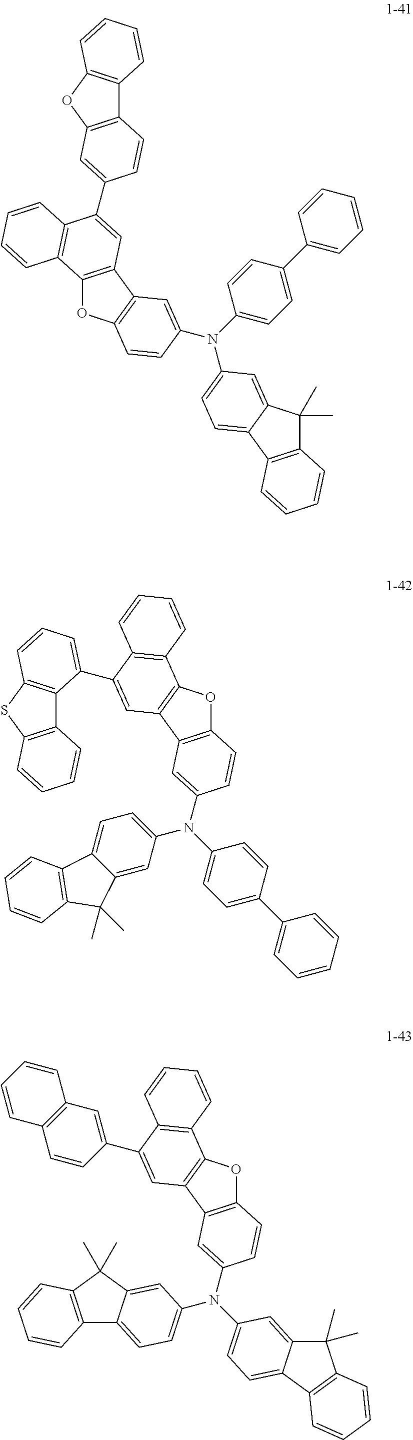 [SMILES: CC1(C)c2ccccc2-c2ccc(N(c3ccc(-c4ccccc4)cc3)c3ccc4oc5c6ccccc6c(-c6ccc7c(c6)oc6ccccc67)cc5c4c3)cc21 ; CC1(C)c2ccccc2-c2ccc(N(c3ccc(-c4ccccc4)cc3)c3ccc4oc5c6ccccc6c(-c6cccc7sc8ccccc8c67)cc5c4c3)cc21 ; CC1(C)c2ccccc2-c2ccc(N(c3ccc4c(c3)C(C)(C)c3ccccc3-4)c3ccc4oc5c6ccccc6c(-c6ccc7ccccc7c6)cc5c4c3)cc21]

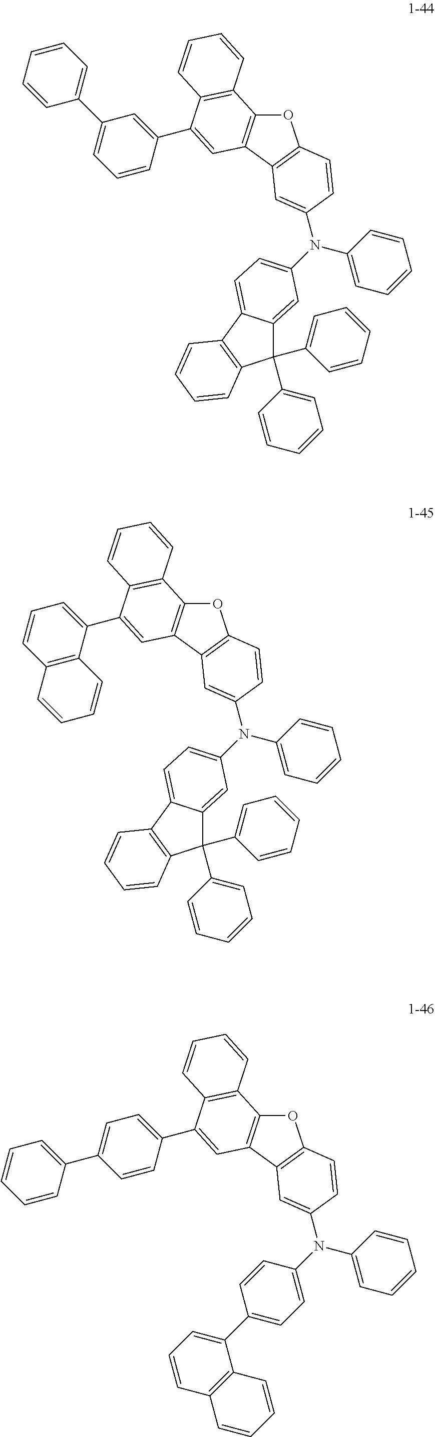 [SMILES: c1ccc(-c2cccc(-c3cc4c5cc(N(c6ccccc6)c6ccc7c(c6)C(c6ccccc6)(c6ccccc6)c6ccccc6-7)ccc5oc4c4ccccc34)c2)cc1 ; c1ccc(N(c2ccc3c(c2)C(c2ccccc2)(c2ccccc2)c2ccccc2-3)c2ccc3oc4c5ccccc5c(-c5cccc6ccccc56)cc4c3c2)cc1 ; c1ccc(-c2ccc(-c3cc4c5cc(N(c6ccccc6)c6ccc(-c7cccc8ccccc78)cc6)ccc5oc4c4ccccc34)cc2)cc1]

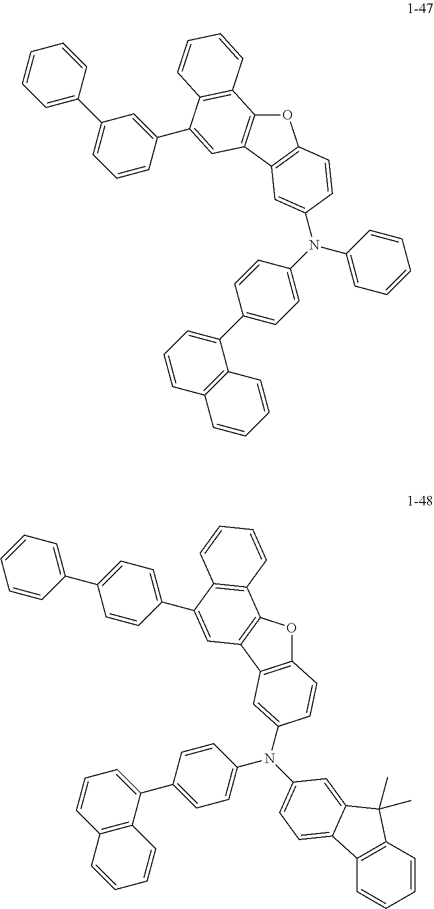 [SMILES: c1ccc(-c2cccc(-c3cc4c5cc(N(c6ccccc6)c6ccc(-c7cccc8ccccc78)cc6)ccc5oc4c4ccccc34)c2)cc1 ; CC1(C)c2ccccc2-c2ccc(N(c3ccc(-c4cccc5ccccc45)cc3)c3ccc4oc5c6ccccc6c(-c6ccc(-c7ccccc7)cc6)cc5c4c3)cc21]

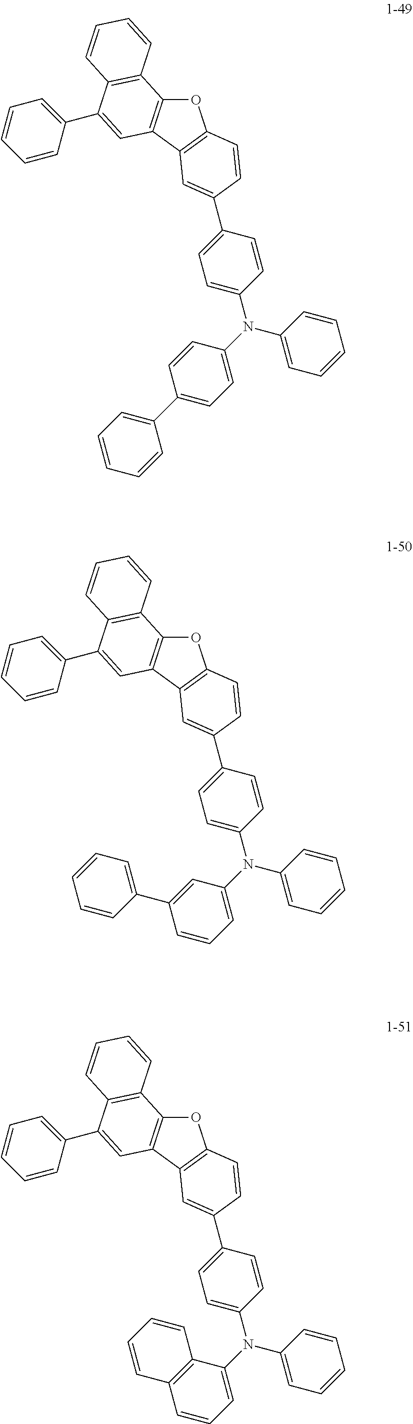 [SMILES: c1ccc(-c2ccc(N(c3ccccc3)c3ccc(-c4ccc5oc6c7ccccc7c(-c7ccccc7)cc6c5c4)cc3)cc2)cc1 ; c1ccc(-c2cccc(N(c3ccccc3)c3ccc(-c4ccc5oc6c7ccccc7c(-c7ccccc7)cc6c5c4)cc3)c2)cc1 ; c1ccc(-c2cc3c4cc(-c5ccc(N(c6ccccc6)c6cccc7ccccc67)cc5)ccc4oc3c3ccccc23)cc1]

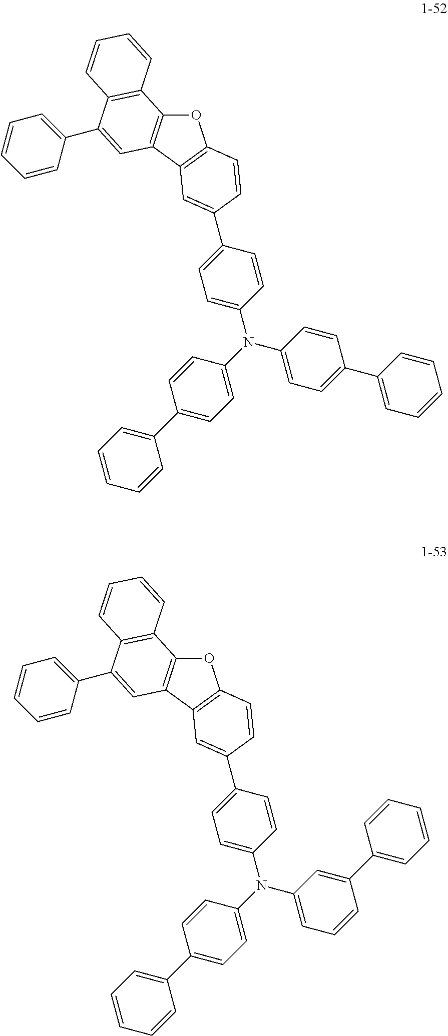 [SMILES: c1ccc(-c2ccc(N(c3ccc(-c4ccccc4)cc3)c3ccc(-c4ccc5oc6c7ccccc7c(-c7ccccc7)cc6c5c4)cc3)cc2)cc1 ; c1ccc(-c2ccc(N(c3ccc(-c4ccc5oc6c7ccccc7c(-c7ccccc7)cc6c5c4)cc3)c3cccc(-c4ccccc4)c3)cc2)cc1]

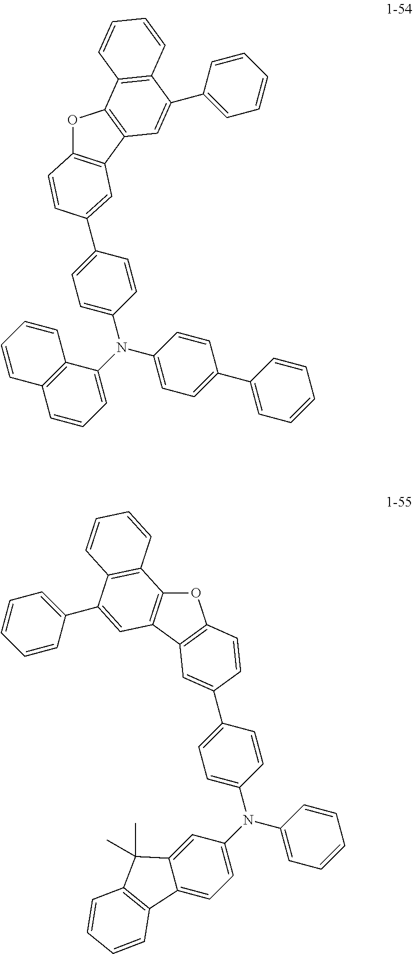 [SMILES: c1ccc(-c2ccc(N(c3ccc(-c4ccc5oc6c7ccccc7c(-c7ccccc7)cc6c5c4)cc3)c3cccc4ccccc34)cc2)cc1 ; CC1(C)c2ccccc2-c2ccc(N(c3ccccc3)c3ccc(-c4ccc5oc6c7ccccc7c(-c7ccccc7)cc6c5c4)cc3)cc21]

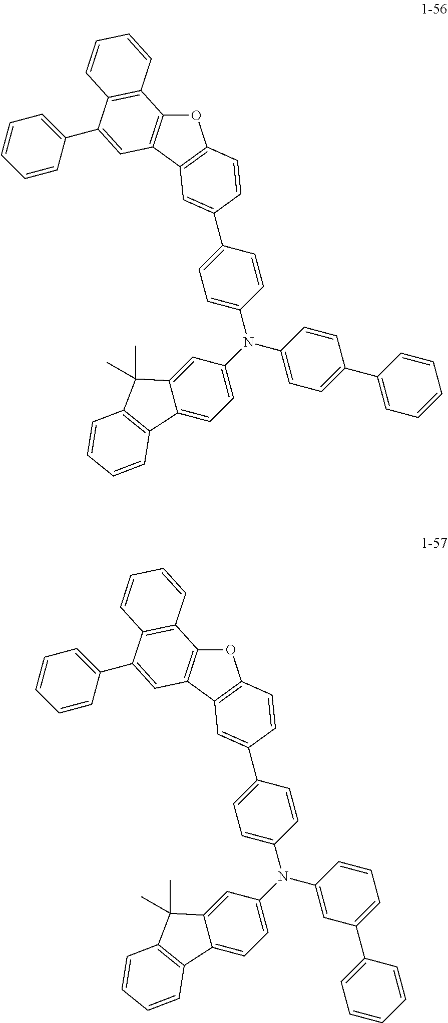 [SMILES: CC1(C)c2ccccc2-c2ccc(N(c3ccc(-c4ccccc4)cc3)c3ccc(-c4ccc5oc6c7ccccc7c(-c7ccccc7)cc6c5c4)cc3)cc21 ; CC1(C)c2ccccc2-c2ccc(N(c3ccc(-c4ccc5oc6c7ccccc7c(-c7ccccc7)cc6c5c4)cc3)c3cccc(-c4ccccc4)c3)cc21]

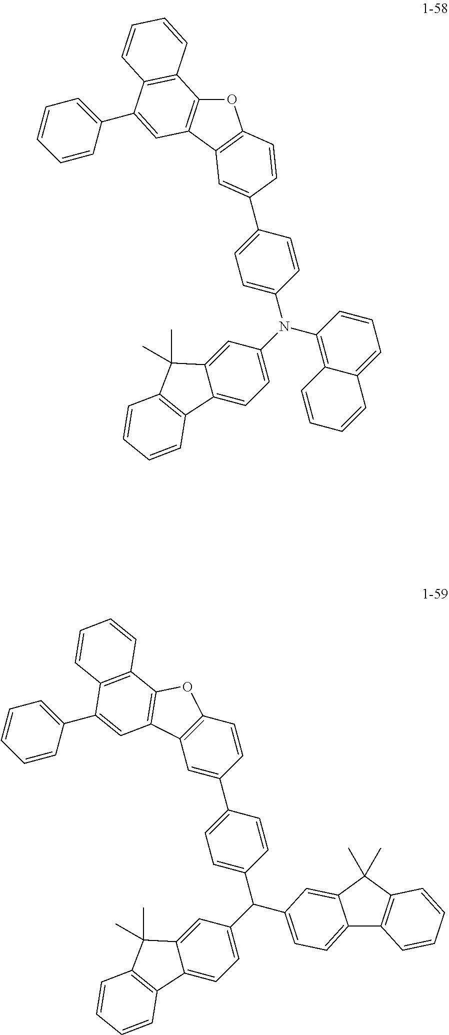 [SMILES: CC1(C)c2ccccc2-c2ccc(N(c3ccc(-c4ccc5oc6c7ccccc7c(-c7ccccc7)cc6c5c4)cc3)c3cccc4ccccc34)cc21 ; CC1(C)c2ccccc2-c2ccc(C(c3ccc(-c4ccc5oc6c7ccccc7c(-c7ccccc7)cc6c5c4)cc3)c3ccc4c(c3)C(C)(C)c3ccccc3-4)cc21]

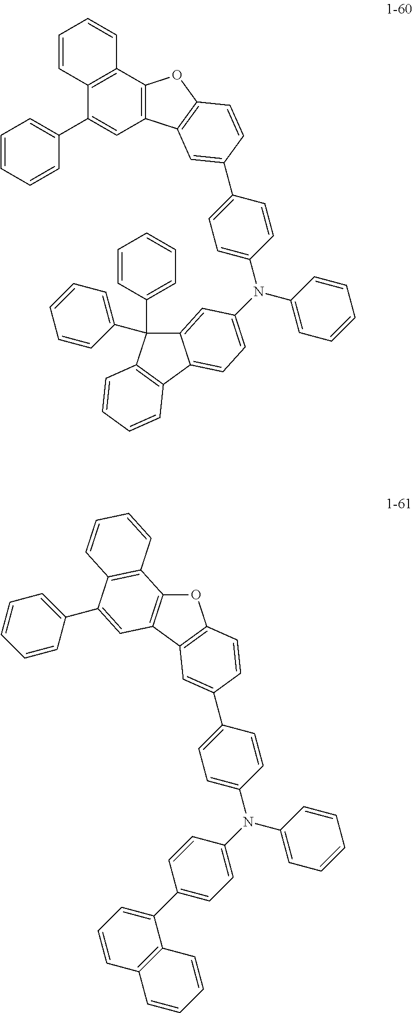 [SMILES: c1ccc(-c2cc3c4cc(-c5ccc(N(c6ccccc6)c6ccc7c(c6)C(c6ccccc6)(c6ccccc6)c6ccccc6-7)cc5)ccc4oc3c3ccccc23)cc1 ; c1ccc(-c2cc3c4cc(-c5ccc(N(c6ccccc6)c6ccc(-c7cccc8ccccc78)cc6)cc5)ccc4oc3c3ccccc23)cc1]

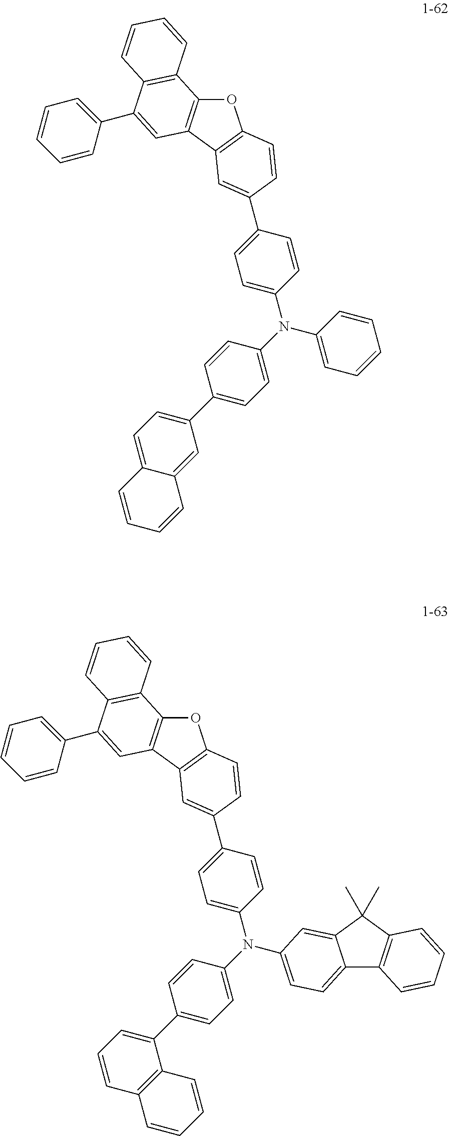 [SMILES: c1ccc(-c2cc3c4cc(-c5ccc(N(c6ccccc6)c6ccc(-c7ccc8ccccc8c7)cc6)cc5)ccc4oc3c3ccccc23)cc1 ; CC1(C)c2ccccc2-c2ccc(N(c3ccc(-c4ccc5oc6c7ccccc7c(-c7ccccc7)cc6c5c4)cc3)c3ccc(-c4cccc5ccccc45)cc3)cc21]

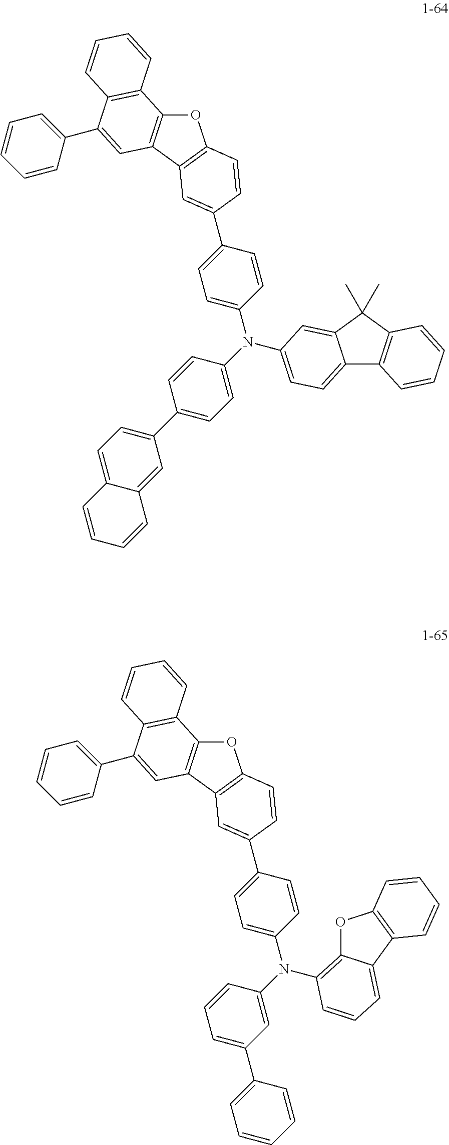 [SMILES: CC1(C)c2ccccc2-c2ccc(N(c3ccc(-c4ccc5ccccc5c4)cc3)c3ccc(-c4ccc5oc6c7ccccc7c(-c7ccccc7)cc6c5c4)cc3)cc21 ; c1ccc(-c2cccc(N(c3ccc(-c4ccc5oc6c7ccccc7c(-c7ccccc7)cc6c5c4)cc3)c3cccc4c3oc3ccccc34)c2)cc1]

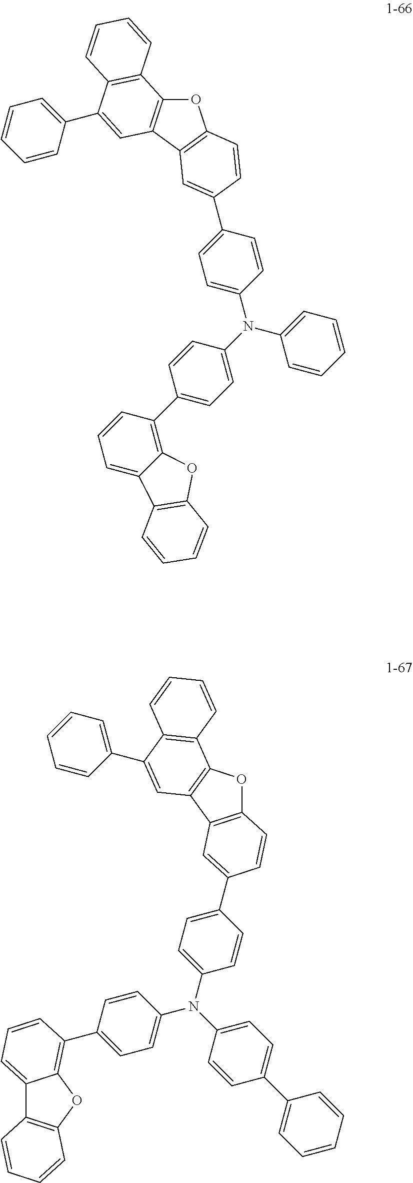 [SMILES: c1ccc(-c2cc3c4cc(-c5ccc(N(c6ccccc6)c6ccc(-c7cccc8c7oc7ccccc78)cc6)cc5)ccc4oc3c3ccccc23)cc1 ; c1ccc(-c2ccc(N(c3ccc(-c4ccc5oc6c7ccccc7c(-c7ccccc7)cc6c5c4)cc3)c3ccc(-c4cccc5c4oc4ccccc45)cc3)cc2)cc1]

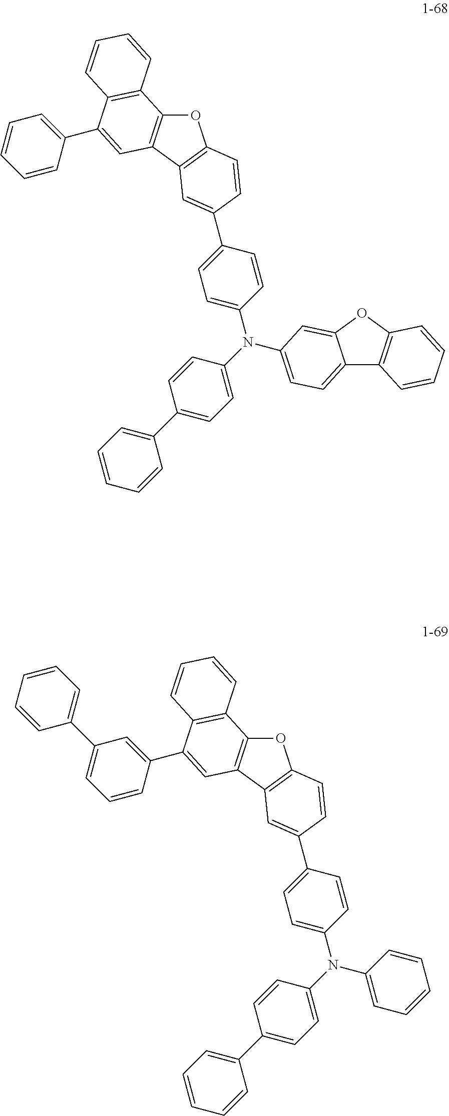 [SMILES: c1ccc(-c2ccc(N(c3ccc(-c4ccc5oc6c7ccccc7c(-c7ccccc7)cc6c5c4)cc3)c3ccc4c(c3)oc3ccccc34)cc2)cc1 ; c1ccc(-c2ccc(N(c3ccccc3)c3ccc(-c4ccc5oc6c7ccccc7c(-c7cccc(-c8ccccc8)c7)cc6c5c4)cc3)cc2)cc1]

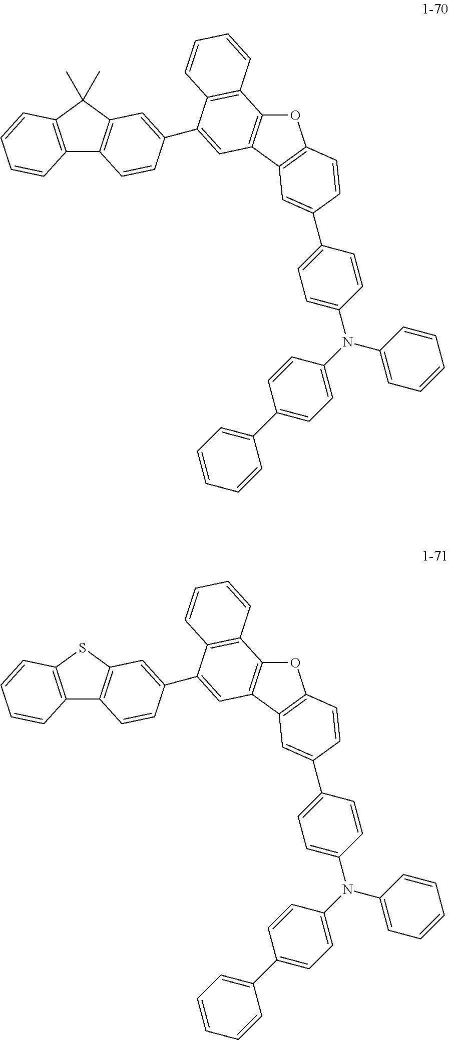 [SMILES: CC1(C)c2ccccc2-c2ccc(-c3cc4c5cc(-c6ccc(N(c7ccccc7)c7ccc(-c8ccccc8)cc7)cc6)ccc5oc4c4ccccc34)cc21 ; c1ccc(-c2ccc(N(c3ccccc3)c3ccc(-c4ccc5oc6c7ccccc7c(-c7ccc8c(c7)sc7ccccc78)cc6c5c4)cc3)cc2)cc1]

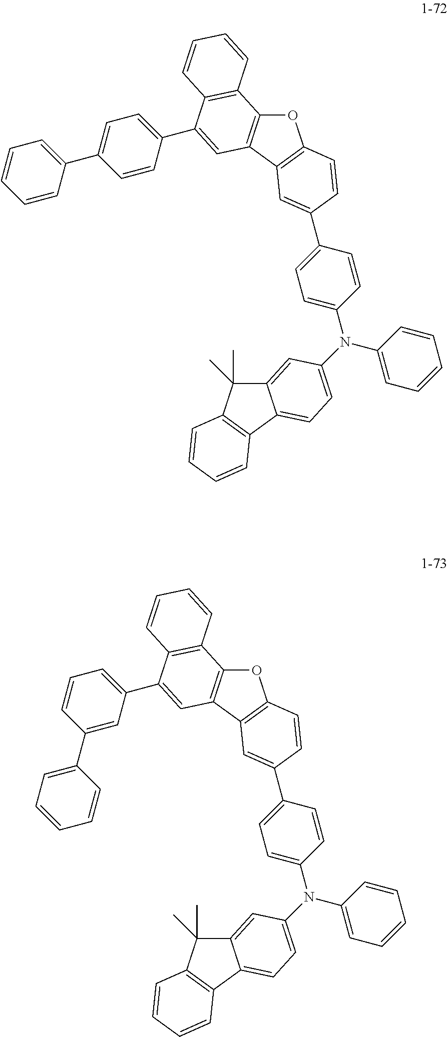 [SMILES: CC1(C)c2ccccc2-c2ccc(N(c3ccccc3)c3ccc(-c4ccc5oc6c7ccccc7c(-c7ccc(-c8ccccc8)cc7)cc6c5c4)cc3)cc21 ; CC1(C)c2ccccc2-c2ccc(N(c3ccccc3)c3ccc(-c4ccc5oc6c7ccccc7c(-c7cccc(-c8ccccc8)c7)cc6c5c4)cc3)cc21]

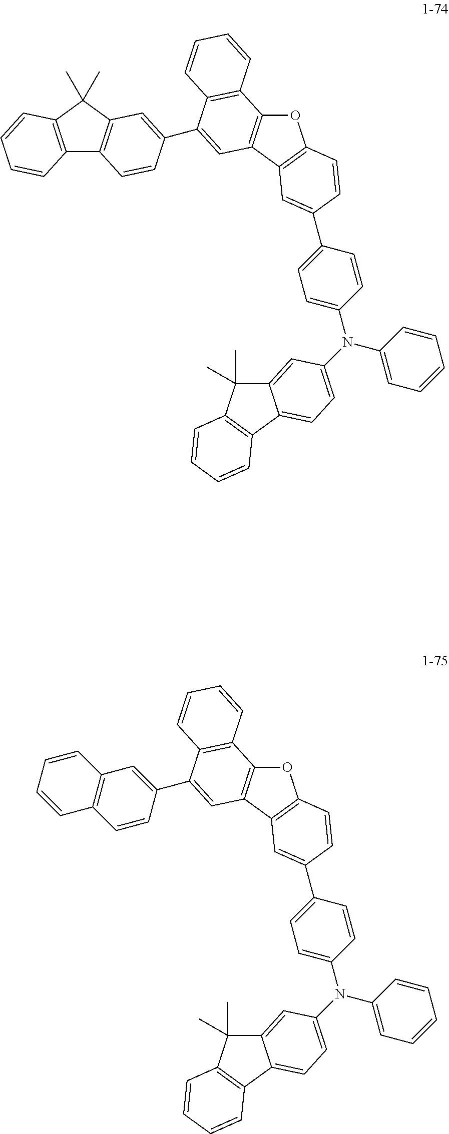 [SMILES: CC1(C)c2ccccc2-c2ccc(-c3cc4c5cc(-c6ccc(N(c7ccccc7)c7ccc8c(c7)C(C)(C)c7ccccc7-8)cc6)ccc5oc4c4ccccc34)cc21 ; CC1(C)c2ccccc2-c2ccc(N(c3ccccc3)c3ccc(-c4ccc5oc6c7ccccc7c(-c7ccc8ccccc8c7)cc6c5c4)cc3)cc21]

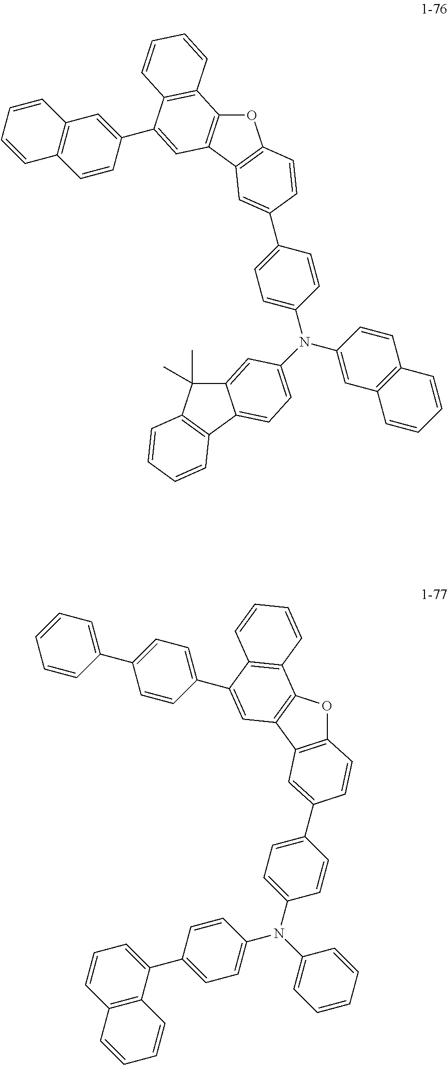 [SMILES: CC1(C)c2ccccc2-c2ccc(N(c3ccc(-c4ccc5oc6c7ccccc7c(-c7ccc8ccccc8c7)cc6c5c4)cc3)c3ccc4ccccc4c3)cc21 ; c1ccc(-c2ccc(-c3cc4c5cc(-c6ccc(N(c7ccccc7)c7ccc(-c8cccc9ccccc89)cc7)cc6)ccc5oc4c4ccccc34)cc2)cc1]

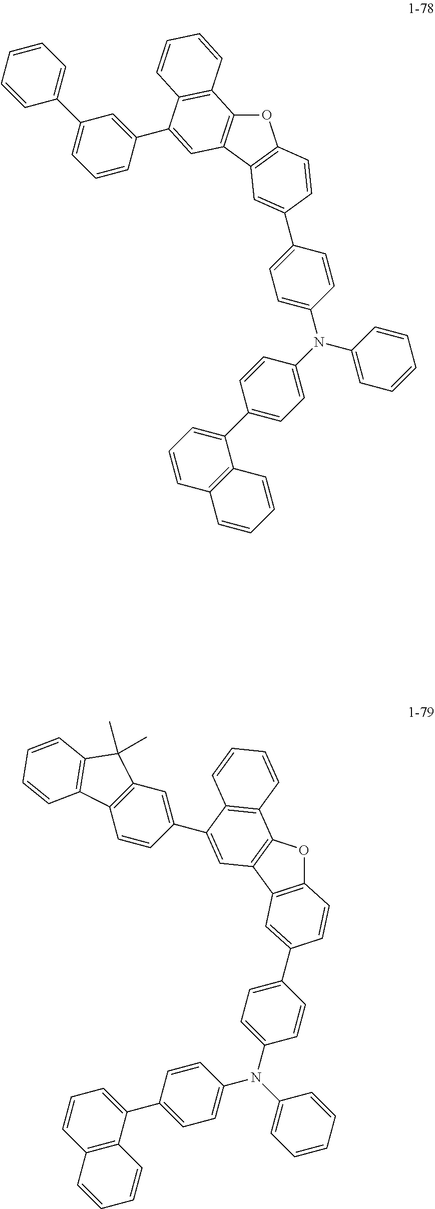 [SMILES: c1ccc(-c2cccc(-c3cc4c5cc(-c6ccc(N(c7ccccc7)c7ccc(-c8cccc9ccccc89)cc7)cc6)ccc5oc4c4ccccc34)c2)cc1 ; CC1(C)c2ccccc2-c2ccc(-c3cc4c5cc(-c6ccc(N(c7ccccc7)c7ccc(-c8cccc9ccccc89)cc7)cc6)ccc5oc4c4ccccc34)cc21]

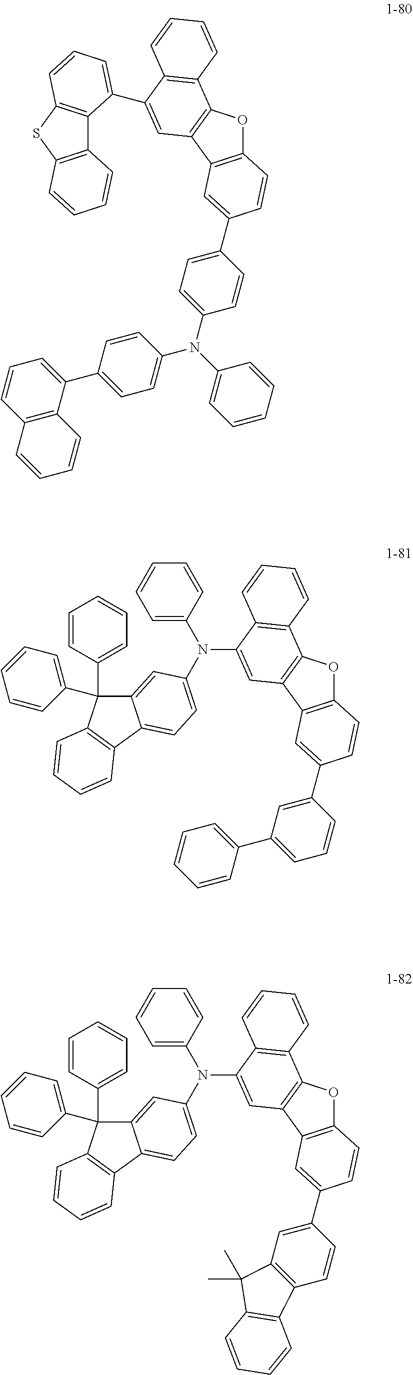 [SMILES: c1ccc(N(c2ccc(-c3ccc4oc5c6ccccc6c(-c6cccc7sc8ccccc8c67)cc5c4c3)cc2)c2ccc(-c3cccc4ccccc34)cc2)cc1 ; c1ccc(-c2cccc(-c3ccc4oc5c6ccccc6c(N(c6ccccc6)c6ccc7c(c6)C(c6ccccc6)(c6ccccc6)c6ccccc6-7)cc5c4c3)c2)cc1 ; CC1(C)c2ccccc2-c2ccc(-c3ccc4oc5c6ccccc6c(N(c6ccccc6)c6ccc7c(c6)C(c6ccccc6)(c6ccccc6)c6ccccc6-7)cc5c4c3)cc21]

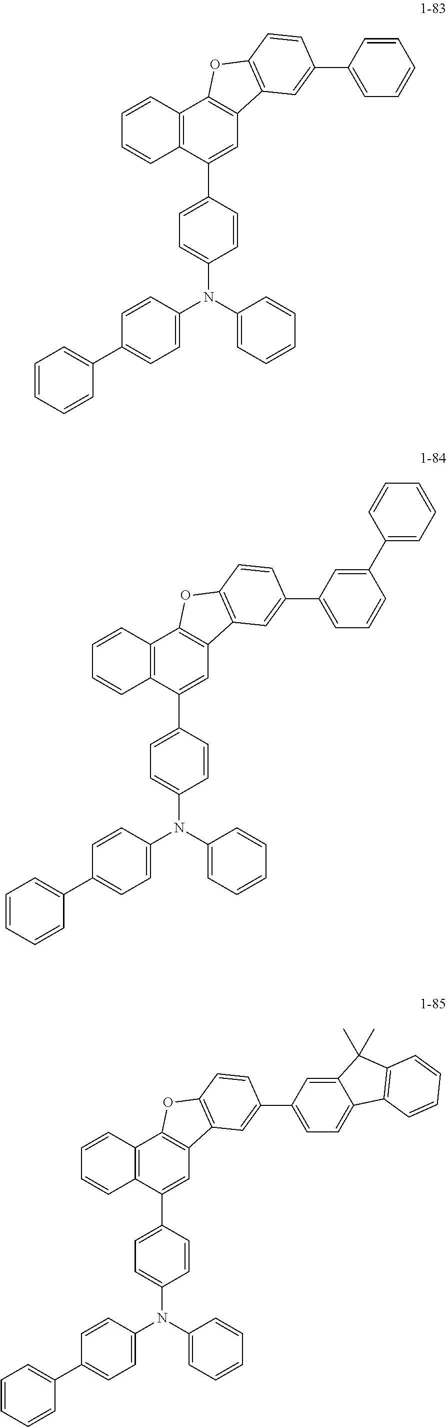 [SMILES: c1ccc(-c2ccc(N(c3ccccc3)c3ccc(-c4cc5c6cc(-c7ccccc7)ccc6oc5c5ccccc45)cc3)cc2)cc1 ; c1ccc(-c2ccc(N(c3ccccc3)c3ccc(-c4cc5c6cc(-c7cccc(-c8ccccc8)c7)ccc6oc5c5ccccc45)cc3)cc2)cc1 ; CC1(C)c2ccccc2-c2ccc(-c3ccc4oc5c6ccccc6c(-c6ccc(N(c7ccccc7)c7ccc(-c8ccccc8)cc7)cc6)cc5c4c3)cc21]

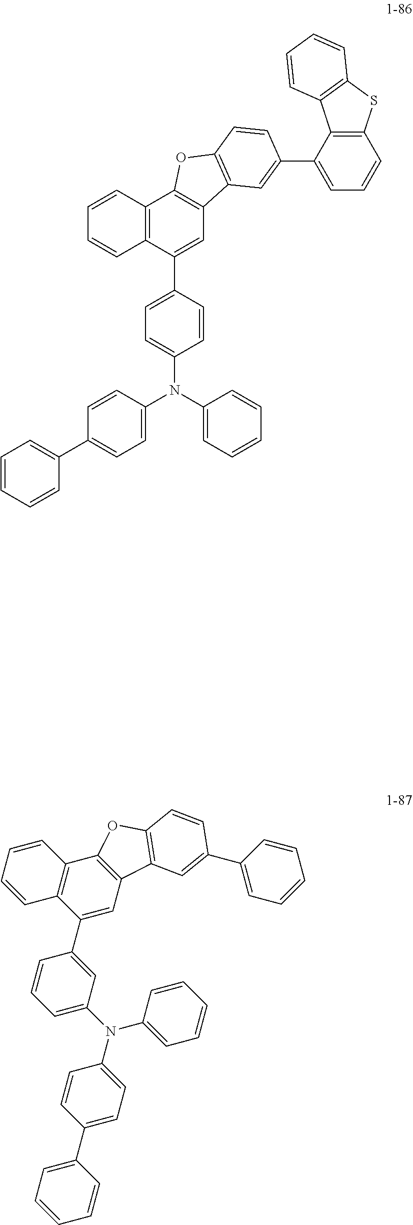 [SMILES: c1ccc(-c2ccc(N(c3ccccc3)c3ccc(-c4cc5c6cc(-c7cccc8sc9ccccc9c78)ccc6oc5c5ccccc45)cc3)cc2)cc1 ; c1ccc(-c2ccc(N(c3ccccc3)c3cccc(-c4cc5c6cc(-c7ccccc7)ccc6oc5c5ccccc45)c3)cc2)cc1]

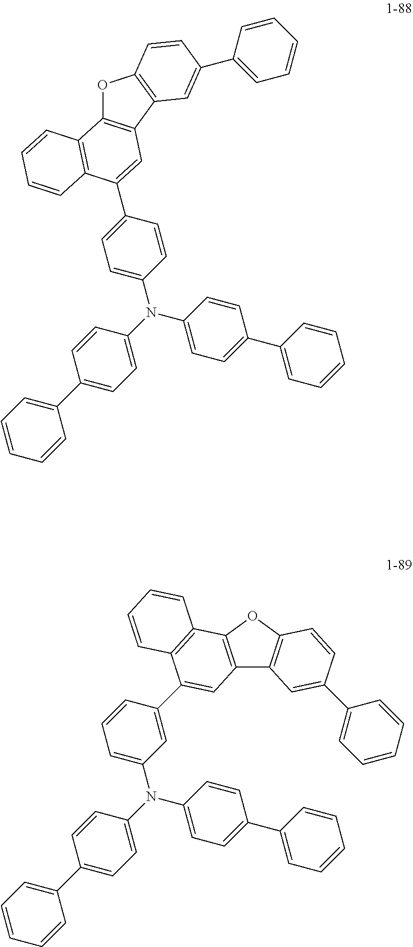 [SMILES: c1ccc(-c2ccc(N(c3ccc(-c4ccccc4)cc3)c3ccc(-c4cc5c6cc(-c7ccccc7)ccc6oc5c5ccccc45)cc3)cc2)cc1 ; c1ccc(-c2ccc(N(c3ccc(-c4ccccc4)cc3)c3cccc(-c4cc5c6cc(-c7ccccc7)ccc6oc5c5ccccc45)c3)cc2)cc1]

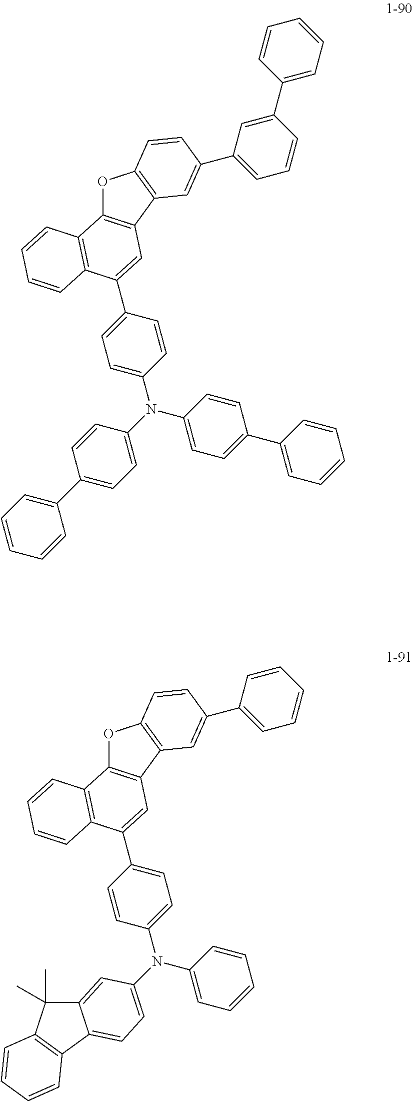 [SMILES: c1ccc(-c2ccc(N(c3ccc(-c4ccccc4)cc3)c3ccc(-c4cc5c6cc(-c7cccc(-c8ccccc8)c7)ccc6oc5c5ccccc45)cc3)cc2)cc1 ; CC1(C)c2ccccc2-c2ccc(N(c3ccccc3)c3ccc(-c4cc5c6cc(-c7ccccc7)ccc6oc5c5ccccc45)cc3)cc21]

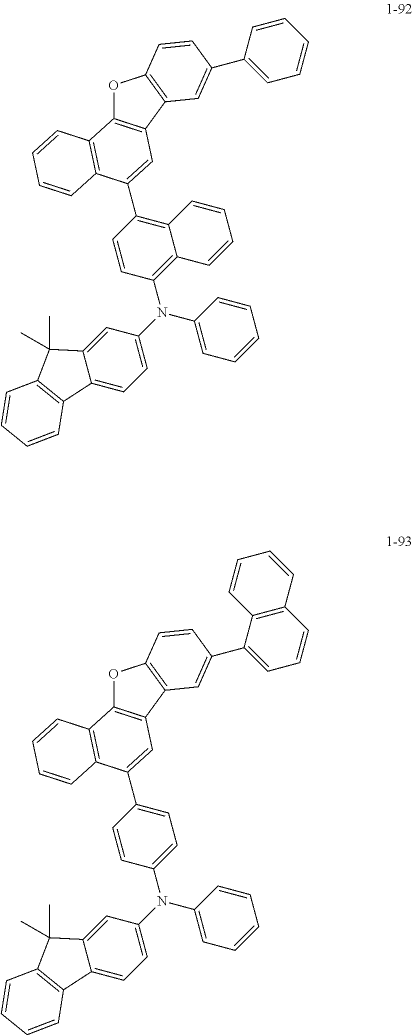 [SMILES: CC1(C)c2ccccc2-c2ccc(N(c3ccccc3)c3ccc(-c4cc5c6cc(-c7ccccc7)ccc6oc5c5ccccc45)c4ccccc34)cc21 ; CC1(C)c2ccccc2-c2ccc(N(c3ccccc3)c3ccc(-c4cc5c6cc(-c7cccc8ccccc78)ccc6oc5c5ccccc45)cc3)cc21]

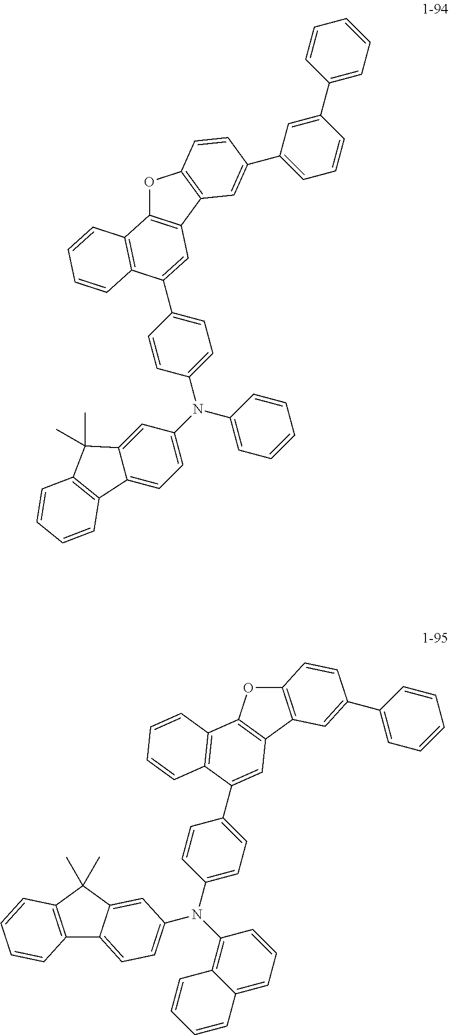 [SMILES: CC1(C)c2ccccc2-c2ccc(N(c3ccccc3)c3ccc(-c4cc5c6cc(-c7cccc(-c8ccccc8)c7)ccc6oc5c5ccccc45)cc3)cc21 ; CC1(C)c2ccccc2-c2ccc(N(c3ccc(-c4cc5c6cc(-c7ccccc7)ccc6oc5c5ccccc45)cc3)c3cccc4ccccc34)cc21]

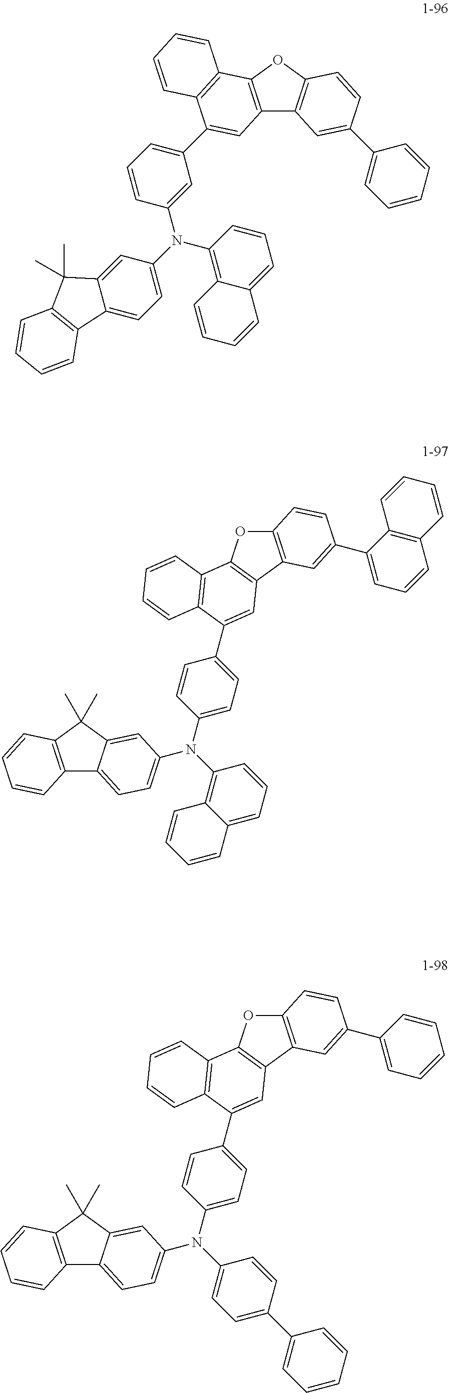 [SMILES: CC1(C)c2ccccc2-c2ccc(N(c3cccc(-c4cc5c6cc(-c7ccccc7)ccc6oc5c5ccccc45)c3)c3cccc4ccccc34)cc21 ; CC1(C)c2ccccc2-c2ccc(N(c3ccc(-c4cc5c6cc(-c7cccc8ccccc78)ccc6oc5c5ccccc45)cc3)c3cccc4ccccc34)cc21 ; CC1(C)c2ccccc2-c2ccc(N(c3ccc(-c4ccccc4)cc3)c3ccc(-c4cc5c6cc(-c7ccccc7)ccc6oc5c5ccccc45)cc3)cc21]

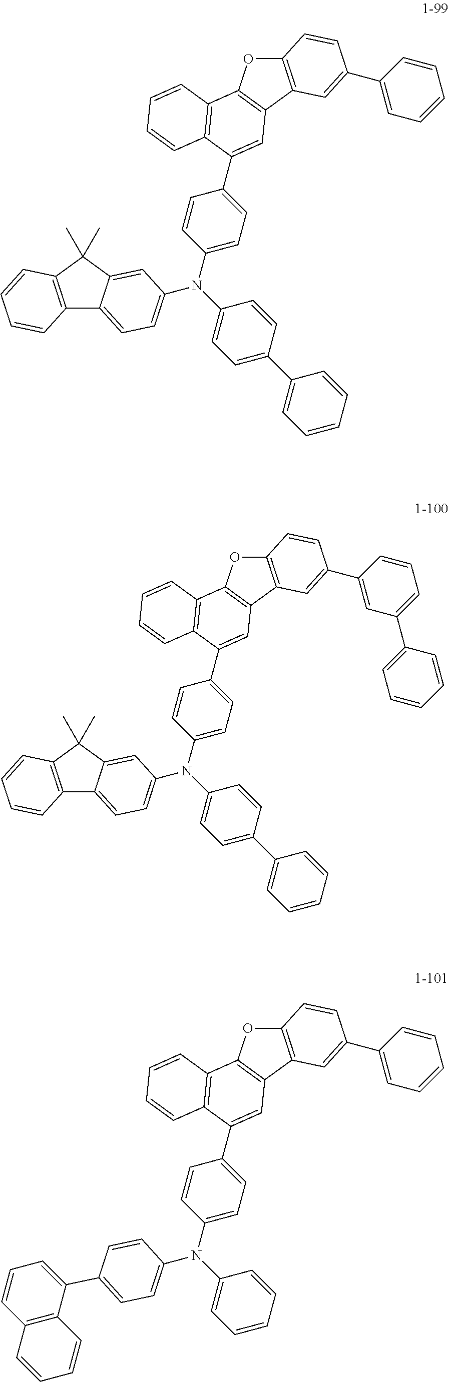 [SMILES: CC1(C)c2ccccc2-c2ccc(N(c3ccc(-c4ccccc4)cc3)c3ccc(-c4cc5c6cc(-c7ccccc7)ccc6oc5c5ccccc45)cc3)cc21 ; CC1(C)c2ccccc2-c2ccc(N(c3ccc(-c4ccccc4)cc3)c3ccc(-c4cc5c6cc(-c7cccc(-c8ccccc8)c7)ccc6oc5c5ccccc45)cc3)cc21 ; c1ccc(-c2ccc3oc4c5ccccc5c(-c5ccc(N(c6ccccc6)c6ccc(-c7cccc8ccccc78)cc6)cc5)cc4c3c2)cc1]

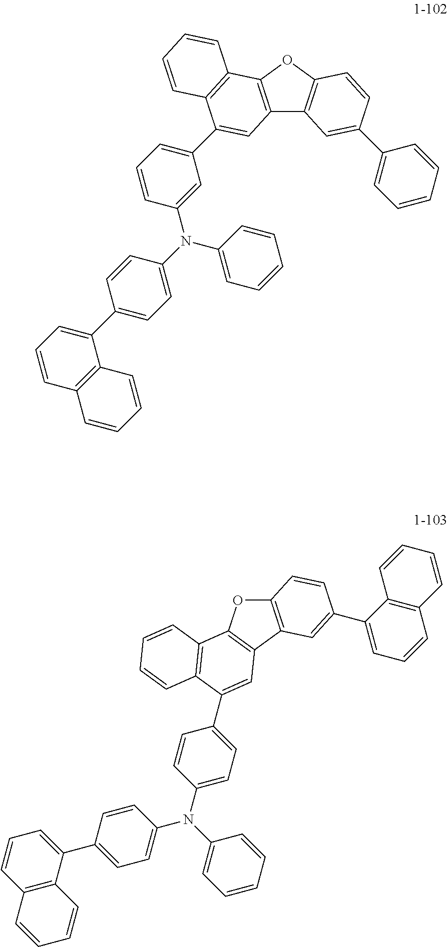 [SMILES: c1ccc(-c2ccc3oc4c5ccccc5c(-c5cccc(N(c6ccccc6)c6ccc(-c7cccc8ccccc78)cc6)c5)cc4c3c2)cc1 ; c1ccc(N(c2ccc(-c3cccc4ccccc34)cc2)c2ccc(-c3cc4c5cc(-c6cccc7ccccc67)ccc5oc4c4ccccc34)cc2)cc1]

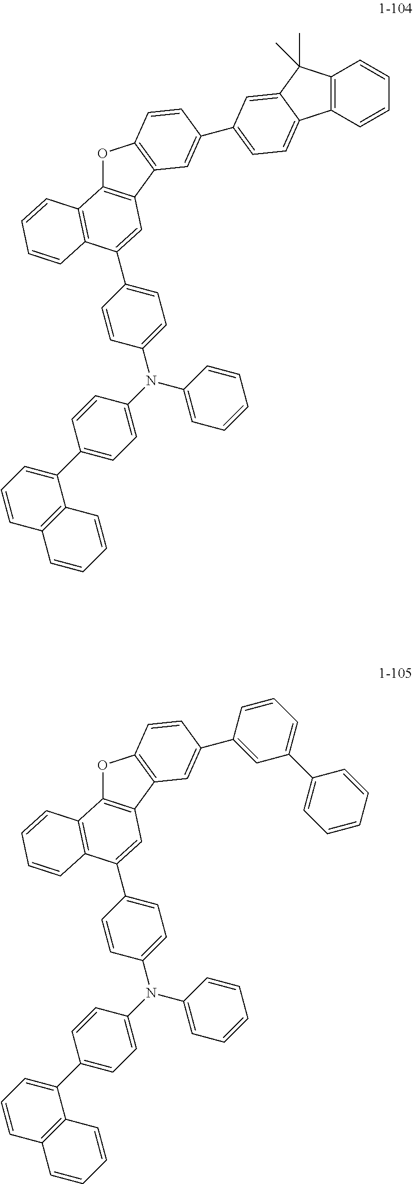 [SMILES: CC1(C)c2ccccc2-c2ccc(-c3ccc4oc5c6ccccc6c(-c6ccc(N(c7ccccc7)c7ccc(-c8cccc9ccccc89)cc7)cc6)cc5c4c3)cc21 ; c1ccc(-c2cccc(-c3ccc4oc5c6ccccc6c(-c6ccc(N(c7ccccc7)c7ccc(-c8cccc9ccccc89)cc7)cc6)cc5c4c3)c2)cc1]

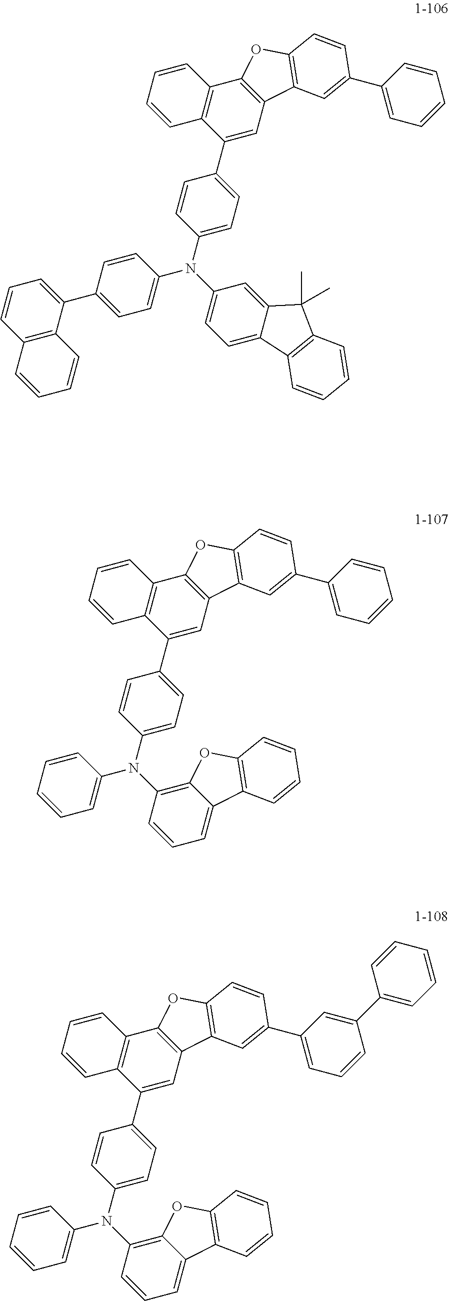 [SMILES: CC1(C)c2ccccc2-c2ccc(N(c3ccc(-c4cccc5ccccc45)cc3)c3ccc(-c4cc5c6cc(-c7ccccc7)ccc6oc5c5ccccc45)cc3)cc21 ; c1ccc(-c2ccc3oc4c5ccccc5c(-c5ccc(N(c6ccccc6)c6cccc7c6oc6ccccc67)cc5)cc4c3c2)cc1 ; c1ccc(-c2cccc(-c3ccc4oc5c6ccccc6c(-c6ccc(N(c7ccccc7)c7cccc8c7oc7ccccc78)cc6)cc5c4c3)c2)cc1]

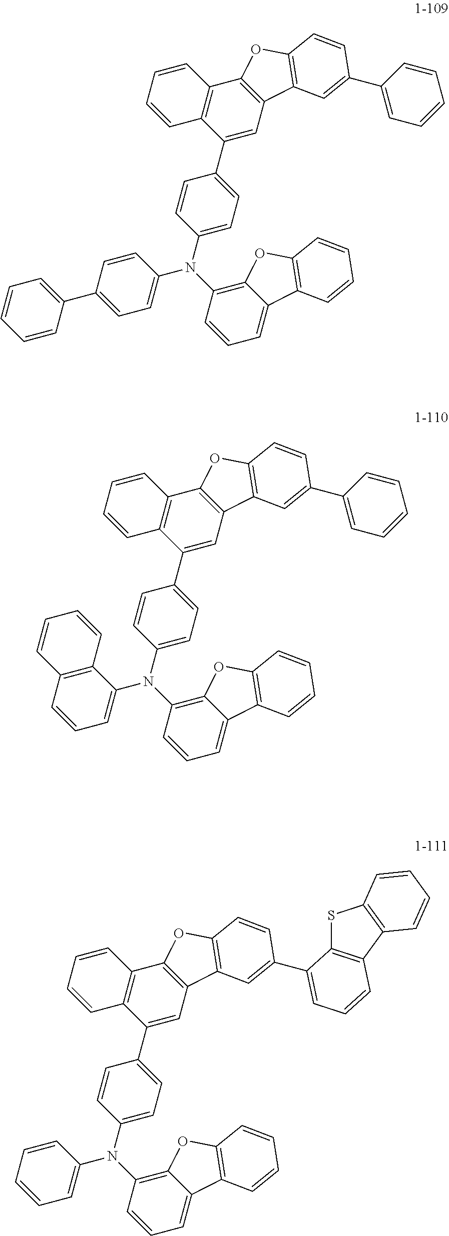 [SMILES: c1ccc(-c2ccc(N(c3ccc(-c4cc5c6cc(-c7ccccc7)ccc6oc5c5ccccc45)cc3)c3cccc4c3oc3ccccc34)cc2)cc1 ; c1ccc(-c2ccc3oc4c5ccccc5c(-c5ccc(N(c6cccc7ccccc67)c6cccc7c6oc6ccccc67)cc5)cc4c3c2)cc1 ; c1ccc(N(c2ccc(-c3cc4c5cc(-c6cccc7c6sc6ccccc67)ccc5oc4c4ccccc34)cc2)c2cccc3c2oc2ccccc23)cc1]

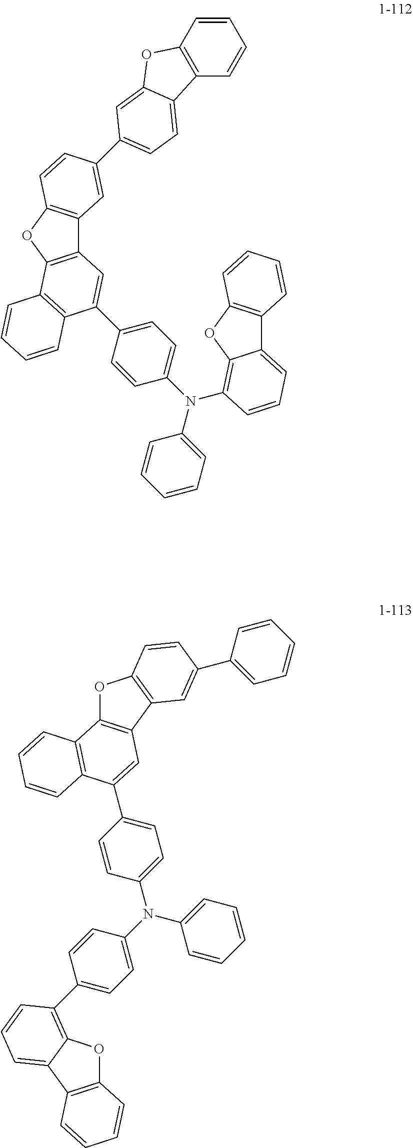 [SMILES: c1ccc(N(c2ccc(-c3cc4c5cc(-c6ccc7c(c6)oc6ccccc67)ccc5oc4c4ccccc34)cc2)c2cccc3c2oc2ccccc23)cc1 ; c1ccc(-c2ccc3oc4c5ccccc5c(-c5ccc(N(c6ccccc6)c6ccc(-c7cccc8c7oc7ccccc78)cc6)cc5)cc4c3c2)cc1]

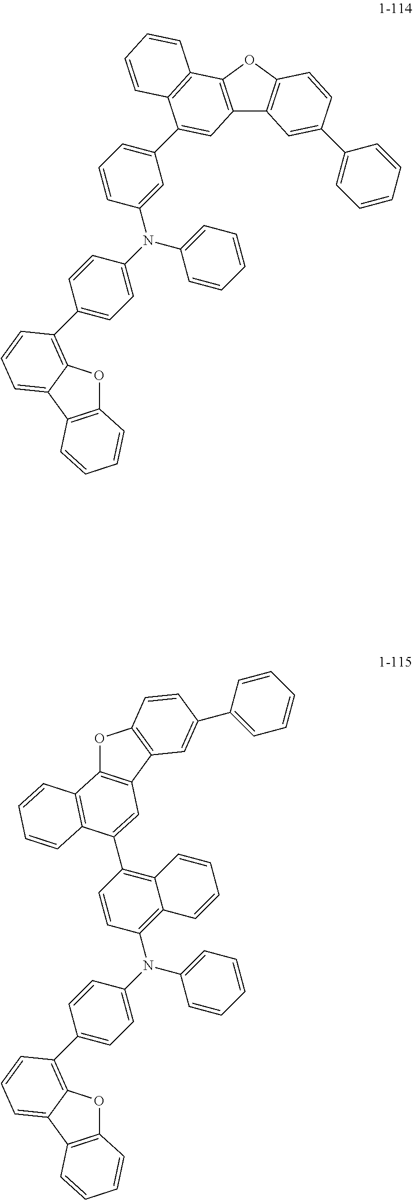 [SMILES: c1ccc(-c2ccc3oc4c5ccccc5c(-c5cccc(N(c6ccccc6)c6ccc(-c7cccc8c7oc7ccccc78)cc6)c5)cc4c3c2)cc1 ; c1ccc(-c2ccc3oc4c5ccccc5c(-c5ccc(N(c6ccccc6)c6ccc(-c7cccc8c7oc7ccccc78)cc6)c6ccccc56)cc4c3c2)cc1]

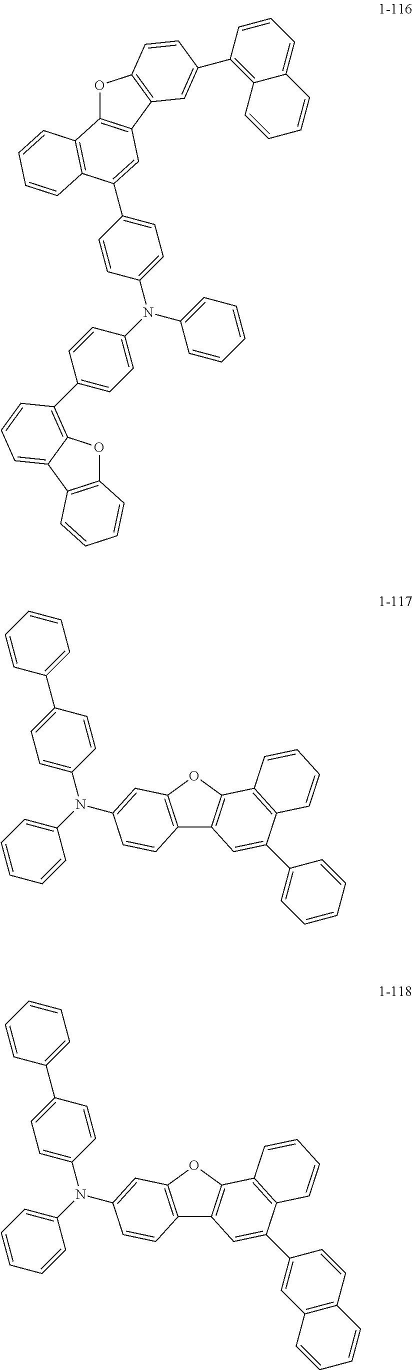 [SMILES: c1ccc(N(c2ccc(-c3cc4c5cc(-c6cccc7ccccc67)ccc5oc4c4ccccc34)cc2)c2ccc(-c3cccc4c3oc3ccccc34)cc2)cc1 ; c1ccc(-c2ccc(N(c3ccccc3)c3ccc4c(c3)oc3c5ccccc5c(-c5ccccc5)cc43)cc2)cc1 ; c1ccc(-c2ccc(N(c3ccccc3)c3ccc4c(c3)oc3c5ccccc5c(-c5ccc6ccccc6c5)cc43)cc2)cc1]

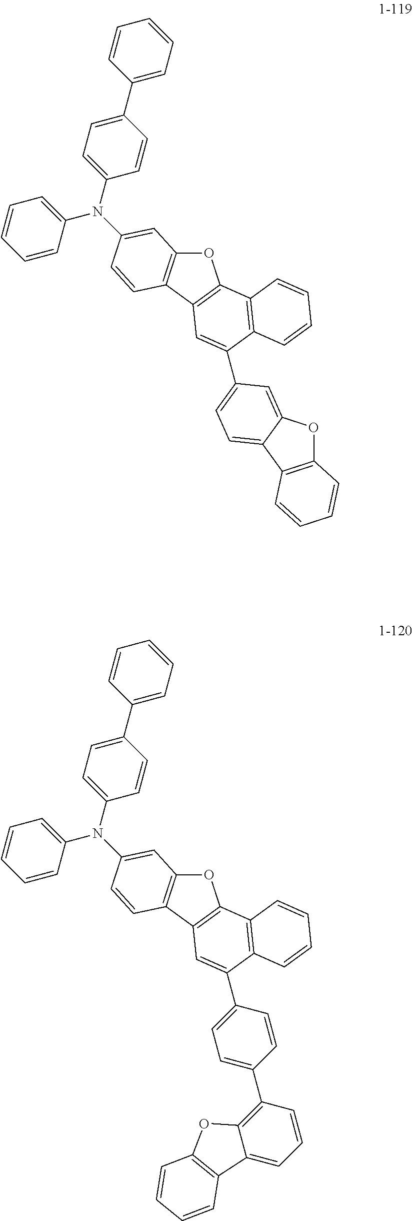 [SMILES: c1ccc(-c2ccc(N(c3ccccc3)c3ccc4c(c3)oc3c5ccccc5c(-c5ccc6c(c5)oc5ccccc56)cc43)cc2)cc1 ; c1ccc(-c2ccc(N(c3ccccc3)c3ccc4c(c3)oc3c5ccccc5c(-c5ccc(-c6cccc7c6oc6ccccc67)cc5)cc43)cc2)cc1]

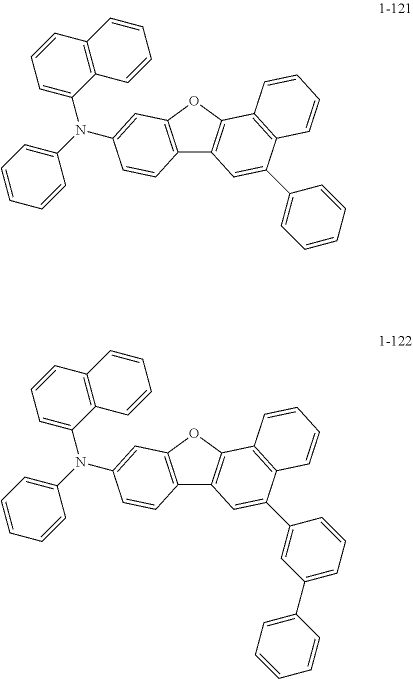 [SMILES: c1ccc(-c2cc3c4ccc(N(c5ccccc5)c5cccc6ccccc56)cc4oc3c3ccccc23)cc1 ; c1ccc(-c2cccc(-c3cc4c5ccc(N(c6ccccc6)c6cccc7ccccc67)cc5oc4c4ccccc34)c2)cc1]

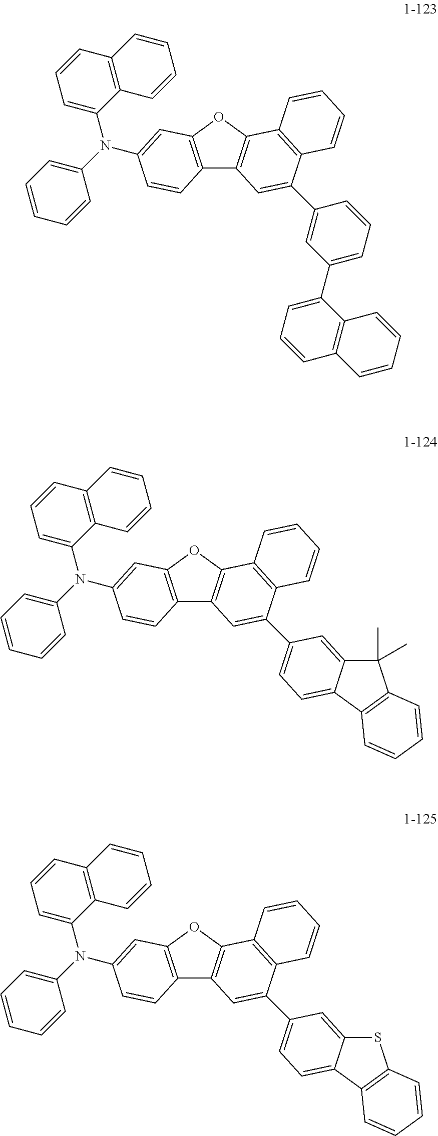 [SMILES: c1ccc(N(c2ccc3c(c2)oc2c4ccccc4c(-c4cccc(-c5cccc6ccccc56)c4)cc32)c2cccc3ccccc23)cc1 ; CC1(C)c2ccccc2-c2ccc(-c3cc4c5ccc(N(c6ccccc6)c6cccc7ccccc67)cc5oc4c4ccccc34)cc21 ; c1ccc(N(c2ccc3c(c2)oc2c4ccccc4c(-c4ccc5c(c4)sc4ccccc45)cc32)c2cccc3ccccc23)cc1]

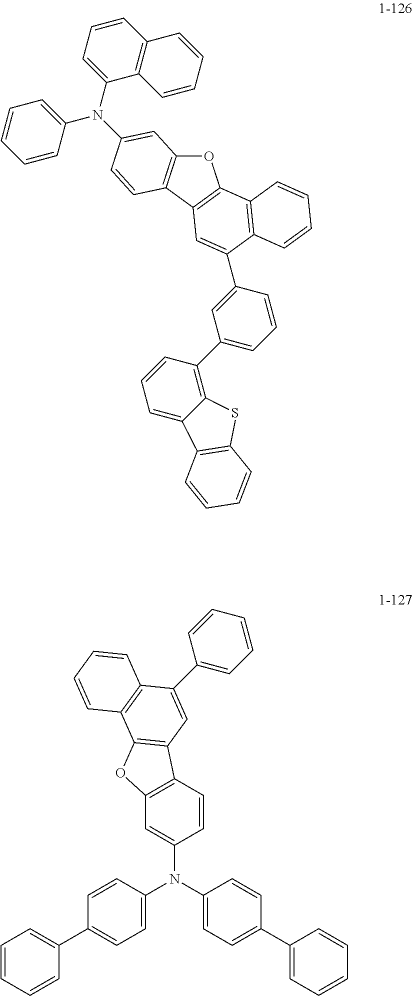 [SMILES: c1ccc(N(c2ccc3c(c2)oc2c4ccccc4c(-c4cccc(-c5cccc6c5sc5ccccc56)c4)cc32)c2cccc3ccccc23)cc1 ; c1ccc(-c2ccc(N(c3ccc(-c4ccccc4)cc3)c3ccc4c(c3)oc3c5ccccc5c(-c5ccccc5)cc43)cc2)cc1]

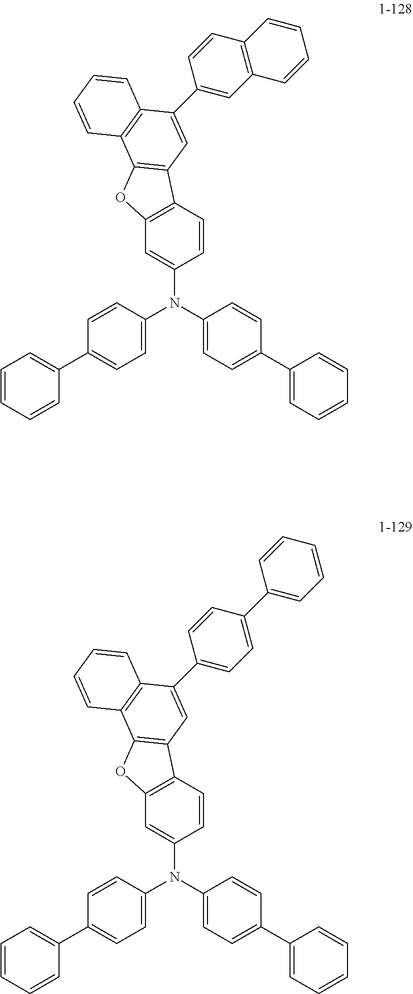 [SMILES: c1ccc(-c2ccc(N(c3ccc(-c4ccccc4)cc3)c3ccc4c(c3)oc3c5ccccc5c(-c5ccc6ccccc6c5)cc43)cc2)cc1 ; c1ccc(-c2ccc(-c3cc4c5ccc(N(c6ccc(-c7ccccc7)cc6)c6ccc(-c7ccccc7)cc6)cc5oc4c4ccccc34)cc2)cc1]

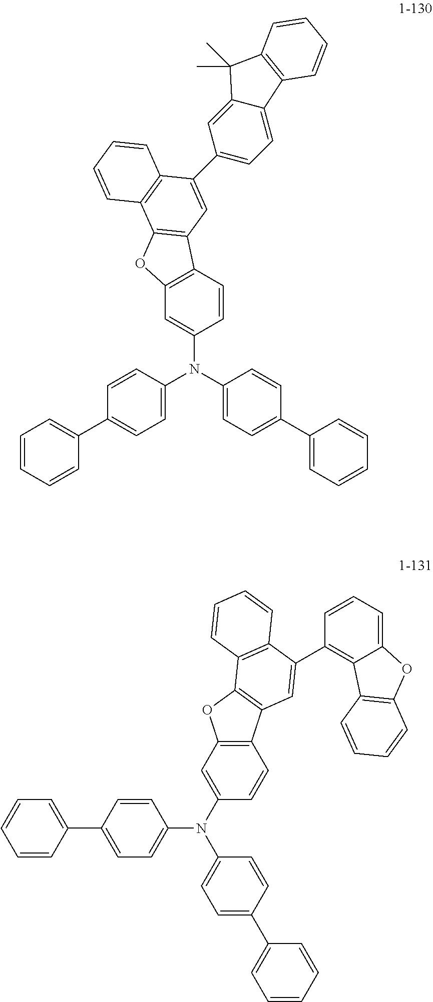 [SMILES: CC1(C)c2ccccc2-c2ccc(-c3cc4c5ccc(N(c6ccc(-c7ccccc7)cc6)c6ccc(-c7ccccc7)cc6)cc5oc4c4ccccc34)cc21 ; c1ccc(-c2ccc(N(c3ccc(-c4ccccc4)cc3)c3ccc4c(c3)oc3c5ccccc5c(-c5cccc6oc7ccccc7c56)cc43)cc2)cc1]

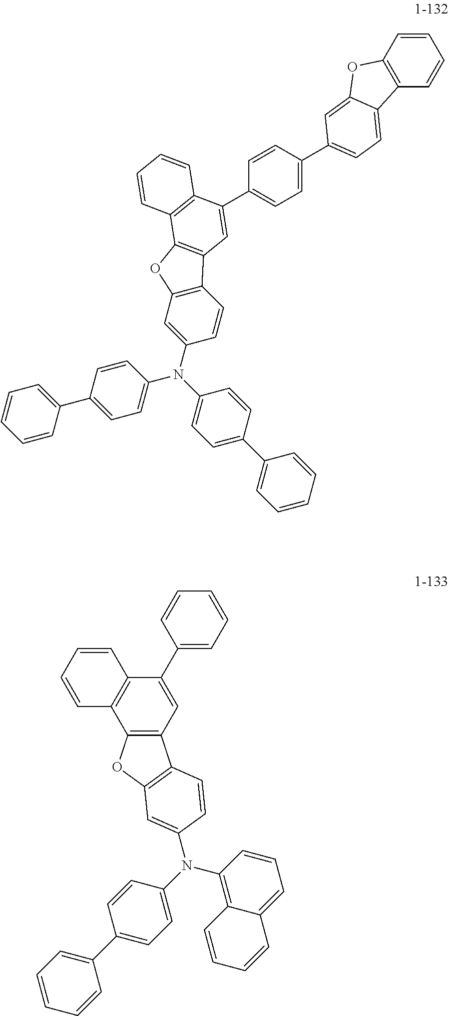 [SMILES: c1ccc(-c2ccc(N(c3ccc(-c4ccccc4)cc3)c3ccc4c(c3)oc3c5ccccc5c(-c5ccc(-c6ccc7c(c6)oc6ccccc67)cc5)cc43)cc2)cc1 ; c1ccc(-c2ccc(N(c3ccc4c(c3)oc3c5ccccc5c(-c5ccccc5)cc43)c3cccc4ccccc34)cc2)cc1]

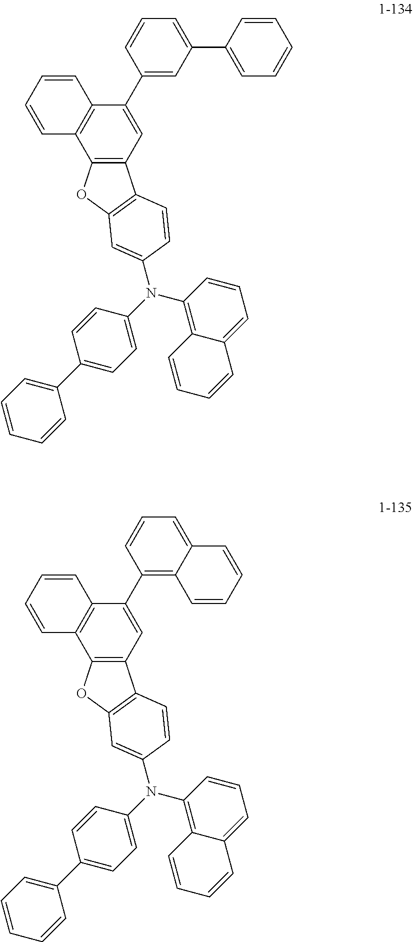 [SMILES: c1ccc(-c2ccc(N(c3ccc4c(c3)oc3c5ccccc5c(-c5cccc(-c6ccccc6)c5)cc43)c3cccc4ccccc34)cc2)cc1 ; c1ccc(-c2ccc(N(c3ccc4c(c3)oc3c5ccccc5c(-c5cccc6ccccc56)cc43)c3cccc4ccccc34)cc2)cc1]

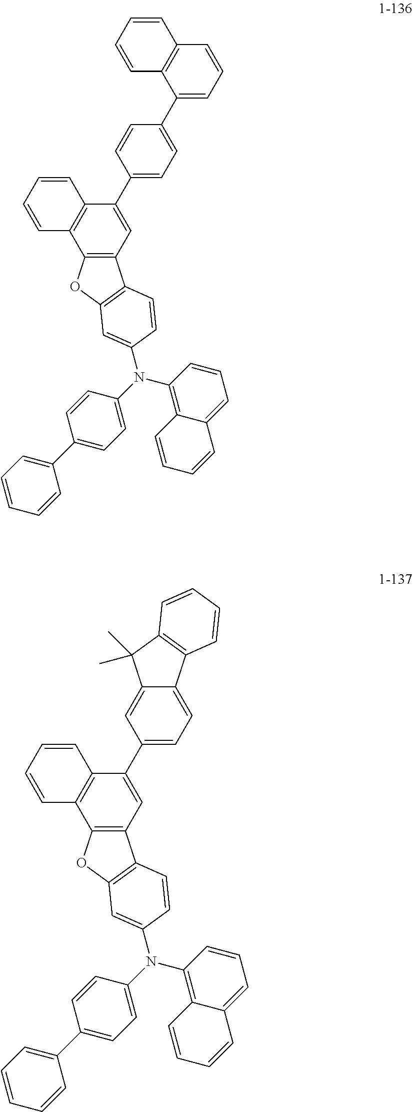 [SMILES: c1ccc(-c2ccc(N(c3ccc4c(c3)oc3c5ccccc5c(-c5ccc(-c6cccc7ccccc67)cc5)cc43)c3cccc4ccccc34)cc2)cc1 ; CC1(C)c2ccccc2-c2ccc(-c3cc4c5ccc(N(c6ccc(-c7ccccc7)cc6)c6cccc7ccccc67)cc5oc4c4ccccc34)cc21]

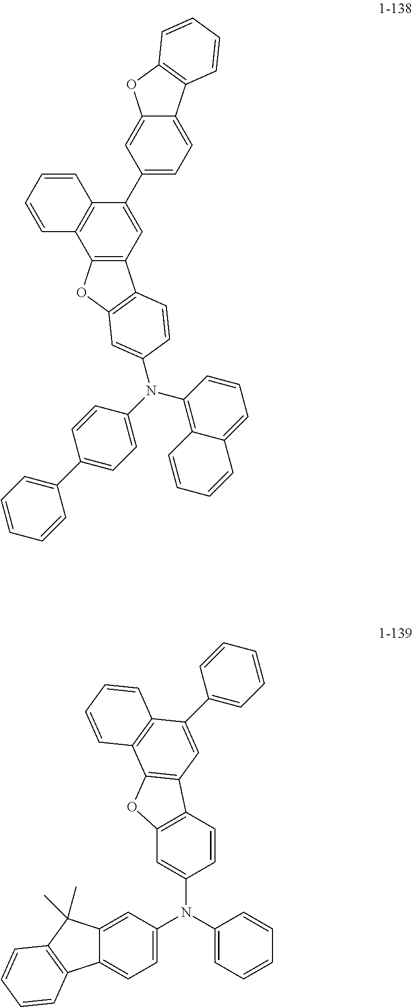 [SMILES: c1ccc(-c2ccc(N(c3ccc4c(c3)oc3c5ccccc5c(-c5ccc6c(c5)oc5ccccc56)cc43)c3cccc4ccccc34)cc2)cc1 ; CC1(C)c2ccccc2-c2ccc(N(c3ccccc3)c3ccc4c(c3)oc3c5ccccc5c(-c5ccccc5)cc43)cc21]

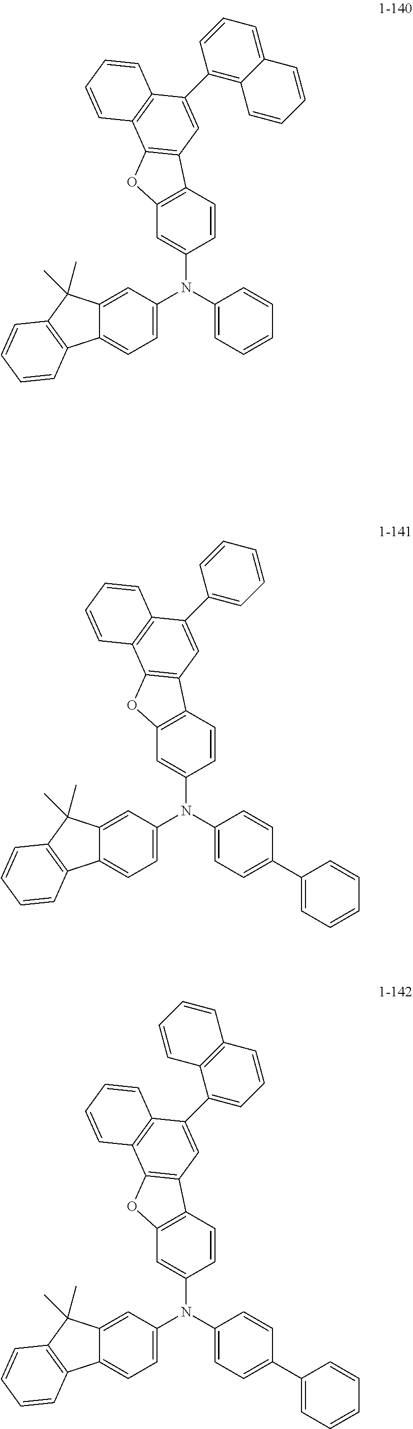 [SMILES: CC1(C)c2ccccc2-c2ccc(N(c3ccccc3)c3ccc4c(c3)oc3c5ccccc5c(-c5cccc6ccccc56)cc43)cc21 ; CC1(C)c2ccccc2-c2ccc(N(c3ccc(-c4ccccc4)cc3)c3ccc4c(c3)oc3c5ccccc5c(-c5ccccc5)cc43)cc21 ; CC1(C)c2ccccc2-c2ccc(N(c3ccc(-c4ccccc4)cc3)c3ccc4c(c3)oc3c5ccccc5c(-c5cccc6ccccc56)cc43)cc21]

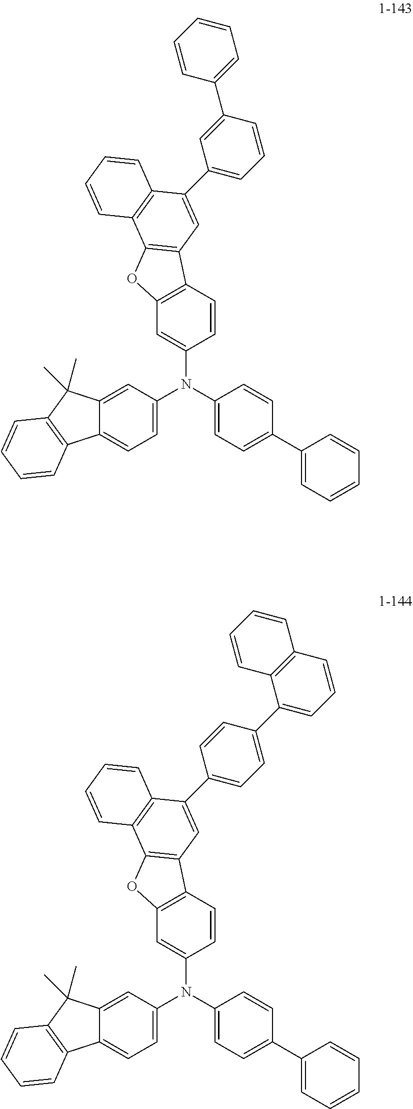 [SMILES: CC1(C)c2ccccc2-c2ccc(N(c3ccc(-c4ccccc4)cc3)c3ccc4c(c3)oc3c5ccccc5c(-c5cccc(-c6ccccc6)c5)cc43)cc21 ; CC1(C)c2ccccc2-c2ccc(N(c3ccc(-c4ccccc4)cc3)c3ccc4c(c3)oc3c5ccccc5c(-c5ccc(-c6cccc7ccccc67)cc5)cc43)cc21]

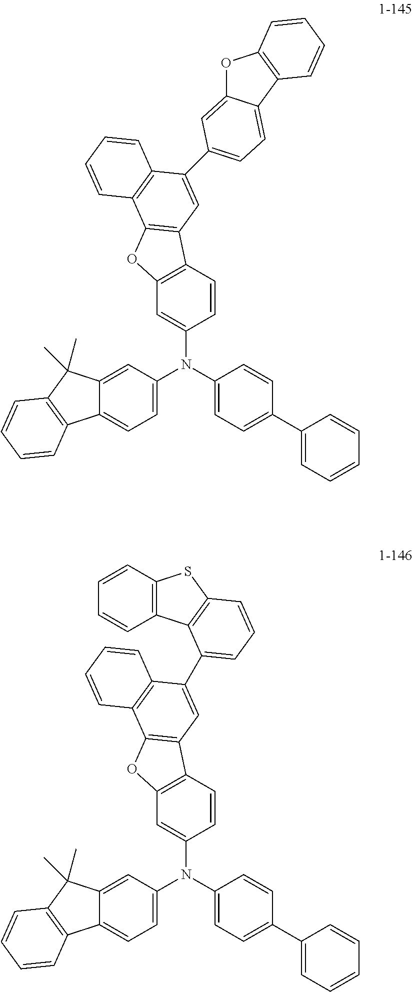 [SMILES: CC1(C)c2ccccc2-c2ccc(N(c3ccc(-c4ccccc4)cc3)c3ccc4c(c3)oc3c5ccccc5c(-c5ccc6c(c5)oc5ccccc56)cc43)cc21 ; CC1(C)c2ccccc2-c2ccc(N(c3ccc(-c4ccccc4)cc3)c3ccc4c(c3)oc3c5ccccc5c(-c5cccc6sc7ccccc7c56)cc43)cc21]

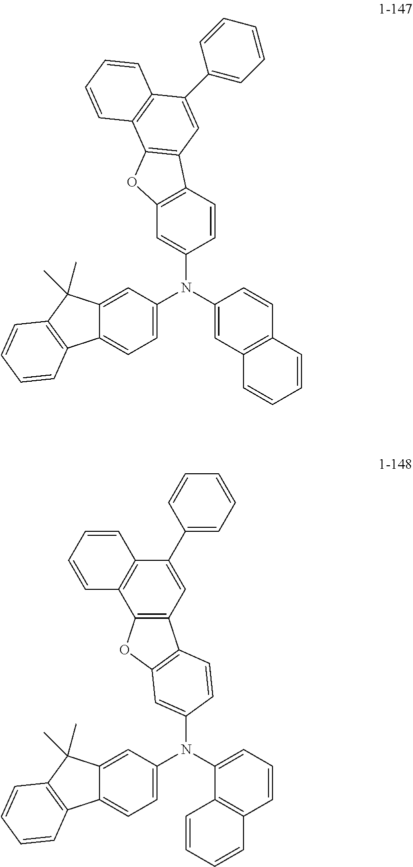 [SMILES: CC1(C)c2ccccc2-c2ccc(N(c3ccc4ccccc4c3)c3ccc4c(c3)oc3c5ccccc5c(-c5ccccc5)cc43)cc21 ; CC1(C)c2ccccc2-c2ccc(N(c3ccc4c(c3)oc3c5ccccc5c(-c5ccccc5)cc43)c3cccc4ccccc34)cc21]

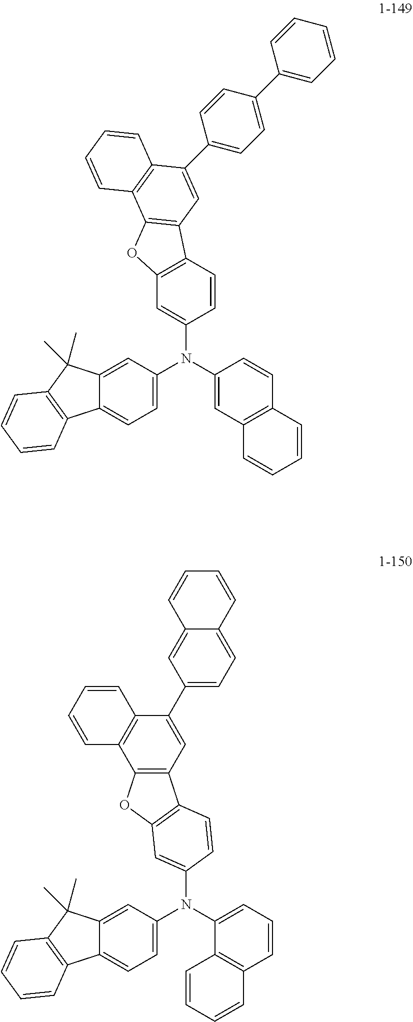 [SMILES: CC1(C)c2ccccc2-c2ccc(N(c3ccc4ccccc4c3)c3ccc4c(c3)oc3c5ccccc5c(-c5ccc(-c6ccccc6)cc5)cc43)cc21 ; CC1(C)c2ccccc2-c2ccc(N(c3ccc4c(c3)oc3c5ccccc5c(-c5ccc6ccccc6c5)cc43)c3cccc4ccccc34)cc21]

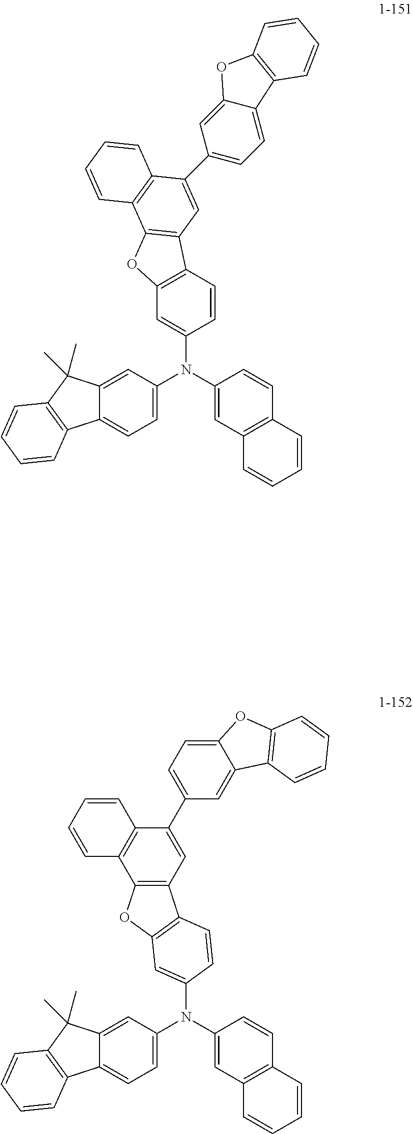 [SMILES: CC1(C)c2ccccc2-c2ccc(N(c3ccc4ccccc4c3)c3ccc4c(c3)oc3c5ccccc5c(-c5ccc6c(c5)oc5ccccc56)cc43)cc21 ; CC1(C)c2ccccc2-c2ccc(N(c3ccc4ccccc4c3)c3ccc4c(c3)oc3c5ccccc5c(-c5ccc6oc7ccccc7c6c5)cc43)cc21]

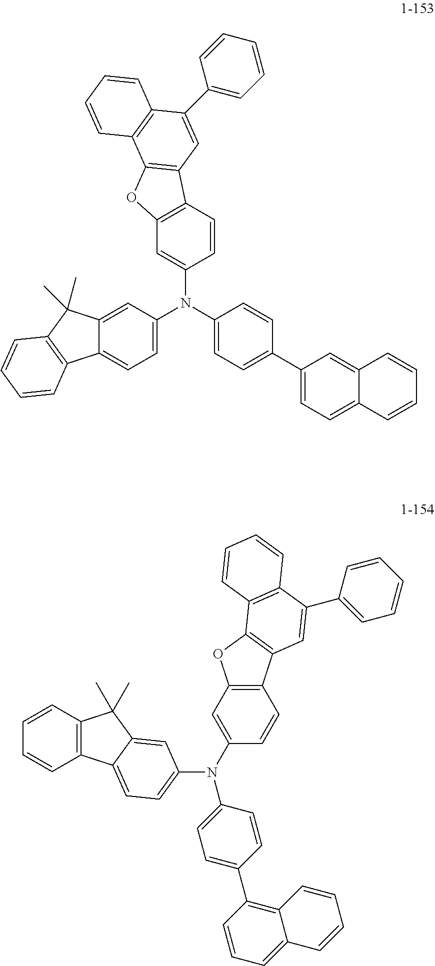 [SMILES: CC1(C)c2ccccc2-c2ccc(N(c3ccc(-c4ccc5ccccc5c4)cc3)c3ccc4c(c3)oc3c5ccccc5c(-c5ccccc5)cc43)cc21 ; CC1(C)c2ccccc2-c2ccc(N(c3ccc(-c4cccc5ccccc45)cc3)c3ccc4c(c3)oc3c5ccccc5c(-c5ccccc5)cc43)cc21]

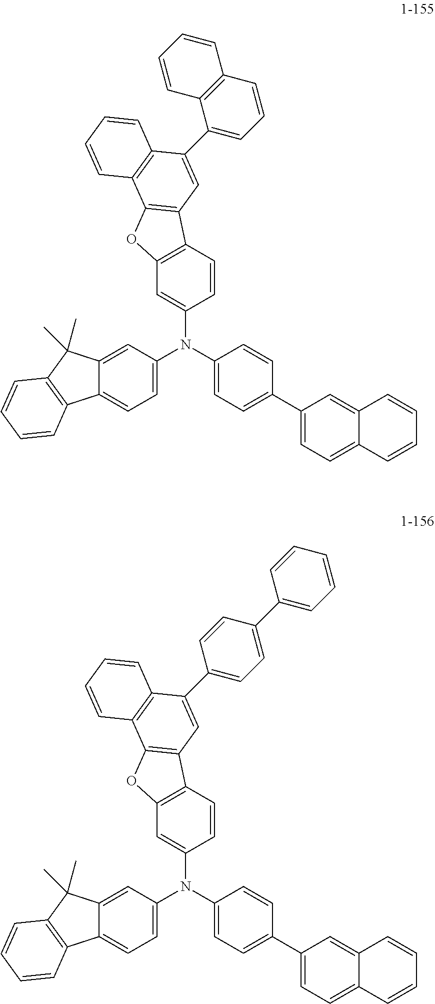 [SMILES: CC1(C)c2ccccc2-c2ccc(N(c3ccc(-c4ccc5ccccc5c4)cc3)c3ccc4c(c3)oc3c5ccccc5c(-c5cccc6ccccc56)cc43)cc21 ; CC1(C)c2ccccc2-c2ccc(N(c3ccc(-c4ccc5ccccc5c4)cc3)c3ccc4c(c3)oc3c5ccccc5c(-c5ccc(-c6ccccc6)cc5)cc43)cc21]

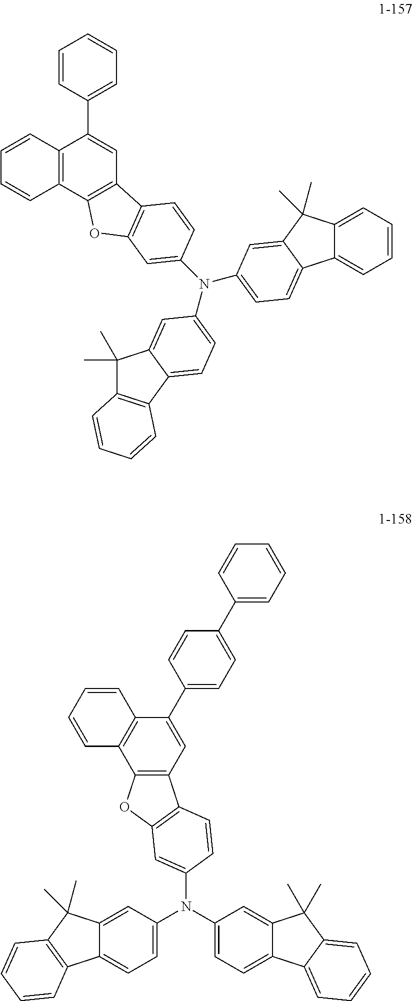 [SMILES: CC1(C)c2ccccc2-c2ccc(N(c3ccc4c(c3)C(C)(C)c3ccccc3-4)c3ccc4c(c3)oc3c5ccccc5c(-c5ccccc5)cc43)cc21 ; CC1(C)c2ccccc2-c2ccc(N(c3ccc4c(c3)C(C)(C)c3ccccc3-4)c3ccc4c(c3)oc3c5ccccc5c(-c5ccc(-c6ccccc6)cc5)cc43)cc21]

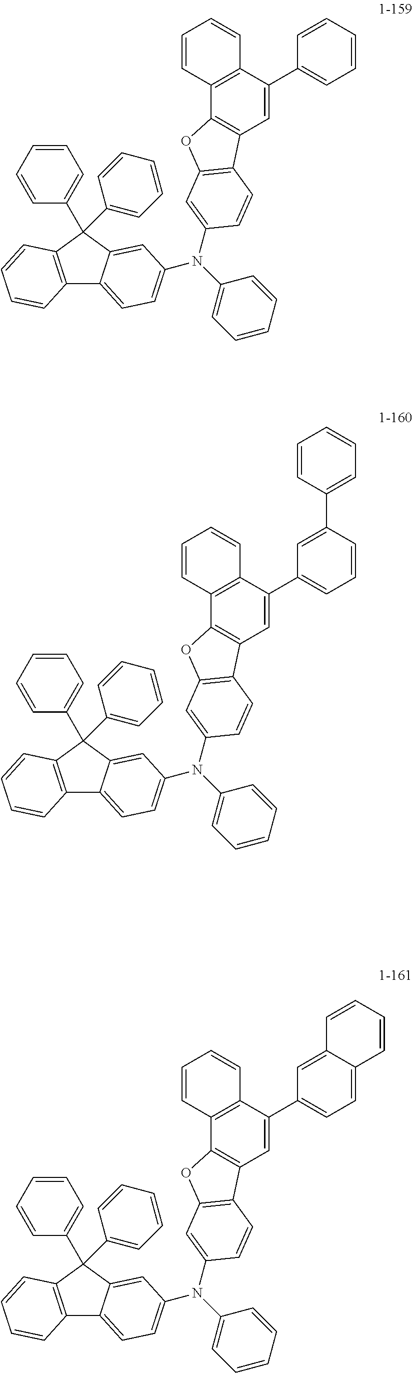 [SMILES: c1ccc(-c2cc3c4ccc(N(c5ccccc5)c5ccc6c(c5)C(c5ccccc5)(c5ccccc5)c5ccccc5-6)cc4oc3c3ccccc23)cc1 ; c1ccc(-c2cccc(-c3cc4c5ccc(N(c6ccccc6)c6ccc7c(c6)C(c6ccccc6)(c6ccccc6)c6ccccc6-7)cc5oc4c4ccccc34)c2)cc1 ; c1ccc(N(c2ccc3c(c2)C(c2ccccc2)(c2ccccc2)c2ccccc2-3)c2ccc3c(c2)oc2c4ccccc4c(-c4ccc5ccccc5c4)cc32)cc1]

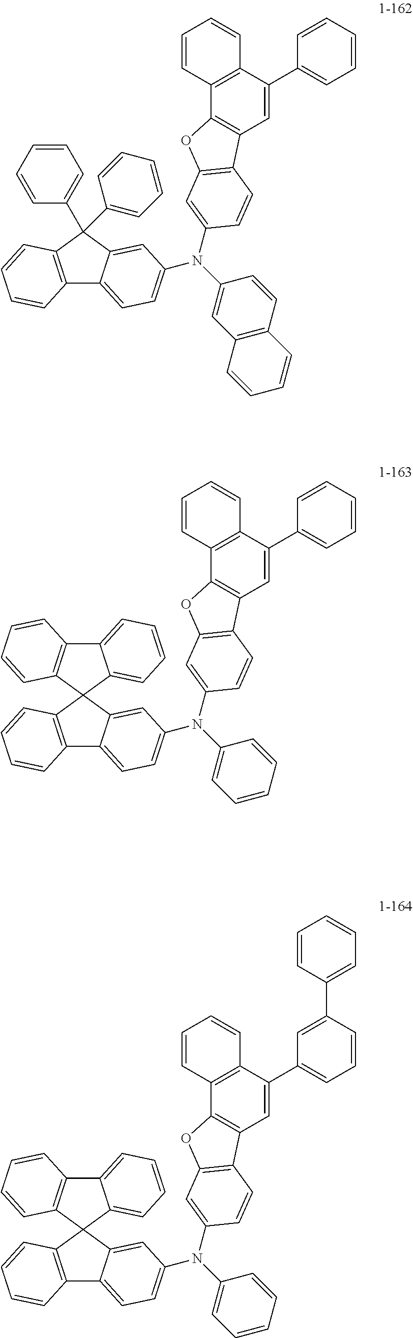 [SMILES: c1ccc(-c2cc3c4ccc(N(c5ccc6c(c5)C(c5ccccc5)(c5ccccc5)c5ccccc5-6)c5ccc6ccccc6c5)cc4oc3c3ccccc23)cc1 ; c1ccc(-c2cc3c4ccc(N(c5ccccc5)c5ccc6c(c5)C5(c7ccccc7-c7ccccc75)c5ccccc5-6)cc4oc3c3ccccc23)cc1 ; c1ccc(-c2cccc(-c3cc4c5ccc(N(c6ccccc6)c6ccc7c(c6)C6(c8ccccc8-c8ccccc86)c6ccccc6-7)cc5oc4c4ccccc34)c2)cc1]

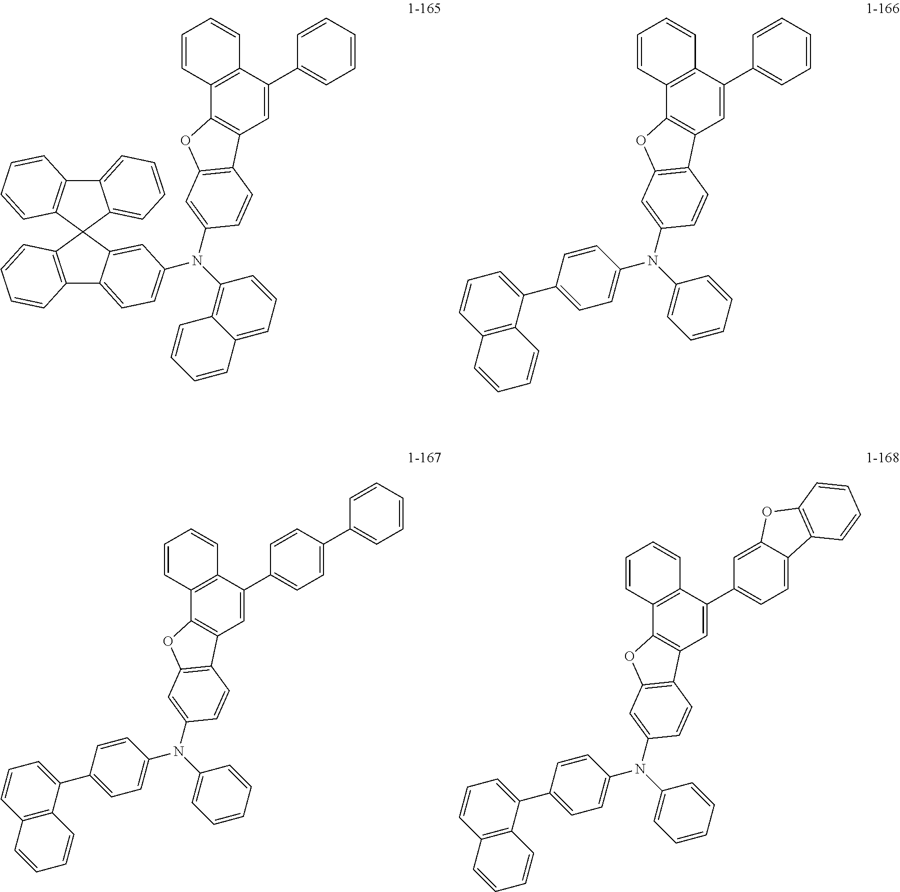 [SMILES: c1ccc(-c2cc3c4ccc(N(c5ccc6c(c5)C5(c7ccccc7-c7ccccc75)c5ccccc5-6)c5cccc6ccccc56)cc4oc3c3ccccc23)cc1 ; c1ccc(-c2cc3c4ccc(N(c5ccccc5)c5ccc(-c6cccc7ccccc67)cc5)cc4oc3c3ccccc23)cc1 ; c1ccc(-c2ccc(-c3cc4c5ccc(N(c6ccccc6)c6ccc(-c7cccc8ccccc78)cc6)cc5oc4c4ccccc34)cc2)cc1 ; c1ccc(N(c2ccc(-c3cccc4ccccc34)cc2)c2ccc3c(c2)oc2c4ccccc4c(-c4ccc5c(c4)oc4ccccc45)cc32)cc1]

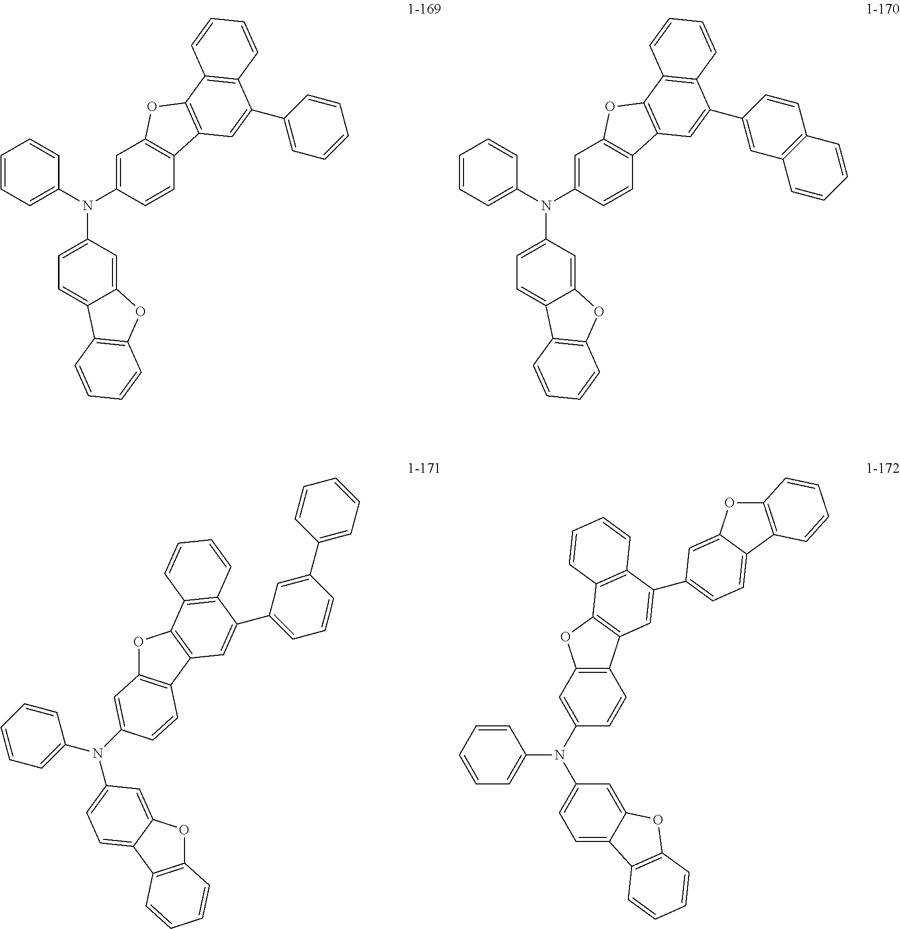 [SMILES: c1ccc(-c2cc3c4ccc(N(c5ccccc5)c5ccc6c(c5)oc5ccccc56)cc4oc3c3ccccc23)cc1 ; c1ccc(N(c2ccc3c(c2)oc2ccccc23)c2ccc3c(c2)oc2c4ccccc4c(-c4ccc5ccccc5c4)cc32)cc1 ; c1ccc(-c2cccc(-c3cc4c5ccc(N(c6ccccc6)c6ccc7c(c6)oc6ccccc67)cc5oc4c4ccccc34)c2)cc1 ; c1ccc(N(c2ccc3c(c2)oc2ccccc23)c2ccc3c(c2)oc2c4ccccc4c(-c4ccc5c(c4)oc4ccccc45)cc32)cc1]

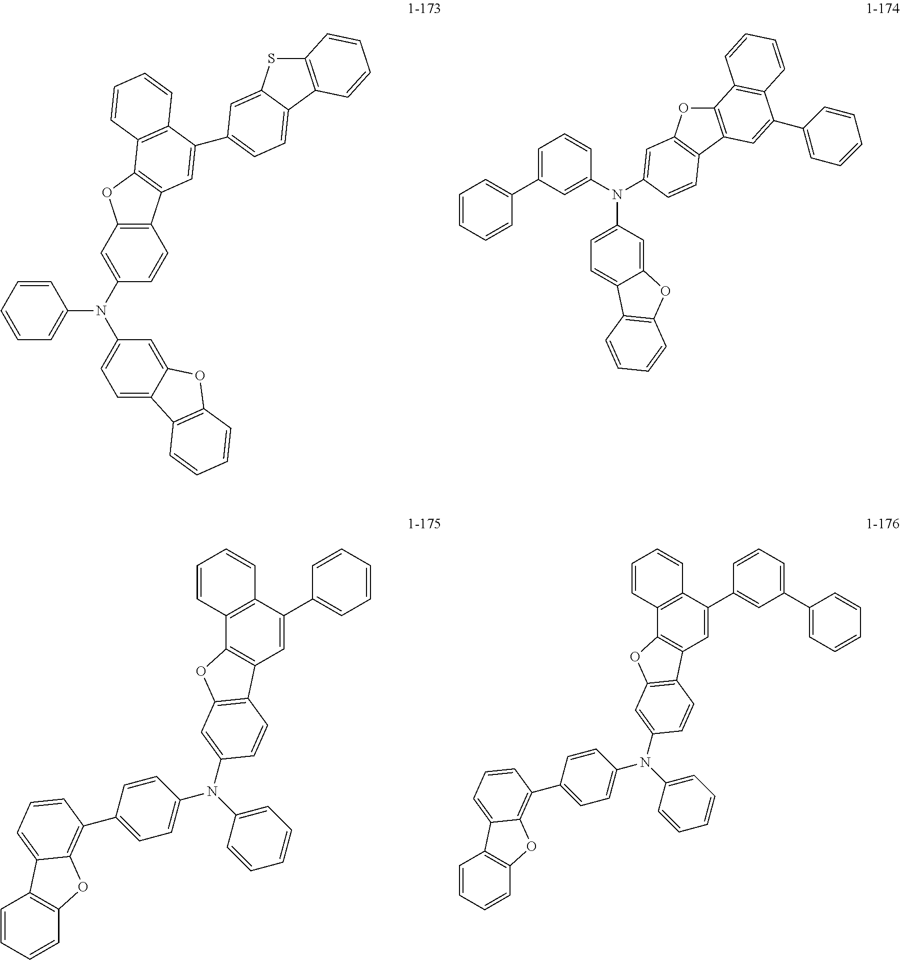 [SMILES: c1ccc(N(c2ccc3c(c2)oc2ccccc23)c2ccc3c(c2)oc2c4ccccc4c(-c4ccc5c(c4)sc4ccccc45)cc32)cc1 ; c1ccc(-c2cccc(N(c3ccc4c(c3)oc3ccccc34)c3ccc4c(c3)oc3c5ccccc5c(-c5ccccc5)cc43)c2)cc1 ; c1ccc(-c2cc3c4ccc(N(c5ccccc5)c5ccc(-c6cccc7c6oc6ccccc67)cc5)cc4oc3c3ccccc23)cc1 ; c1ccc(-c2cccc(-c3cc4c5ccc(N(c6ccccc6)c6ccc(-c7cccc8c7oc7ccccc78)cc6)cc5oc4c4ccccc34)c2)cc1]

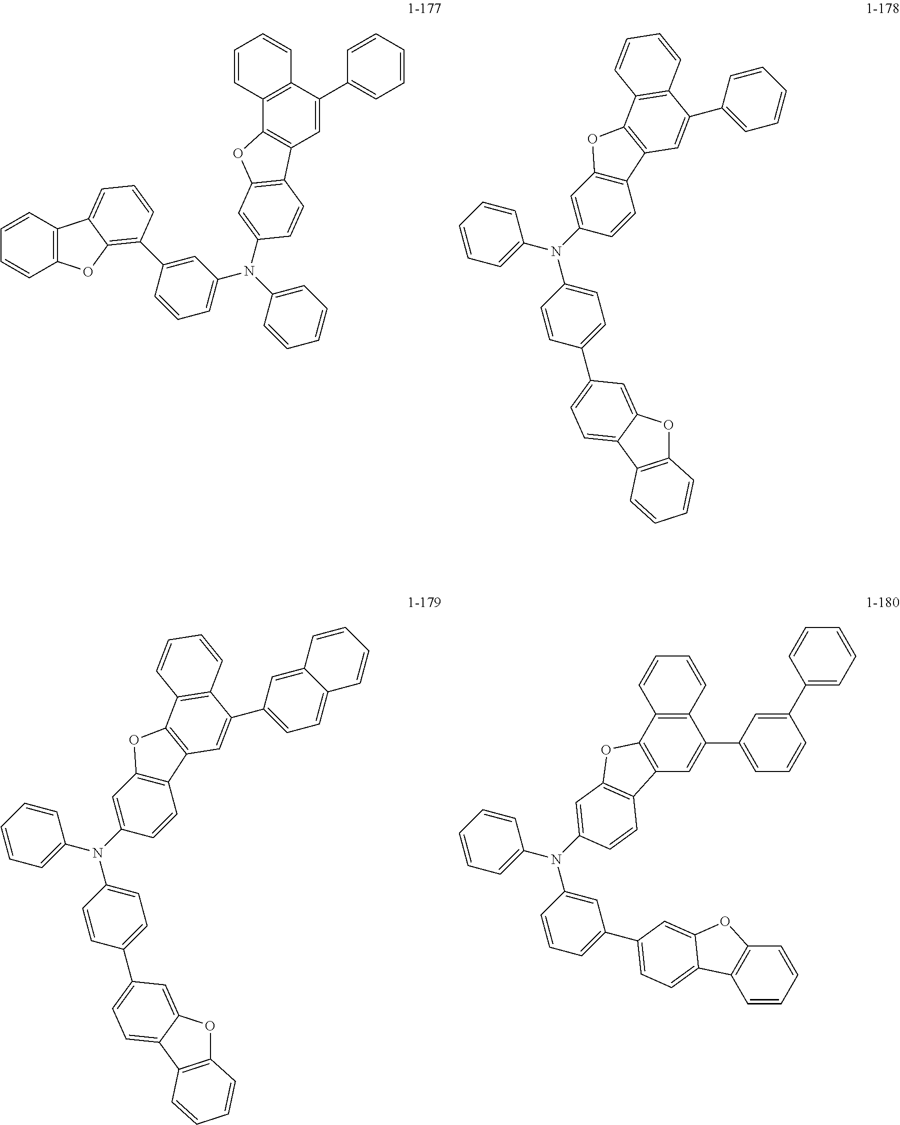 [SMILES: c1ccc(-c2cc3c4ccc(N(c5ccccc5)c5cccc(-c6cccc7c6oc6ccccc67)c5)cc4oc3c3ccccc23)cc1 ; c1ccc(-c2cc3c4ccc(N(c5ccccc5)c5ccc(-c6ccc7c(c6)oc6ccccc67)cc5)cc4oc3c3ccccc23)cc1 ; c1ccc(N(c2ccc(-c3ccc4c(c3)oc3ccccc34)cc2)c2ccc3c(c2)oc2c4ccccc4c(-c4ccc5ccccc5c4)cc32)cc1 ; c1ccc(-c2cccc(-c3cc4c5ccc(N(c6ccccc6)c6cccc(-c7ccc8c(c7)oc7ccccc78)c6)cc5oc4c4ccccc34)c2)cc1]

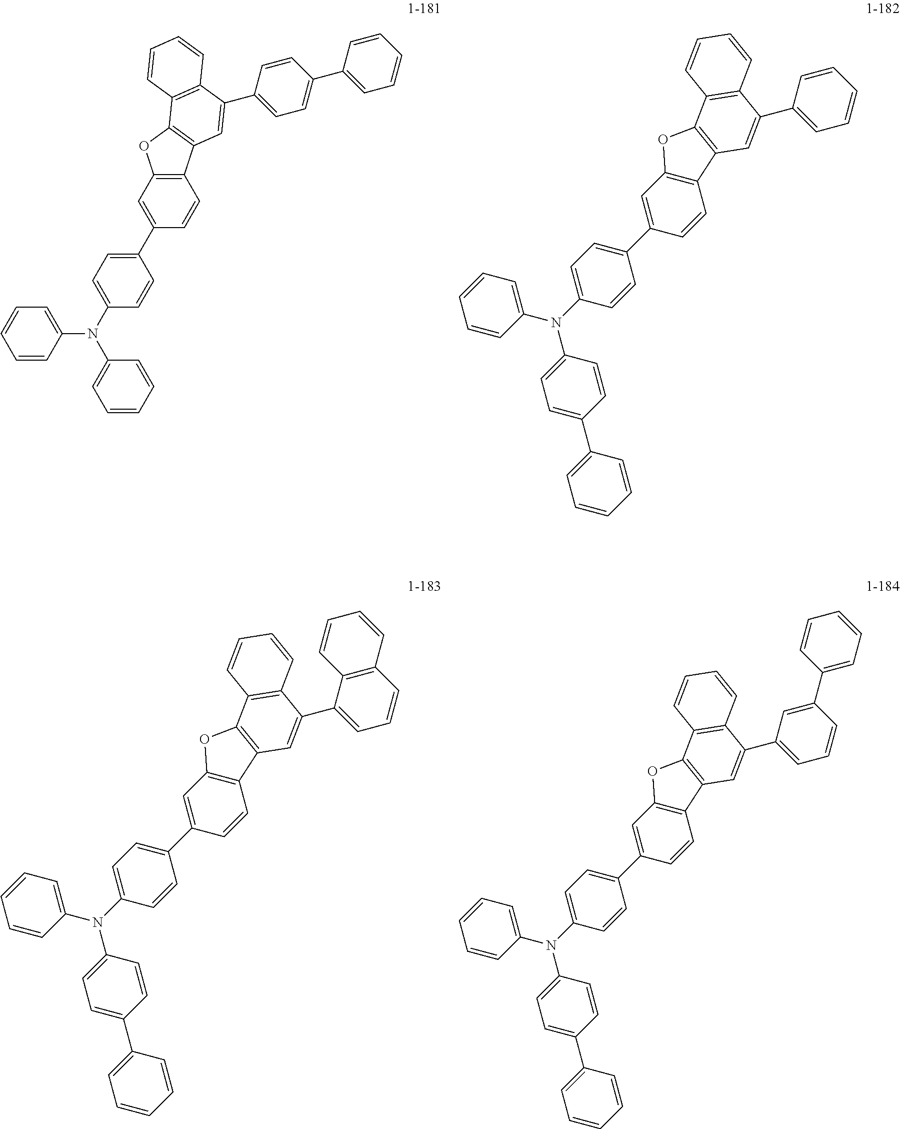 [SMILES: c1ccc(-c2ccc(-c3cc4c5ccc(-c6ccc(N(c7ccccc7)c7ccccc7)cc6)cc5oc4c4ccccc34)cc2)cc1 ; c1ccc(-c2ccc(N(c3ccccc3)c3ccc(-c4ccc5c(c4)oc4c6ccccc6c(-c6ccccc6)cc54)cc3)cc2)cc1 ; c1ccc(-c2ccc(N(c3ccccc3)c3ccc(-c4ccc5c(c4)oc4c6ccccc6c(-c6cccc7ccccc67)cc54)cc3)cc2)cc1 ; c1ccc(-c2ccc(N(c3ccccc3)c3ccc(-c4ccc5c(c4)oc4c6ccccc6c(-c6cccc(-c7ccccc7)c6)cc54)cc3)cc2)cc1]

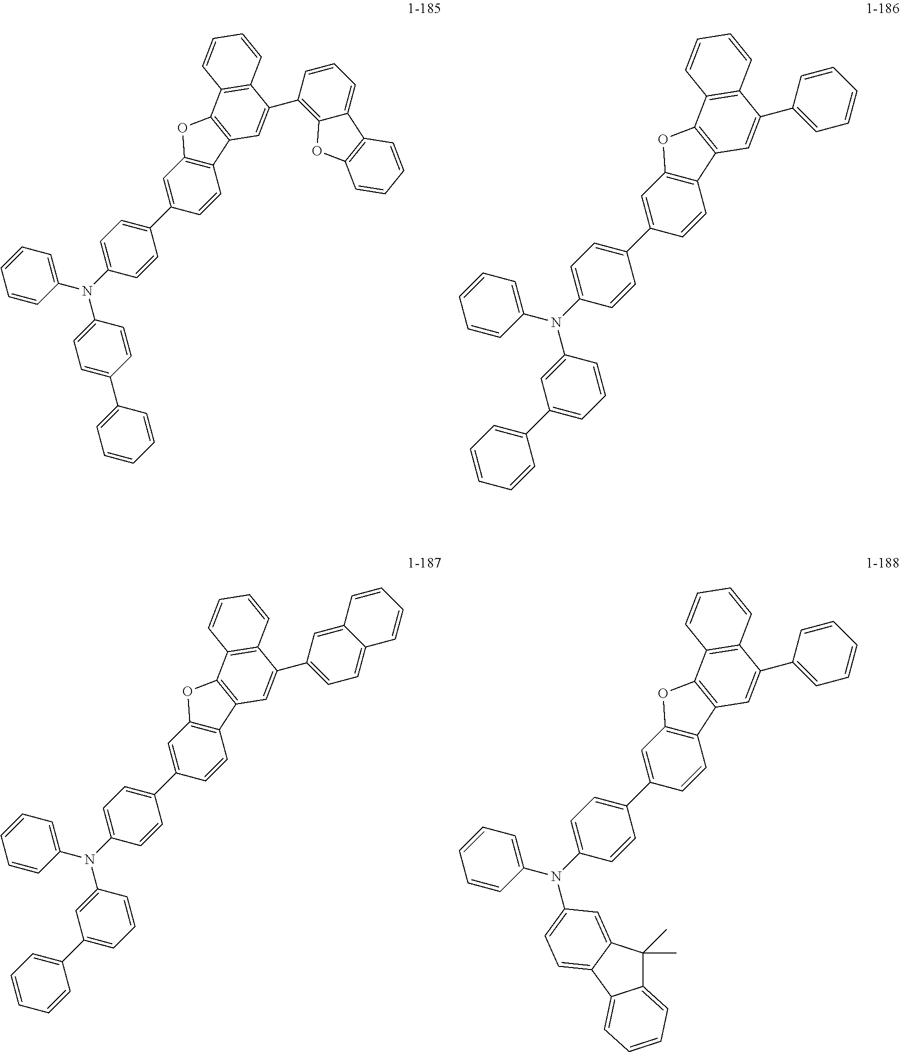 [SMILES: c1ccc(-c2ccc(N(c3ccccc3)c3ccc(-c4ccc5c(c4)oc4c6ccccc6c(-c6cccc7c6oc6ccccc67)cc54)cc3)cc2)cc1 ; c1ccc(-c2cccc(N(c3ccccc3)c3ccc(-c4ccc5c(c4)oc4c6ccccc6c(-c6ccccc6)cc54)cc3)c2)cc1 ; c1ccc(-c2cccc(N(c3ccccc3)c3ccc(-c4ccc5c(c4)oc4c6ccccc6c(-c6ccc7ccccc7c6)cc54)cc3)c2)cc1 ; CC1(C)c2ccccc2-c2ccc(N(c3ccccc3)c3ccc(-c4ccc5c(c4)oc4c6ccccc6c(-c6ccccc6)cc54)cc3)cc21]

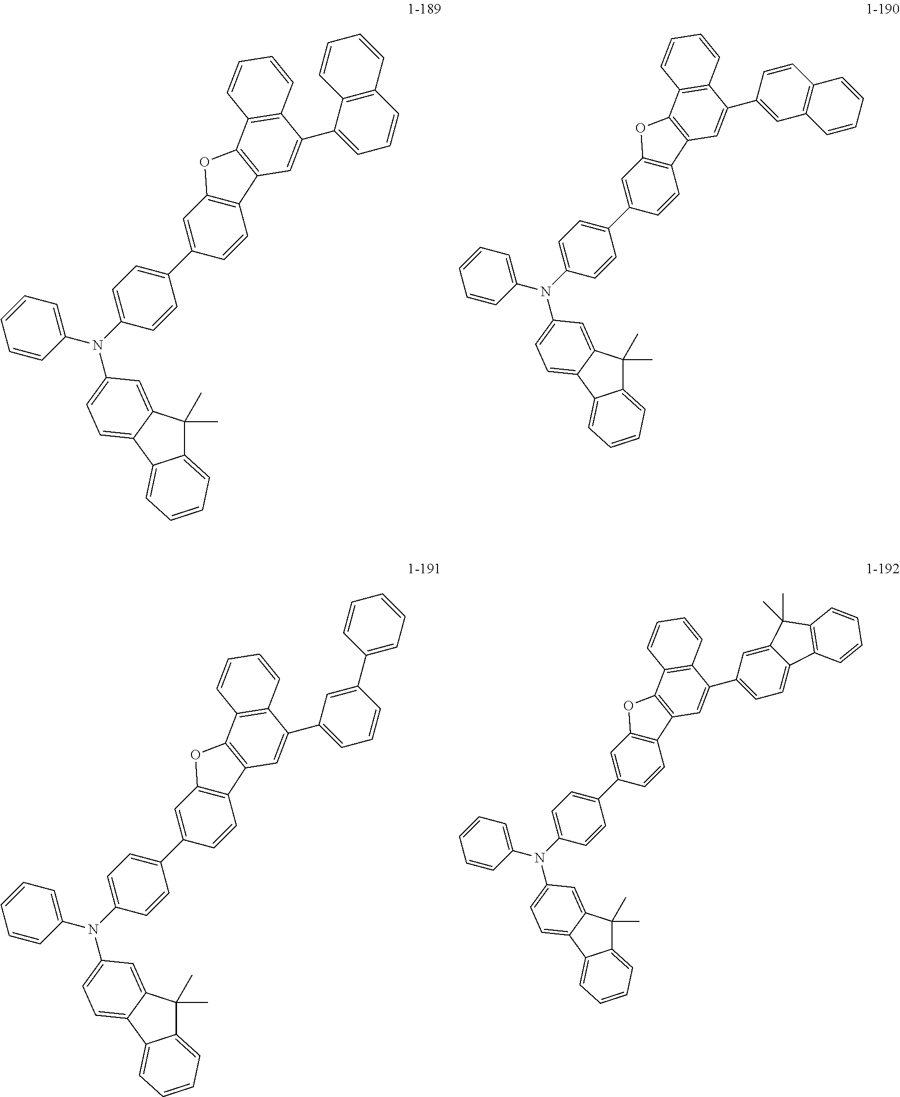 [SMILES: CC1(C)c2ccccc2-c2ccc(N(c3ccccc3)c3ccc(-c4ccc5c(c4)oc4c6ccccc6c(-c6cccc7ccccc67)cc54)cc3)cc21 ; CC1(C)c2ccccc2-c2ccc(N(c3ccccc3)c3ccc(-c4ccc5c(c4)oc4c6ccccc6c(-c6ccc7ccccc7c6)cc54)cc3)cc21 ; CC1(C)c2ccccc2-c2ccc(N(c3ccccc3)c3ccc(-c4ccc5c(c4)oc4c6ccccc6c(-c6cccc(-c7ccccc7)c6)cc54)cc3)cc21 ; CC1(C)c2ccccc2-c2ccc(-c3cc4c5ccc(-c6ccc(N(c7ccccc7)c7ccc8c(c7)C(C)(C)c7ccccc7-8)cc6)cc5oc4c4ccccc34)cc21]

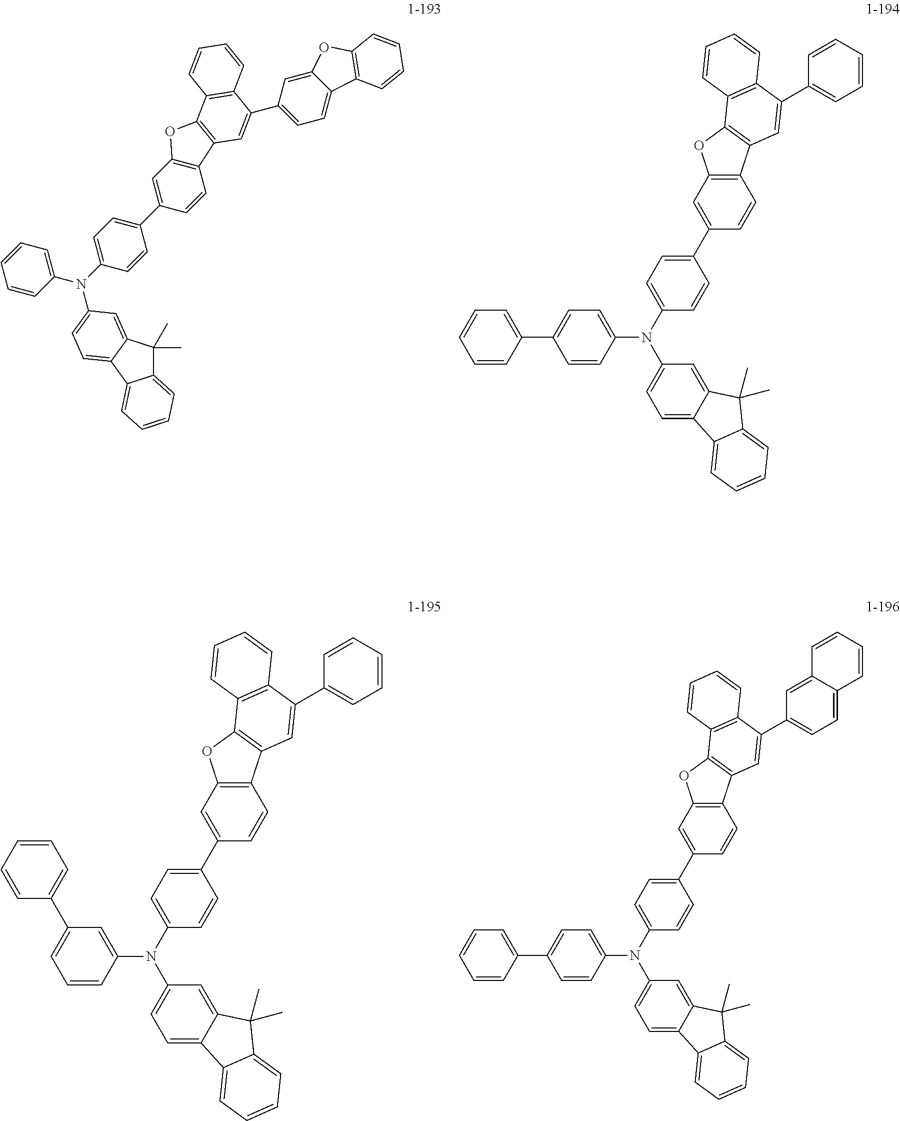 [SMILES: CC1(C)c2ccccc2-c2ccc(N(c3ccccc3)c3ccc(-c4ccc5c(c4)oc4c6ccccc6c(-c6ccc7c(c6)oc6ccccc67)cc54)cc3)cc21 ; CC1(C)c2ccccc2-c2ccc(N(c3ccc(-c4ccccc4)cc3)c3ccc(-c4ccc5c(c4)oc4c6ccccc6c(-c6ccccc6)cc54)cc3)cc21 ; CC1(C)c2ccccc2-c2ccc(N(c3ccc(-c4ccc5c(c4)oc4c6ccccc6c(-c6ccccc6)cc54)cc3)c3cccc(-c4ccccc4)c3)cc21 ; CC1(C)c2ccccc2-c2ccc(N(c3ccc(-c4ccccc4)cc3)c3ccc(-c4ccc5c(c4)oc4c6ccccc6c(-c6ccc7ccccc7c6)cc54)cc3)cc21]

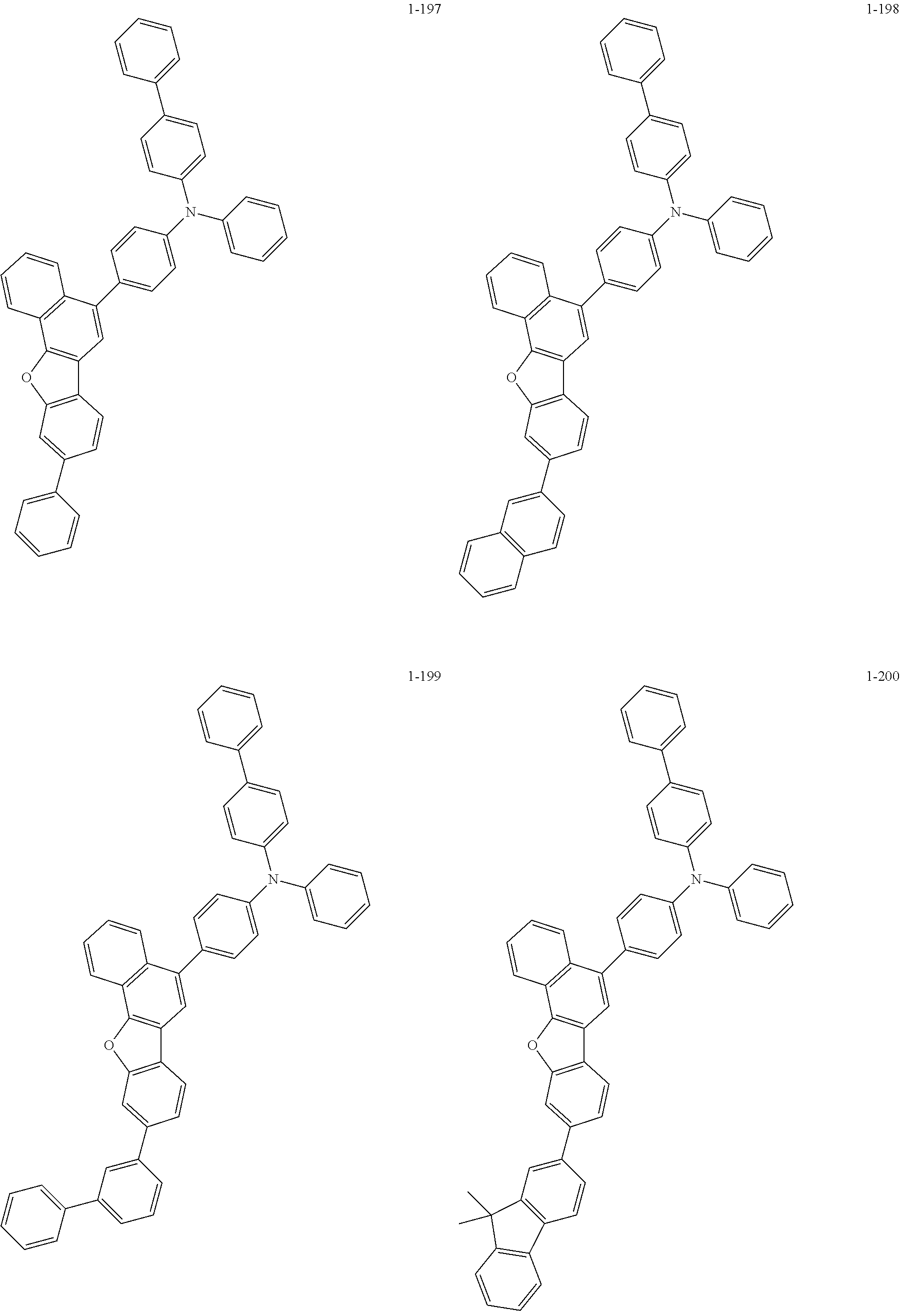 [SMILES: c1ccc(-c2ccc(N(c3ccccc3)c3ccc(-c4cc5c6ccc(-c7ccccc7)cc6oc5c5ccccc45)cc3)cc2)cc1 ; c1ccc(-c2ccc(N(c3ccccc3)c3ccc(-c4cc5c6ccc(-c7ccc8ccccc8c7)cc6oc5c5ccccc45)cc3)cc2)cc1 ; c1ccc(-c2ccc(N(c3ccccc3)c3ccc(-c4cc5c6ccc(-c7cccc(-c8ccccc8)c7)cc6oc5c5ccccc45)cc3)cc2)cc1 ; CC1(C)c2ccccc2-c2ccc(-c3ccc4c(c3)oc3c5ccccc5c(-c5ccc(N(c6ccccc6)c6ccc(-c7ccccc7)cc6)cc5)cc43)cc21]

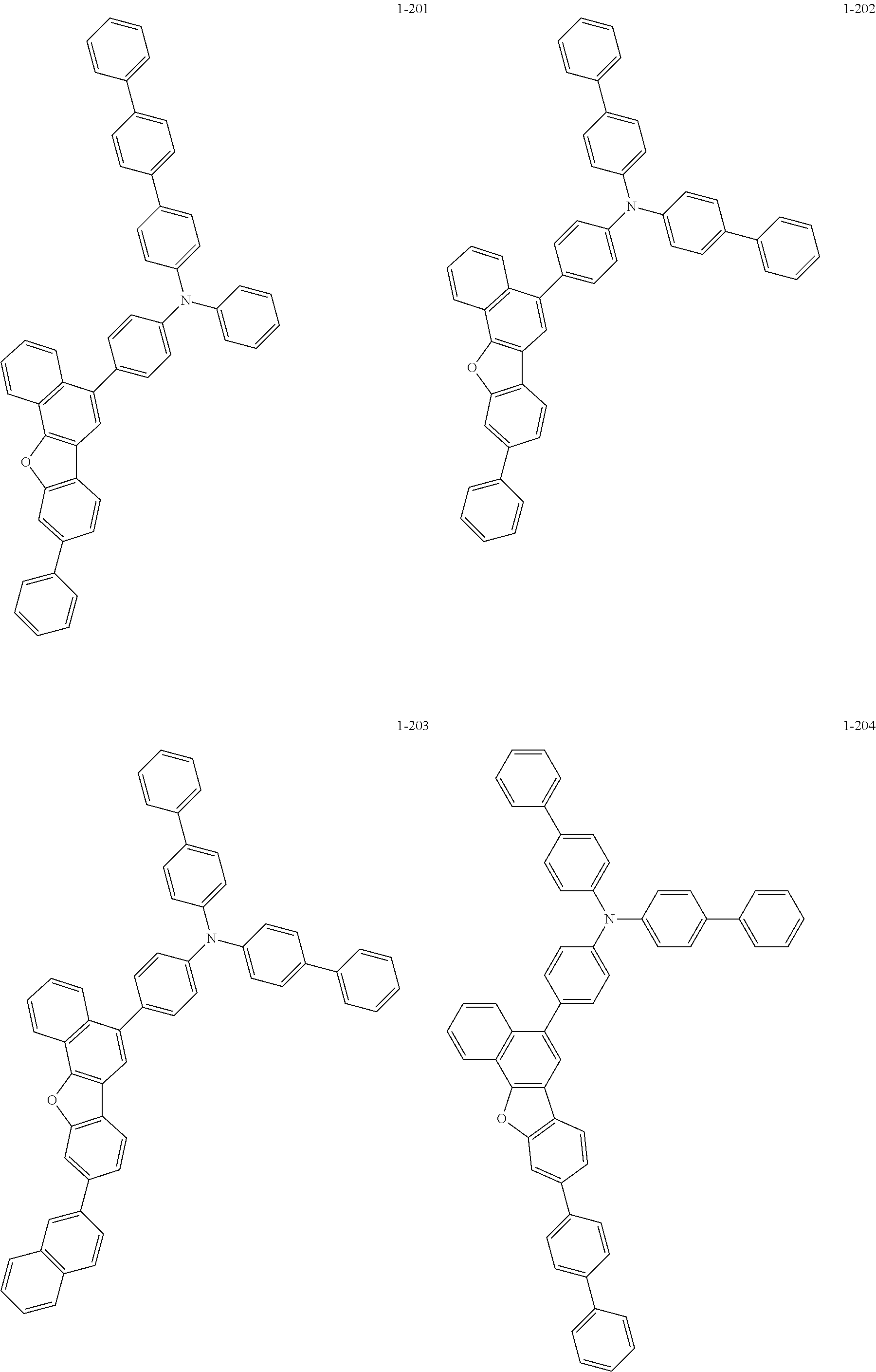 [SMILES: c1ccc(-c2ccc(-c3ccc(N(c4ccccc4)c4ccc(-c5cc6c7ccc(-c8ccccc8)cc7oc6c6ccccc56)cc4)cc3)cc2)cc1 ; c1ccc(-c2ccc(N(c3ccc(-c4ccccc4)cc3)c3ccc(-c4cc5c6ccc(-c7ccccc7)cc6oc5c5ccccc45)cc3)cc2)cc1 ; c1ccc(-c2ccc(N(c3ccc(-c4ccccc4)cc3)c3ccc(-c4cc5c6ccc(-c7ccc8ccccc8c7)cc6oc5c5ccccc45)cc3)cc2)cc1 ; c1ccc(-c2ccc(-c3ccc4c(c3)oc3c5ccccc5c(-c5ccc(N(c6ccc(-c7ccccc7)cc6)c6ccc(-c7ccccc7)cc6)cc5)cc43)cc2)cc1]

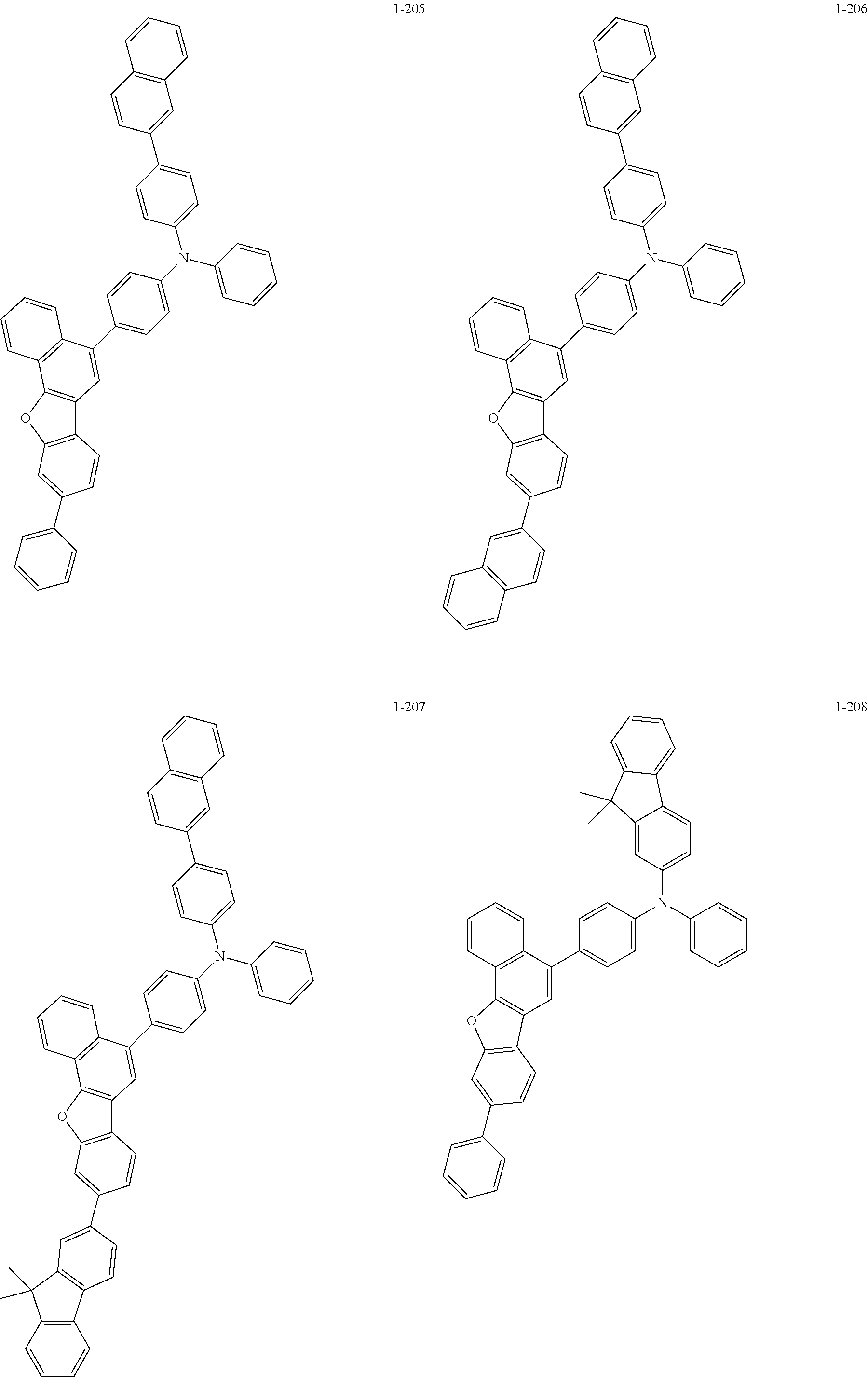 [SMILES: c1ccc(-c2ccc3c(c2)oc2c4ccccc4c(-c4ccc(N(c5ccccc5)c5ccc(-c6ccc7ccccc7c6)cc5)cc4)cc32)cc1 ; c1ccc(N(c2ccc(-c3ccc4ccccc4c3)cc2)c2ccc(-c3cc4c5ccc(-c6ccc7ccccc7c6)cc5oc4c4ccccc34)cc2)cc1 ; CC1(C)c2ccccc2-c2ccc(-c3ccc4c(c3)oc3c5ccccc5c(-c5ccc(N(c6ccccc6)c6ccc(-c7ccc8ccccc8c7)cc6)cc5)cc43)cc21 ; CC1(C)c2ccccc2-c2ccc(N(c3ccccc3)c3ccc(-c4cc5c6ccc(-c7ccccc7)cc6oc5c5ccccc45)cc3)cc21]

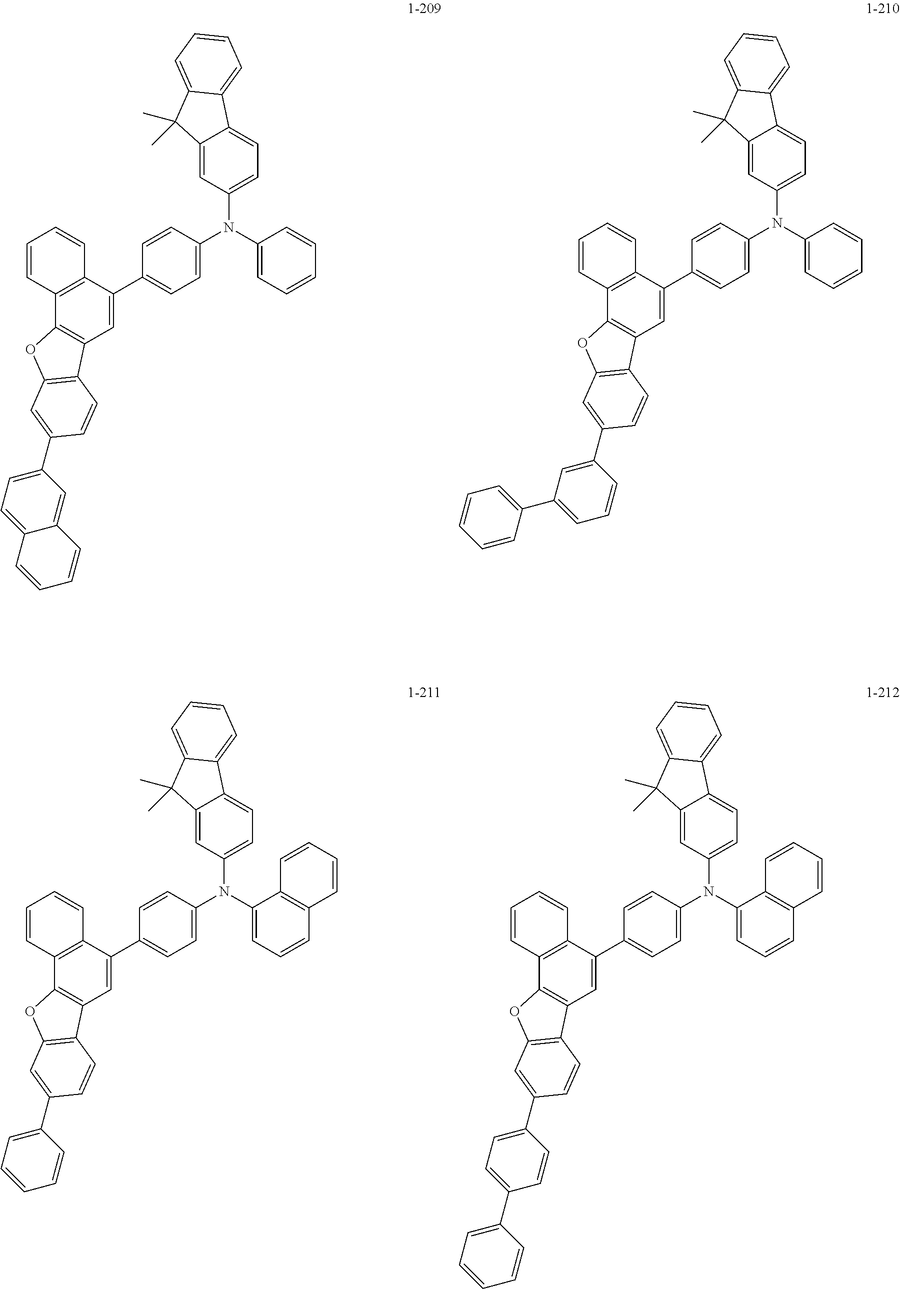 [SMILES: CC1(C)c2ccccc2-c2ccc(N(c3ccccc3)c3ccc(-c4cc5c6ccc(-c7ccc8ccccc8c7)cc6oc5c5ccccc45)cc3)cc21 ; CC1(C)c2ccccc2-c2ccc(N(c3ccccc3)c3ccc(-c4cc5c6ccc(-c7cccc(-c8ccccc8)c7)cc6oc5c5ccccc45)cc3)cc21 ; CC1(C)c2ccccc2-c2ccc(N(c3ccc(-c4cc5c6ccc(-c7ccccc7)cc6oc5c5ccccc45)cc3)c3cccc4ccccc34)cc21 ; CC1(C)c2ccccc2-c2ccc(N(c3ccc(-c4cc5c6ccc(-c7ccc(-c8ccccc8)cc7)cc6oc5c5ccccc45)cc3)c3cccc4ccccc34)cc21]

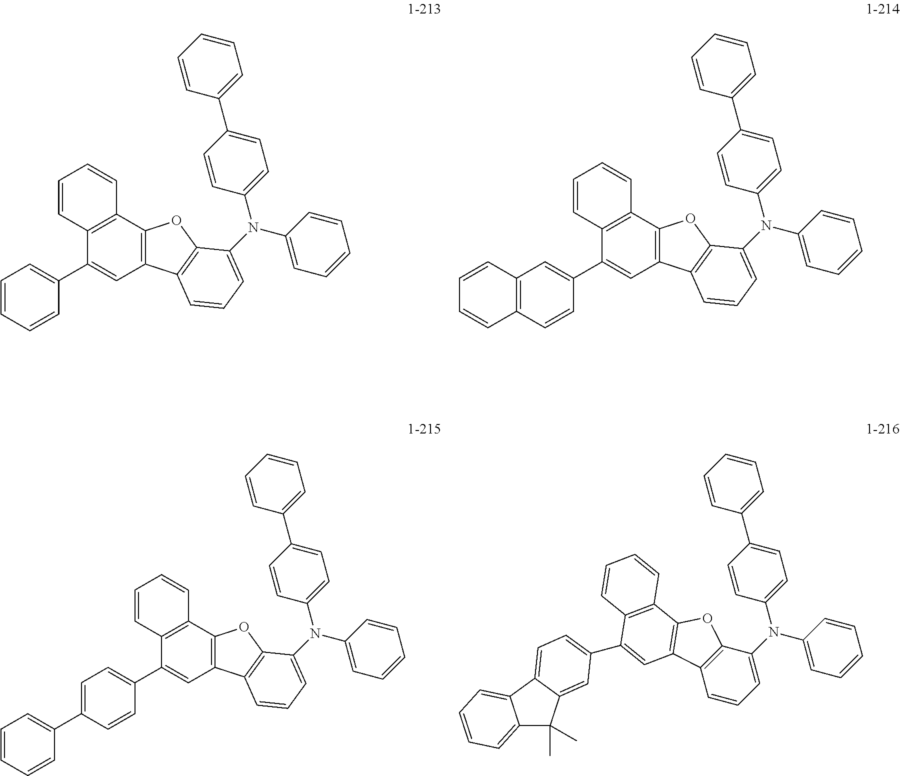 [SMILES: c1ccc(-c2ccc(N(c3ccccc3)c3cccc4c3oc3c5ccccc5c(-c5ccccc5)cc43)cc2)cc1 ; c1ccc(-c2ccc(N(c3ccccc3)c3cccc4c3oc3c5ccccc5c(-c5ccc6ccccc6c5)cc43)cc2)cc1 ; c1ccc(-c2ccc(-c3cc4c5cccc(N(c6ccccc6)c6ccc(-c7ccccc7)cc6)c5oc4c4ccccc34)cc2)cc1 ; CC1(C)c2ccccc2-c2ccc(-c3cc4c5cccc(N(c6ccccc6)c6ccc(-c7ccccc7)cc6)c5oc4c4ccccc34)cc21]

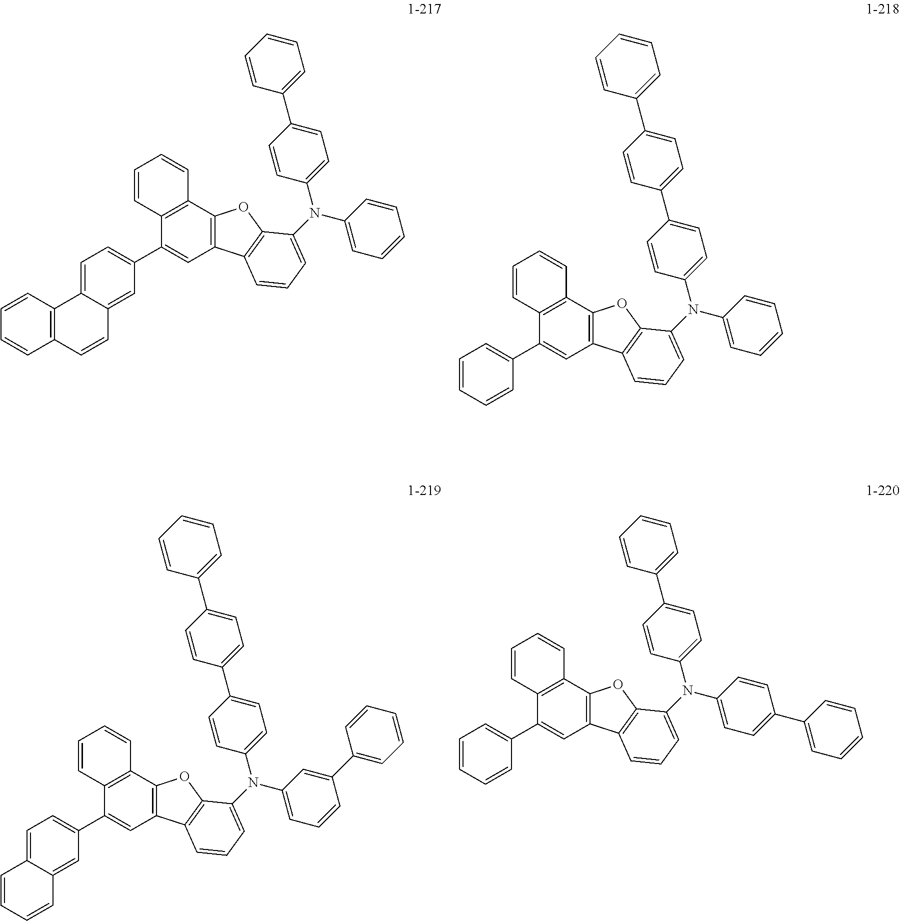 [SMILES: c1ccc(-c2ccc(N(c3ccccc3)c3cccc4c3oc3c5ccccc5c(-c5ccc6c(ccc7ccccc76)c5)cc43)cc2)cc1 ; c1ccc(-c2ccc(-c3ccc(N(c4ccccc4)c4cccc5c4oc4c6ccccc6c(-c6ccccc6)cc54)cc3)cc2)cc1 ; c1ccc(-c2ccc(-c3ccc(N(c4cccc(-c5ccccc5)c4)c4cccc5c4oc4c6ccccc6c(-c6ccc7ccccc7c6)cc54)cc3)cc2)cc1 ; c1ccc(-c2ccc(N(c3ccc(-c4ccccc4)cc3)c3cccc4c3oc3c5ccccc5c(-c5ccccc5)cc43)cc2)cc1]

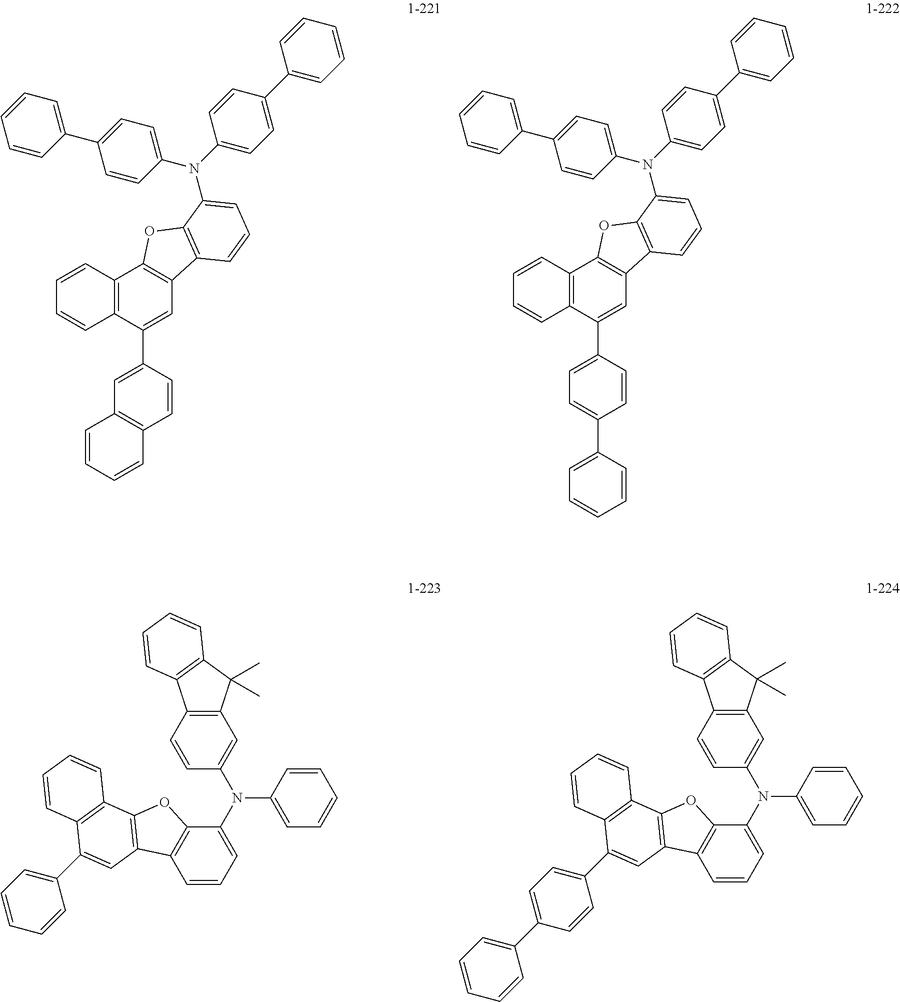 [SMILES: c1ccc(-c2ccc(N(c3ccc(-c4ccccc4)cc3)c3cccc4c3oc3c5ccccc5c(-c5ccc6ccccc6c5)cc43)cc2)cc1 ; c1ccc(-c2ccc(-c3cc4c5cccc(N(c6ccc(-c7ccccc7)cc6)c6ccc(-c7ccccc7)cc6)c5oc4c4ccccc34)cc2)cc1 ; CC1(C)c2ccccc2-c2ccc(N(c3ccccc3)c3cccc4c3oc3c5ccccc5c(-c5ccccc5)cc43)cc21 ; CC1(C)c2ccccc2-c2ccc(N(c3ccccc3)c3cccc4c3oc3c5ccccc5c(-c5ccc(-c6ccccc6)cc5)cc43)cc21]

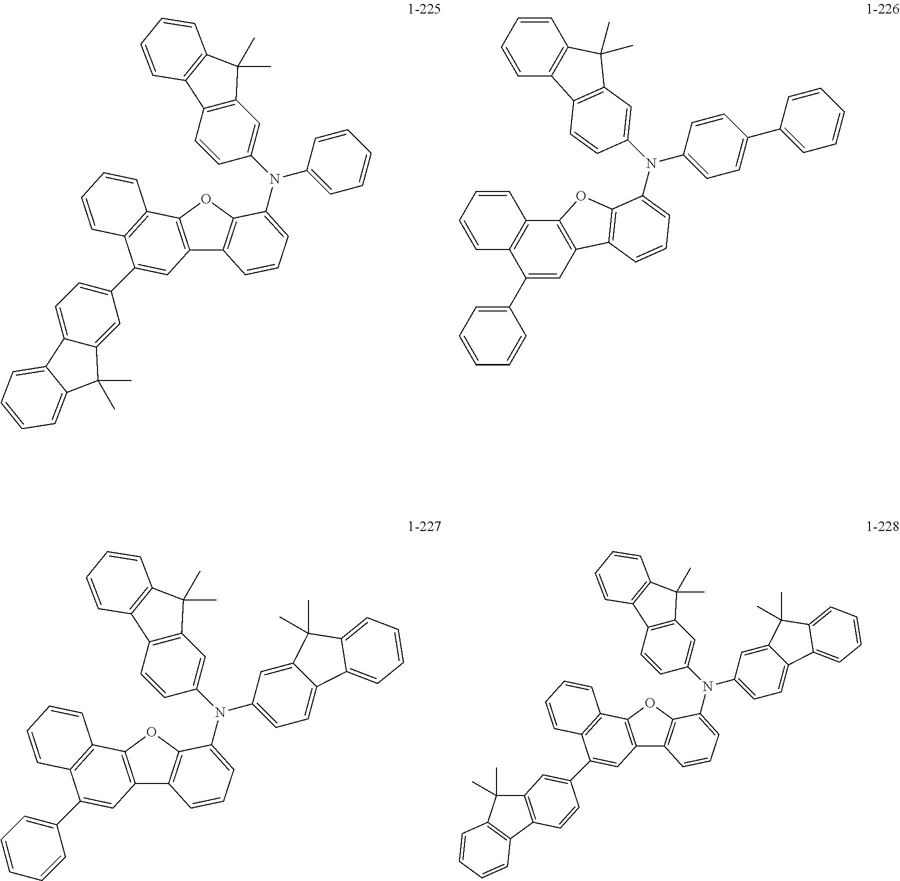 [SMILES: CC1(C)c2ccccc2-c2ccc(-c3cc4c5cccc(N(c6ccccc6)c6ccc7c(c6)C(C)(C)c6ccccc6-7)c5oc4c4ccccc34)cc21 ; CC1(C)c2ccccc2-c2ccc(N(c3ccc(-c4ccccc4)cc3)c3cccc4c3oc3c5ccccc5c(-c5ccccc5)cc43)cc21 ; CC1(C)c2ccccc2-c2ccc(N(c3ccc4c(c3)C(C)(C)c3ccccc3-4)c3cccc4c3oc3c5ccccc5c(-c5ccccc5)cc43)cc21 ; CC1(C)c2ccccc2-c2ccc(-c3cc4c5cccc(N(c6ccc7c(c6)C(C)(C)c6ccccc6-7)c6ccc7c(c6)C(C)(C)c6ccccc6-7)c5oc4c4ccccc34)cc21]

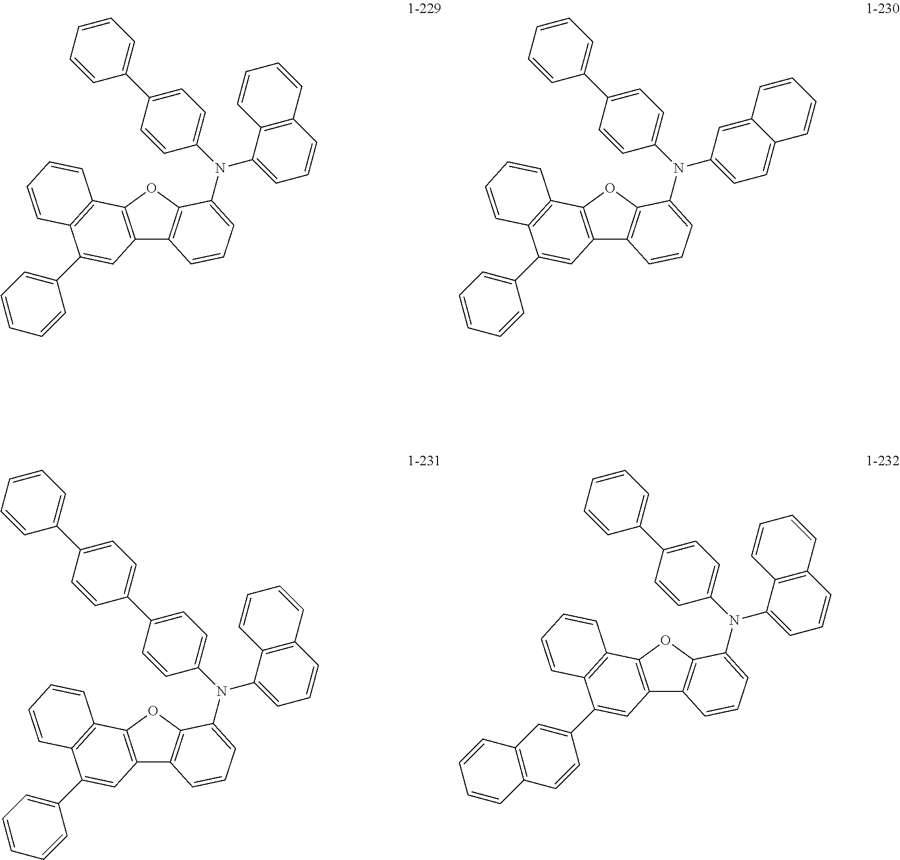 [SMILES: c1ccc(-c2ccc(N(c3cccc4ccccc34)c3cccc4c3oc3c5ccccc5c(-c5ccccc5)cc43)cc2)cc1 ; c1ccc(-c2ccc(N(c3ccc4ccccc4c3)c3cccc4c3oc3c5ccccc5c(-c5ccccc5)cc43)cc2)cc1 ; c1ccc(-c2ccc(-c3ccc(N(c4cccc5ccccc45)c4cccc5c4oc4c6ccccc6c(-c6ccccc6)cc54)cc3)cc2)cc1 ; c1ccc(-c2ccc(N(c3cccc4ccccc34)c3cccc4c3oc3c5ccccc5c(-c5ccc6ccccc6c5)cc43)cc2)cc1]

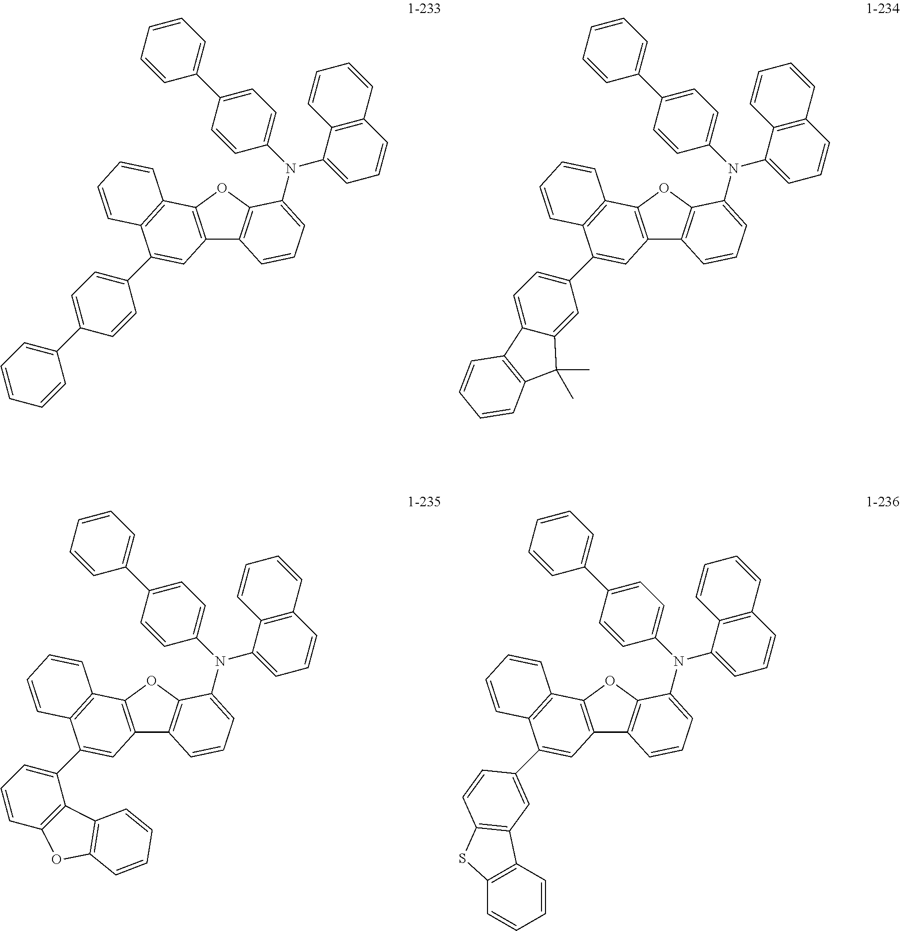 [SMILES: c1ccc(-c2ccc(-c3cc4c5cccc(N(c6ccc(-c7ccccc7)cc6)c6cccc7ccccc67)c5oc4c4ccccc34)cc2)cc1 ; CC1(C)c2ccccc2-c2ccc(-c3cc4c5cccc(N(c6ccc(-c7ccccc7)cc6)c6cccc7ccccc67)c5oc4c4ccccc34)cc21 ; c1ccc(-c2ccc(N(c3cccc4ccccc34)c3cccc4c3oc3c5ccccc5c(-c5cccc6oc7ccccc7c56)cc43)cc2)cc1 ; c1ccc(-c2ccc(N(c3cccc4ccccc34)c3cccc4c3oc3c5ccccc5c(-c5ccc6sc7ccccc7c6c5)cc43)cc2)cc1]

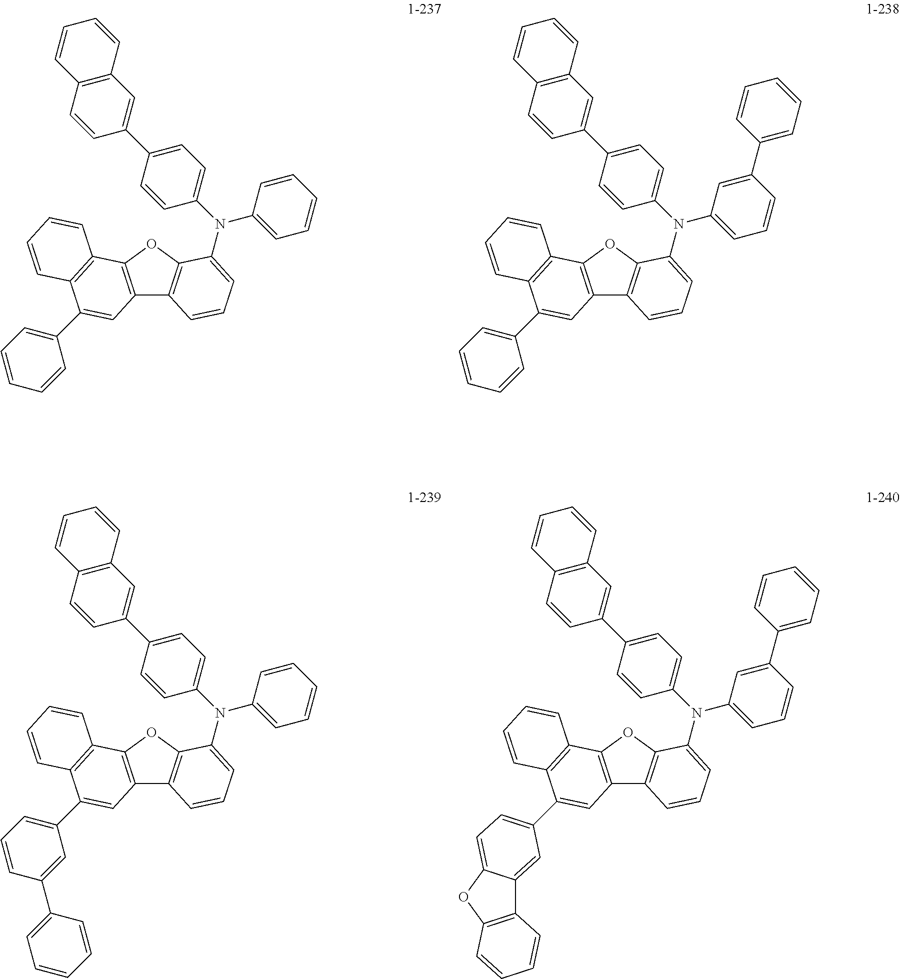 [SMILES: c1ccc(-c2cc3c4cccc(N(c5ccccc5)c5ccc(-c6ccc7ccccc7c6)cc5)c4oc3c3ccccc23)cc1 ; c1ccc(-c2cccc(N(c3ccc(-c4ccc5ccccc5c4)cc3)c3cccc4c3oc3c5ccccc5c(-c5ccccc5)cc43)c2)cc1 ; c1ccc(-c2cccc(-c3cc4c5cccc(N(c6ccccc6)c6ccc(-c7ccc8ccccc8c7)cc6)c5oc4c4ccccc34)c2)cc1 ; c1ccc(-c2cccc(N(c3ccc(-c4ccc5ccccc5c4)cc3)c3cccc4c3oc3c5ccccc5c(-c5ccc6oc7ccccc7c6c5)cc43)c2)cc1]

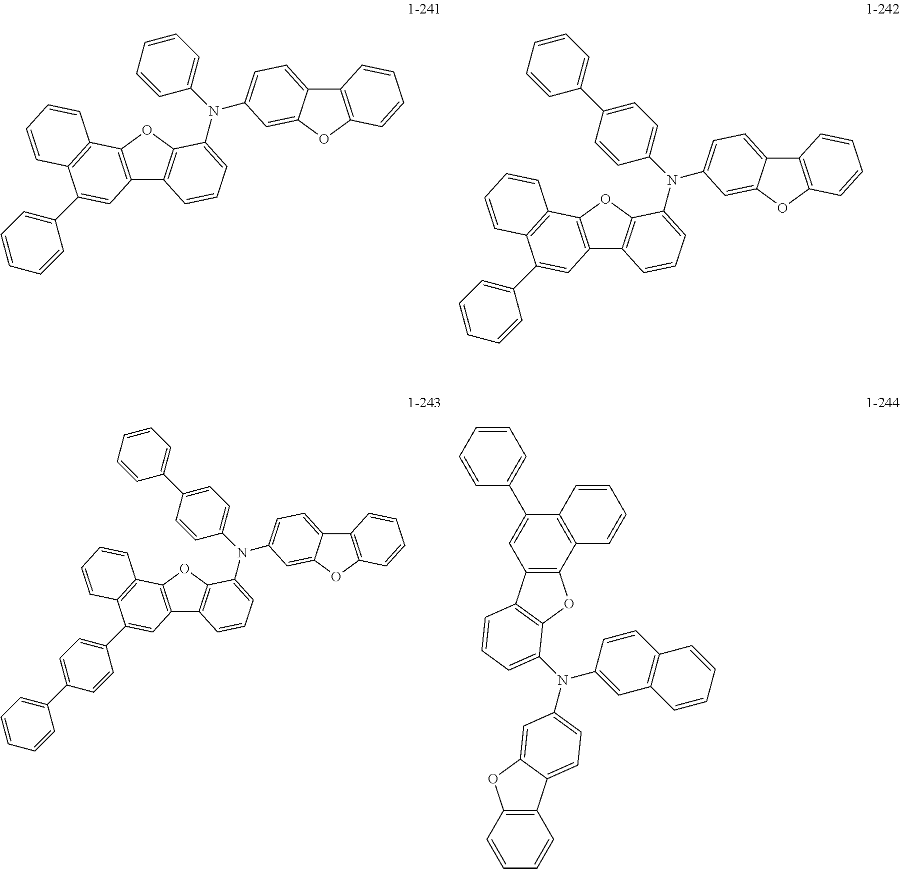 [SMILES: c1ccc(-c2cc3c4cccc(N(c5ccccc5)c5ccc6c(c5)oc5ccccc56)c4oc3c3ccccc23)cc1 ; c1ccc(-c2ccc(N(c3ccc4c(c3)oc3ccccc34)c3cccc4c3oc3c5ccccc5c(-c5ccccc5)cc43)cc2)cc1 ; c1ccc(-c2ccc(-c3cc4c5cccc(N(c6ccc(-c7ccccc7)cc6)c6ccc7c(c6)oc6ccccc67)c5oc4c4ccccc34)cc2)cc1 ; c1ccc(-c2cc3c4cccc(N(c5ccc6ccccc6c5)c5ccc6c(c5)oc5ccccc56)c4oc3c3ccccc23)cc1]

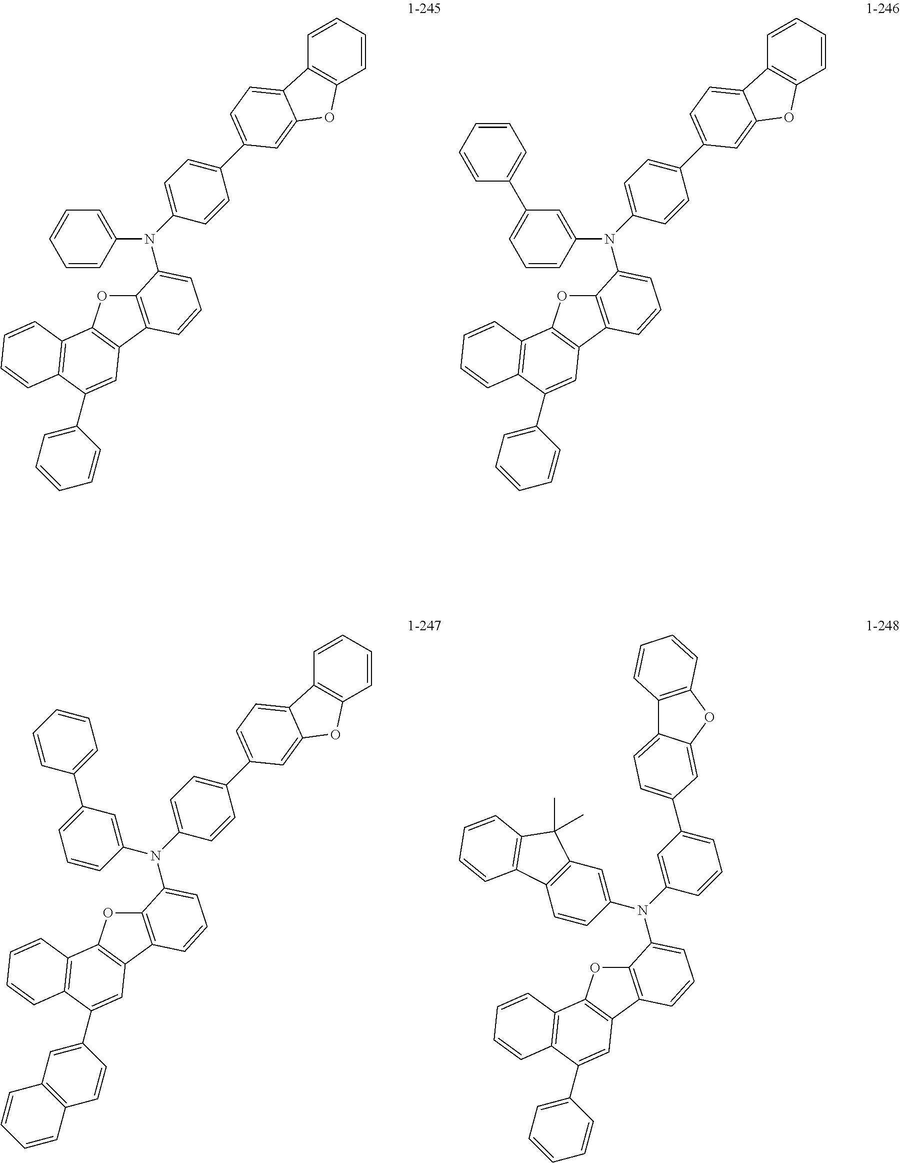 [SMILES: c1ccc(-c2cc3c4cccc(N(c5ccccc5)c5ccc(-c6ccc7c(c6)oc6ccccc67)cc5)c4oc3c3ccccc23)cc1 ; c1ccc(-c2cccc(N(c3ccc(-c4ccc5c(c4)oc4ccccc45)cc3)c3cccc4c3oc3c5ccccc5c(-c5ccccc5)cc43)c2)cc1 ; c1ccc(-c2cccc(N(c3ccc(-c4ccc5c(c4)oc4ccccc45)cc3)c3cccc4c3oc3c5ccccc5c(-c5ccc6ccccc6c5)cc43)c2)cc1 ; CC1(C)c2ccccc2-c2ccc(N(c3cccc(-c4ccc5c(c4)oc4ccccc45)c3)c3cccc4c3oc3c5ccccc5c(-c5ccccc5)cc43)cc21]

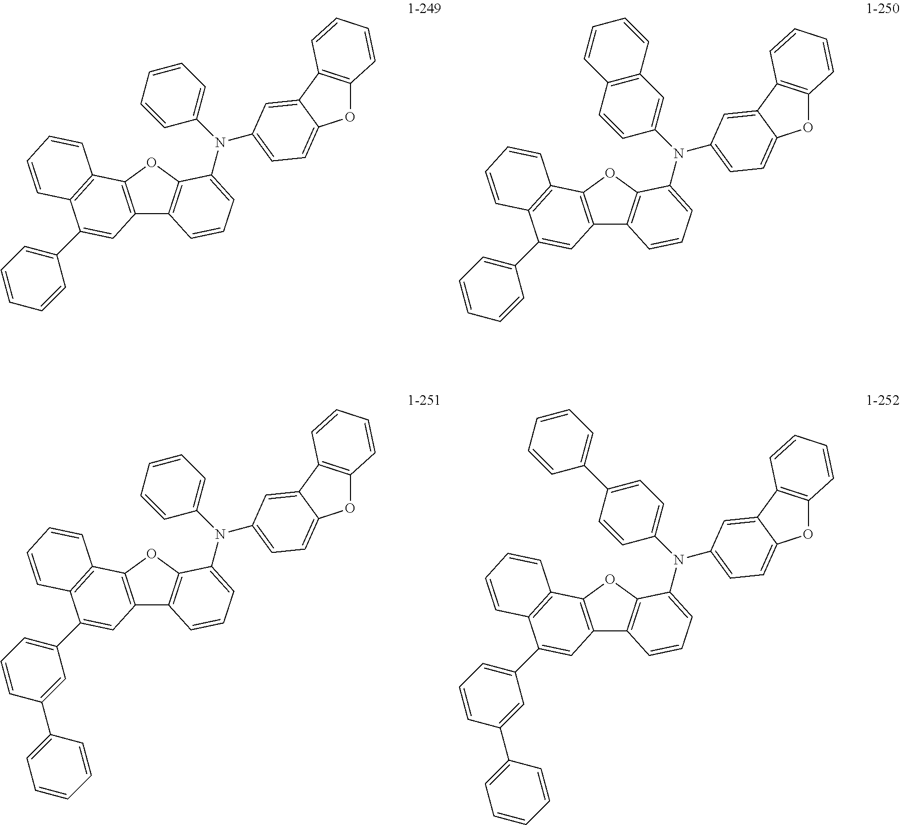 [SMILES: c1ccc(-c2cc3c4cccc(N(c5ccccc5)c5ccc6oc7ccccc7c6c5)c4oc3c3ccccc23)cc1 ; c1ccc(-c2cc3c4cccc(N(c5ccc6ccccc6c5)c5ccc6oc7ccccc7c6c5)c4oc3c3ccccc23)cc1 ; c1ccc(-c2cccc(-c3cc4c5cccc(N(c6ccccc6)c6ccc7oc8ccccc8c7c6)c5oc4c4ccccc34)c2)cc1 ; c1ccc(-c2ccc(N(c3ccc4oc5ccccc5c4c3)c3cccc4c3oc3c5ccccc5c(-c5cccc(-c6ccccc6)c5)cc43)cc2)cc1]

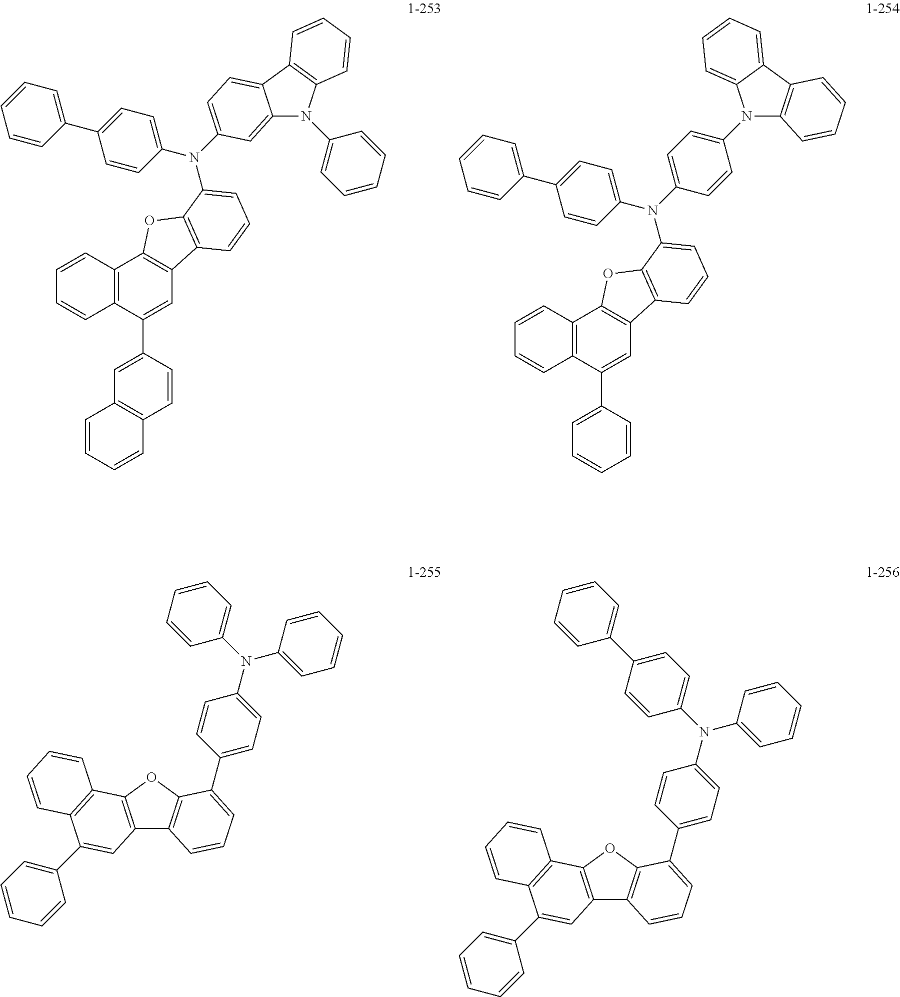 [SMILES: c1ccc(-c2ccc(N(c3ccc4c5ccccc5n(-c5ccccc5)c4c3)c3cccc4c3oc3c5ccccc5c(-c5ccc6ccccc6c5)cc43)cc2)cc1 ; c1ccc(-c2ccc(N(c3ccc(-n4c5ccccc5c5ccccc54)cc3)c3cccc4c3oc3c5ccccc5c(-c5ccccc5)cc43)cc2)cc1 ; c1ccc(-c2cc3c4cccc(-c5ccc(N(c6ccccc6)c6ccccc6)cc5)c4oc3c3ccccc23)cc1 ; c1ccc(-c2ccc(N(c3ccccc3)c3ccc(-c4cccc5c4oc4c6ccccc6c(-c6ccccc6)cc54)cc3)cc2)cc1]

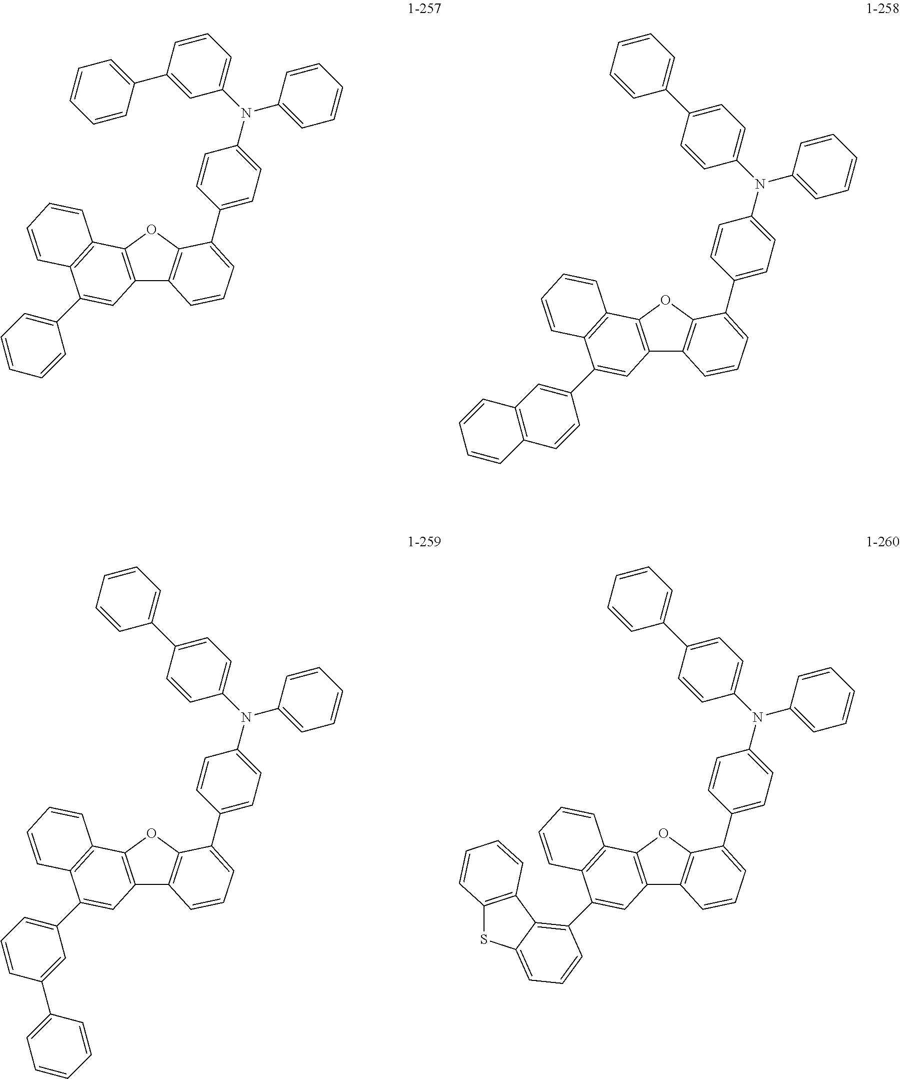 [SMILES: c1ccc(-c2cccc(N(c3ccccc3)c3ccc(-c4cccc5c4oc4c6ccccc6c(-c6ccccc6)cc54)cc3)c2)cc1 ; c1ccc(-c2ccc(N(c3ccccc3)c3ccc(-c4cccc5c4oc4c6ccccc6c(-c6ccc7ccccc7c6)cc54)cc3)cc2)cc1 ; c1ccc(-c2ccc(N(c3ccccc3)c3ccc(-c4cccc5c4oc4c6ccccc6c(-c6cccc(-c7ccccc7)c6)cc54)cc3)cc2)cc1 ; c1ccc(-c2ccc(N(c3ccccc3)c3ccc(-c4cccc5c4oc4c6ccccc6c(-c6cccc7sc8ccccc8c67)cc54)cc3)cc2)cc1]

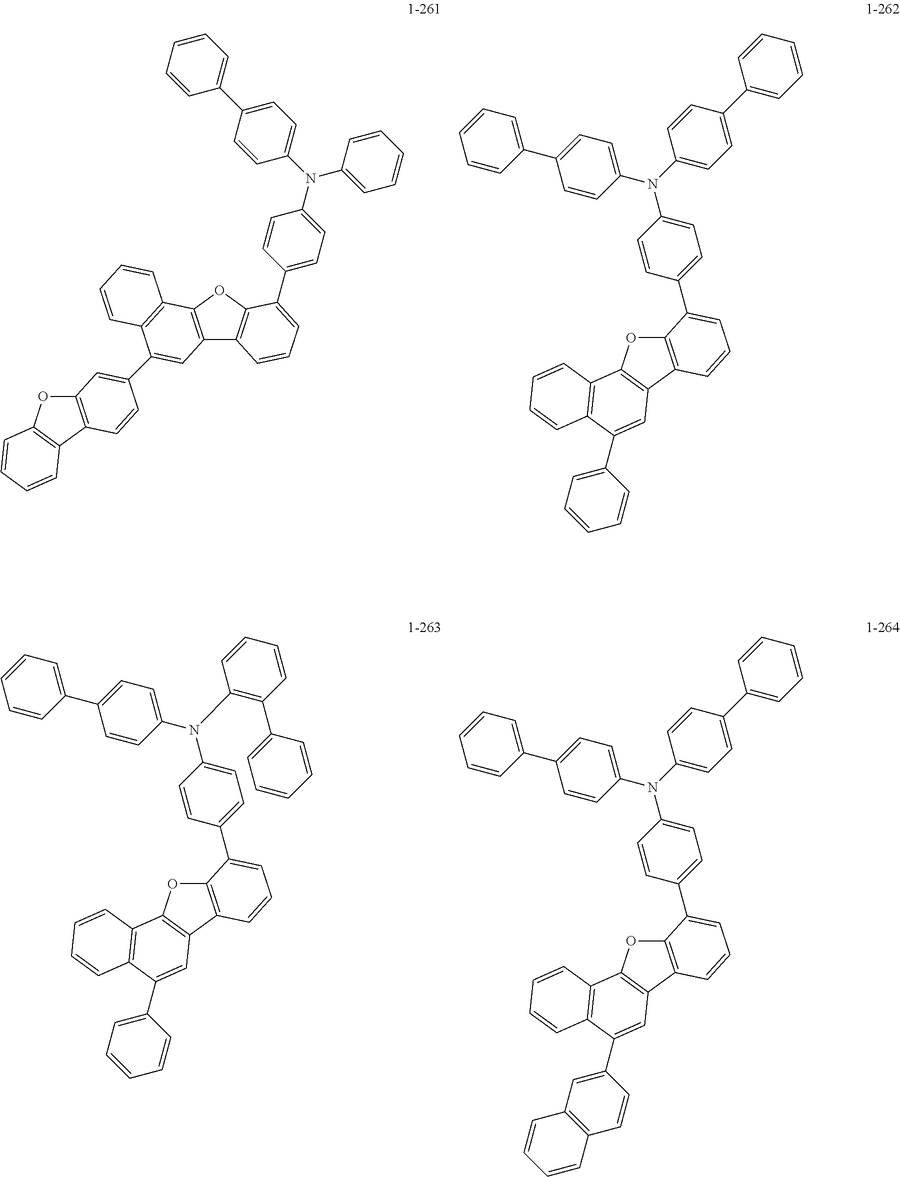 [SMILES: c1ccc(-c2ccc(N(c3ccccc3)c3ccc(-c4cccc5c4oc4c6ccccc6c(-c6ccc7c(c6)oc6ccccc67)cc54)cc3)cc2)cc1 ; c1ccc(-c2ccc(N(c3ccc(-c4ccccc4)cc3)c3ccc(-c4cccc5c4oc4c6ccccc6c(-c6ccccc6)cc54)cc3)cc2)cc1 ; c1ccc(-c2ccc(N(c3ccc(-c4cccc5c4oc4c6ccccc6c(-c6ccccc6)cc54)cc3)c3ccccc3-c3ccccc3)cc2)cc1 ; c1ccc(-c2ccc(N(c3ccc(-c4ccccc4)cc3)c3ccc(-c4cccc5c4oc4c6ccccc6c(-c6ccc7ccccc7c6)cc54)cc3)cc2)cc1]

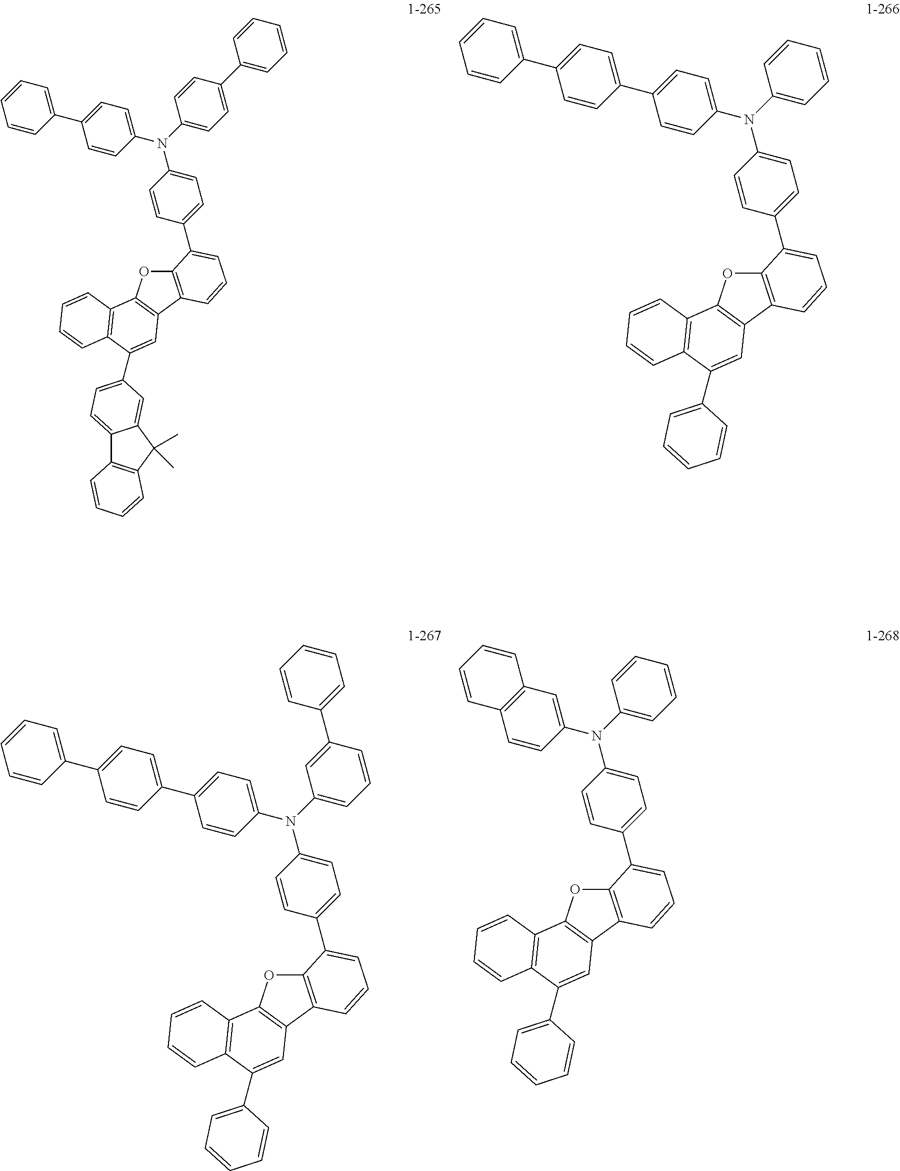 [SMILES: CC1(C)c2ccccc2-c2ccc(-c3cc4c5cccc(-c6ccc(N(c7ccc(-c8ccccc8)cc7)c7ccc(-c8ccccc8)cc7)cc6)c5oc4c4ccccc34)cc21 ; c1ccc(-c2ccc(-c3ccc(N(c4ccccc4)c4ccc(-c5cccc6c5oc5c7ccccc7c(-c7ccccc7)cc65)cc4)cc3)cc2)cc1 ; c1ccc(-c2ccc(-c3ccc(N(c4ccc(-c5cccc6c5oc5c7ccccc7c(-c7ccccc7)cc65)cc4)c4cccc(-c5ccccc5)c4)cc3)cc2)cc1 ; c1ccc(-c2cc3c4cccc(-c5ccc(N(c6ccccc6)c6ccc7ccccc7c6)cc5)c4oc3c3ccccc23)cc1]

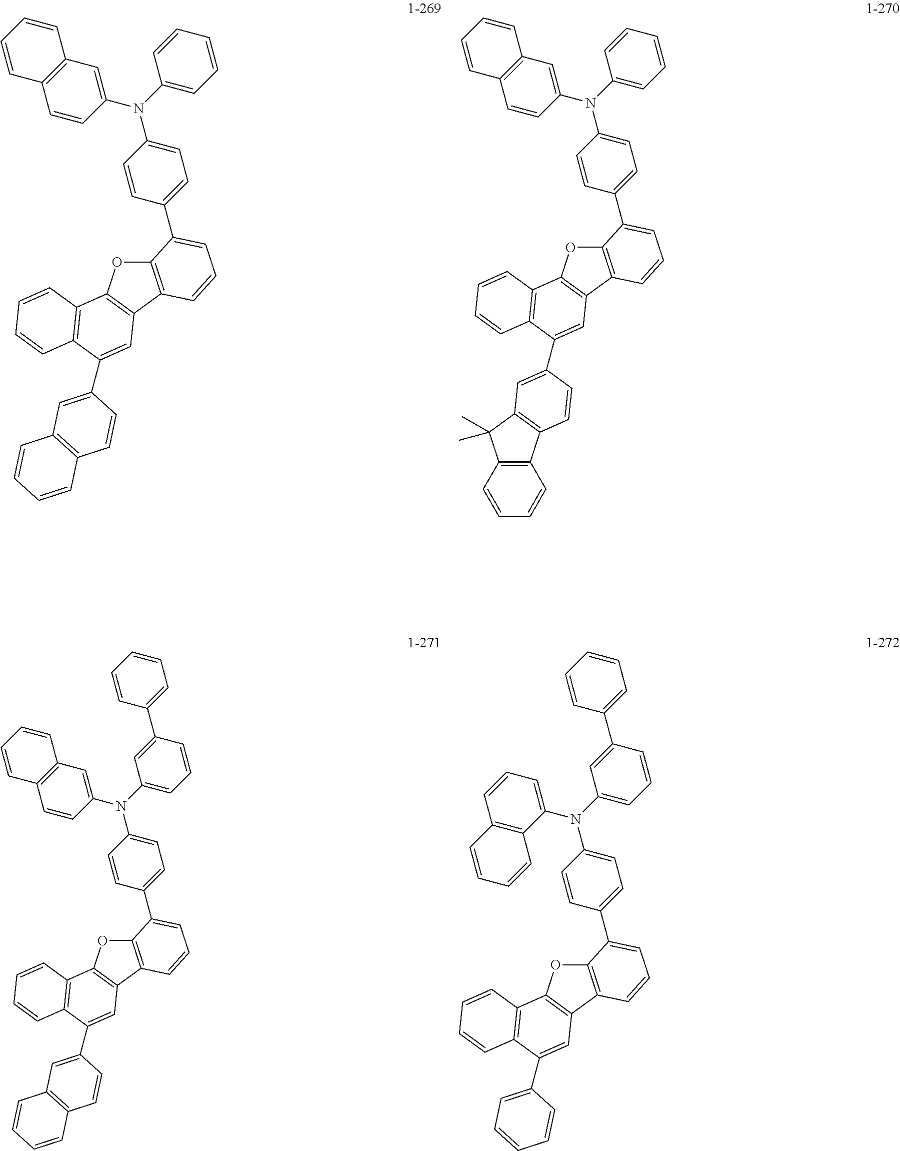 [SMILES: c1ccc(N(c2ccc(-c3cccc4c3oc3c5ccccc5c(-c5ccc6ccccc6c5)cc43)cc2)c2ccc3ccccc3c2)cc1 ; CC1(C)c2ccccc2-c2ccc(-c3cc4c5cccc(-c6ccc(N(c7ccccc7)c7ccc8ccccc8c7)cc6)c5oc4c4ccccc34)cc21 ; c1ccc(-c2cccc(N(c3ccc(-c4cccc5c4oc4c6ccccc6c(-c6ccc7ccccc7c6)cc54)cc3)c3ccc4ccccc4c3)c2)cc1 ; c1ccc(-c2cccc(N(c3ccc(-c4cccc5c4oc4c6ccccc6c(-c6ccccc6)cc54)cc3)c3cccc4ccccc34)c2)cc1]

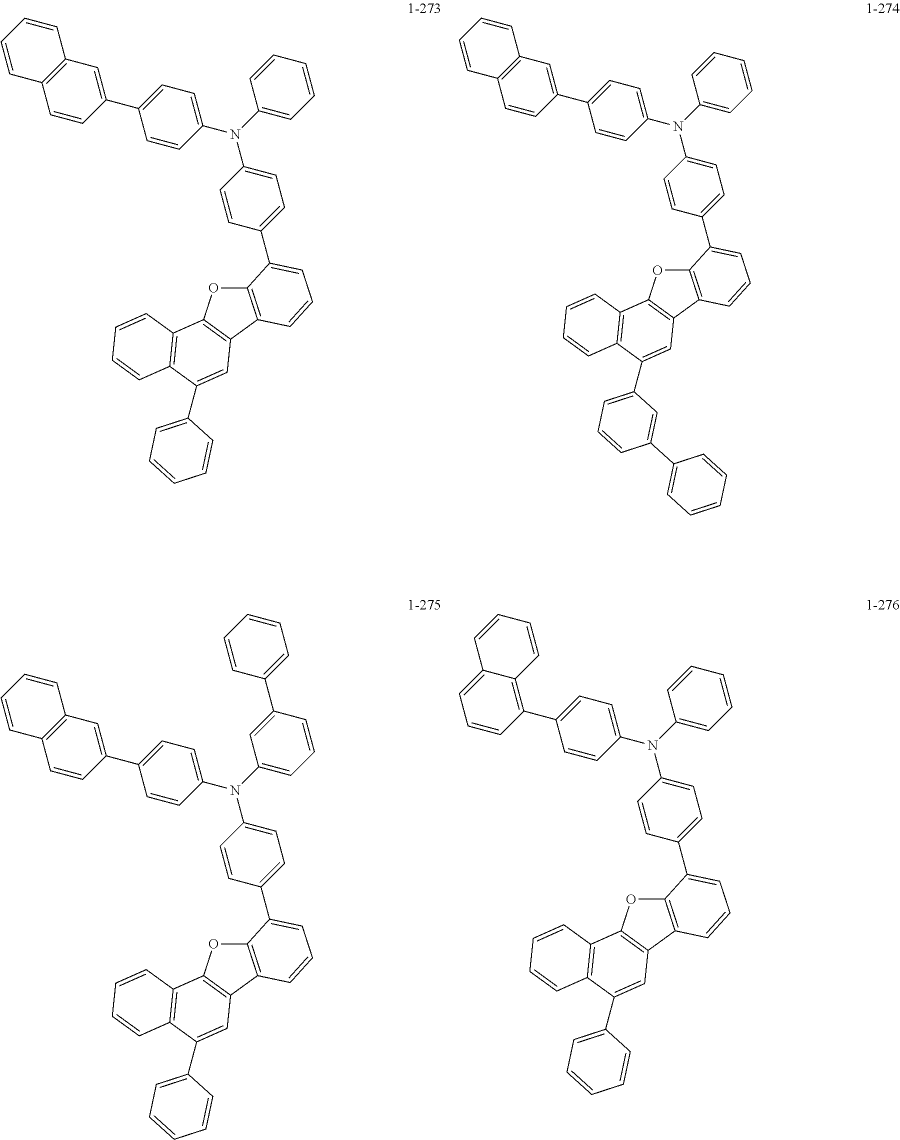 [SMILES: c1ccc(-c2cc3c4cccc(-c5ccc(N(c6ccccc6)c6ccc(-c7ccc8ccccc8c7)cc6)cc5)c4oc3c3ccccc23)cc1 ; c1ccc(-c2cccc(-c3cc4c5cccc(-c6ccc(N(c7ccccc7)c7ccc(-c8ccc9ccccc9c8)cc7)cc6)c5oc4c4ccccc34)c2)cc1 ; c1ccc(-c2cccc(N(c3ccc(-c4ccc5ccccc5c4)cc3)c3ccc(-c4cccc5c4oc4c6ccccc6c(-c6ccccc6)cc54)cc3)c2)cc1 ; c1ccc(-c2cc3c4cccc(-c5ccc(N(c6ccccc6)c6ccc(-c7cccc8ccccc78)cc6)cc5)c4oc3c3ccccc23)cc1]

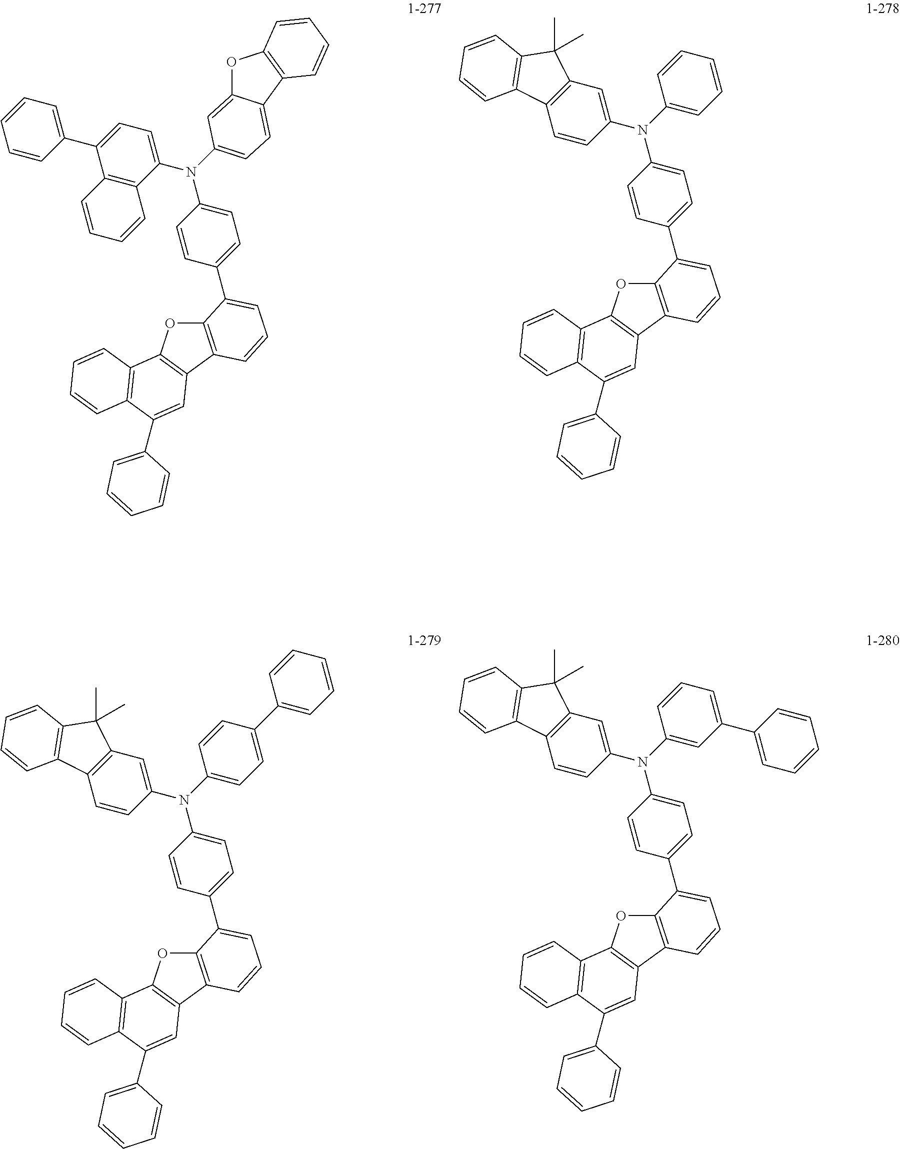 [SMILES: c1ccc(-c2ccc(N(c3ccc(-c4cccc5c4oc4c6ccccc6c(-c6ccccc6)cc54)cc3)c3ccc4c(c3)oc3ccccc34)c3ccccc23)cc1 ; CC1(C)c2ccccc2-c2ccc(N(c3ccccc3)c3ccc(-c4cccc5c4oc4c6ccccc6c(-c6ccccc6)cc54)cc3)cc21 ; CC1(C)c2ccccc2-c2ccc(N(c3ccc(-c4ccccc4)cc3)c3ccc(-c4cccc5c4oc4c6ccccc6c(-c6ccccc6)cc54)cc3)cc21 ; CC1(C)c2ccccc2-c2ccc(N(c3ccc(-c4cccc5c4oc4c6ccccc6c(-c6ccccc6)cc54)cc3)c3cccc(-c4ccccc4)c3)cc21]

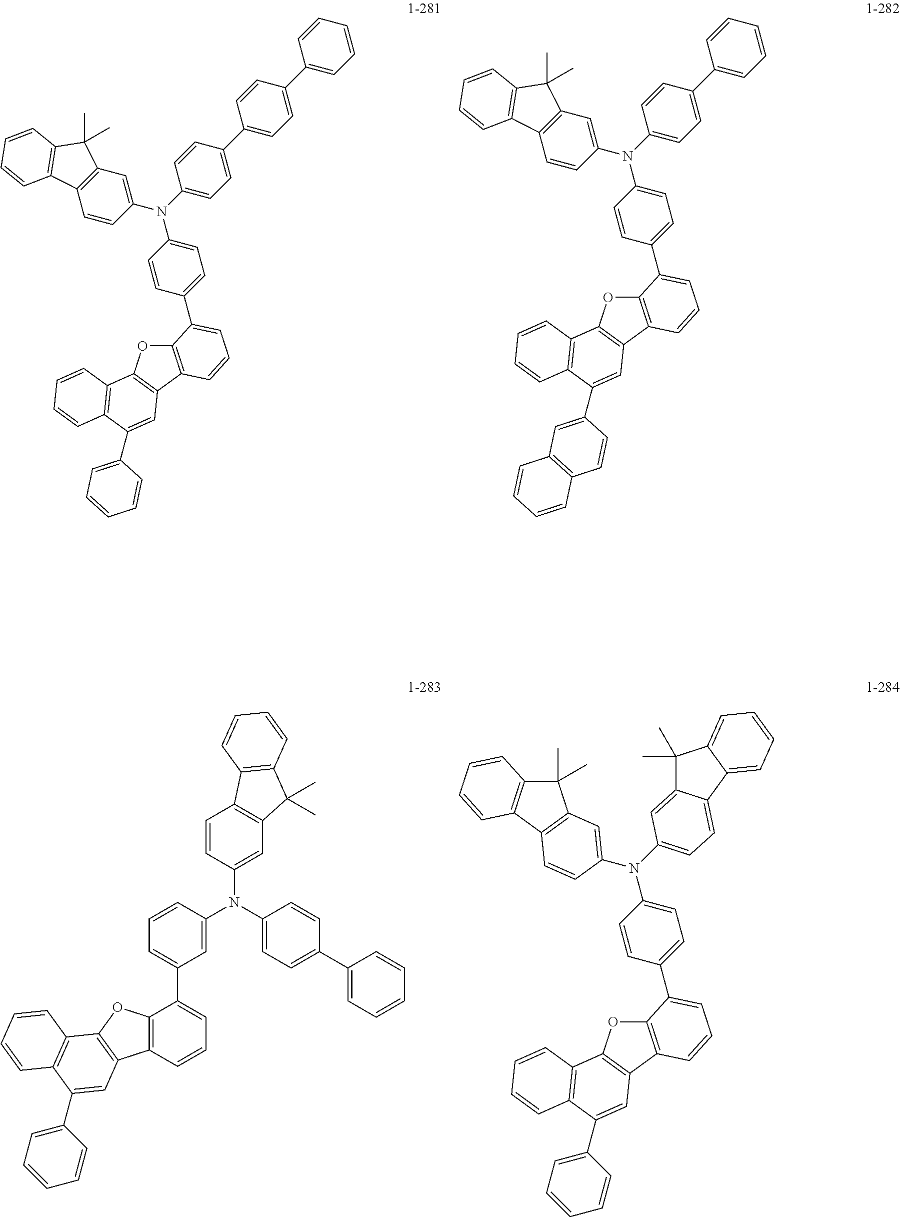 [SMILES: CC1(C)c2ccccc2-c2ccc(N(c3ccc(-c4ccc(-c5ccccc5)cc4)cc3)c3ccc(-c4cccc5c4oc4c6ccccc6c(-c6ccccc6)cc54)cc3)cc21 ; CC1(C)c2ccccc2-c2ccc(N(c3ccc(-c4ccccc4)cc3)c3ccc(-c4cccc5c4oc4c6ccccc6c(-c6ccc7ccccc7c6)cc54)cc3)cc21 ; CC1(C)c2ccccc2-c2ccc(N(c3ccc(-c4ccccc4)cc3)c3cccc(-c4cccc5c4oc4c6ccccc6c(-c6ccccc6)cc54)c3)cc21 ; CC1(C)c2ccccc2-c2ccc(N(c3ccc(-c4cccc5c4oc4c6ccccc6c(-c6ccccc6)cc54)cc3)c3ccc4c(c3)C(C)(C)c3ccccc3-4)cc21]

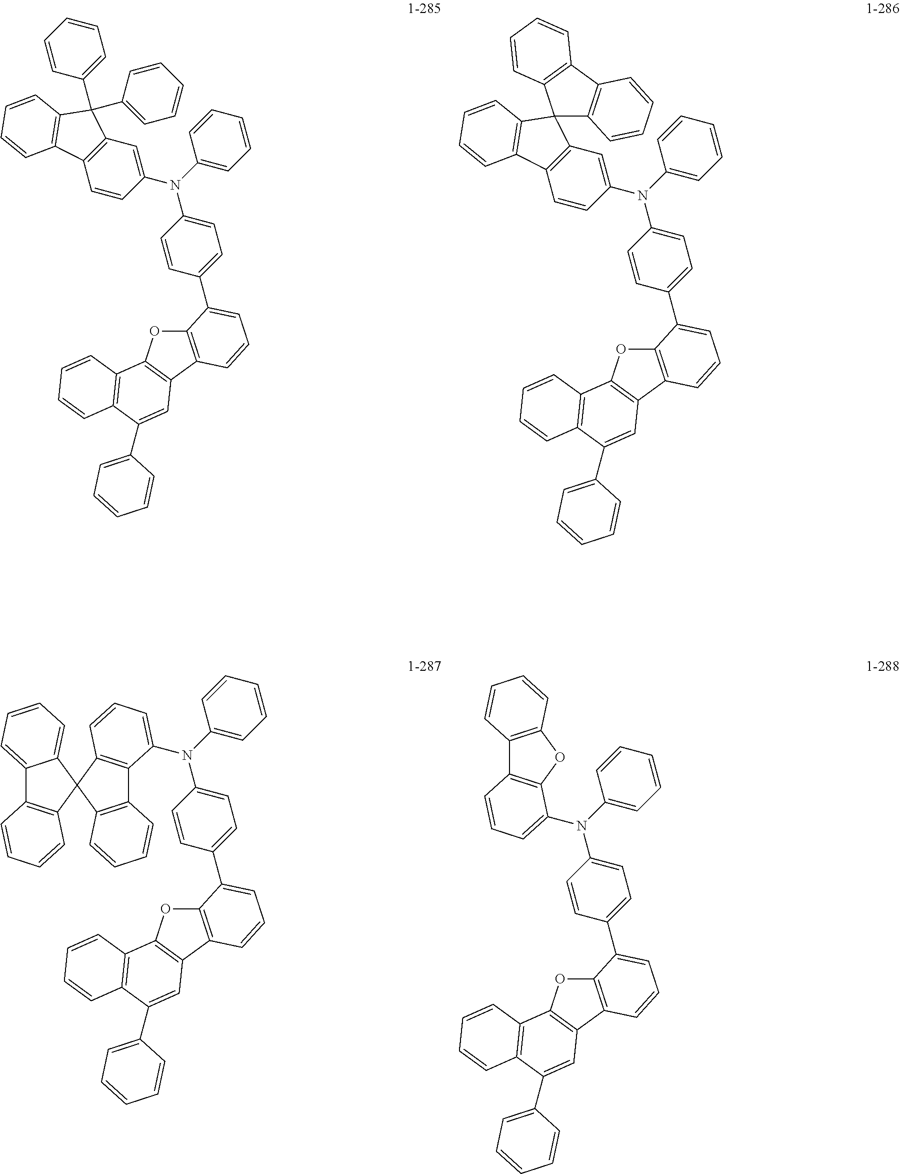 [SMILES: c1ccc(-c2cc3c4cccc(-c5ccc(N(c6ccccc6)c6ccc7c(c6)C(c6ccccc6)(c6ccccc6)c6ccccc6-7)cc5)c4oc3c3ccccc23)cc1 ; c1ccc(-c2cc3c4cccc(-c5ccc(N(c6ccccc6)c6ccc7c(c6)C6(c8ccccc8-c8ccccc86)c6ccccc6-7)cc5)c4oc3c3ccccc23)cc1 ; c1ccc(-c2cc3c4cccc(-c5ccc(N(c6ccccc6)c6cccc7c6-c6ccccc6C76c7ccccc7-c7ccccc76)cc5)c4oc3c3ccccc23)cc1 ; c1ccc(-c2cc3c4cccc(-c5ccc(N(c6ccccc6)c6cccc7c6oc6ccccc67)cc5)c4oc3c3ccccc23)cc1]

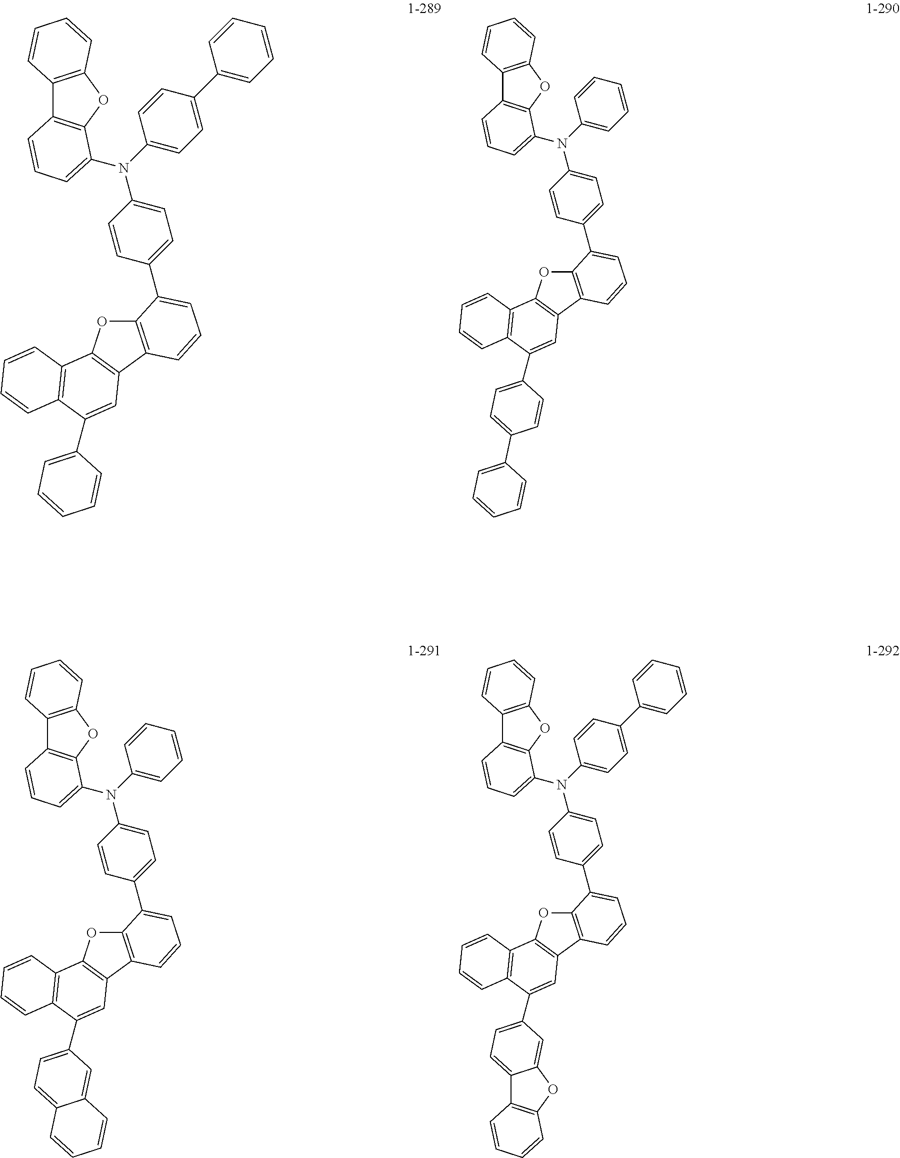 [SMILES: c1ccc(-c2ccc(N(c3ccc(-c4cccc5c4oc4c6ccccc6c(-c6ccccc6)cc54)cc3)c3cccc4c3oc3ccccc34)cc2)cc1 ; c1ccc(-c2ccc(-c3cc4c5cccc(-c6ccc(N(c7ccccc7)c7cccc8c7oc7ccccc78)cc6)c5oc4c4ccccc34)cc2)cc1 ; c1ccc(N(c2ccc(-c3cccc4c3oc3c5ccccc5c(-c5ccc6ccccc6c5)cc43)cc2)c2cccc3c2oc2ccccc23)cc1 ; c1ccc(-c2ccc(N(c3ccc(-c4cccc5c4oc4c6ccccc6c(-c6ccc7c(c6)oc6ccccc67)cc54)cc3)c3cccc4c3oc3ccccc34)cc2)cc1]

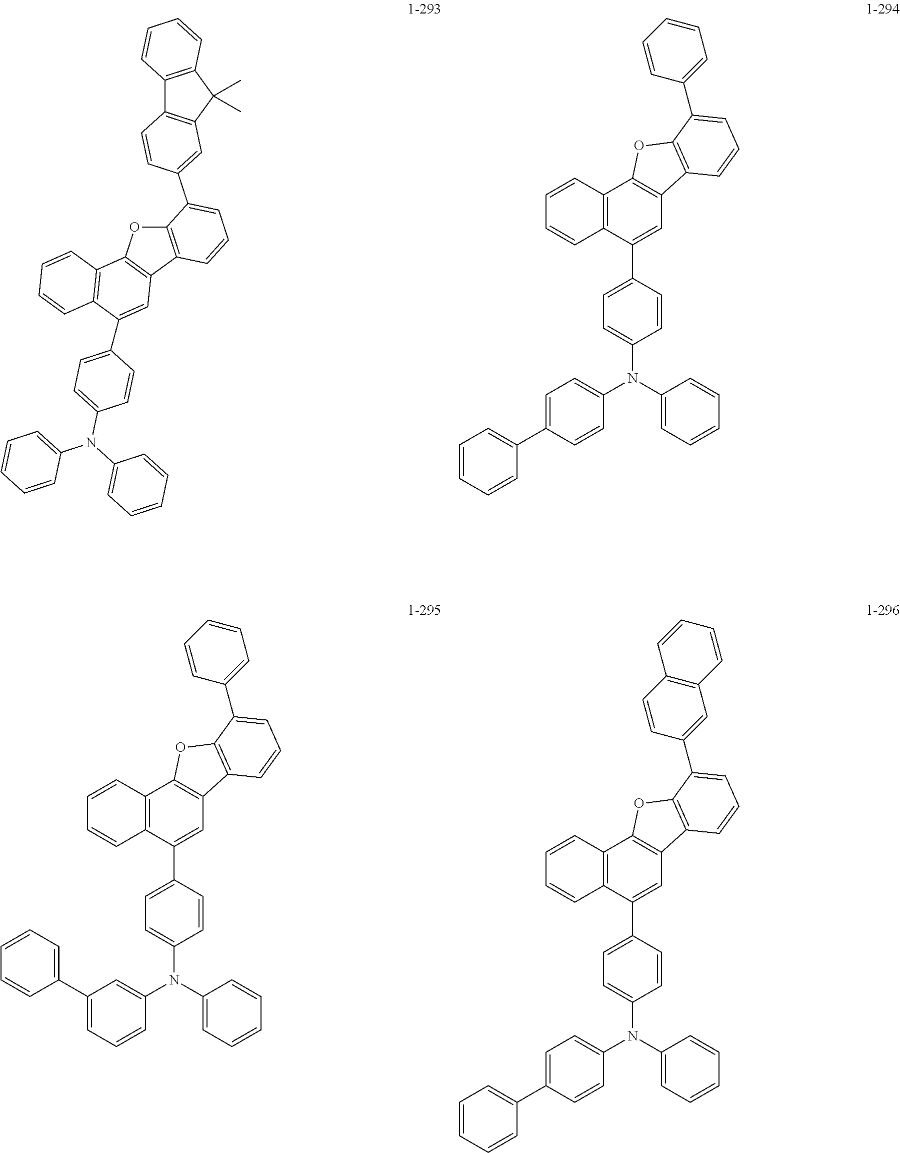 [SMILES: CC1(C)c2ccccc2-c2ccc(-c3cccc4c3oc3c5ccccc5c(-c5ccc(N(c6ccccc6)c6ccccc6)cc5)cc43)cc21 ; c1ccc(-c2ccc(N(c3ccccc3)c3ccc(-c4cc5c6cccc(-c7ccccc7)c6oc5c5ccccc45)cc3)cc2)cc1 ; c1ccc(-c2cccc(N(c3ccccc3)c3ccc(-c4cc5c6cccc(-c7ccccc7)c6oc5c5ccccc45)cc3)c2)cc1 ; c1ccc(-c2ccc(N(c3ccccc3)c3ccc(-c4cc5c6cccc(-c7ccc8ccccc8c7)c6oc5c5ccccc45)cc3)cc2)cc1]

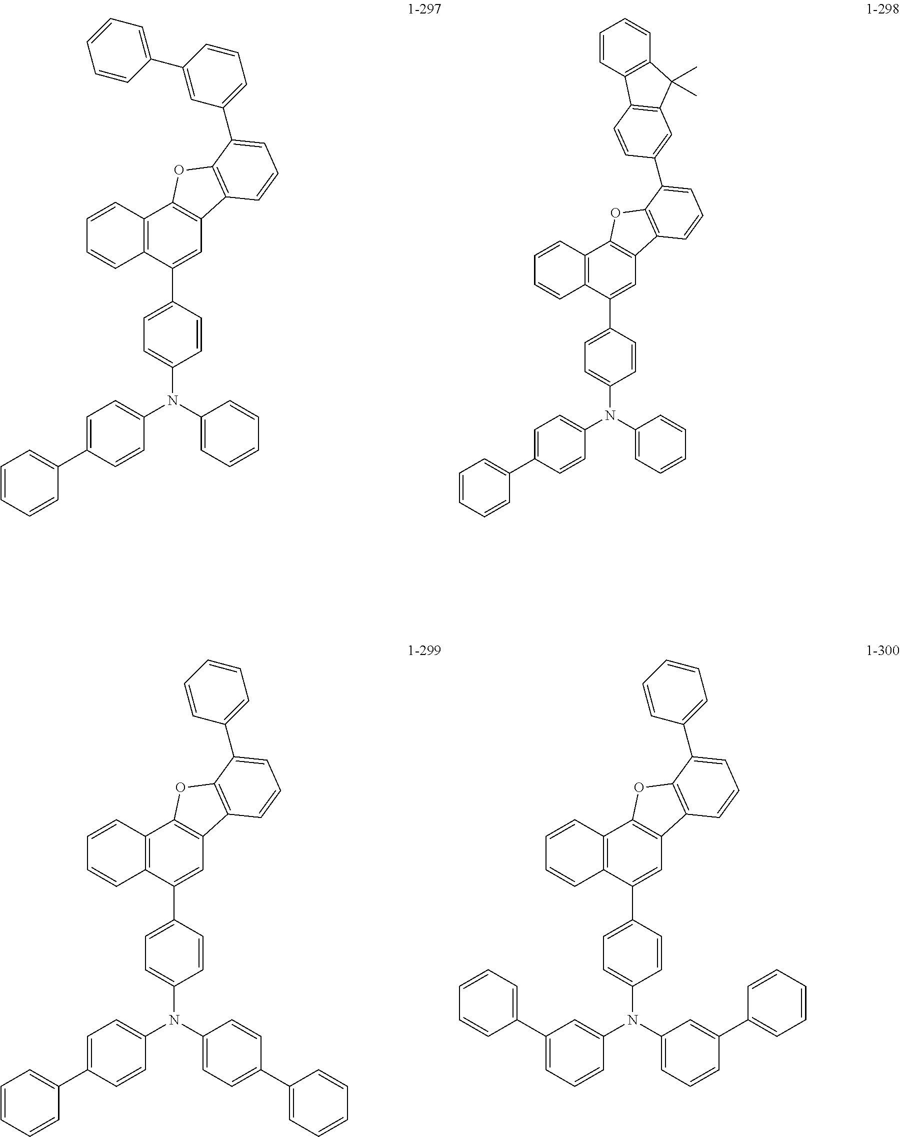 [SMILES: c1ccc(-c2ccc(N(c3ccccc3)c3ccc(-c4cc5c6cccc(-c7cccc(-c8ccccc8)c7)c6oc5c5ccccc45)cc3)cc2)cc1 ; CC1(C)c2ccccc2-c2ccc(-c3cccc4c3oc3c5ccccc5c(-c5ccc(N(c6ccccc6)c6ccc(-c7ccccc7)cc6)cc5)cc43)cc21 ; c1ccc(-c2ccc(N(c3ccc(-c4ccccc4)cc3)c3ccc(-c4cc5c6cccc(-c7ccccc7)c6oc5c5ccccc45)cc3)cc2)cc1 ; c1ccc(-c2cccc(N(c3ccc(-c4cc5c6cccc(-c7ccccc7)c6oc5c5ccccc45)cc3)c3cccc(-c4ccccc4)c3)c2)cc1]

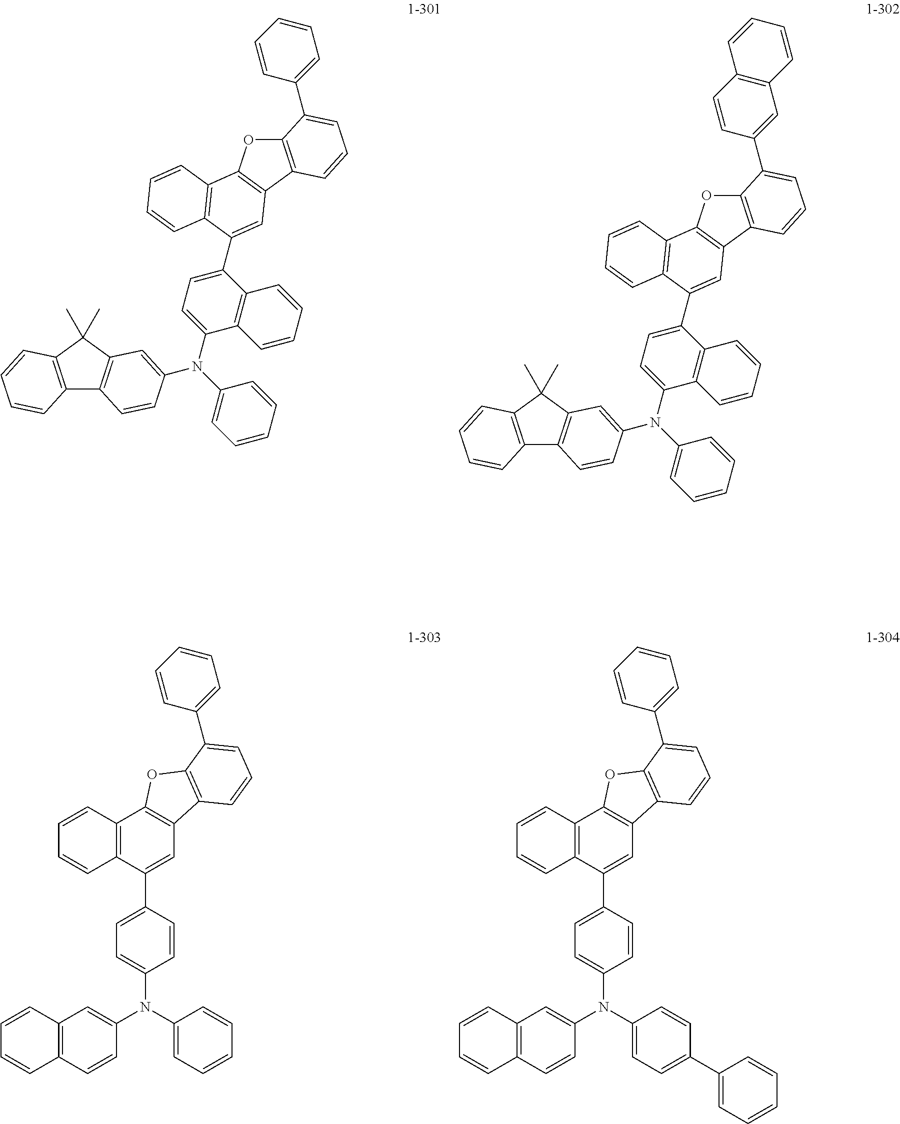 [SMILES: CC1(C)c2ccccc2-c2ccc(N(c3ccccc3)c3ccc(-c4cc5c6cccc(-c7ccccc7)c6oc5c5ccccc45)c4ccccc34)cc21 ; CC1(C)c2ccccc2-c2ccc(N(c3ccccc3)c3ccc(-c4cc5c6cccc(-c7ccc8ccccc8c7)c6oc5c5ccccc45)c4ccccc34)cc21 ; c1ccc(-c2cccc3c2oc2c4ccccc4c(-c4ccc(N(c5ccccc5)c5ccc6ccccc6c5)cc4)cc32)cc1 ; c1ccc(-c2ccc(N(c3ccc(-c4cc5c6cccc(-c7ccccc7)c6oc5c5ccccc45)cc3)c3ccc4ccccc4c3)cc2)cc1]

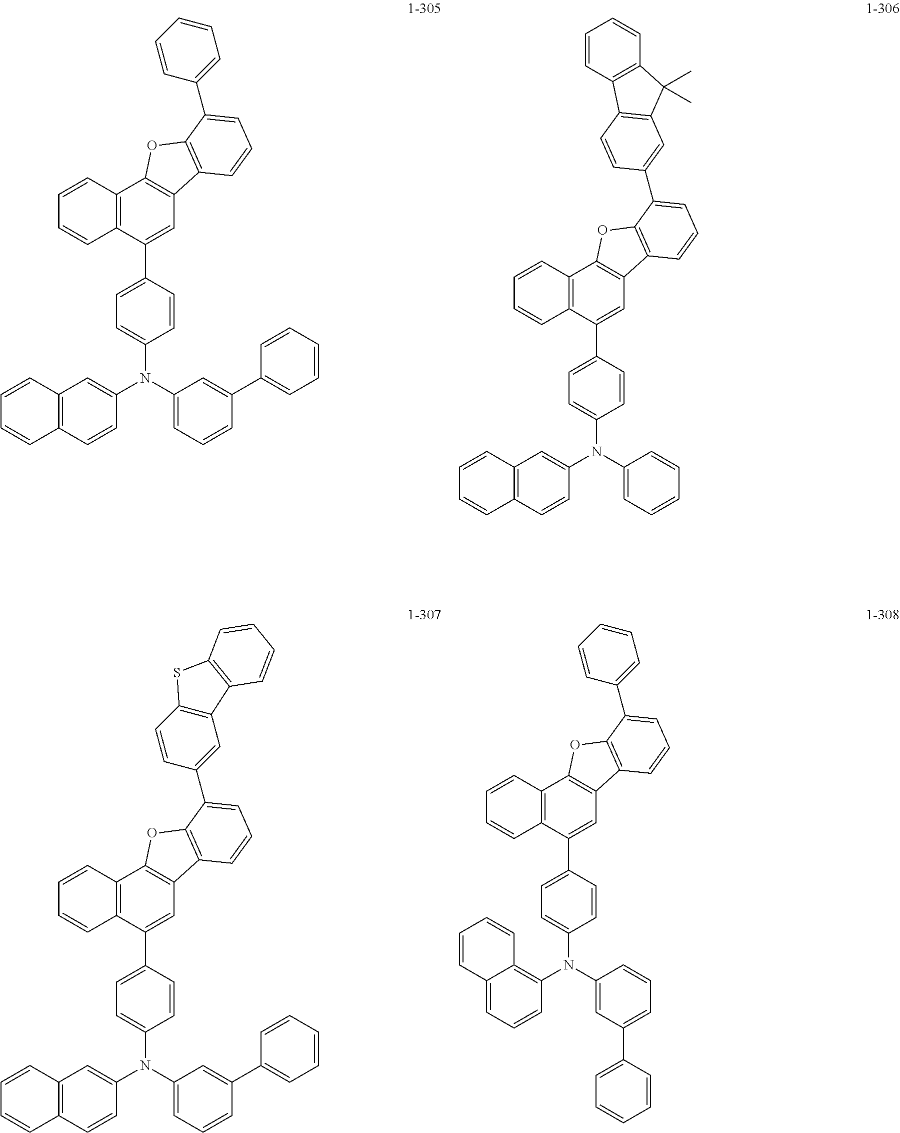 [SMILES: c1ccc(-c2cccc(N(c3ccc(-c4cc5c6cccc(-c7ccccc7)c6oc5c5ccccc45)cc3)c3ccc4ccccc4c3)c2)cc1 ; CC1(C)c2ccccc2-c2ccc(-c3cccc4c3oc3c5ccccc5c(-c5ccc(N(c6ccccc6)c6ccc7ccccc7c6)cc5)cc43)cc21 ; c1ccc(-c2cccc(N(c3ccc(-c4cc5c6cccc(-c7ccc8sc9ccccc9c8c7)c6oc5c5ccccc45)cc3)c3ccc4ccccc4c3)c2)cc1 ; c1ccc(-c2cccc(N(c3ccc(-c4cc5c6cccc(-c7ccccc7)c6oc5c5ccccc45)cc3)c3cccc4ccccc34)c2)cc1]

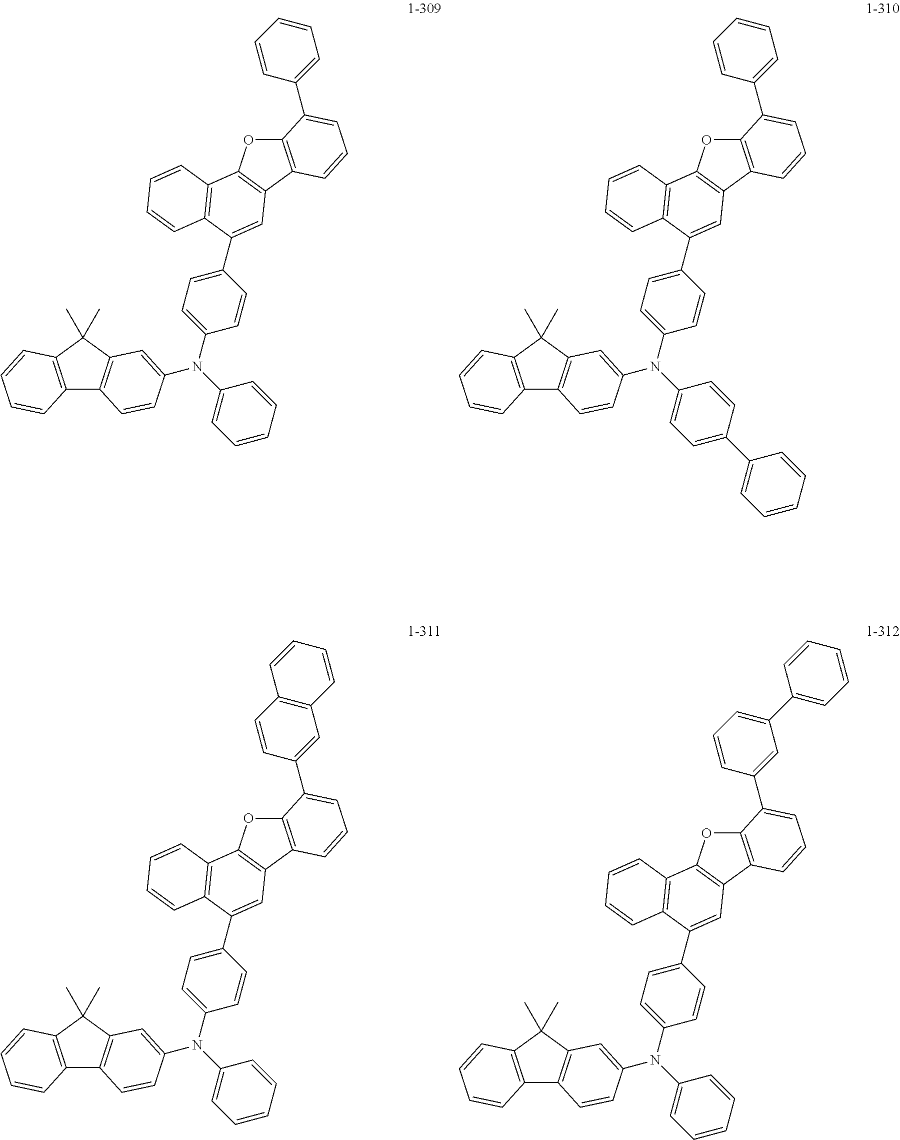 [SMILES: CC1(C)c2ccccc2-c2ccc(N(c3ccccc3)c3ccc(-c4cc5c6cccc(-c7ccccc7)c6oc5c5ccccc45)cc3)cc21 ; CC1(C)c2ccccc2-c2ccc(N(c3ccc(-c4ccccc4)cc3)c3ccc(-c4cc5c6cccc(-c7ccccc7)c6oc5c5ccccc45)cc3)cc21 ; CC1(C)c2ccccc2-c2ccc(N(c3ccccc3)c3ccc(-c4cc5c6cccc(-c7ccc8ccccc8c7)c6oc5c5ccccc45)cc3)cc21 ; CC1(C)c2ccccc2-c2ccc(N(c3ccccc3)c3ccc(-c4cc5c6cccc(-c7cccc(-c8ccccc8)c7)c6oc5c5ccccc45)cc3)cc21]

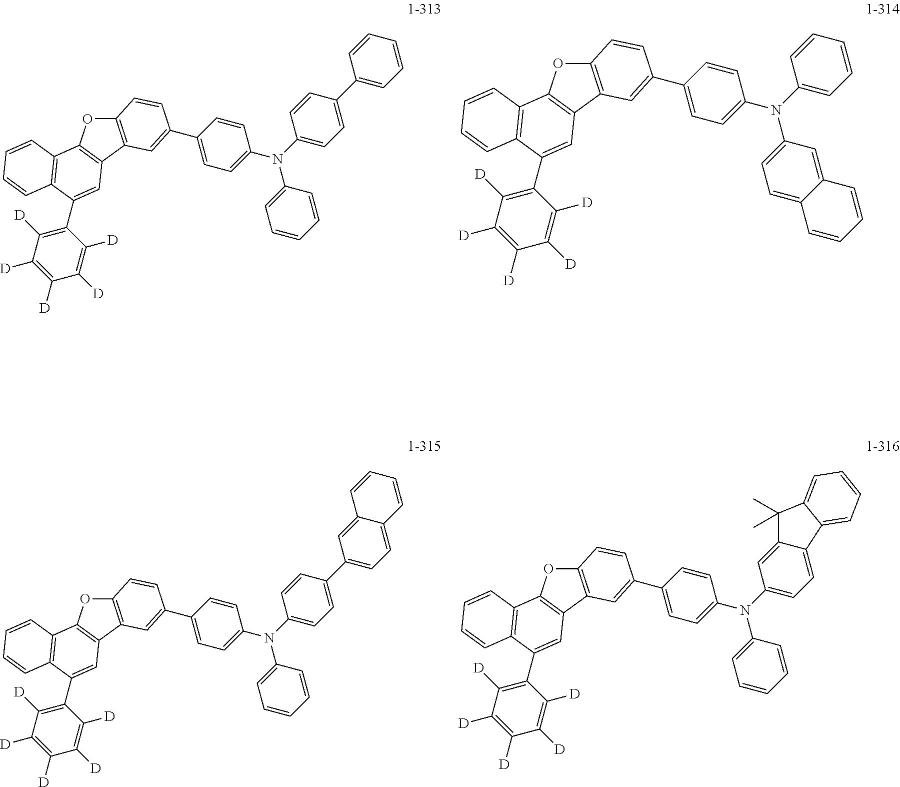 [SMILES: [2H]c1c([2H])c([2H])c(-c2cc3c4cc(-c5ccc(N(c6ccccc6)c6ccc(-c7ccccc7)cc6)cc5)ccc4oc3c3ccccc23)c([2H])c1[2H] ; [2H]c1c([2H])c([2H])c(-c2cc3c4cc(-c5ccc(N(c6ccccc6)c6ccc7ccccc7c6)cc5)ccc4oc3c3ccccc23)c([2H])c1[2H] ; [2H]c1c([2H])c([2H])c(-c2cc3c4cc(-c5ccc(N(c6ccccc6)c6ccc(-c7ccc8ccccc8c7)cc6)cc5)ccc4oc3c3ccccc23)c([2H])c1[2H] ; [2H]c1c([2H])c([2H])c(-c2cc3c4cc(-c5ccc(N(c6ccccc6)c6ccc7c(c6)C(C)(C)c6ccccc6-7)cc5)ccc4oc3c3ccccc23)c([2H])c1[2H]]

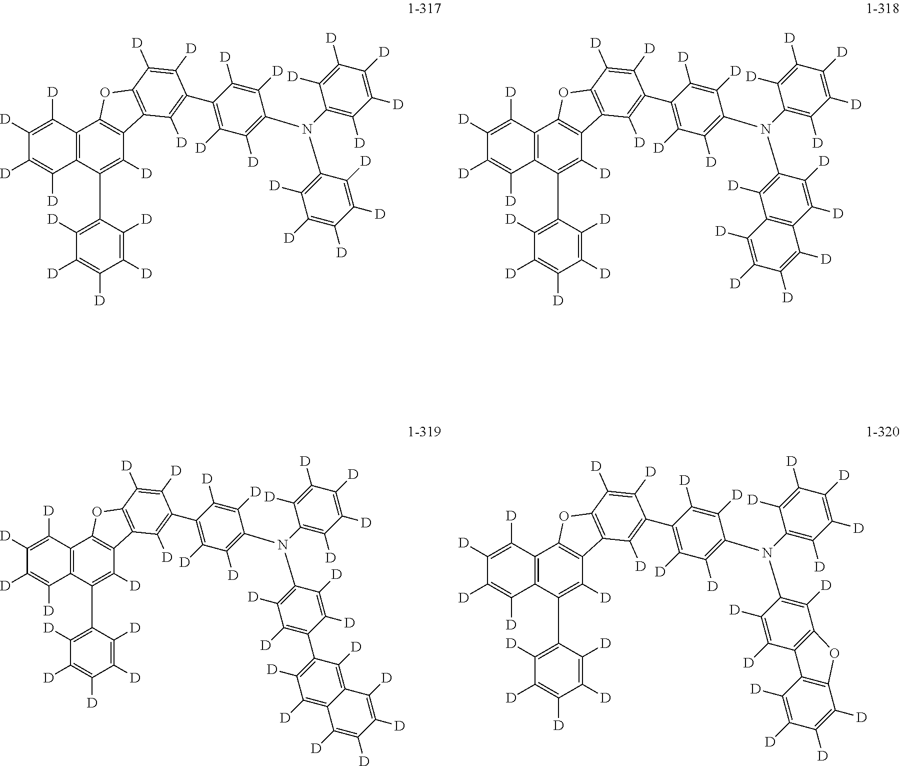

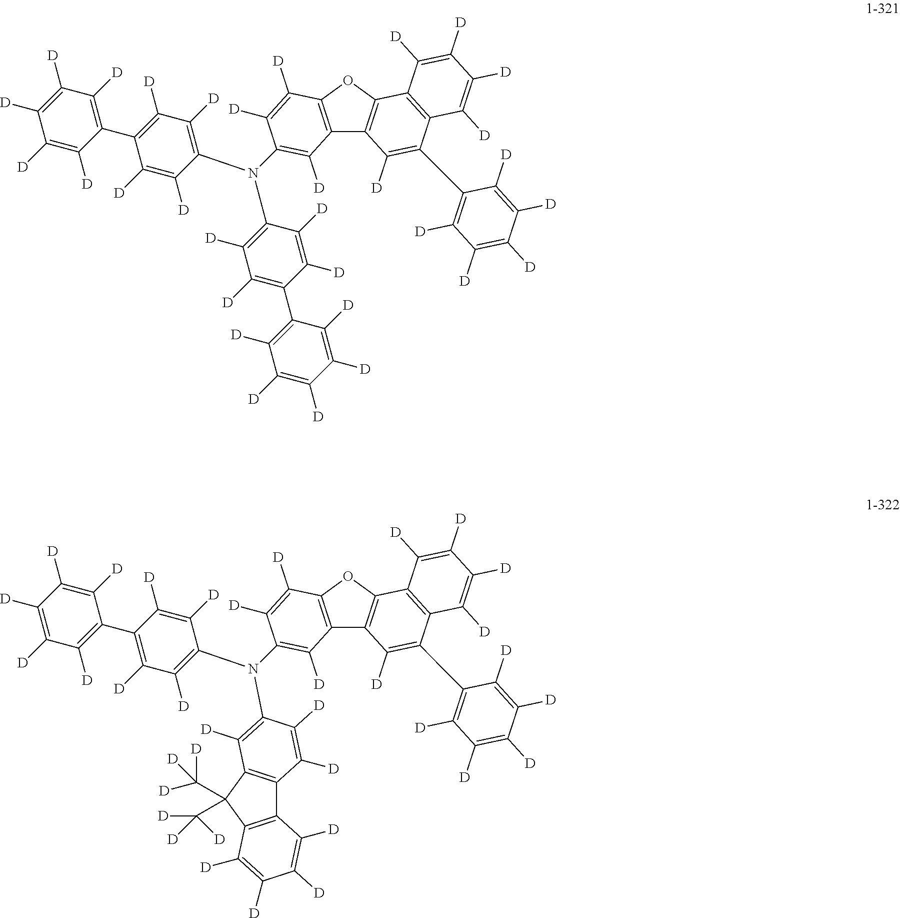

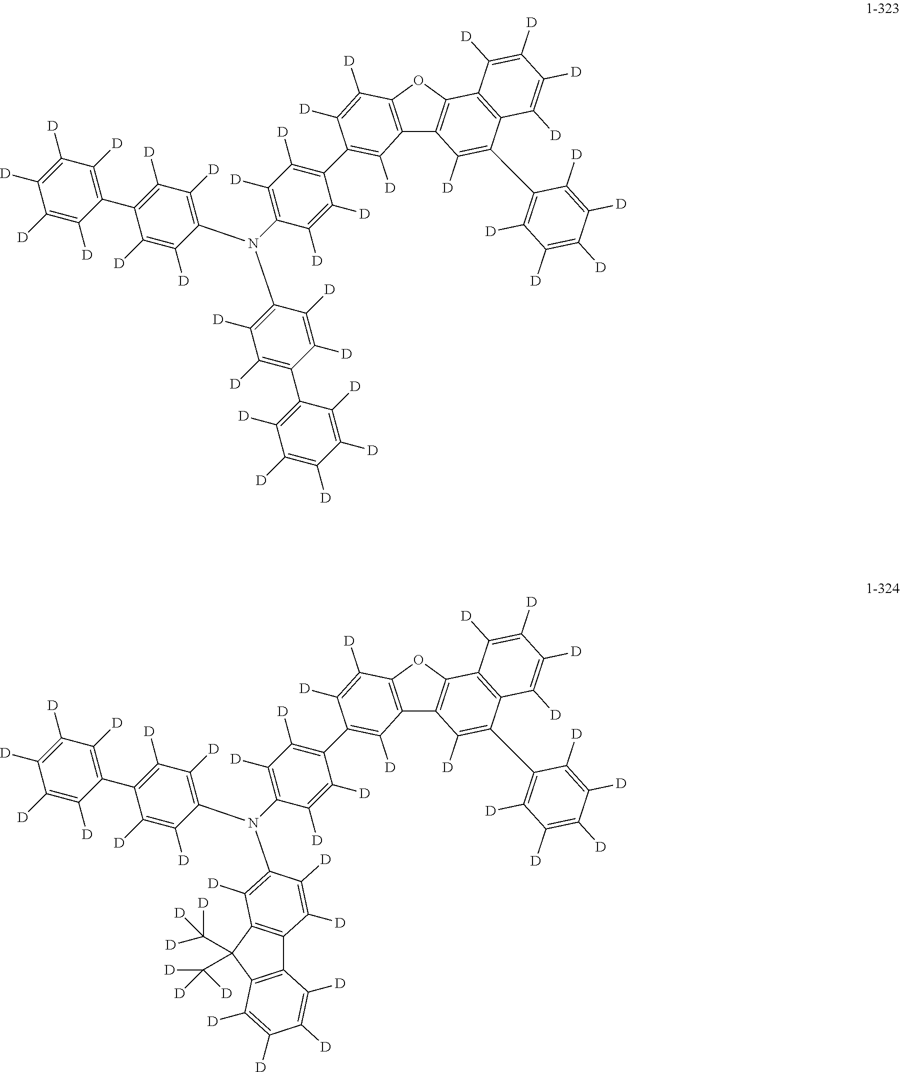

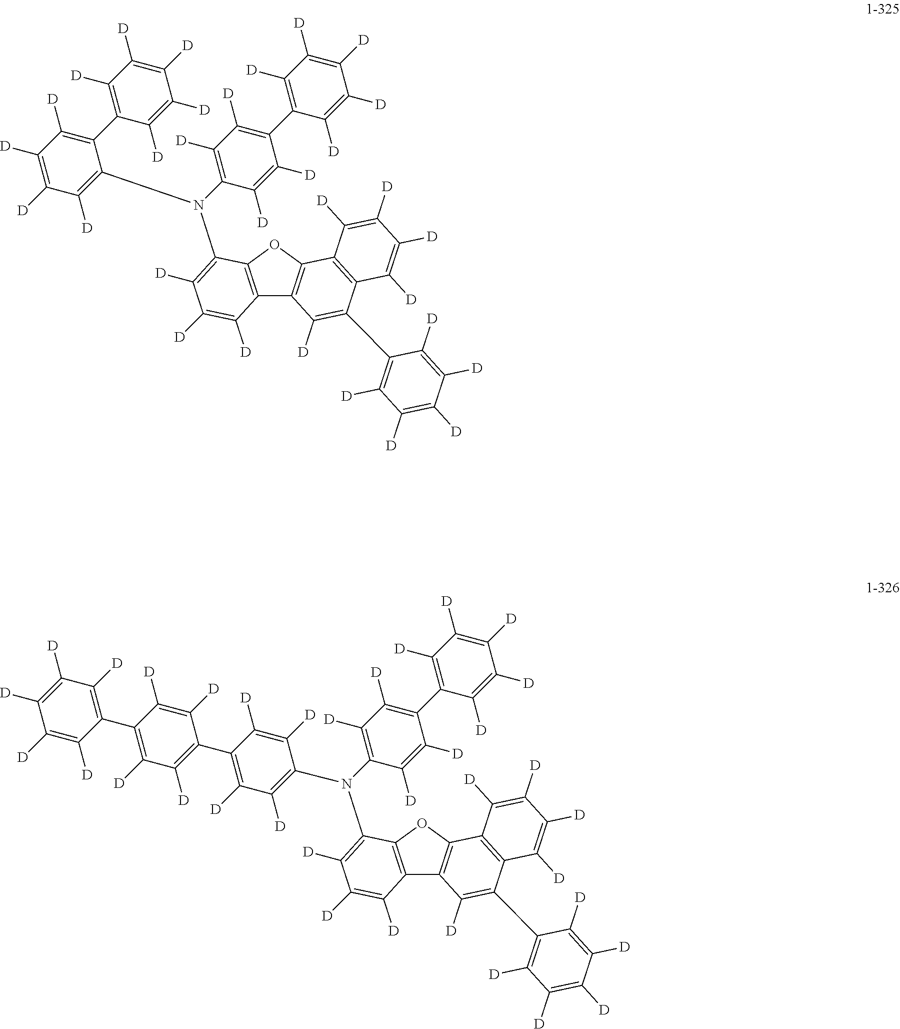

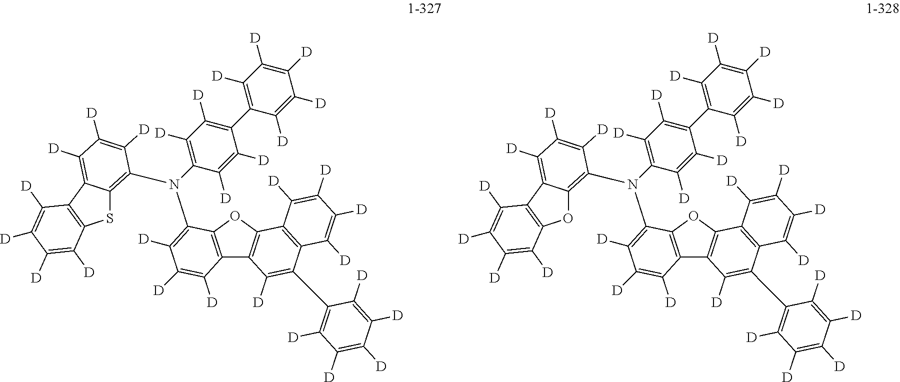 [SMILES: [2H]c1c([2H])c([2H])c(-c2c([2H])c([2H])c(N(c3c([2H])c([2H])c([2H])c4c3oc3c5c([2H])c([2H])c([2H])c([2H])c5c(-c5c([2H])c([2H])c([2H])c([2H])c5[2H])c([2H])c34)c3c([2H])c([2H])c([2H])c4c3sc3c([2H])c([2H])c([2H])c([2H])c34)c([2H])c2[2H])c([2H])c1[2H] ; [2H]c1c([2H])c([2H])c(-c2c([2H])c([2H])c(N(c3c([2H])c([2H])c([2H])c4c3oc3c([2H])c([2H])c([2H])c([2H])c34)c3c([2H])c([2H])c([2H])c4c3oc3c5c([2H])c([2H])c([2H])c([2H])c5c(-c5c([2H])c([2H])c([2H])c([2H])c5[2H])c([2H])c34)c([2H])c2[2H])c([2H])c1[2H]]

As an example, the red-blue emitting material layer may be disposed in the first emitting part.

In another example aspect, the first electrode comprises a transmissive electrode and the second electrode comprises a reflective electrode.

Alternatively, the blue emitting material layer may further include a second host.

The first host may have a lowest unoccupied molecular orbital (LUMO) energy level higher than a LUMO energy level of the second host.

As an example, a LUMO energy level of the first host and a LUMO energy level of the second host may satisfy the following relationship in Equation (1):

0.4 eV≤LUMO^{H1}−LUMO^{H2}≤0.8 eV (1)

wherein, LUMO^{H1} indicates the LUMO energy level of the first host and LUMO^{H2} indicates the LUMO energy level of the second host.

In another example aspect, the first host may have a highest occupied molecular orbital (HOMO) energy level higher than a HOMO energy level of the second host.

As an example, the HOMO energy level of the first host and the HOMO energy level of the second host may satisfy the following relationship in Equation (2):

0.3 eV≤HOMO^{H1}−HOMO^{H2}≤0.6 eV (2)

wherein, HOMO^{H1} indicates HOMO energy level of the first host and HOMO^{H2} indicates HOMO energy level of the second host.

The second host may have the following structure of Chemical Formula 3:

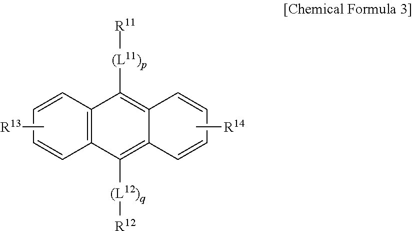

wherein,
R¹¹ and R¹² are independently selected from a group consisting of an unsubstituted C₆-C₃₀ aryl group, a substituted C₆-C₃₀ aryl group, an unsubstituted C₃-C₃₀ hetero aryl group, and a substituted C₃-C₃₀ hetero aryl group;
R¹³ and R¹⁴ are independently selected from a group consisting of hydrogen, an unsubstituted C₁-C₂₀ alkyl group, a substituted C₁-C₂₀ alkyl group, an unsubstituted C₆-C₃₀ aryl group, a substituted C₆-C₃₀ aryl group, an unsubstituted C₃-C₃₀ hetero aryl group, and a substituted C₃-C₃₀ hetero aryl group;
L¹¹ and L¹² are independently selected from a group consisting of an unsubstituted C₆-C₃₀ arylene group, a substituted C₆-C₃₀ arylene group, an unsubstituted C₃-C₃₀ hetero arylene group, and a substituted C₃-C₃₀ hetero arylene group; and
p and q are independently 0 or 1.

In one example aspect, the first host and the second host in the blue emitting material layer may be admixed with a weight ratio ranging from about 3:7 to about 7:3.

The red emitting material layer may include a red emitter and a third host.

The first host may have a LUMO energy level higher than a LUMO energy level of the third host.

For example, LUMO energy level of the first host and LUMO energy level of the third host may satisfy the following relationship in Equation (3):

0.4 eV≤LUMO^{H1}−LUMO^{H3}≤0.8 eV (3)

wherein, LUMO^{H1} indicates a LUMO energy level of the first host and a LUMO^{H3} indicates LUMO energy level of the third host.

The first host may have the HOMO energy level higher than the HOMO energy level of the third host.

As an example, the HOMO energy level of the first host and the HOMO energy level of the third host may satisfy the following relationship in Equation (4):

0.4 eV≤HOMO^{H1}−HOMO^{H3}≤0.6 eV (4)

wherein, HOMO^{H1} indicates HOMO energy level of the first host and HOMO^{H3} indicates HOMO energy level of the third host.

In another aspect, the present disclosure provides an organic light emitting diode comprising a first electrode; a second electrode facing the first electrode; and an emissive layer disposed between the first and second electrodes, wherein the emissive layer comprises: a first emitting part disposed between the first electrode and the second electrode; a second emitting part disposed between the first emitting part and the second electrode; a third emitting part disposed between the second emitting part and the second electrode; a fourth emitting part disposed between the third emitting part and the second electrode; a first charge generation layer disposed between the first emitting part and the second emitting part; a second charge generation layer disposed between the second emitting part and the third emitting part; and a third charge generation layer disposed between the third emitting part and the fourth emitting part, wherein the first emitting part comprises a red-blue emitting material layer comprising: a red emitting material layer disposed between the first electrode and the second electrode; and a blue emitting material layer disposed between the red emitting material layer and the second electrode, wherein each of the second emitting part and the fourth emitting part comprises a blue emitting material layer, respectively, wherein the second emitting part comprises a green emitting material layer, and wherein the blue emitting material layer in the first emitting part comprises a blue emitter and a first host having the structure of Chemical Formula 1.

In yet another aspect, the present disclosure provides an organic light emitting device, for example, an organic light emitting display device or an organic light emitting illumination device, comprises a substrate and the organic light emitting diode over the substrate.

The blue emitting material layer, comprising a host having a controlled HOMO and/or a LUMO energy levels, are disposed adjacently to the red emitting material layer disposed adjacently to the electrode in an organic light emitting diode with multiple emitting parts.

The blue light intensity emitted from the emitting material layer may be enhanced and color temperature of light emitted from the organic light emitting diode may be improved as exciton energy may be transferred efficiently to the blue emitter from the host with controlled energy levels.

The viewing angle of the organic light emitting diode may be maximized and white emission having improved luminous properties such as color temperature as the blue, red and green lights among the white light are emitted in balance.

It is to be understood that both the foregoing general description and the following detailed description are merely by way of example and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with the present disclosure.

FIG. 2 illustrates a cross-sectional view of an organic light emitting display device as an example of an organic light emitting device in accordance with an example aspect of the present disclosure.

FIG. 3 illustrates a cross-sectional view of an organic light emitting diode having a single emitting part in accordance with an example aspect of the present disclosure.

FIG. 4 illustrates a contour map by color of an organic light emitting diode fabricated in Examples in accordance with the present disclosure.

FIGS. 5 to 9 illustrate EL spectra of organic light emitting diodes fabricated in Examples in accordance with the present disclosure.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

The present disclosure relates to an organic emitting diode and/or an organic light emitting device that may realize efficient white emission by improving blue emission intensity and blue emission temperature to emit uniformly emission colors among white light. The organic light emitting diode may be applied to an organic light emitting device such as an organic light emitting display device or an organic light emitting illumination device.

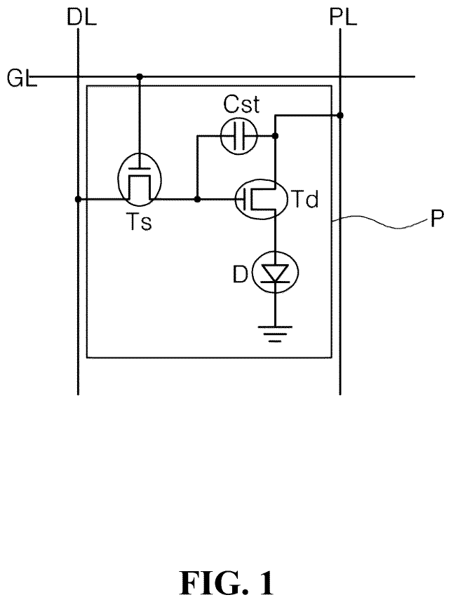

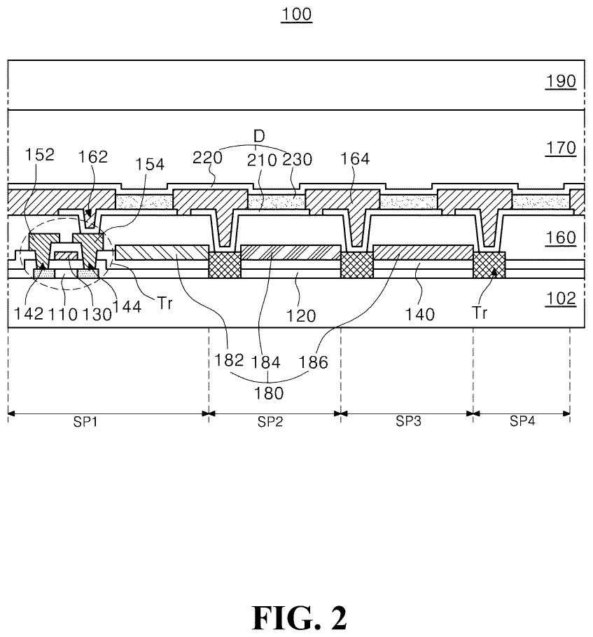

FIG. 1 illustrates a schematic circuit diagram of an organic light emitting display device in accordance with the present disclosure. As illustrated in FIG. 1, a gate line GL, a data line DL and power line PL, each of which crosses each other to define a pixel region P, in an organic light emitting display device 100. A switching thin film transistor Ts, a driving thin film transistor Td, a storage capacitor Cst and an organic light emitting diode D are disposed within the pixel region P. The pixel region P may include a first pixel region SP1, a second pixel region SP2, a third pixel region SP3, and optionally, a fourth pixel region SP4 (FIG. 2). However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

The driving thin film transistor Td is turned on by the data signal applied to the gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device may display a desired image.

FIG. 2 illustrates a schematic cross-sectional view of an organic light emitting display device in accordance with an example aspect of the present disclosure. As illustrated in FIG. 2, the organic light emitting display device 100 includes a substrate 102 where defines a first pixel region SP1, a second pixel region SP2, a third pixel region SP3, a fourth pixel region SP4, and an encapsulation film 190 facing the substrate 102. Each pixel region SP1, SP2, SP3, or SP4, may be divided into an emission area where an organic light emitting diode D is arranged and a non-emission area where a thin film transistor Tr is arranged. The substrate 102, on which the thin film transistor Tr and the organic light emitting diode D are arranged in each of the pixel regions SP1, SP2, SP3, and SP4, forms an array substrate. A color filter layer 180 may be disposed between the thin film transistor Tr and the organic light emitting diode D in the emission area of the first to third pixel regions SP1, SP2, and SP3.

The substrate 102 may include, but is not limited to, glass, thin flexible material and/or polymer plastics. For example, the flexible material may be selected from the group, but is not limited to, polyimide (PI), polyethersulfone (PES), polyethylenenaphthalate (PEN), polyethylene terephthalate (PET), polycarbonate (PC), and/or combinations thereof.

A buffer layer may be disposed on the substrate 102 in each of the first to fourth pixel regions SP1, SP2, SP3, and SP4. The thin film transistor Tr may be disposed on the buffer layer. The buffer layer may be omitted.

A semiconductor layer 110 is disposed on the buffer layer. In one example aspect, the semiconductor layer 110 may include, but is not limited to, oxide semiconductor materials. In this case, a light-shield pattern may be disposed under the semiconductor layer 110, and the light-shield pattern may prevent light from being incident toward the semiconductor layer 110, and thereby, preventing or reducing the semiconductor layer 110 from being degraded by the light. Alternatively, the semiconductor layer 110 may include polycrystalline silicon. In this case, opposite edges of the semiconductor layer 110 may be doped with impurities.

A gate insulating layer 120 including insulating material is disposed on the semiconductor layer 110. The gate insulating layer 120 may include, but is not limited to, an inorganic insulating material such as silicon oxide (SiOₓ, wherein 0<x≤2) or silicon nitride (SiNₓ, wherein 0<x≤2).

A gate electrode 130 made of conductive material such as metal is disposed on the gate insulating layer 120 to correspond to a center of the semiconductor layer 110. While the gate insulating layer 120 is disposed on a whole area of the substrate 102 as shown in FIG. 2, the gate insulating layer 120 may be patterned identically as the gate electrode 130.

An interlayer insulating layer 140 including an insulating material is disposed on the gate electrode 130 and covers an entire surface of the substrate 102. The interlayer insulating layer 140 may include, but is not limited to, an inorganic insulating material such as silicon oxide (SiOₓ), silicon nitride (SiNₓ), or an organic insulating material such as benzocyclobutene or a photo-acryl.

The interlayer insulating layer 140 has a first and a second semiconductor layer contacting holes 142 and 144 that expose or do not cover a portion of the surface nearer to the opposing ends than to a center of the semiconductor layer 110. The first and the second semiconductor layer contact holes 142 and 144 are disposed on opposite sides of the gate electrode 130 and spaced apart from the gate electrode 130. The first and the second semiconductor layer contact holes 142 and 144 are formed within the gate insulating layer 120 in FIG. 2. Alternatively, the first and the second semiconductor layer contact holes 142 and 144 may be formed only within the interlayer insulating layer 140 when the gate insulating layer 120 is patterned identically as the gate electrode 130.

A source electrode 152 and a drain electrode 154, which are made of conductive material such as metal, are disposed on the interlayer insulating layer 140. The source electrode 152 and the drain electrode 154 are spaced apart from each other on opposing sides of the gate electrode 130 and contact both sides of the semiconductor layer 110 through the first and the second semiconductor layer contact holes 142 and 144, respectively.

The semiconductor layer 110, the gate electrode 130, the source electrode 152, and the drain electrode 154 constitute the thin film transistor Tr, which acts as a driving element. The thin film transistor Tr in FIG. 2 has a coplanar structure in which the gate electrode 130, the source electrode 152, and the drain electrode 154 are disposed on the semiconductor layer 110. Alternatively, the thin film transistor Tr may have an inverted staggered structure in which a gate electrode is disposed under a semiconductor layer, a source, and drain electrodes which are disposed on the semiconductor layer. In this case, the semiconductor layer may include amorphous silicon.

The gate line GL and the data line DL, which cross each other to define a pixel region P, and a switching element Ts, which is connected to the gate line GL and the data line DL, may be further formed in the pixel region P. The switching element Ts is connected to the thin film transistor Tr, which is a driving element. In addition, the power line PL is spaced apart in parallel from the gate line GL or the data line DL. The thin film transistor Tr may further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the whole substrate 102. The passivation layer 160 has a flat top surface and a drain contact hole 162 that exposes or does not cover the drain electrode 154 of the thin film transistor Tr. While the drain contact hole 162 is disposed on the second semiconductor layer contact hole 144, it may be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is disposed separately in each pixel region SP1, SP2, SP3, or SP4. The first electrode 210 may be an anode and include conductive material having relatively high work function value. For example, the first electrode 210 may include a transparent conductive oxide (TCO).

In one example aspect, the first electrode 210 may have a single-layered structure of TCO when the organic light emitting display device 100 is a bottom-emission type. In this case, the first electrode 210 is thin to have light-transmissive (semi-transmissive) property. Alternatively, when the organic light emitting display device 100 is a top-emission type, a reflective electrode or a reflective layer may be disposed under the first electrode 210. For example, the reflective electrode or the reflective layer may include, but is not limited to, silver (Ag) or aluminum-palladium-copper (APC) alloy. In the OLED D of the top-emission type, the first electrode 210 may have a triple-layered structure of ITO/Ag/ITO or ITO/APC/ITO.

In addition, a bank layer 164 is disposed on the passivation layer 160 to cover edges of the first electrode 210. The bank layer 164 exposes or does not cover a center of the first electrode 210 corresponding to each pixel region SP1, SP2, SP3, or SP4. The bank layer 164 may be omitted.

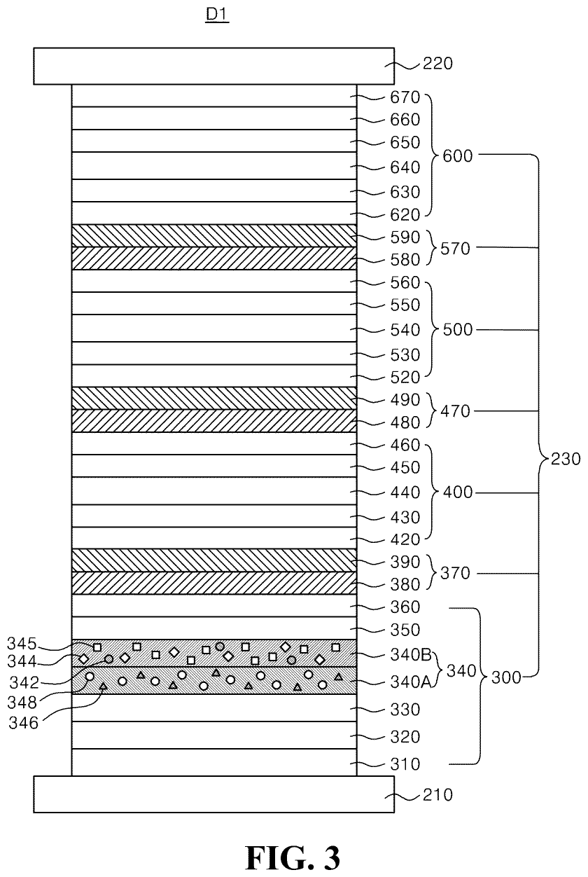

An emissive layer 230 is disposed on the first electrode 210. The emissive layer 230 may include multiple emitting parts 300, 400, 500, and 600 (FIG. 3) and charge generations layers 370, 470, and 570 (FIG. 3). Each of the emitting parts 300, 400, 500, and 600 may have a single-layered structure of an emitting material layer (EML). Alternatively, each of the emitting parts 300, 400, 500, and 600 may have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3).

The second electrode 220 is disposed on the substrate 102 above which the emissive layer 230 is disposed. The second electrode 220 may be disposed on a whole display area. The second electrode 220 may include a conductive material with a relatively low work function value compared to the first electrode 210 and may be a cathode.

An adhesive film 170 may be disposed on the second electrode 220 to prevent or reduce primarily outer moisture from penetrating into the OLED D. The adhesive film 170 may include, but is not limited to, optical clear resin (OCR).

An encapsulation film 190 may be disposed on the adhesive film 170 to further prevent outer moisture from penetrating into the OLED D. The encapsulation film may include transparent or semi-transparent material. For example, the encapsulation film 190 may include, but is not limited to, plastics such as polyimide, metal foil, and the like. Alternatively, the encapsulation film 190 may have, but is not limited to, a laminated structure of a first inorganic insulating film, an organic insulating film and a second inorganic insulating film.

The color filter layer 180 may be disposed correspondingly to the emission area between the thin film transistor Tr and the OLED D in the first pixel region SP1, the second pixel region SP2 and the third pixel region SP3. For example, the color filter layer 180 may include a first color filter pattern 182 disposed between the thin film transistor Tr and the OLED D corresponding to the first pixel region SP1, a second color filter pattern 184 disposed between the thin film transistor Tr and the OLED D corresponding to the second pixel region SP2 and a third color filter pattern 186 disposed between the thin film transistor Tr and the OLED D corresponding to the second pixel region SP3. As an example, the first color filter pattern 182 may include a red dye and/or a red pigment, the second color filter pattern 184 may include a green dye and/or a green pigment and the third color filter pattern 186 may include a blue dye and/or a blue pigment. The organic light emitting display device may realize a full color by introducing the color filter layer 180 in the first to third pixel regions SP1, SP2 and SP3.

The white light emitted from the OLED D may pass through the first color pattern 182, the second color filter pattern 184 and the third color filter pattern 186 each of which is disposed correspondingly to the first pixel region SP1, the second pixel region SP2 and the third pixel region SP3, respectively, so that red color light, the green color light and the blue color light may be displayed in the first pixel region SP1, the second pixel region SP2 and the third pixel region SP3, respectively.

The light emitted from the OLED D passes through the first electrode 210 and the color filter layer 182 is disposed under the OLED D in FIG. 2. The organic light emitting display device 100 may be a bottom-type emission. Alternatively, the light emitted from the OLED D may pass through the second electrode 220 and the color filter layer may be disposed between the OLED D and the encapsulation film 190 when the organic light emitting display device 100 is a top-emission type. For example, the color filter layer 180 may be attached to the OLED by the adhesive layer 170 in the organic light emitting display device 100 of the top-emission type. Alternatively, the color filter layer 180 may be disposed on the OLED D or the encapsulation 190.

In addition, a color conversion layer may be formed or disposed between the OLED D and the color filter layer 180. The color conversion layer may include a red color conversion layer, a green color conversion layer, and a blue color conversion layer, each of which is disposed correspondingly to the first to third pixel regions SP1, SP2, and SP3, respectively, to convert the white (W) color light to each of a red, green, and blue color lights, respectively. For example, the color conversion layer may include quantum dot so that the color purity of the organic light emitting display device 100 may be further improved. Alternatively, the organic light emitting display device 100 may comprise the color conversion layer instead of the color filter layer 180.

The organic light emitting display device 100 may further include a polarizing plate to reduce reflection of external light. For example, the polarizing plate may be a circular polarizing plate. The polarizing plate may be disposed under the substrate 102 when the organic light emitting display device 100 is the bottom-emission type. Alternatively, the polarizing plate may be disposed on the encapsulation film 190 when the organic light emitting display device 100 is the top-emission type. In addition, a cover window may be attached to the encapsulation film 190 or the polarizing plate in the organic light emitting display device 100 of the top-emission type. In this case, the substrate 102 and the cover window may have a flexible property, thus the organic light emitting display device 100 may be a flexible display device.

The OLED D is described in more detail. FIG. 3 which illustrates a schematic cross-sectional view of an organic light emitting diode in accordance with an example aspect of the present disclosure.

As illustrated in FIG. 3, the OLED D includes a first electrode 210, a second electrode 220 facing the first electrode 210 and an emissive layer 230 disposed between the first and second electrodes 210 and 220. The OLED D is disposed in each of the first to fourth pixel regions SP1, SP2, SP3, and SP4 which emits white color light. For example, the first pixel region SP1 may be a red pixel region, the second pixel region SP2 may be a green pixel region, the third pixel region SP3 may be a blue pixel region, and the fourth pixel region SP4 may be a white pixel region.

One of the first electrode 210 and the second electrode 220 may be an anode and the other of the first electrode 210 and the second electrode 220 may be a cathode. For example, the first electrode 210 may be the anode and the second electrode 220 may be the cathode. Alternatively, one of the first electrode 210 and the second electrode 220 may be a transmissive electrode and the other of the first electrode 210 and the second electrode 220 may be a reflective electrode.

As an example, the first electrode 210 may include, but is not limited to, undoped or doped metal oxide including indium tin oxide (ITO), indium zinc oxide (IZO), indium tin zinc oxide (ITZO), indium copper oxide (ICO), tin oxide (SnO₂), indium oxide (In₂O₃), cadmium doped zinc oxide (Cd:ZnO), fluorine doped tin oxide (F:SnO₂), indium doped tin oxide (In:SnO₂), gallium doped tin oxide (Ga:SnO₂), aluminum doped zinc oxide (Al:ZnO, AZO), and/or combinations thereof. Alternatively, the first electrode 210 may include metal material or non-metal material including nickel (Ni), platinum (Pt), gold (Au), silver (Ag), iridium (Ir) and/or carbon nanotube (CNT) in addition to the metal oxide.

The second electrode 220 may include, but is not limited to, calcium (Ca), barium (Ba), calcium/aluminum (Ca/Al), lithium fluoride/calcium (LiF/Ca), lithium fluoride/aluminum (LiF/Al), barium fluoride/aluminum (BaF₂/Al), cesium fluoride/aluminum (CsF/Al), calcium carbonate/aluminum (CaCO₃/Al), barium fluoride/calcium/aluminum (BaF₂/Ca/Al), aluminum (Al), magnesium (Mg), aluminum/magnesium (Al/Mg), gold doped magnesium (Au:Mg), silver doped magnesium (Ag:Mg), and/or combinations thereof. As an example, each of the first electrode 210 and the second electrode 220 may have a thickness, but is not limited to, from about 3 nm to about 300 nm.

The emissive layer 230 includes a first emitting part 300, a second emitting part 400, a third emitting part 500, and a fourth emitting part 600, each of which is disposed sequentially between the first electrode 210 and the second electrode 220. In other words, the emissive layer 230 comprises the first emitting part 300 disposed between the first electrode 210 and the second electrode 220, the second emitting part 400 disposed between the first emitting part 300 and the second electrode 220, the third emitting part 500 disposed between the second emitting part 400 and the second electrode 220, and the fourth emitting part 600 disposed between the third emitting part 500 and the second electrode 220. In addition, the emissive layer 230 may further include a first charge generation layer (CGL1) 370, a second charge generation layer (CGL2) 470, and a third charge generation layer (CGL3) 570, each of which is disposed between the emitting parts 300, 400, 500 and 600. In other words, the emissive layer 230 may include the CGL1 370 disposed between the first emitting part 300 and the second emitting part 400, the CGL2 470 disposed between the second emitting part 400 and the third emitting part 500 and the CGL3 570 disposed between the third emitting part 500 and the fourth emitting part 600.

The first emitting part 300 includes a first emitting material layer (EML1) 340. The first emitting part 300 may include at least one of a hole injection layer (HIL) 310 disposed between the first electrode 210 and the EML1 340, a first hole transport layer (HTL1) 320 disposed between the HIL 310 and the EML1 340 and a first electron transport layer (ETL1) 360 disposed between the EML1 340 and the CGL1 370. Alternatively, the first emitting part 300 may further include a first electron blocking layer (EBL1) 330 disposed between the HTL1 320 and the EML1 340 and/or a first hole blocking layer (HBL1) 350 disposed between the EML1 340 and the ETL1 360.

The second emitting part 400 includes a second emitting material layer (EML2) 440. The second emitting part 400 may include at least one of a second hole transport layer (HTL2) 420 disposed between the CGL1 370 and the EML2 440 and a second electron transport layer (ETL2) 460 disposed between the EML2 440 and the CGL2 470. Alternatively, the second emitting part 400 may further include a second electron blocking layer (EBL2) 430 disposed between the HTL2 420 and the EML2 440 and/or a second hole blocking layer (HBL2) 450 disposed between the EML2 440 and the ETL2 460.

The third emitting part 500 includes a third emitting material layer (EML3) 540. The third emitting part 500 may include at least one of a third hole transport layer (HTL3) 520 disposed between the CGL2 470 and the EML3 540 and a third electron transport layer (ETL3) 560 disposed between the EML3 540 and the CGL3 570. Alternatively, the third emitting part 500 may further include a third electron blocking layer (EBL3) 530 disposed between the HTL3 520 and the EML3 540 and/or a third hole blocking layer (HBL3) 550 disposed between the EML3 540 and the ETL3 560.

The fourth emitting part 600 includes a fourth emitting material layer (EML4) 640. The fourth emitting part 600 may include at least one of a fourth hole blocking layer (HTL4) 620 disposed between the CGL3 570 and the EML4 640, a fourth electron transport layer (ETL4) 660 disposed between the EML4 640 and the second electrode 220 and an electron injection layer (EIL) 670 disposed between the ETL4 660 and the second electrode 220. Alternatively, the fourth emitting part 600 may further include a fourth electron blocking layer (EBL4) 630 disposed between the HTL4 620 and the EML4 640 and/or a fourth hole blocking layer (HBL4) 650 disposed between the EML4 640 and the ETL4 660.

One of the EML1 to EML4 340, 440, 540, and 640 may be an emitting material layer where a red emitting material layer and a blue emitting material layer are contacted, two others of the EML1 to EML4 340, 440, 540, and 640 may be a blue emitting material layer and others of the EML1 to EML4 340, 440, 540, and 640 may be a green emitting material layer so that the OLED D may realize a white emission. Hereinafter, the OLED D where the EML1 340 is an emitting material layer where the red emitting material layer and the blue emitting material layer are contacted each other, the EML2 440 and the EML4 640 are blue emitting material layers and the EML3 540 is a green emitting material layer is described in detail.

The HIL 310 is disposed between the first electrode 210 and the HTL1 320 which improves interfacial property between the inorganic first electrode 210 and the organic HTL1 320. In one example aspect, the HIL 310 may include, but is not limited to, 4, 4′, 4″-tris (3-methylphenylamino) triphenylamine (MTDATA), 4, 4′, 4″-tris (N, N-diphenyl-amino) triphenylamine (NATA), 4, 4′, 4″-tris (N-(naphthalene-1-yl)-N-phenyl-amino) triphenylamine (IT-NATA), 4, 4′, 4″-tris (N-(naphthalene-2-yl)-N-phenyl-amino) triphenylamine (2T-NATA), copper phthalocyanine (CuPc), tris (4-carbazoyl-9-yl-phenyl) amine (TCTA), N, N′-diphenyl-N, N′-bis (1-naphthyl)-1, 1′-biphenyl-4, 4″-diamine (NPB; NPD), N, N′-bis {4-[bis (3-methylphonyl) amino]phenyl}-N, N′-diphenyl-4, 4′-biphenyldiamine (DNTPD), 1, 4, 5, 8, 9, 11-hexaazatriphenylenehexacarbonitrile (dipyrazino [2, 3-f: 2′3′-h]quinoxaline-2, 3, 6, 7, 10, 11-hexacarbonitrile; HAT-CN), 2, 3, 5, 6-tetrafluoro-7, 7, 8, 8-tetracyanoquinodimethane (F4-TCNQ), 1, 3, 4, 5, 7, 8-hexafluorotetracyanonaphthoquinodimethane (F6-TCNNQ), 1, 3, 5-tris [4-(diphenylamino) phenyl]benzene (TDAPB), poly (3, 4-ethylenedioxythiphene) polystyrene sulfonate (PEDOT/PSS), N-(biphenyl-4-yl)-9, 9-dimethyl-N-(4-(9-phenyl-9H-carbazol-3-yl) phenyl)-9H-fluoren-2-amine, N, N′-diphenyl-N, N′-di [4-(N, N′-diphenyl-amino) phenyl]benzidine (NPNPB), MgF₂, CaF₂ and/or combinations thereof.

In an alternative aspect, the HIL 310 may include a host of the above hole injecting material and/or hole transporting material below, and a P-type dopant. The P-type dopant may include, but is not limited to, HAT-CN, F4-TCNQ, F6-TCNNQ, NPD9 and/or combinations thereof. The contents of the P-type dopant in the HIL 310 may be, but is not limited to, from about 1 wt. % to about 10 wt. %. For example, the HIL 310 may have a thickness, but is not limited to, from about 1 nm to about 100 nm. The HIL 310 may be omitted in compliance of the OLED D property.

Each of the HTL1 320, the HTL2 420, the HTL3 520, and the HTL4 620 provides holes to the EML1 340, the EML2 440, the EML3 540, and the EML4 640, respectively. In one example aspect, each of the HTL1 320, the HTL2 420, the HTL3 520, and the HTL4 620 may independently include, but is not limited to, N, N′-diphenyl-N, N′-bis (3-methylphenyl)-1, 1′-biphenyl-4, 4′-diamine (TPD), NPB (NPD), DNTPD, N4, N4, N4′, N4′-tetra [(1, 1′-biphenyl)-4-yl]-(1, 1′-biphenyl)-4, 4′-diamine (BPBPA), 4, 4′-bis (N-carbazolyl)-1, 1′-biphenyl (CBP), poly [N, N′-bis (4-butylphenyl)-N, N′-bis (phenyl)-benzidine] (Poly-TPD), poly [(9, 9-dioctylfluorenyl-2, 7-diyl)-co-(4, 4′-(N-(4-sec-butylphenyl) diphenylamine))] (TFB), di-[4-(N, N-di-p-tolyl-amino)-phenyl]cyclohexane (TAPC), 3, 5-di (9H-carbazol-9-yl)-N, N-diphenylaniline (DCDPA), N-(biphenyl-4-yl)-9, 9-dimethyl-N-(4-(9-phenyl-9H-carbazol-3-yl) phenyl)-9H-fluoren-2-amine, N-(biphenyl-4-yl)-N-(4-(9-phenyl-9H-carbazol-3-yl) phenyl) biphenyl-4-amine), N-([1,1′-biphenyl]-4-yl)-9, 9-dimethyl-N-(4-(9-phenyl-9H-carbazol-3-yl) phenyl)-9H-fluoren-2-amine and/or combinations thereof. For example, each of the HTL1 320, the HTL2 420, the HTL3 520, and the HTL4 620 may have a thickness of, but is not limited to, from about 20 nm to about 200 nm.

Each of the ETL1 360, the ETL2 460, the ETL3 560, and the ETL4 660 includes materials with high electron mobility and provides electrons stably to the EML1 340, the ETL2 440, the EML3 540, and the EML4 640, respectively, by efficient electron transportations. As an example, each of the ETL1 360, the ETL2 460, the ETL3 560, and the ETL4 660 may independently include at least one of an oxadiazole-based compound, a triazole-based compound, a phenanthroline-based compound, a benzoxazole-based compound, a benzothiazole-based compound, a benzimidazole-based compound, or a triazine-based compound.

For example, each of the ETL1 360, the ETL2 460, the ETL3 560, and the ETL4 660 may independently include, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 2,2′,2″-(1,3,5-benzenetriyl)-tris(1-phenyl-1-H-benzimidazole (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl)4,7-diphenyl-1,10-phenanthroline (NBphen), 2,9-dimethyl-4,7-diphenyl-1,10-phenanthroline (BCP), 3-(4-diphenyl)-4-phenyl-5-tert-butylphenyl-1,2,4-triazole (TAZ), 4-(naphthalene-1-yl)-3,5-diphenyl-4H-1,2,4-triazole (NTAZ), 3,5-tri(p-pyrid-3-yl-phenyl)benzene (TpPyPB), 2,4,6-tris(3′-(pyridin-3-yl)biphenyl-3-yl)1,3,5-triazine (TmPPPyTz), poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), TSPO1, 2-[4-(9,10-di-2-naphthalen2-yl-2-anthracen-2-yl)phenyl]-1-phenyl-1H-benzimidazole (ZADN), and/or combinations thereof.

The EIL 670 is disposed between the second electrode 220 and the ETL4 660 which may improve physical properties of the second electrode 220 and therefore, may enhance the lifespan of the OLED D. In one example aspect, the EIL 670 may include, but is not limited to, an alkali metal halide and/or an alkaline earth metal halide such as LiF, CsF, NaF, BaF₂, and the like, and/or an organometallic compound such as Liq, lithium benzoate, sodium stearate, and the like.

As an example, each of the ETL1 to ETL4 (360, 460, 560, and 660) and the EIL 670 may have a thickness of, but is not limited to, from about 1 nm to about 100 nm. Alternatively, the EIL 670 may be omitted.

Alternatively, the electron transporting material and the electron injecting material are mixed to form a single electron transport-electron injection layer. The electron transporting material and the electron injection material may be admixed, but is not limited to, with a weight ratio of from about 4:1 to about 1:4, for example, from about 2:1 to about 1:2.

Each of the EBL1 330, the EBL2 430, the EBL3 530, and the EBL4 640 prevents electrons injected into the EML1 to EML4 340, 440, 540, and 640 from leaking to the first electrode 210, the CGL1 370, the CGL2 470, and the CGL3 570, respectively.

For example, each of the EBL1 330, the EBL2 430, the EBL3 530, and the EBL4 630 may independently include, but is not limited to, TCTA, tris [4-(diethylamino) phenyl]amine, N-(biphenyl-4-yl)-9, 9-dimethyl-N-(4-(9-phenyl-9H-carbazol-3-yl) phenyl)-9H-fluoren-2-amine, TCTA, MTDATA, 1, 3-bis (carbazol-9-yl) benzene (mCP), 3, 3-di (9H-carbazol-9-yl) biphenyl (mCBP), CuPc, DNTPD, TDAPB, DCDPA, 2, 8-bis (9-phenyl-9H-carbazol-3-yl) dibenzo[b, d]thiophene and/or combinations thereof. Alternatively, at least one of the EBL1 330, the EBL2 430, the EBL3 530, and the EBL4 630 may be omitted.

Each of the HBL1 350, the HBL2 450, the HBL3 550, and the HBL4 650 prevents holes injected into the EML1 to EML4 340, 440, 540, and 640 from leaking to the CGL1 370, the CGL2 470, the CGL3 570, and the second electrode 220, respectively.

In one example aspect, each of the HBL1 350, the HBL2 450, the HBL3 550, and the HBL4 650 may independently include, but is not limited to, at least one of an oxadiazole-based compound, a triazole-based compound, a phenanthroline-based compound, a benzoxazole-based compound, a benzothiazole-based compound, a benzimidazole-based compound, or a triazine-based compound.

For example, each of the HBL1 350, the HBL2 450, the HBL3 550, and the HBL4 650 may independently include a material having a relatively low HOMO energy level compared to the luminescent materials in EML1 to EML4 340, 440, 540, and 640. Each of the HBL1 to HBL4 350, 450, 550, and 650 may independently include, but is not limited to, BCP, BAlq, Alq3, PBD, spiro-PBD, Liq, bis-4, 5-(3, 5-di-3-pyridylphenyl)-2-methylpyrimidine (B3PYMPM), DPEPO, 9-(6-(9H-carbazol-9-yl) pyridine-3-yl)-9H-3, 9′-bicarbazole, TSPO1 and/or combinations thereof. Alternatively, at least one of the HBL1 to HBL4 350, 450, 550, and 650 may be omitted.

As an example, each of the EBL1 to EBL4 330, 430, 530, and 630, and the HBL1 to HBL4 350, 450, 550, and 650 may have a thickness of, but is not limited to, from about 1 nm to about 100 nm.

The CGL1 370 is disposed between the first emitting part 300 and the second emitting part 400. The CGL1 370 includes a first N-type charge generation layer (N-CGL1) 380 disposed adjacently to the first emitting part 300 and a first P-type charge generation layer (P-CGL1) 390 disposed adjacently to the second emitting part 400. The N-CGL1 380 injects electrons to the EML1 340 of the first emitting part 300 and the P-CGL1 390 injects holes to the EML2 440 of the second emitting part 400.

The CGL2 470 is disposed between the second emitting part 400 and the third emitting part 500. The CGL2 470 includes a second N-type charge generation layer (N-CGL2) 480 disposed adjacently to the second emitting part 400 and a second P-type charge generation layer (P-CGL2) 490 disposed adjacently to the third emitting part 500. The N-CGL2 480 injects electrons to the EML2 440 of the second emitting part 400 and the P-CGL2 490 injects holes to the EML3 540 of the third emitting part 500.

The CGL3 570 is disposed between the third emitting part 500 and the fourth emitting part 600. The CGL3 570 includes a third N-type charge generation layer (N-CGL3) 580 disposed adjacently to the third emitting part 500 and a third P-type charge generation layer (P-CGL3) 590 disposed adjacently to the fourth emitting part 600. The N-CGL3 580 injects electrons to the EML3 540 of the third emitting part 500 and the P-CGL2 590 injects holes to the EML4 640 of the fourth emitting part 600.

Each of the N-CGL1 to N-CGL3 380, 480 and 580 may be an organic layer doped with an alkali metal such as Li, Na, K, Cs, and/or an alkaline earth metal such as Mg, Sr, Ba and Ra. For example, the host in each of the N-CGL1 to N-CGL3 380, 480, and 580 may include, but is not limited to, phenanthroline-based organic compound such as Bphen and MTDATA. The contents of the alkali metal or the alkaline earth metal in each of the N-CGL1 to N-CGL3 380, 480, and 580 may range from about 0.01 wt. % and about 30 wt. %.

Each of the P-CGL1 to P-CGL3 390, 490, and 590 may include, but is not limited to, inorganic material selected from the group consisting of WOₓ, MoOₓ, Bc₂O₃, V₂O₅, and combinations thereof and/or organic material selected from the group consisting of NPD, DNTPD, HAT-CN, F4-TCNQ, F6-TCNNQ, TPD, N, N, N′, N′-tetranaphthalenyl-benzidine (TNB), TCTA, N, N′-dioctyl-3, 4, 9, 10-perylenedicarboximide (PTCDI-C8) and/or combinations thereof. Alternatively, each of the P-CGL1 to P-CGL3 390, 490, and 590 may independently include a host of NPD, DNTPD, TPD, TNB, TCTA and/or combinations thereof, and a P-type dopant of F4-TCNQ, F6-TCNNQ, NPD-9 and/or combinations thereof. The contents of the P-type dopant in each of the P-CGL1 to P-CGL3 390, 490, and 590 may be independently, but is not limited to, from about 1 wt. % to about 30 wt. %, for example, from about 3 wt. % to about 25 wt. %.

The EML1 340 may be a red-blue emitting material layer wherein the red emitting material layer and the blue emitting material layer are contacted each other. The EML1 340 comprises a red emitting material layer (R-EML) 340A disposed between the first electrode 210 and the CGL1 370 and a first blue emitting material layer 340 (B-EML1) 340B disposed between the R-EML 340A and the CGL1 370.

The B-EML1 340B may include a blue emitter (blue dopant) 342, a first host 344, and optionally, a second host 345. The R-EML 340A may include a red emitter (red dopant) 346 and a third host 348.

The blue emitter 342 may include at least one of a blue fluorescent material, a blue phosphorescent material, and a blue delayed fluorescent material, which may be blue fluorescent material. For example, the blue emitter 342 may include, but is not limited to, perylene, 4, 4′-bis [4-(di-p-tolylamino) styryl]biphenyl (DPAVBi), 4-(di-p-tolylamino)-4-4′-[(di-p-tolylamino) styryl]stilbene (DPAVB), 4, 4′-bis [4-(diphenylamino) styryl]biphenyl (BDAVBi), 2, 7-bis (4-diphenylamino) styryl)-9, 9-spirofluorene (spiro-DPVBi), [1, 4-bis [2-[4-[N, N-di (p-tolyl) amino]phenyl]vinyl]benzene (DSB), 1-4-di-[4-(N, N-diphenyl) amino]styryl-benzene (DSA), 2, 5, 8, 11-tetra-tert-butylperylene (TBPe), bis (2-hydroxylphenyl)-pyridine) beryllium (Bepp₂), 9-(9-phenylcarbazoyl-3-yl)-10-(naphthalene-1-yl)anthracene (PCAN), mer-tris(1-phenyl-3-methylimidazolin-2-ylidene-C,C(2)′iridium(III) (mer-Ir(pmi)₃), fac-tris(1,3-diphenyl-benzimidazolin-2-ylidene-C,C(2)′iridium(III) (fac-Ir(dpbic)₃), bis(3,4,5-trifluoro-2-(2-pyridyl)phenyl-(2-carboxypyridyl)iridium(III) ((Ir(tfpd)₂pic), tris(2-(4,6-difluorophenyl)pyridine))iridium(III) ((Ir(Fppy)₃), bis[2-(4,6-difluorophenyl)pyridinato-C²,N](picolinato)iridium(III) (FIrpic), DABNA-1, DABNA-2, t-DABNA, v-DABNA and/or combinations thereof.

The first host 344 may have a lowest unoccupied molecular orbital (LUMO) energy level and/or a highest occupied molecular orbital (HOMO) energy level each of which may be higher than a LUMO energy level and a HOMO energy level of the second host 345. In one example aspect, the first host 344 may include an organic compound having the following structure of Chemical Formula 1:

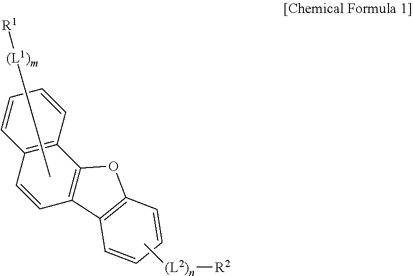

wherein
R¹ and R² are independently selected from a group consisting of an unsubstituted C₆-C₃₀ aryl group, a substituted C₆-C₃₀ aryl group, an unsubstituted C₃-C₃₀ hetero aryl group, a substituted C₃-C₃₀ hetero aryl group, an unsubstituted C₆-C₃₀ aryl amino group, a substituted C₆-C₃₀ aryl amino group, an unsubstituted C₃-C₃₀ hetero aryl amino group, and a substituted C₃-C₃₀ hetero aryl amino group, where one of R¹ and R² is the unsubstituted C₆-C₃₀ aryl group, a substituted C₆-C₃₀ aryl group, the unsubstituted C₃-C₃₀ hetero aryl group, or the substituted C₃-C₃₀ hetero aryl group and another of R¹ and R² is the unsubstituted C₆-C₃₀ aryl amino group, the substituted C₆-C₃₀ aryl amino group, the unsubstituted C₃-C₃₀ hetero aryl amino group, or the substituted C₃-C₃₀ hetero aryl amino group;
L¹ and L² are independently selected from a group consisting of an unsubstituted C₆-C₃₀ arylene group, a substituted C₆-C₃₀ arylene group, an unsubstituted C₃-C₃₀ hetero arylene group, and substituted C₃-C₃₀ hetero arylene group; and
m and n are independently 0 or 1.

In various aspects, R¹ and R² are independently selected from a group consisting of an unsubstituted C₆-C₂₀ aryl group, a substituted C₆-C₂₀ aryl group, an unsubstituted C₃-C₂₀ hetero aryl group, a substituted C₃-C₂₀ hetero aryl group, an unsubstituted C₆-C₃₀ aryl amino group, a substituted C₆-C₃₀ aryl amino group, an unsubstituted C₃-C₃₀ hetero aryl amino group, and a substituted C₃-C₃₀ hetero aryl amino group, where one of R¹ and R² is the unsubstituted C₆-C₂₀ aryl group, a substituted C₆-C₂₀ aryl group, the unsubstituted C₃-C₂₀ hetero aryl group, or the substituted C₃-C₂₀ hetero aryl group and another of R¹ and R² is the unsubstituted C₆-C₃₀ aryl amino group, the substituted C₆-C₃₀ aryl amino group, the unsubstituted C₃-C₃₀ hetero aryl amino group, or the substituted C₃-C₃₀ hetero aryl amino group;
L¹ and L² are independently selected from a group consisting of an unsubstituted C₆-C₂₀ arylene group, a substituted C₆-C₂₀ arylene group, an unsubstituted C₃-C₂₀ hetero arylene group, and substituted C₃-C₂₀ hetero arylene group; and
m and n are independently 0 or 1.

As used herein, the term “unsubstituted” means that hydrogen is directly linked to a carbon atom. “Hydrogen”, as used herein, may refer to protium, deuterium and tritium.

As used herein, “substituted” means that the hydrogen is replaced with a substituent. The substituent may comprise, but is not limited to, an unsubstituted or a halogen-substituted C₁-C₂₀ alkyl group, an unsubstituted or a halogen-substituted C₁-C₂₀ alkoxy, a halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, a C₁-C₁₀ alkyl silyl group, a C₁-C₁₀ alkoxy silyl group, a C₃-C₂₀ cyclo alkyl silyl group, a C₆-C₃₀ aryl silyl group, a C₃-C₃₀ hetero aryl silyl group, an unsubstituted or substituted C₆-C₃₀ aryl group, an unsubstituted C₃-C₃₀ hetero aryl group, or substituted C₃-C₃₀ hetero aryl group.

As used herein, the term “hetero” in terms such as “a hetero aryl group”, and “a hetero arylene group” and the likes means that at least one carbon atom, for example 1 to 5 carbons atoms, constituting an aliphatic chain, an alicyclic group, a ring, or an aromatic group or ring which is substituted with at least one hetero atom selected from the group consisting of N, O, S and P.

The aryl group may independently include, but is not limited to, an unfused or a fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl, or spiro-fluorenyl.

The hetero aryl group may independently include, but is not limited to, an unfused or a fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthlazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thioazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the C₆-C₃₀ aryl group, the C₃-C₃₀ hetero aryl group, the C₆-C₃₀ aryl amino group, the C₆-C₃₀ aryl, a C₃-C₃₀ hetero aryl amino group, may be independently unsubstituted or substituted with at least one group selected from a C₁-C₁₀ alkyl, a C₆-C₃₀ aryl and a C₃-C₃₀ hetero aryl.

The aryl amino group means that two aryl groups are substituted to a nitrogen atom; the aryl and hetero aryl amino group means that one aryl group and one hetero aryl groups are linked to a nitrogen atom; and the hetero aryl amino group means that two hetero aryl groups are linked to a nitrogen atom. For example, the aryl amino group may include, but is not limited to, diphenyl amino, phenyl-biphenyl amino, phenyl-naphthyl amino, biphenyl-biphenyl amino, phenyl-fluorenyl (may be substituted with phenyl and/or alkyl) amino, biphenyl-fluorenyl (may be substituted with phenyl and/or alkyl) amino, naphthyl-fluorenyl (may be substituted with phenyl and/or alkyl) amino and the like, where each of the aryl group linked to the nitrogen atom may be unsubstituted or substituted with alkyl, aryl (e.g., phenyl, naphthyl and the like) and/or hetero aryl (e.g., pyridyl, carbazolyl and the like).

The aryl and hetero aryl amino group may include, but is not limited to, a phenyl-dibenzofuranyl amino, a phenyl-dibenzothiophenyl amino, a phenyl-carbazolyl amino, and the like, where each of the aryl group and the hetero aryl group linked to the nitrogen atom may be unsubstituted or substituted with alkyl, aryl (e.g., phenyl, naphthyl and the like) and/or hetero aryl (e.g., pyridyl, carbazolyl and the like).

The hetero aryl amino group may include, but is not limited to, dicarbazolyl amino and the like, where each of the hetero aryl group linked to the nitrogen atom may be unsubstituted or substituted with alkyl, aryl (e.g., phenyl, naphthyl and the like) and/or hetero aryl (e.g., pyridyl, carbazolyl and the like).

In one aspect, the first host 344 may include, but is not limited to, at least one organic compound having the structure of Chemical Formula 2:

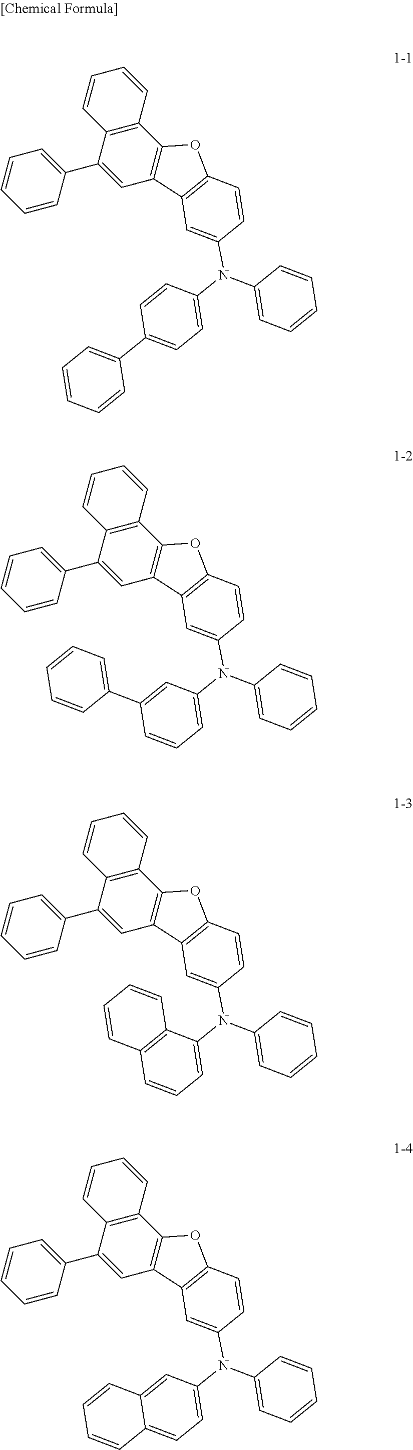 [SMILES: c1ccc(-c2ccc(N(c3ccccc3)c3ccc4oc5c6ccccc6c(-c6ccccc6)cc5c4c3)cc2)cc1 ; c1ccc(-c2cccc(N(c3ccccc3)c3ccc4oc5c6ccccc6c(-c6ccccc6)cc5c4c3)c2)cc1 ; c1ccc(-c2cc3c4cc(N(c5ccccc5)c5cccc6ccccc56)ccc4oc3c3ccccc23)cc1 ; c1ccc(-c2cc3c4cc(N(c5ccccc5)c5ccc6ccccc6c5)ccc4oc3c3ccccc23)cc1]

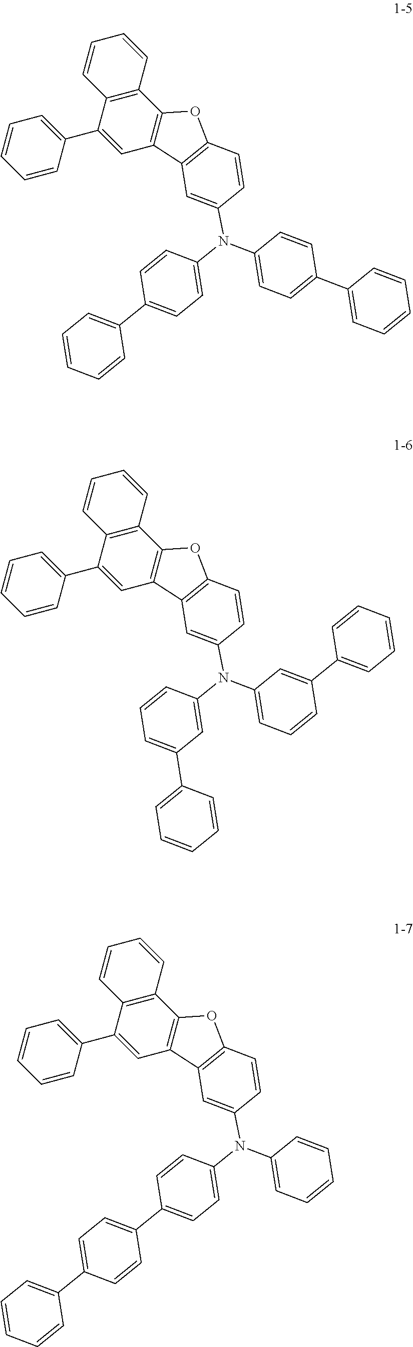 [SMILES: c1ccc(-c2ccc(N(c3ccc(-c4ccccc4)cc3)c3ccc4oc5c6ccccc6c(-c6ccccc6)cc5c4c3)cc2)cc1 ; c1ccc(-c2cccc(N(c3cccc(-c4ccccc4)c3)c3ccc4oc5c6ccccc6c(-c6ccccc6)cc5c4c3)c2)cc1 ; c1ccc(-c2ccc(-c3ccc(N(c4ccccc4)c4ccc5oc6c7ccccc7c(-c7ccccc7)cc6c5c4)cc3)cc2)cc1]

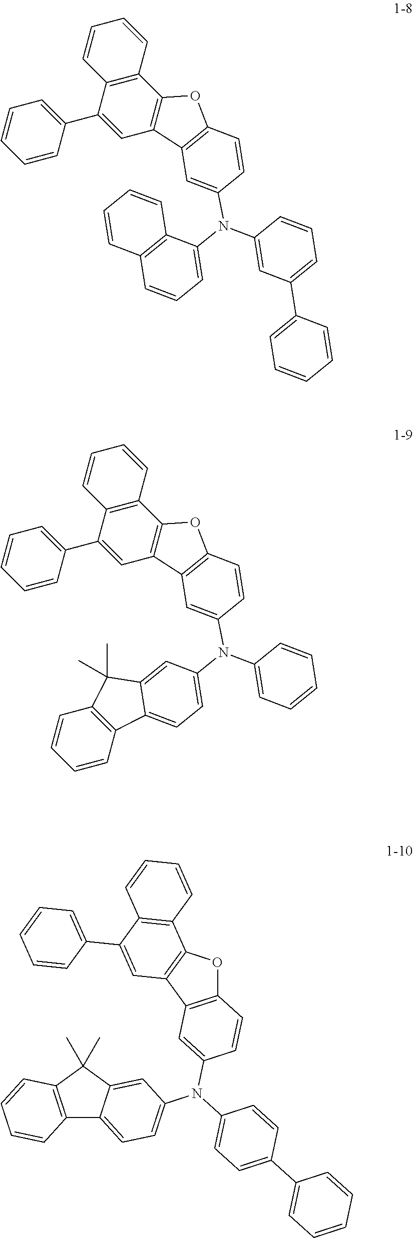 [SMILES: c1ccc(-c2cccc(N(c3ccc4oc5c6ccccc6c(-c6ccccc6)cc5c4c3)c3cccc4ccccc34)c2)cc1 ; CC1(C)c2ccccc2-c2ccc(N(c3ccccc3)c3ccc4oc5c6ccccc6c(-c6ccccc6)cc5c4c3)cc21 ; CC1(C)c2ccccc2-c2ccc(N(c3ccc(-c4ccccc4)cc3)c3ccc4oc5c6ccccc6c(-c6ccccc6)cc5c4c3)cc21]

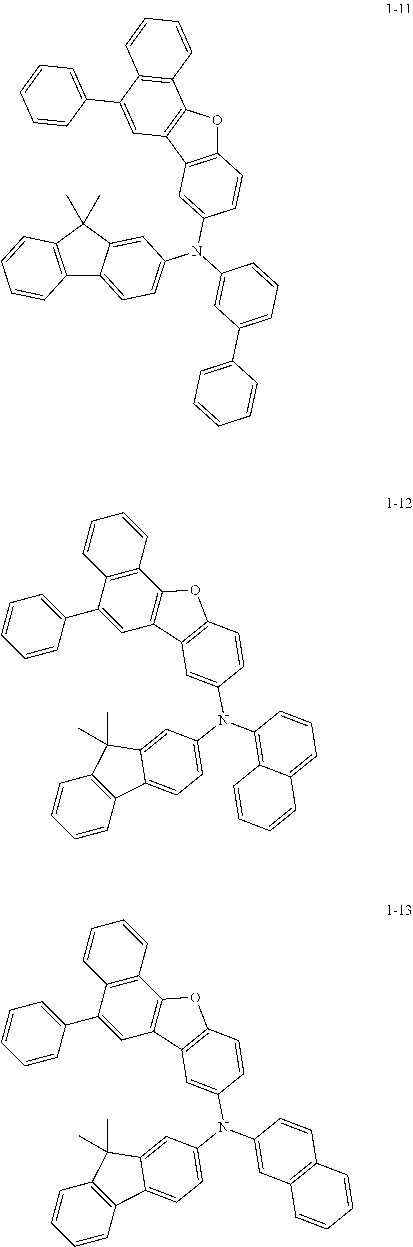 [SMILES: CC1(C)c2ccccc2-c2ccc(N(c3cccc(-c4ccccc4)c3)c3ccc4oc5c6ccccc6c(-c6ccccc6)cc5c4c3)cc21 ; CC1(C)c2ccccc2-c2ccc(N(c3ccc4oc5c6ccccc6c(-c6ccccc6)cc5c4c3)c3cccc4ccccc34)cc21 ; CC1(C)c2ccccc2-c2ccc(N(c3ccc4ccccc4c3)c3ccc4oc5c6ccccc6c(-c6ccccc6)cc5c4c3)cc21]

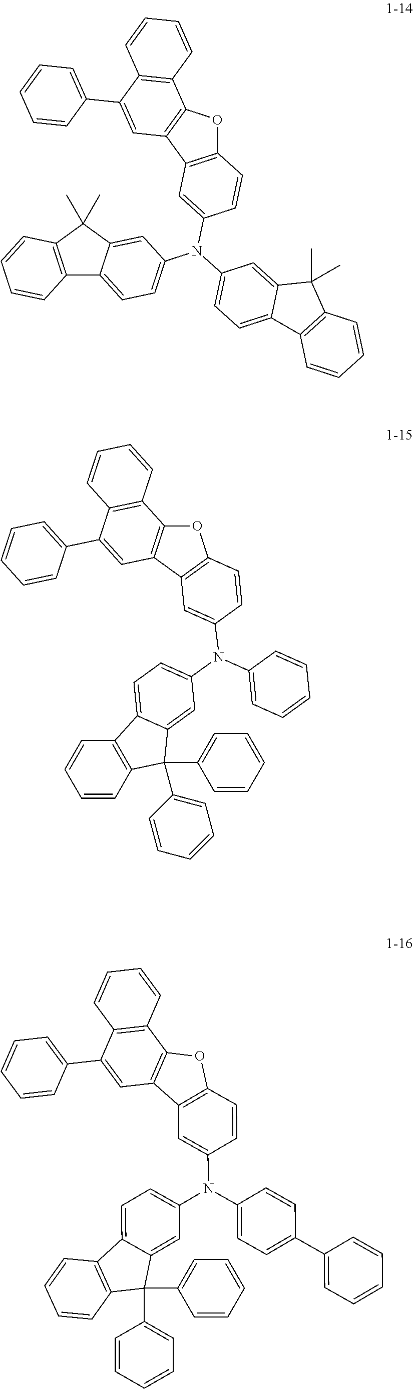 [SMILES: CC1(C)c2ccccc2-c2ccc(N(c3ccc4c(c3)C(C)(C)c3ccccc3-4)c3ccc4oc5c6ccccc6c(-c6ccccc6)cc5c4c3)cc21 ; c1ccc(-c2cc3c4cc(N(c5ccccc5)c5ccc6c(c5)C(c5ccccc5)(c5ccccc5)c5ccccc5-6)ccc4oc3c3ccccc23)cc1 ; c1ccc(-c2ccc(N(c3ccc4c(c3)C(c3ccccc3)(c3ccccc3)c3ccccc3-4)c3ccc4oc5c6ccccc6c(-c6ccccc6)cc5c4c3)cc2)cc1]

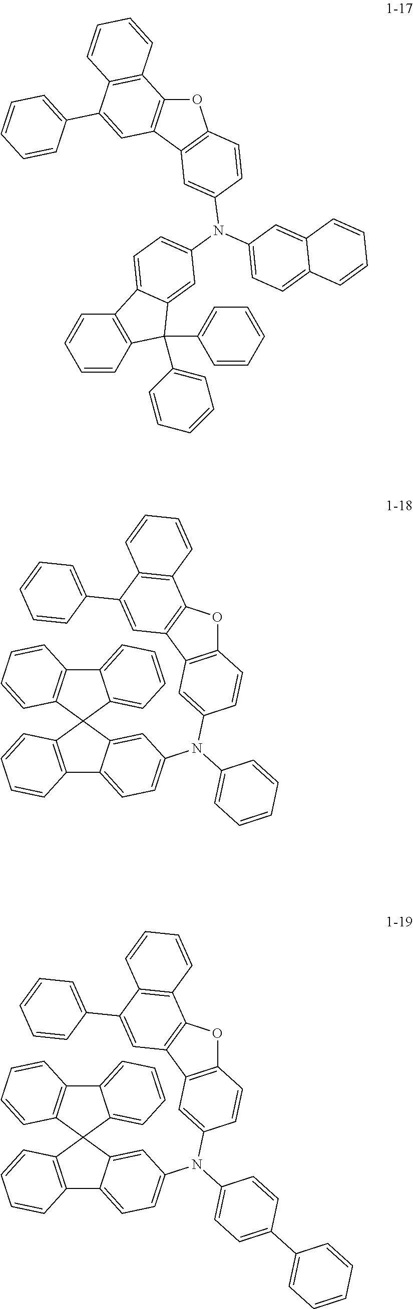 [SMILES: c1ccc(-c2cc3c4cc(N(c5ccc6c(c5)C(c5ccccc5)(c5ccccc5)c5ccccc5-6)c5ccc6ccccc6c5)ccc4oc3c3ccccc23)cc1 ; c1ccc(-c2cc3c4cc(N(c5ccccc5)c5ccc6c(c5)C5(c7ccccc7-c7ccccc75)c5ccccc5-6)ccc4oc3c3ccccc23)cc1 ; c1ccc(-c2ccc(N(c3ccc4c(c3)C3(c5ccccc5-c5ccccc53)c3ccccc3-4)c3ccc4oc5c6ccccc6c(-c6ccccc6)cc5c4c3)cc2)cc1]

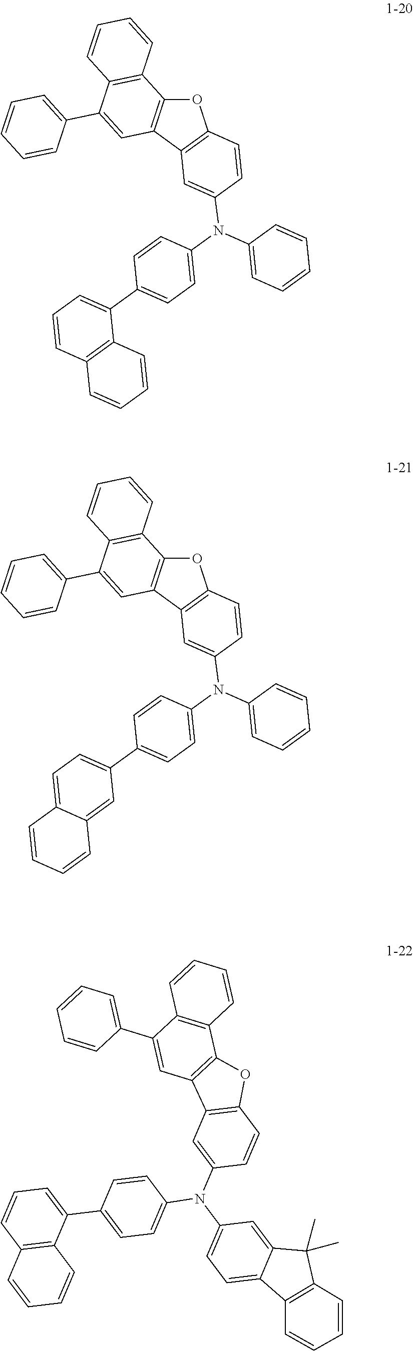 [SMILES: c1ccc(-c2cc3c4cc(N(c5ccccc5)c5ccc(-c6cccc7ccccc67)cc5)ccc4oc3c3ccccc23)cc1 ; c1ccc(-c2cc3c4cc(N(c5ccccc5)c5ccc(-c6ccc7ccccc7c6)cc5)ccc4oc3c3ccccc23)cc1 ; CC1(C)c2ccccc2-c2ccc(N(c3ccc(-c4cccc5ccccc45)cc3)c3ccc4oc5c6ccccc6c(-c6ccccc6)cc5c4c3)cc21]

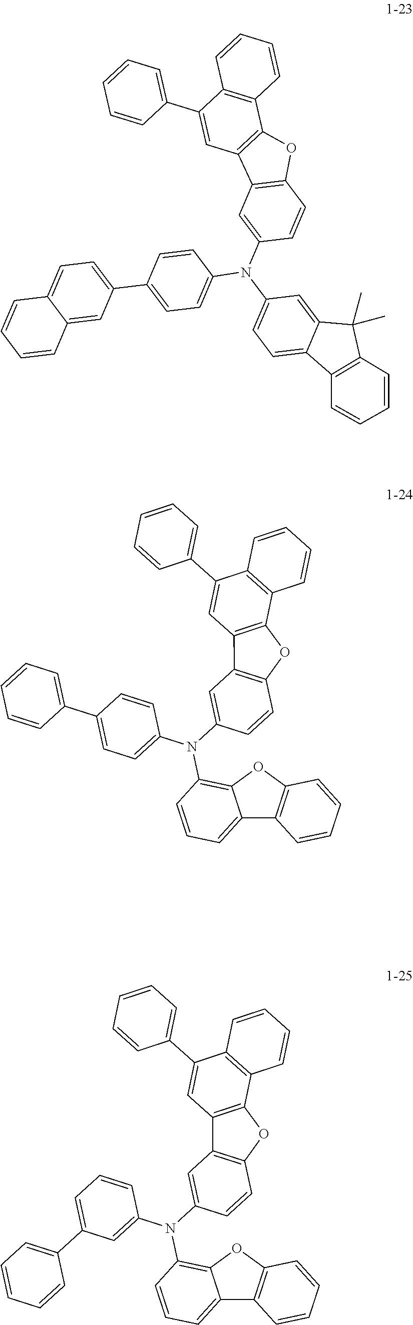 [SMILES: CC1(C)c2ccccc2-c2ccc(N(c3ccc(-c4ccc5ccccc5c4)cc3)c3ccc4oc5c6ccccc6c(-c6ccccc6)cc5c4c3)cc21 ; c1ccc(-c2ccc(N(c3ccc4oc5c6ccccc6c(-c6ccccc6)cc5c4c3)c3cccc4c3oc3ccccc34)cc2)cc1 ; c1ccc(-c2cccc(N(c3ccc4oc5c6ccccc6c(-c6ccccc6)cc5c4c3)c3cccc4c3oc3ccccc34)c2)cc1]

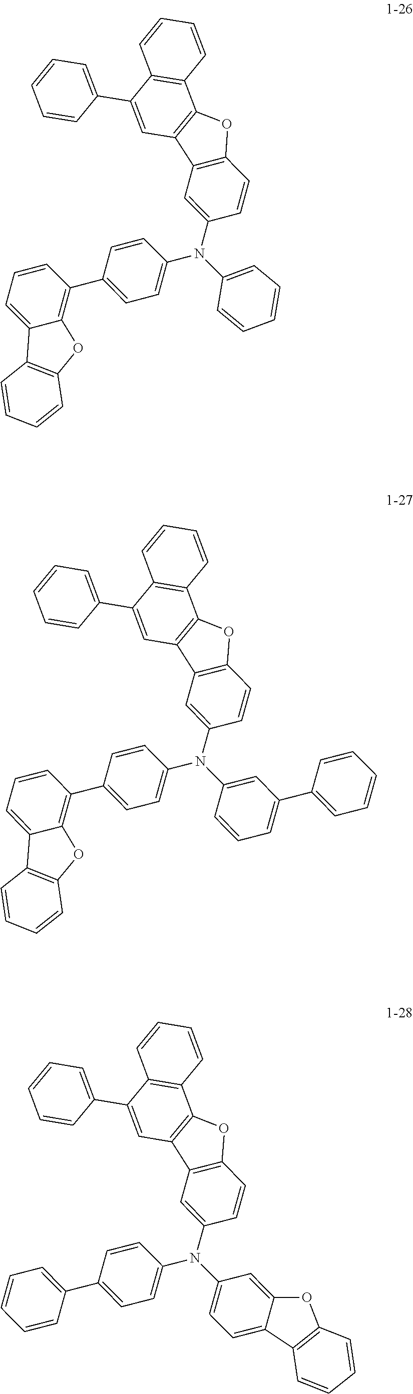 [SMILES: c1ccc(-c2cc3c4cc(N(c5ccccc5)c5ccc(-c6cccc7c6oc6ccccc67)cc5)ccc4oc3c3ccccc23)cc1 ; c1ccc(-c2cccc(N(c3ccc(-c4cccc5c4oc4ccccc45)cc3)c3ccc4oc5c6ccccc6c(-c6ccccc6)cc5c4c3)c2)cc1 ; c1ccc(-c2ccc(N(c3ccc4c(c3)oc3ccccc34)c3ccc4oc5c6ccccc6c(-c6ccccc6)cc5c4c3)cc2)cc1]

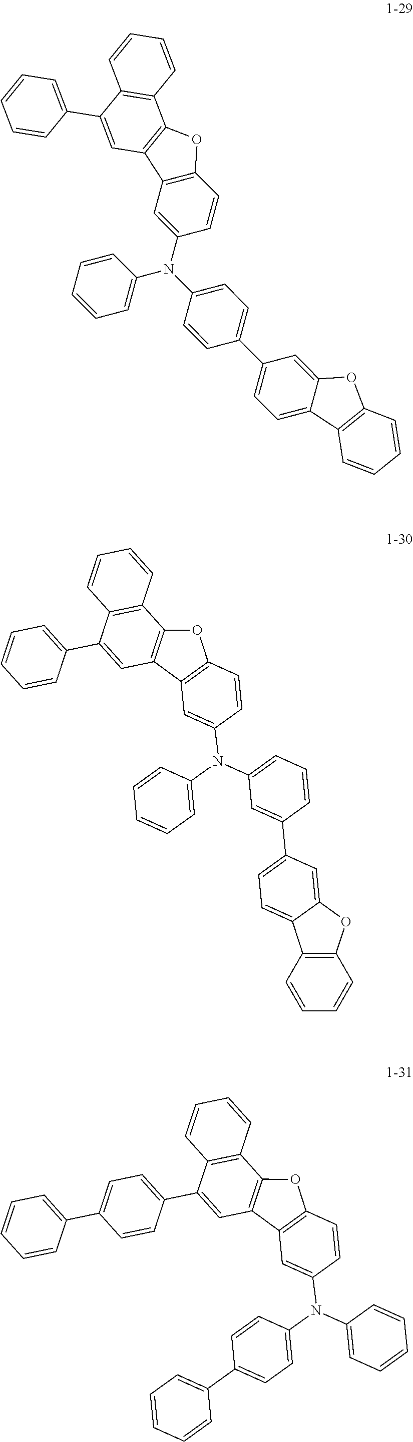 [SMILES: c1ccc(-c2cc3c4cc(N(c5ccccc5)c5ccc(-c6ccc7c(c6)oc6ccccc67)cc5)ccc4oc3c3ccccc23)cc1 ; c1ccc(-c2cc3c4cc(N(c5ccccc5)c5cccc(-c6ccc7c(c6)oc6ccccc67)c5)ccc4oc3c3ccccc23)cc1 ; c1ccc(-c2ccc(-c3cc4c5cc(N(c6ccccc6)c6ccc(-c7ccccc7)cc6)ccc5oc4c4ccccc34)cc2)cc1]

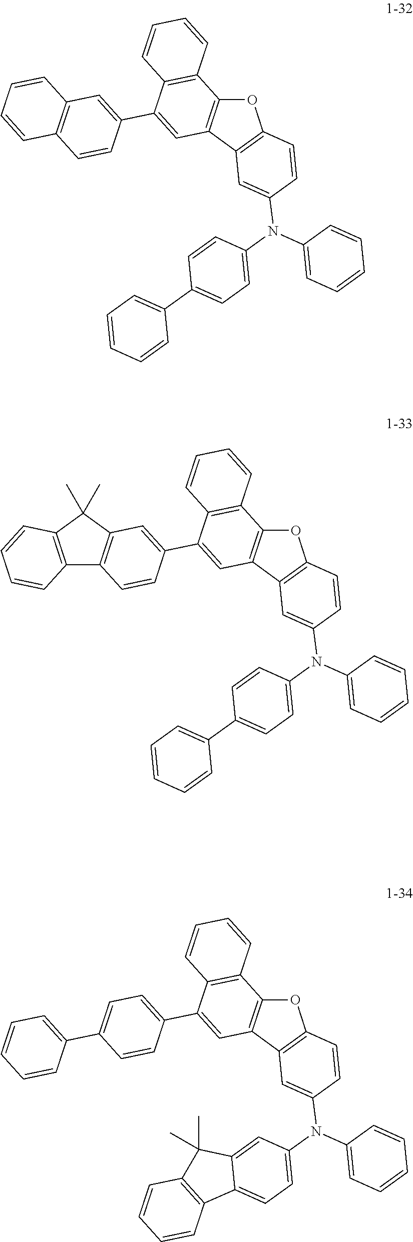 [SMILES: c1ccc(-c2ccc(N(c3ccccc3)c3ccc4oc5c6ccccc6c(-c6ccc7ccccc7c6)cc5c4c3)cc2)cc1 ; CC1(C)c2ccccc2-c2ccc(-c3cc4c5cc(N(c6ccccc6)c6ccc(-c7ccccc7)cc6)ccc5oc4c4ccccc34)cc21 ; CC1(C)c2ccccc2-c2ccc(N(c3ccccc3)c3ccc4oc5c6ccccc6c(-c6ccc(-c7ccccc7)cc6)cc5c4c3)cc21]

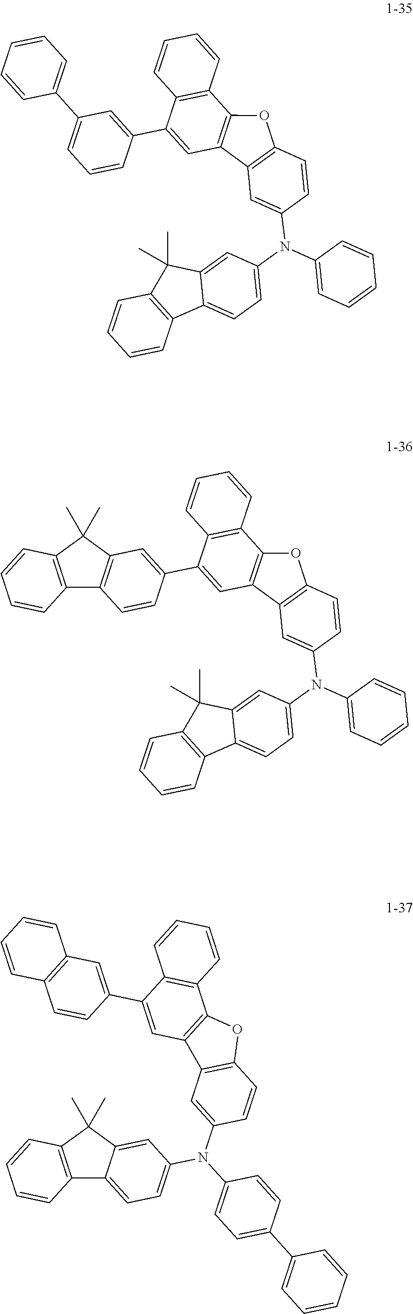 [SMILES: CC1(C)c2ccccc2-c2ccc(N(c3ccccc3)c3ccc4oc5c6ccccc6c(-c6cccc(-c7ccccc7)c6)cc5c4c3)cc21 ; CC1(C)c2ccccc2-c2ccc(-c3cc4c5cc(N(c6ccccc6)c6ccc7c(c6)C(C)(C)c6ccccc6-7)ccc5oc4c4ccccc34)cc21 ; CC1(C)c2ccccc2-c2ccc(N(c3ccc(-c4ccccc4)cc3)c3ccc4oc5c6ccccc6c(-c6ccc7ccccc7c6)cc5c4c3)cc21]

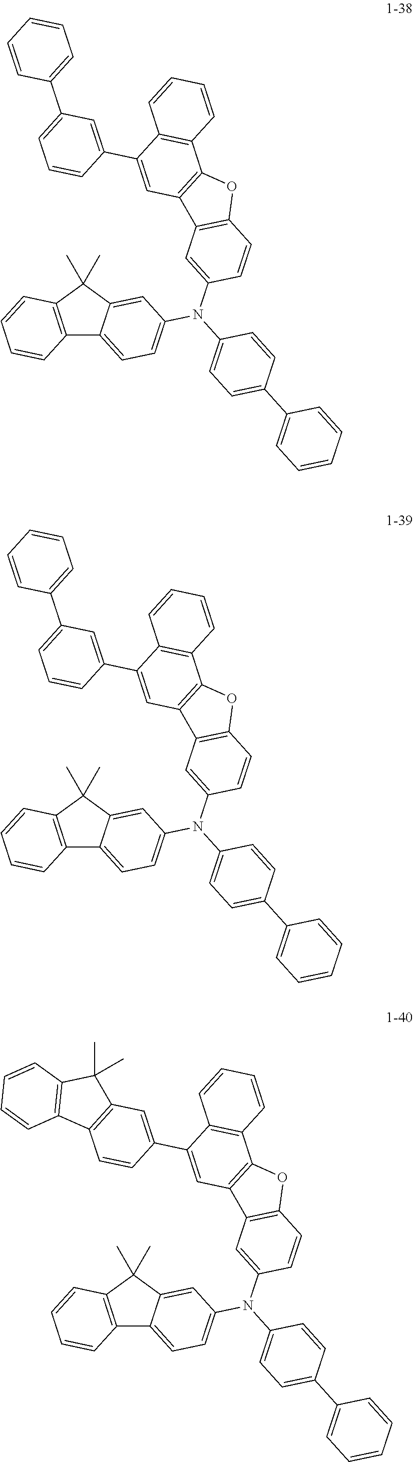 [SMILES: CC1(C)c2ccccc2-c2ccc(N(c3ccc(-c4ccccc4)cc3)c3ccc4oc5c6ccccc6c(-c6cccc(-c7ccccc7)c6)cc5c4c3)cc21 ; CC1(C)c2ccccc2-c2ccc(N(c3ccc(-c4ccccc4)cc3)c3ccc4oc5c6ccccc6c(-c6cccc(-c7ccccc7)c6)cc5c4c3)cc21 ; CC1(C)c2ccccc2-c2ccc(-c3cc4c5cc(N(c6ccc(-c7ccccc7)cc6)c6ccc7c(c6)C(C)(C)c6ccccc6-7)ccc5oc4c4ccccc34)cc21]

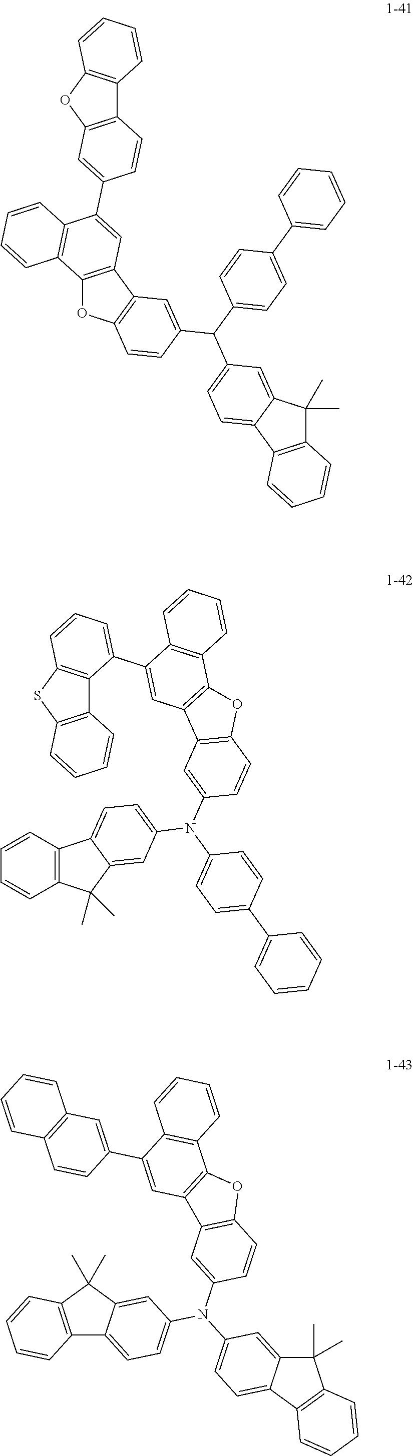 [SMILES: CC1(C)c2ccccc2-c2ccc(C(c3ccc(-c4ccccc4)cc3)c3ccc4oc5c6ccccc6c(-c6ccc7c(c6)oc6ccccc67)cc5c4c3)cc21 ; CC1(C)c2ccccc2-c2ccc(N(c3ccc(-c4ccccc4)cc3)c3ccc4oc5c6ccccc6c(-c6cccc7sc8ccccc8c67)cc5c4c3)cc21 ; CC1(C)c2ccccc2-c2ccc(N(c3ccc4c(c3)C(C)(C)c3ccccc3-4)c3ccc4oc5c6ccccc6c(-c6ccc7ccccc7c6)cc5c4c3)cc21]

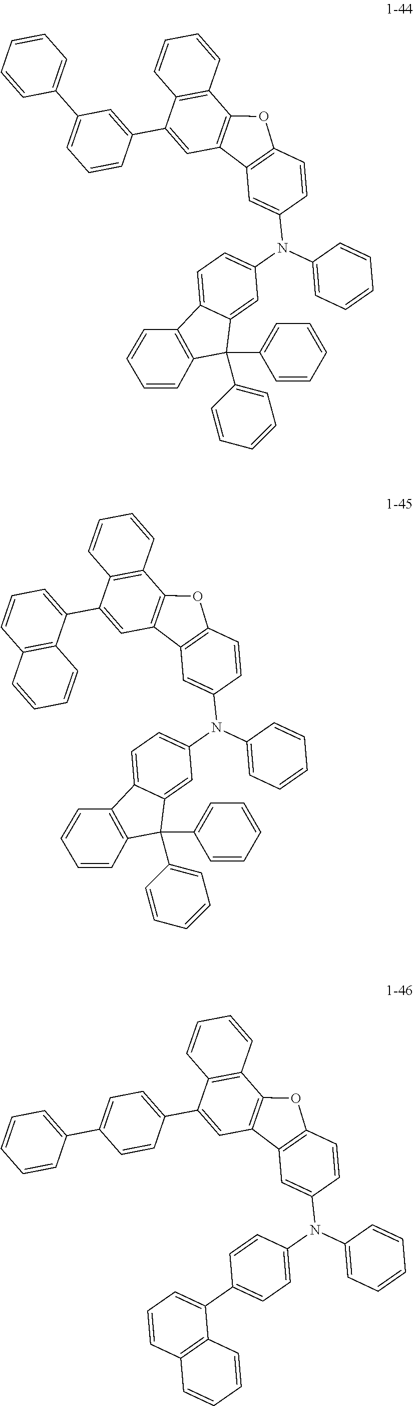 [SMILES: c1ccc(-c2cccc(-c3cc4c5cc(N(c6ccccc6)c6ccc7c(c6)C(c6ccccc6)(c6ccccc6)c6ccccc6-7)ccc5oc4c4ccccc34)c2)cc1 ; c1ccc(N(c2ccc3c(c2)C(c2ccccc2)(c2ccccc2)c2ccccc2-3)c2ccc3oc4c5ccccc5c(-c5cccc6ccccc56)cc4c3c2)cc1 ; c1ccc(-c2ccc(-c3cc4c5cc(N(c6ccccc6)c6ccc(-c7cccc8ccccc78)cc6)ccc5oc4c4ccccc34)cc2)cc1]

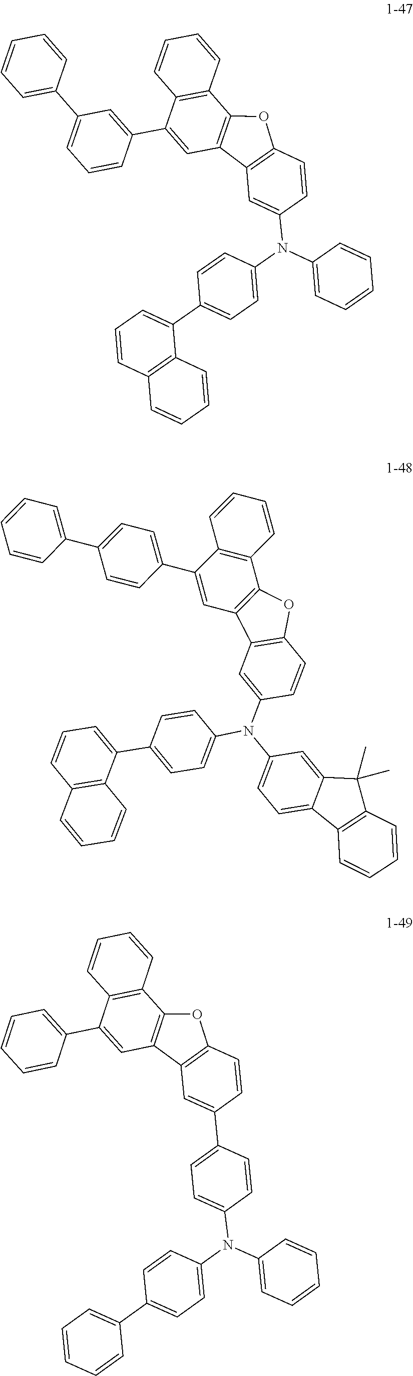 [SMILES: c1ccc(-c2cccc(-c3cc4c5cc(N(c6ccccc6)c6ccc(-c7cccc8ccccc78)cc6)ccc5oc4c4ccccc34)c2)cc1 ; CC1(C)c2ccccc2-c2ccc(N(c3ccc(-c4cccc5ccccc45)cc3)c3ccc4oc5c6ccccc6c(-c6ccc(-c7ccccc7)cc6)cc5c4c3)cc21 ; c1ccc(-c2ccc(N(c3ccccc3)c3ccc(-c4ccc5oc6c7ccccc7c(-c7ccccc7)cc6c5c4)cc3)cc2)cc1]

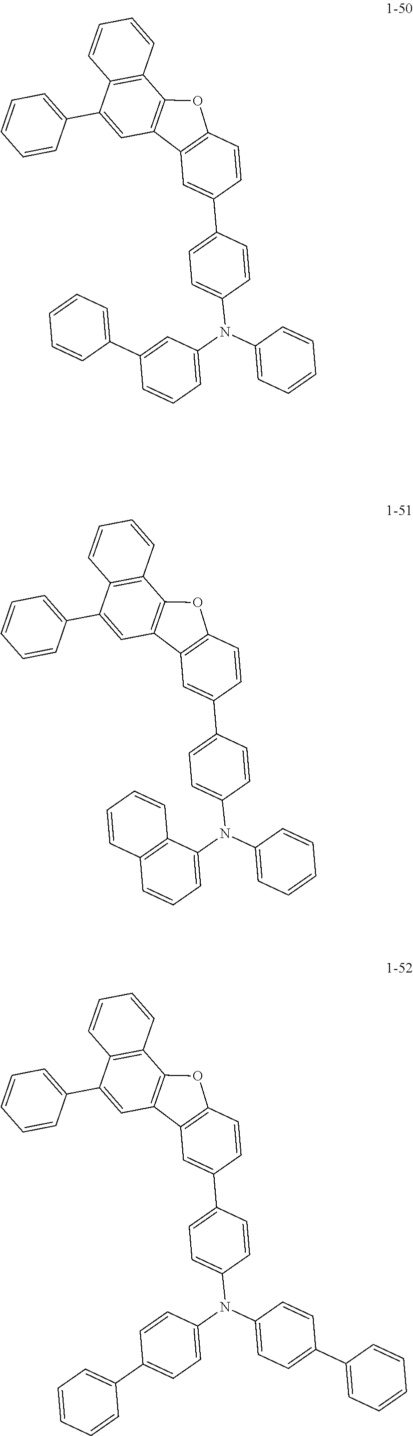 [SMILES: c1ccc(-c2cccc(N(c3ccccc3)c3ccc(-c4ccc5oc6c7ccccc7c(-c7ccccc7)cc6c5c4)cc3)c2)cc1 ; c1ccc(-c2cc3c4cc(-c5ccc(N(c6ccccc6)c6cccc7ccccc67)cc5)ccc4oc3c3ccccc23)cc1 ; c1ccc(-c2ccc(N(c3ccc(-c4ccccc4)cc3)c3ccc(-c4ccc5oc6c7ccccc7c(-c7ccccc7)cc6c5c4)cc3)cc2)cc1]

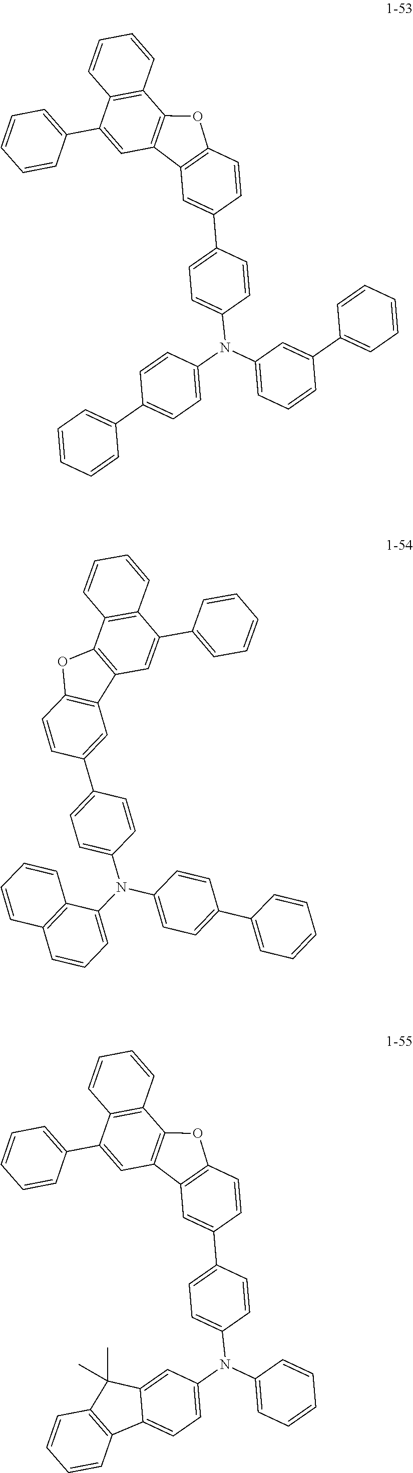 [SMILES: c1ccc(-c2ccc(N(c3ccc(-c4ccc5oc6c7ccccc7c(-c7ccccc7)cc6c5c4)cc3)c3cccc(-c4ccccc4)c3)cc2)cc1 ; c1ccc(-c2ccc(N(c3ccc(-c4ccc5oc6c7ccccc7c(-c7ccccc7)cc6c5c4)cc3)c3cccc4ccccc34)cc2)cc1 ; CC1(C)c2ccccc2-c2ccc(N(c3ccccc3)c3ccc(-c4ccc5oc6c7ccccc7c(-c7ccccc7)cc6c5c4)cc3)cc21]

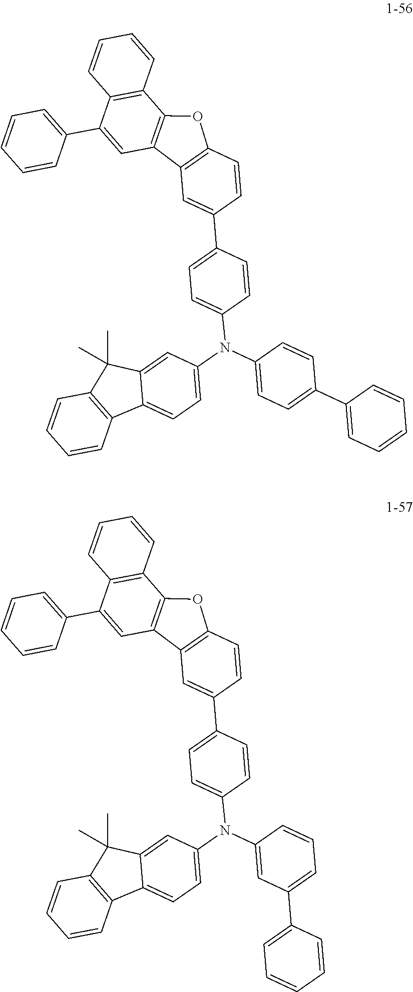 [SMILES: CC1(C)c2ccccc2-c2ccc(N(c3ccc(-c4ccccc4)cc3)c3ccc(-c4ccc5oc6c7ccccc7c(-c7ccccc7)cc6c5c4)cc3)cc21 ; CC1(C)c2ccccc2-c2ccc(N(c3ccc(-c4ccc5oc6c7ccccc7c(-c7ccccc7)cc6c5c4)cc3)c3cccc(-c4ccccc4)c3)cc21]

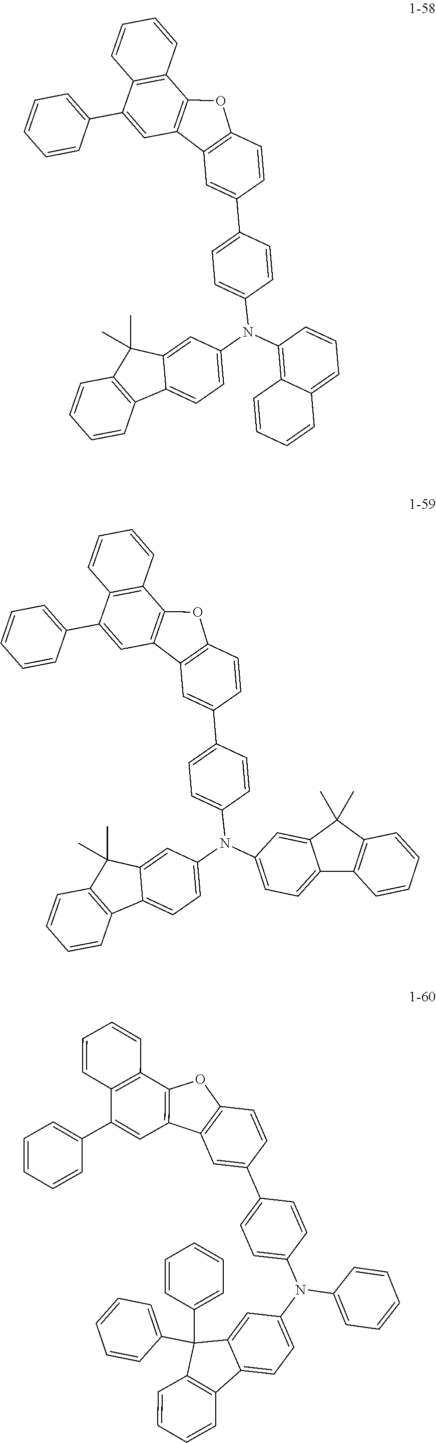 [SMILES: CC1(C)c2ccccc2-c2ccc(N(c3ccc(-c4ccc5oc6c7ccccc7c(-c7ccccc7)cc6c5c4)cc3)c3cccc4ccccc34)cc21 ; CC1(C)c2ccccc2-c2ccc(N(c3ccc(-c4ccc5oc6c7ccccc7c(-c7ccccc7)cc6c5c4)cc3)c3ccc4c(c3)C(C)(C)c3ccccc3-4)cc21 ; c1ccc(-c2cc3c4cc(-c5ccc(N(c6ccccc6)c6ccc7c(c6)C(c6ccccc6)(c6ccccc6)c6ccccc6-7)cc5)ccc4oc3c3ccccc23)cc1]

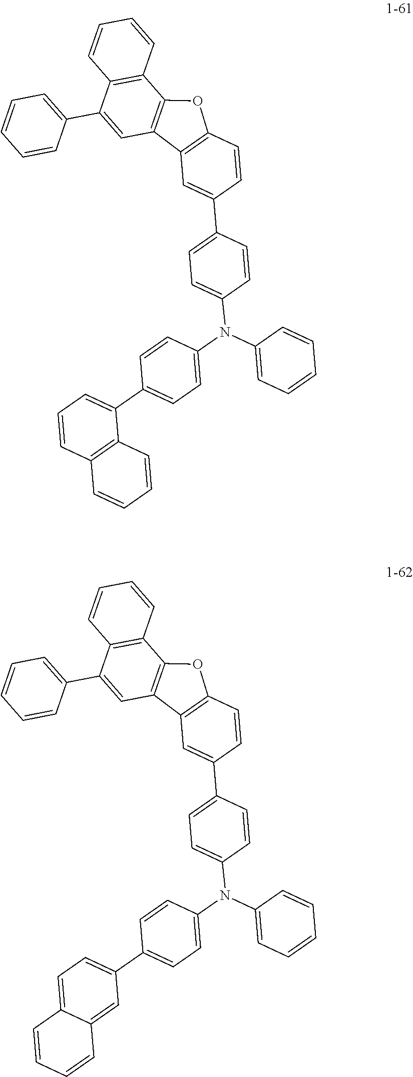 [SMILES: c1ccc(-c2cc3c4cc(-c5ccc(N(c6ccccc6)c6ccc(-c7cccc8ccccc78)cc6)cc5)ccc4oc3c3ccccc23)cc1 ; c1ccc(-c2cc3c4cc(-c5ccc(N(c6ccccc6)c6ccc(-c7ccc8ccccc8c7)cc6)cc5)ccc4oc3c3ccccc23)cc1]

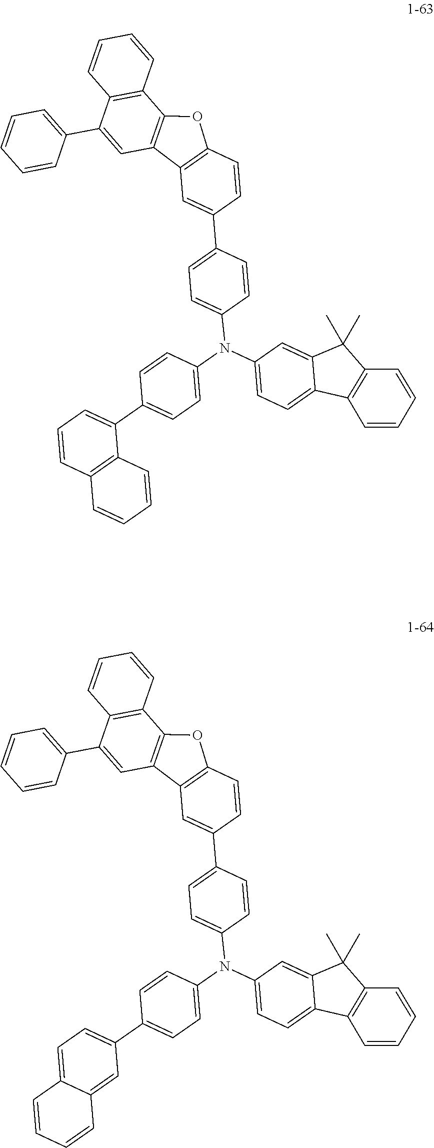 [SMILES: CC1(C)c2ccccc2-c2ccc(N(c3ccc(-c4ccc5oc6c7ccccc7c(-c7ccccc7)cc6c5c4)cc3)c3ccc(-c4cccc5ccccc45)cc3)cc21 ; CC1(C)c2ccccc2-c2ccc(N(c3ccc(-c4ccc5ccccc5c4)cc3)c3ccc(-c4ccc5oc6c7ccccc7c(-c7ccccc7)cc6c5c4)cc3)cc21]

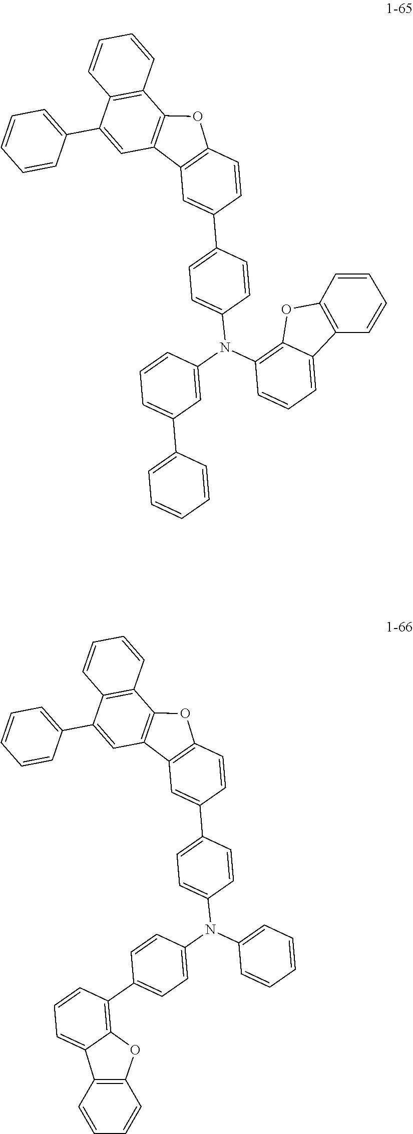 [SMILES: c1ccc(-c2cccc(N(c3ccc(-c4ccc5oc6c7ccccc7c(-c7ccccc7)cc6c5c4)cc3)c3cccc4c3oc3ccccc34)c2)cc1 ; c1ccc(-c2cc3c4cc(-c5ccc(N(c6ccccc6)c6ccc(-c7cccc8c7oc7ccccc78)cc6)cc5)ccc4oc3c3ccccc23)cc1]

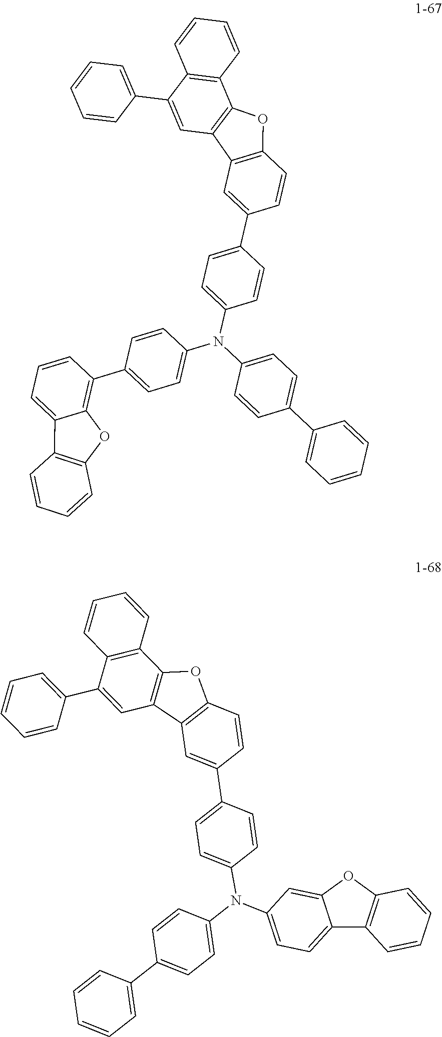 [SMILES: c1ccc(-c2ccc(N(c3ccc(-c4ccc5oc6c7ccccc7c(-c7ccccc7)cc6c5c4)cc3)c3ccc(-c4cccc5c4oc4ccccc45)cc3)cc2)cc1 ; c1ccc(-c2ccc(N(c3ccc(-c4ccc5oc6c7ccccc7c(-c7ccccc7)cc6c5c4)cc3)c3ccc4c(c3)oc3ccccc34)cc2)cc1]

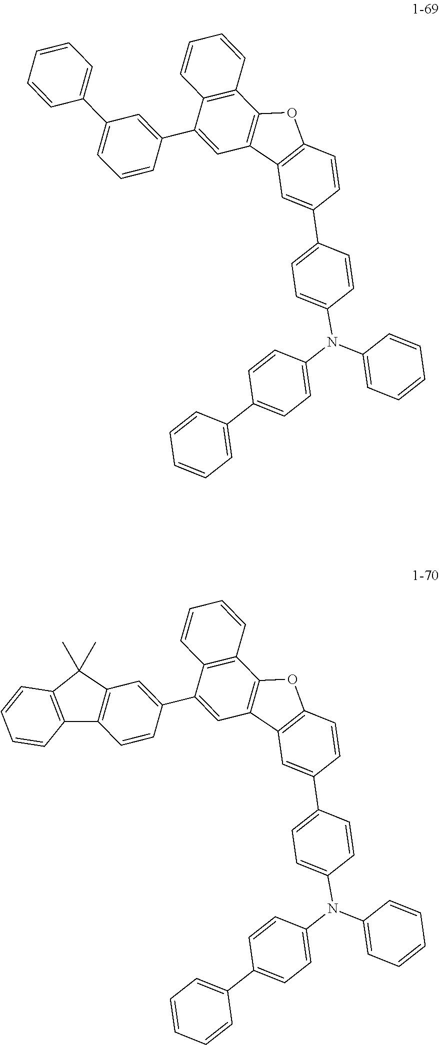 [SMILES: c1ccc(-c2ccc(N(c3ccccc3)c3ccc(-c4ccc5oc6c7ccccc7c(-c7cccc(-c8ccccc8)c7)cc6c5c4)cc3)cc2)cc1 ; CC1(C)c2ccccc2-c2ccc(-c3cc4c5cc(-c6ccc(N(c7ccccc7)c7ccc(-c8ccccc8)cc7)cc6)ccc5oc4c4ccccc34)cc21]

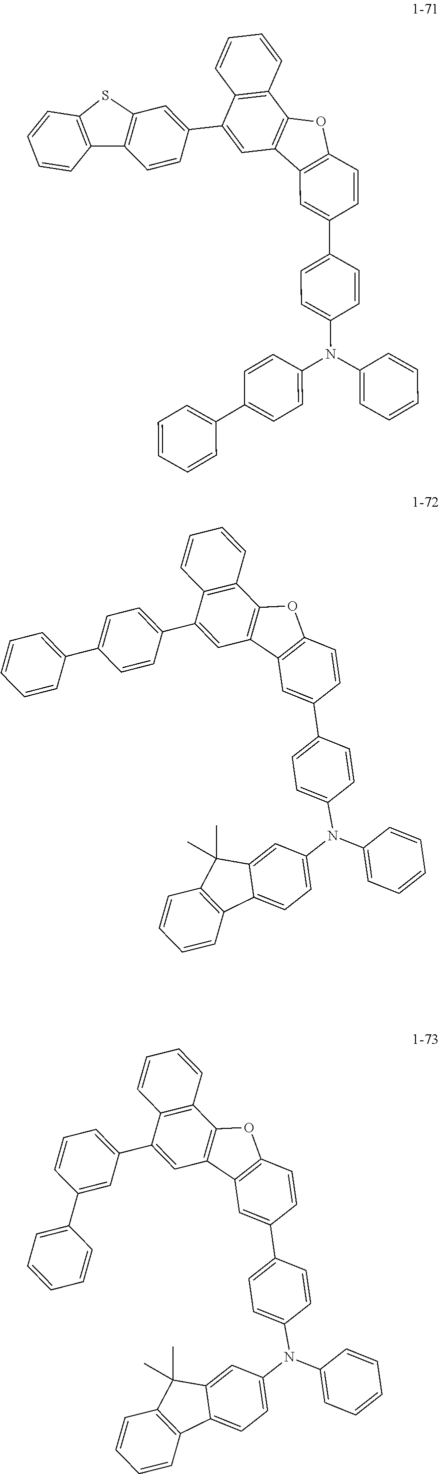 [SMILES: c1ccc(-c2ccc(N(c3ccccc3)c3ccc(-c4ccc5oc6c7ccccc7c(-c7ccc8c(c7)sc7ccccc78)cc6c5c4)cc3)cc2)cc1 ; CC1(C)c2ccccc2-c2ccc(N(c3ccccc3)c3ccc(-c4ccc5oc6c7ccccc7c(-c7ccc(-c8ccccc8)cc7)cc6c5c4)cc3)cc21 ; CC1(C)c2ccccc2-c2ccc(N(c3ccccc3)c3ccc(-c4ccc5oc6c7ccccc7c(-c7cccc(-c8ccccc8)c7)cc6c5c4)cc3)cc21]

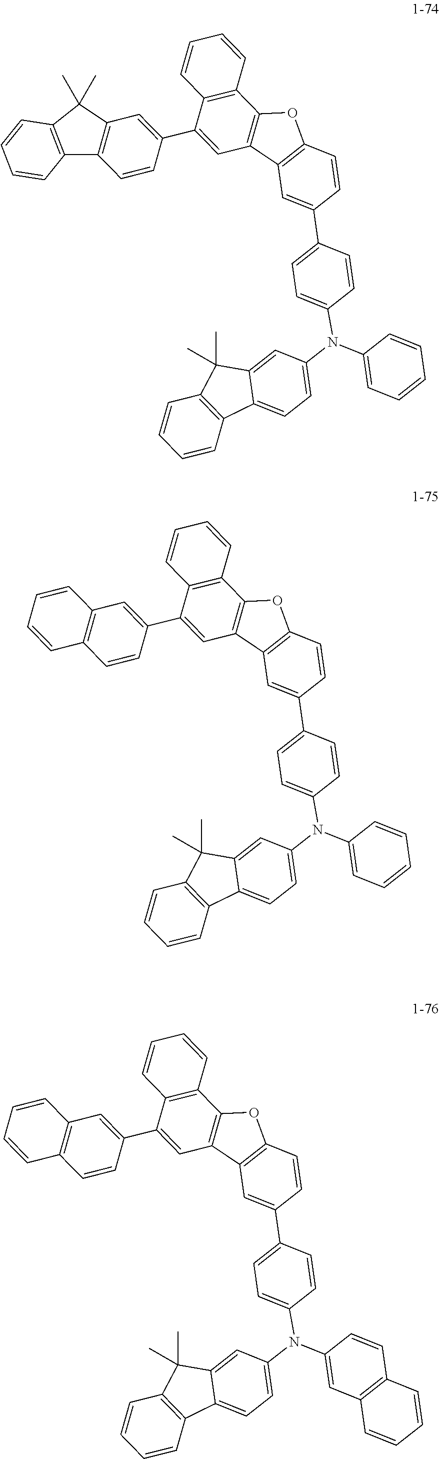 [SMILES: CC1(C)c2ccccc2-c2ccc(-c3cc4c5cc(-c6ccc(N(c7ccccc7)c7ccc8c(c7)C(C)(C)c7ccccc7-8)cc6)ccc5oc4c4ccccc34)cc21 ; CC1(C)c2ccccc2-c2ccc(N(c3ccccc3)c3ccc(-c4ccc5oc6c7ccccc7c(-c7ccc8ccccc8c7)cc6c5c4)cc3)cc21 ; CC1(C)c2ccccc2-c2ccc(N(c3ccc(-c4ccc5oc6c7ccccc7c(-c7ccc8ccccc8c7)cc6c5c4)cc3)c3ccc4ccccc4c3)cc21]

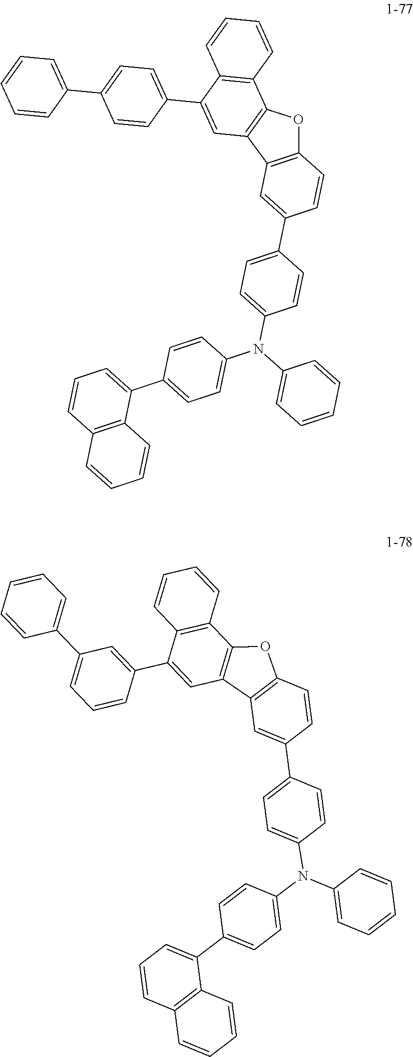 [SMILES: c1ccc(-c2ccc(-c3cc4c5cc(-c6ccc(N(c7ccccc7)c7ccc(-c8cccc9ccccc89)cc7)cc6)ccc5oc4c4ccccc34)cc2)cc1 ; c1ccc(-c2cccc(-c3cc4c5cc(-c6ccc(N(c7ccccc7)c7ccc(-c8cccc9ccccc89)cc7)cc6)ccc5oc4c4ccccc34)c2)cc1]

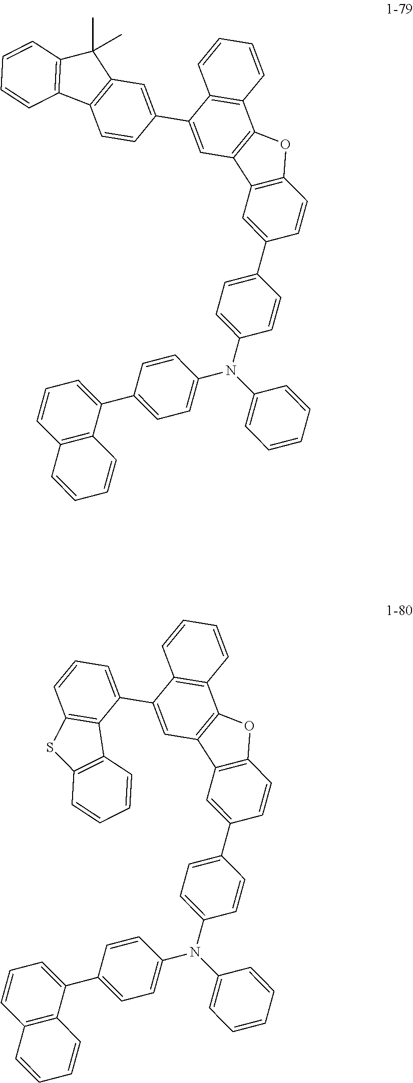 [SMILES: CC1(C)c2ccccc2-c2ccc(-c3cc4c5cc(-c6ccc(N(c7ccccc7)c7ccc(-c8cccc9ccccc89)cc7)cc6)ccc5oc4c4ccccc34)cc21 ; c1ccc(N(c2ccc(-c3ccc4oc5c6ccccc6c(-c6cccc7sc8ccccc8c67)cc5c4c3)cc2)c2ccc(-c3cccc4ccccc34)cc2)cc1]

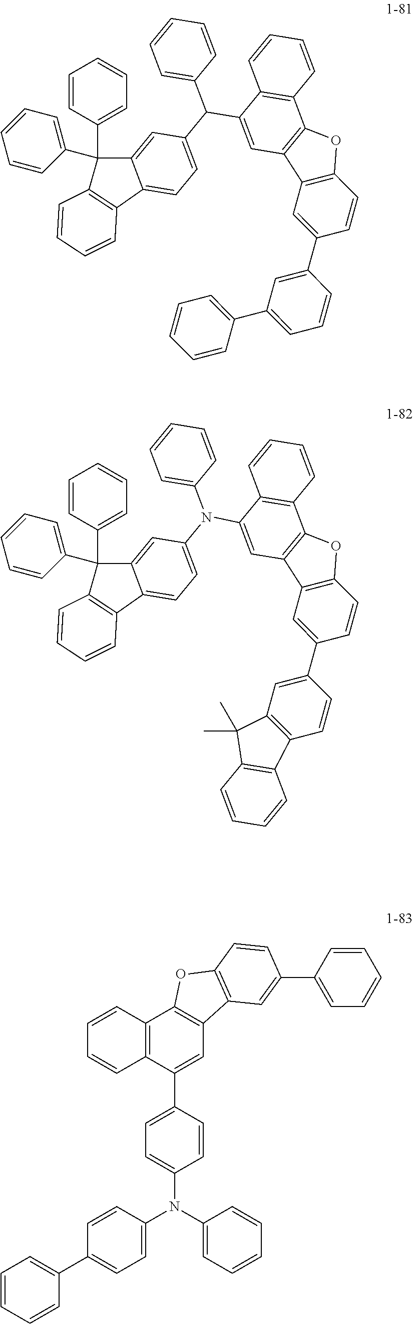 [SMILES: c1ccc(-c2cccc(-c3ccc4oc5c6ccccc6c(C(c6ccccc6)c6ccc7c(c6)C(c6ccccc6)(c6ccccc6)c6ccccc6-7)cc5c4c3)c2)cc1 ; CC1(C)c2ccccc2-c2ccc(-c3ccc4oc5c6ccccc6c(N(c6ccccc6)c6ccc7c(c6)C(c6ccccc6)(c6ccccc6)c6ccccc6-7)cc5c4c3)cc21 ; c1ccc(-c2ccc(N(c3ccccc3)c3ccc(-c4cc5c6cc(-c7ccccc7)ccc6oc5c5ccccc45)cc3)cc2)cc1]

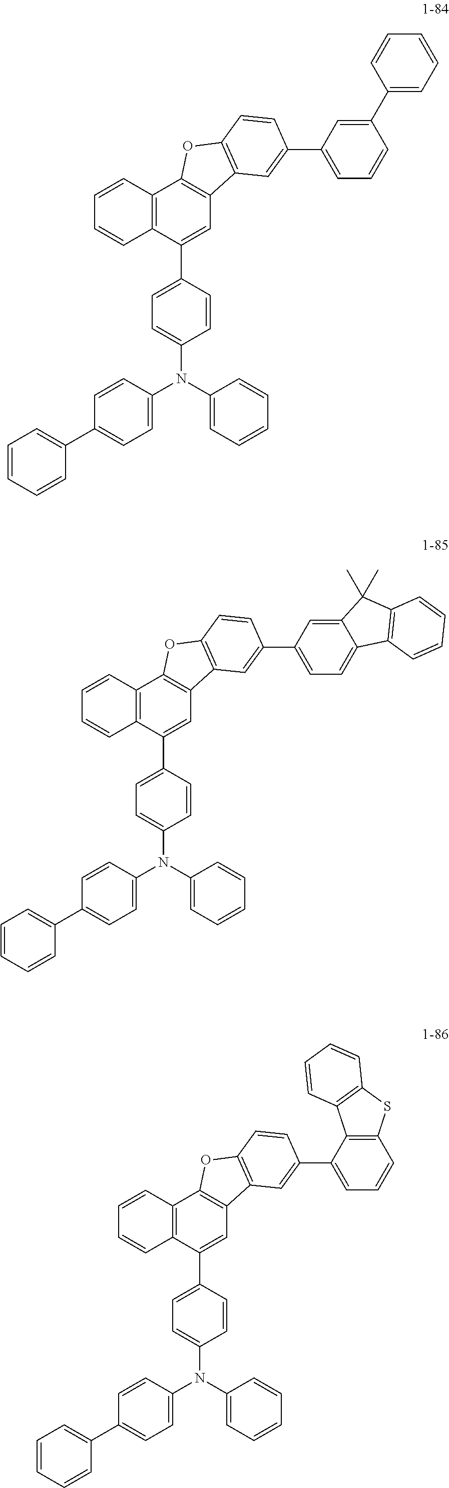 [SMILES: c1ccc(-c2ccc(N(c3ccccc3)c3ccc(-c4cc5c6cc(-c7cccc(-c8ccccc8)c7)ccc6oc5c5ccccc45)cc3)cc2)cc1 ; CC1(C)c2ccccc2-c2ccc(-c3ccc4oc5c6ccccc6c(-c6ccc(N(c7ccccc7)c7ccc(-c8ccccc8)cc7)cc6)cc5c4c3)cc21 ; c1ccc(-c2ccc(N(c3ccccc3)c3ccc(-c4cc5c6cc(-c7cccc8sc9ccccc9c78)ccc6oc5c5ccccc45)cc3)cc2)cc1]

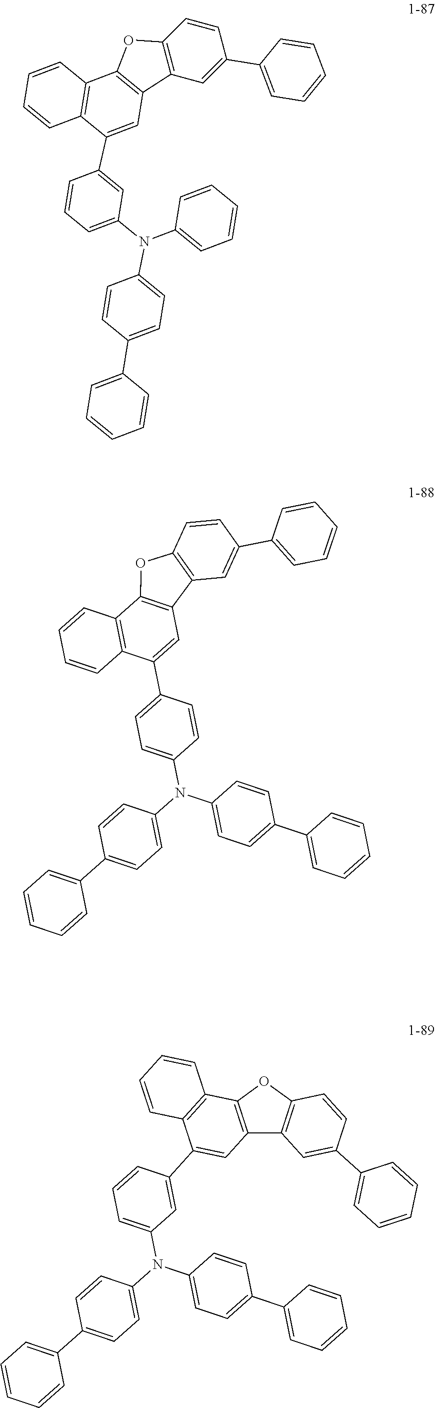 [SMILES: c1ccc(-c2ccc(N(c3ccccc3)c3cccc(-c4cc5c6cc(-c7ccccc7)ccc6oc5c5ccccc45)c3)cc2)cc1 ; c1ccc(-c2ccc(N(c3ccc(-c4ccccc4)cc3)c3ccc(-c4cc5c6cc(-c7ccccc7)ccc6oc5c5ccccc45)cc3)cc2)cc1 ; c1ccc(-c2ccc(N(c3ccc(-c4ccccc4)cc3)c3cccc(-c4cc5c6cc(-c7ccccc7)ccc6oc5c5ccccc45)c3)cc2)cc1]

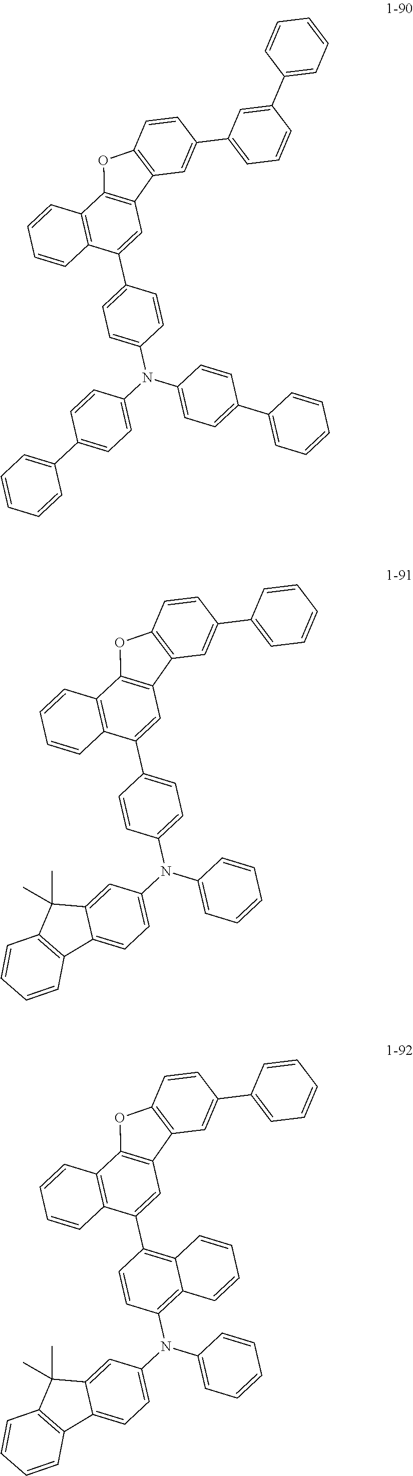 [SMILES: c1ccc(-c2ccc(N(c3ccc(-c4ccccc4)cc3)c3ccc(-c4cc5c6cc(-c7cccc(-c8ccccc8)c7)ccc6oc5c5ccccc45)cc3)cc2)cc1 ; CC1(C)c2ccccc2-c2ccc(N(c3ccccc3)c3ccc(-c4cc5c6cc(-c7ccccc7)ccc6oc5c5ccccc45)cc3)cc21 ; CC1(C)c2ccccc2-c2ccc(N(c3ccccc3)c3ccc(-c4cc5c6cc(-c7ccccc7)ccc6oc5c5ccccc45)c4ccccc34)cc21]

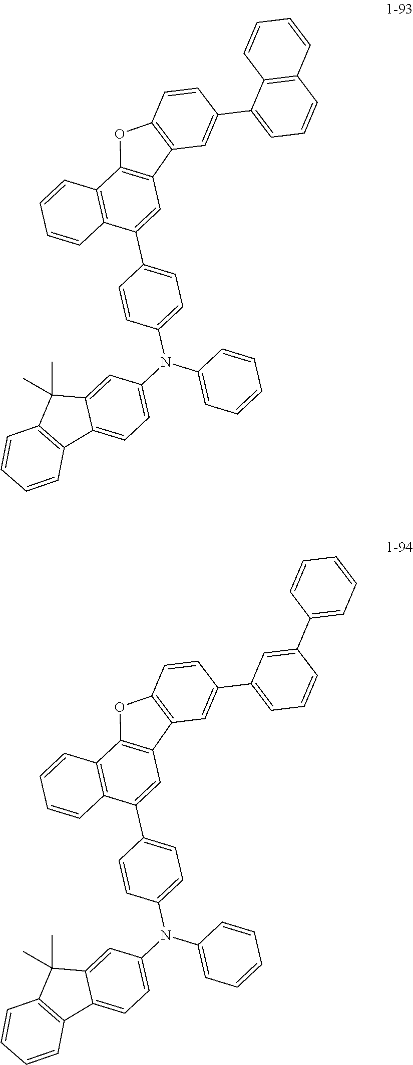 [SMILES: CC1(C)c2ccccc2-c2ccc(N(c3ccccc3)c3ccc(-c4cc5c6cc(-c7cccc8ccccc78)ccc6oc5c5ccccc45)cc3)cc21 ; CC1(C)c2ccccc2-c2ccc(N(c3ccccc3)c3ccc(-c4cc5c6cc(-c7cccc(-c8ccccc8)c7)ccc6oc5c5ccccc45)cc3)cc21]

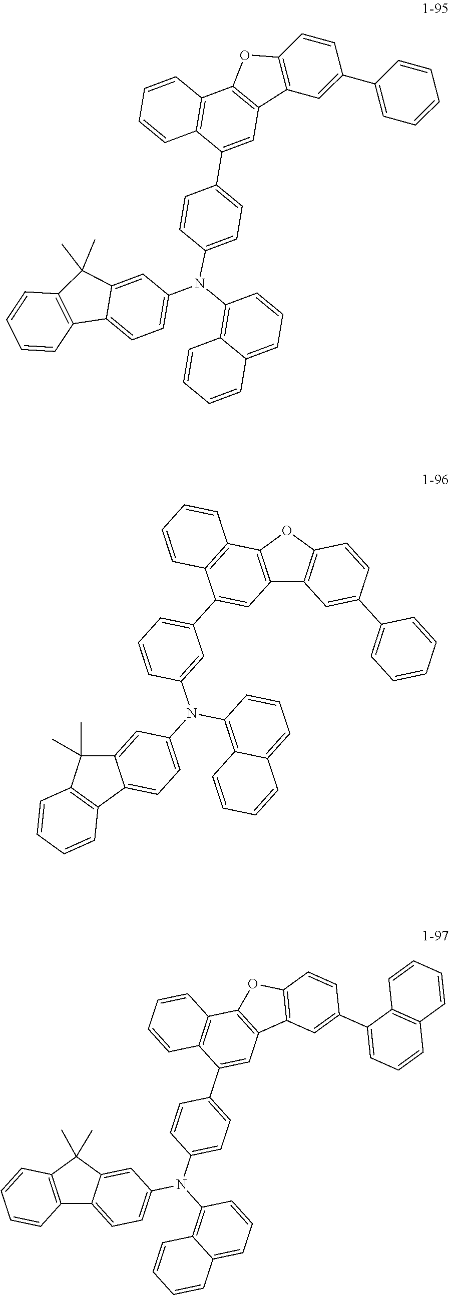 [SMILES: CC1(C)c2ccccc2-c2ccc(N(c3ccc(-c4cc5c6cc(-c7ccccc7)ccc6oc5c5ccccc45)cc3)c3cccc4ccccc34)cc21 ; CC1(C)c2ccccc2-c2ccc(N(c3cccc(-c4cc5c6cc(-c7ccccc7)ccc6oc5c5ccccc45)c3)c3cccc4ccccc34)cc21 ; CC1(C)c2ccccc2-c2ccc(N(c3ccc(-c4cc5c6cc(-c7cccc8ccccc78)ccc6oc5c5ccccc45)cc3)c3cccc4ccccc34)cc21]

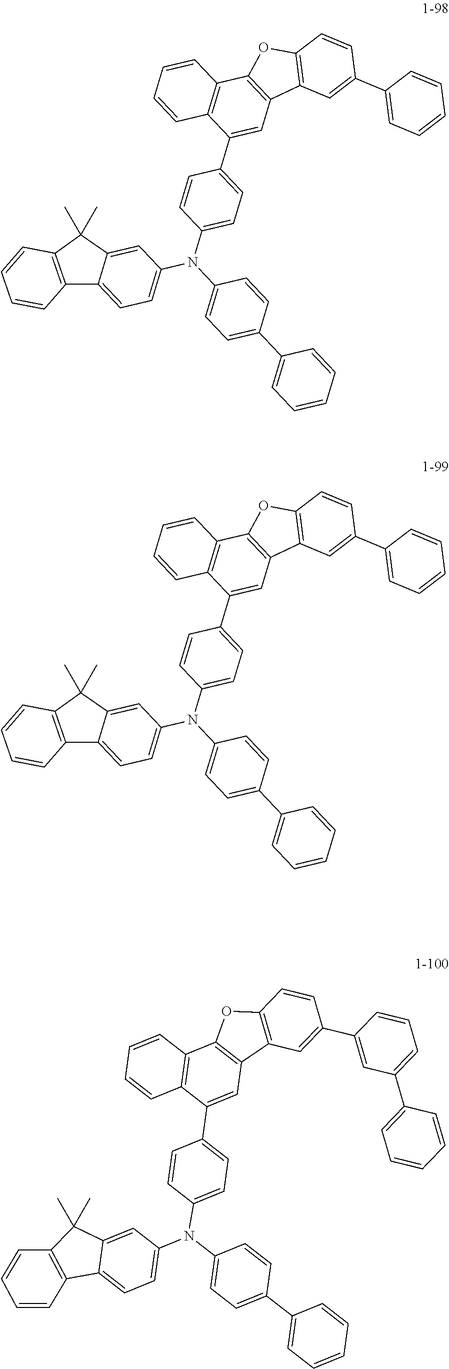 [SMILES: CC1(C)c2ccccc2-c2ccc(N(c3ccc(-c4ccccc4)cc3)c3ccc(-c4cc5c6cc(-c7ccccc7)ccc6oc5c5ccccc45)cc3)cc21 ; CC1(C)c2ccccc2-c2ccc(N(c3ccc(-c4ccccc4)cc3)c3ccc(-c4cc5c6cc(-c7ccccc7)ccc6oc5c5ccccc45)cc3)cc21 ; CC1(C)c2ccccc2-c2ccc(N(c3ccc(-c4ccccc4)cc3)c3ccc(-c4cc5c6cc(-c7cccc(-c8ccccc8)c7)ccc6oc5c5ccccc45)cc3)cc21]

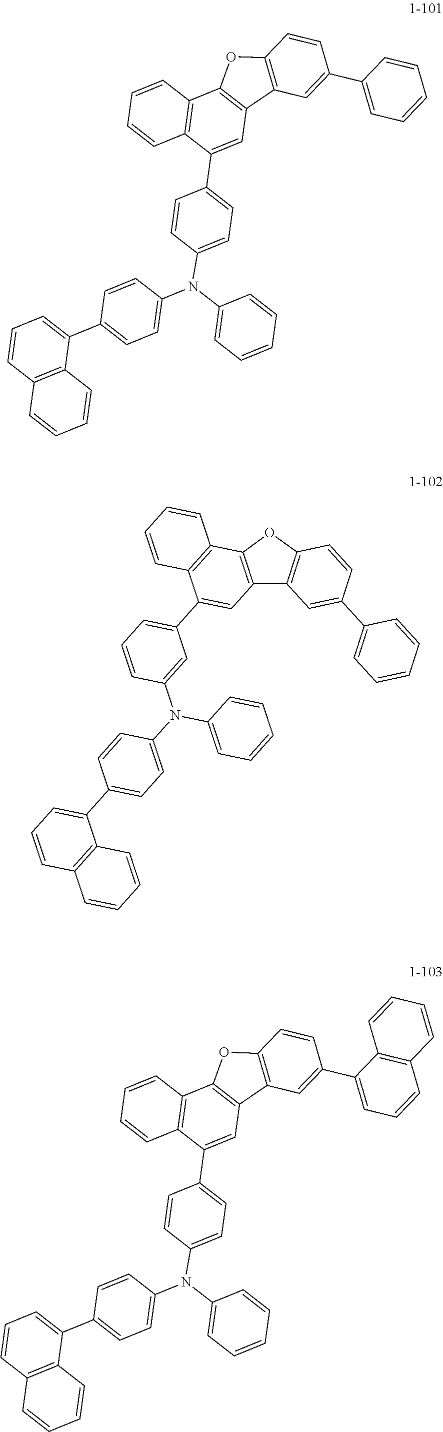 [SMILES: c1ccc(-c2ccc3oc4c5ccccc5c(-c5ccc(N(c6ccccc6)c6ccc(-c7cccc8ccccc78)cc6)cc5)cc4c3c2)cc1 ; c1ccc(-c2ccc3oc4c5ccccc5c(-c5cccc(N(c6ccccc6)c6ccc(-c7cccc8ccccc78)cc6)c5)cc4c3c2)cc1 ; c1ccc(N(c2ccc(-c3cccc4ccccc34)cc2)c2ccc(-c3cc4c5cc(-c6cccc7ccccc67)ccc5oc4c4ccccc34)cc2)cc1]

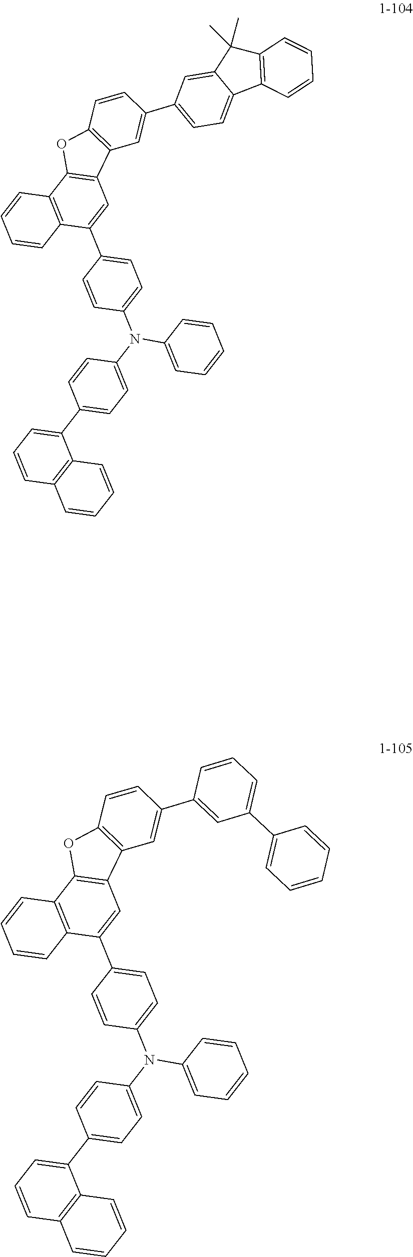 [SMILES: CC1(C)c2ccccc2-c2ccc(-c3ccc4oc5c6ccccc6c(-c6ccc(N(c7ccccc7)c7ccc(-c8cccc9ccccc89)cc7)cc6)cc5c4c3)cc21 ; c1ccc(-c2cccc(-c3ccc4oc5c6ccccc6c(-c6ccc(N(c7ccccc7)c7ccc(-c8cccc9ccccc89)cc7)cc6)cc5c4c3)c2)cc1]

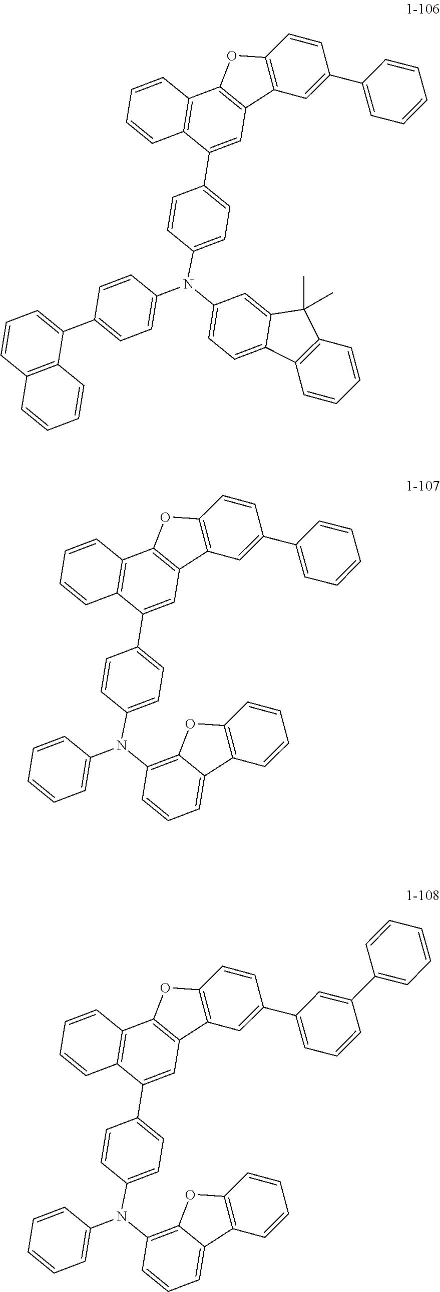 [SMILES: CC1(C)c2ccccc2-c2ccc(N(c3ccc(-c4cccc5ccccc45)cc3)c3ccc(-c4cc5c6cc(-c7ccccc7)ccc6oc5c5ccccc45)cc3)cc21 ; c1ccc(-c2ccc3oc4c5ccccc5c(-c5ccc(N(c6ccccc6)c6cccc7c6oc6ccccc67)cc5)cc4c3c2)cc1 ; c1ccc(-c2cccc(-c3ccc4oc5c6ccccc6c(-c6ccc(N(c7ccccc7)c7cccc8c7oc7ccccc78)cc6)cc5c4c3)c2)cc1]

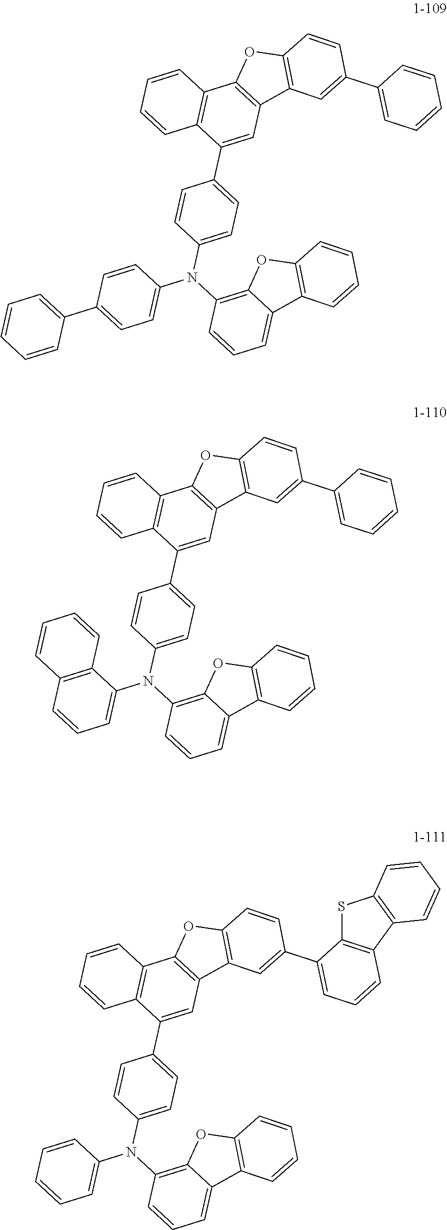 [SMILES: c1ccc(-c2ccc(N(c3ccc(-c4cc5c6cc(-c7ccccc7)ccc6oc5c5ccccc45)cc3)c3cccc4c3oc3ccccc34)cc2)cc1 ; c1ccc(-c2ccc3oc4c5ccccc5c(-c5ccc(N(c6cccc7ccccc67)c6cccc7c6oc6ccccc67)cc5)cc4c3c2)cc1 ; c1ccc(N(c2ccc(-c3cc4c5cc(-c6cccc7c6sc6ccccc67)ccc5oc4c4ccccc34)cc2)c2cccc3c2oc2ccccc23)cc1]

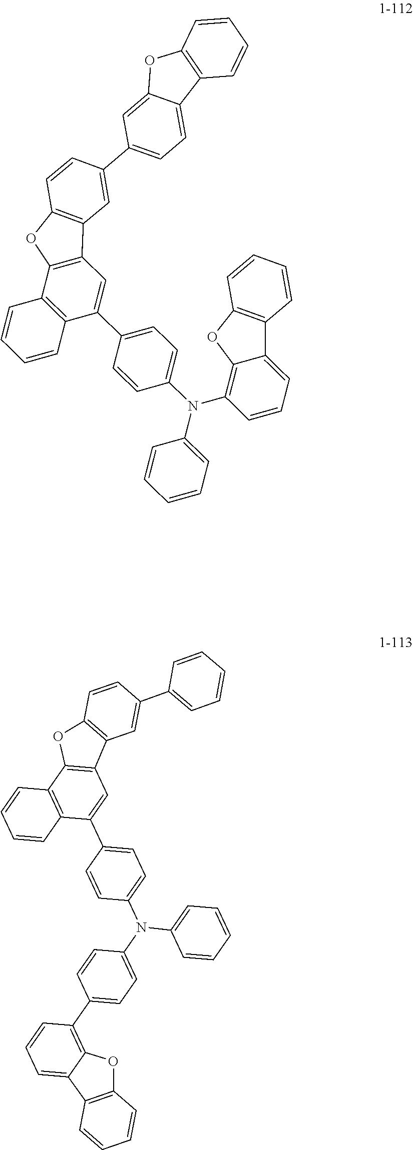 [SMILES: c1ccc(N(c2ccc(-c3cc4c5cc(-c6ccc7c(c6)oc6ccccc67)ccc5oc4c4ccccc34)cc2)c2cccc3c2oc2ccccc23)cc1 ; c1ccc(-c2ccc3oc4c5ccccc5c(-c5ccc(N(c6ccccc6)c6ccc(-c7cccc8c7oc7ccccc78)cc6)cc5)cc4c3c2)cc1]

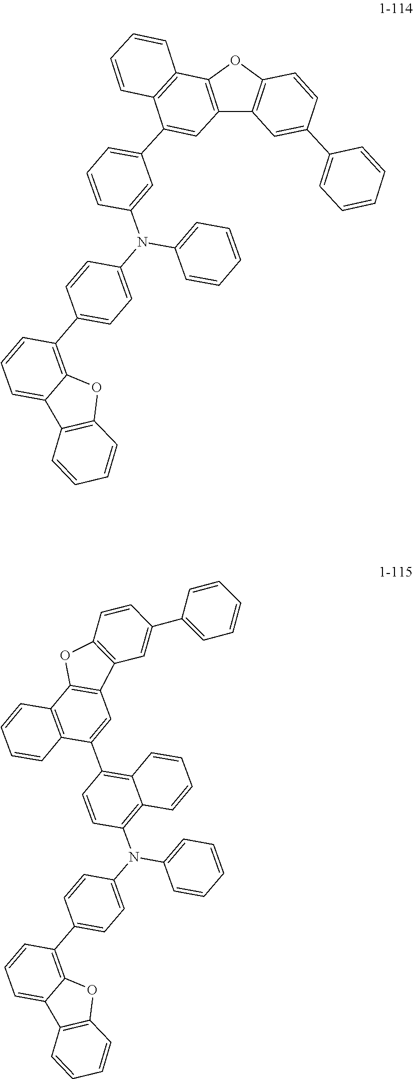 [SMILES: c1ccc(-c2ccc3oc4c5ccccc5c(-c5cccc(N(c6ccccc6)c6ccc(-c7cccc8c7oc7ccccc78)cc6)c5)cc4c3c2)cc1 ; c1ccc(-c2ccc3oc4c5ccccc5c(-c5ccc(N(c6ccccc6)c6ccc(-c7cccc8c7oc7ccccc78)cc6)c6ccccc56)cc4c3c2)cc1]

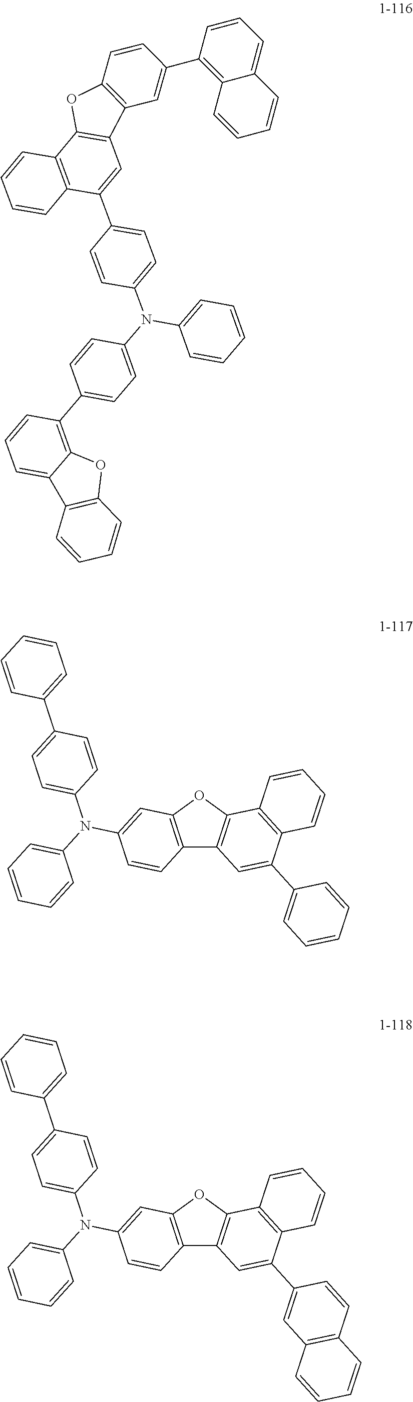 [SMILES: c1ccc(N(c2ccc(-c3cc4c5cc(-c6cccc7ccccc67)ccc5oc4c4ccccc34)cc2)c2ccc(-c3cccc4c3oc3ccccc34)cc2)cc1 ; c1ccc(-c2ccc(N(c3ccccc3)c3ccc4c(c3)oc3c5ccccc5c(-c5ccccc5)cc43)cc2)cc1 ; c1ccc(-c2ccc(N(c3ccccc3)c3ccc4c(c3)oc3c5ccccc5c(-c5ccc6ccccc6c5)cc43)cc2)cc1]

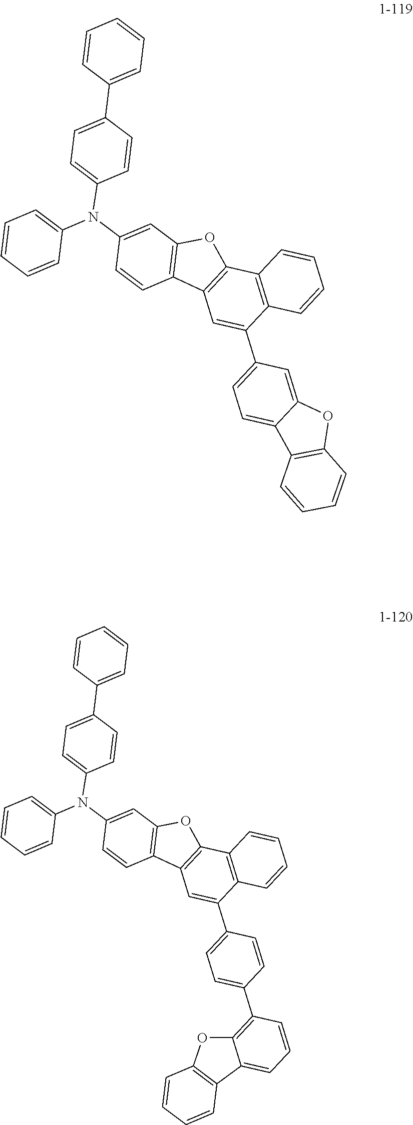 [SMILES: c1ccc(-c2ccc(N(c3ccccc3)c3ccc4c(c3)oc3c5ccccc5c(-c5ccc6c(c5)oc5ccccc56)cc43)cc2)cc1 ; c1ccc(-c2ccc(N(c3ccccc3)c3ccc4c(c3)oc3c5ccccc5c(-c5ccc(-c6cccc7c6oc6ccccc67)cc5)cc43)cc2)cc1]

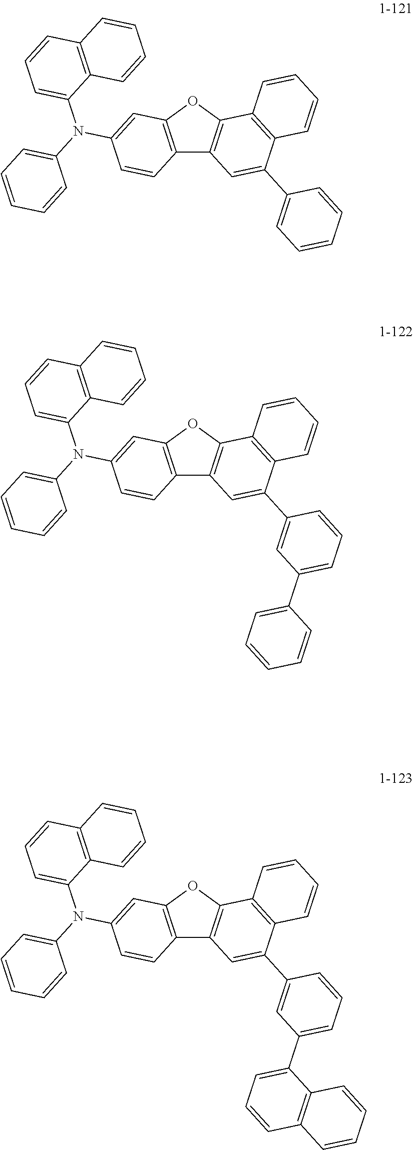 [SMILES: c1ccc(-c2cc3c4ccc(N(c5ccccc5)c5cccc6ccccc56)cc4oc3c3ccccc23)cc1 ; c1ccc(-c2cccc(-c3cc4c5ccc(N(c6ccccc6)c6cccc7ccccc67)cc5oc4c4ccccc34)c2)cc1 ; c1ccc(N(c2ccc3c(c2)oc2c4ccccc4c(-c4cccc(-c5cccc6ccccc56)c4)cc32)c2cccc3ccccc23)cc1]

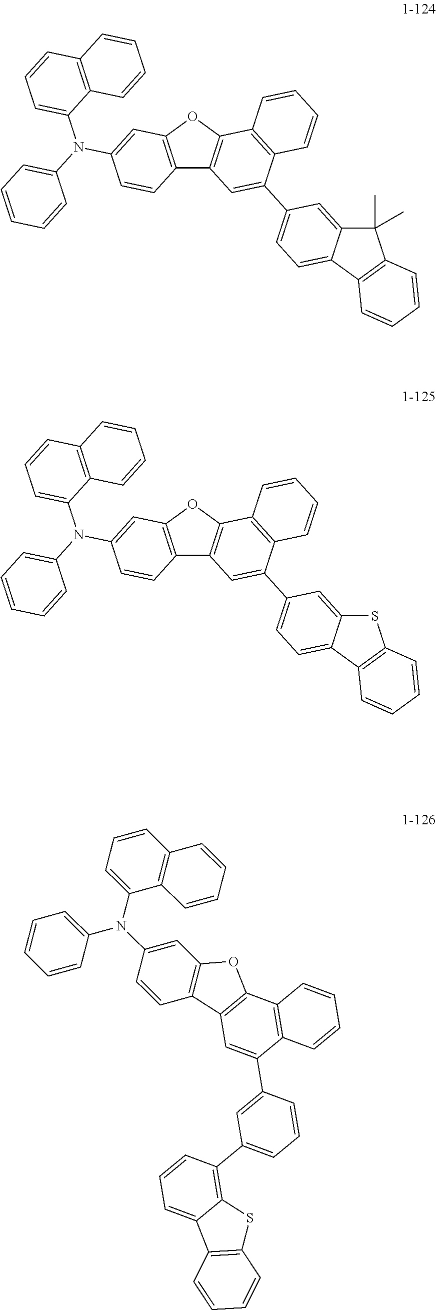 [SMILES: CC1(C)c2ccccc2-c2ccc(-c3cc4c5ccc(N(c6ccccc6)c6cccc7ccccc67)cc5oc4c4ccccc34)cc21 ; c1ccc(N(c2ccc3c(c2)oc2c4ccccc4c(-c4ccc5c(c4)sc4ccccc45)cc32)c2cccc3ccccc23)cc1 ; c1ccc(N(c2ccc3c(c2)oc2c4ccccc4c(-c4cccc(-c5cccc6c5sc5ccccc56)c4)cc32)c2cccc3ccccc23)cc1]

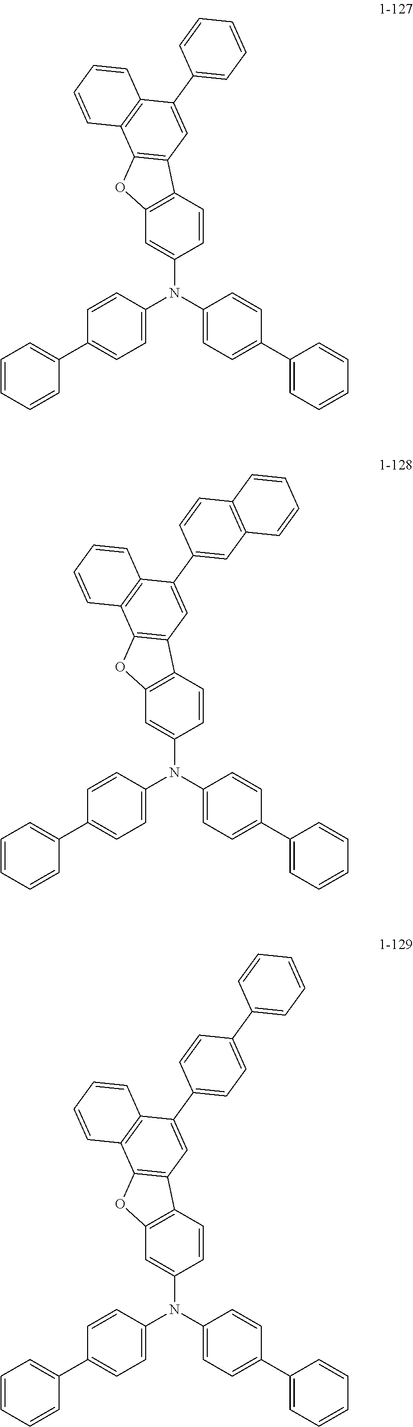 [SMILES: c1ccc(-c2ccc(N(c3ccc(-c4ccccc4)cc3)c3ccc4c(c3)oc3c5ccccc5c(-c5ccccc5)cc43)cc2)cc1 ; c1ccc(-c2ccc(N(c3ccc(-c4ccccc4)cc3)c3ccc4c(c3)oc3c5ccccc5c(-c5ccc6ccccc6c5)cc43)cc2)cc1 ; c1ccc(-c2ccc(-c3cc4c5ccc(N(c6ccc(-c7ccccc7)cc6)c6ccc(-c7ccccc7)cc6)cc5oc4c4ccccc34)cc2)cc1]

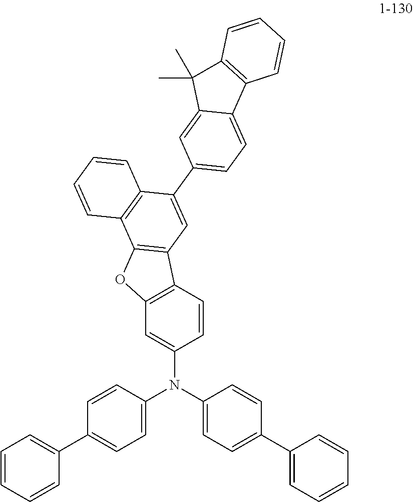 [SMILES: CC1(C)c2ccccc2-c2ccc(-c3cc4c5ccc(N(c6ccc(-c7ccccc7)cc6)c6ccc(-c7ccccc7)cc6)cc5oc4c4ccccc34)cc21]

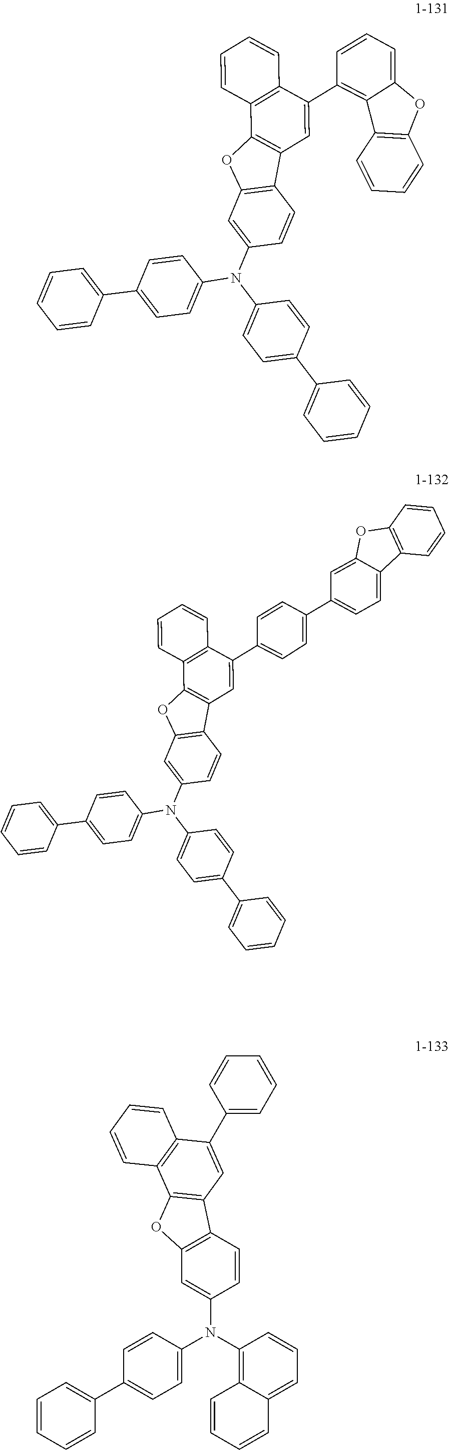 [SMILES: c1ccc(-c2ccc(N(c3ccc(-c4ccccc4)cc3)c3ccc4c(c3)oc3c5ccccc5c(-c5cccc6oc7ccccc7c56)cc43)cc2)cc1 ; c1ccc(-c2ccc(N(c3ccc(-c4ccccc4)cc3)c3ccc4c(c3)oc3c5ccccc5c(-c5ccc(-c6ccc7c(c6)oc6ccccc67)cc5)cc43)cc2)cc1 ; c1ccc(-c2ccc(N(c3ccc4c(c3)oc3c5ccccc5c(-c5ccccc5)cc43)c3cccc4ccccc34)cc2)cc1]

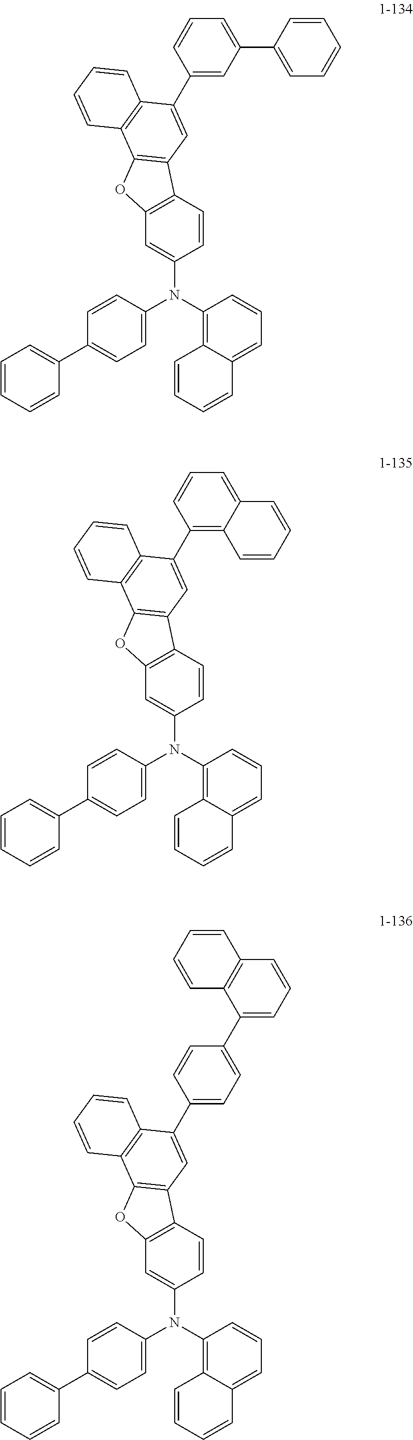 [SMILES: c1ccc(-c2ccc(N(c3ccc4c(c3)oc3c5ccccc5c(-c5cccc(-c6ccccc6)c5)cc43)c3cccc4ccccc34)cc2)cc1 ; c1ccc(-c2ccc(N(c3ccc4c(c3)oc3c5ccccc5c(-c5cccc6ccccc56)cc43)c3cccc4ccccc34)cc2)cc1 ; c1ccc(-c2ccc(N(c3ccc4c(c3)oc3c5ccccc5c(-c5ccc(-c6cccc7ccccc67)cc5)cc43)c3cccc4ccccc34)cc2)cc1]

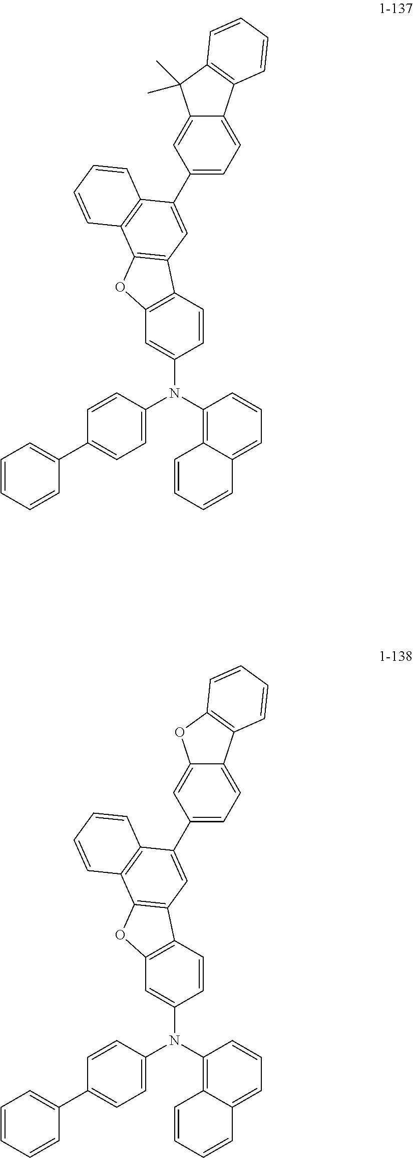 [SMILES: CC1(C)c2ccccc2-c2ccc(-c3cc4c5ccc(N(c6ccc(-c7ccccc7)cc6)c6cccc7ccccc67)cc5oc4c4ccccc34)cc21 ; c1ccc(-c2ccc(N(c3ccc4c(c3)oc3c5ccccc5c(-c5ccc6c(c5)oc5ccccc56)cc43)c3cccc4ccccc34)cc2)cc1]

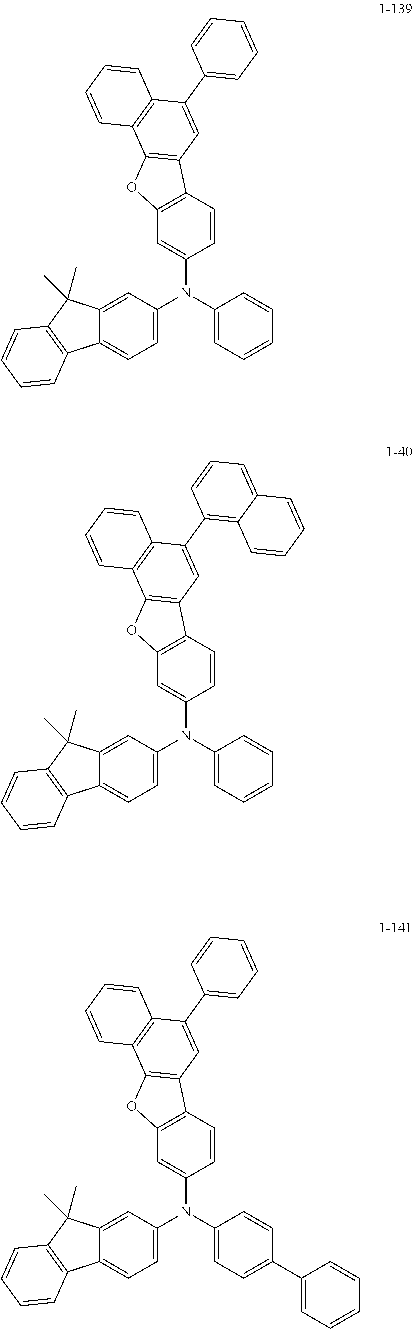 [SMILES: CC1(C)c2ccccc2-c2ccc(N(c3ccccc3)c3ccc4c(c3)oc3c5ccccc5c(-c5ccccc5)cc43)cc21 ; CC1(C)c2ccccc2-c2ccc(N(c3ccccc3)c3ccc4c(c3)oc3c5ccccc5c(-c5cccc6ccccc56)cc43)cc21 ; CC1(C)c2ccccc2-c2ccc(N(c3ccc(-c4ccccc4)cc3)c3ccc4c(c3)oc3c5ccccc5c(-c5ccccc5)cc43)cc21]

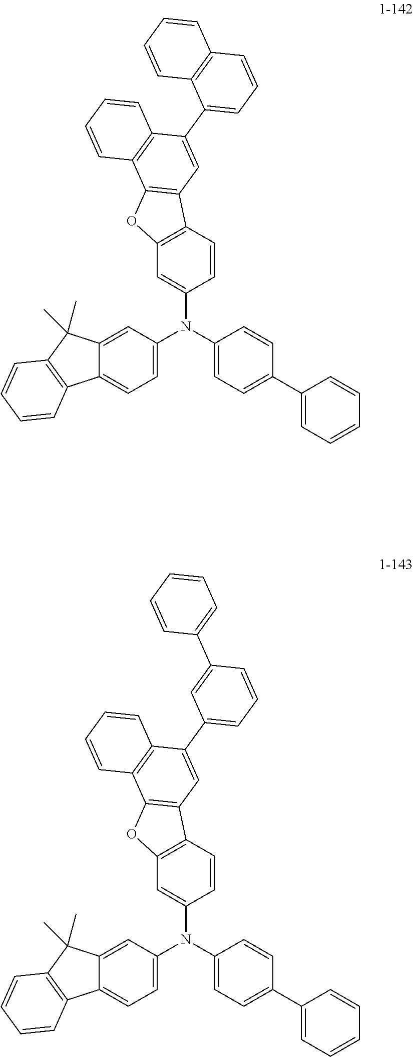 [SMILES: CC1(C)c2ccccc2-c2ccc(N(c3ccc(-c4ccccc4)cc3)c3ccc4c(c3)oc3c5ccccc5c(-c5cccc6ccccc56)cc43)cc21 ; CC1(C)c2ccccc2-c2ccc(N(c3ccc(-c4ccccc4)cc3)c3ccc4c(c3)oc3c5ccccc5c(-c5cccc(-c6ccccc6)c5)cc43)cc21]

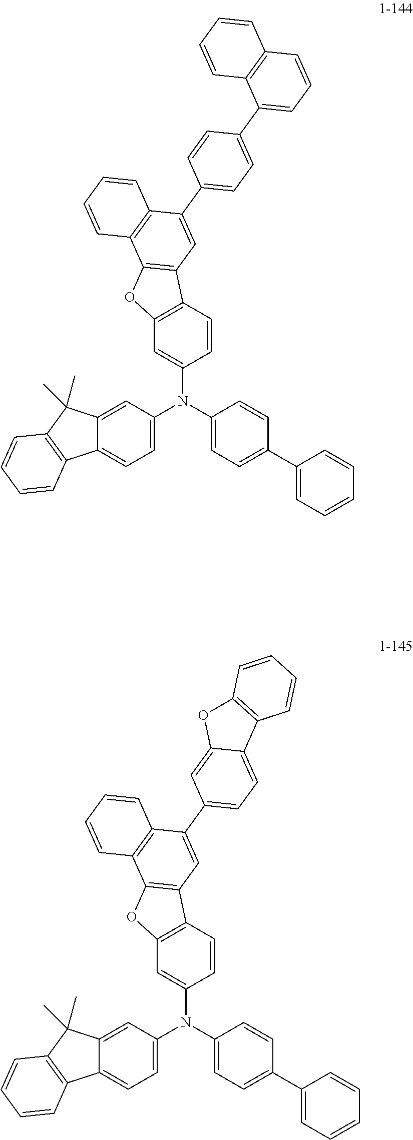 [SMILES: CC1(C)c2ccccc2-c2ccc(N(c3ccc(-c4ccccc4)cc3)c3ccc4c(c3)oc3c5ccccc5c(-c5ccc(-c6cccc7ccccc67)cc5)cc43)cc21 ; CC1(C)c2ccccc2-c2ccc(N(c3ccc(-c4ccccc4)cc3)c3ccc4c(c3)oc3c5ccccc5c(-c5ccc6c(c5)oc5ccccc56)cc43)cc21]

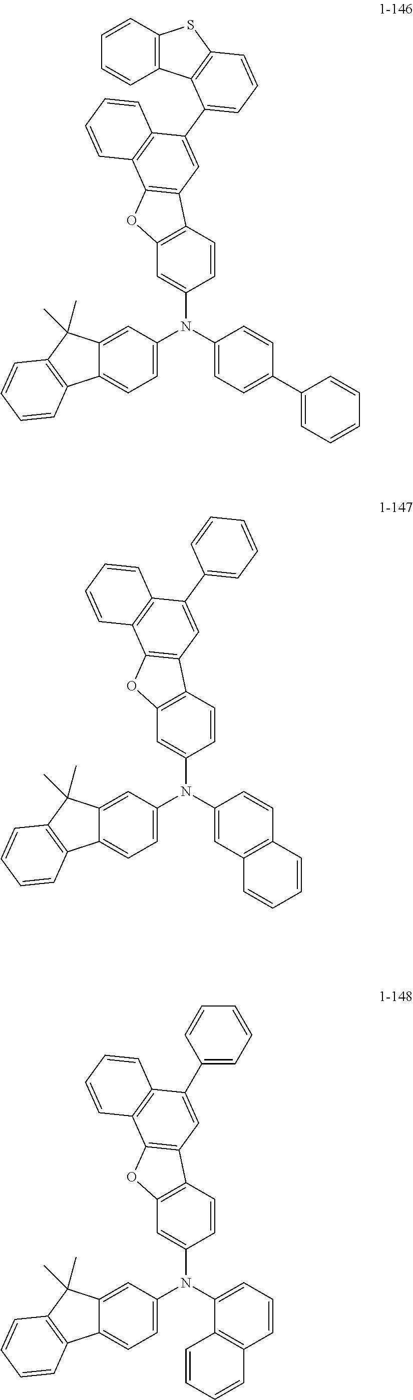 [SMILES: CC1(C)c2ccccc2-c2ccc(N(c3ccc(-c4ccccc4)cc3)c3ccc4c(c3)oc3c5ccccc5c(-c5cccc6sc7ccccc7c56)cc43)cc21 ; CC1(C)c2ccccc2-c2ccc(N(c3ccc4ccccc4c3)c3ccc4c(c3)oc3c5ccccc5c(-c5ccccc5)cc43)cc21 ; CC1(C)c2ccccc2-c2ccc(N(c3ccc4c(c3)oc3c5ccccc5c(-c5ccccc5)cc43)c3cccc4ccccc34)cc21]

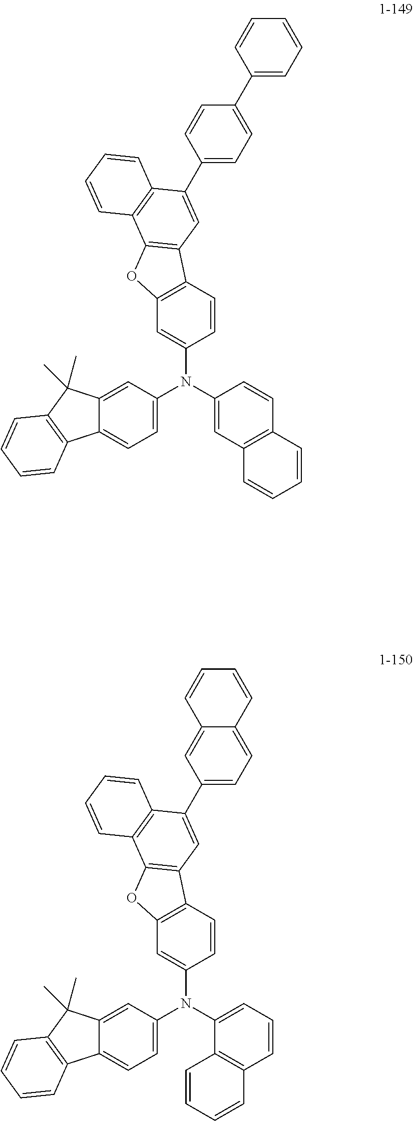 [SMILES: CC1(C)c2ccccc2-c2ccc(N(c3ccc4ccccc4c3)c3ccc4c(c3)oc3c5ccccc5c(-c5ccc(-c6ccccc6)cc5)cc43)cc21 ; CC1(C)c2ccccc2-c2ccc(N(c3ccc4c(c3)oc3c5ccccc5c(-c5ccc6ccccc6c5)cc43)c3cccc4ccccc34)cc21]

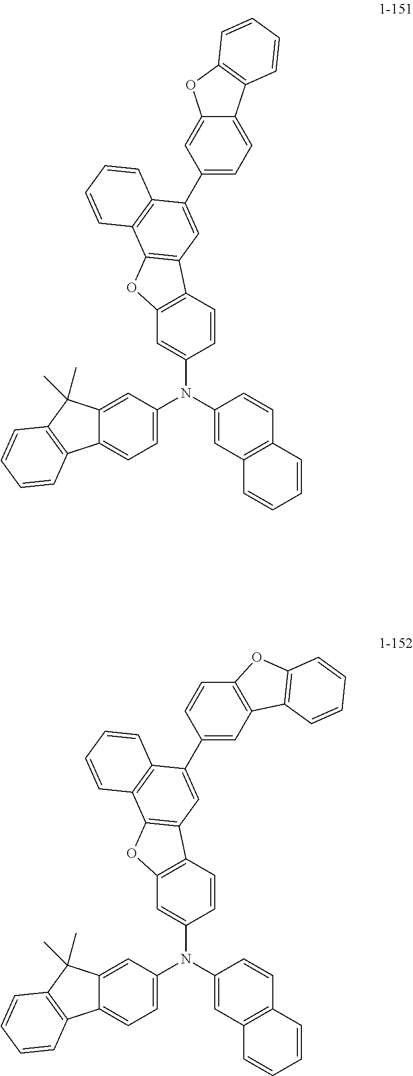 [SMILES: CC1(C)c2ccccc2-c2ccc(N(c3ccc4ccccc4c3)c3ccc4c(c3)oc3c5ccccc5c(-c5ccc6c(c5)oc5ccccc56)cc43)cc21 ; CC1(C)c2ccccc2-c2ccc(N(c3ccc4ccccc4c3)c3ccc4c(c3)oc3c5ccccc5c(-c5ccc6oc7ccccc7c6c5)cc43)cc21]

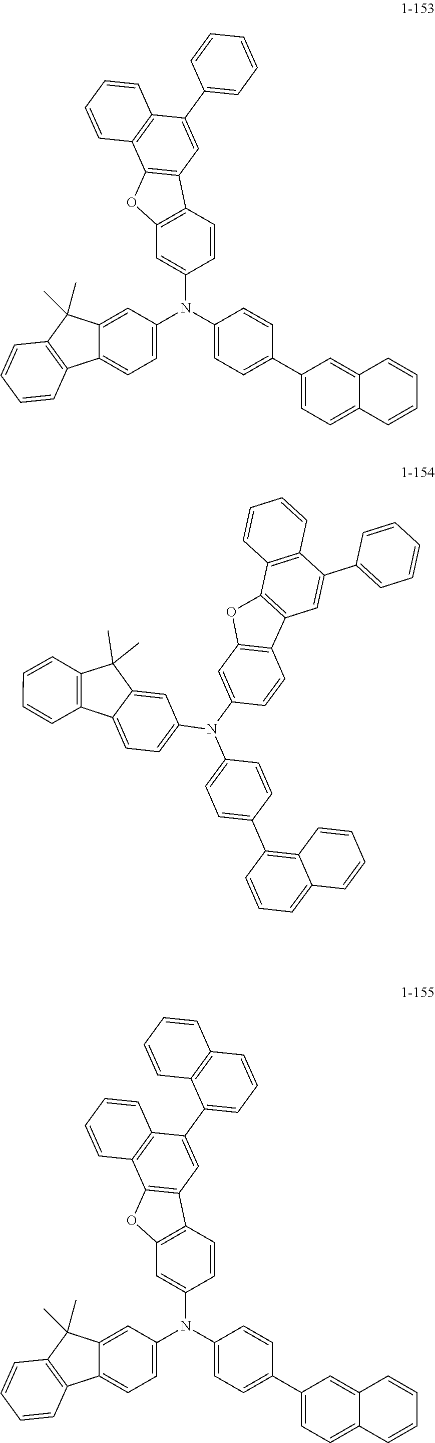 [SMILES: CC1(C)c2ccccc2-c2ccc(N(c3ccc(-c4ccc5ccccc5c4)cc3)c3ccc4c(c3)oc3c5ccccc5c(-c5ccccc5)cc43)cc21 ; CC1(C)c2ccccc2-c2ccc(N(c3ccc(-c4cccc5ccccc45)cc3)c3ccc4c(c3)oc3c5ccccc5c(-c5ccccc5)cc43)cc21 ; CC1(C)c2ccccc2-c2ccc(N(c3ccc(-c4ccc5ccccc5c4)cc3)c3ccc4c(c3)oc3c5ccccc5c(-c5cccc6ccccc56)cc43)cc21]

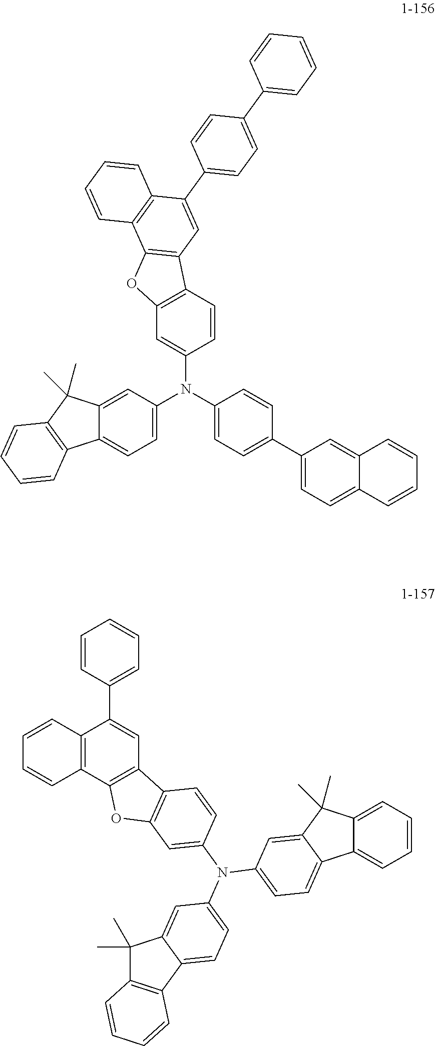 [SMILES: CC1(C)c2ccccc2-c2ccc(N(c3ccc(-c4ccc5ccccc5c4)cc3)c3ccc4c(c3)oc3c5ccccc5c(-c5ccc(-c6ccccc6)cc5)cc43)cc21 ; CC1(C)c2ccccc2-c2ccc(N(c3ccc4c(c3)C(C)(C)c3ccccc3-4)c3ccc4c(c3)oc3c5ccccc5c(-c5ccccc5)cc43)cc21]

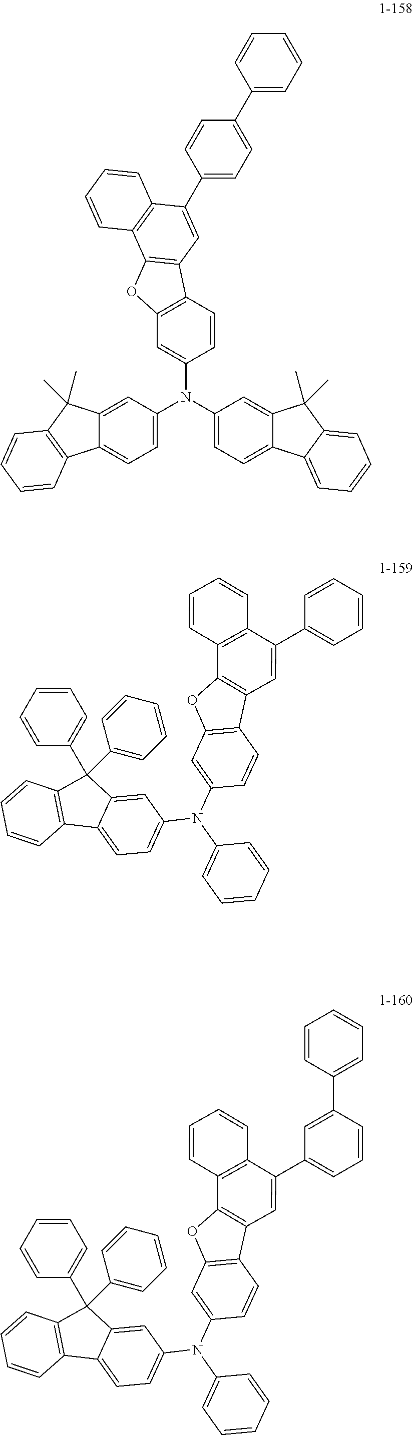 [SMILES: CC1(C)c2ccccc2-c2ccc(N(c3ccc4c(c3)C(C)(C)c3ccccc3-4)c3ccc4c(c3)oc3c5ccccc5c(-c5ccc(-c6ccccc6)cc5)cc43)cc21 ; c1ccc(-c2cc3c4ccc(N(c5ccccc5)c5ccc6c(c5)C(c5ccccc5)(c5ccccc5)c5ccccc5-6)cc4oc3c3ccccc23)cc1 ; c1ccc(-c2cccc(-c3cc4c5ccc(N(c6ccccc6)c6ccc7c(c6)C(c6ccccc6)(c6ccccc6)c6ccccc6-7)cc5oc4c4ccccc34)c2)cc1]

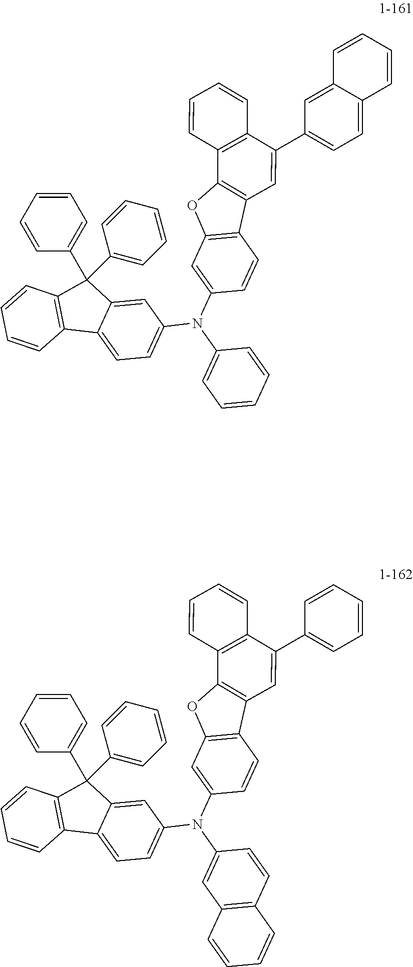 [SMILES: c1ccc(N(c2ccc3c(c2)C(c2ccccc2)(c2ccccc2)c2ccccc2-3)c2ccc3c(c2)oc2c4ccccc4c(-c4ccc5ccccc5c4)cc32)cc1 ; c1ccc(-c2cc3c4ccc(N(c5ccc6c(c5)C(c5ccccc5)(c5ccccc5)c5ccccc5-6)c5ccc6ccccc6c5)cc4oc3c3ccccc23)cc1]

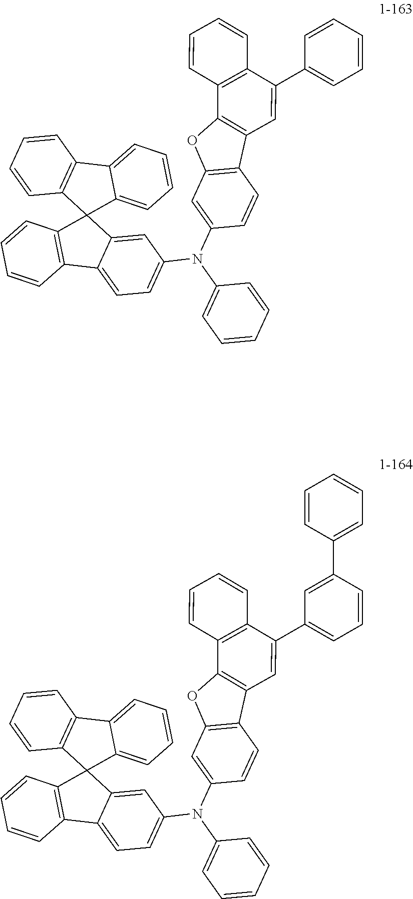 [SMILES: c1ccc(-c2cc3c4ccc(N(c5ccccc5)c5ccc6c(c5)C5(c7ccccc7-c7ccccc75)c5ccccc5-6)cc4oc3c3ccccc23)cc1 ; c1ccc(-c2cccc(-c3cc4c5ccc(N(c6ccccc6)c6ccc7c(c6)C6(c8ccccc8-c8ccccc86)c6ccccc6-7)cc5oc4c4ccccc34)c2)cc1]

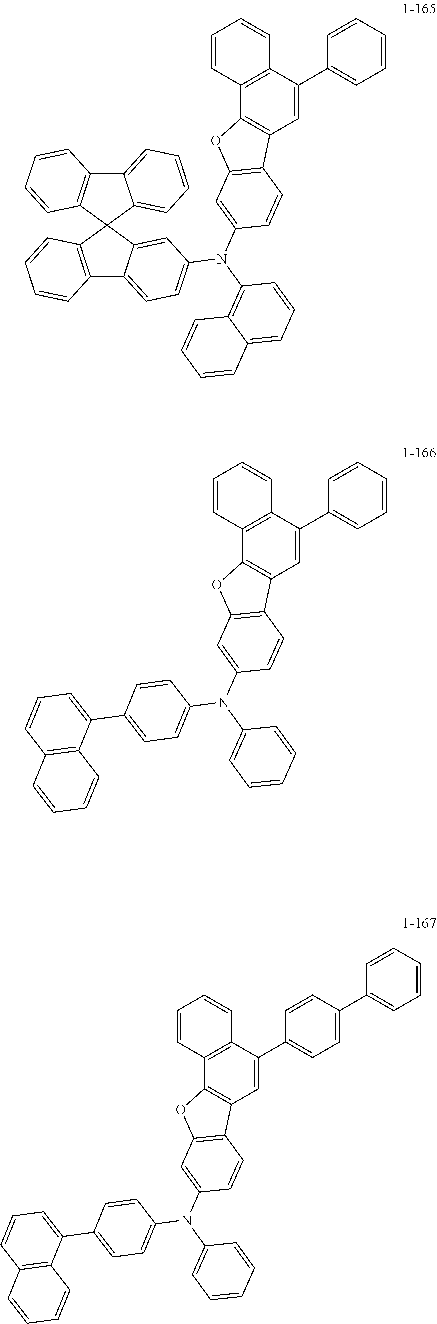 [SMILES: c1ccc(-c2cc3c4ccc(N(c5ccc6c(c5)C5(c7ccccc7-c7ccccc75)c5ccccc5-6)c5cccc6ccccc56)cc4oc3c3ccccc23)cc1 ; c1ccc(-c2cc3c4ccc(N(c5ccccc5)c5ccc(-c6cccc7ccccc67)cc5)cc4oc3c3ccccc23)cc1 ; c1ccc(-c2ccc(-c3cc4c5ccc(N(c6ccccc6)c6ccc(-c7cccc8ccccc78)cc6)cc5oc4c4ccccc34)cc2)cc1]

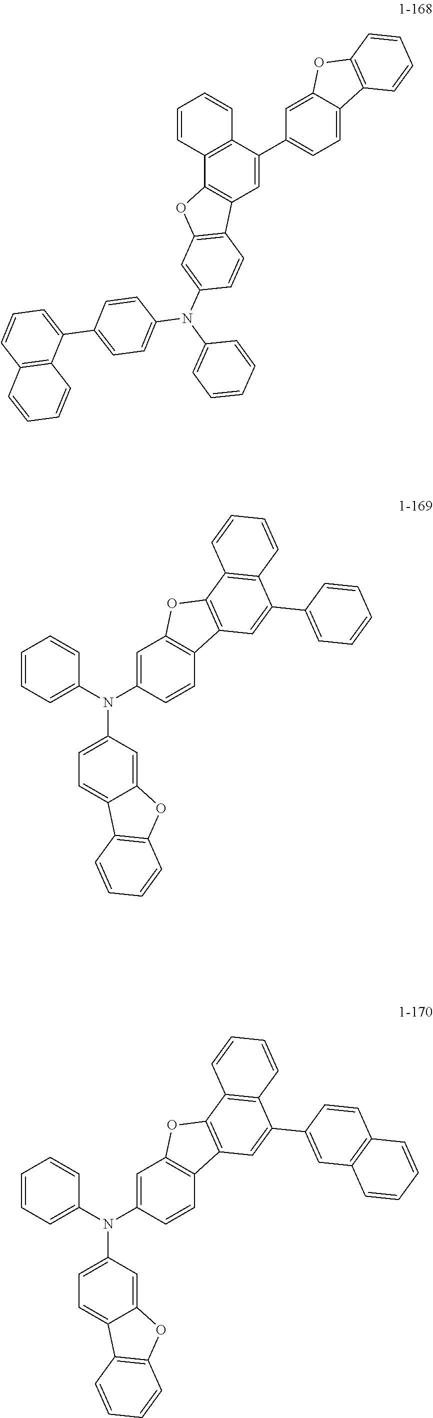 [SMILES: c1ccc(N(c2ccc(-c3cccc4ccccc34)cc2)c2ccc3c(c2)oc2c4ccccc4c(-c4ccc5c(c4)oc4ccccc45)cc32)cc1 ; c1ccc(-c2cc3c4ccc(N(c5ccccc5)c5ccc6c(c5)oc5ccccc56)cc4oc3c3ccccc23)cc1 ; c1ccc(N(c2ccc3c(c2)oc2ccccc23)c2ccc3c(c2)oc2c4ccccc4c(-c4ccc5ccccc5c4)cc32)cc1]

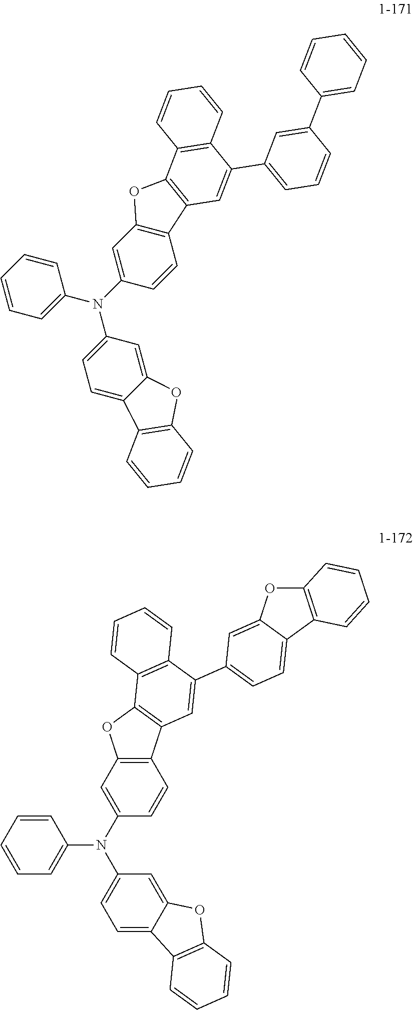 [SMILES: c1ccc(-c2cccc(-c3cc4c5ccc(N(c6ccccc6)c6ccc7c(c6)oc6ccccc67)cc5oc4c4ccccc34)c2)cc1 ; c1ccc(N(c2ccc3c(c2)oc2ccccc23)c2ccc3c(c2)oc2c4ccccc4c(-c4ccc5c(c4)oc4ccccc45)cc32)cc1]

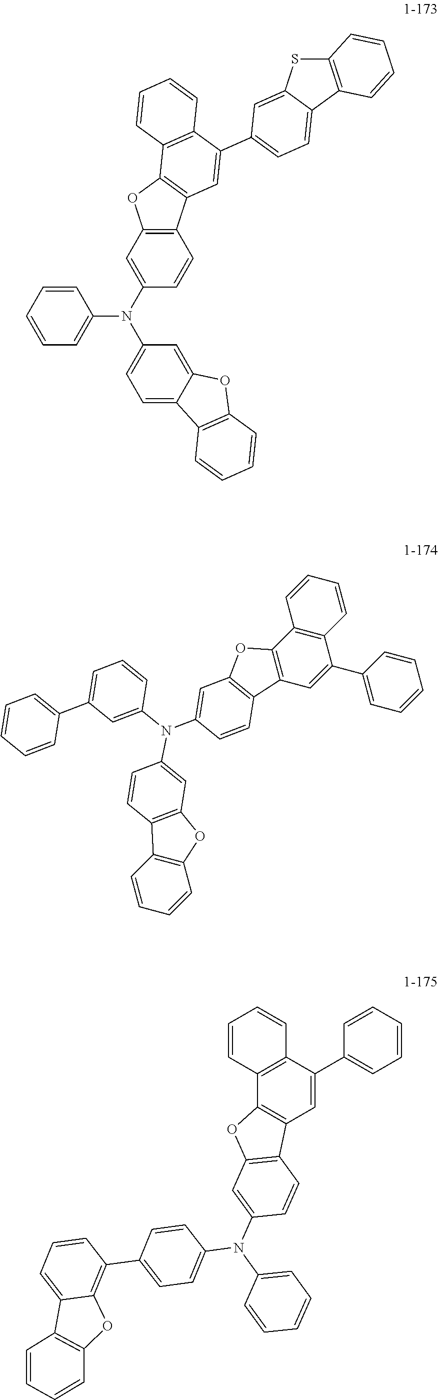 [SMILES: c1ccc(N(c2ccc3c(c2)oc2ccccc23)c2ccc3c(c2)oc2c4ccccc4c(-c4ccc5c(c4)sc4ccccc45)cc32)cc1 ; c1ccc(-c2cccc(N(c3ccc4c(c3)oc3ccccc34)c3ccc4c(c3)oc3c5ccccc5c(-c5ccccc5)cc43)c2)cc1 ; c1ccc(-c2cc3c4ccc(N(c5ccccc5)c5ccc(-c6cccc7c6oc6ccccc67)cc5)cc4oc3c3ccccc23)cc1]

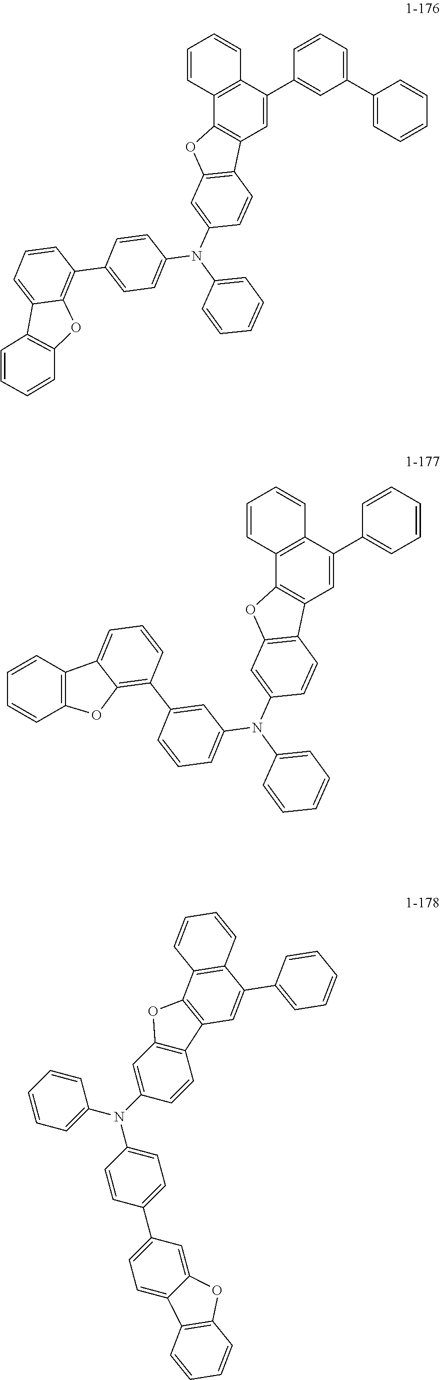 [SMILES: c1ccc(-c2cccc(-c3cc4c5ccc(N(c6ccccc6)c6ccc(-c7cccc8c7oc7ccccc78)cc6)cc5oc4c4ccccc34)c2)cc1 ; c1ccc(-c2cc3c4ccc(N(c5ccccc5)c5cccc(-c6cccc7c6oc6ccccc67)c5)cc4oc3c3ccccc23)cc1 ; c1ccc(-c2cc3c4ccc(N(c5ccccc5)c5ccc(-c6ccc7c(c6)oc6ccccc67)cc5)cc4oc3c3ccccc23)cc1]

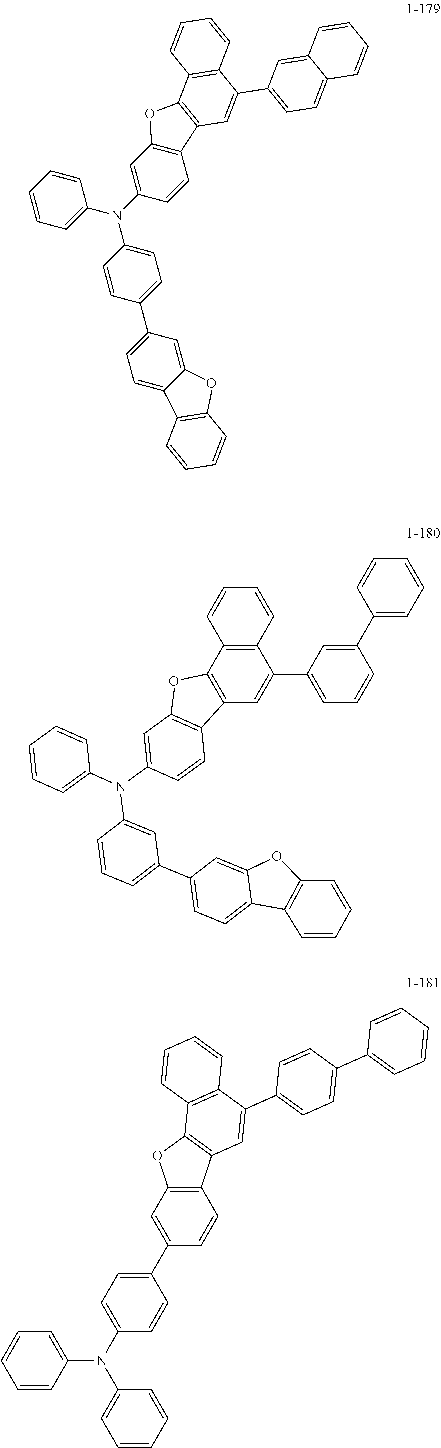 [SMILES: c1ccc(N(c2ccc(-c3ccc4c(c3)oc3ccccc34)cc2)c2ccc3c(c2)oc2c4ccccc4c(-c4ccc5ccccc5c4)cc32)cc1 ; c1ccc(-c2cccc(-c3cc4c5ccc(N(c6ccccc6)c6cccc(-c7ccc8c(c7)oc7ccccc78)c6)cc5oc4c4ccccc34)c2)cc1 ; c1ccc(-c2ccc(-c3cc4c5ccc(-c6ccc(N(c7ccccc7)c7ccccc7)cc6)cc5oc4c4ccccc34)cc2)cc1]

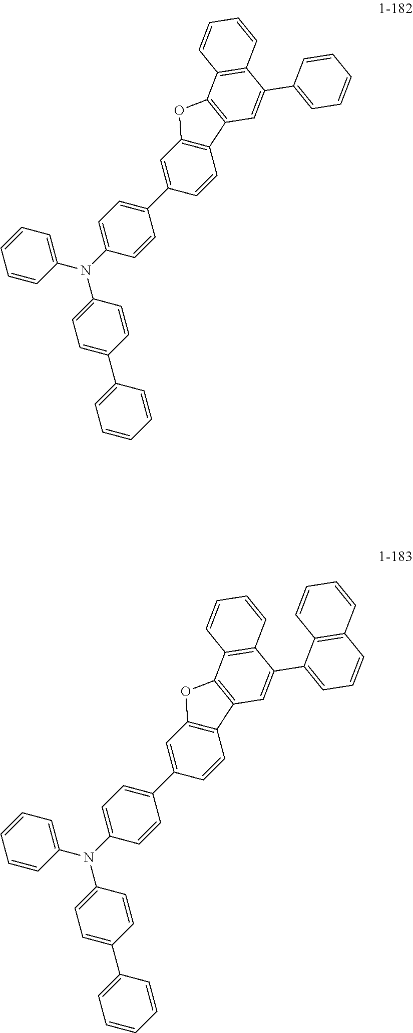 [SMILES: c1ccc(-c2ccc(N(c3ccccc3)c3ccc(-c4ccc5c(c4)oc4c6ccccc6c(-c6ccccc6)cc54)cc3)cc2)cc1 ; c1ccc(-c2ccc(N(c3ccccc3)c3ccc(-c4ccc5c(c4)oc4c6ccccc6c(-c6cccc7ccccc67)cc54)cc3)cc2)cc1]

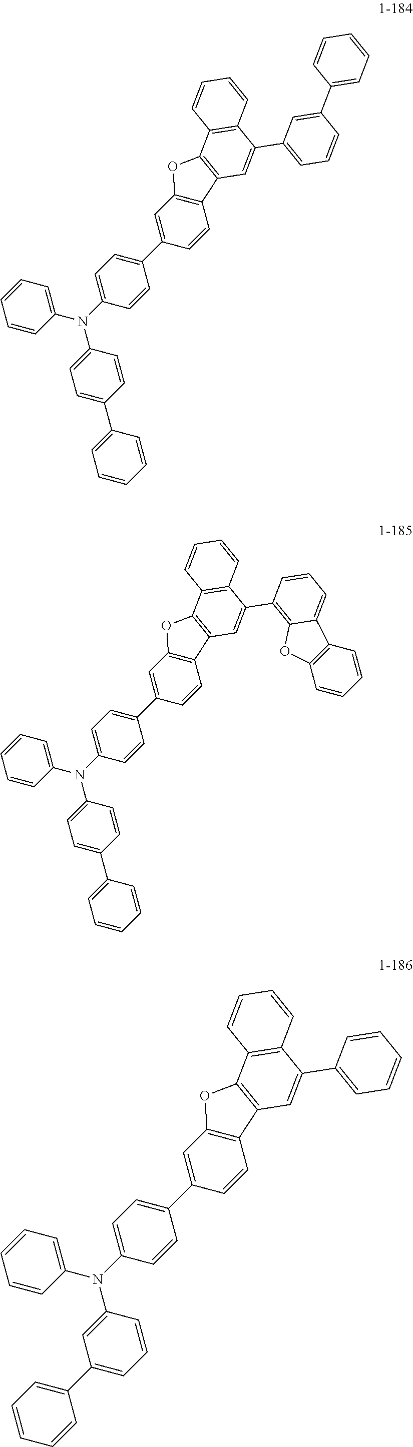 [SMILES: c1ccc(-c2ccc(N(c3ccccc3)c3ccc(-c4ccc5c(c4)oc4c6ccccc6c(-c6cccc(-c7ccccc7)c6)cc54)cc3)cc2)cc1 ; c1ccc(-c2ccc(N(c3ccccc3)c3ccc(-c4ccc5c(c4)oc4c6ccccc6c(-c6cccc7c6oc6ccccc67)cc54)cc3)cc2)cc1 ; c1ccc(-c2cccc(N(c3ccccc3)c3ccc(-c4ccc5c(c4)oc4c6ccccc6c(-c6ccccc6)cc54)cc3)c2)cc1]

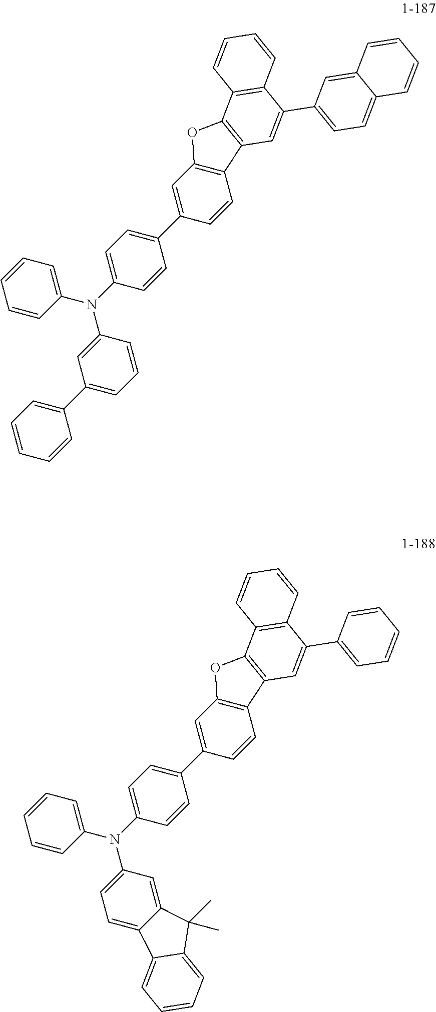 [SMILES: c1ccc(-c2cccc(N(c3ccccc3)c3ccc(-c4ccc5c(c4)oc4c6ccccc6c(-c6ccc7ccccc7c6)cc54)cc3)c2)cc1 ; CC1(C)c2ccccc2-c2ccc(N(c3ccccc3)c3ccc(-c4ccc5c(c4)oc4c6ccccc6c(-c6ccccc6)cc54)cc3)cc21]

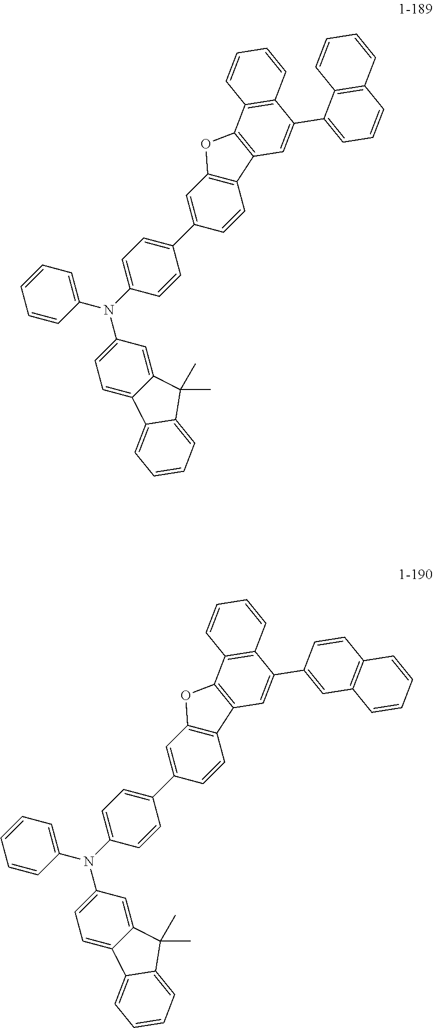 [SMILES: CC1(C)c2ccccc2-c2ccc(N(c3ccccc3)c3ccc(-c4ccc5c(c4)oc4c6ccccc6c(-c6cccc7ccccc67)cc54)cc3)cc21 ; CC1(C)c2ccccc2-c2ccc(N(c3ccccc3)c3ccc(-c4ccc5c(c4)oc4c6ccccc6c(-c6ccc7ccccc7c6)cc54)cc3)cc21]

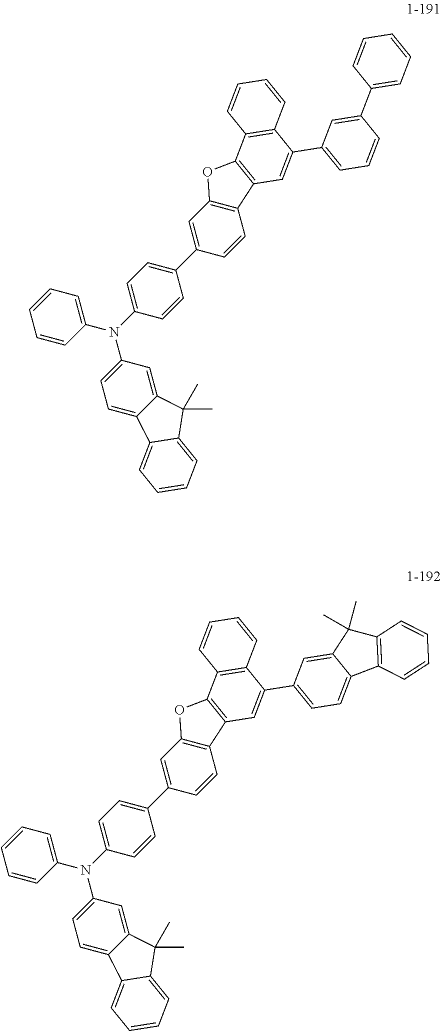 [SMILES: CC1(C)c2ccccc2-c2ccc(N(c3ccccc3)c3ccc(-c4ccc5c(c4)oc4c6ccccc6c(-c6cccc(-c7ccccc7)c6)cc54)cc3)cc21 ; CC1(C)c2ccccc2-c2ccc(-c3cc4c5ccc(-c6ccc(N(c7ccccc7)c7ccc8c(c7)C(C)(C)c7ccccc7-8)cc6)cc5oc4c4ccccc34)cc21]

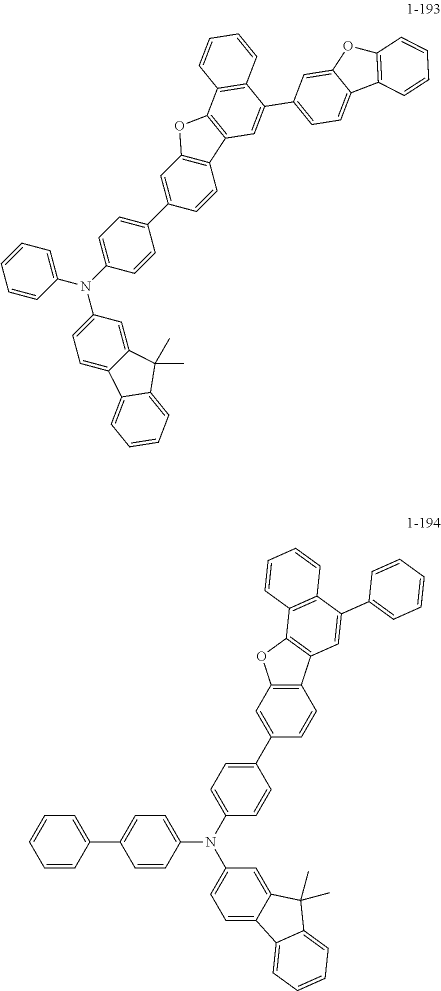 [SMILES: CC1(C)c2ccccc2-c2ccc(N(c3ccccc3)c3ccc(-c4ccc5c(c4)oc4c6ccccc6c(-c6ccc7c(c6)oc6ccccc67)cc54)cc3)cc21 ; CC1(C)c2ccccc2-c2ccc(N(c3ccc(-c4ccccc4)cc3)c3ccc(-c4ccc5c(c4)oc4c6ccccc6c(-c6ccccc6)cc54)cc3)cc21]

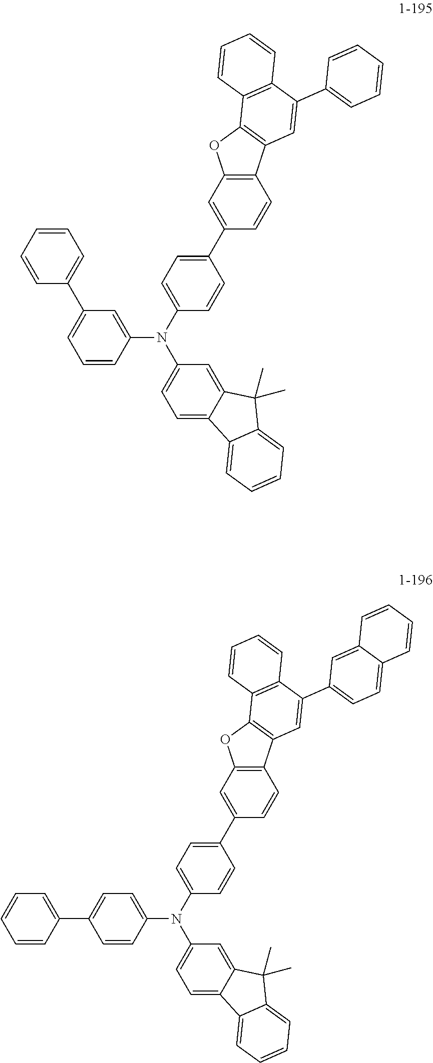 [SMILES: CC1(C)c2ccccc2-c2ccc(N(c3ccc(-c4ccc5c(c4)oc4c6ccccc6c(-c6ccccc6)cc54)cc3)c3cccc(-c4ccccc4)c3)cc21 ; CC1(C)c2ccccc2-c2ccc(N(c3ccc(-c4ccccc4)cc3)c3ccc(-c4ccc5c(c4)oc4c6ccccc6c(-c6ccc7ccccc7c6)cc54)cc3)cc21]

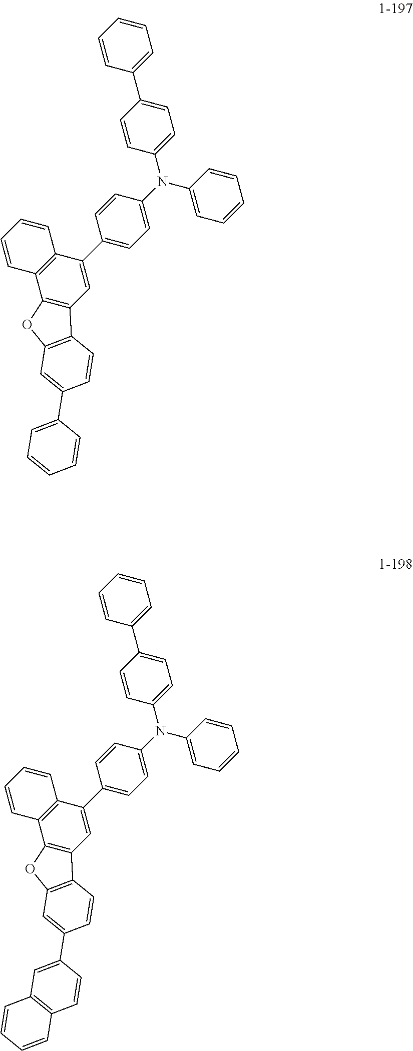 [SMILES: c1ccc(-c2ccc(N(c3ccccc3)c3ccc(-c4cc5c6ccc(-c7ccccc7)cc6oc5c5ccccc45)cc3)cc2)cc1 ; c1ccc(-c2ccc(N(c3ccccc3)c3ccc(-c4cc5c6ccc(-c7ccc8ccccc8c7)cc6oc5c5ccccc45)cc3)cc2)cc1]

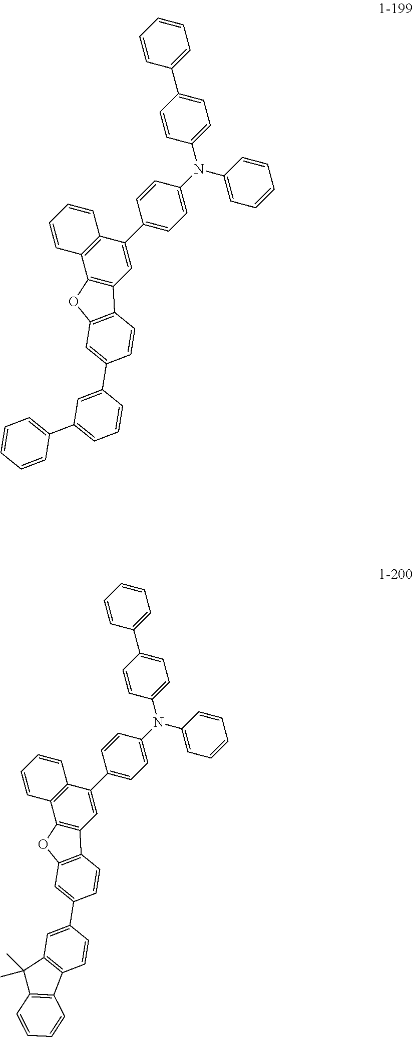 [SMILES: c1ccc(-c2ccc(N(c3ccccc3)c3ccc(-c4cc5c6ccc(-c7cccc(-c8ccccc8)c7)cc6oc5c5ccccc45)cc3)cc2)cc1 ; CC1(C)c2ccccc2-c2ccc(-c3ccc4c(c3)oc3c5ccccc5c(-c5ccc(N(c6ccccc6)c6ccc(-c7ccccc7)cc6)cc5)cc43)cc21]

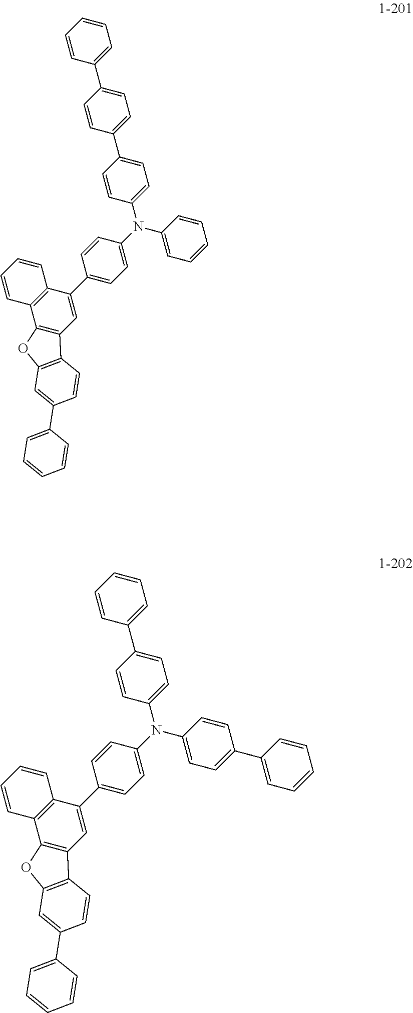 [SMILES: c1ccc(-c2ccc(-c3ccc(N(c4ccccc4)c4ccc(-c5cc6c7ccc(-c8ccccc8)cc7oc6c6ccccc56)cc4)cc3)cc2)cc1 ; c1ccc(-c2ccc(N(c3ccc(-c4ccccc4)cc3)c3ccc(-c4cc5c6ccc(-c7ccccc7)cc6oc5c5ccccc45)cc3)cc2)cc1]

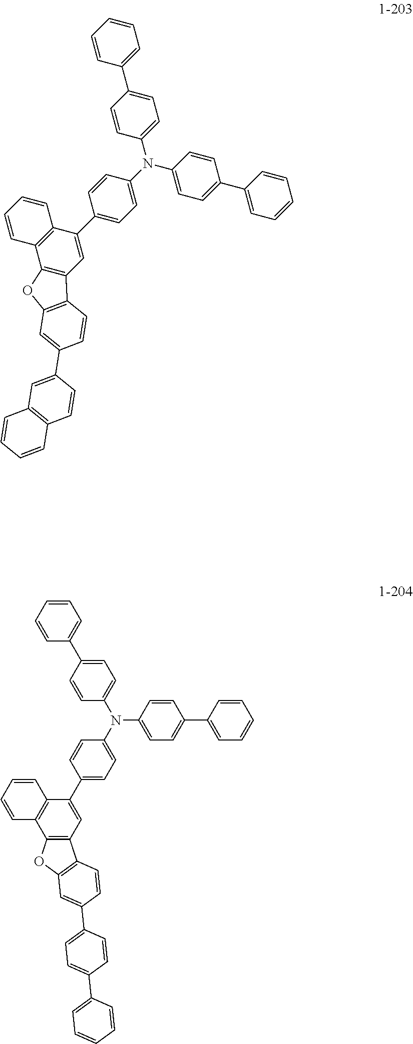 [SMILES: c1ccc(-c2ccc(N(c3ccc(-c4ccccc4)cc3)c3ccc(-c4cc5c6ccc(-c7ccc8ccccc8c7)cc6oc5c5ccccc45)cc3)cc2)cc1 ; c1ccc(-c2ccc(-c3ccc4c(c3)oc3c5ccccc5c(-c5ccc(N(c6ccc(-c7ccccc7)cc6)c6ccc(-c7ccccc7)cc6)cc5)cc43)cc2)cc1]

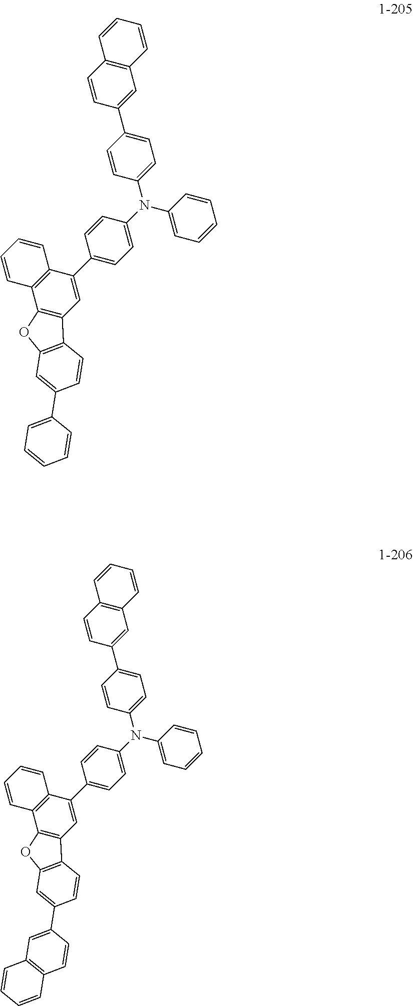 [SMILES: c1ccc(-c2ccc3c(c2)oc2c4ccccc4c(-c4ccc(N(c5ccccc5)c5ccc(-c6ccc7ccccc7c6)cc5)cc4)cc32)cc1 ; c1ccc(N(c2ccc(-c3ccc4ccccc4c3)cc2)c2ccc(-c3cc4c5ccc(-c6ccc7ccccc7c6)cc5oc4c4ccccc34)cc2)cc1]

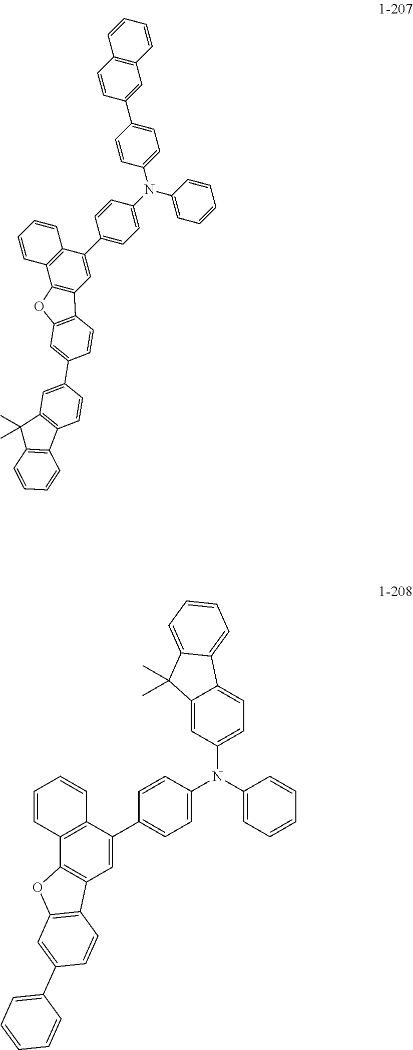 [SMILES: CC1(C)c2ccccc2-c2ccc(-c3ccc4c(c3)oc3c5ccccc5c(-c5ccc(N(c6ccccc6)c6ccc(-c7ccc8ccccc8c7)cc6)cc5)cc43)cc21 ; CC1(C)c2ccccc2-c2ccc(N(c3ccccc3)c3ccc(-c4cc5c6ccc(-c7ccccc7)cc6oc5c5ccccc45)cc3)cc21]

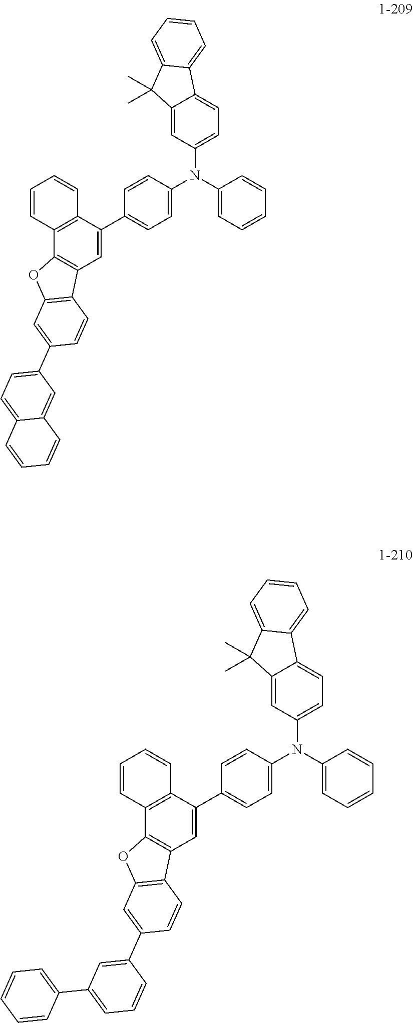 [SMILES: CC1(C)c2ccccc2-c2ccc(N(c3ccccc3)c3ccc(-c4cc5c6ccc(-c7ccc8ccccc8c7)cc6oc5c5ccccc45)cc3)cc21 ; CC1(C)c2ccccc2-c2ccc(N(c3ccccc3)c3ccc(-c4cc5c6ccc(-c7cccc(-c8ccccc8)c7)cc6oc5c5ccccc45)cc3)cc21]

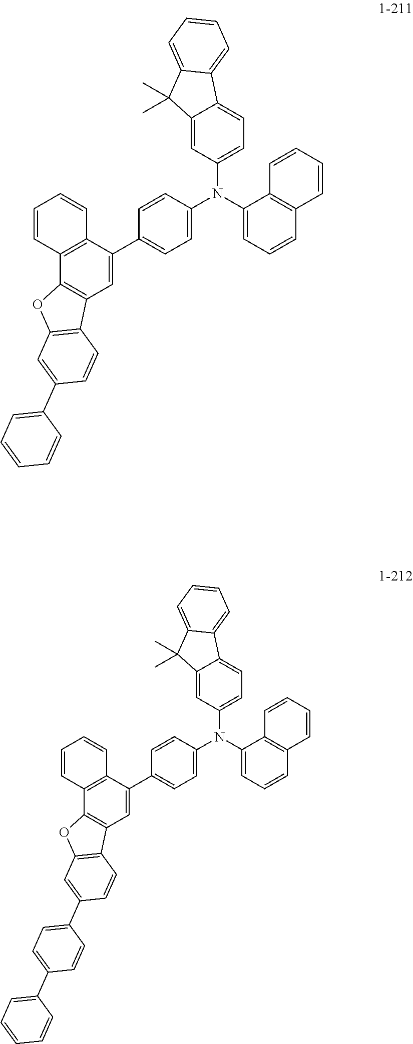 [SMILES: CC1(C)c2ccccc2-c2ccc(N(c3ccc(-c4cc5c6ccc(-c7ccccc7)cc6oc5c5ccccc45)cc3)c3cccc4ccccc34)cc21 ; CC1(C)c2ccccc2-c2ccc(N(c3ccc(-c4cc5c6ccc(-c7ccc(-c8ccccc8)cc7)cc6oc5c5ccccc45)cc3)c3cccc4ccccc34)cc21]

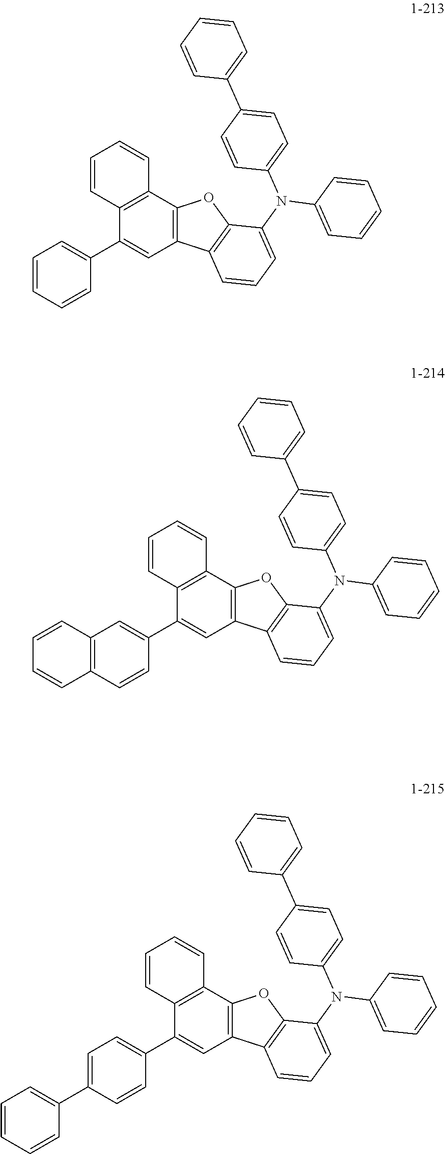 [SMILES: c1ccc(-c2ccc(N(c3ccccc3)c3cccc4c3oc3c5ccccc5c(-c5ccccc5)cc43)cc2)cc1 ; c1ccc(-c2ccc(N(c3ccccc3)c3cccc4c3oc3c5ccccc5c(-c5ccc6ccccc6c5)cc43)cc2)cc1 ; c1ccc(-c2ccc(-c3cc4c5cccc(N(c6ccccc6)c6ccc(-c7ccccc7)cc6)c5oc4c4ccccc34)cc2)cc1]

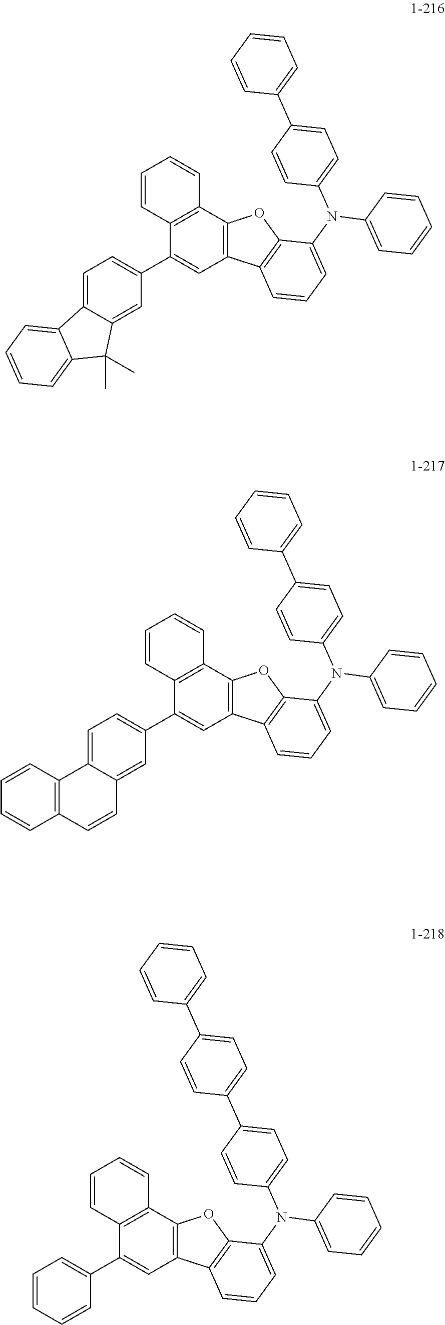 [SMILES: CC1(C)c2ccccc2-c2ccc(-c3cc4c5cccc(N(c6ccccc6)c6ccc(-c7ccccc7)cc6)c5oc4c4ccccc34)cc21 ; c1ccc(-c2ccc(N(c3ccccc3)c3cccc4c3oc3c5ccccc5c(-c5ccc6c(ccc7ccccc76)c5)cc43)cc2)cc1 ; c1ccc(-c2ccc(-c3ccc(N(c4ccccc4)c4cccc5c4oc4c6ccccc6c(-c6ccccc6)cc54)cc3)cc2)cc1]

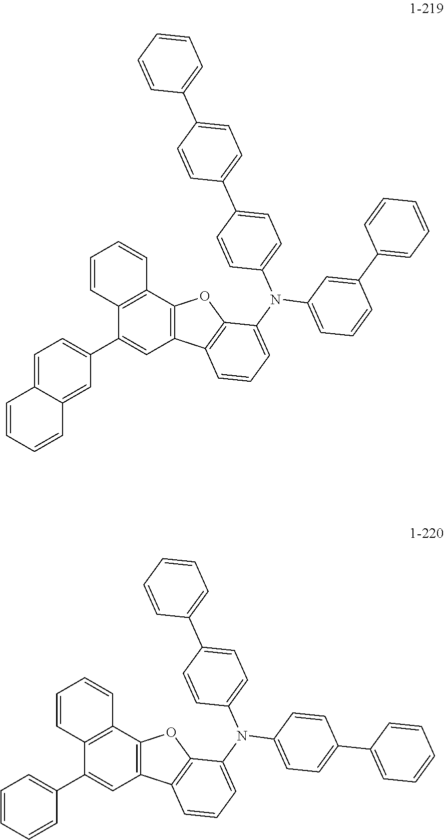 [SMILES: c1ccc(-c2ccc(-c3ccc(N(c4cccc(-c5ccccc5)c4)c4cccc5c4oc4c6ccccc6c(-c6ccc7ccccc7c6)cc54)cc3)cc2)cc1 ; c1ccc(-c2ccc(N(c3ccc(-c4ccccc4)cc3)c3cccc4c3oc3c5ccccc5c(-c5ccccc5)cc43)cc2)cc1]

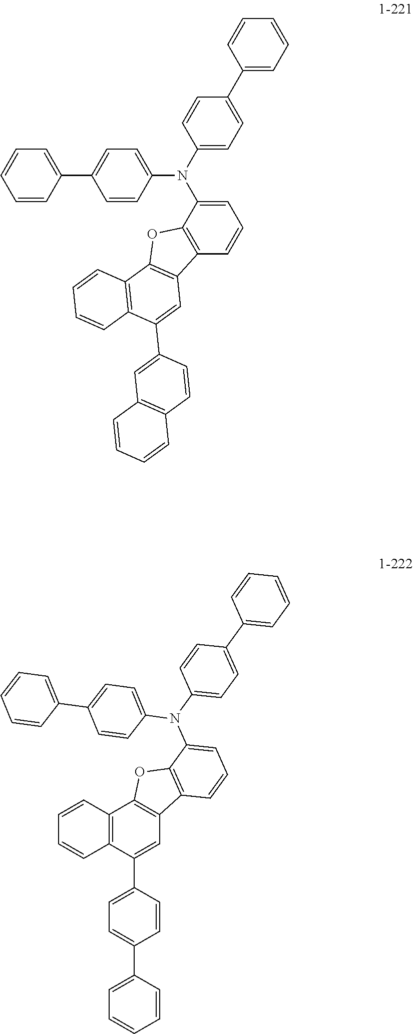 [SMILES: c1ccc(-c2ccc(N(c3ccc(-c4ccccc4)cc3)c3cccc4c3oc3c5ccccc5c(-c5ccc6ccccc6c5)cc43)cc2)cc1 ; c1ccc(-c2ccc(-c3cc4c5cccc(N(c6ccc(-c7ccccc7)cc6)c6ccc(-c7ccccc7)cc6)c5oc4c4ccccc34)cc2)cc1]

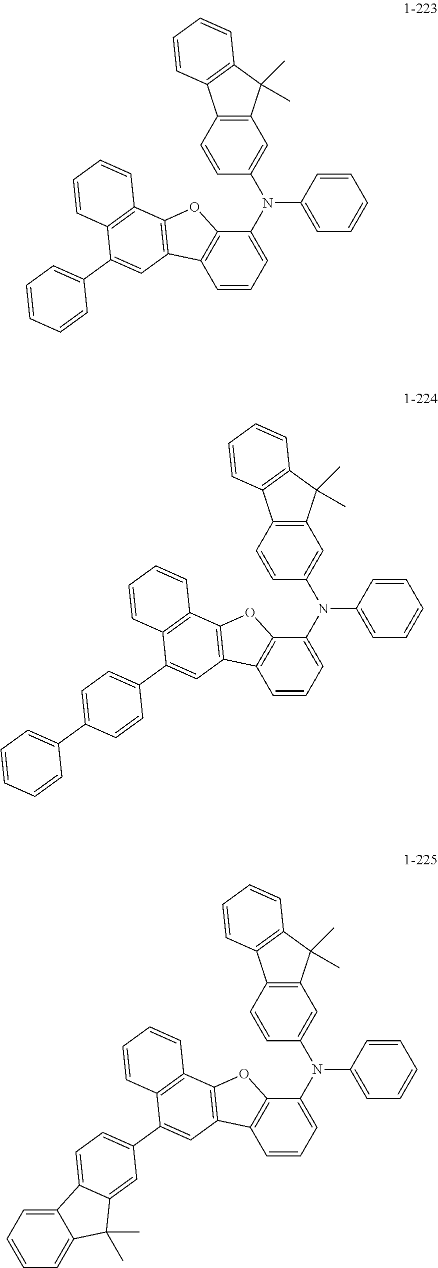 [SMILES: CC1(C)c2ccccc2-c2ccc(N(c3ccccc3)c3cccc4c3oc3c5ccccc5c(-c5ccccc5)cc43)cc21 ; CC1(C)c2ccccc2-c2ccc(N(c3ccccc3)c3cccc4c3oc3c5ccccc5c(-c5ccc(-c6ccccc6)cc5)cc43)cc21 ; CC1(C)c2ccccc2-c2ccc(-c3cc4c5cccc(N(c6ccccc6)c6ccc7c(c6)C(C)(C)c6ccccc6-7)c5oc4c4ccccc34)cc21]

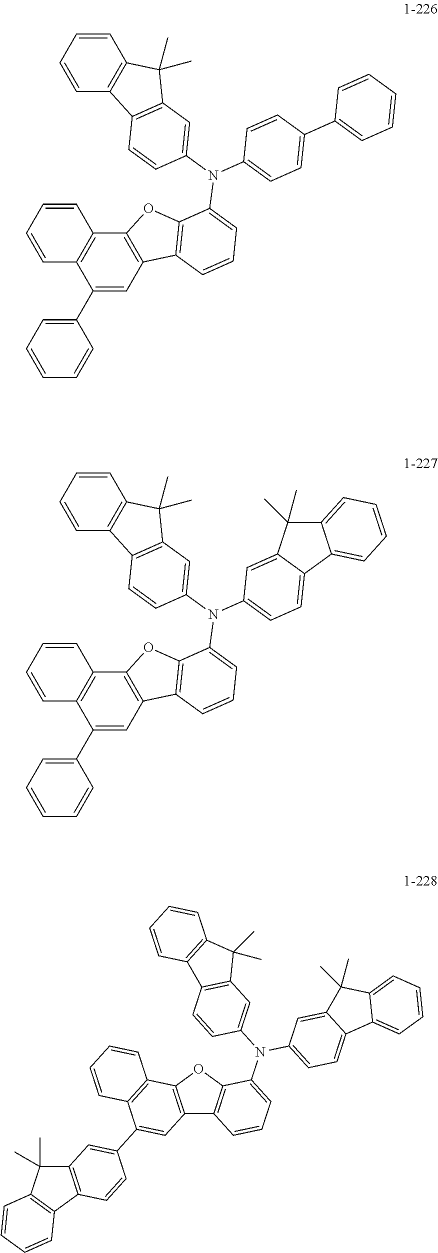 [SMILES: CC1(C)c2ccccc2-c2ccc(N(c3ccc(-c4ccccc4)cc3)c3cccc4c3oc3c5ccccc5c(-c5ccccc5)cc43)cc21 ; CC1(C)c2ccccc2-c2ccc(N(c3ccc4c(c3)C(C)(C)c3ccccc3-4)c3cccc4c3oc3c5ccccc5c(-c5ccccc5)cc43)cc21 ; CC1(C)c2ccccc2-c2ccc(-c3cc4c5cccc(N(c6ccc7c(c6)C(C)(C)c6ccccc6-7)c6ccc7c(c6)C(C)(C)c6ccccc6-7)c5oc4c4ccccc34)cc21]

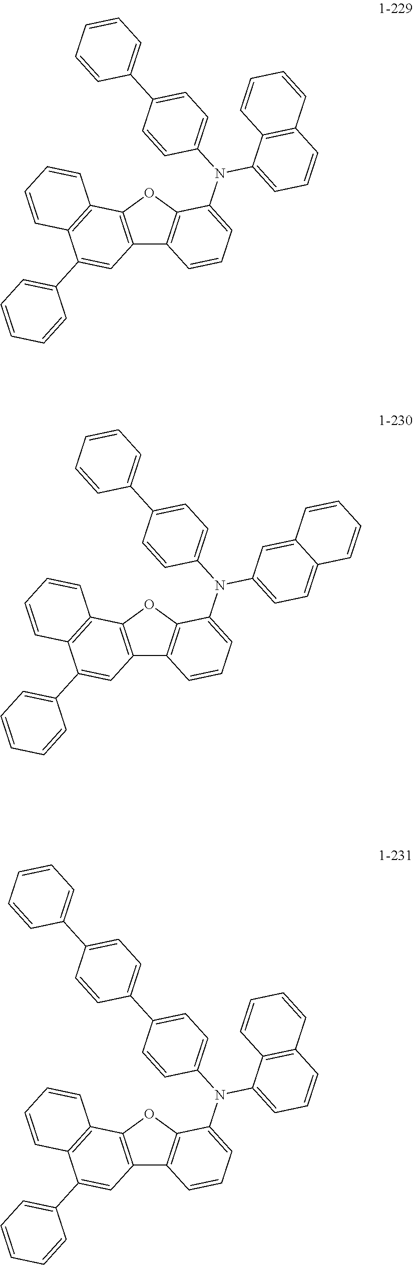 [SMILES: c1ccc(-c2ccc(N(c3cccc4ccccc34)c3cccc4c3oc3c5ccccc5c(-c5ccccc5)cc43)cc2)cc1 ; c1ccc(-c2ccc(N(c3ccc4ccccc4c3)c3cccc4c3oc3c5ccccc5c(-c5ccccc5)cc43)cc2)cc1 ; c1ccc(-c2ccc(-c3ccc(N(c4cccc5ccccc45)c4cccc5c4oc4c6ccccc6c(-c6ccccc6)cc54)cc3)cc2)cc1]

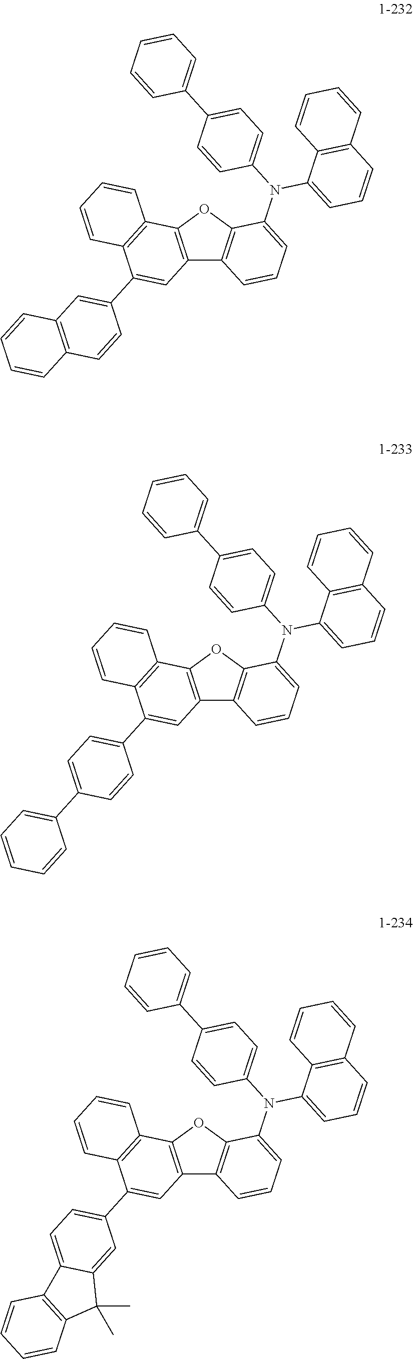 [SMILES: c1ccc(-c2ccc(N(c3cccc4ccccc34)c3cccc4c3oc3c5ccccc5c(-c5ccc6ccccc6c5)cc43)cc2)cc1 ; c1ccc(-c2ccc(-c3cc4c5cccc(N(c6ccc(-c7ccccc7)cc6)c6cccc7ccccc67)c5oc4c4ccccc34)cc2)cc1 ; CC1(C)c2ccccc2-c2ccc(-c3cc4c5cccc(N(c6ccc(-c7ccccc7)cc6)c6cccc7ccccc67)c5oc4c4ccccc34)cc21]

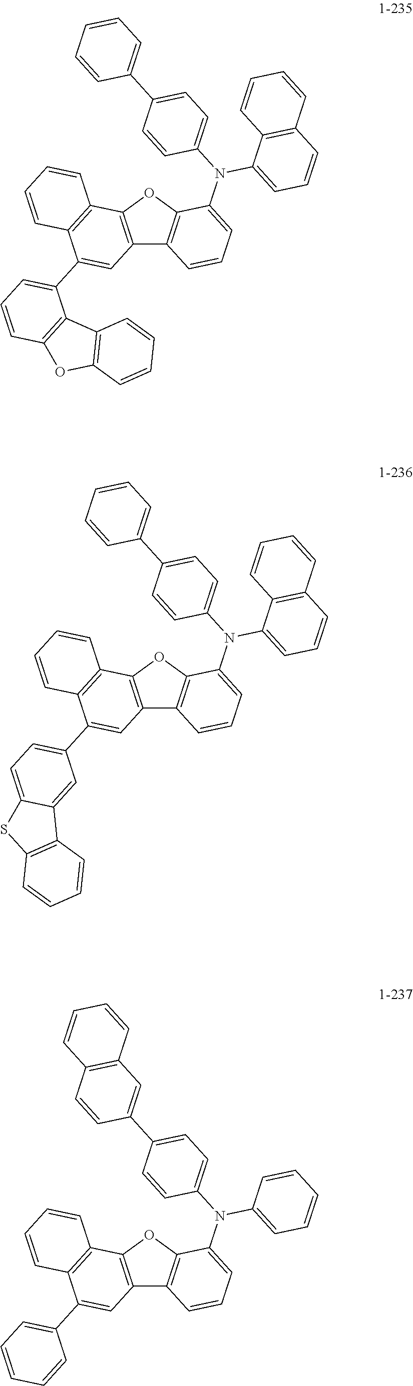 [SMILES: c1ccc(-c2ccc(N(c3cccc4ccccc34)c3cccc4c3oc3c5ccccc5c(-c5cccc6oc7ccccc7c56)cc43)cc2)cc1 ; c1ccc(-c2ccc(N(c3cccc4ccccc34)c3cccc4c3oc3c5ccccc5c(-c5ccc6sc7ccccc7c6c5)cc43)cc2)cc1 ; c1ccc(-c2cc3c4cccc(N(c5ccccc5)c5ccc(-c6ccc7ccccc7c6)cc5)c4oc3c3ccccc23)cc1]

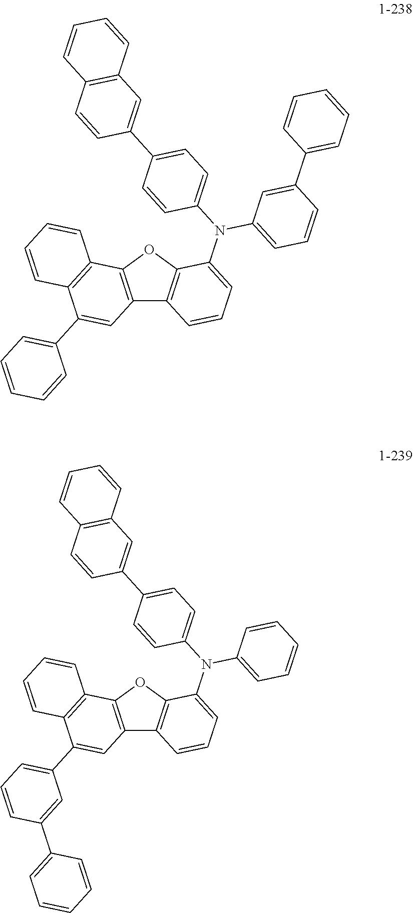 [SMILES: c1ccc(-c2cccc(N(c3ccc(-c4ccc5ccccc5c4)cc3)c3cccc4c3oc3c5ccccc5c(-c5ccccc5)cc43)c2)cc1 ; c1ccc(-c2cccc(-c3cc4c5cccc(N(c6ccccc6)c6ccc(-c7ccc8ccccc8c7)cc6)c5oc4c4ccccc34)c2)cc1]

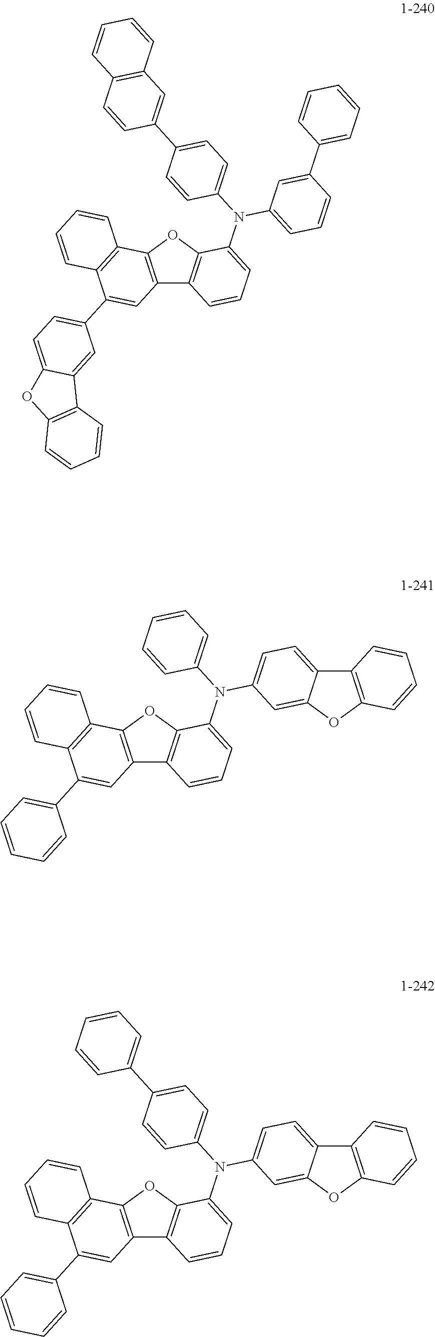 [SMILES: c1ccc(-c2cccc(N(c3ccc(-c4ccc5ccccc5c4)cc3)c3cccc4c3oc3c5ccccc5c(-c5ccc6oc7ccccc7c6c5)cc43)c2)cc1 ; c1ccc(-c2cc3c4cccc(N(c5ccccc5)c5ccc6c(c5)oc5ccccc56)c4oc3c3ccccc23)cc1 ; c1ccc(-c2ccc(N(c3ccc4c(c3)oc3ccccc34)c3cccc4c3oc3c5ccccc5c(-c5ccccc5)cc43)cc2)cc1]

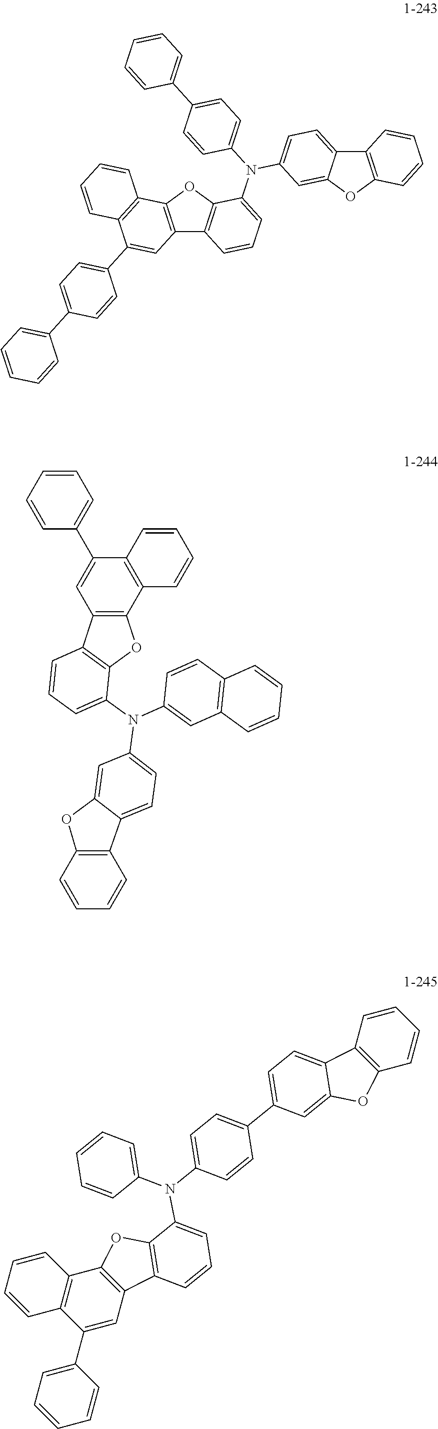 [SMILES: c1ccc(-c2ccc(-c3cc4c5cccc(N(c6ccc(-c7ccccc7)cc6)c6ccc7c(c6)oc6ccccc67)c5oc4c4ccccc34)cc2)cc1 ; c1ccc(-c2cc3c4cccc(N(c5ccc6ccccc6c5)c5ccc6c(c5)oc5ccccc56)c4oc3c3ccccc23)cc1 ; c1ccc(-c2cc3c4cccc(N(c5ccccc5)c5ccc(-c6ccc7c(c6)oc6ccccc67)cc5)c4oc3c3ccccc23)cc1]

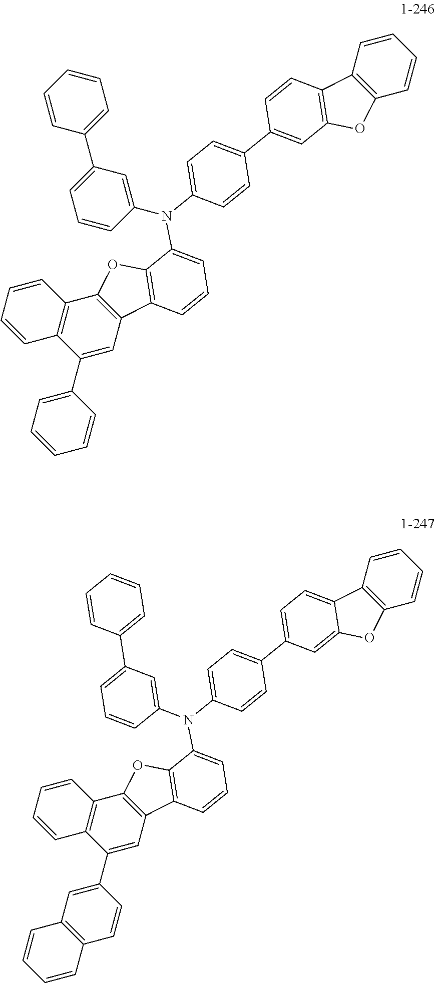 [SMILES: c1ccc(-c2cccc(N(c3ccc(-c4ccc5c(c4)oc4ccccc45)cc3)c3cccc4c3oc3c5ccccc5c(-c5ccccc5)cc43)c2)cc1 ; c1ccc(-c2cccc(N(c3ccc(-c4ccc5c(c4)oc4ccccc45)cc3)c3cccc4c3oc3c5ccccc5c(-c5ccc6ccccc6c5)cc43)c2)cc1]

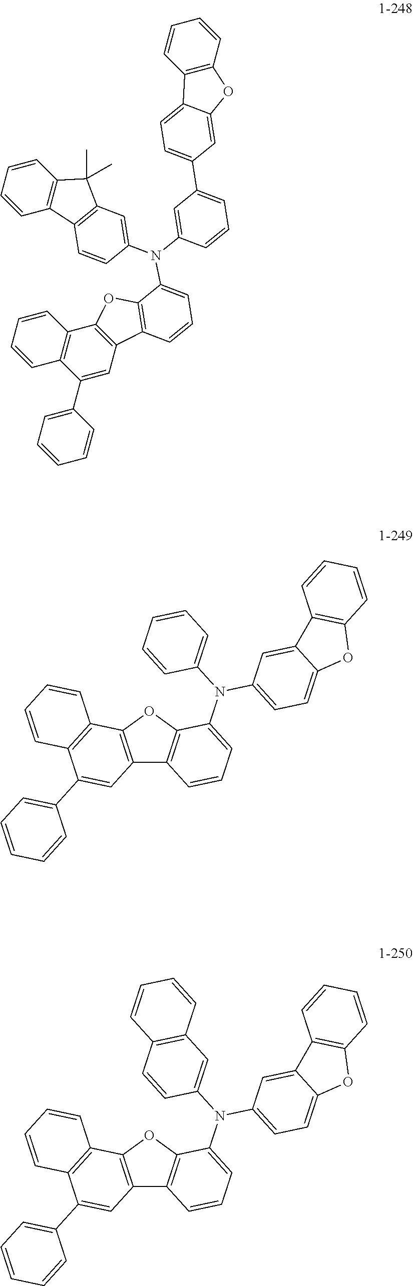 [SMILES: CC1(C)c2ccccc2-c2ccc(N(c3cccc(-c4ccc5c(c4)oc4ccccc45)c3)c3cccc4c3oc3c5ccccc5c(-c5ccccc5)cc43)cc21 ; c1ccc(-c2cc3c4cccc(N(c5ccccc5)c5ccc6oc7ccccc7c6c5)c4oc3c3ccccc23)cc1 ; c1ccc(-c2cc3c4cccc(N(c5ccc6ccccc6c5)c5ccc6oc7ccccc7c6c5)c4oc3c3ccccc23)cc1]

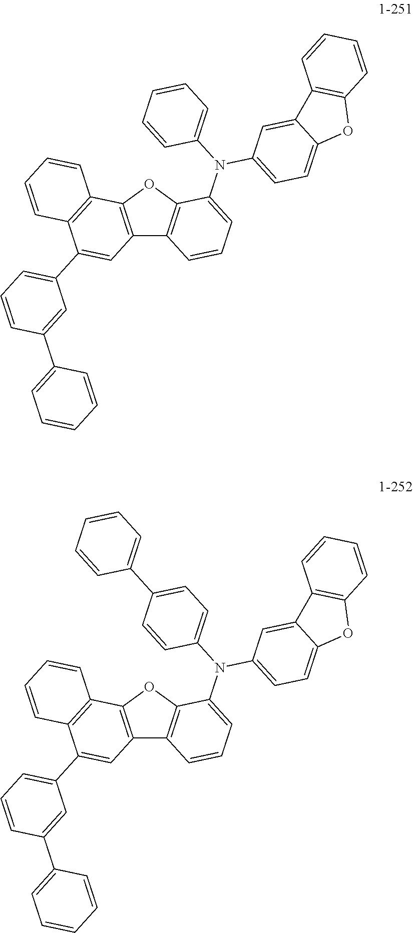 [SMILES: c1ccc(-c2cccc(-c3cc4c5cccc(N(c6ccccc6)c6ccc7oc8ccccc8c7c6)c5oc4c4ccccc34)c2)cc1 ; c1ccc(-c2ccc(N(c3ccc4oc5ccccc5c4c3)c3cccc4c3oc3c5ccccc5c(-c5cccc(-c6ccccc6)c5)cc43)cc2)cc1]

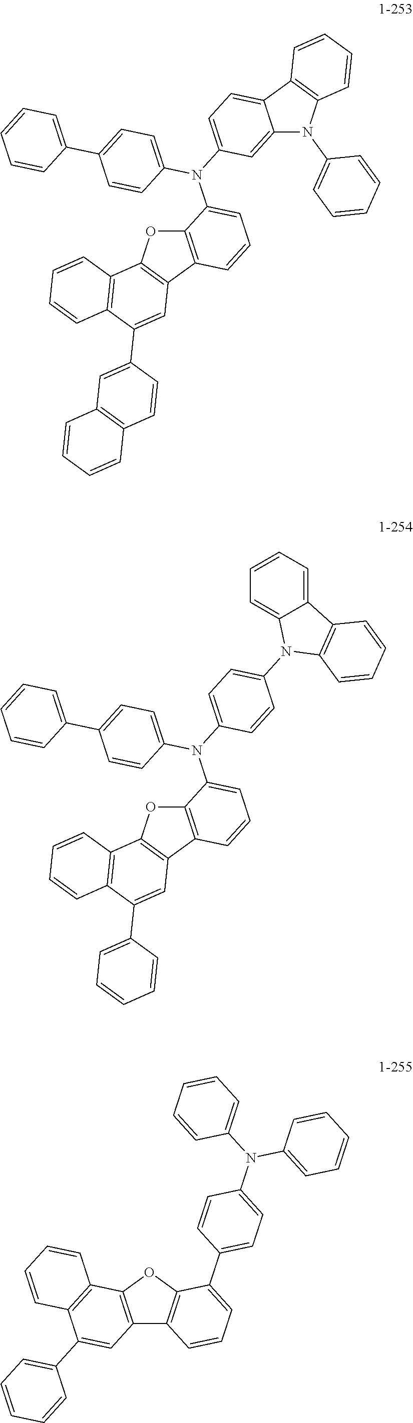 [SMILES: c1ccc(-c2ccc(N(c3ccc4c5ccccc5n(-c5ccccc5)c4c3)c3cccc4c3oc3c5ccccc5c(-c5ccc6ccccc6c5)cc43)cc2)cc1 ; c1ccc(-c2ccc(N(c3ccc(-n4c5ccccc5c5ccccc54)cc3)c3cccc4c3oc3c5ccccc5c(-c5ccccc5)cc43)cc2)cc1 ; c1ccc(-c2cc3c4cccc(-c5ccc(N(c6ccccc6)c6ccccc6)cc5)c4oc3c3ccccc23)cc1]

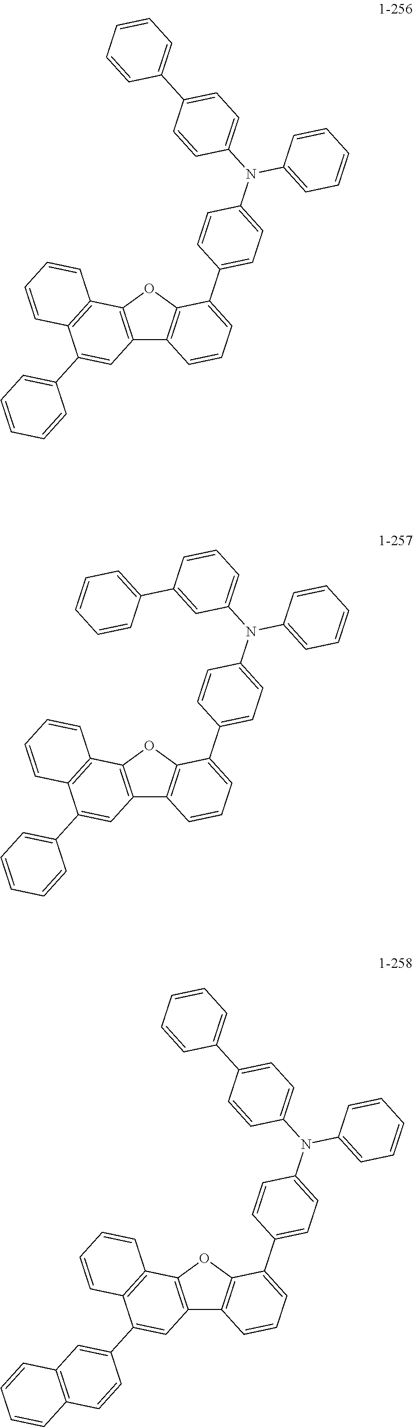 [SMILES: c1ccc(-c2ccc(N(c3ccccc3)c3ccc(-c4cccc5c4oc4c6ccccc6c(-c6ccccc6)cc54)cc3)cc2)cc1 ; c1ccc(-c2cccc(N(c3ccccc3)c3ccc(-c4cccc5c4oc4c6ccccc6c(-c6ccccc6)cc54)cc3)c2)cc1 ; c1ccc(-c2ccc(N(c3ccccc3)c3ccc(-c4cccc5c4oc4c6ccccc6c(-c6ccc7ccccc7c6)cc54)cc3)cc2)cc1]

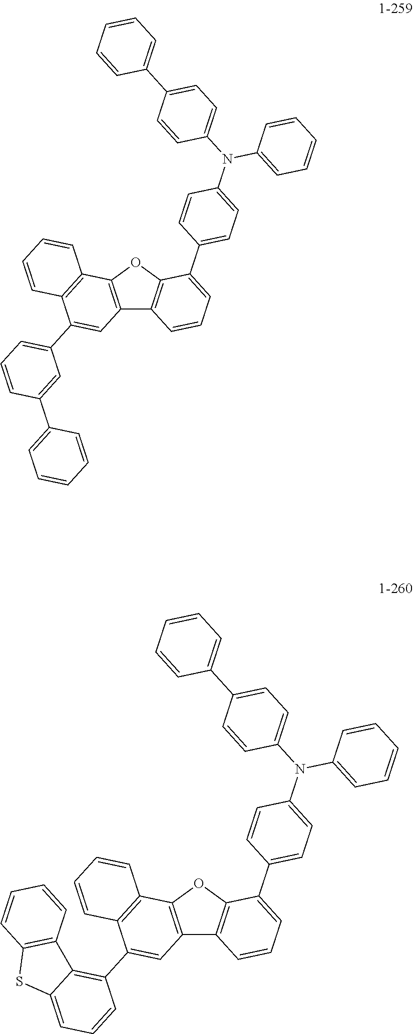 [SMILES: c1ccc(-c2ccc(N(c3ccccc3)c3ccc(-c4cccc5c4oc4c6ccccc6c(-c6cccc(-c7ccccc7)c6)cc54)cc3)cc2)cc1 ; c1ccc(-c2ccc(N(c3ccccc3)c3ccc(-c4cccc5c4oc4c6ccccc6c(-c6cccc7sc8ccccc8c67)cc54)cc3)cc2)cc1]

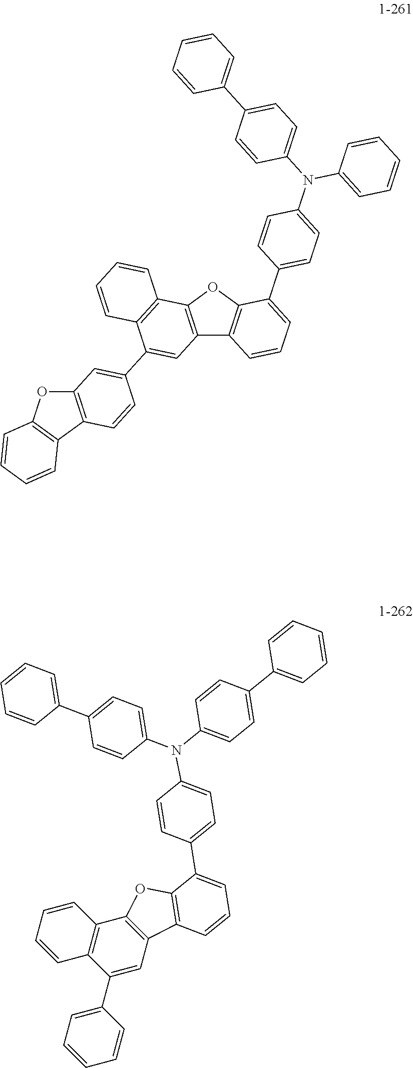 [SMILES: c1ccc(-c2ccc(N(c3ccccc3)c3ccc(-c4cccc5c4oc4c6ccccc6c(-c6ccc7c(c6)oc6ccccc67)cc54)cc3)cc2)cc1 ; c1ccc(-c2ccc(N(c3ccc(-c4ccccc4)cc3)c3ccc(-c4cccc5c4oc4c6ccccc6c(-c6ccccc6)cc54)cc3)cc2)cc1]

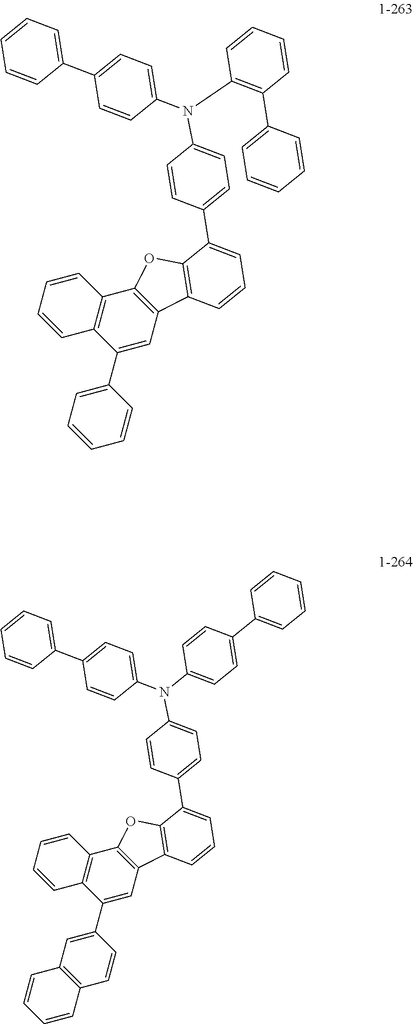 [SMILES: c1ccc(-c2ccc(N(c3ccc(-c4cccc5c4oc4c6ccccc6c(-c6ccccc6)cc54)cc3)c3ccccc3-c3ccccc3)cc2)cc1 ; c1ccc(-c2ccc(N(c3ccc(-c4ccccc4)cc3)c3ccc(-c4cccc5c4oc4c6ccccc6c(-c6ccc7ccccc7c6)cc54)cc3)cc2)cc1]

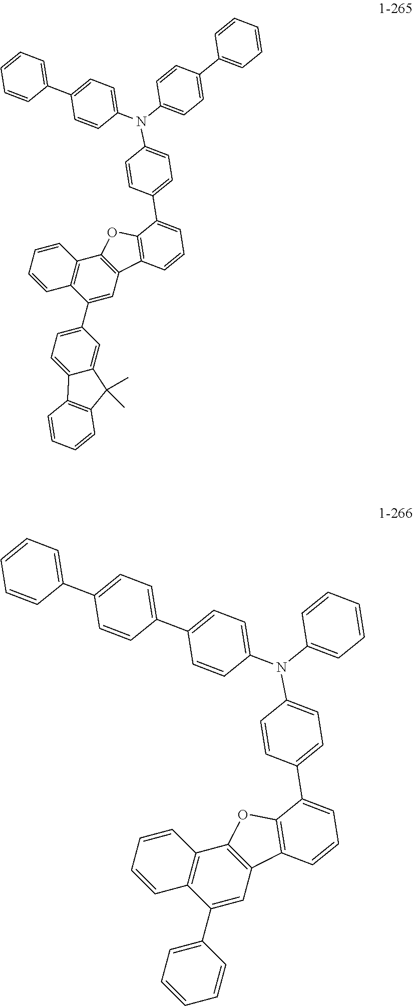 [SMILES: CC1(C)c2ccccc2-c2ccc(-c3cc4c5cccc(-c6ccc(N(c7ccc(-c8ccccc8)cc7)c7ccc(-c8ccccc8)cc7)cc6)c5oc4c4ccccc34)cc21 ; c1ccc(-c2ccc(-c3ccc(N(c4ccccc4)c4ccc(-c5cccc6c5oc5c7ccccc7c(-c7ccccc7)cc65)cc4)cc3)cc2)cc1]

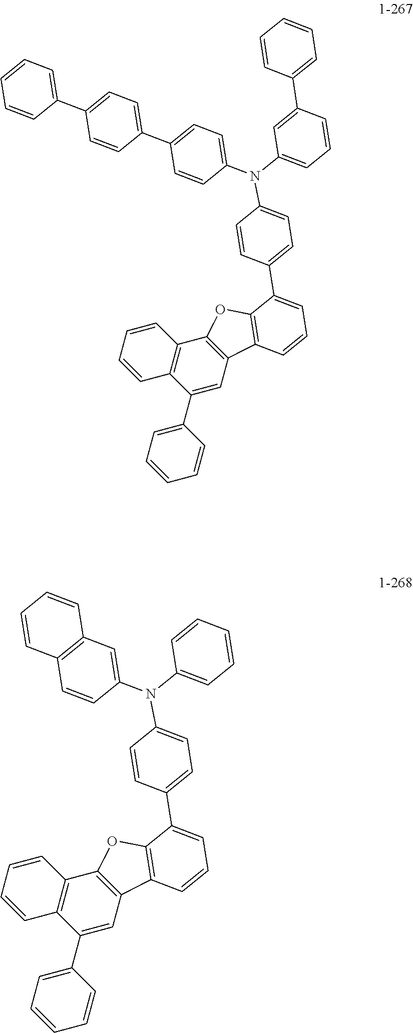 [SMILES: c1ccc(-c2ccc(-c3ccc(N(c4ccc(-c5cccc6c5oc5c7ccccc7c(-c7ccccc7)cc65)cc4)c4cccc(-c5ccccc5)c4)cc3)cc2)cc1 ; c1ccc(-c2cc3c4cccc(-c5ccc(N(c6ccccc6)c6ccc7ccccc7c6)cc5)c4oc3c3ccccc23)cc1]

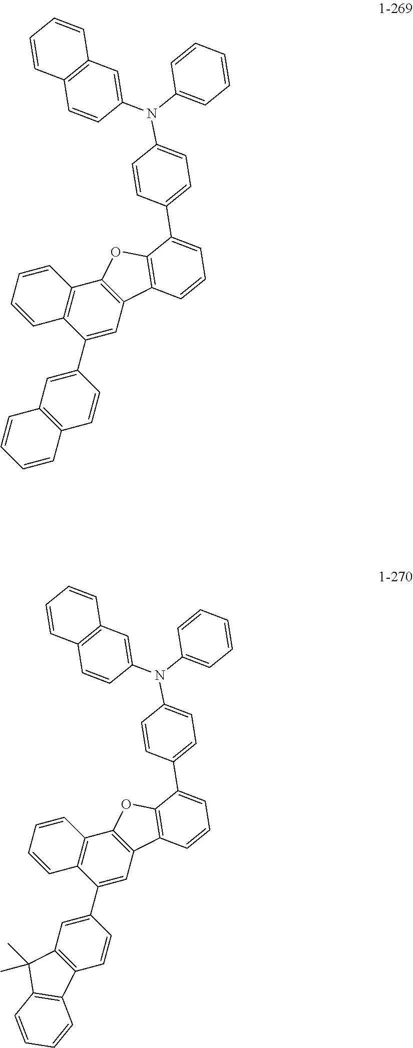 [SMILES: c1ccc(N(c2ccc(-c3cccc4c3oc3c5ccccc5c(-c5ccc6ccccc6c5)cc43)cc2)c2ccc3ccccc3c2)cc1 ; CC1(C)c2ccccc2-c2ccc(-c3cc4c5cccc(-c6ccc(N(c7ccccc7)c7ccc8ccccc8c7)cc6)c5oc4c4ccccc34)cc21]

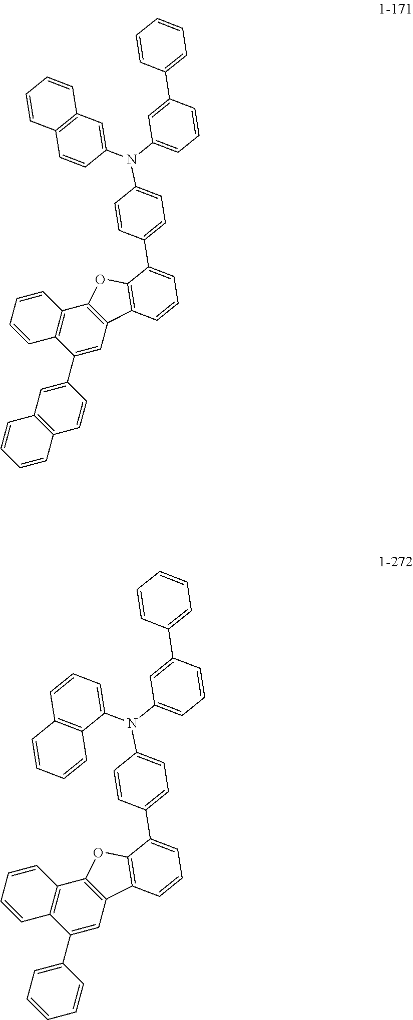 [SMILES: c1ccc(-c2cccc(N(c3ccc(-c4cccc5c4oc4c6ccccc6c(-c6ccc7ccccc7c6)cc54)cc3)c3ccc4ccccc4c3)c2)cc1 ; c1ccc(-c2cccc(N(c3ccc(-c4cccc5c4oc4c6ccccc6c(-c6ccccc6)cc54)cc3)c3cccc4ccccc34)c2)cc1]

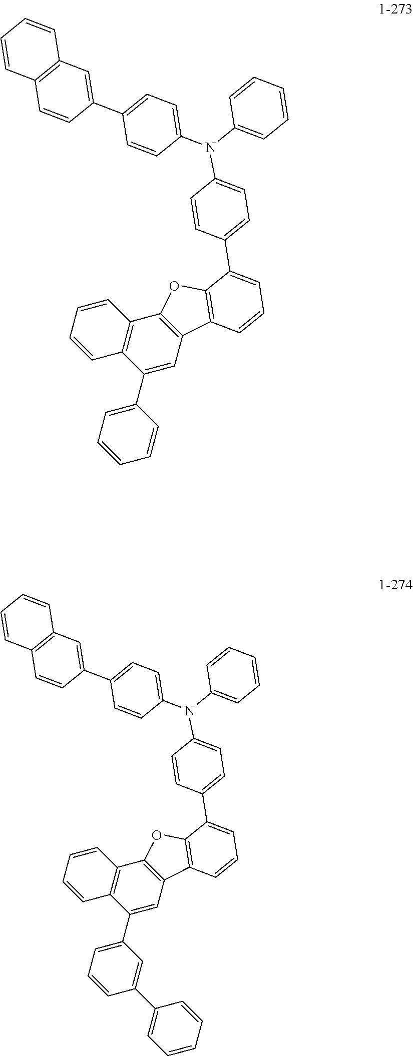 [SMILES: c1ccc(-c2cc3c4cccc(-c5ccc(N(c6ccccc6)c6ccc(-c7ccc8ccccc8c7)cc6)cc5)c4oc3c3ccccc23)cc1 ; c1ccc(-c2cccc(-c3cc4c5cccc(-c6ccc(N(c7ccccc7)c7ccc(-c8ccc9ccccc9c8)cc7)cc6)c5oc4c4ccccc34)c2)cc1]

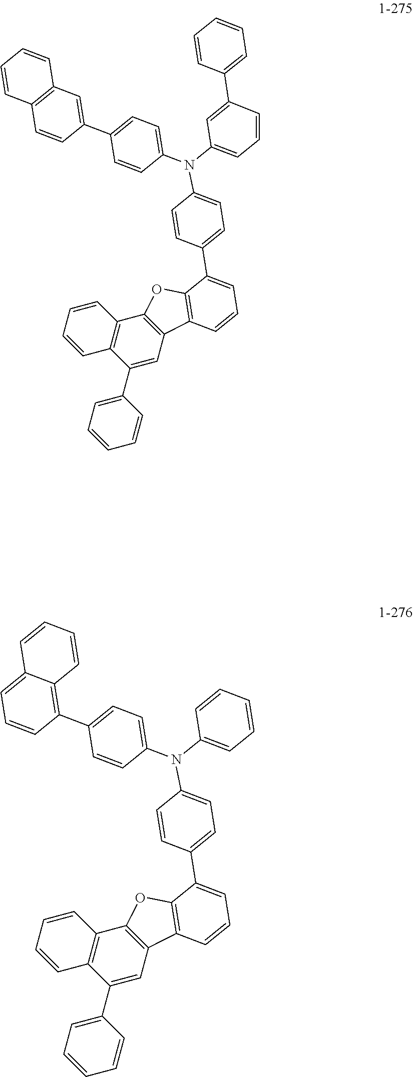 [SMILES: c1ccc(-c2cccc(N(c3ccc(-c4ccc5ccccc5c4)cc3)c3ccc(-c4cccc5c4oc4c6ccccc6c(-c6ccccc6)cc54)cc3)c2)cc1 ; c1ccc(-c2cc3c4cccc(-c5ccc(N(c6ccccc6)c6ccc(-c7cccc8ccccc78)cc6)cc5)c4oc3c3ccccc23)cc1]

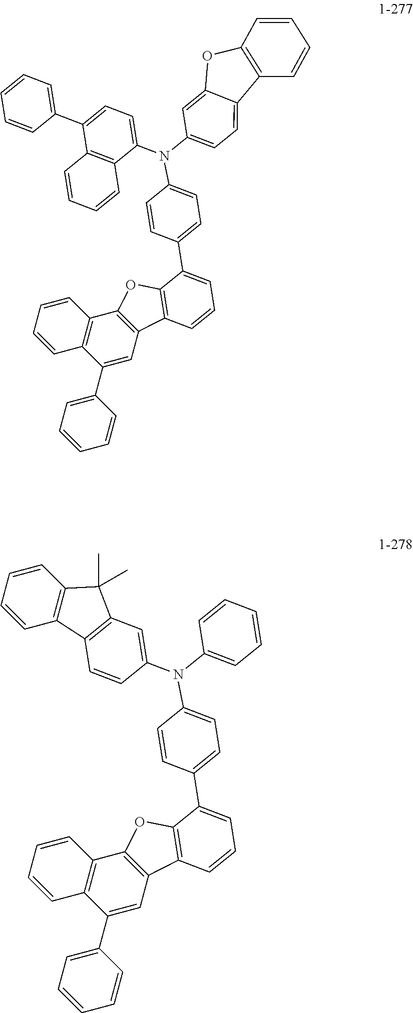 [SMILES: c1ccc(-c2ccc(N(c3ccc(-c4cccc5c4oc4c6ccccc6c(-c6ccccc6)cc54)cc3)c3ccc4c(c3)oc3ccccc34)c3ccccc23)cc1 ; CC1(C)c2ccccc2-c2ccc(N(c3ccccc3)c3ccc(-c4cccc5c4oc4c6ccccc6c(-c6ccccc6)cc54)cc3)cc21]

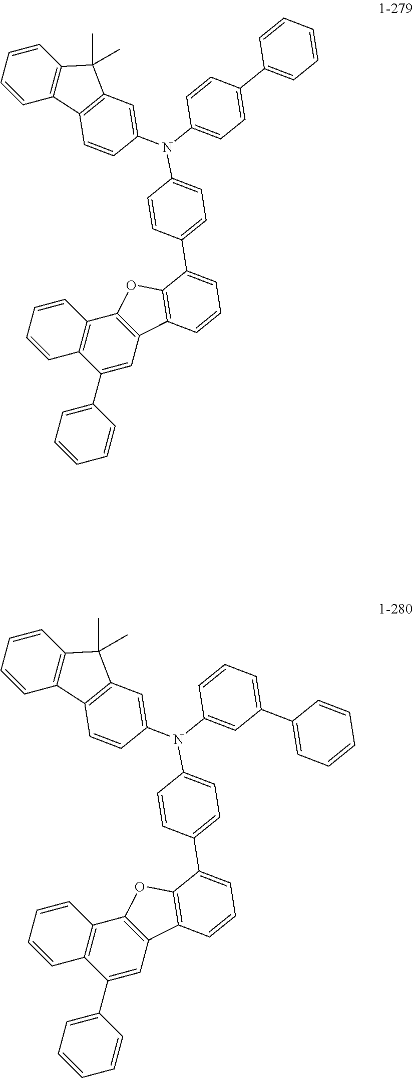 [SMILES: CC1(C)c2ccccc2-c2ccc(N(c3ccc(-c4ccccc4)cc3)c3ccc(-c4cccc5c4oc4c6ccccc6c(-c6ccccc6)cc54)cc3)cc21 ; CC1(C)c2ccccc2-c2ccc(N(c3ccc(-c4cccc5c4oc4c6ccccc6c(-c6ccccc6)cc54)cc3)c3cccc(-c4ccccc4)c3)cc21]

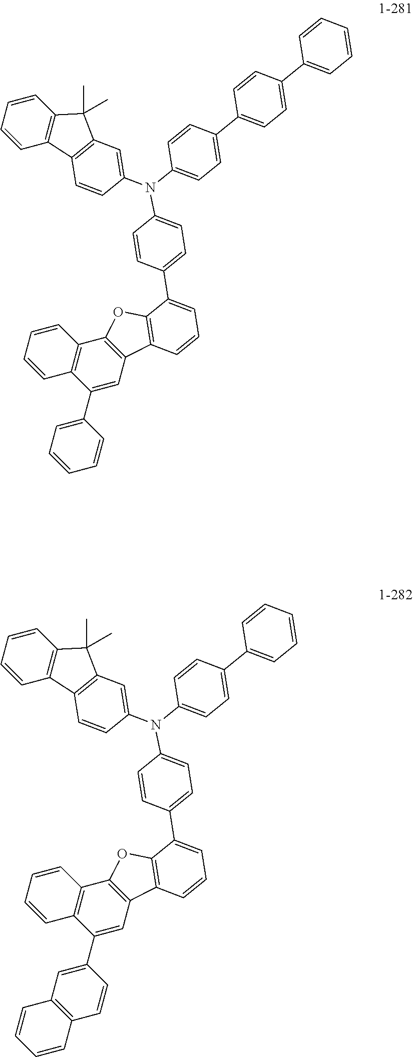 [SMILES: CC1(C)c2ccccc2-c2ccc(N(c3ccc(-c4ccc(-c5ccccc5)cc4)cc3)c3ccc(-c4cccc5c4oc4c6ccccc6c(-c6ccccc6)cc54)cc3)cc21 ; CC1(C)c2ccccc2-c2ccc(N(c3ccc(-c4ccccc4)cc3)c3ccc(-c4cccc5c4oc4c6ccccc6c(-c6ccc7ccccc7c6)cc54)cc3)cc21]

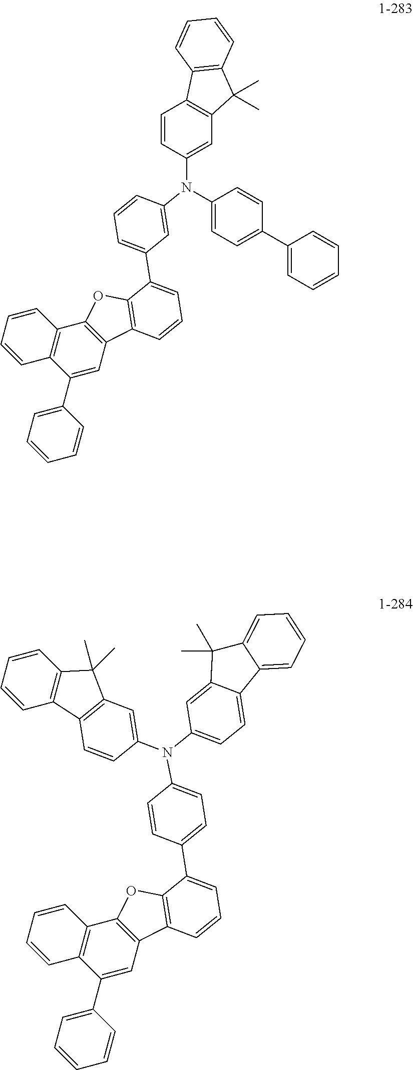 [SMILES: CC1(C)c2ccccc2-c2ccc(N(c3ccc(-c4ccccc4)cc3)c3cccc(-c4cccc5c4oc4c6ccccc6c(-c6ccccc6)cc54)c3)cc21 ; CC1(C)c2ccccc2-c2ccc(N(c3ccc(-c4cccc5c4oc4c6ccccc6c(-c6ccccc6)cc54)cc3)c3ccc4c(c3)C(C)(C)c3ccccc3-4)cc21]

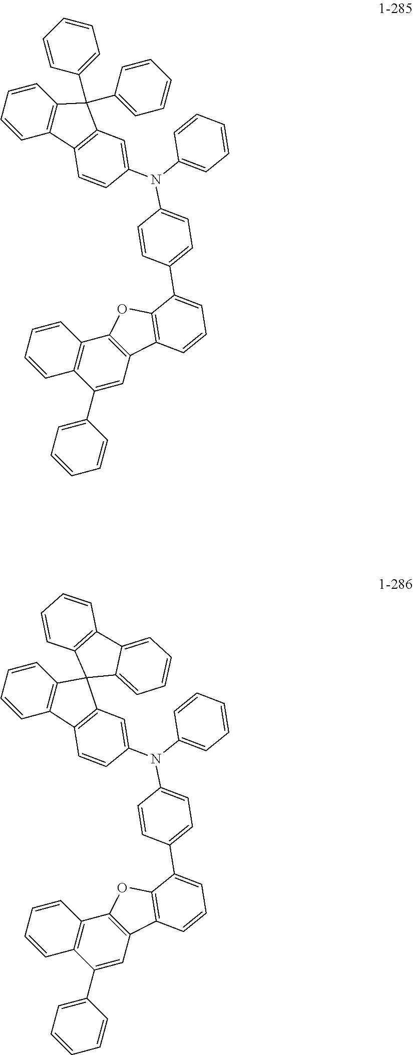 [SMILES: c1ccc(-c2cc3c4cccc(-c5ccc(N(c6ccccc6)c6ccc7c(c6)C(c6ccccc6)(c6ccccc6)c6ccccc6-7)cc5)c4oc3c3ccccc23)cc1 ; c1ccc(-c2cc3c4cccc(-c5ccc(N(c6ccccc6)c6ccc7c(c6)C6(c8ccccc8-c8ccccc86)c6ccccc6-7)cc5)c4oc3c3ccccc23)cc1]

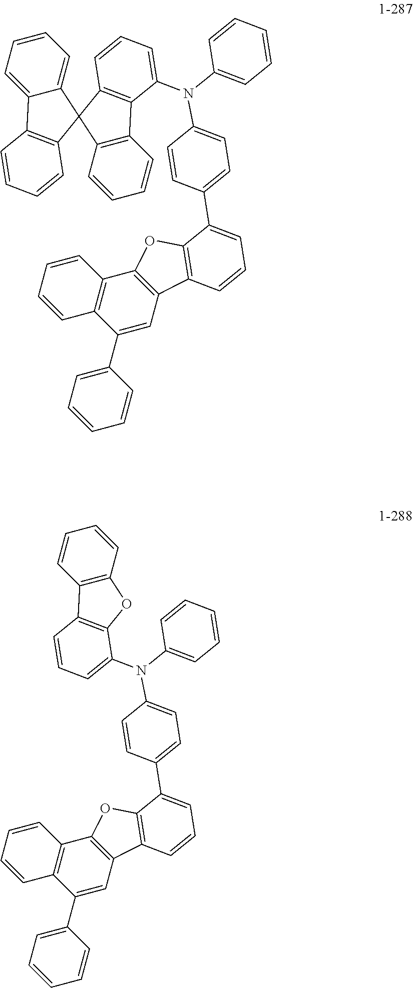 [SMILES: c1ccc(-c2cc3c4cccc(-c5ccc(N(c6ccccc6)c6cccc7c6-c6ccccc6C76c7ccccc7-c7ccccc76)cc5)c4oc3c3ccccc23)cc1 ; c1ccc(-c2cc3c4cccc(-c5ccc(N(c6ccccc6)c6cccc7c6oc6ccccc67)cc5)c4oc3c3ccccc23)cc1]

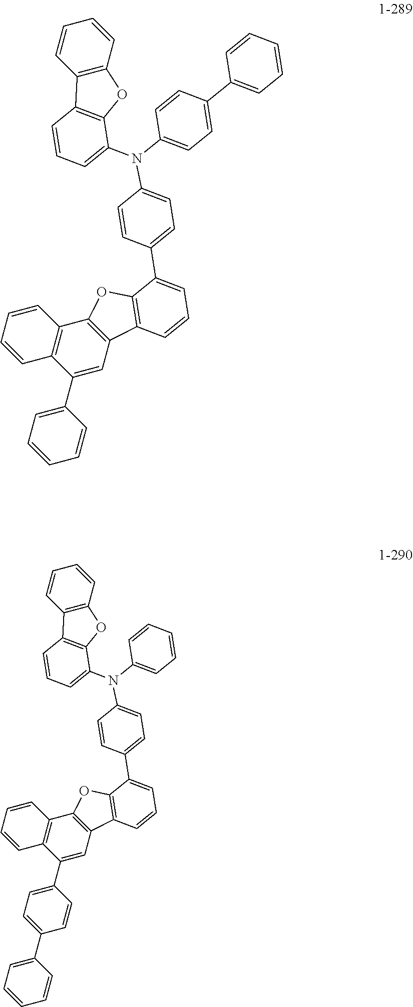 [SMILES: c1ccc(-c2ccc(N(c3ccc(-c4cccc5c4oc4c6ccccc6c(-c6ccccc6)cc54)cc3)c3cccc4c3oc3ccccc34)cc2)cc1 ; c1ccc(-c2ccc(-c3cc4c5cccc(-c6ccc(N(c7ccccc7)c7cccc8c7oc7ccccc78)cc6)c5oc4c4ccccc34)cc2)cc1]

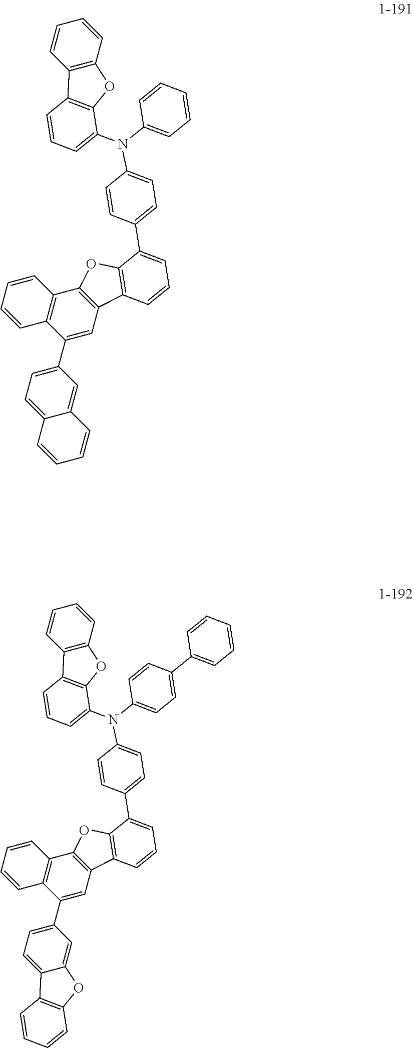 [SMILES: c1ccc(N(c2ccc(-c3cccc4c3oc3c5ccccc5c(-c5ccc6ccccc6c5)cc43)cc2)c2cccc3c2oc2ccccc23)cc1 ; c1ccc(-c2ccc(N(c3ccc(-c4cccc5c4oc4c6ccccc6c(-c6ccc7c(c6)oc6ccccc67)cc54)cc3)c3cccc4c3oc3ccccc34)cc2)cc1]

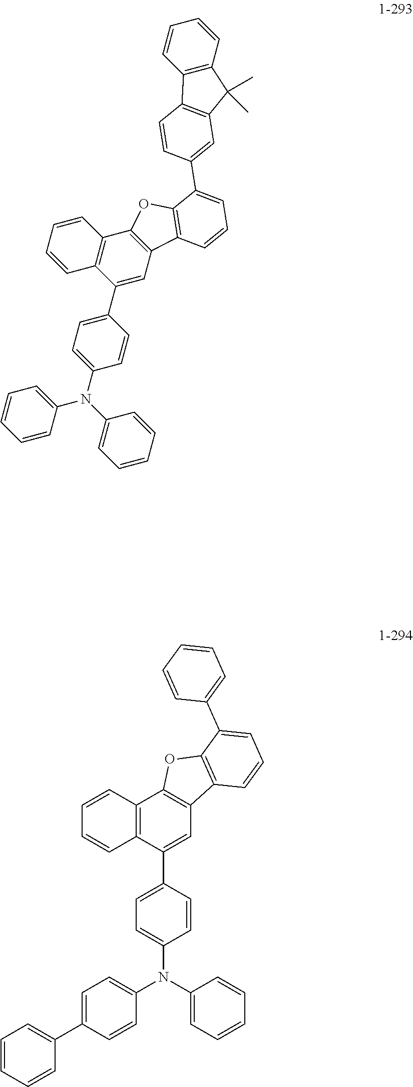 [SMILES: CC1(C)c2ccccc2-c2ccc(-c3cccc4c3oc3c5ccccc5c(-c5ccc(N(c6ccccc6)c6ccccc6)cc5)cc43)cc21 ; c1ccc(-c2ccc(N(c3ccccc3)c3ccc(-c4cc5c6cccc(-c7ccccc7)c6oc5c5ccccc45)cc3)cc2)cc1]

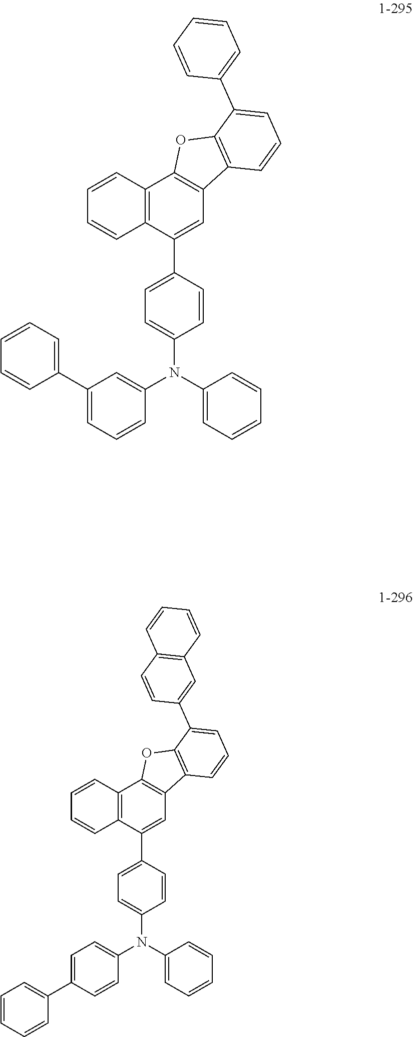 [SMILES: c1ccc(-c2cccc(N(c3ccccc3)c3ccc(-c4cc5c6cccc(-c7ccccc7)c6oc5c5ccccc45)cc3)c2)cc1 ; c1ccc(-c2ccc(N(c3ccccc3)c3ccc(-c4cc5c6cccc(-c7ccc8ccccc8c7)c6oc5c5ccccc45)cc3)cc2)cc1]

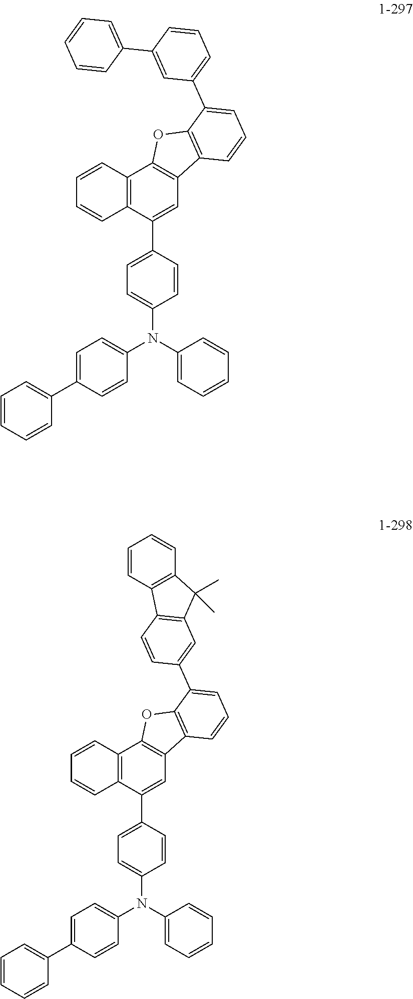 [SMILES: c1ccc(-c2ccc(N(c3ccccc3)c3ccc(-c4cc5c6cccc(-c7cccc(-c8ccccc8)c7)c6oc5c5ccccc45)cc3)cc2)cc1 ; CC1(C)c2ccccc2-c2ccc(-c3cccc4c3oc3c5ccccc5c(-c5ccc(N(c6ccccc6)c6ccc(-c7ccccc7)cc6)cc5)cc43)cc21]

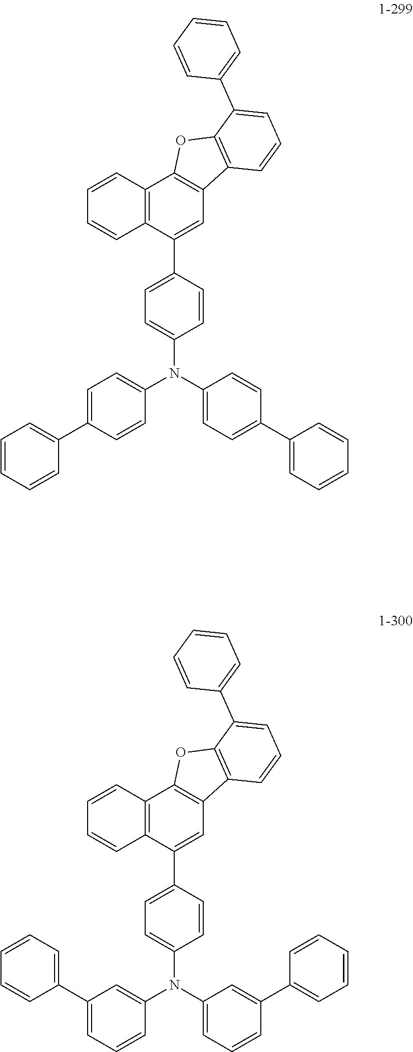 [SMILES: c1ccc(-c2ccc(N(c3ccc(-c4ccccc4)cc3)c3ccc(-c4cc5c6cccc(-c7ccccc7)c6oc5c5ccccc45)cc3)cc2)cc1 ; c1ccc(-c2cccc(N(c3ccc(-c4cc5c6cccc(-c7ccccc7)c6oc5c5ccccc45)cc3)c3cccc(-c4ccccc4)c3)c2)cc1]

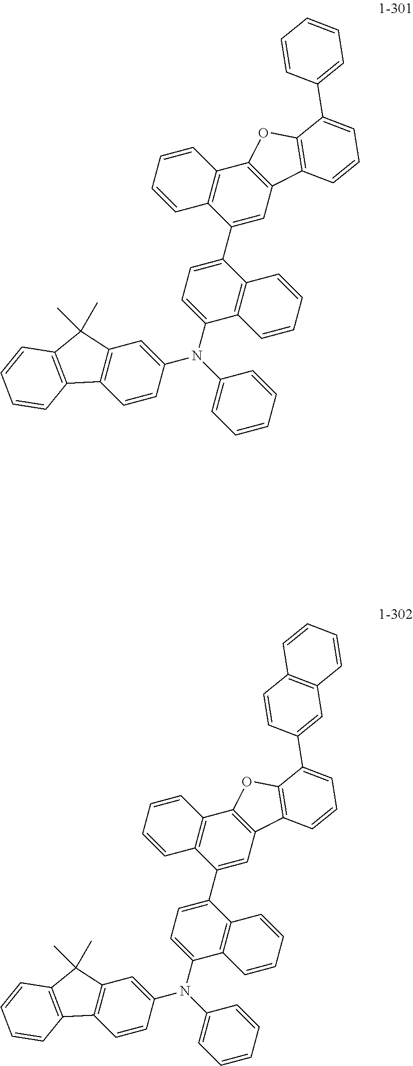 [SMILES: CC1(C)c2ccccc2-c2ccc(N(c3ccccc3)c3ccc(-c4cc5c6cccc(-c7ccccc7)c6oc5c5ccccc45)c4ccccc34)cc21 ; CC1(C)c2ccccc2-c2ccc(N(c3ccccc3)c3ccc(-c4cc5c6cccc(-c7ccc8ccccc8c7)c6oc5c5ccccc45)c4ccccc34)cc21]

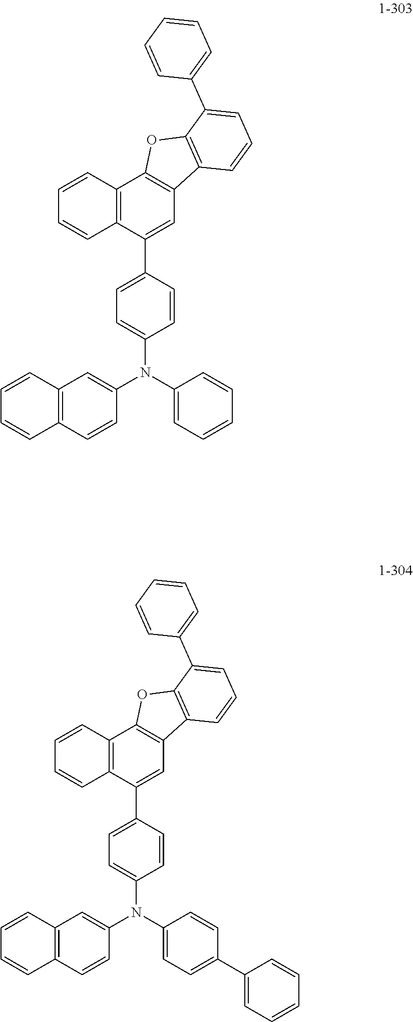 [SMILES: c1ccc(-c2cccc3c2oc2c4ccccc4c(-c4ccc(N(c5ccccc5)c5ccc6ccccc6c5)cc4)cc32)cc1 ; c1ccc(-c2ccc(N(c3ccc(-c4cc5c6cccc(-c7ccccc7)c6oc5c5ccccc45)cc3)c3ccc4ccccc4c3)cc2)cc1]

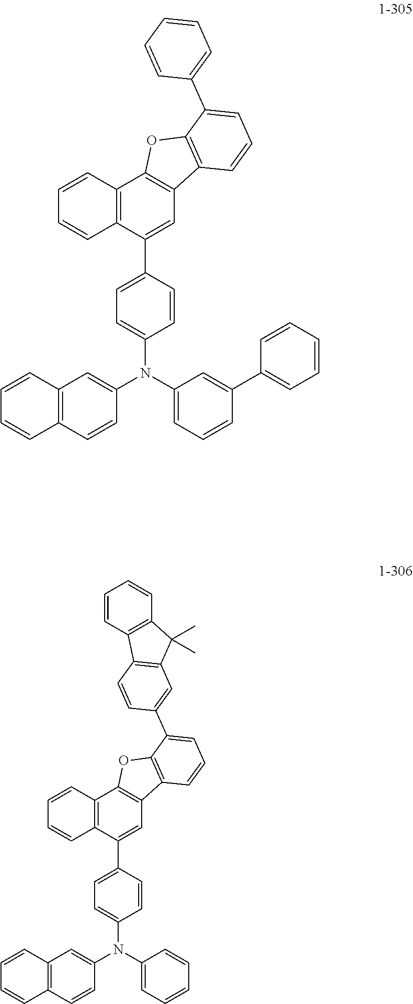 [SMILES: c1ccc(-c2cccc(N(c3ccc(-c4cc5c6cccc(-c7ccccc7)c6oc5c5ccccc45)cc3)c3ccc4ccccc4c3)c2)cc1 ; CC1(C)c2ccccc2-c2ccc(-c3cccc4c3oc3c5ccccc5c(-c5ccc(N(c6ccccc6)c6ccc7ccccc7c6)cc5)cc43)cc21]

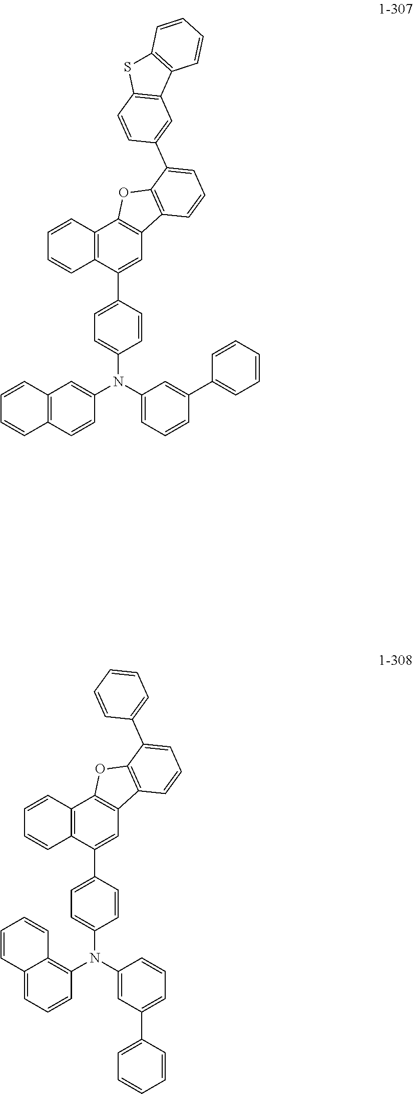 [SMILES: c1ccc(-c2cccc(N(c3ccc(-c4cc5c6cccc(-c7ccc8sc9ccccc9c8c7)c6oc5c5ccccc45)cc3)c3ccc4ccccc4c3)c2)cc1 ; c1ccc(-c2cccc(N(c3ccc(-c4cc5c6cccc(-c7ccccc7)c6oc5c5ccccc45)cc3)c3cccc4ccccc34)c2)cc1]

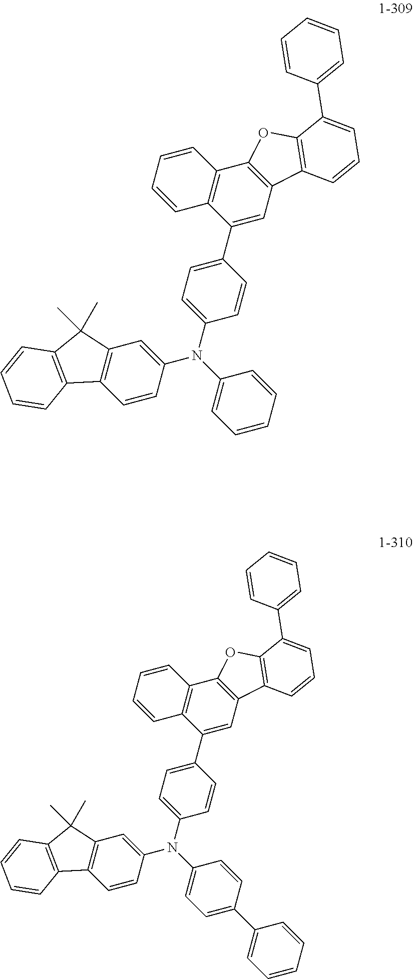 [SMILES: CC1(C)c2ccccc2-c2ccc(N(c3ccccc3)c3ccc(-c4cc5c6cccc(-c7ccccc7)c6oc5c5ccccc45)cc3)cc21 ; CC1(C)c2ccccc2-c2ccc(N(c3ccc(-c4ccccc4)cc3)c3ccc(-c4cc5c6cccc(-c7ccccc7)c6oc5c5ccccc45)cc3)cc21]

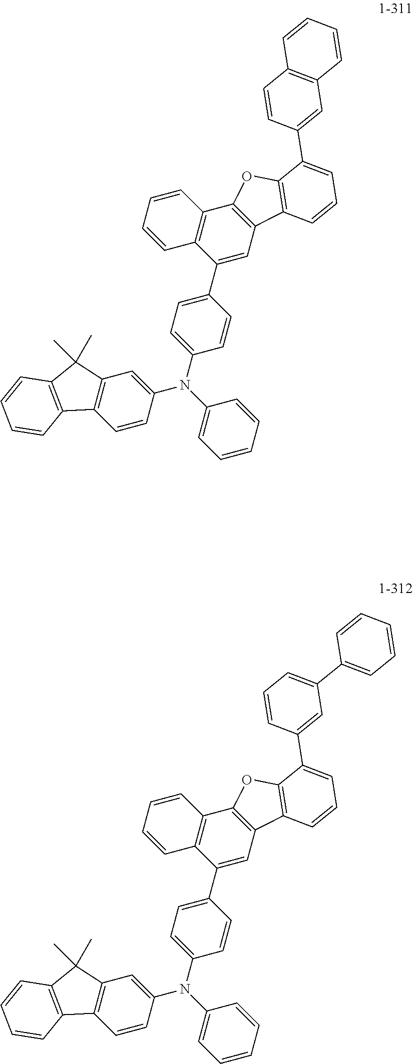 [SMILES: CC1(C)c2ccccc2-c2ccc(N(c3ccccc3)c3ccc(-c4cc5c6cccc(-c7ccc8ccccc8c7)c6oc5c5ccccc45)cc3)cc21 ; CC1(C)c2ccccc2-c2ccc(N(c3ccccc3)c3ccc(-c4cc5c6cccc(-c7cccc(-c8ccccc8)c7)c6oc5c5ccccc45)cc3)cc21]

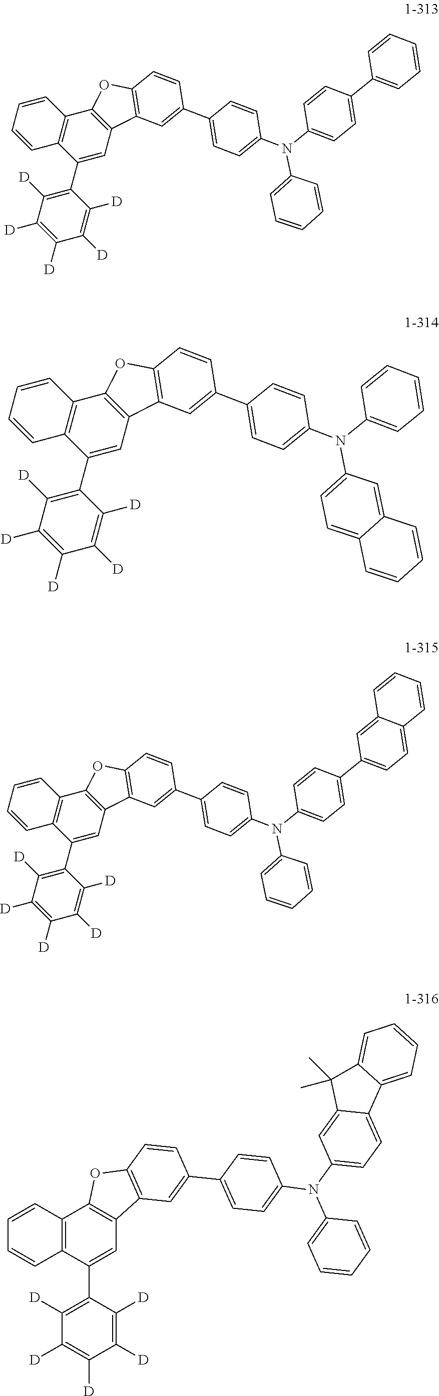 [SMILES: [2H]c1c([2H])c([2H])c(-c2cc3c4cc(-c5ccc(N(c6ccccc6)c6ccc(-c7ccccc7)cc6)cc5)ccc4oc3c3ccccc23)c([2H])c1[2H] ; [2H]c1c([2H])c([2H])c(-c2cc3c4cc(-c5ccc(N(c6ccccc6)c6ccc7ccccc7c6)cc5)ccc4oc3c3ccccc23)c([2H])c1[2H] ; [2H]c1c([2H])c([2H])c(-c2cc3c4cc(-c5ccc(N(c6ccccc6)c6ccc(-c7ccc8ccccc8c7)cc6)cc5)ccc4oc3c3ccccc23)c([2H])c1[2H] ; [2H]c1c([2H])c([2H])c(-c2cc3c4cc(-c5ccc(N(c6ccccc6)c6ccc7c(c6)C(C)(C)c6ccccc6-7)cc5)ccc4oc3c3ccccc23)c([2H])c1[2H]]

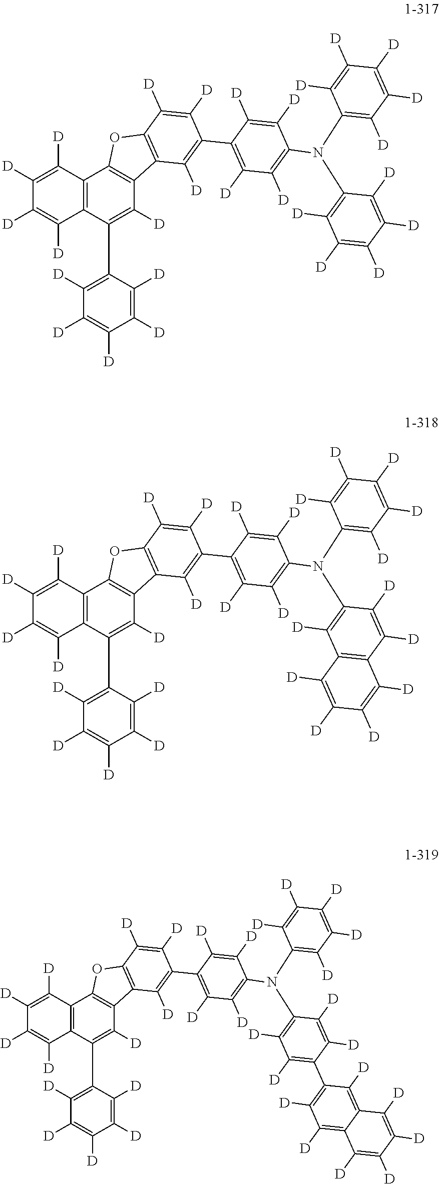

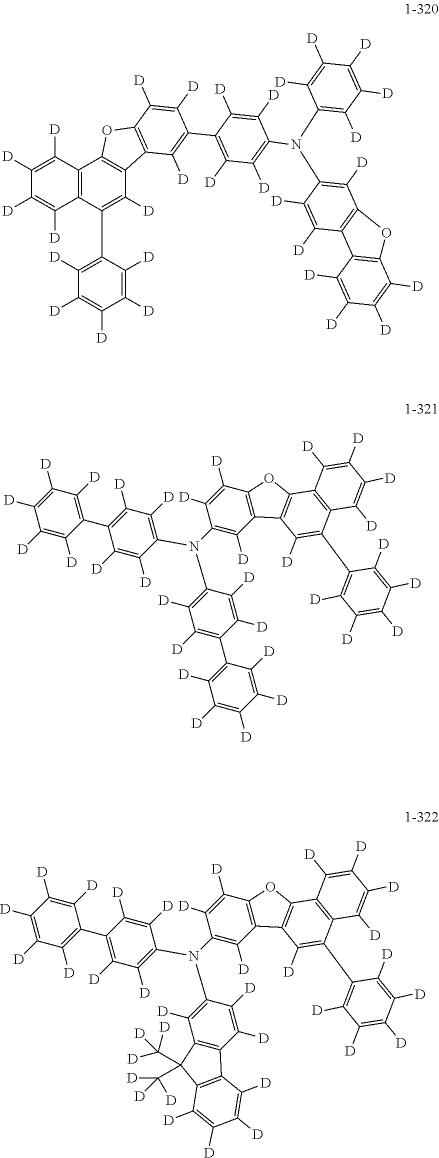

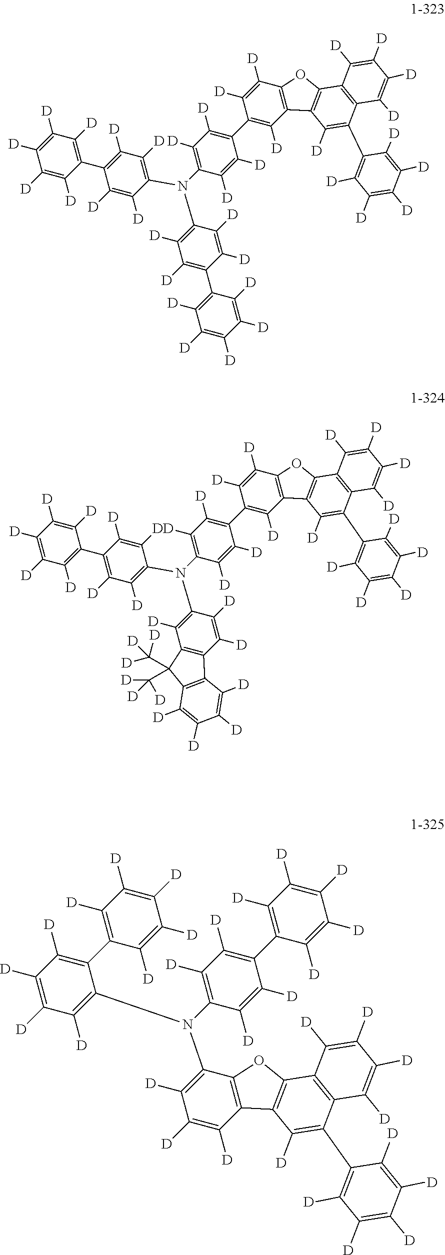

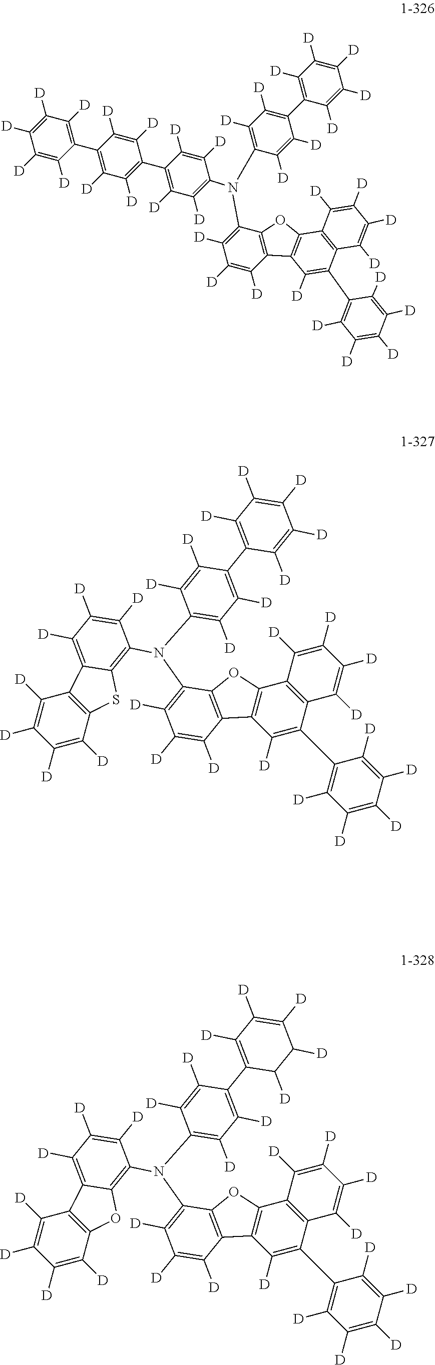

and combinations thereof.

Those having skill in the art will appreciate that each of compounds 1-1 through 1-328 of Chemical Formula 2 also fall within the scope of Chemical Formula 1.

Alternatively, the B-EML1 340B may further include the second host 345. In one example aspect, the first host 344 may have a LUMO energy level higher than a LUMO energy level of the second host 345. As an example, the LUMO energy level of the first host 344 and the LUMO energy level of the second host 346 may satisfy the following relationship in Equation (1):

0.4 eV≤LUMO^{H1}−LUMO^{H2}≤0.8 eV (1)

wherein, LUMO^{H1} indicates LUMO energy level of the first host and LUMO^{H2} indicates LUMO energy level of the second host.

In another example aspect, the first host 344 may have a HOMO energy level higher than a HOMO energy level of the second host 345. As an example, the HOMO energy level of the first host 344 and the HOMO energy level of the second host 345 may satisfy the following relationship in Equation (2):

0.3 eV≤HOMO^{H1}−HOMO^{H2}≤0.6 eV (2)

wherein, HOMO^{H1} indicates HOMO energy level of the first host and HOMO^{H2} indicates HOMO energy level of the second host.

For example, the first host 344 may have the LUMO energy level higher than the LUMO energy level of the second host 345 by at least about 0.4 eV and by at most about 0.6 eV. Alternatively, the first host 344 may have the HOMO energy level higher than the HOMO energy level of the second host 345 by at least 0.3 eV and by at most about 0.5 eV.

As an example, the first host 344 may have the LUMO energy level of about −2.1 eV or more, for example, between about −2.1 eV and about −1.8 eV and may have the HOMO energy level of about −5.3 eV or more, for example, between about −5.3 eV and about −5.0 eV but is not limited thereto. Alternatively, the second host 345 may have the LUMO energy level of about −2.4 eV or less, for example, between about −2.4 eV and about −3.0 eV and may have the HOMO energy level of about −5.4 eV or less, for example, between about −5.4 eV and about −6.0 eV but is not limited thereto.

In one example aspect, the second host 345 may be an anthracene-based organic compound. As an example, the second host 345 may have the following structure of Chemical Formula 3:

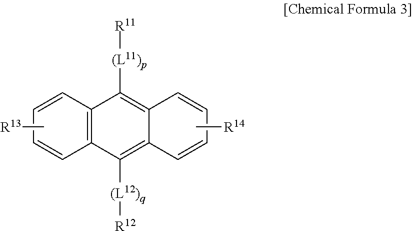

wherein
R¹¹ and R¹² are independently an unsubstituted C₆-C₃₀ aryl, a substituted C₆-C₃₀ aryl group, an unsubstituted C₃-C₃₀ hetero aryl group, or a substituted C₃-C₃₀ hetero aryl group;
R¹³ and R¹⁴ are independently hydrogen, an unsubstituted C₁-C₂₀ alkyl group, a substituted C₁-C₂₀ alkyl group, an unsubstituted C₆-C₃₀ aryl group, a substituted C₆-C₃₀ aryl group, an unsubstituted C₃-C₃₀ hetero aryl group, or substituted C₃-C₃₀ hetero aryl group;
L¹¹ and L¹² are independently an unsubstituted C₆-C₃₀ arylene group, a substituted C₆-C₃₀ arylene group, an unsubstituted C₃-C₃₀ hetero arylene group, or a substituted C₃-C₃₀ hetero arylene group; and
p and q are independently 0 or 1.

As an example, each of the C₆-C₃₀ aryl group and the C₃-C₃₀ hetero aryl group in R¹¹ to R¹⁴ and the C₆-C₃₀ arylene group and the C₃-C₃₀ hetero arylene group in L¹ and L² may be independently unsubstituted or substituted with at least one group selected from C₁-C₁₀ alkyl, C₆-C₃₀ aryl and C₃-C₃₀ hetero aryl.

For example, the second host 345 may include, but is not limited to, 9, 10-di (naphthalen-2-yl) anthracene (ADN), 2-methyl-9, 10-bis (naphthalen-2-yl) anthracene (MADN), 2-tert-butyl-9, 10-di (naphthen-2-yl) anthracene (TBADN), 9, 10-di (naphthalen-2-yl)-2-phenylanthracene (PADN), 9-phenyl-10-(p-tolyl) anthracene (PTA), 9-(1-naphthyl)-10-(p-tolyl) anthracene (1-NTA), 9-(2-naphthyl)-10-(p-tolyl) anthracene (2-NTA), 2-(3-(10-phenylanthracen-9-yl)-phenyl) dibenzo[b, d]furan (m-PPDF), 2-(4-(10-phenylanthracen-9-yl) phenyl) dibenzo[b, d]furan (p-PPDF) and/or combinations thereof.

In one example aspect, when the B-EML1 340B includes the first host 344 and the second host 345, the first host 344 and the second host 345 has a weight ratio ranging from about 4:1 to about 1:4, for example, from about 3:1 to about 1:3, from about 3:7 to about 7:3 or from about 4:6 to about 6:4.

The R-EML 340A may include the red emitter 346 and the third host 348. The red emitter 346 may include at least one of red phosphorescent material, red fluorescent material and red delayed fluorescent material, for example, red phosphorescent material. For example, the red emitter 346 may include, but is not limited to, Bis [2-(4, 6-dimethyl) phenylquinoline)] (2, 2, 6, 6-tetramethylheptane-3, 5-dionate) iridium (III), Bis [2-(4-n-hexylphenyl) quinoline] (acetylacetonate) iridium (III) (Hcx-Ir(phq)₂(acac)), tris[2-(4-n-hexylphenyl)quinoline] iridium(III) (Hex-Ir(phq)₃), tris[2-phenyl-4-methylquinoline] iridium(III) (Ir(Mphq)₃), bis(2-phenylquinoline)(2,2,6,6-tetramethylheptene-3,5-dionate) iridium(III) (Ir(dpm)PQ₂), bis(phenylisoquinoline)(2,2,6,6-tetramethylheptene-3,5-dionate) iridium(III) (Ir(dpm)(piq)₂), bis(1-phenylisoquinoline)(acetylacetonate) iridium(III) (Ir(piq)₂(acac)), bis[(4-n-hexylphenyl)isoquinoline](acetylacetonate) iridium(III) (Hex-Ir(piq)₂(acac)), tris[2-(4-n-hexylphenyl)quinoline] iridium(III) (Hex-Ir(piq)₃), tris(2-(3-methylphenyl)-7-methyl-quinolato) iridium (Ir(dmpq)₃), bis[2-(2-methylphenyl)-7-methyl-quinoline](acetylacetonate) iridium(III) (Ir(dmpq)₂(acac)), bis[2-(3,5-dimethylphenyl)-4-methyl-quinoline](acetylacetonate) iridium(III) (Ir(mphmq)₂(acac)), tris(dibenzoylmethanc)mono(1, 10-phenanthroline)curopium(III) (Eu(dbm)₃(phen) and/or combinations thereof.

The third host 348 may include, but is not limited to, 9-(3-(9H-carbazol-9-yl) phenyl)-9H-carbazole-3-carbonitrile (mCP-CN), CBP, mCBP, mCP, bis [2-(diphenylphosphino) phenyl]ether oxide (DPEPO), 2, 8-bis (diphenylphosphoryl) dibenzothiophene (PPT), 1, 3, 5-Tri [(3-pyridyl)-phen-3-yl]benzene (TmPyPB), 2, 6-di (9H-carbazol-9-yl) pyridine (PYD-2Cz), 2, 8-di (9H-carbazol-9-yl) dibenzothiophene (DCzDBT), 3, 5′-di (carbazol-9-yl)-[1,1′-biphenyl]-3, 5-dicarbonitrile (DCzTPA), 4′-(9H-carbazol-9-yl) biphenyl-3, 5-dicarbonitrile (pCzB-2CN), 3′-(9H-carbazol-9-yl) biphenyl-3, 5-dicarbonitrile (mCzB-2CN), TSPO1, 9-(9-phenyl-9H-carbazol-6-yl)-9H-carbazole (CCP), 4-(3-(triphenylen-2-yl) phenyl) dibenzo[b, d]thiophene), 9-(4-(9H-carbazol-9-yl) phenyl)-9H-3, 9′-bicarbazole, 9-(3-(9H-carbazol-9-yl) phenyl)-9H-3, 9′-bicarbazole, 9-(6-(9H-carbazol-9-yl) pyridin-3-yl)-9H-3, 9′-bicarbazole, 9, 9′-Diphenyl-9H, 9′H-3, 3′-bicarbazole (BCzPh), 1, 3, 5-tris (carbazol-9-yl) benzene (TCP), TCTA, 4, 4′-Bis (carbazole-9-yl)-2, 2′-dimethylbiphenyl (CDBP), 2, 7-bis (carbazole-9-yl)-9, 9-dimethylfluorene (DMFL-CBP), 2, 2′, 7, 7′-tetrakis (carbazol-9-yl)-9, 9-spirofluorene (Spiro-CBP), 3, 6-bis (carbazole-9-yl)-9-(2-ethyl-hexyl)-9H-carbazole (TCzl), BPBPA, 1, 3, 5-tris (N-phenylbenzimidazol-2-yl) benzene (TBPi) and/or combinations thereof.

In one embodiment, the first host 344 may have a LUMO energy level higher than a LUMO energy level of the third host 348. As an example, the LUMO energy level of the first host 344 and the LUMO energy level of the third host 348 may satisfy the following Equation (3):

0.4 eV≤LUMO^{H1}−LUMO^{H3}≤0.8 eV (3)

wherein, LUMO^{H1} indicates the LUMO energy level of the first host and LUMO^{H3} indicates the LUMO energy level of the third host.

In another example aspect, the first host 344 may have a HOMO energy level higher than a HOMO energy level of the third host 348. As an example, the HOMO energy level of the first host 344 and the HOMO energy level of the third host 348 may satisfy the following relationship in Equation (4):

0.4 eV≤HOMO^{H1}−HOMO^{H3}≤0.6 eV (4)

wherein, HOMO^{H1} indicates HOMO energy level of the first host and HOMO^{H3} indicates HOMO energy level of the third host.

For example, the first host 344 may have the LUMO energy level higher than the LUMO energy level of the third host 348 by at least about 0.4 eV and by at most about 0.6 eV. Alternatively, the first host 344 may have the HOMO energy level higher than the HOMO energy level of the third host 348 by at least about 0.3 eV and by at most about 0.5 eV. As an example, the third host 348 may have the LUMO energy level of about −2.4 eV or less, for example, between about −2.4 eV and about −3.0 eV and may have the HOMO energy level of about −5.5 eV or less, for example, between about −5.5 eV and about −6.0 eV but is not limited thereto.

Each of the EML2 440 and the EML4 640 may be a second blue emitting material layer (B-EML2) and a third blue emitting material layer (B-EML3), respectively. In this case, each of the EML2 440 and the EML4 640 may be independently a blue EML, a sky-blue EML or a deep-blue EML. Each of the EML2 440 and the EML4 640 may include a host and a blue emitter (blue dopant). For example, the blue emitter may include the blue emitter 342 in the B-EML1 340B. The host in the EML2 440 and the EML4 640 may include, but is not limited to, mCP, mCP-CN, mCBP, CBP-CN, 9-(3-(9H-carbazoyl-9-yl) phenyl)-3-(diphenylphosphoryl)-9H-carbazole (mCPPO1) 3, 5-di (9H-carbazol-9-yl) biphenyl (Ph-mCP), TSPO1, 9-(3′-(9H-carbazol-9-yl)-[1,1′-biphenyl]-3-yl)-9H-pyrido [2, 3-b]indole (CzBPCb), bis (2-methylphenyl) diphenylsilane (UGH-1), 1, 4-bis (triphenylsilyl) benzene (UGH-2), 1, 3-bis (triphenylsilyl) benzene (UGH-3), 9, 9-spirobifluoren-2-yl-diphenyl-phosphine oxide (SPPO1), 9, 9′-(5-(triphenylsilyl)-1, 3-phenylene) bis (9H-carbazole) (SimCP), ADN, MADN and/or combinations thereof.

The EML3 540 may include a green host and a green emitter (a green dopant). For example, the green host may include the blue host (e.g., first host 344 and/or second host 345) and/or the red host. The green emitter may include at least one of green phosphorescent material, green fluorescent material, and green delayed fluorescent material, for example, green phosphorescent material.

As an example, the green emitter may include, but is not limited to, [bis (2-phenylpyridine)] (pyridyl-2-benzofuro [2, 3-b]pyridine) iridium, tris [2-phenylpyridine]iridium (III) (Ir(ppy)₃), fac-tris(2-phenylpyridine)iridium(III) (fac-Ir(ppy)₃), bis(2-phenylpyridine)(acetylacetonate)iridium(III) (Ir(ppy)₂(acac)), tris[2-(p-tolyl)pyridine]iridium(III) (Ir(mppy)₃), bis(2-(naphthalene-2-yl)pyridine)(acetylacetonate)iridium(III) (Ir(npy)₂acac), tris(2-phenyl-3-methyl-pyridine)iridium(Ir(3mppy)₃), fac-tris(2-(3-p-xylyl)phenyl)pyridine iridium(III) (TEG) and/or combinations thereof.

Alternatively, the R-EML 340A, the EML2 to EML4 440, 540, and 640 may independently include a P-type host and an N-type host. The contents of the host in the R-EML 340A, the B-EML1 340B, the EML2 to EML4 440, 540, and 640 may be independently about 50 wt. % to about 99 wt. %, for example, about 80 wt. % to about 95 wt. % and the contents of the emitter (dopant) in R-EML 340A, the B-EML1 340B, the EML2 to EML4 440, 540 and 640 may be independently from about 1 wt. % to about 50 wt. %, for example, from about 5 wt. % to about 20 wt. %, but is not limited thereto. Alternatively, when the R-EML 340A, the B-EML1 340B, the EML2 to EML4 440, 540, and 640 include the P-type host and the N-type host, the P-type host and the N-type host may be admixed with, but is not limited to, a weight ratio ranging from about 4:1 to about 1:4, for example, from about 3:1 to about 1:3. Alternatively, each of the R-EML 340A, the B-EML1 340B, the EML2 to EML4 440, 540 and 640 may have a thickness of, but is not limited to, from about 5 nm to about 200 nm.

The blue light intensity in an organic light emitting diode with 4-stack structure of two blue emitting parts, one red emitting part and one green emitting part is very low compared to other light intensities and the blue color temperature becomes low. The OLED D includes a host having high HOMO and/or LUMO energy levels in the blue emitting material layer disposed adjacently to the red emitting material layer so that the blue light intensity of the OLED D may be enhanced, and the color temperature of lights emitted from the OLED D may be improved while the red light may be maintained.

More particularly, the first host 344 in the B-EML1 340B has the LUMO energy level and/or the HOMO energy level each of which is higher than the LUMO energy levels and/or the HOMO energy levels of the second host 345 in the B-EML1 340B and/or the third host 348 in the R-EML 340A. The B-EML1 340B disposed adjacently to the R-EML 340 includes the first host 344 having relatively high LUMO energy level and/or HOMO energy level so that the blue light intensity, the color temperature, and viewing angle in the B-EML1 340B may be improved. As the white light having controlled emission colors in balance is emitted from the OLED D1, it is possible to realize efficient white emission.

### Example 1 (Ex.1): Fabrication of OLED

An organic light emitting diode with a tandem structure where a first emitting part includes a red and blue emitting material layers, second and fourth emitting parts include a blue emitting material layer, and a third emitting part includes a green emitting material layer. A glass substrate onto which ITO (110 nm) was coated as a thin film was washed and ultrasonically cleaned by solvent such as isopropyl alcohol, acetone and dried at 100° C. oven. The substrate was transferred to a vacuum chamber for depositing emissive layer. Subsequently, an emissive layer and a cathode were deposited by evaporation from a heating boat under about 5-7×10⁻⁷ Torr as the following order:

Hole injection layer (HIL, MgF₂, 7 nm); first hole transport layer (HTL1, DNTPD, 15 nm); red emitting material layer (R-EML, host (HOMO: −5.57 eV, LUMO: −2.47 eV, maximum PL peak: 516 nm, 95 wt. %), red emitter (Ir(piq)₂(acac), 5 wt. %), 10-20 nm); first blue emitting material layer (B-EML1, host (Compound 1-1 in Chemical Formula 2, HOMO: −5.1 eV, LUMO: −1.98 eV, maximum PL peak: 429 nm, 95 wt. %), blue emitter DABNA-1 (5 wt. %), 10-20 nm); first electron transport layer (ETL1, ZADN, 20 nm); first N-type charge generation layer (N-CGL1, Bphen (99 wt. %), Li (1 wt. %), 17 nm); first P-type charge generation layer (P-CGL1, DNTPD (90 wt. %), P-type dopant (10 wt. %), 7.5 nm); second hole transport layer (HTL2, DNTPD, 77 nm); third hole transport layer (HTL3, TCTA, 15 nm); second blue emitting material layer (B-EML2, MADN (95 wt. %), DABNA-1 (5 wt. %), 20 nm): second electron transport layer (ETL2, ZADN, 11 nm); second N-type charge generation layer (N-CGL2, Bphen (99 wt. %), Li (1 wt. %), 12 nm); second P-type charge generation layer (P-CGL2, DNTPD (90 wt. %), P-type dopant (10 wt. %), 65 nm); fourth hole transport layer (HTL4, BPBPA, 26 nm); green emitting material layer (G-EML1, host (P-type host (CBP), N-type host (TPBi), 88 wt. %), green emitter Ir(ppy)₃ (12 wt. %), 40 nm); third electron transport layer (ETL3, TPBi, 22 nm); third N-type charge generation layer (N-CGL3, Bphen (99 wt. %), Li (1 wt. %), 20 nm); third P-type charge generation layer (P-CGL3, DNDPD (90 wt. %); P-type dopant (10 wt. %), 11 nm); fifth hole transport layer (HTL5, DNTPD, 57 nm); sixth hole transport layer (HTL6, TCTA, 15 nm); third blue emitting material layer (B-EML3, MADN (98.5 wt. %), DABNA-1 (1.5 wt. %), 30 nm); fourth electron transport layer (ETL4, ZADN, 23 nm); electron injection layer (EIL, LiF, 1.35 nm); cathode (Al, 150 nm).

The materials in fabricating the organic light emitting diode are illustrated in the below:

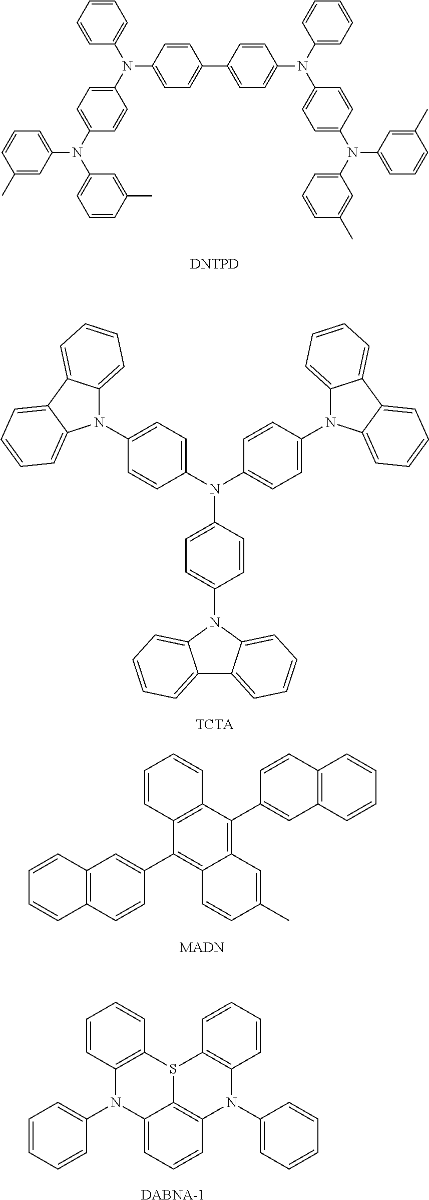

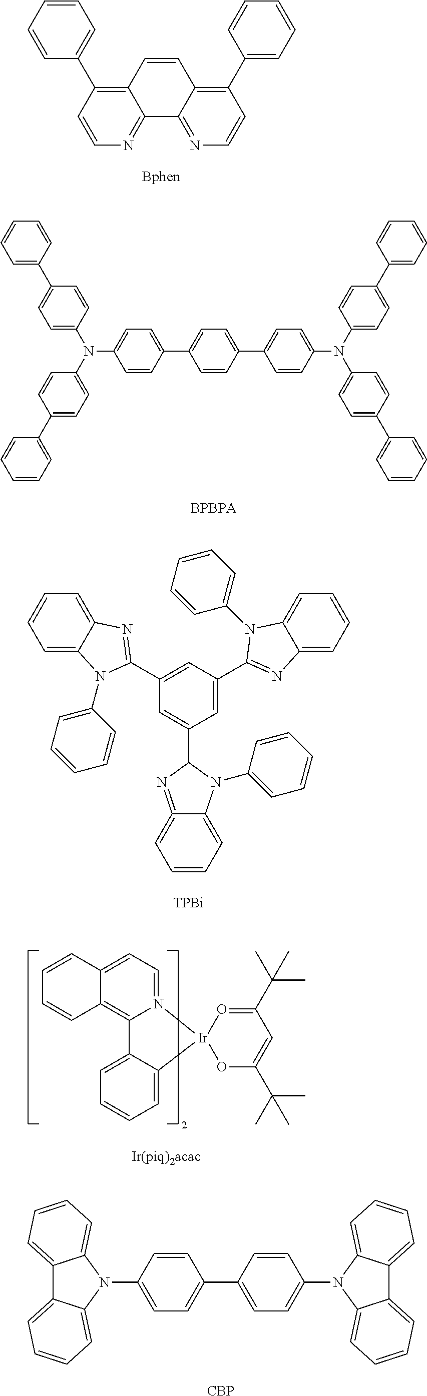

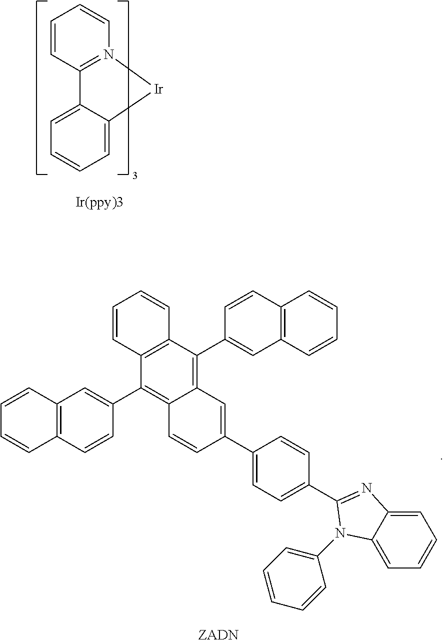

### Comparative Example 1 (Ref. 1): Fabrication of OLEDs

An OLED was fabricated using the same procedure and the same material as Example 1, except that a first blue emitting material layer and a red emitting material layer are laminated sequentially on the first hole transport layer in the first emitting part disposed adjacently to the ITO.

### Experimental Example 1: Measurement of Luminous Properties of OLEDs

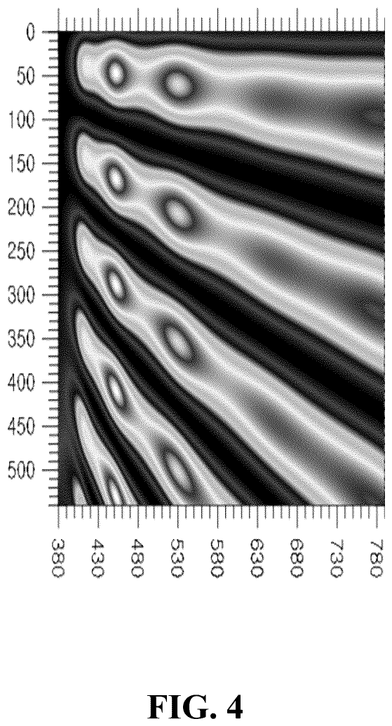

The luminous properties for each of the OLEDs, fabricated in Example 1 and Comparative Example 1, were measured. Particularly, color coordinates and EQE at 10 mA/cm² of current density were measured. FIG. 4 illustrates a contour map by color of an organic light emitting diode fabricated in Example 1, Table 1 below indicates measurement results for the luminous properties in the OLED fabricated in Example 1 and Comparative Example 1 and FIG. illustrates EL (electroluminescence) spectra of OLED fabricated in Example 1 and Comparative Example 1.

TABLE 1
Luminous Properties of OLED

| | Color Coordinates | | | | EQE | | |
|---|---|---|---|---|---|---|---|
| Sample | Rx | Ry | Bx | By | EQE (%) | R | B |
| Ex. 1 | 0.697 | 0.308 | 0.147 | 0.038 | 14.69 | 13.59 | 1.10 |
| Ref. 1 | 0.696 | 0.309 | 0.145 | 0.043 | 3.84 | 3.45 | 0.39 |

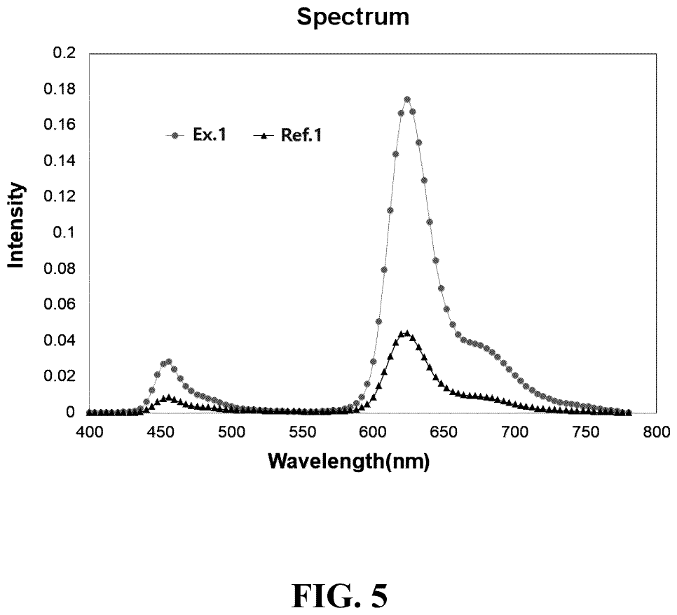

As illustrated in Table 1 and FIGS. 4 and 5, compared to the OLED fabricated in Comparative Example 1 where the blue emitting material layer and the red emitting material layer in the first emitting part are laminated sequentially on the ITO electrode, in the OLED fabricated in Example 1 where the red emitting material layer and the blue emitting material layer in the first emitting part are laminated sequentially on the ITO electrode, the efficiency of the red, green and blue may be maximized and color viewing angle may be improved. Particularly, compared to the OLED fabricated in Comparative Example 1, in the OLED fabricated in Example 1, the blue light intensity was improved and EQE was improved significantly.

### Comparative Example 2 (Ref. 2): Fabrication of OLEDs

An OLED was fabricated using the same procedure and the same material as Example 1, except that the red host in the R-EML instead of Compound 1-1 as the host in the B-EML1 of the first emitting part was used.

### Comparative Example 3 (Ref. 3): Fabrication of OLEDs

An OLED was fabricated using the same procedure and the same material as Example 1, except that the emitting material layer in the first emitting part was changed to a single emitting material layer of the R-EML.

### Experimental Example 2: Measurement of Luminous Properties of OLEDs

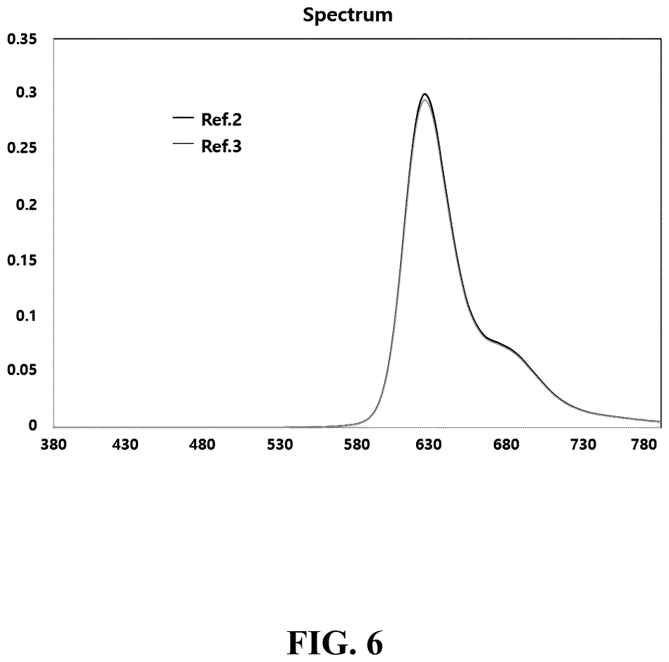

The luminous properties for each of the OLEDs fabricated in Comparative Examples 2-3 were measured as the same process as the Experimental Example 1. The driving voltage (V), current efficiency (cd/A), color coordinates and EQE at 10 mA/cm² of current density was measured, and EL spectra in the first emitting part were measured. Table 2 below and FIG. 6 indicate the measurement results.

TABLE 2
Luminous Properties of OLED

| Sample | V | cd/A | CIE(x) | CIE(y) | EQE (%) |
|---|---|---|---|---|---|
| Ref. 2 | 2.74 | 22.9 | 0.688 | 0.312 | 23.06 |
| Ref. 3 | 2.83 | 21.7 | 0.689 | 0.311 | 22.2 |

As illustrated in Table 2 and FIG. 6, no blue emission peak was observed in the OLED fabricated in Comparative Example 3 where the first emitting part includes only the red emitting material layer as well as in the OLED fabricated in Comparative Example 2 wherein the red emitting material layer and the blue emitting material layer in the first emitting part include the same host. When the red emitting material layer and the blue emitting material layer uses the same host, the blue light intensity was not enhanced, and color temperature and viewing angle were not improved.

### Examples 2-3 (Ex. 2-3): Fabrication of OLEDs

An OLED was fabricated using the same procedure and the same material as Example 1, except that Compound 1-4 in Chemical Formula 2 (HOMO: −5.15 eV, LUMO: −2.0 eV, maximum PL peak: 426 nm, Ex. 2) or Compound 1-10 in Chemical Formula 2 (HOMO: −5.14 eV, LUMO: −1.93 eV, maximum PL peak: 431 nm, Ex. 3) instead of Compound 1-1 was used as the host in the B-EML1 of the first emitting part.

### Comparative Example 4 (Ref. 4): Fabrication of OLEDs

An OLED was fabricated using the same procedure and the same material as Example 1, except that an anthracene-based host of Chemical Formula 3 (HOMO: −5.47 eV, LUMO: −2.45 eV, maximum PL peak 420 nm) instead of Compound 1-1 was used as the host in the B-EML1 of the first emitting part.

### Experimental Example 3: Measurement of Luminous Properties of OLEDs

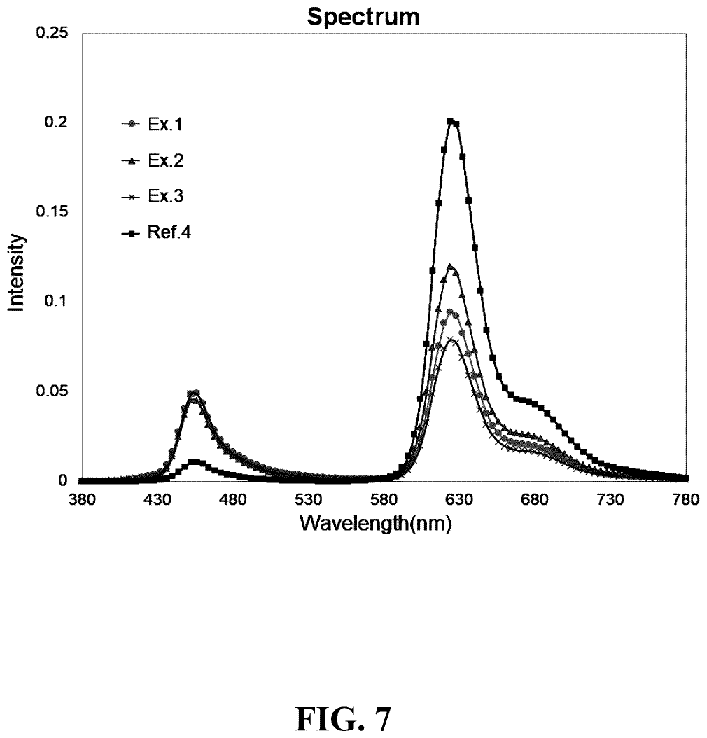

The luminous properties for each of the OLEDs fabricated in Examples 1-3 and Comparative Example 4 were measured as the same process as the Experimental Example 1. Table 3 below and FIG. 7 indicate the measurement results.

TABLE 3
Luminous Properties of OLED

| Sample | V | cd/A | CIE(x) | CIE(y) | EQE (%) |
|---|---|---|---|---|---|
| Ex. 1 | 3.79 | 9.49 | 0.429 | 0.206 | 9.74 |
| Ex. 2 | 3.94 | 11.11 | 0.479 | 0.224 | 11.38 |
| Ex. 3 | 3.64 | 8.07 | 0.410 | 0.196 | 8.39 |
| Ref. 4 | 3.05 | 16.07 | 0.644 | 0.291 | 16.4 |

As illustrated in Table 3 and FIG. 7, in the OLED fabricated in Comparative Example 4 where the HOMO and/or LUMO energy levels of the host in the B-EML1 were designed to be similar to the HOMO and/or LUMO energy levels of the host in the R-EML, the color temperature was not improved owing to low blue light intensity. On the contrary, in the OLEDs fabricated in Examples 1-3 where the B-EML1 includes the host having LUMO and/or HOMO energy levels higher than the LUMO and/or HOMO energy levels of the host in the R-EML by 0.3 eV or more, luminous color temperature and viewing angles are improved as the luminescence peak in the blue range is increased.

### Example 4 (Ex. 4): Fabrication of OLEDs

An OLED was fabricated using the same procedure and the same material as Example 1, except that composite host with Compound 1-1 and the anthracene-based host of Comparative Example instead of Compound 1-1 was admixed with a weight ratio 7:3 in the B-EML1 of the first emitting part.

### Examples 5-6 (Ex. 5-6): Fabrication of OLEDs

An OLED was fabricated using the same procedure and the same material as Example 4, except that Compound 1-1 and the anthracene-based host (5:5 by weight, Ex. 5) or Compound 1-1 and the anthracene-based host (3:7 by weight, Ex. 6) were used in the B-EML1 of the first emitting part.

### Experimental Example 4: Measurement of Luminous Properties of OLEDs

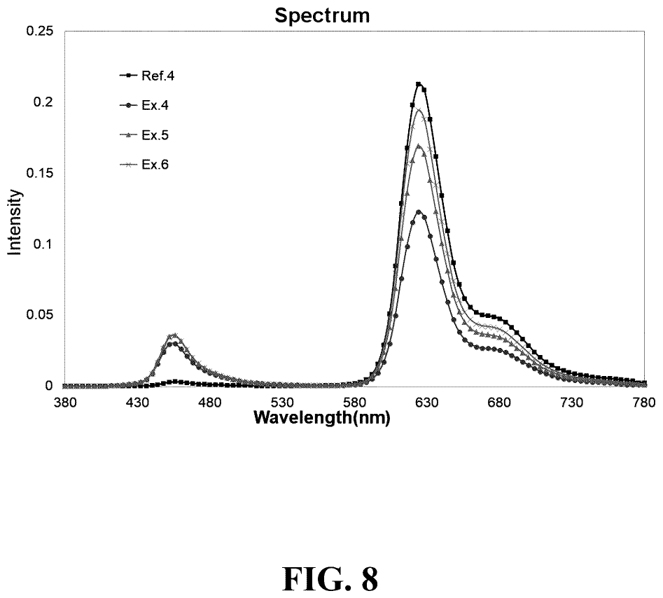

The luminous properties for each of the OLEDs fabricated in Examples 4-6 and Comparative Example 4 were measured as the same process as the Experimental Example 1. Table 4 below and FIG. 8 indicate the measurement results.

TABLE 4
Luminous Properties of OLED

| Sample | V | cd/A | CIE(x) | CIE(y) | EQE (%) |
|---|---|---|---|---|---|
| Ex. 4 | 3.6 | 7.87 | 0.46 | 0.215 | 8.08 |
| Ex. 5 | 3.38 | 13.01 | 0.524 | 0.241 | 13.03 |
| Ex. 6 | 3.28 | 16.26 | 0.559 | 0.241 | 13.03 |
| Ref. 4 | 3.28 | 17.01 | 0.674 | 0.307 | 17.2 |

### Example 7 (Ex. 7): Fabrication of OLEDs

An OLED was fabricated using the same procedure and the same material as Example 1, except that composite host with Compound 1-4 and the anthracene-based host of Comparative Example instead of Compound 1-1 was admixed with a weight ratio 7:3 in the B-EML1 of the first emitting part.

### Examples 8-9 (Ex. 8-9): Fabrication of OLEDs

An OLED was fabricated using the same procedure and the same material as Example 7, except that Compound 1-1 and the anthracene-based host (5:5 by weight, Ex. 8) or Compound 1-1 and the anthracene-based host (3:7 by weight, Ex. 8) were used in the B-EML1 of the first emitting part.

### Experimental Example 5: Measurement of Luminous Properties of OLEDs

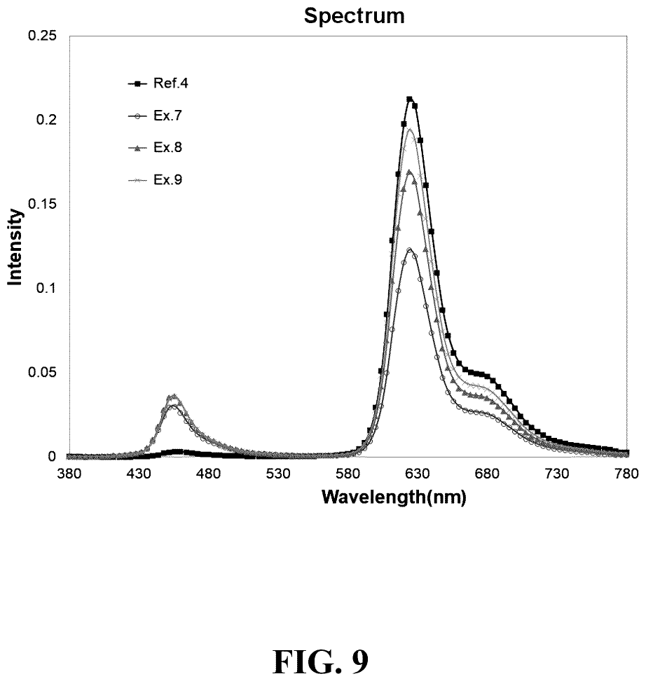

The luminous properties for each of the OLEDs fabricated in Examples 7-9 and Comparative Example 4 were measured as the same process as the Experimental Example 1. Table 5 below and FIG. 9 indicate the measurement results.

TABLE 5
Luminous Properties of OLED

| Sample | V | cd/A | CIE(x) | CIE(y) | EQE (%) |
|---|---|---|---|---|---|
| Ex. 7 | 3.64 | 10.68 | 0.53 | 0.245 | 10.73 |
| Ex. 8 | 3.37 | 14.39 | 0.548 | 0.251 | 14.43 |
| Ex. 9 | 3.26 | 16.35 | 0.564 | 0.258 | 16.38 |
| Ref. 4 | 3.28 | 17.01 | 0.674 | 0.307 | 17.2 |

As illustrated in Tables 4 and 5, and FIGS. 8 and 9, in the OLEDs fabricated in Examples 4-9 where the B-EML1 includes both the host having LUMO and/or HOMO energy levels higher than the LUMO and/or HOMO energy levels of the host in the R-EML by 0.3 eV or more and the anthracene host, the luminous color temperature and viewing angles are improved as the luminescence peak in the blue range is increased. Particularly, the luminous properties of the OLED may be improved significantly by using together with the anthracene-based host in the B-EML1.

It will be apparent to those skilled in the art that various modifications and variations may be made in the present disclosure without departing from the scope of the disclosure. Thus, it is intended that the present disclosure covers the modifications and variations of the present disclosure provided they come within the scope of the appended claims.

What is claimed is:

1. An organic light emitting diode comprising:
a first electrode;
a second electrode facing the first electrode;
an emissive layer disposed between the first electrode and the second electrode,
wherein the emissive layer comprises:
a first emitting part disposed between the first electrode and the second electrode;
a second emitting part disposed between the first emitting part and the second electrode;
a third emitting part disposed between the second emitting part and the second electrode;
a fourth emitting part disposed between the third emitting part and the second electrode;
a first charge generation layer disposed between the first emitting part and the second emitting part;
a second charge generation layer disposed between the second emitting part and the third emitting part;
a third charge generation layer disposed between the third emitting part and the fourth emitting part;
wherein one of the first emitting part, the second emitting part, the third emitting part, and the fourth emitting part comprises a red-blue emitting material layer comprising:
a red emitting material layer disposed between the first electrode and the second electrode;
a blue emitting material layer disposed between the red emitting material layer and the second electrode;
wherein the blue emitting material layer comprises a blue emitter and a first host of Chemical Formula 1: 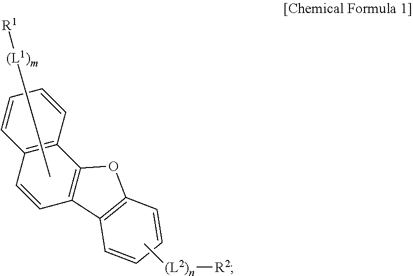
wherein,
R¹ and R² are independently selected from a group consisting of an unsubstituted C₆-C₃₀ aryl group, a substituted C₆-C₃₀ aryl group, an unsubstituted C₃-C₃₀ hetero aryl group, a substituted C₃-C₃₀ hetero aryl group, an unsubstituted C₆-C₃₀ aryl amino group, a substituted C₆-C₃₀ aryl amino group, an unsubstituted C₃-C₃₀ hetero aryl amino group, and a substituted C₃-C₃₀ hetero aryl amino group, where one of R¹ and R² is the unsubstituted C₆-C₃₀ aryl group, a substituted C₆-C₃₀ aryl group, the unsubstituted C₃-C₃₀ hetero aryl group, or the substituted C₃-C₃₀ hetero aryl group and another of R¹ and R² is the unsubstituted C₆-C₃₀ aryl amino group, the substituted C₆-C₃₀ aryl amino group, the unsubstituted C₃-C₃₀ hetero aryl amino group, or the substituted C₃-C₃₀ hetero aryl amino group;
L¹ and L² are independently selected from a group consisting of an unsubstituted C₆-C₃₀ arylene group, a substituted C₆-C₃₀ arylene group, an unsubstituted C₃-C₃₀ hetero arylene group, and substituted C₃-C₃₀ hetero arylene group; and
m and n are independently 0 or 1.

2. The organic light emitting diode of claim 1, wherein the first emitting part comprises the red-blue emitting material layer.

3. The organic light emitting diode of claim 1, wherein the first electrode comprises a transmissive electrode and the second electrode comprises a reflective electrode.

4. The organic light emitting diode of claim 1, wherein the blue emitting material layer further comprises a second host.

5. The organic light emitting diode of claim 4, wherein the first host has a lowest unoccupied molecular orbital (LUMO) energy level higher than a LUMO energy level of the second host.

6. The organic light emitting diode of claim 5, wherein LUMO energy level of the first host and LUMO energy level of the second host satisfies Equation (1):
0.4 eV≤LUMO^{H1}−LUMO^{H2}≤0.8 eV (1);
wherein, LUMO^{H1} indicates LUMO energy level of the first host and LUMO^{H2} indicates LUMO energy level of the second host.

7. The organic light emitting diode of claim 4, wherein the first host has a highest occupied molecular orbital (HOMO) energy level higher than a HOMO energy level of the second host.

8. The organic light emitting diode of claim 7, wherein the HOMO energy level of the first host and the HOMO energy level of the second host satisfies the following relationship in Equation (2):
0.3 eV≤HOMO^{H1}−HOMO^{H2}≤0.6 eV (2);
wherein, HOMO^{H1} indicates HOMO energy level of the first host and HOMO^{H2} indicates HOMO energy level of the second host.

9. The organic light emitting diode of claim 4, wherein the second host has a structure of Chemical Formula 3: 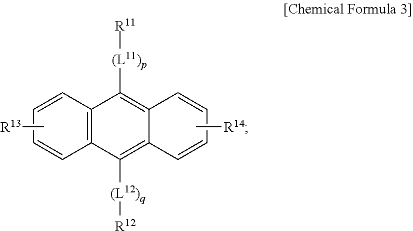
wherein
R¹¹ and R¹² are independently selected from a group consisting of an unsubstituted C₆-C₃₀ aryl group, a substituted C₆-C₃₀ aryl group, an unsubstituted C₃-C₃₀ hetero aryl group, and a substituted C₃-C₃₀ hetero aryl group;
R¹³ and R¹⁴ are independently selected from a group consisting of hydrogen, an unsubstituted C₁-C₂₀ alkyl group, a substituted C₁-C₂₀ alkyl group, an unsubstituted C₆-C₃₀ aryl group, a substituted C₆-C₃₀ aryl group, an unsubstituted C₃-C₃₀ hetero aryl group, and a substituted C₃-C₃₀ hetero aryl group;
L¹¹ and L¹² are independently selected from a group consisting of an unsubstituted C₆-C₃₀ arylene group, a substituted C₆-C₃₀ arylene group, an unsubstituted C₃-C₃₀ hetero arylene group, and a substituted C₃-C₃₀ hetero arylene group; and
p and q are independently 0 or 1.

10. The organic light emitting diode of claim 4, wherein the first host and the second host in the blue emitting material layer has a weight ratio ranging from about 3:7 to about 7:3.

11. The organic light emitting diode of claim 1, wherein the red emitting material layer comprises a red emitter and a third host.

12. The organic light emitting diode of claim 11, wherein the first host has a LUMO energy level higher than a LUMO energy level of the third host.

13. The organic light emitting diode of claim 12, wherein a LUMO energy level of the first host and the LUMO energy level of the third host satisfies Equation (3):
0.4 eV≤LUMO^{H1}−LUMO^{H3}≤0.8 eV (3)
wherein, LUMO^{H1} indicates LUMO energy level of the first host and LUMO^{H3} indicates LUMO energy level of the third host.

14. The organic light emitting diode of claim 11, wherein the first host has a HOMO energy level higher than the HOMO energy level of the third host.

15. The organic light emitting diode of claim 14, wherein the HOMO energy level of the first host and the HOMO energy level of the third host satisfies Equation (4):
0.4 eV≤HOMO^{H1}−HOMO^{H3}≤0.6 eV (4);
wherein, HOMO^{H1} indicates HOMO energy level of the first host and HOMO^{H3} indicates HOMO energy level of the third host.

16. An organic light emitting diode including:
a first electrode;
a second electrode facing the first electrode;
an emissive layer disposed between the first electrode and the second electrode;
wherein the emissive layer comprises:
a first emitting part disposed between the first electrode and the second electrode;
a second emitting part disposed between the first emitting part and the second electrode;
a third emitting part disposed between the second emitting part and the second electrode;
a fourth emitting part disposed between the third emitting part and the second electrode;
a first charge generation layer disposed between the first emitting part and the second emitting part;
a second charge generation layer disposed between the second emitting part and the third emitting part;
a third charge generation layer disposed between the third emitting part and the fourth emitting part;
wherein the first emitting part comprises a red-blue emitting material layer comprising:
a red emitting material layer disposed between the first electrode and the second electrode;
a blue emitting material layer disposed between the red emitting material layer and the second electrode,
wherein each of the second emitting part and the fourth emitting part includes a blue emitting material layer, respectively;
wherein the second emitting part comprises a green emitting material layer,
wherein the blue emitting material layer in the first emitting part comprises a blue emitter and a first host of Chemical Formula 1: 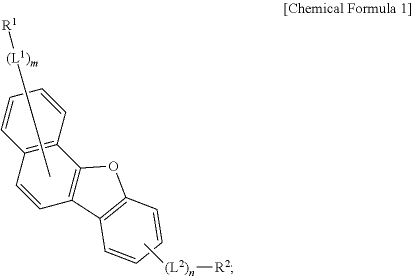
wherein
R¹ and R² are independently selected from a group consisting of an unsubstituted C₆-C₃₀ aryl group, a substituted C₆-C₃₀ aryl group, an unsubstituted C₃-C₃₀ hetero aryl group, a substituted C₃-C₃₀ hetero aryl group, an unsubstituted C₆-C₃₀ aryl amino group, a substituted C₆-C₃₀ aryl amino group, an unsubstituted C₃-C₃₀ hetero aryl amino group, and a substituted C₃-C₃₀ hetero aryl amino group, where one of R¹ and R² is the unsubstituted C₆-C₃₀ aryl group, the substituted C₆-C₃₀ aryl group, the unsubstituted C₃-C₃₀ hetero aryl group, or the substituted C₃-C₃₀ hetero aryl group and another of R¹ and R² is the unsubstituted C₆-C₃₀ aryl amino group, the substituted C₆-C₃₀ aryl amino group, the unsubstituted C₃-C₃₀ hetero aryl amino group, or the substituted C₃-C₃₀ hetero aryl amino group;
L¹ and L² are independently selected from a group consisting of an unsubstituted C₆-C₃₀ arylene group, a substituted C₆-C₃₀ arylene group, an unsubstituted C₃-C₃₀ hetero arylene group, and substituted C₃-C₃₀ hetero arylene group; and
m and n are independently 0 or 1.

17. The organic light emitting diode of claim 16, wherein the first electrode comprises a transmissive electrode and the second electrode comprises a reflective electrode.

18. The organic light emitting diode of claim 16, wherein the blue emitting material layer in the first emitting part further comprises a second host.

19. The organic light emitting diode of claim 18, wherein a LUMO energy level of the first host and the LUMO energy level of the second host satisfies Equation (1):
0.4 eV≤LUMO^{H1}−LUMO^{H2}≤0.8 eV (1);
wherein, LUMO^{H1} indicates LUMO energy level of the first host and LUMO^{H2} indicates LUMO energy level of the second host.

20. The organic light emitting diode of claim 18, wherein a HOMO energy level of the first host and the HOMO energy level of the second host satisfies Equation (2):
0.3 eV≤HOMO^{H1}−HOMO^{H2}≤0.6 eV (2);
wherein, HOMO^{H1} indicates HOMO energy level of the first host and HOMO^{H2} indicates HOMO energy level of the second host.

21. An organic light emitting diode comprising:
a first electrode;
a second electrode facing the first electrode;
an emissive layer disposed between the first electrode and the second electrode,
wherein the emissive layer comprises:
a first emitting part disposed between the first electrode and the second electrode;
a second emitting part disposed between the first emitting part and the second electrode;
a third emitting part disposed between the second emitting part and the second electrode;
a fourth emitting part disposed between the third emitting part and the second electrode;
a first charge generation layer disposed between the first emitting part and the second emitting part;
a second charge generation layer disposed between the second emitting part and the third emitting part;
a third charge generation layer disposed between the third emitting part and the fourth emitting part;
wherein one of the first emitting part, the second emitting part, the third emitting part, and the fourth emitting part comprises a red-blue emitting material layer comprising:
a red emitting material layer disposed between the first electrode and the second electrode;
a blue emitting material layer disposed between the red emitting material layer and the second electrode;
wherein the blue emitting material layer comprises a blue emitter and a first host comprising at least one organic compound having the structure of Chemical Formula 2: 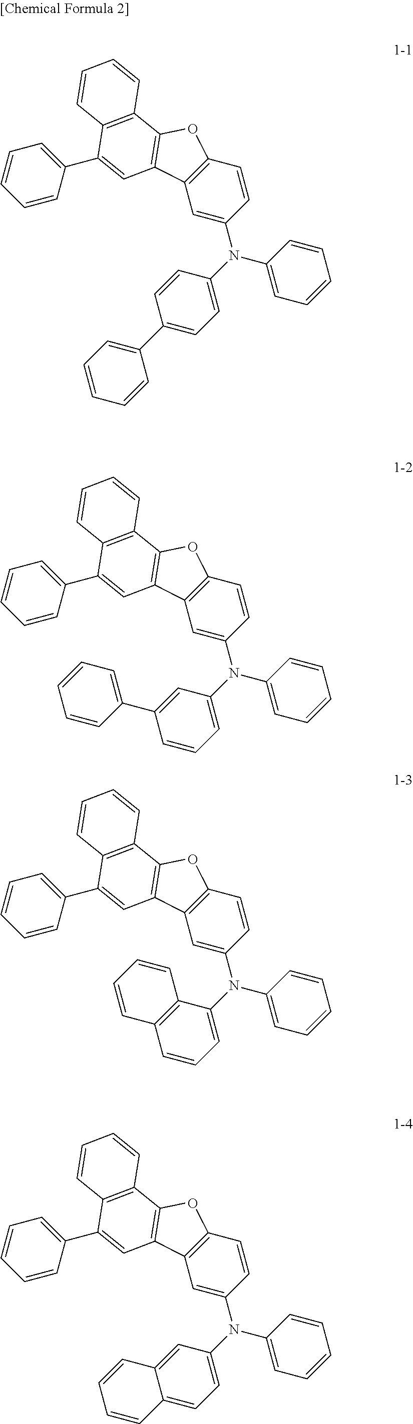 [SMILES: c1ccc(-c2ccc(N(c3ccccc3)c3ccc4oc5c6ccccc6c(-c6ccccc6)cc5c4c3)cc2)cc1 ; c1ccc(-c2cccc(N(c3ccccc3)c3ccc4oc5c6ccccc6c(-c6ccccc6)cc5c4c3)c2)cc1 ; c1ccc(-c2cc3c4cc(N(c5ccccc5)c5cccc6ccccc56)ccc4oc3c3ccccc23)cc1 ; c1ccc(-c2cc3c4cc(N(c5ccccc5)c5ccc6ccccc6c5)ccc4oc3c3ccccc23)cc1] 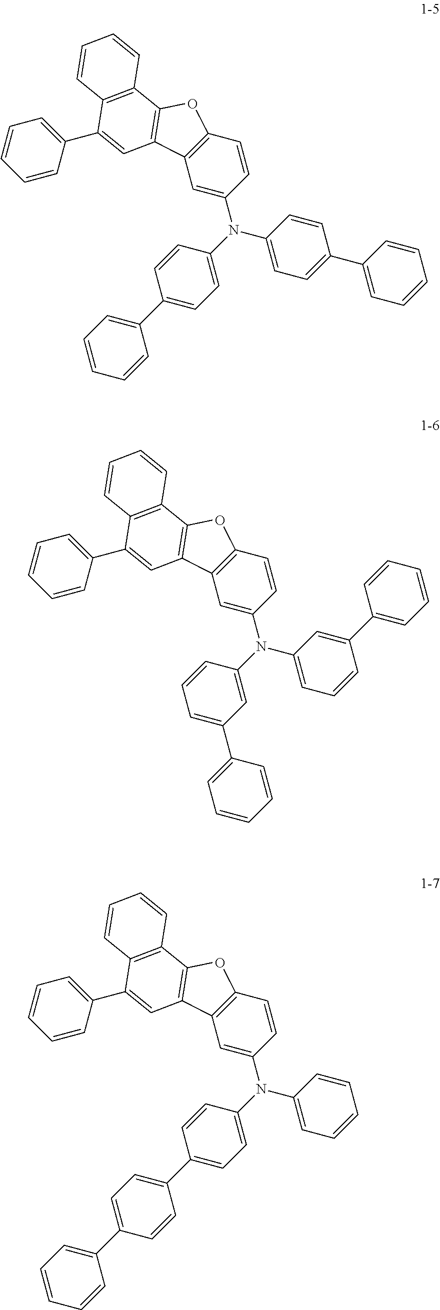 [SMILES: c1ccc(-c2ccc(N(c3ccc(-c4ccccc4)cc3)c3ccc4oc5c6ccccc6c(-c6ccccc6)cc5c4c3)cc2)cc1 ; c1ccc(-c2cccc(N(c3cccc(-c4ccccc4)c3)c3ccc4oc5c6ccccc6c(-c6ccccc6)cc5c4c3)c2)cc1 ; c1ccc(-c2ccc(-c3ccc(N(c4ccccc4)c4ccc5oc6c7ccccc7c(-c7ccccc7)cc6c5c4)cc3)cc2)cc1] 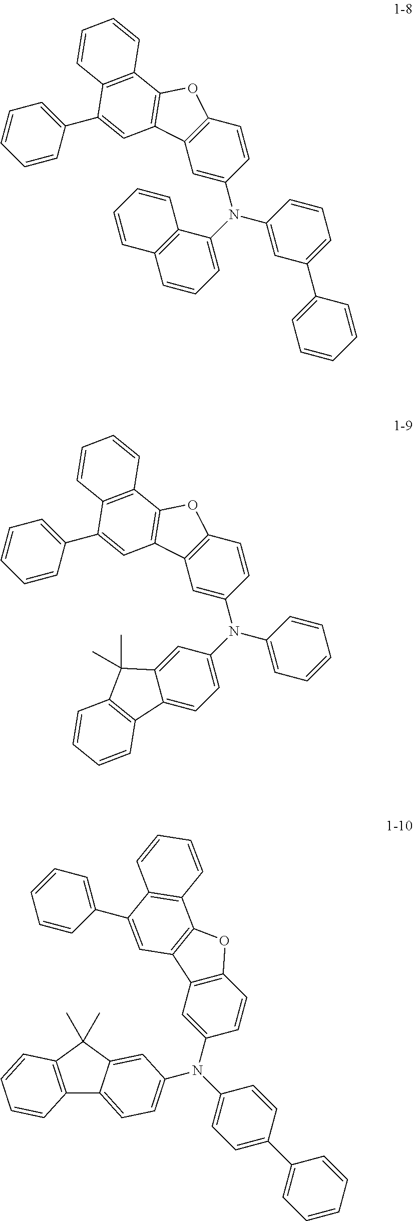 [SMILES: c1ccc(-c2cccc(N(c3ccc4oc5c6ccccc6c(-c6ccccc6)cc5c4c3)c3cccc4ccccc34)c2)cc1 ; CC1(C)c2ccccc2-c2ccc(N(c3ccccc3)c3ccc4oc5c6ccccc6c(-c6ccccc6)cc5c4c3)cc21 ; CC1(C)c2ccccc2-c2ccc(N(c3ccc(-c4ccccc4)cc3)c3ccc4oc5c6ccccc6c(-c6ccccc6)cc5c4c3)cc21] 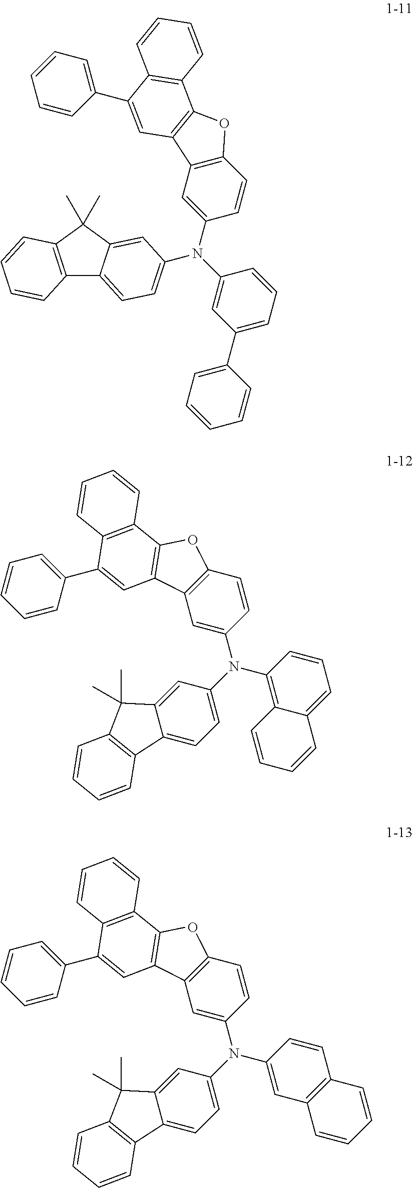 [SMILES: CC1(C)c2ccccc2-c2ccc(N(c3cccc(-c4ccccc4)c3)c3ccc4oc5c6ccccc6c(-c6ccccc6)cc5c4c3)cc21 ; CC1(C)c2ccccc2-c2ccc(N(c3ccc4oc5c6ccccc6c(-c6ccccc6)cc5c4c3)c3cccc4ccccc34)cc21 ; CC1(C)c2ccccc2-c2ccc(N(c3ccc4ccccc4c3)c3ccc4oc5c6ccccc6c(-c6ccccc6)cc5c4c3)cc21] 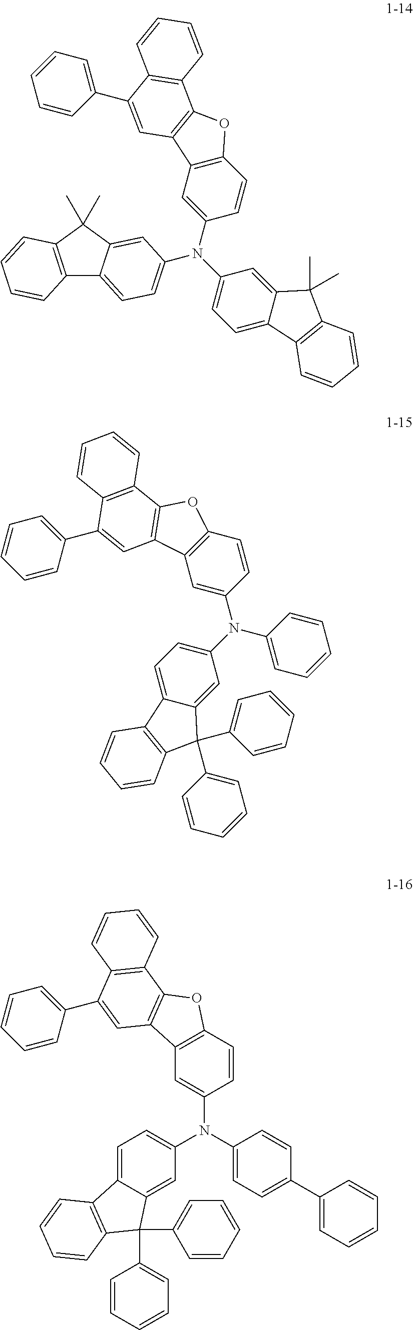 [SMILES: CC1(C)c2ccccc2-c2ccc(N(c3ccc4c(c3)C(C)(C)c3ccccc3-4)c3ccc4oc5c6ccccc6c(-c6ccccc6)cc5c4c3)cc21 ; c1ccc(-c2cc3c4cc(N(c5ccccc5)c5ccc6c(c5)C(c5ccccc5)(c5ccccc5)c5ccccc5-6)ccc4oc3c3ccccc23)cc1 ; c1ccc(-c2ccc(N(c3ccc4c(c3)C(c3ccccc3)(c3ccccc3)c3ccccc3-4)c3ccc4oc5c6ccccc6c(-c6ccccc6)cc5c4c3)cc2)cc1] 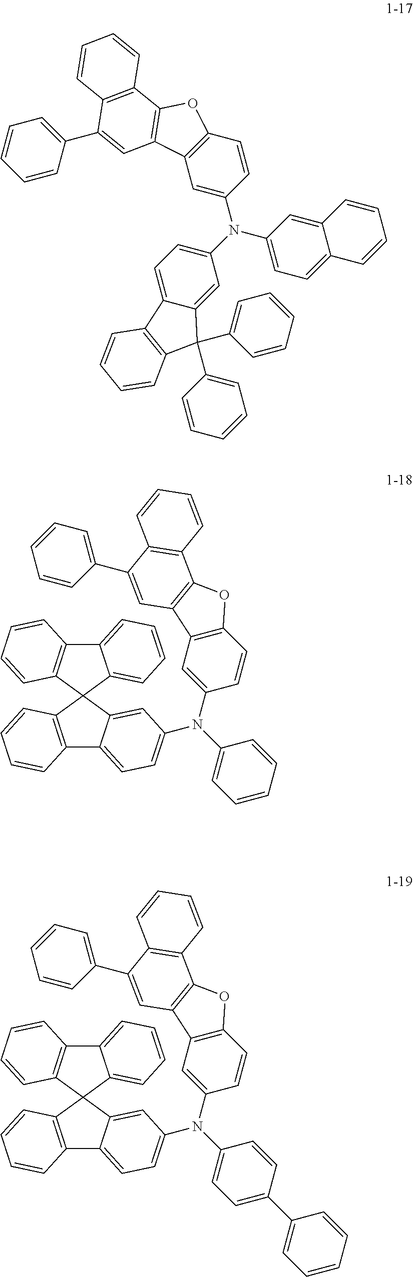 [SMILES: c1ccc(-c2cc3c4cc(N(c5ccc6c(c5)C(c5ccccc5)(c5ccccc5)c5ccccc5-6)c5ccc6ccccc6c5)ccc4oc3c3ccccc23)cc1 ; c1ccc(-c2cc3c4cc(N(c5ccccc5)c5ccc6c(c5)C5(c7ccccc7-c7ccccc75)c5ccccc5-6)ccc4oc3c3ccccc23)cc1 ; c1ccc(-c2ccc(N(c3ccc4c(c3)C3(c5ccccc5-c5ccccc53)c3ccccc3-4)c3ccc4oc5c6ccccc6c(-c6ccccc6)cc5c4c3)cc2)cc1] 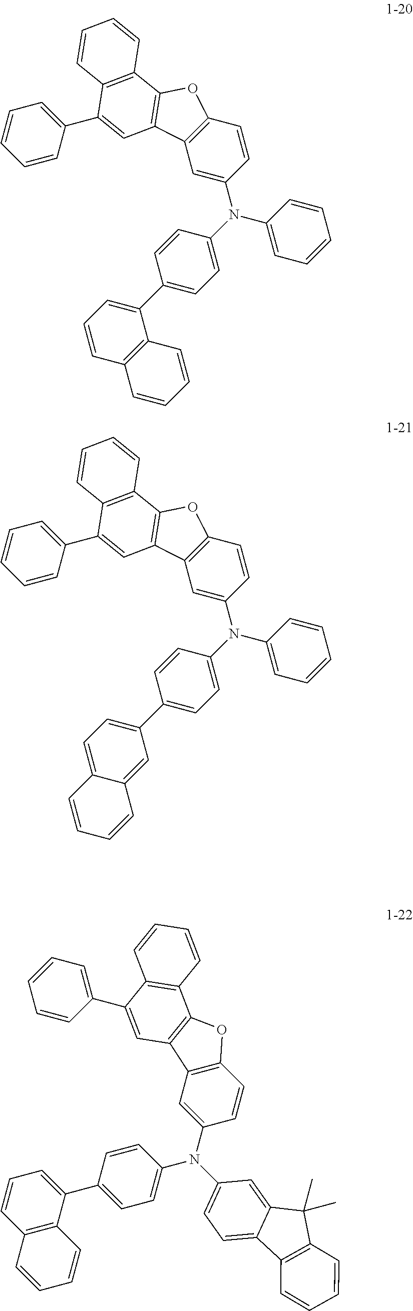 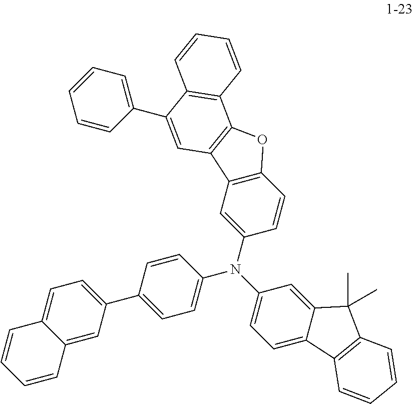 [SMILES: CC1(C)c2ccccc2-c2ccc(N(c3ccc(-c4ccc5ccccc5c4)cc3)c3ccc4oc5c6ccccc6c(-c6ccccc6)cc5c4c3)cc21] 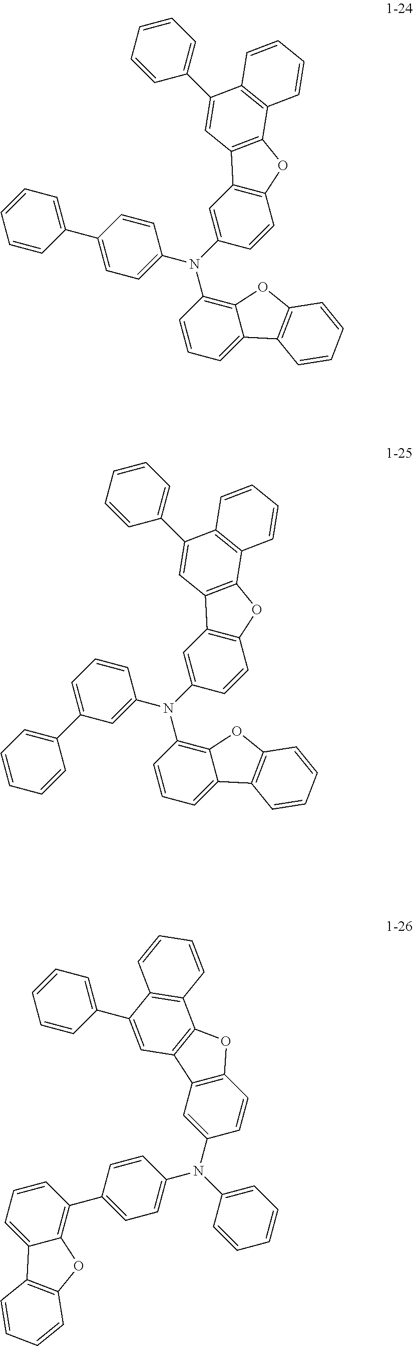 [SMILES: c1ccc(-c2ccc(N(c3ccc4oc5c6ccccc6c(-c6ccccc6)cc5c4c3)c3cccc4c3oc3ccccc34)cc2)cc1 ; c1ccc(-c2cccc(N(c3ccc4oc5c6ccccc6c(-c6ccccc6)cc5c4c3)c3cccc4c3oc3ccccc34)c2)cc1 ; c1ccc(-c2cc3c4cc(N(c5ccccc5)c5ccc(-c6cccc7c6oc6ccccc67)cc5)ccc4oc3c3ccccc23)cc1] 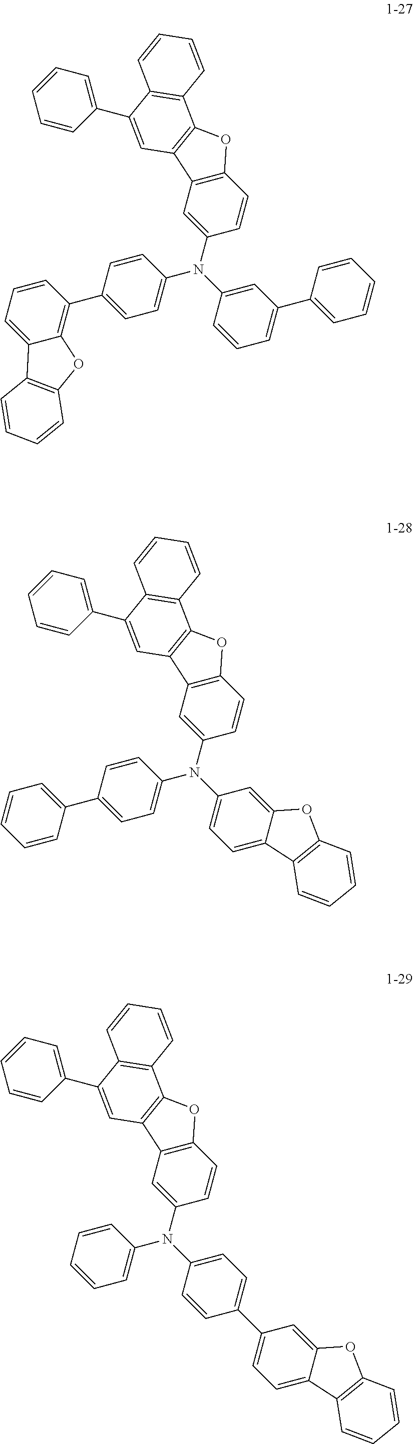 [SMILES: c1ccc(-c2cccc(N(c3ccc(-c4cccc5c4oc4ccccc45)cc3)c3ccc4oc5c6ccccc6c(-c6ccccc6)cc5c4c3)c2)cc1 ; c1ccc(-c2ccc(N(c3ccc4c(c3)oc3ccccc34)c3ccc4oc5c6ccccc6c(-c6ccccc6)cc5c4c3)cc2)cc1 ; c1ccc(-c2cc3c4cc(N(c5ccccc5)c5ccc(-c6ccc7c(c6)oc6ccccc67)cc5)ccc4oc3c3ccccc23)cc1] 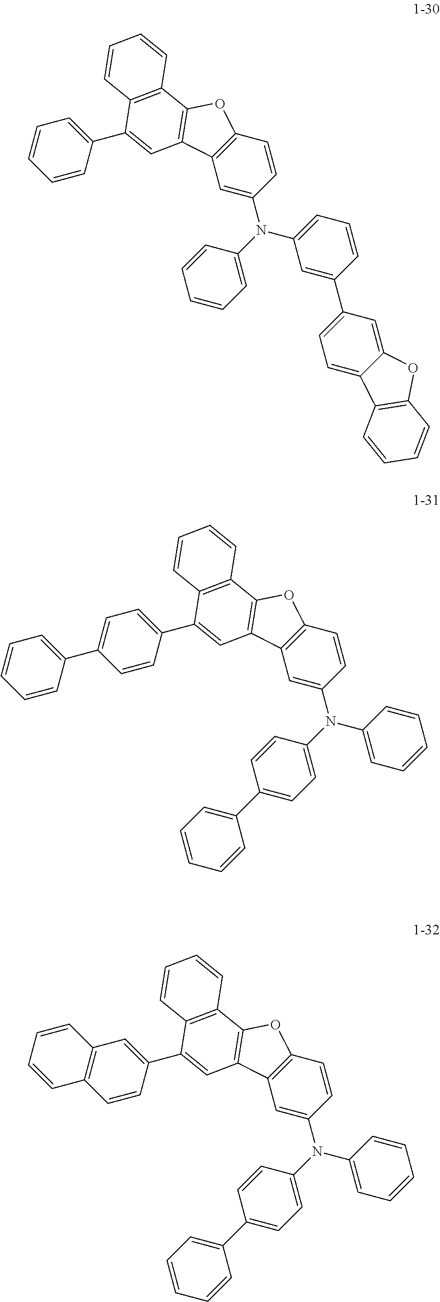 [SMILES: c1ccc(-c2cc3c4cc(N(c5ccccc5)c5cccc(-c6ccc7c(c6)oc6ccccc67)c5)ccc4oc3c3ccccc23)cc1 ; c1ccc(-c2ccc(-c3cc4c5cc(N(c6ccccc6)c6ccc(-c7ccccc7)cc6)ccc5oc4c4ccccc34)cc2)cc1 ; c1ccc(-c2ccc(N(c3ccccc3)c3ccc4oc5c6ccccc6c(-c6ccc7ccccc7c6)cc5c4c3)cc2)cc1] 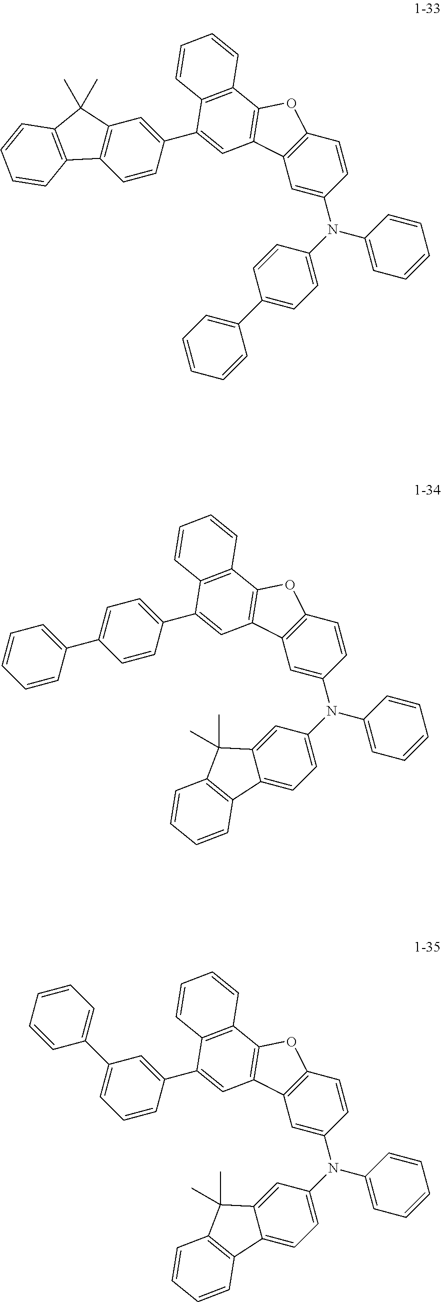 [SMILES: CC1(C)c2ccccc2-c2ccc(-c3cc4c5cc(N(c6ccccc6)c6ccc(-c7ccccc7)cc6)ccc5oc4c4ccccc34)cc21 ; CC1(C)c2ccccc2-c2ccc(N(c3ccccc3)c3ccc4oc5c6ccccc6c(-c6ccc(-c7ccccc7)cc6)cc5c4c3)cc21 ; CC1(C)c2ccccc2-c2ccc(N(c3ccccc3)c3ccc4oc5c6ccccc6c(-c6cccc(-c7ccccc7)c6)cc5c4c3)cc21] 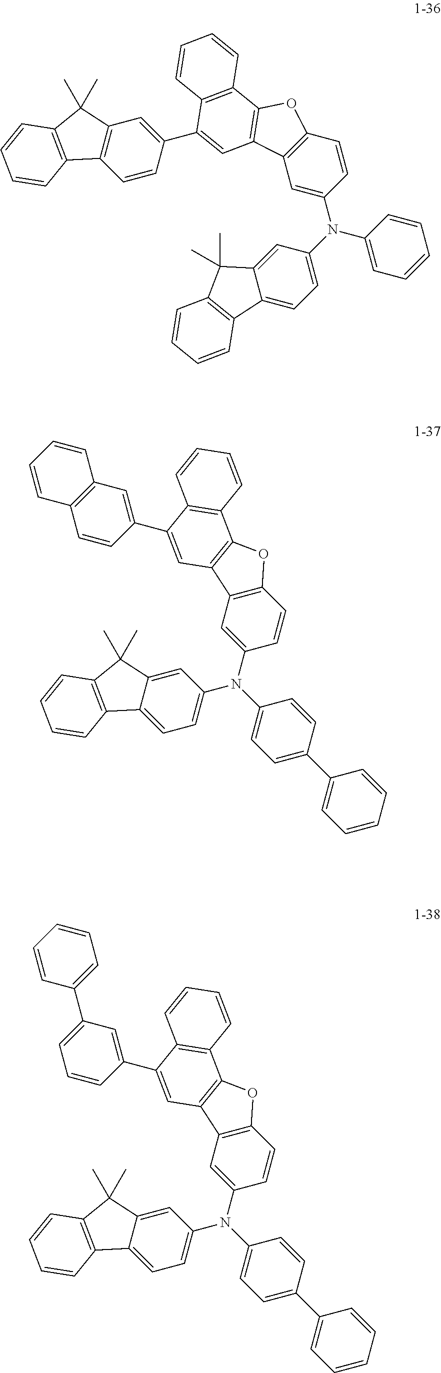 [SMILES: CC1(C)c2ccccc2-c2ccc(-c3cc4c5cc(N(c6ccccc6)c6ccc7c(c6)C(C)(C)c6ccccc6-7)ccc5oc4c4ccccc34)cc21 ; CC1(C)c2ccccc2-c2ccc(N(c3ccc(-c4ccccc4)cc3)c3ccc4oc5c6ccccc6c(-c6ccc7ccccc7c6)cc5c4c3)cc21 ; CC1(C)c2ccccc2-c2ccc(N(c3ccc(-c4ccccc4)cc3)c3ccc4oc5c6ccccc6c(-c6cccc(-c7ccccc7)c6)cc5c4c3)cc21] 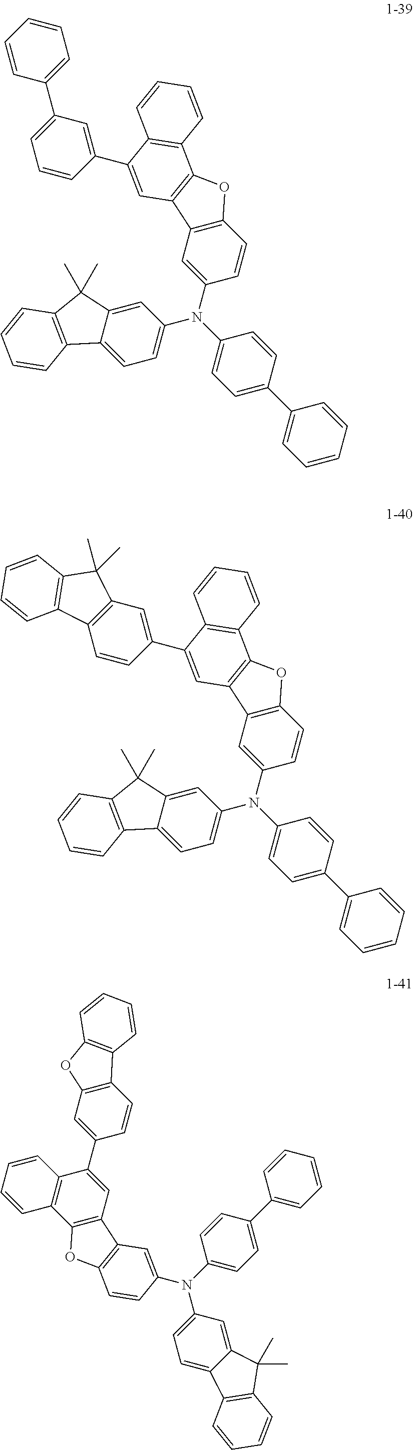 [SMILES: CC1(C)c2ccccc2-c2ccc(N(c3ccc(-c4ccccc4)cc3)c3ccc4oc5c6ccccc6c(-c6cccc(-c7ccccc7)c6)cc5c4c3)cc21 ; CC1(C)c2ccccc2-c2ccc(-c3cc4c5cc(N(c6ccc(-c7ccccc7)cc6)c6ccc7c(c6)C(C)(C)c6ccccc6-7)ccc5oc4c4ccccc34)cc21 ; CC1(C)c2ccccc2-c2ccc(N(c3ccc(-c4ccccc4)cc3)c3ccc4oc5c6ccccc6c(-c6ccc7c(c6)oc6ccccc67)cc5c4c3)cc21] 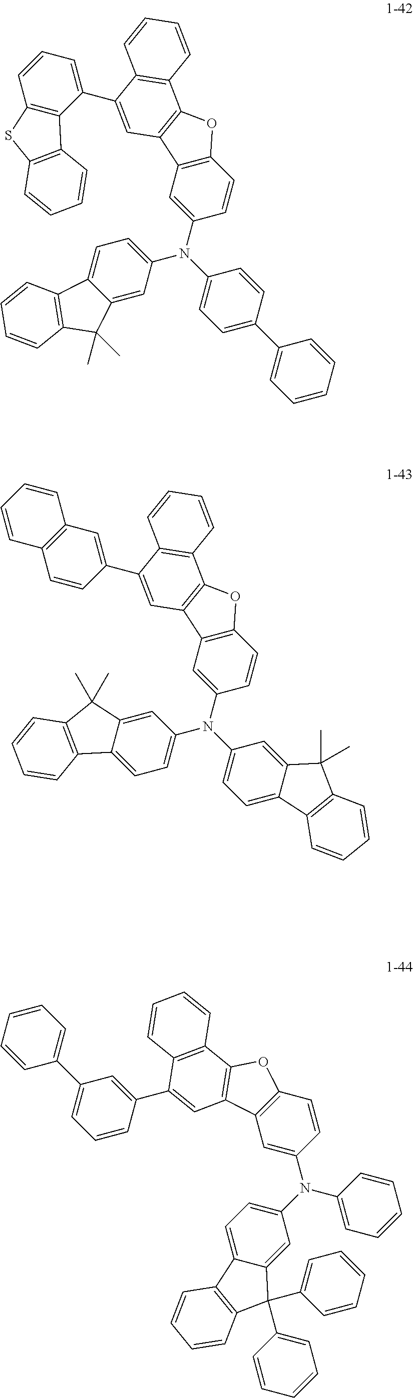 [SMILES: CC1(C)c2ccccc2-c2ccc(N(c3ccc(-c4ccccc4)cc3)c3ccc4oc5c6ccccc6c(-c6cccc7sc8ccccc8c67)cc5c4c3)cc21 ; CC1(C)c2ccccc2-c2ccc(N(c3ccc4c(c3)C(C)(C)c3ccccc3-4)c3ccc4oc5c6ccccc6c(-c6ccc7ccccc7c6)cc5c4c3)cc21 ; c1ccc(-c2cccc(-c3cc4c5cc(N(c6ccccc6)c6ccc7c(c6)C(c6ccccc6)(c6ccccc6)c6ccccc6-7)ccc5oc4c4ccccc34)c2)cc1] 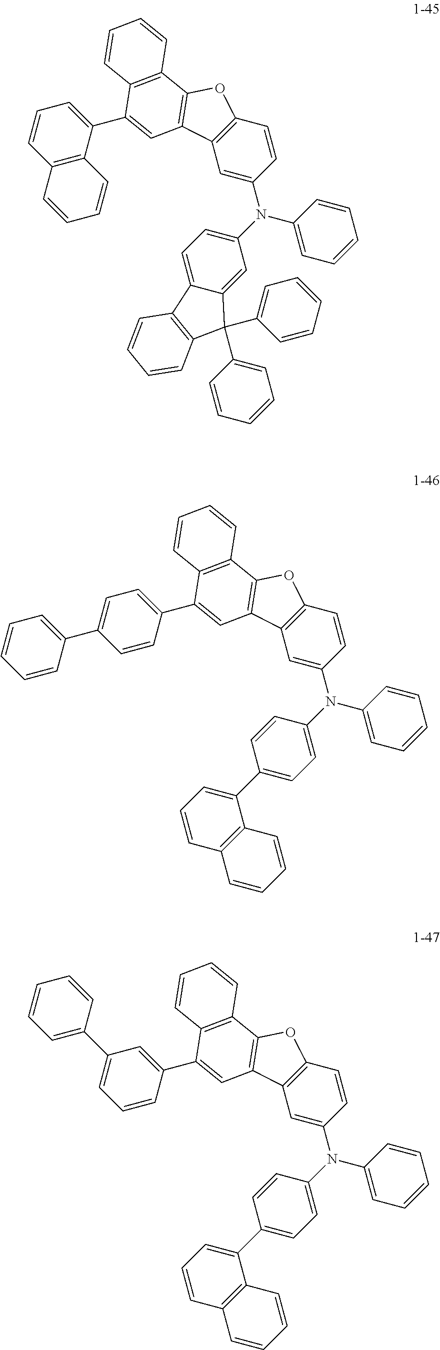 [SMILES: c1ccc(N(c2ccc3c(c2)C(c2ccccc2)(c2ccccc2)c2ccccc2-3)c2ccc3oc4c5ccccc5c(-c5cccc6ccccc56)cc4c3c2)cc1 ; c1ccc(-c2ccc(-c3cc4c5cc(N(c6ccccc6)c6ccc(-c7cccc8ccccc78)cc6)ccc5oc4c4ccccc34)cc2)cc1 ; c1ccc(-c2cccc(-c3cc4c5cc(N(c6ccccc6)c6ccc(-c7cccc8ccccc78)cc6)ccc5oc4c4ccccc34)c2)cc1] 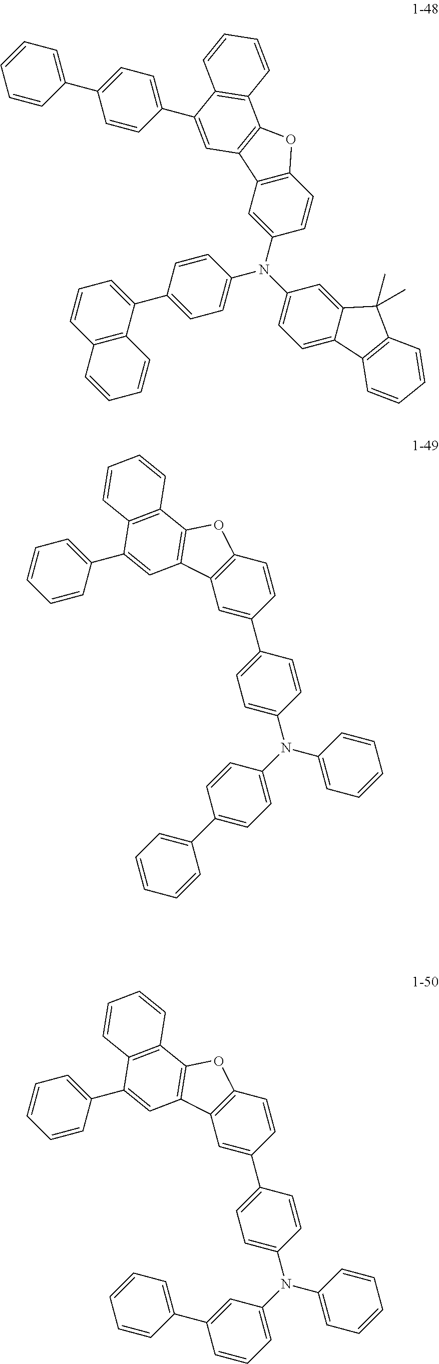 [SMILES: CC1(C)c2ccccc2-c2ccc(N(c3ccc(-c4cccc5ccccc45)cc3)c3ccc4oc5c6ccccc6c(-c6ccc(-c7ccccc7)cc6)cc5c4c3)cc21 ; c1ccc(-c2ccc(N(c3ccccc3)c3ccc(-c4ccc5oc6c7ccccc7c(-c7ccccc7)cc6c5c4)cc3)cc2)cc1 ; c1ccc(-c2cccc(N(c3ccccc3)c3ccc(-c4ccc5oc6c7ccccc7c(-c7ccccc7)cc6c5c4)cc3)c2)cc1] 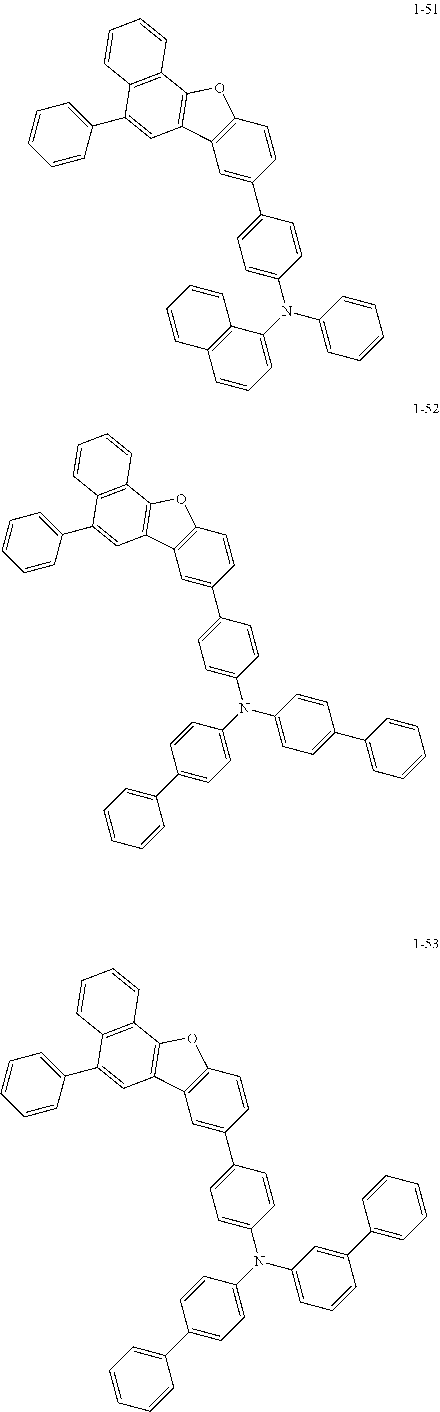 [SMILES: c1ccc(-c2cc3c4cc(-c5ccc(N(c6ccccc6)c6cccc7ccccc67)cc5)ccc4oc3c3ccccc23)cc1 ; c1ccc(-c2ccc(N(c3ccc(-c4ccccc4)cc3)c3ccc(-c4ccc5oc6c7ccccc7c(-c7ccccc7)cc6c5c4)cc3)cc2)cc1 ; c1ccc(-c2ccc(N(c3ccc(-c4ccc5oc6c7ccccc7c(-c7ccccc7)cc6c5c4)cc3)c3cccc(-c4ccccc4)c3)cc2)cc1] 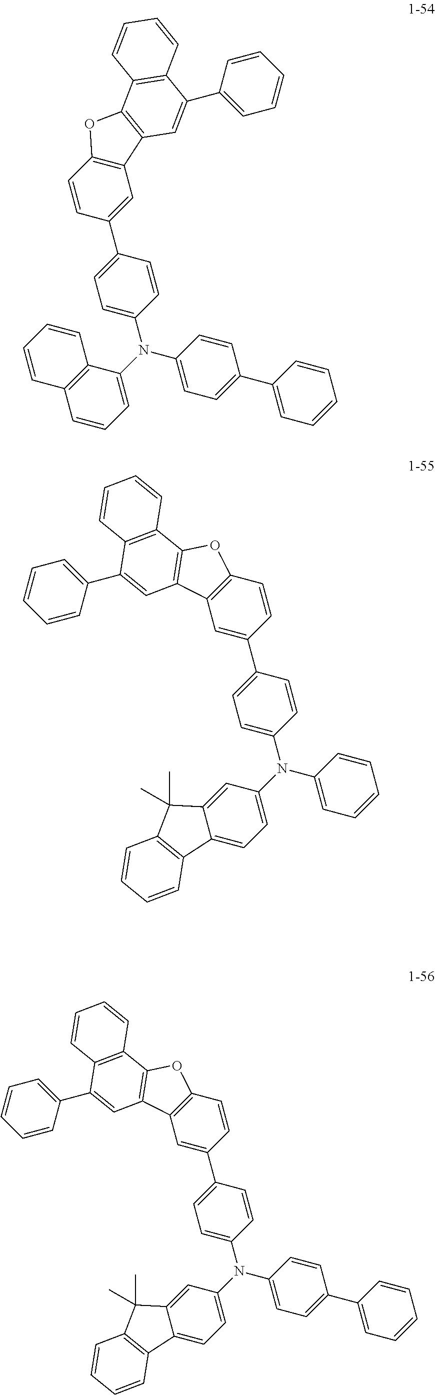 [SMILES: c1ccc(-c2ccc(N(c3ccc(-c4ccc5oc6c7ccccc7c(-c7ccccc7)cc6c5c4)cc3)c3cccc4ccccc34)cc2)cc1 ; CC1(C)c2ccccc2-c2ccc(N(c3ccccc3)c3ccc(-c4ccc5oc6c7ccccc7c(-c7ccccc7)cc6c5c4)cc3)cc21 ; CC1(C)c2ccccc2-c2ccc(N(c3ccc(-c4ccccc4)cc3)c3ccc(-c4ccc5oc6c7ccccc7c(-c7ccccc7)cc6c5c4)cc3)cc21] 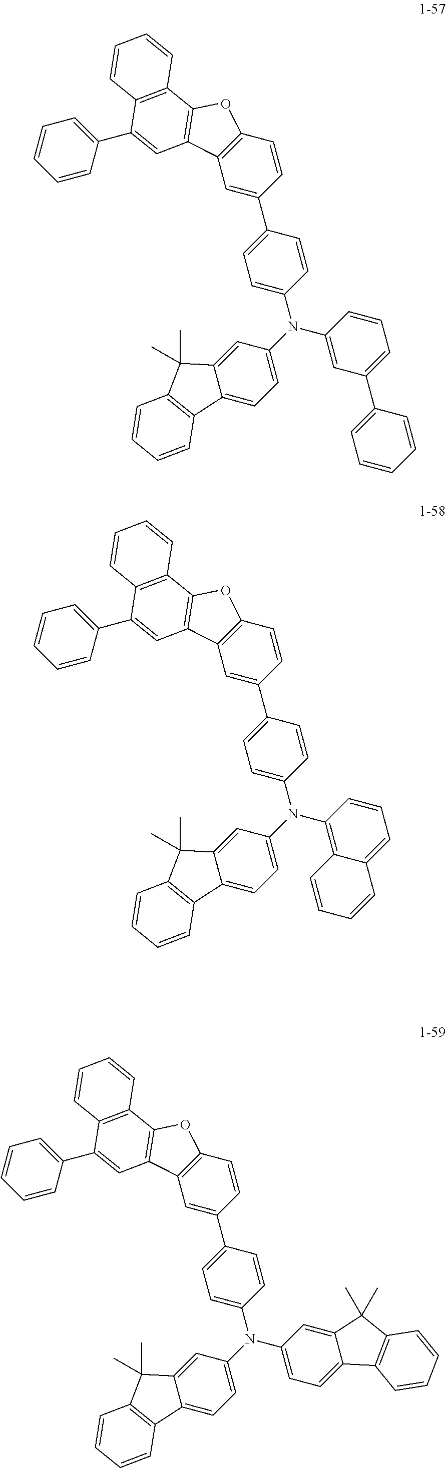 [SMILES: CC1(C)c2ccccc2-c2ccc(N(c3ccc(-c4ccc5oc6c7ccccc7c(-c7ccccc7)cc6c5c4)cc3)c3cccc(-c4ccccc4)c3)cc21 ; CC1(C)c2ccccc2-c2ccc(N(c3ccc(-c4ccc5oc6c7ccccc7c(-c7ccccc7)cc6c5c4)cc3)c3cccc4ccccc34)cc21 ; CC1(C)c2ccccc2-c2ccc(N(c3ccc(-c4ccc5oc6c7ccccc7c(-c7ccccc7)cc6c5c4)cc3)c3ccc4c(c3)C(C)(C)c3ccccc3-4)cc21] 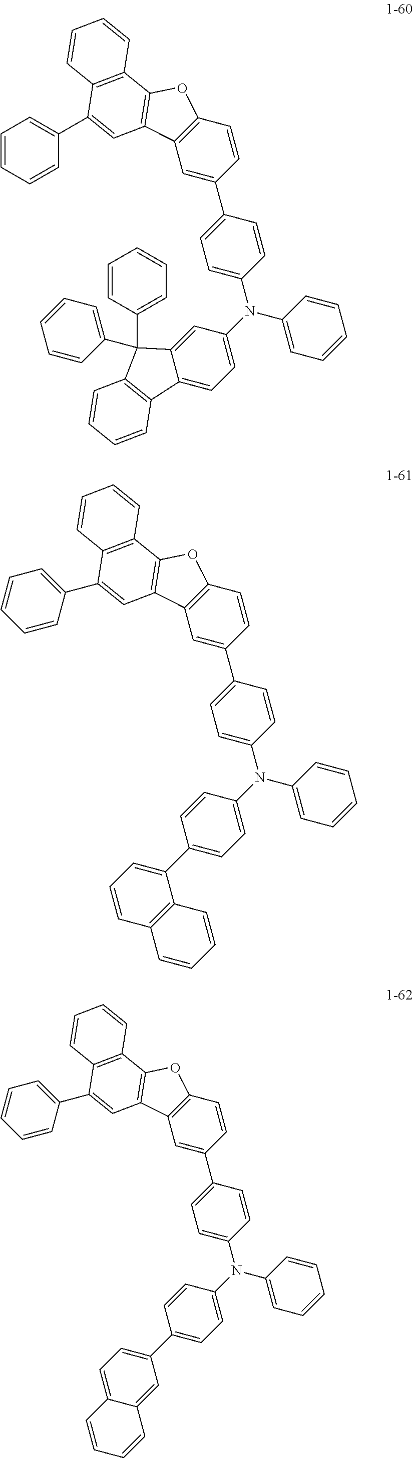 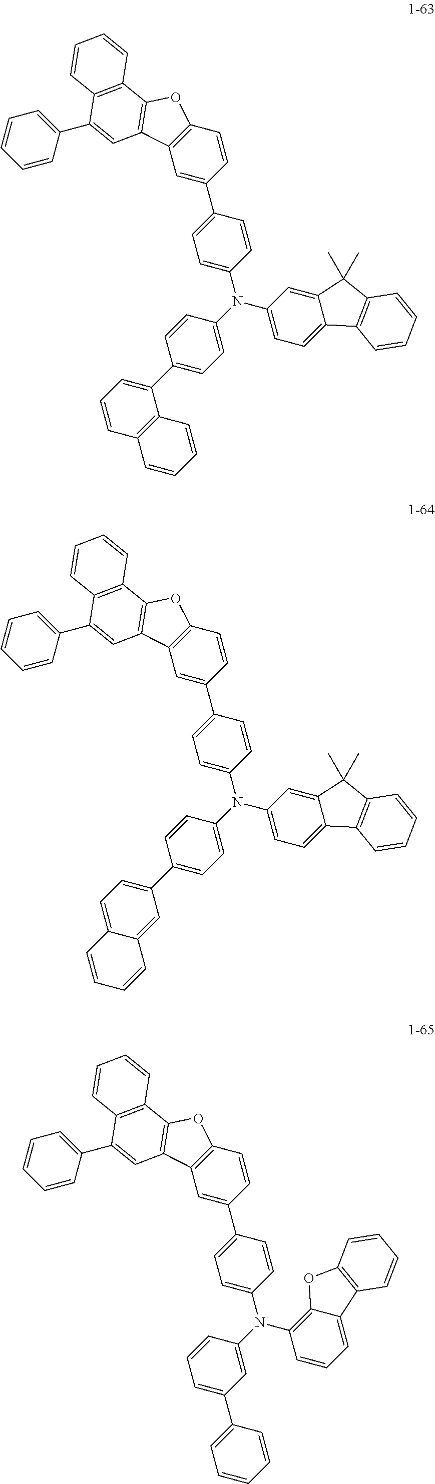 [SMILES: CC1(C)c2ccccc2-c2ccc(N(c3ccc(-c4ccc5oc6c7ccccc7c(-c7ccccc7)cc6c5c4)cc3)c3ccc(-c4cccc5ccccc45)cc3)cc21 ; CC1(C)c2ccccc2-c2ccc(N(c3ccc(-c4ccc5ccccc5c4)cc3)c3ccc(-c4ccc5oc6c7ccccc7c(-c7ccccc7)cc6c5c4)cc3)cc21 ; c1ccc(-c2cccc(N(c3ccc(-c4ccc5oc6c7ccccc7c(-c7ccccc7)cc6c5c4)cc3)c3cccc4c3oc3ccccc34)c2)cc1] 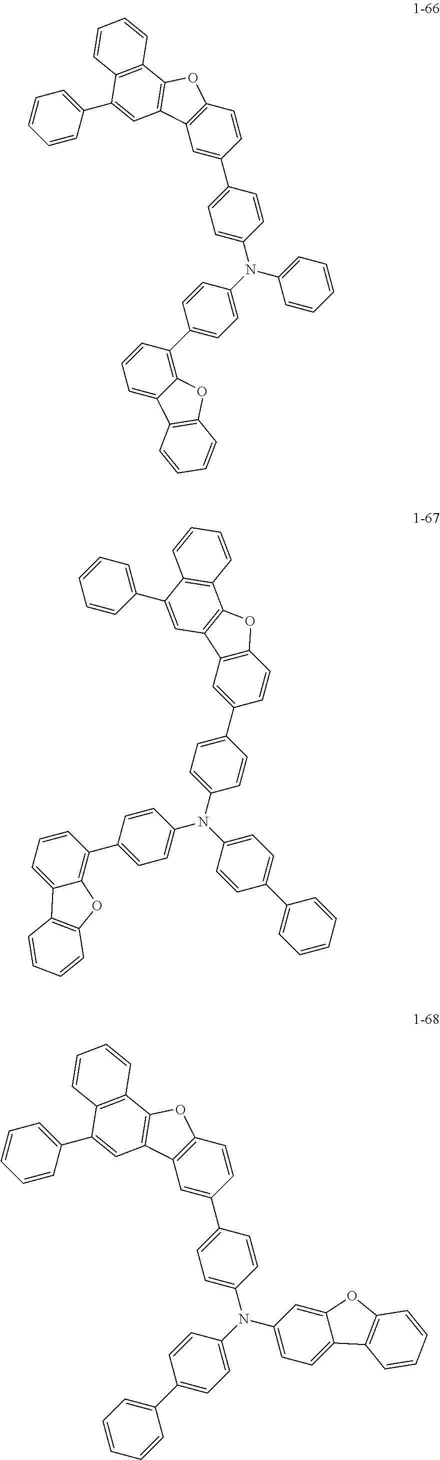 [SMILES: c1ccc(-c2cc3c4cc(-c5ccc(N(c6ccccc6)c6ccc(-c7cccc8c7oc7ccccc78)cc6)cc5)ccc4oc3c3ccccc23)cc1 ; c1ccc(-c2ccc(N(c3ccc(-c4ccc5oc6c7ccccc7c(-c7ccccc7)cc6c5c4)cc3)c3ccc(-c4cccc5c4oc4ccccc45)cc3)cc2)cc1 ; c1ccc(-c2ccc(N(c3ccc(-c4ccc5oc6c7ccccc7c(-c7ccccc7)cc6c5c4)cc3)c3ccc4c(c3)oc3ccccc34)cc2)cc1] 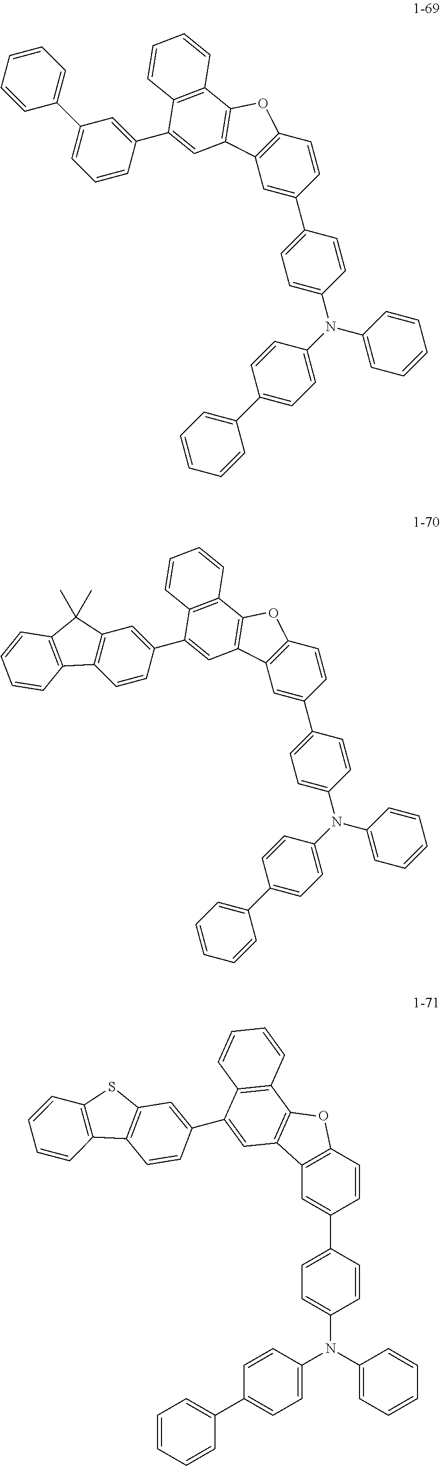 [SMILES: c1ccc(-c2ccc(N(c3ccccc3)c3ccc(-c4ccc5oc6c7ccccc7c(-c7cccc(-c8ccccc8)c7)cc6c5c4)cc3)cc2)cc1 ; CC1(C)c2ccccc2-c2ccc(-c3cc4c5cc(-c6ccc(N(c7ccccc7)c7ccc(-c8ccccc8)cc7)cc6)ccc5oc4c4ccccc34)cc21 ; c1ccc(-c2ccc(N(c3ccccc3)c3ccc(-c4ccc5oc6c7ccccc7c(-c7ccc8c(c7)sc7ccccc78)cc6c5c4)cc3)cc2)cc1] 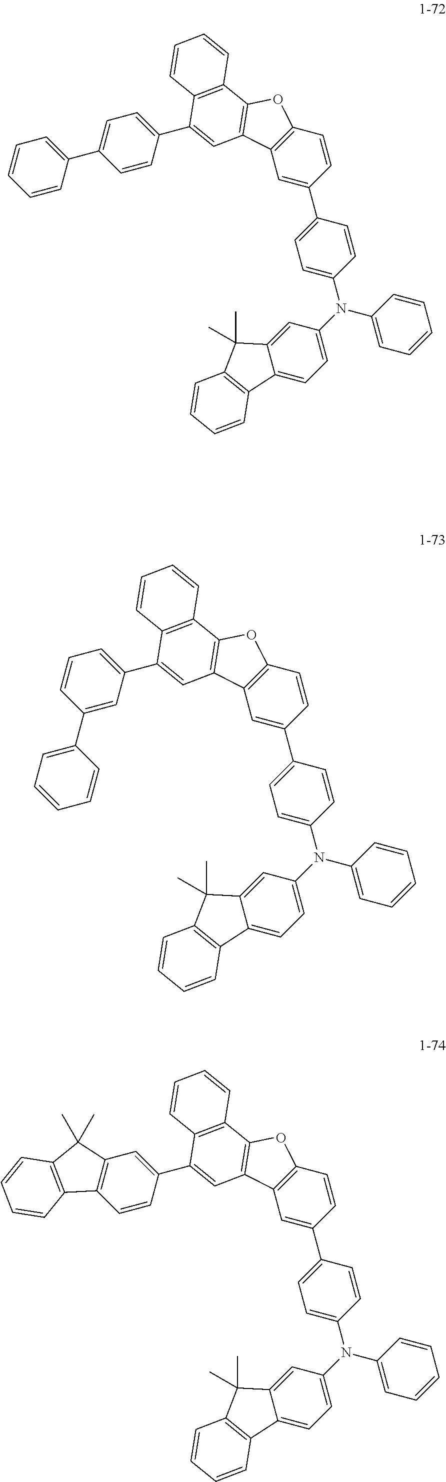 [SMILES: CC1(C)c2ccccc2-c2ccc(N(c3ccccc3)c3ccc(-c4ccc5oc6c7ccccc7c(-c7ccc(-c8ccccc8)cc7)cc6c5c4)cc3)cc21 ; CC1(C)c2ccccc2-c2ccc(N(c3ccccc3)c3ccc(-c4ccc5oc6c7ccccc7c(-c7cccc(-c8ccccc8)c7)cc6c5c4)cc3)cc21 ; CC1(C)c2ccccc2-c2ccc(-c3cc4c5cc(-c6ccc(N(c7ccccc7)c7ccc8c(c7)C(C)(C)c7ccccc7-8)cc6)ccc5oc4c4ccccc34)cc21] 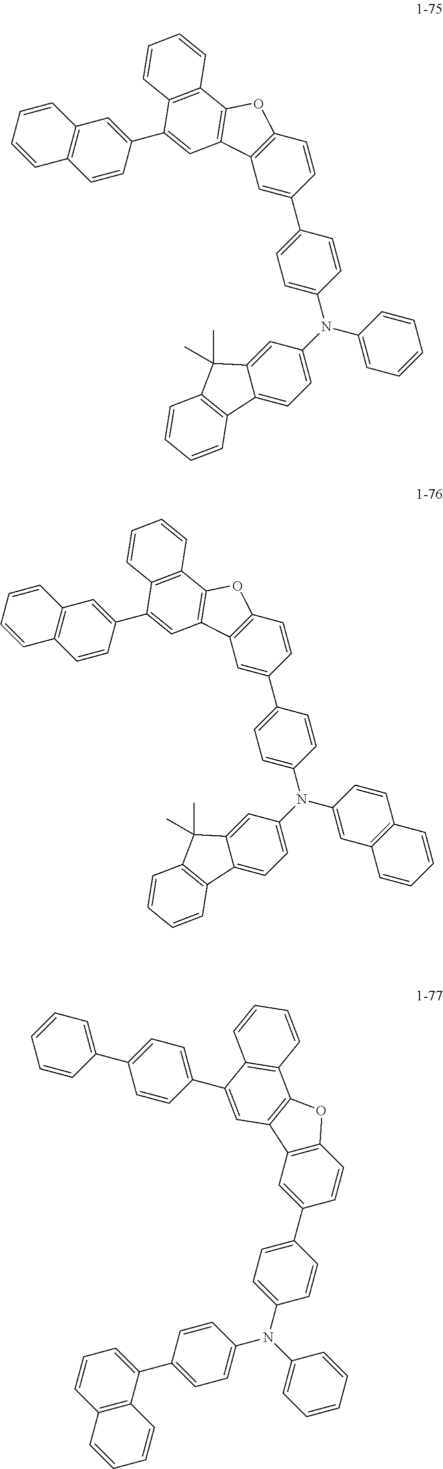 [SMILES: CC1(C)c2ccccc2-c2ccc(N(c3ccccc3)c3ccc(-c4ccc5oc6c7ccccc7c(-c7ccc8ccccc8c7)cc6c5c4)cc3)cc21 ; CC1(C)c2ccccc2-c2ccc(N(c3ccc(-c4ccc5oc6c7ccccc7c(-c7ccc8ccccc8c7)cc6c5c4)cc3)c3ccc4ccccc4c3)cc21 ; c1ccc(-c2ccc(-c3cc4c5cc(-c6ccc(N(c7ccccc7)c7ccc(-c8cccc9ccccc89)cc7)cc6)ccc5oc4c4ccccc34)cc2)cc1] 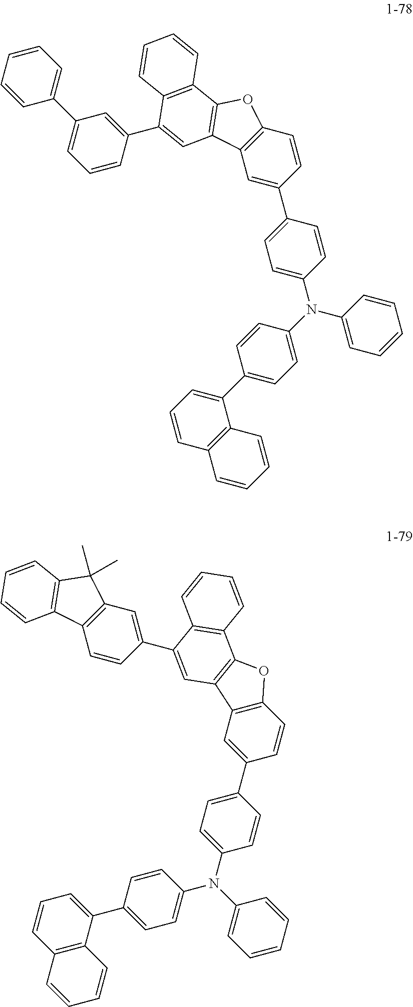 [SMILES: c1ccc(-c2cccc(-c3cc4c5cc(-c6ccc(N(c7ccccc7)c7ccc(-c8cccc9ccccc89)cc7)cc6)ccc5oc4c4ccccc34)c2)cc1 ; CC1(C)c2ccccc2-c2ccc(-c3cc4c5cc(-c6ccc(N(c7ccccc7)c7ccc(-c8cccc9ccccc89)cc7)cc6)ccc5oc4c4ccccc34)cc21] 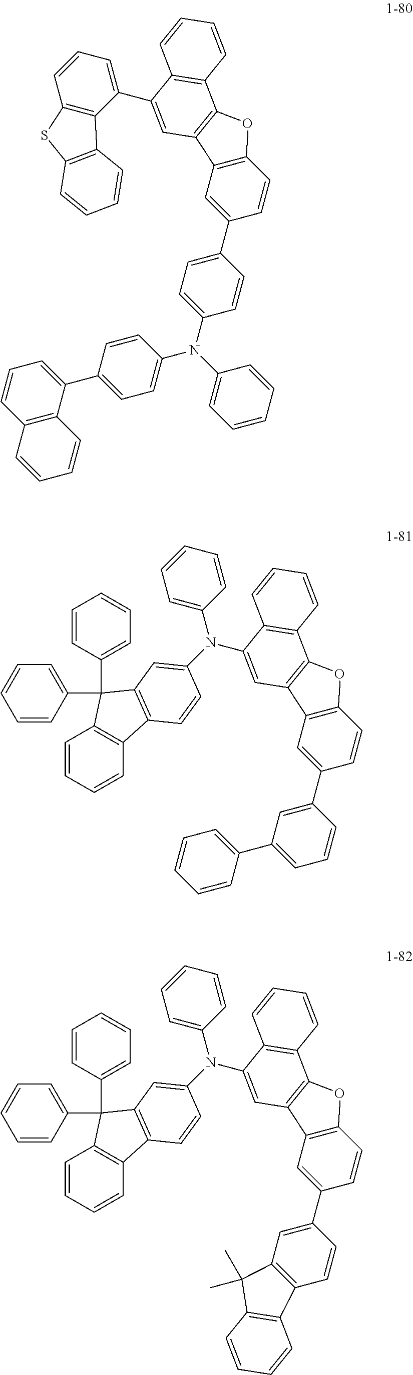 [SMILES: c1ccc(N(c2ccc(-c3ccc4oc5c6ccccc6c(-c6cccc7sc8ccccc8c67)cc5c4c3)cc2)c2ccc(-c3cccc4ccccc34)cc2)cc1 ; c1ccc(-c2cccc(-c3ccc4oc5c6ccccc6c(N(c6ccccc6)c6ccc7c(c6)C(c6ccccc6)(c6ccccc6)c6ccccc6-7)cc5c4c3)c2)cc1 ; CC1(C)c2ccccc2-c2ccc(-c3ccc4oc5c6ccccc6c(N(c6ccccc6)c6ccc7c(c6)C(c6ccccc6)(c6ccccc6)c6ccccc6-7)cc5c4c3)cc21] 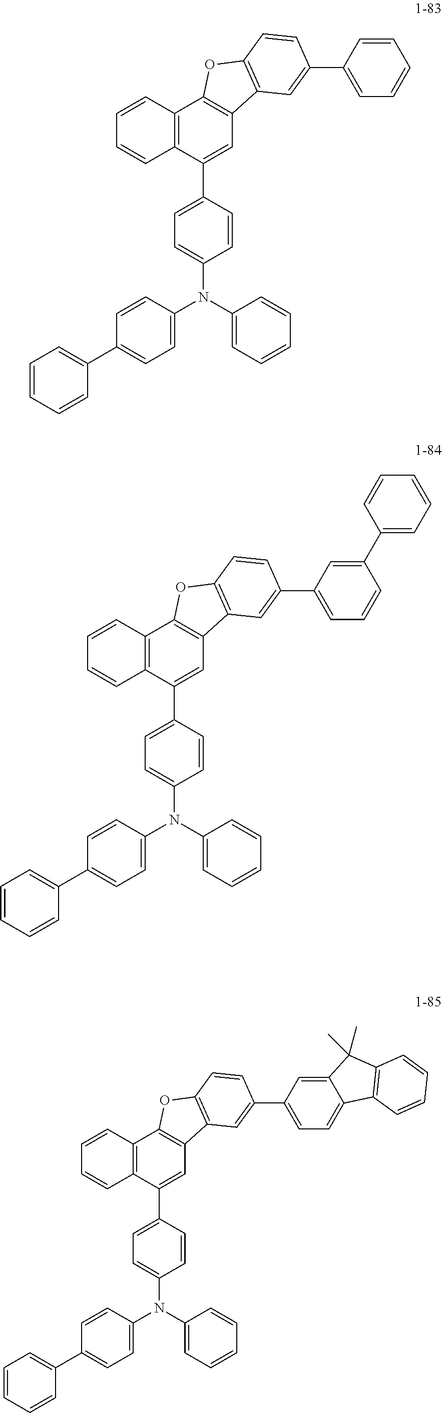 [SMILES: c1ccc(-c2ccc(N(c3ccccc3)c3ccc(-c4cc5c6cc(-c7ccccc7)ccc6oc5c5ccccc45)cc3)cc2)cc1 ; c1ccc(-c2ccc(N(c3ccccc3)c3ccc(-c4cc5c6cc(-c7cccc(-c8ccccc8)c7)ccc6oc5c5ccccc45)cc3)cc2)cc1 ; CC1(C)c2ccccc2-c2ccc(-c3ccc4oc5c6ccccc6c(-c6ccc(N(c7ccccc7)c7ccc(-c8ccccc8)cc7)cc6)cc5c4c3)cc21] 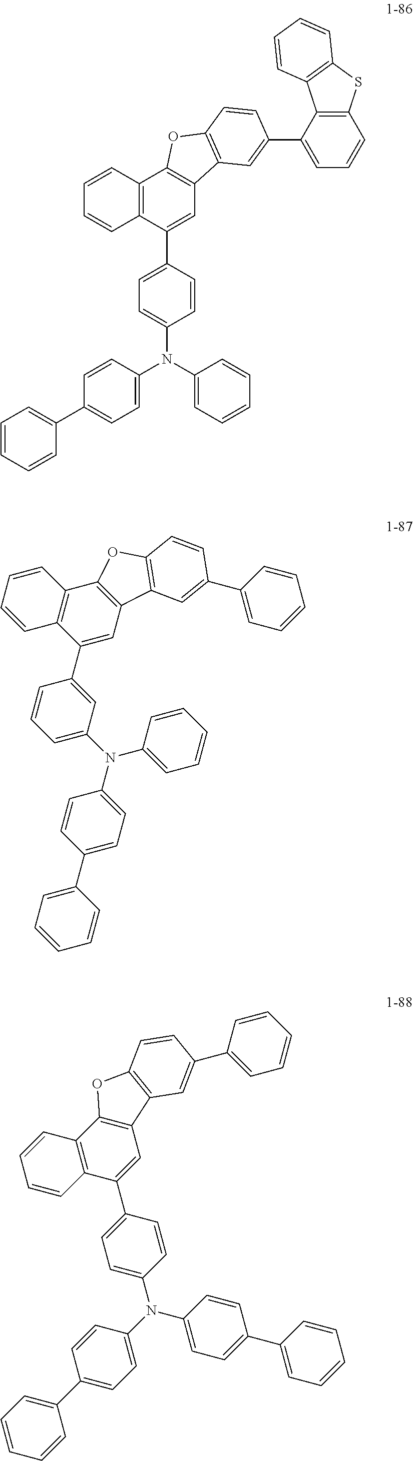 [SMILES: c1ccc(-c2ccc(N(c3ccccc3)c3ccc(-c4cc5c6cc(-c7cccc8sc9ccccc9c78)ccc6oc5c5ccccc45)cc3)cc2)cc1 ; c1ccc(-c2ccc(N(c3ccccc3)c3cccc(-c4cc5c6cc(-c7ccccc7)ccc6oc5c5ccccc45)c3)cc2)cc1 ; c1ccc(-c2ccc(N(c3ccc(-c4ccccc4)cc3)c3ccc(-c4cc5c6cc(-c7ccccc7)ccc6oc5c5ccccc45)cc3)cc2)cc1] 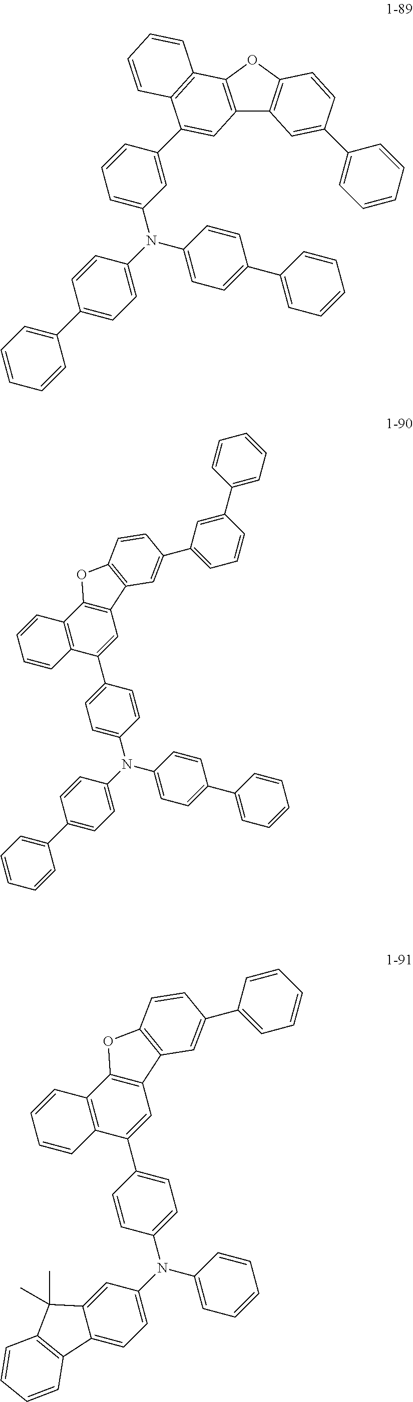 [SMILES: c1ccc(-c2ccc(N(c3ccc(-c4ccccc4)cc3)c3cccc(-c4cc5c6cc(-c7ccccc7)ccc6oc5c5ccccc45)c3)cc2)cc1 ; c1ccc(-c2ccc(N(c3ccc(-c4ccccc4)cc3)c3ccc(-c4cc5c6cc(-c7cccc(-c8ccccc8)c7)ccc6oc5c5ccccc45)cc3)cc2)cc1 ; CC1(C)c2ccccc2-c2ccc(N(c3ccccc3)c3ccc(-c4cc5c6cc(-c7ccccc7)ccc6oc5c5ccccc45)cc3)cc21] 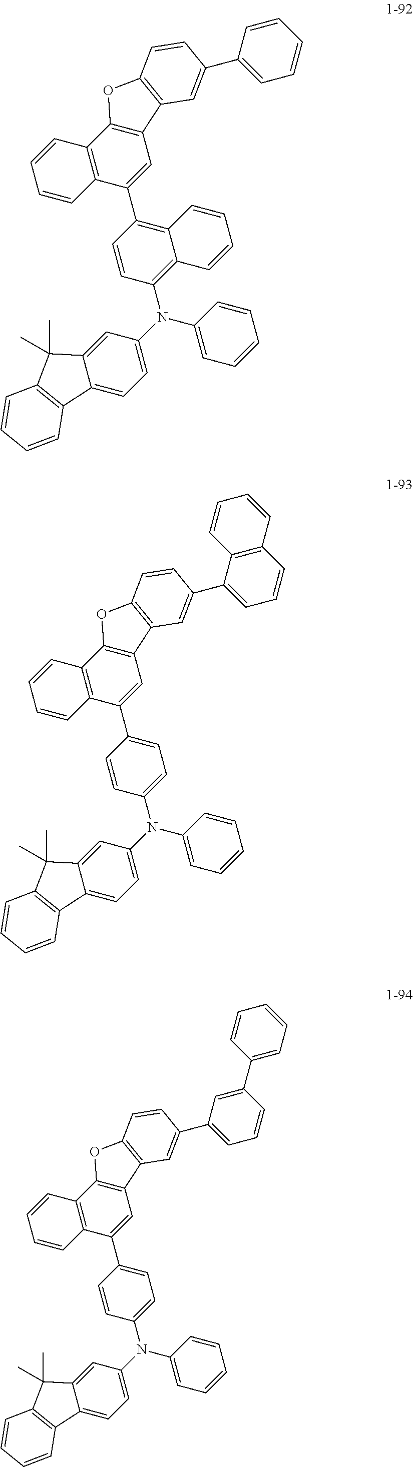 [SMILES: CC1(C)c2ccccc2-c2ccc(N(c3ccccc3)c3ccc(-c4cc5c6cc(-c7ccccc7)ccc6oc5c5ccccc45)c4ccccc34)cc21 ; CC1(C)c2ccccc2-c2ccc(N(c3ccccc3)c3ccc(-c4cc5c6cc(-c7cccc8ccccc78)ccc6oc5c5ccccc45)cc3)cc21 ; CC1(C)c2ccccc2-c2ccc(N(c3ccccc3)c3ccc(-c4cc5c6cc(-c7cccc(-c8ccccc8)c7)ccc6oc5c5ccccc45)cc3)cc21] 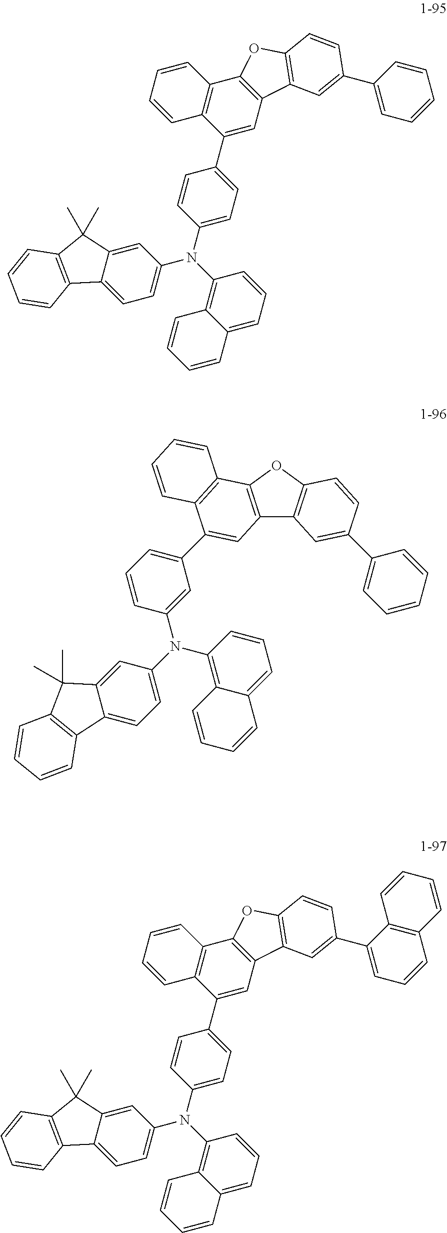 [SMILES: CC1(C)c2ccccc2-c2ccc(N(c3ccc(-c4cc5c6cc(-c7ccccc7)ccc6oc5c5ccccc45)cc3)c3cccc4ccccc34)cc21 ; CC1(C)c2ccccc2-c2ccc(N(c3cccc(-c4cc5c6cc(-c7ccccc7)ccc6oc5c5ccccc45)c3)c3cccc4ccccc34)cc21 ; CC1(C)c2ccccc2-c2ccc(N(c3ccc(-c4cc5c6cc(-c7cccc8ccccc78)ccc6oc5c5ccccc45)cc3)c3cccc4ccccc34)cc21] 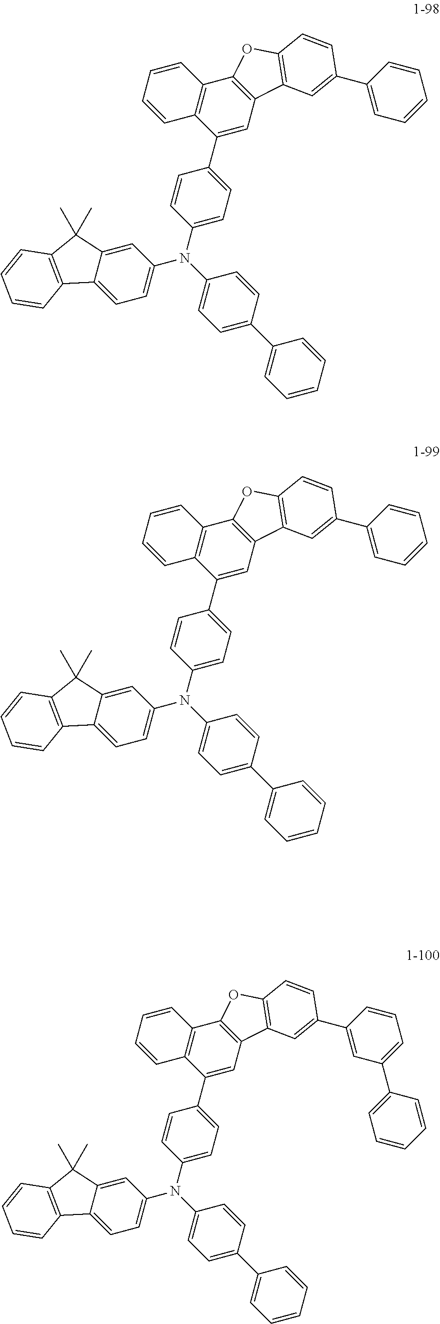 [SMILES: CC1(C)c2ccccc2-c2ccc(N(c3ccc(-c4ccccc4)cc3)c3ccc(-c4cc5c6cc(-c7ccccc7)ccc6oc5c5ccccc45)cc3)cc21 ; CC1(C)c2ccccc2-c2ccc(N(c3ccc(-c4ccccc4)cc3)c3ccc(-c4cc5c6cc(-c7ccccc7)ccc6oc5c5ccccc45)cc3)cc21 ; CC1(C)c2ccccc2-c2ccc(N(c3ccc(-c4ccccc4)cc3)c3ccc(-c4cc5c6cc(-c7cccc(-c8ccccc8)c7)ccc6oc5c5ccccc45)cc3)cc21] 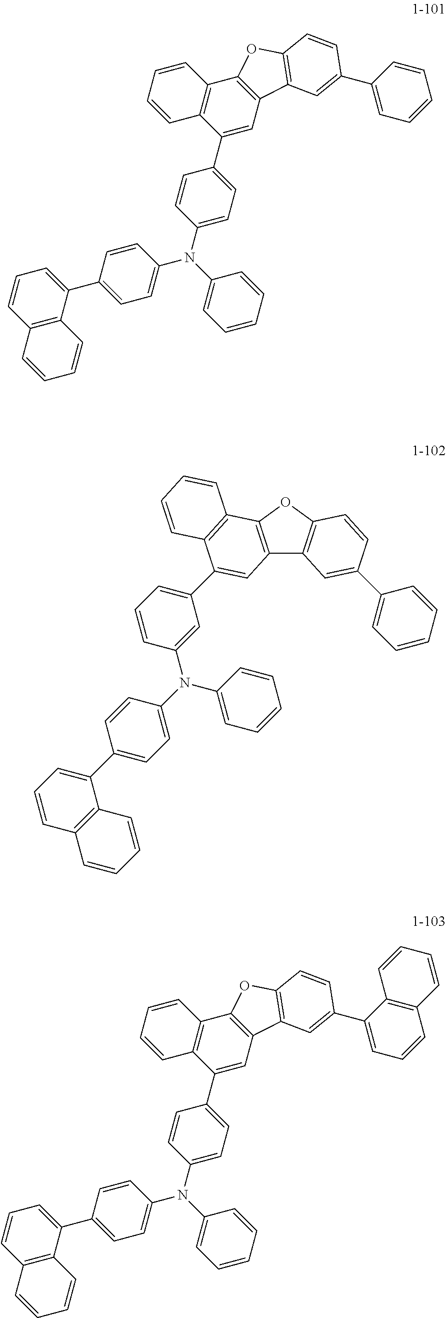 [SMILES: c1ccc(-c2ccc3oc4c5ccccc5c(-c5ccc(N(c6ccccc6)c6ccc(-c7cccc8ccccc78)cc6)cc5)cc4c3c2)cc1 ; c1ccc(-c2ccc3oc4c5ccccc5c(-c5cccc(N(c6ccccc6)c6ccc(-c7cccc8ccccc78)cc6)c5)cc4c3c2)cc1 ; c1ccc(N(c2ccc(-c3cccc4ccccc34)cc2)c2ccc(-c3cc4c5cc(-c6cccc7ccccc67)ccc5oc4c4ccccc34)cc2)cc1] 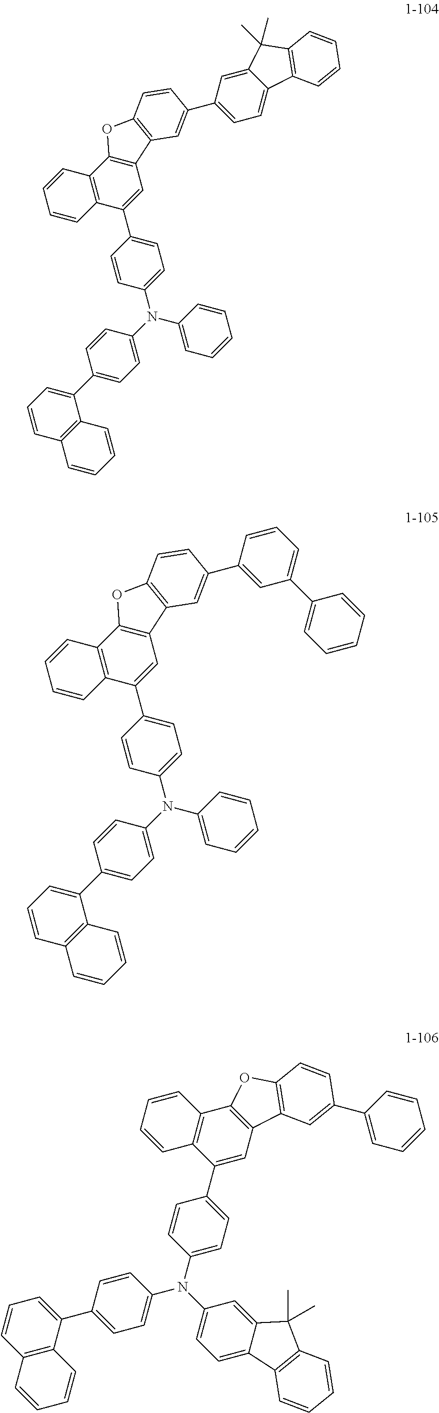 [SMILES: CC1(C)c2ccccc2-c2ccc(-c3ccc4oc5c6ccccc6c(-c6ccc(N(c7ccccc7)c7ccc(-c8cccc9ccccc89)cc7)cc6)cc5c4c3)cc21 ; c1ccc(-c2cccc(-c3ccc4oc5c6ccccc6c(-c6ccc(N(c7ccccc7)c7ccc(-c8cccc9ccccc89)cc7)cc6)cc5c4c3)c2)cc1 ; CC1(C)c2ccccc2-c2ccc(N(c3ccc(-c4cccc5ccccc45)cc3)c3ccc(-c4cc5c6cc(-c7ccccc7)ccc6oc5c5ccccc45)cc3)cc21] 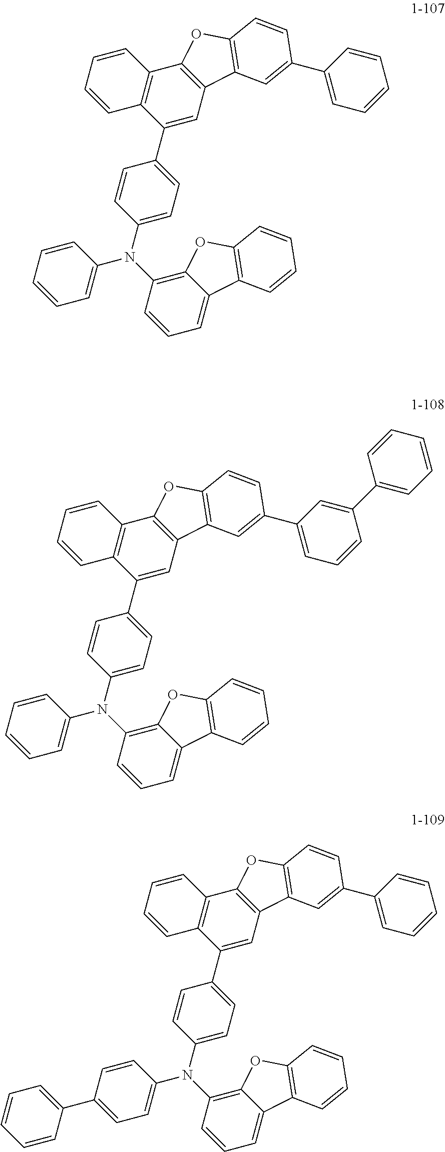 [SMILES: c1ccc(-c2ccc3oc4c5ccccc5c(-c5ccc(N(c6ccccc6)c6cccc7c6oc6ccccc67)cc5)cc4c3c2)cc1 ; c1ccc(-c2cccc(-c3ccc4oc5c6ccccc6c(-c6ccc(N(c7ccccc7)c7cccc8c7oc7ccccc78)cc6)cc5c4c3)c2)cc1 ; c1ccc(-c2ccc(N(c3ccc(-c4cc5c6cc(-c7ccccc7)ccc6oc5c5ccccc45)cc3)c3cccc4c3oc3ccccc34)cc2)cc1] 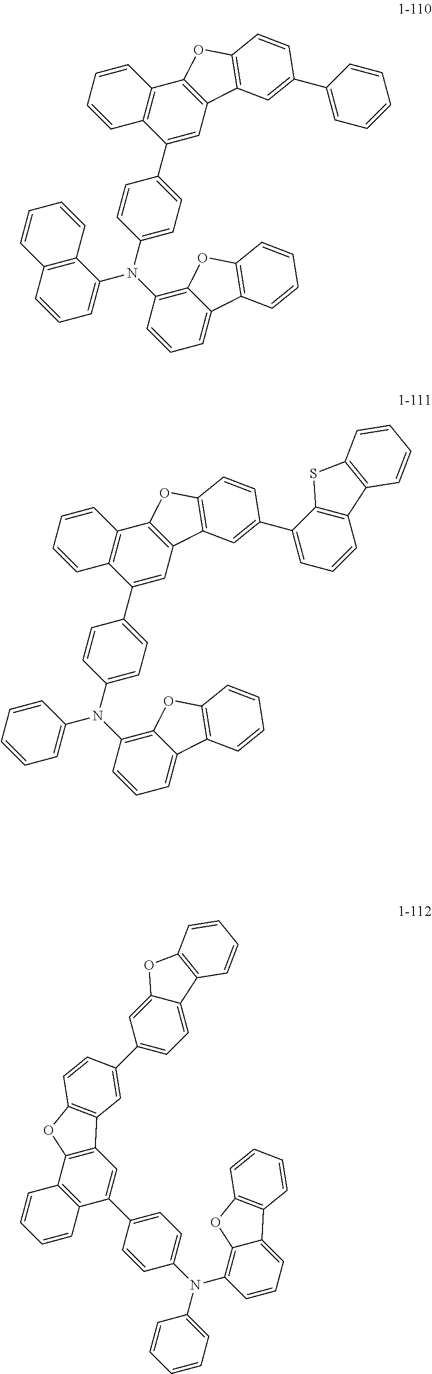 [SMILES: c1ccc(-c2ccc3oc4c5ccccc5c(-c5ccc(N(c6cccc7ccccc67)c6cccc7c6oc6ccccc67)cc5)cc4c3c2)cc1 ; c1ccc(N(c2ccc(-c3cc4c5cc(-c6cccc7c6sc6ccccc67)ccc5oc4c4ccccc34)cc2)c2cccc3c2oc2ccccc23)cc1 ; c1ccc(N(c2ccc(-c3cc4c5cc(-c6ccc7c(c6)oc6ccccc67)ccc5oc4c4ccccc34)cc2)c2cccc3c2oc2ccccc23)cc1] 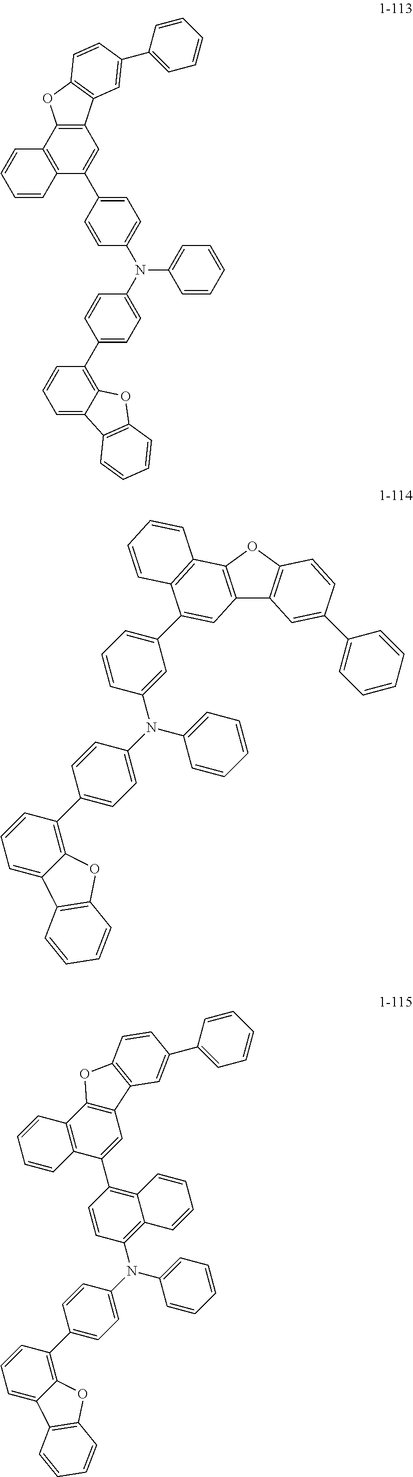 [SMILES: c1ccc(-c2ccc3oc4c5ccccc5c(-c5ccc(N(c6ccccc6)c6ccc(-c7cccc8c7oc7ccccc78)cc6)cc5)cc4c3c2)cc1 ; c1ccc(-c2ccc3oc4c5ccccc5c(-c5cccc(N(c6ccccc6)c6ccc(-c7cccc8c7oc7ccccc78)cc6)c5)cc4c3c2)cc1 ; c1ccc(-c2ccc3oc4c5ccccc5c(-c5ccc(N(c6ccccc6)c6ccc(-c7cccc8c7oc7ccccc78)cc6)c6ccccc56)cc4c3c2)cc1] 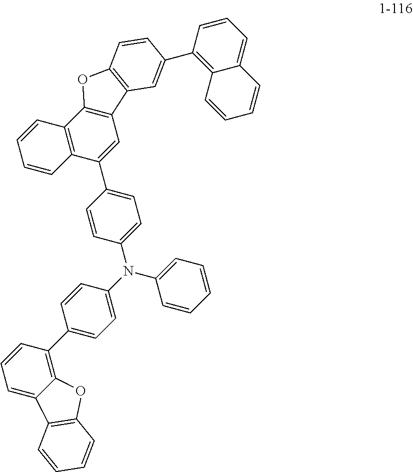 [SMILES: c1ccc(N(c2ccc(-c3cc4c5cc(-c6cccc7ccccc67)ccc5oc4c4ccccc34)cc2)c2ccc(-c3cccc4c3oc3ccccc34)cc2)cc1] 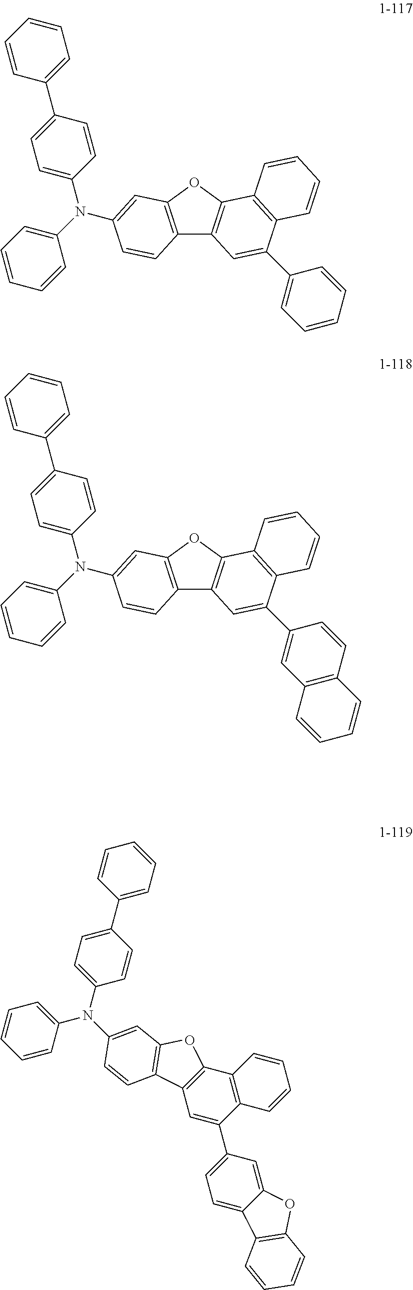 [SMILES: c1ccc(-c2ccc(N(c3ccccc3)c3ccc4c(c3)oc3c5ccccc5c(-c5ccccc5)cc43)cc2)cc1 ; c1ccc(-c2ccc(N(c3ccccc3)c3ccc4c(c3)oc3c5ccccc5c(-c5ccc6ccccc6c5)cc43)cc2)cc1 ; c1ccc(-c2ccc(N(c3ccccc3)c3ccc4c(c3)oc3c5ccccc5c(-c5ccc6c(c5)oc5ccccc56)cc43)cc2)cc1] 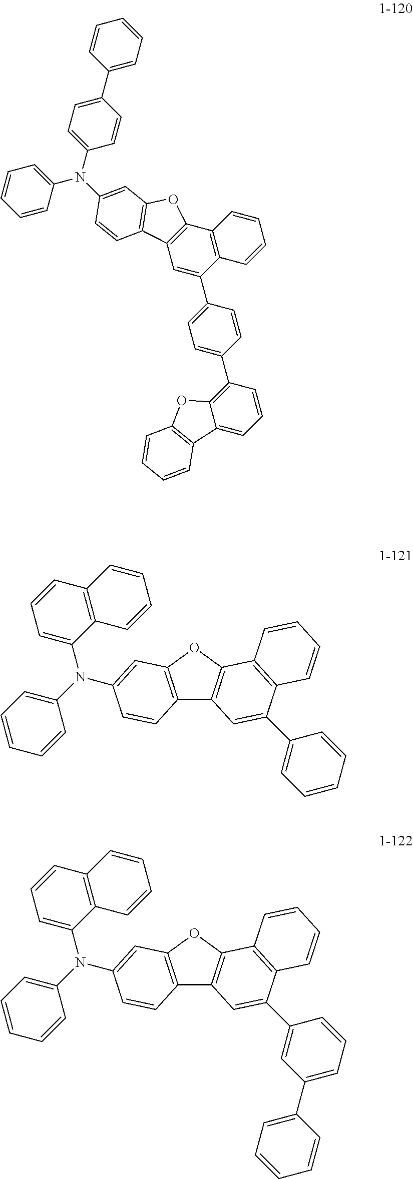 [SMILES: c1ccc(-c2ccc(N(c3ccccc3)c3ccc4c(c3)oc3c5ccccc5c(-c5ccc(-c6cccc7c6oc6ccccc67)cc5)cc43)cc2)cc1 ; c1ccc(-c2cc3c4ccc(N(c5ccccc5)c5cccc6ccccc56)cc4oc3c3ccccc23)cc1 ; c1ccc(-c2cccc(-c3cc4c5ccc(N(c6ccccc6)c6cccc7ccccc67)cc5oc4c4ccccc34)c2)cc1] 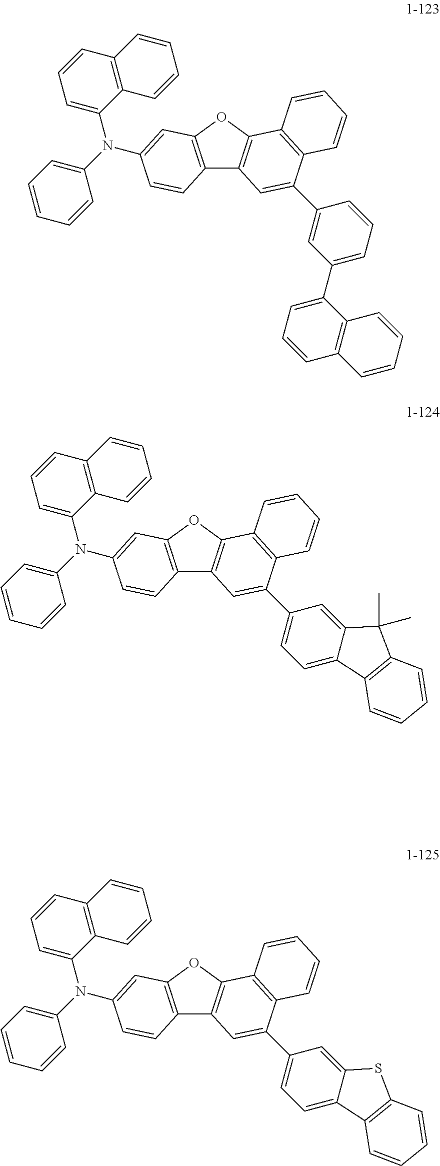 [SMILES: c1ccc(N(c2ccc3c(c2)oc2c4ccccc4c(-c4cccc(-c5cccc6ccccc56)c4)cc32)c2cccc3ccccc23)cc1 ; CC1(C)c2ccccc2-c2ccc(-c3cc4c5ccc(N(c6ccccc6)c6cccc7ccccc67)cc5oc4c4ccccc34)cc21 ; c1ccc(N(c2ccc3c(c2)oc2c4ccccc4c(-c4ccc5c(c4)sc4ccccc45)cc32)c2cccc3ccccc23)cc1] 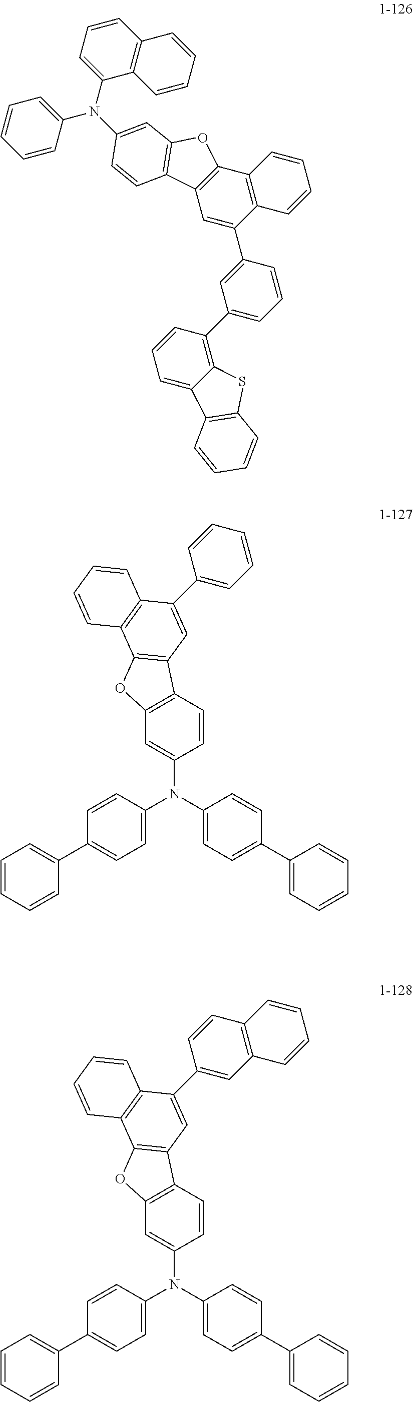 [SMILES: c1ccc(N(c2ccc3c(c2)oc2c4ccccc4c(-c4cccc(-c5cccc6c5sc5ccccc56)c4)cc32)c2cccc3ccccc23)cc1 ; c1ccc(-c2ccc(N(c3ccc(-c4ccccc4)cc3)c3ccc4c(c3)oc3c5ccccc5c(-c5ccccc5)cc43)cc2)cc1 ; c1ccc(-c2ccc(N(c3ccc(-c4ccccc4)cc3)c3ccc4c(c3)oc3c5ccccc5c(-c5ccc6ccccc6c5)cc43)cc2)cc1] 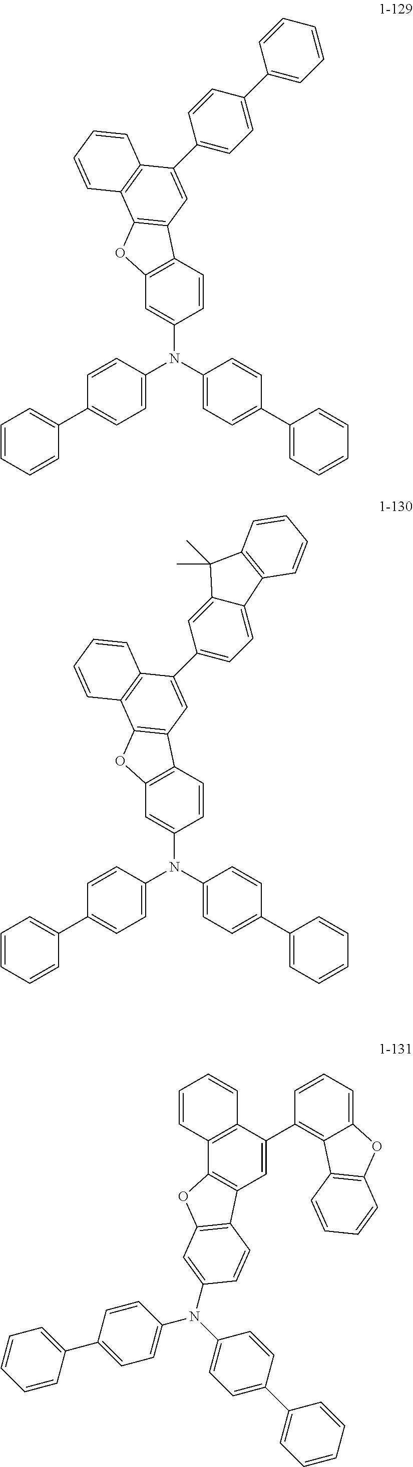 [SMILES: c1ccc(-c2ccc(-c3cc4c5ccc(N(c6ccc(-c7ccccc7)cc6)c6ccc(-c7ccccc7)cc6)cc5oc4c4ccccc34)cc2)cc1 ; CC1(C)c2ccccc2-c2ccc(-c3cc4c5ccc(N(c6ccc(-c7ccccc7)cc6)c6ccc(-c7ccccc7)cc6)cc5oc4c4ccccc34)cc21 ; c1ccc(-c2ccc(N(c3ccc(-c4ccccc4)cc3)c3ccc4c(c3)oc3c5ccccc5c(-c5cccc6oc7ccccc7c56)cc43)cc2)cc1] 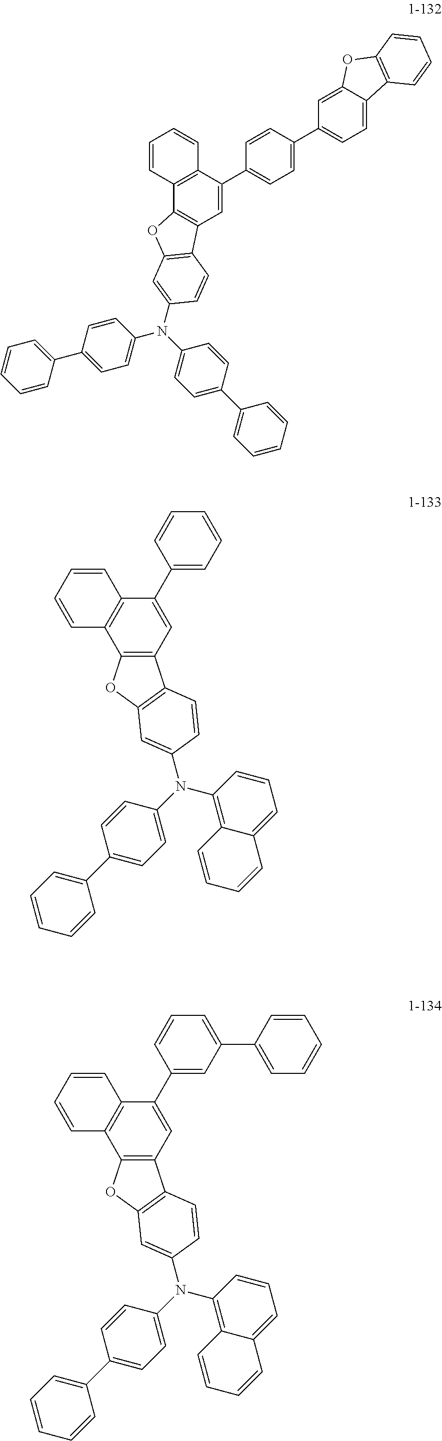 [SMILES: c1ccc(-c2ccc(N(c3ccc(-c4ccccc4)cc3)c3ccc4c(c3)oc3c5ccccc5c(-c5ccc(-c6ccc7c(c6)oc6ccccc67)cc5)cc43)cc2)cc1 ; c1ccc(-c2ccc(N(c3ccc4c(c3)oc3c5ccccc5c(-c5ccccc5)cc43)c3cccc4ccccc34)cc2)cc1 ; c1ccc(-c2ccc(N(c3ccc4c(c3)oc3c5ccccc5c(-c5cccc(-c6ccccc6)c5)cc43)c3cccc4ccccc34)cc2)cc1] 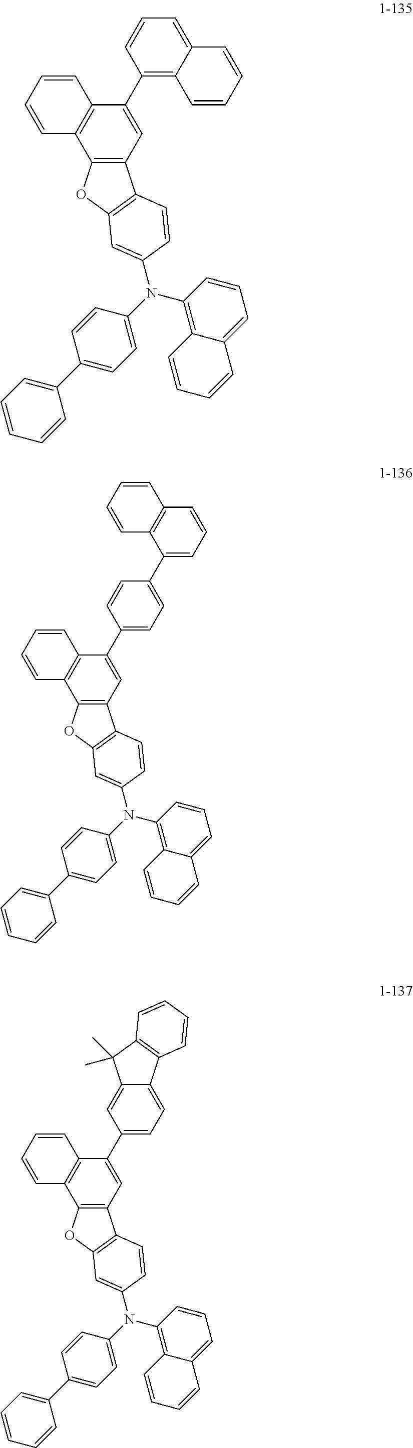 [SMILES: c1ccc(-c2ccc(N(c3ccc4c(c3)oc3c5ccccc5c(-c5cccc6ccccc56)cc43)c3cccc4ccccc34)cc2)cc1 ; c1ccc(-c2ccc(N(c3ccc4c(c3)oc3c5ccccc5c(-c5ccc(-c6cccc7ccccc67)cc5)cc43)c3cccc4ccccc34)cc2)cc1 ; CC1(C)c2ccccc2-c2ccc(-c3cc4c5ccc(N(c6ccc(-c7ccccc7)cc6)c6cccc7ccccc67)cc5oc4c4ccccc34)cc21] 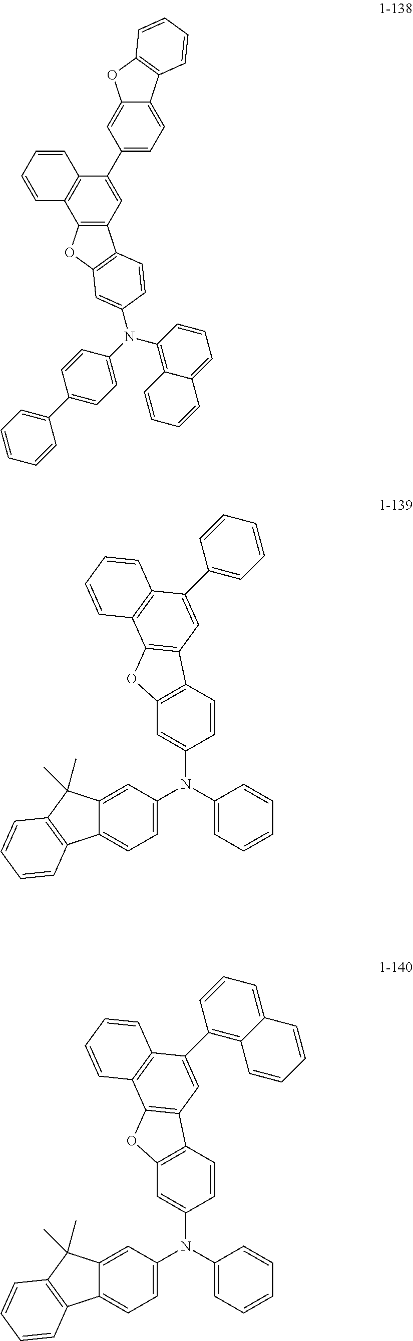 [SMILES: c1ccc(-c2ccc(N(c3ccc4c(c3)oc3c5ccccc5c(-c5ccc6c(c5)oc5ccccc56)cc43)c3cccc4ccccc34)cc2)cc1 ; CC1(C)c2ccccc2-c2ccc(N(c3ccccc3)c3ccc4c(c3)oc3c5ccccc5c(-c5ccccc5)cc43)cc21 ; CC1(C)c2ccccc2-c2ccc(N(c3ccccc3)c3ccc4c(c3)oc3c5ccccc5c(-c5cccc6ccccc56)cc43)cc21] 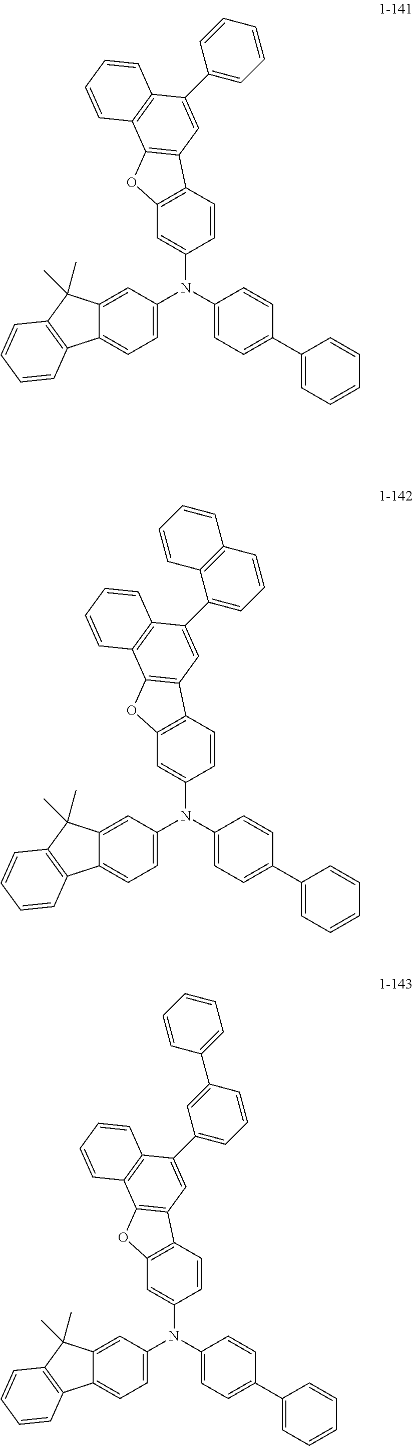 [SMILES: CC1(C)c2ccccc2-c2ccc(N(c3ccc(-c4ccccc4)cc3)c3ccc4c(c3)oc3c5ccccc5c(-c5ccccc5)cc43)cc21 ; CC1(C)c2ccccc2-c2ccc(N(c3ccc(-c4ccccc4)cc3)c3ccc4c(c3)oc3c5ccccc5c(-c5cccc6ccccc56)cc43)cc21 ; CC1(C)c2ccccc2-c2ccc(N(c3ccc(-c4ccccc4)cc3)c3ccc4c(c3)oc3c5ccccc5c(-c5cccc(-c6ccccc6)c5)cc43)cc21] 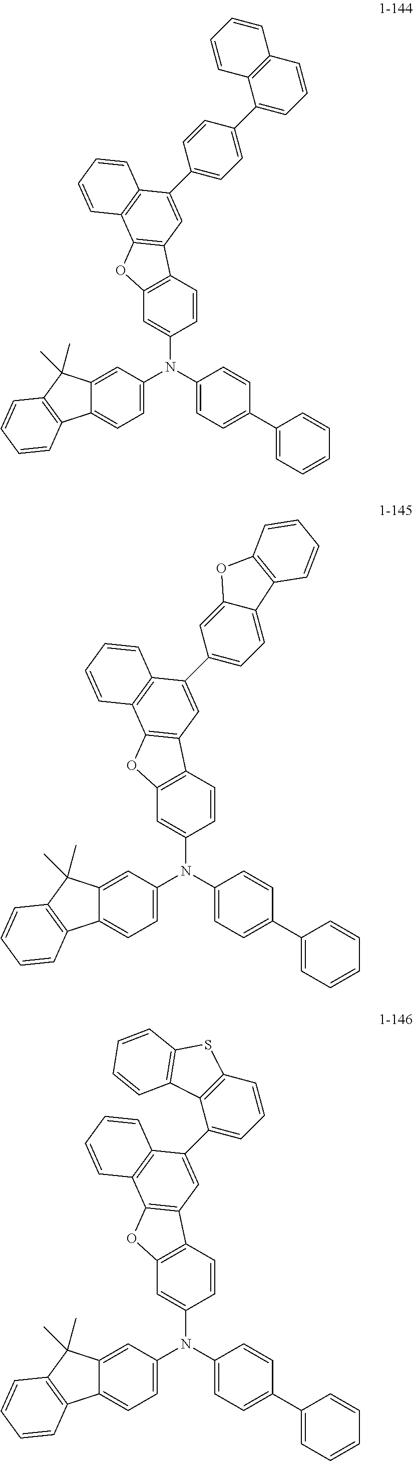 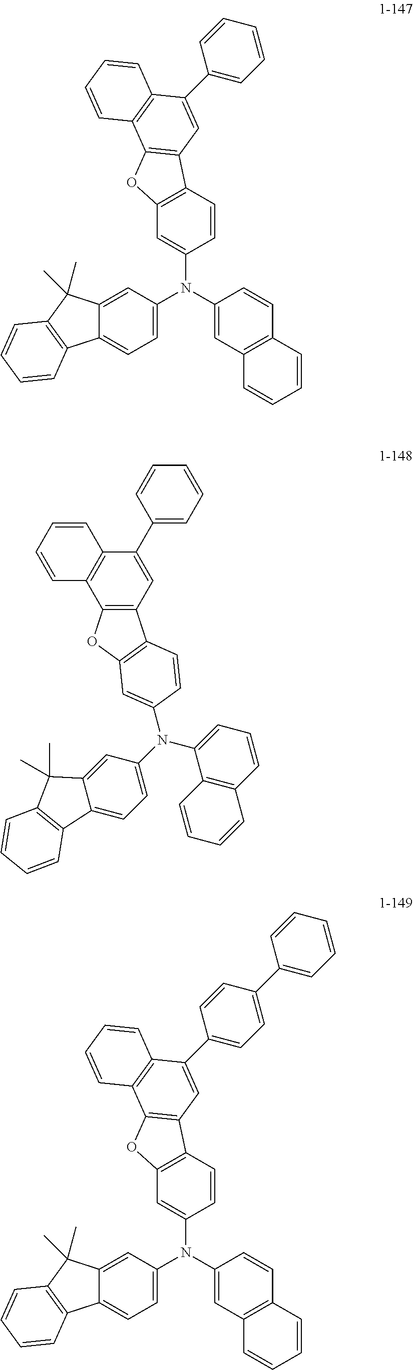 [SMILES: CC1(C)c2ccccc2-c2ccc(N(c3ccc4ccccc4c3)c3ccc4c(c3)oc3c5ccccc5c(-c5ccccc5)cc43)cc21 ; CC1(C)c2ccccc2-c2ccc(N(c3ccc4c(c3)oc3c5ccccc5c(-c5ccccc5)cc43)c3cccc4ccccc34)cc21 ; CC1(C)c2ccccc2-c2ccc(N(c3ccc4ccccc4c3)c3ccc4c(c3)oc3c5ccccc5c(-c5ccc(-c6ccccc6)cc5)cc43)cc21] 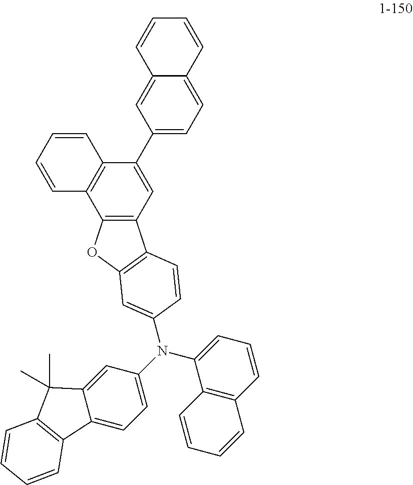 [SMILES: CC1(C)c2ccccc2-c2ccc(N(c3ccc4c(c3)oc3c5ccccc5c(-c5ccc6ccccc6c5)cc43)c3cccc4ccccc34)cc21] 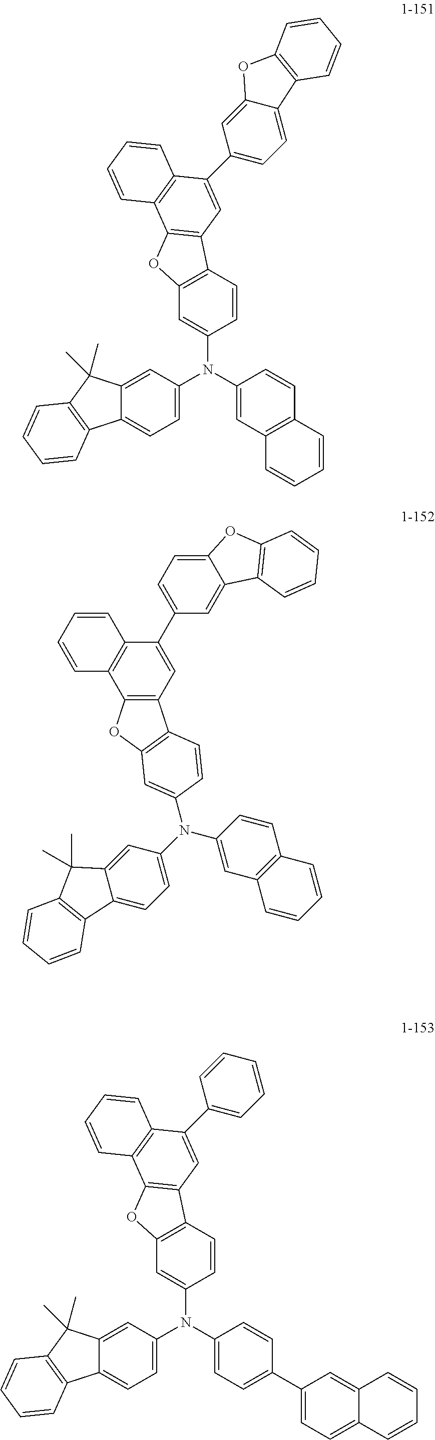 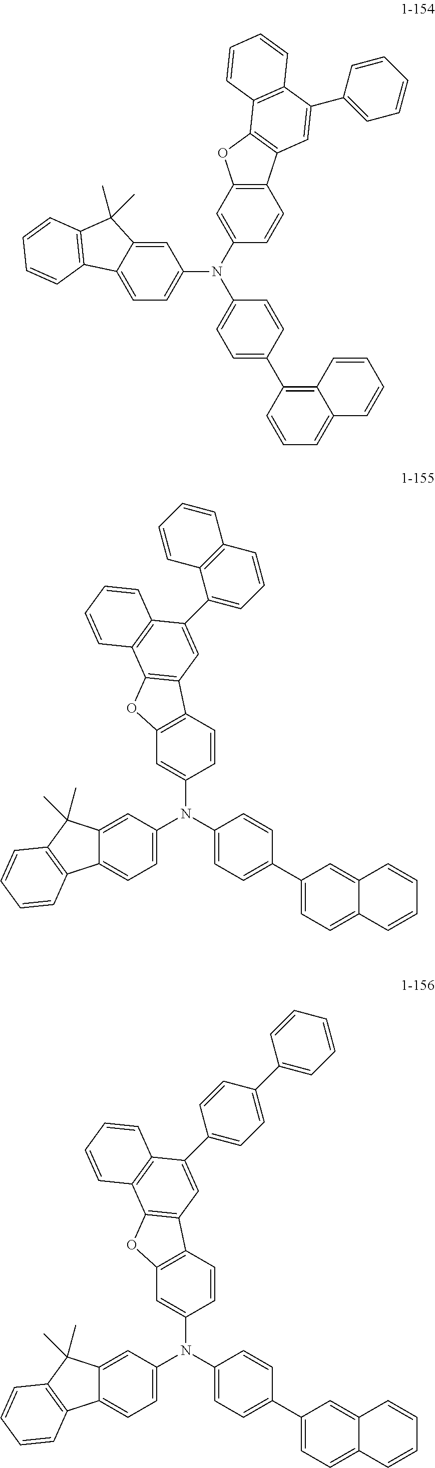 [SMILES: CC1(C)c2ccccc2-c2ccc(N(c3ccc(-c4cccc5ccccc45)cc3)c3ccc4c(c3)oc3c5ccccc5c(-c5ccccc5)cc43)cc21 ; CC1(C)c2ccccc2-c2ccc(N(c3ccc(-c4ccc5ccccc5c4)cc3)c3ccc4c(c3)oc3c5ccccc5c(-c5cccc6ccccc56)cc43)cc21 ; CC1(C)c2ccccc2-c2ccc(N(c3ccc(-c4ccc5ccccc5c4)cc3)c3ccc4c(c3)oc3c5ccccc5c(-c5ccc(-c6ccccc6)cc5)cc43)cc21] 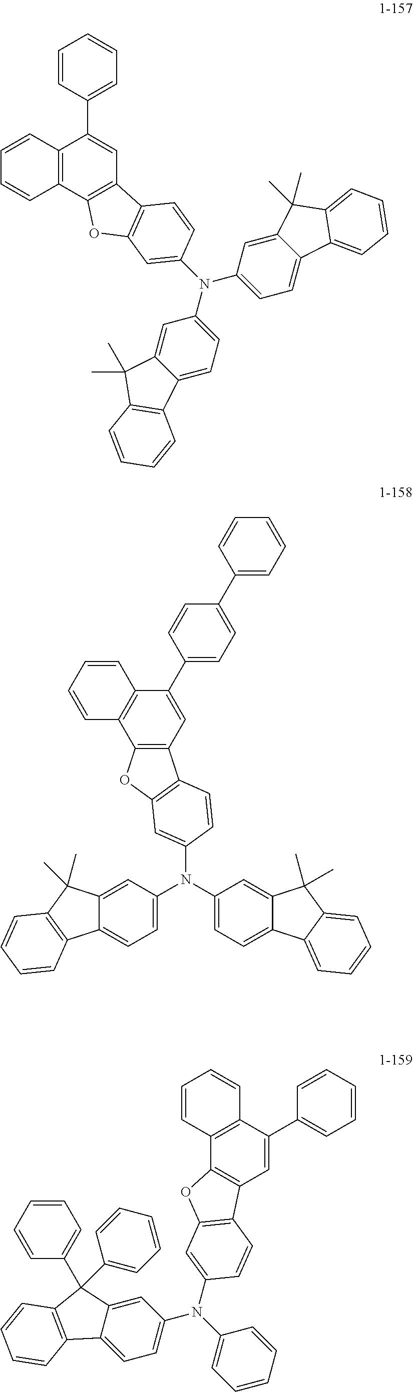 [SMILES: CC1(C)c2ccccc2-c2ccc(N(c3ccc4c(c3)C(C)(C)c3ccccc3-4)c3ccc4c(c3)oc3c5ccccc5c(-c5ccccc5)cc43)cc21 ; CC1(C)c2ccccc2-c2ccc(N(c3ccc4c(c3)C(C)(C)c3ccccc3-4)c3ccc4c(c3)oc3c5ccccc5c(-c5ccc(-c6ccccc6)cc5)cc43)cc21 ; c1ccc(-c2cc3c4ccc(N(c5ccccc5)c5ccc6c(c5)C(c5ccccc5)(c5ccccc5)c5ccccc5-6)cc4oc3c3ccccc23)cc1] 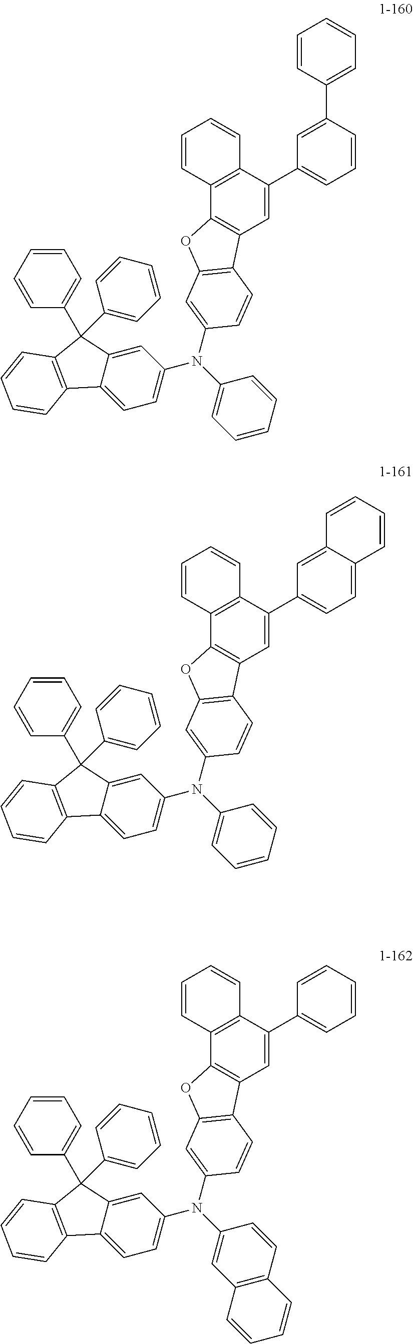 [SMILES: c1ccc(-c2cccc(-c3cc4c5ccc(N(c6ccccc6)c6ccc7c(c6)C(c6ccccc6)(c6ccccc6)c6ccccc6-7)cc5oc4c4ccccc34)c2)cc1 ; c1ccc(N(c2ccc3c(c2)C(c2ccccc2)(c2ccccc2)c2ccccc2-3)c2ccc3c(c2)oc2c4ccccc4c(-c4ccc5ccccc5c4)cc32)cc1 ; c1ccc(-c2cc3c4ccc(N(c5ccc6c(c5)C(c5ccccc5)(c5ccccc5)c5ccccc5-6)c5ccc6ccccc6c5)cc4oc3c3ccccc23)cc1] 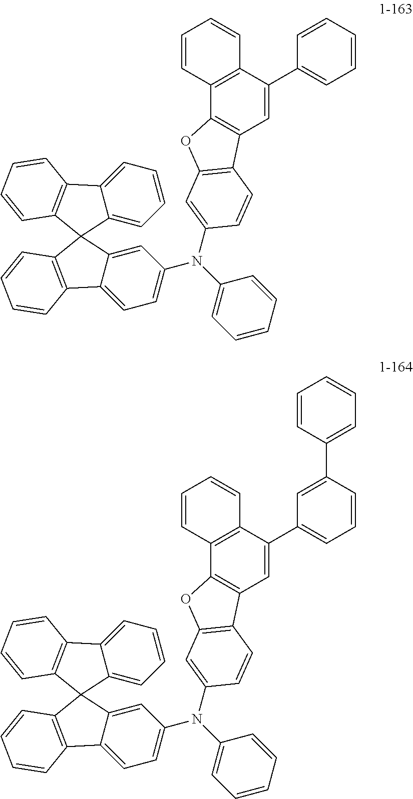 [SMILES: c1ccc(-c2cc3c4ccc(N(c5ccccc5)c5ccc6c(c5)C5(c7ccccc7-c7ccccc75)c5ccccc5-6)cc4oc3c3ccccc23)cc1 ; c1ccc(-c2cccc(-c3cc4c5ccc(N(c6ccccc6)c6ccc7c(c6)C6(c8ccccc8-c8ccccc86)c6ccccc6-7)cc5oc4c4ccccc34)c2)cc1] 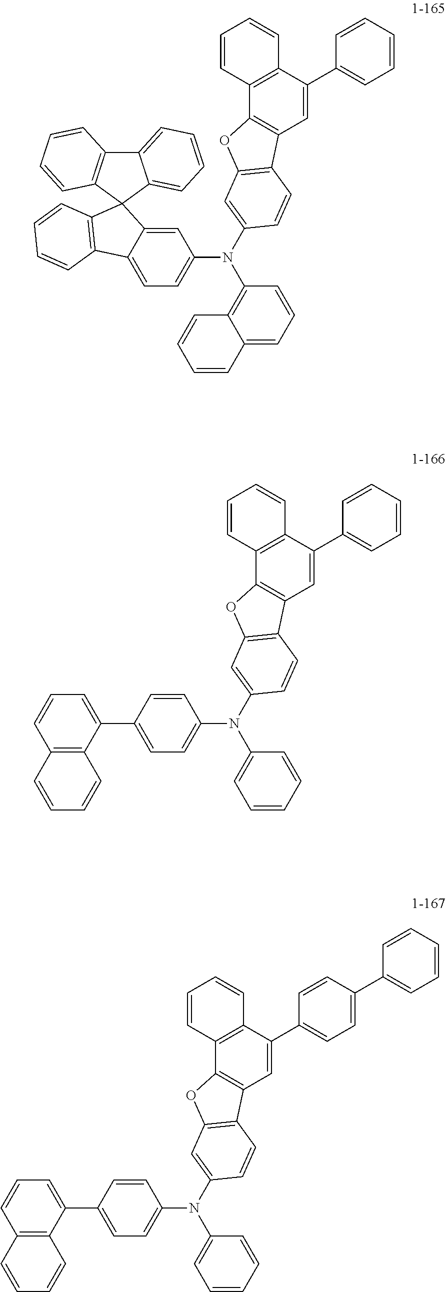 [SMILES: c1ccc(-c2cc3c4ccc(N(c5ccc6c(c5)C5(c7ccccc7-c7ccccc75)c5ccccc5-6)c5cccc6ccccc56)cc4oc3c3ccccc23)cc1 ; c1ccc(-c2cc3c4ccc(N(c5ccccc5)c5ccc(-c6cccc7ccccc67)cc5)cc4oc3c3ccccc23)cc1 ; c1ccc(-c2ccc(-c3cc4c5ccc(N(c6ccccc6)c6ccc(-c7cccc8ccccc78)cc6)cc5oc4c4ccccc34)cc2)cc1] 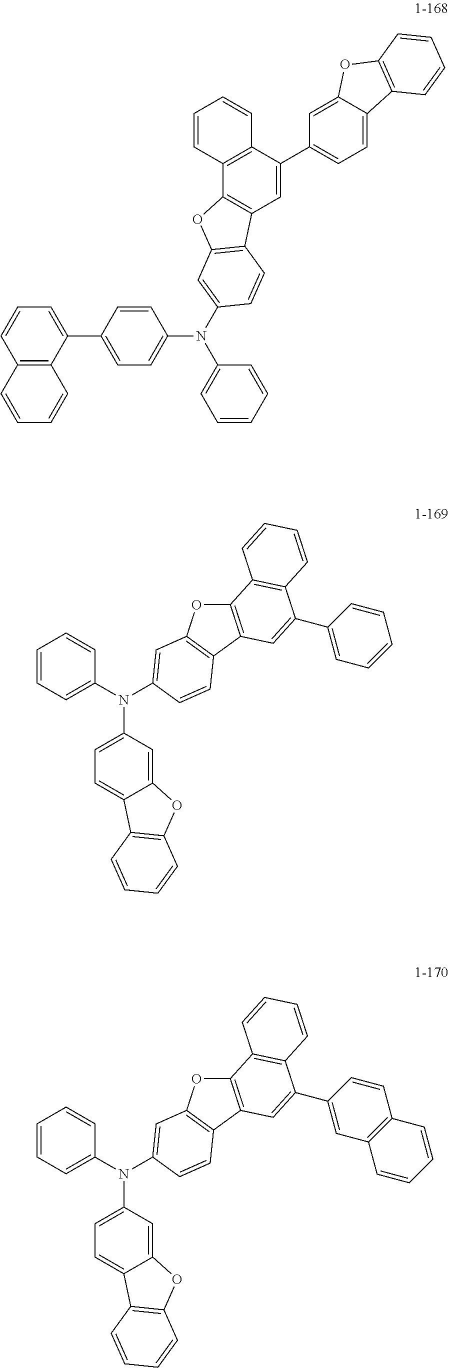 [SMILES: c1ccc(N(c2ccc(-c3cccc4ccccc34)cc2)c2ccc3c(c2)oc2c4ccccc4c(-c4ccc5c(c4)oc4ccccc45)cc32)cc1 ; c1ccc(-c2cc3c4ccc(N(c5ccccc5)c5ccc6c(c5)oc5ccccc56)cc4oc3c3ccccc23)cc1 ; c1ccc(N(c2ccc3c(c2)oc2ccccc23)c2ccc3c(c2)oc2c4ccccc4c(-c4ccc5ccccc5c4)cc32)cc1] 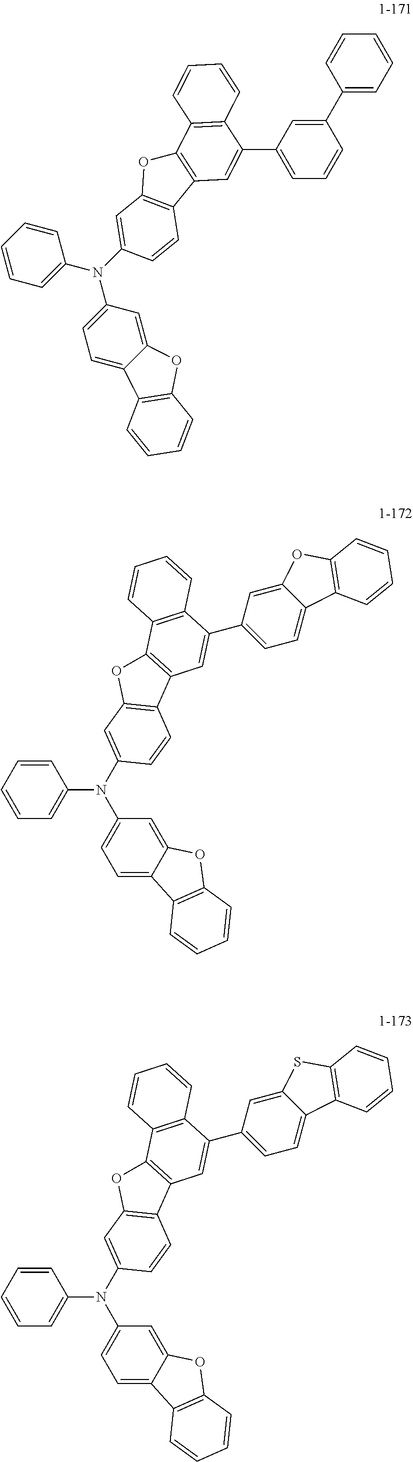 [SMILES: c1ccc(-c2cccc(-c3cc4c5ccc(N(c6ccccc6)c6ccc7c(c6)oc6ccccc67)cc5oc4c4ccccc34)c2)cc1 ; c1ccc(N(c2ccc3c(c2)oc2ccccc23)c2ccc3c(c2)oc2c4ccccc4c(-c4ccc5c(c4)oc4ccccc45)cc32)cc1 ; c1ccc(N(c2ccc3c(c2)oc2ccccc23)c2ccc3c(c2)oc2c4ccccc4c(-c4ccc5c(c4)sc4ccccc45)cc32)cc1] 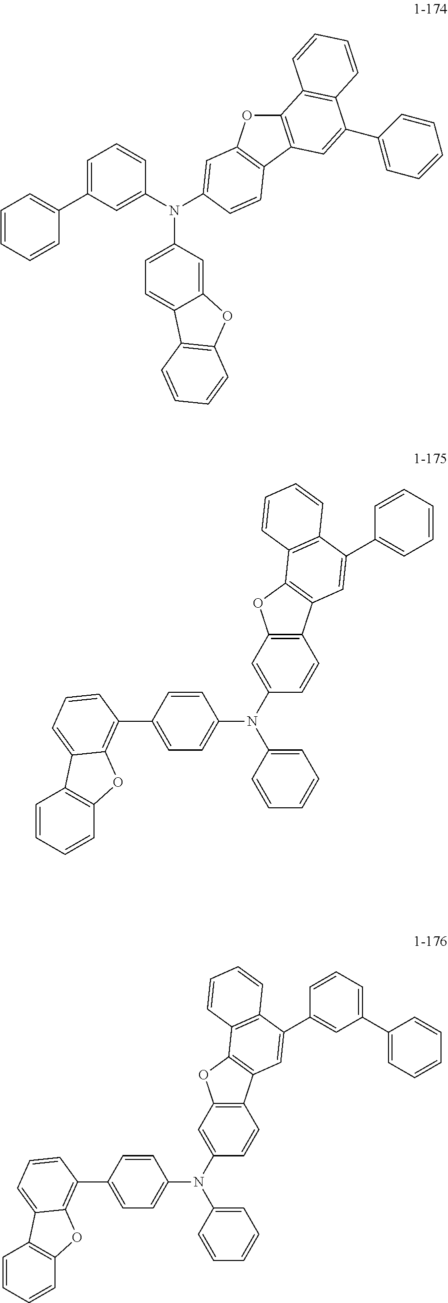 [SMILES: c1ccc(-c2cccc(N(c3ccc4c(c3)oc3ccccc34)c3ccc4c(c3)oc3c5ccccc5c(-c5ccccc5)cc43)c2)cc1 ; c1ccc(-c2cc3c4ccc(N(c5ccccc5)c5ccc(-c6cccc7c6oc6ccccc67)cc5)cc4oc3c3ccccc23)cc1 ; c1ccc(-c2cccc(-c3cc4c5ccc(N(c6ccccc6)c6ccc(-c7cccc8c7oc7ccccc78)cc6)cc5oc4c4ccccc34)c2)cc1] 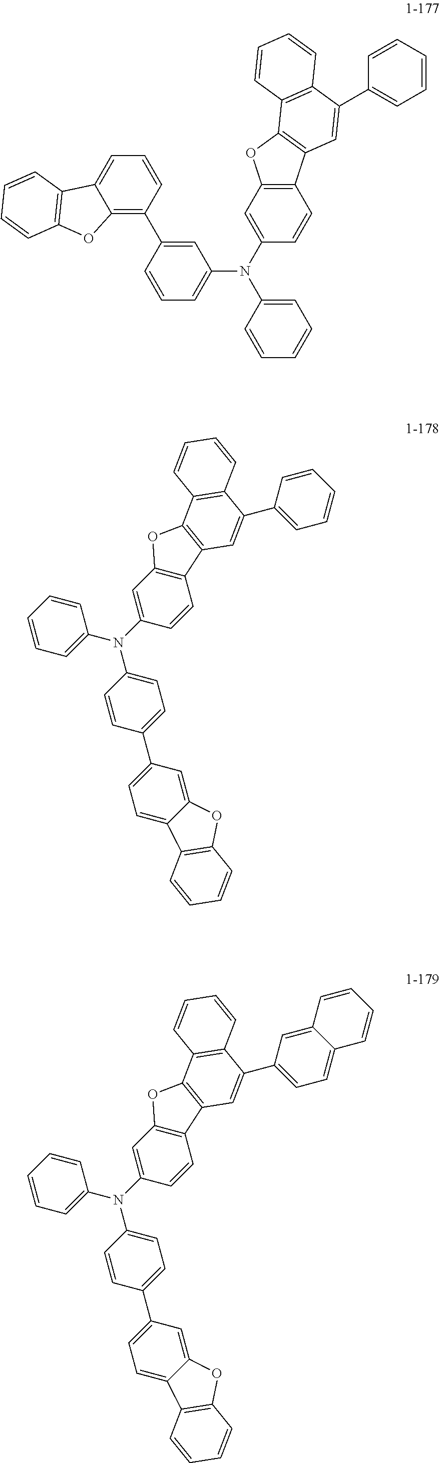 [SMILES: c1ccc(-c2cc3c4ccc(N(c5ccccc5)c5cccc(-c6cccc7c6oc6ccccc67)c5)cc4oc3c3ccccc23)cc1 ; c1ccc(-c2cc3c4ccc(N(c5ccccc5)c5ccc(-c6ccc7c(c6)oc6ccccc67)cc5)cc4oc3c3ccccc23)cc1 ; c1ccc(N(c2ccc(-c3ccc4c(c3)oc3ccccc34)cc2)c2ccc3c(c2)oc2c4ccccc4c(-c4ccc5ccccc5c4)cc32)cc1] 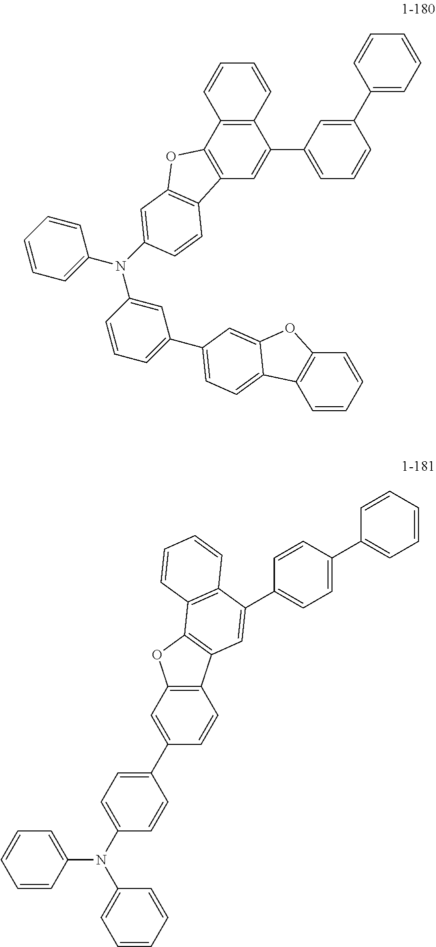 [SMILES: c1ccc(-c2cccc(-c3cc4c5ccc(N(c6ccccc6)c6cccc(-c7ccc8c(c7)oc7ccccc78)c6)cc5oc4c4ccccc34)c2)cc1 ; c1ccc(-c2ccc(-c3cc4c5ccc(-c6ccc(N(c7ccccc7)c7ccccc7)cc6)cc5oc4c4ccccc34)cc2)cc1] 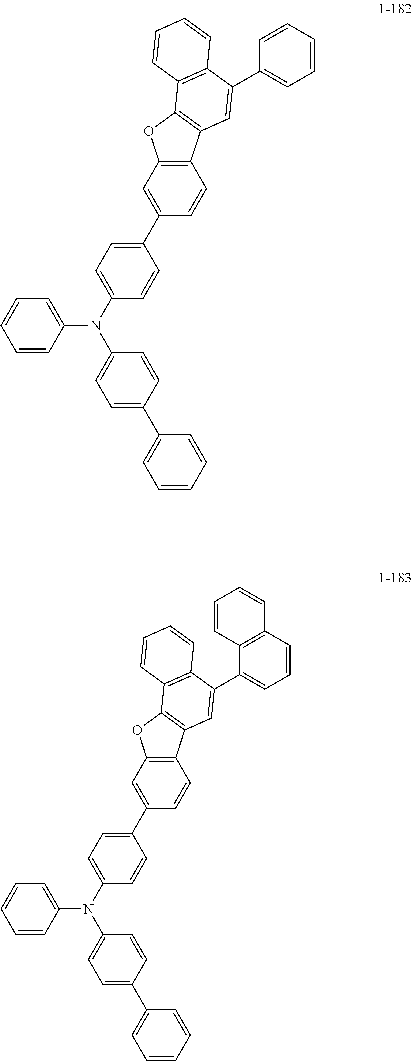 [SMILES: c1ccc(-c2ccc(N(c3ccccc3)c3ccc(-c4ccc5c(c4)oc4c6ccccc6c(-c6ccccc6)cc54)cc3)cc2)cc1 ; c1ccc(-c2ccc(N(c3ccccc3)c3ccc(-c4ccc5c(c4)oc4c6ccccc6c(-c6cccc7ccccc67)cc54)cc3)cc2)cc1] 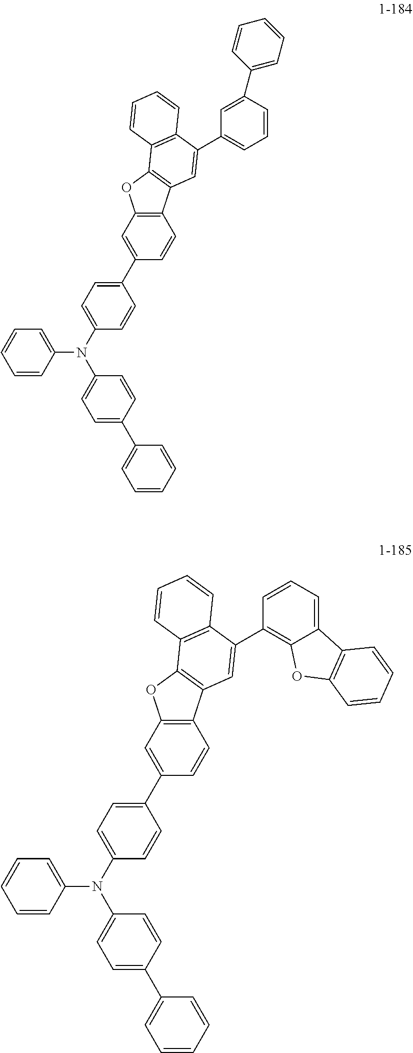 [SMILES: c1ccc(-c2ccc(N(c3ccccc3)c3ccc(-c4ccc5c(c4)oc4c6ccccc6c(-c6cccc(-c7ccccc7)c6)cc54)cc3)cc2)cc1 ; c1ccc(-c2ccc(N(c3ccccc3)c3ccc(-c4ccc5c(c4)oc4c6ccccc6c(-c6cccc7c6oc6ccccc67)cc54)cc3)cc2)cc1] 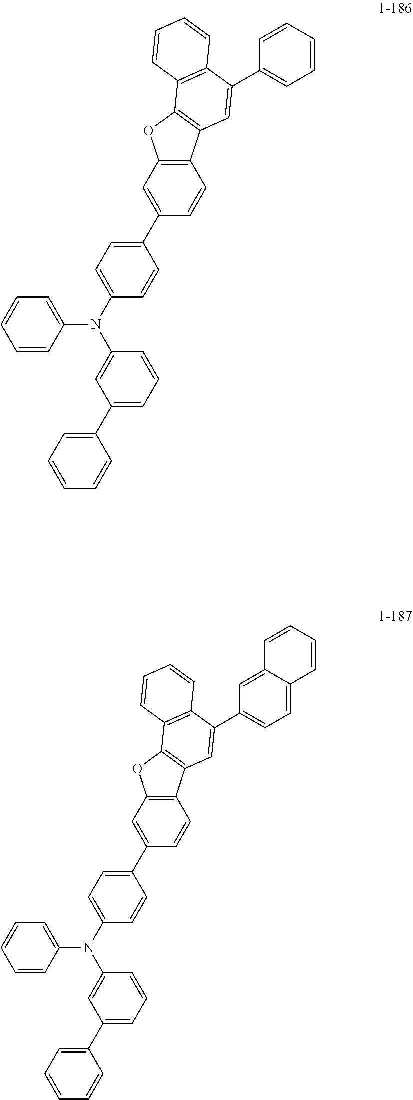 [SMILES: c1ccc(-c2cccc(N(c3ccccc3)c3ccc(-c4ccc5c(c4)oc4c6ccccc6c(-c6ccccc6)cc54)cc3)c2)cc1 ; c1ccc(-c2cccc(N(c3ccccc3)c3ccc(-c4ccc5c(c4)oc4c6ccccc6c(-c6ccc7ccccc7c6)cc54)cc3)c2)cc1] 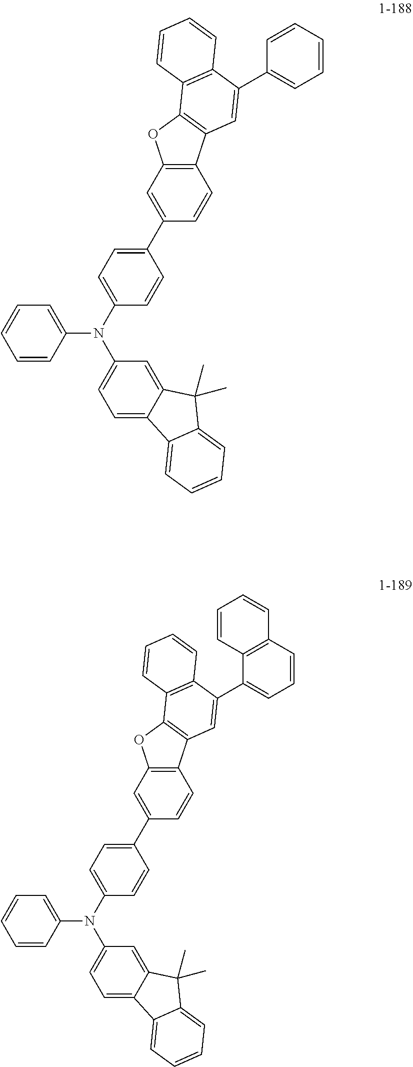 [SMILES: CC1(C)c2ccccc2-c2ccc(N(c3ccccc3)c3ccc(-c4ccc5c(c4)oc4c6ccccc6c(-c6ccccc6)cc54)cc3)cc21 ; CC1(C)c2ccccc2-c2ccc(N(c3ccccc3)c3ccc(-c4ccc5c(c4)oc4c6ccccc6c(-c6cccc7ccccc67)cc54)cc3)cc21] 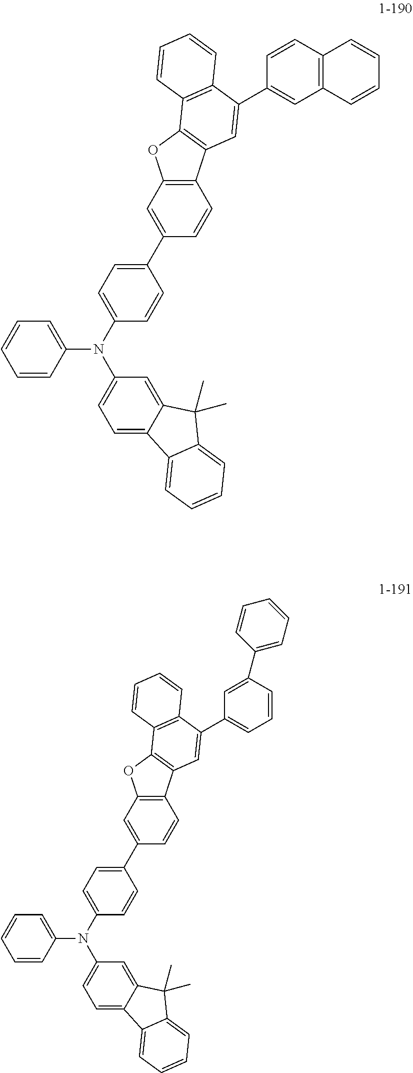 [SMILES: CC1(C)c2ccccc2-c2ccc(N(c3ccccc3)c3ccc(-c4ccc5c(c4)oc4c6ccccc6c(-c6ccc7ccccc7c6)cc54)cc3)cc21 ; CC1(C)c2ccccc2-c2ccc(N(c3ccccc3)c3ccc(-c4ccc5c(c4)oc4c6ccccc6c(-c6cccc(-c7ccccc7)c6)cc54)cc3)cc21] 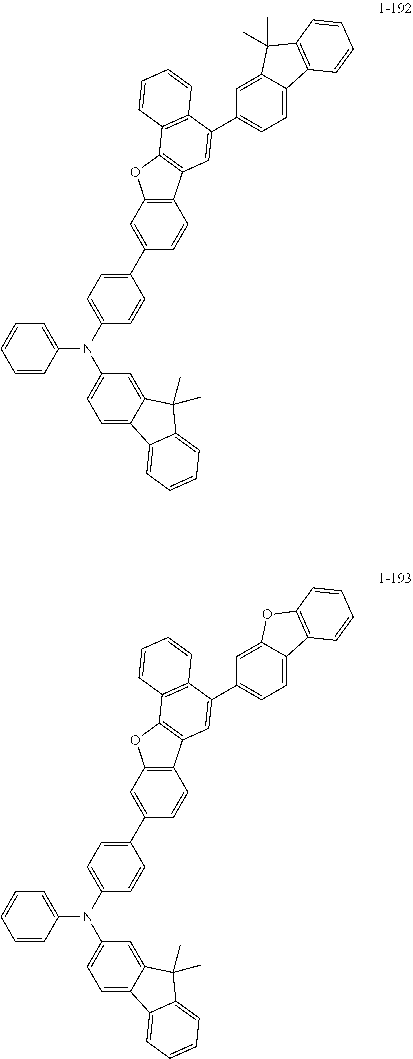 [SMILES: CC1(C)c2ccccc2-c2ccc(-c3cc4c5ccc(-c6ccc(N(c7ccccc7)c7ccc8c(c7)C(C)(C)c7ccccc7-8)cc6)cc5oc4c4ccccc34)cc21 ; CC1(C)c2ccccc2-c2ccc(N(c3ccccc3)c3ccc(-c4ccc5c(c4)oc4c6ccccc6c(-c6ccc7c(c6)oc6ccccc67)cc54)cc3)cc21] 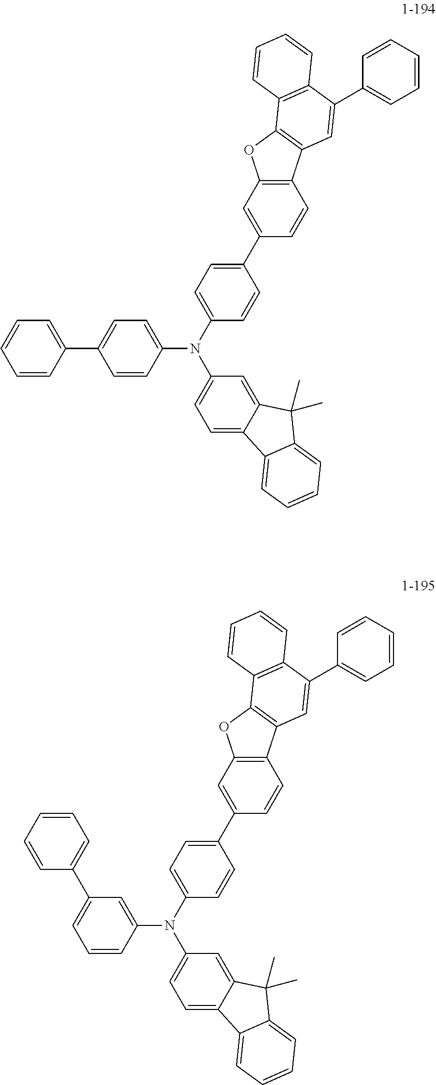 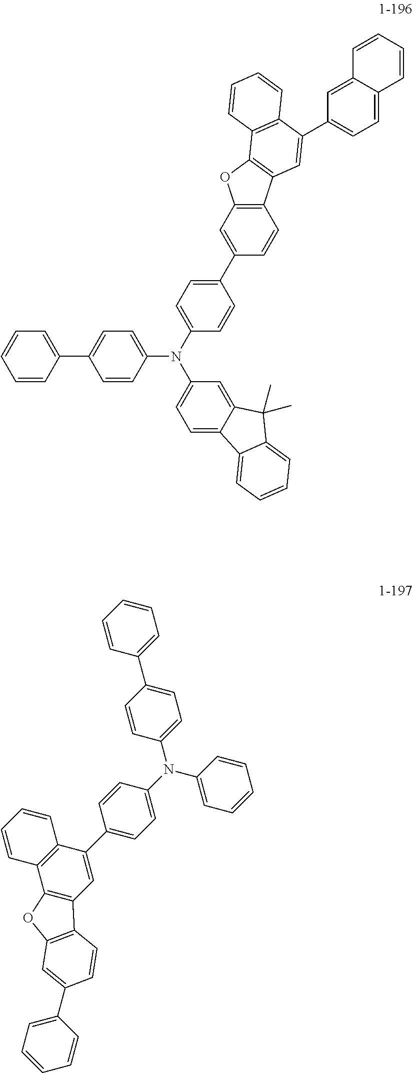 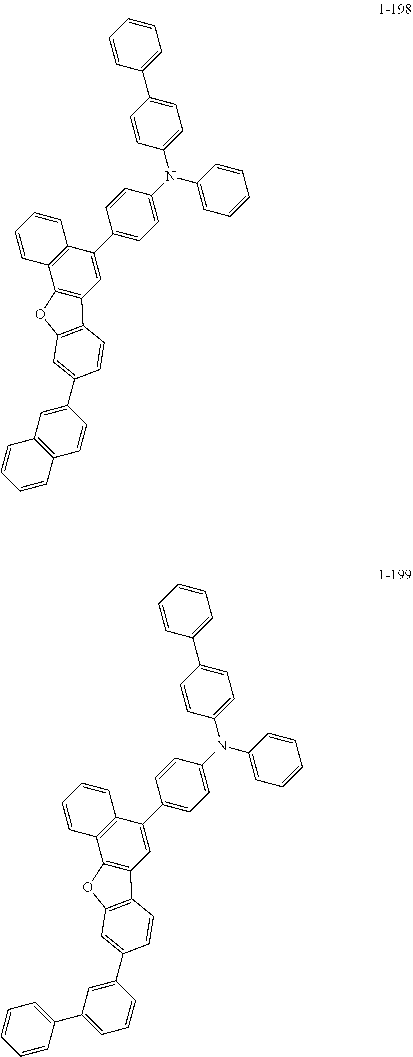 [SMILES: c1ccc(-c2ccc(N(c3ccccc3)c3ccc(-c4cc5c6ccc(-c7ccc8ccccc8c7)cc6oc5c5ccccc45)cc3)cc2)cc1 ; c1ccc(-c2ccc(N(c3ccccc3)c3ccc(-c4cc5c6ccc(-c7cccc(-c8ccccc8)c7)cc6oc5c5ccccc45)cc3)cc2)cc1] 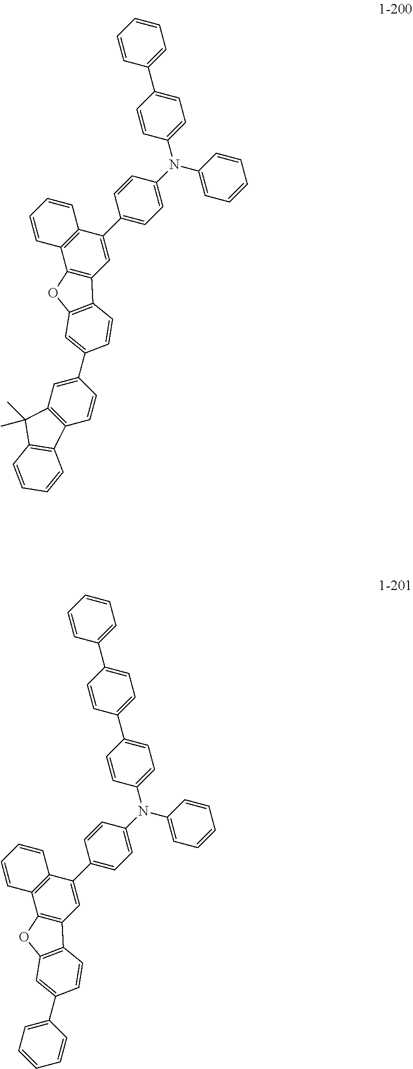 [SMILES: CC1(C)c2ccccc2-c2ccc(-c3ccc4c(c3)oc3c5ccccc5c(-c5ccc(N(c6ccccc6)c6ccc(-c7ccccc7)cc6)cc5)cc43)cc21 ; c1ccc(-c2ccc(-c3ccc(N(c4ccccc4)c4ccc(-c5cc6c7ccc(-c8ccccc8)cc7oc6c6ccccc56)cc4)cc3)cc2)cc1] 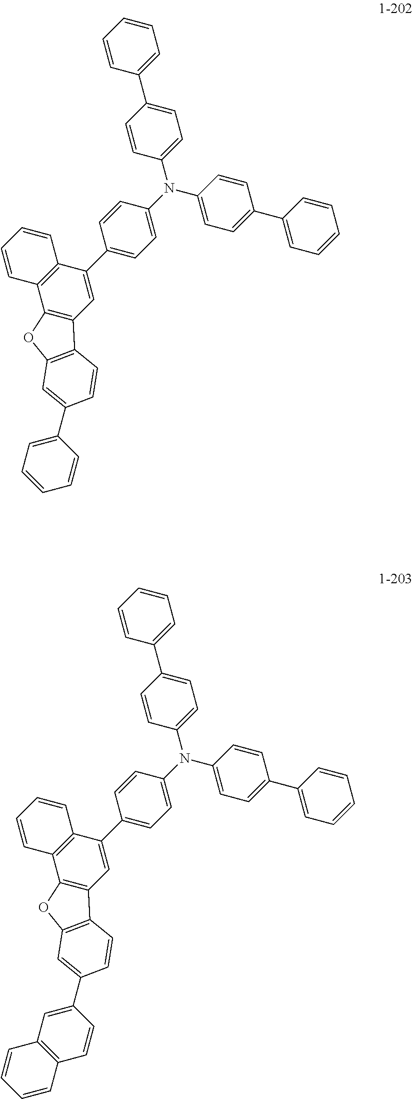 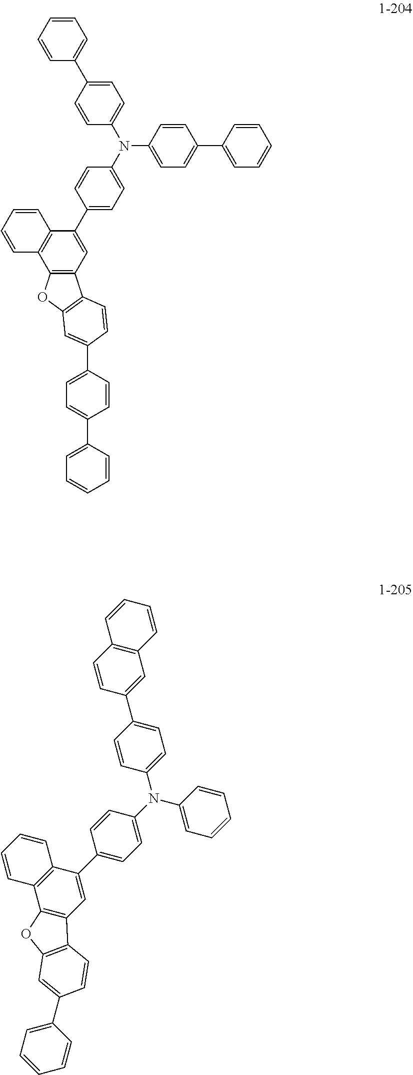 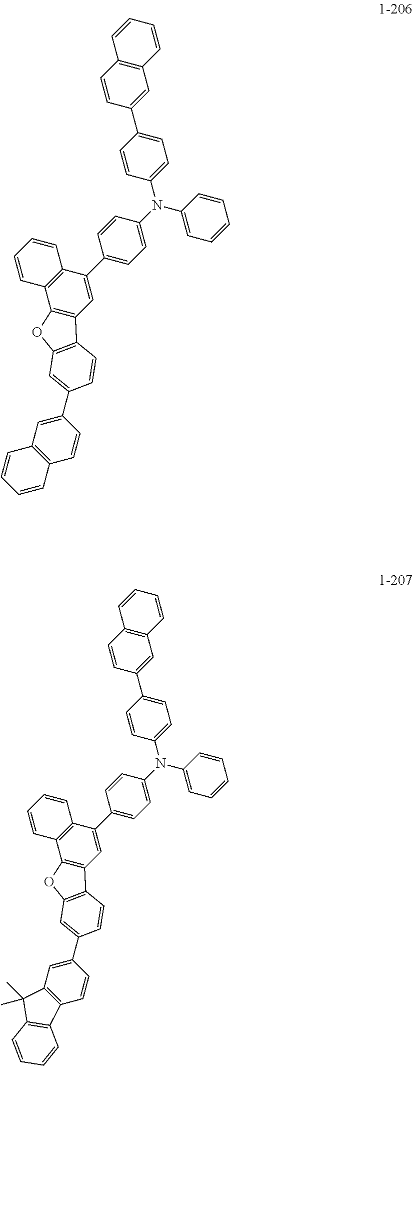 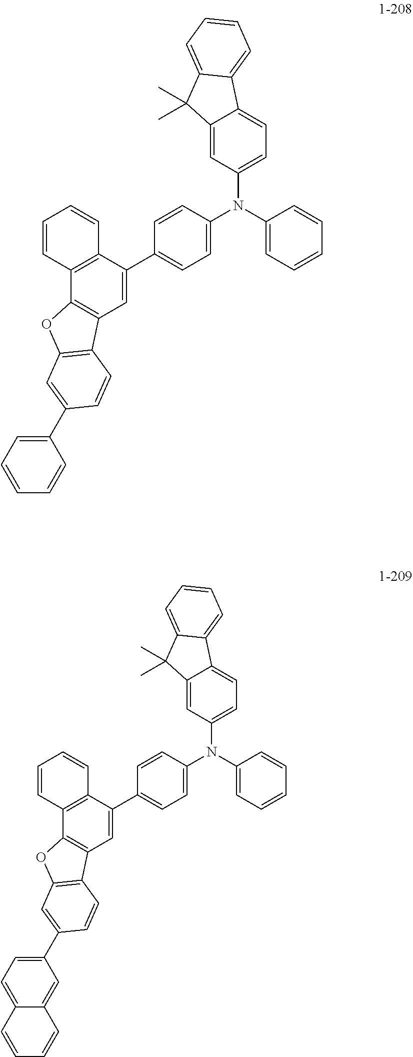 [SMILES: CC1(C)c2ccccc2-c2ccc(N(c3ccccc3)c3ccc(-c4cc5c6ccc(-c7ccccc7)cc6oc5c5ccccc45)cc3)cc21 ; CC1(C)c2ccccc2-c2ccc(N(c3ccccc3)c3ccc(-c4cc5c6ccc(-c7ccc8ccccc8c7)cc6oc5c5ccccc45)cc3)cc21] 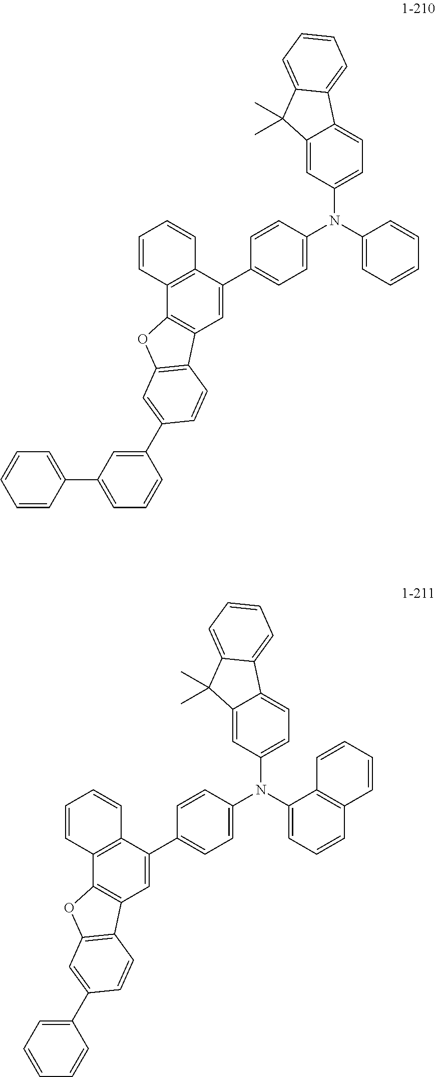 [SMILES: CC1(C)c2ccccc2-c2ccc(N(c3ccccc3)c3ccc(-c4cc5c6ccc(-c7cccc(-c8ccccc8)c7)cc6oc5c5ccccc45)cc3)cc21 ; CC1(C)c2ccccc2-c2ccc(N(c3ccc(-c4cc5c6ccc(-c7ccccc7)cc6oc5c5ccccc45)cc3)c3cccc4ccccc34)cc21] 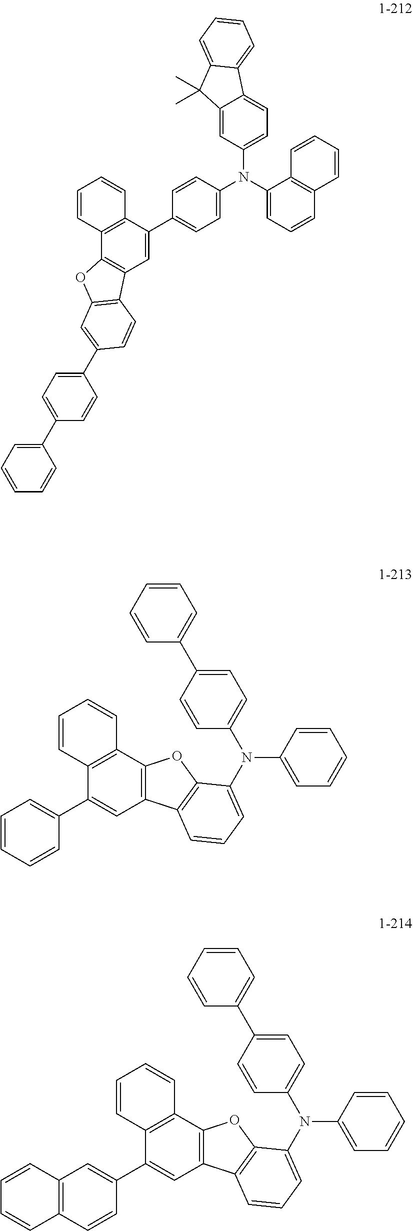 [SMILES: CC1(C)c2ccccc2-c2ccc(N(c3ccc(-c4cc5c6ccc(-c7ccc(-c8ccccc8)cc7)cc6oc5c5ccccc45)cc3)c3cccc4ccccc34)cc21 ; c1ccc(-c2ccc(N(c3ccccc3)c3cccc4c3oc3c5ccccc5c(-c5ccccc5)cc43)cc2)cc1 ; c1ccc(-c2ccc(N(c3ccccc3)c3cccc4c3oc3c5ccccc5c(-c5ccc6ccccc6c5)cc43)cc2)cc1] 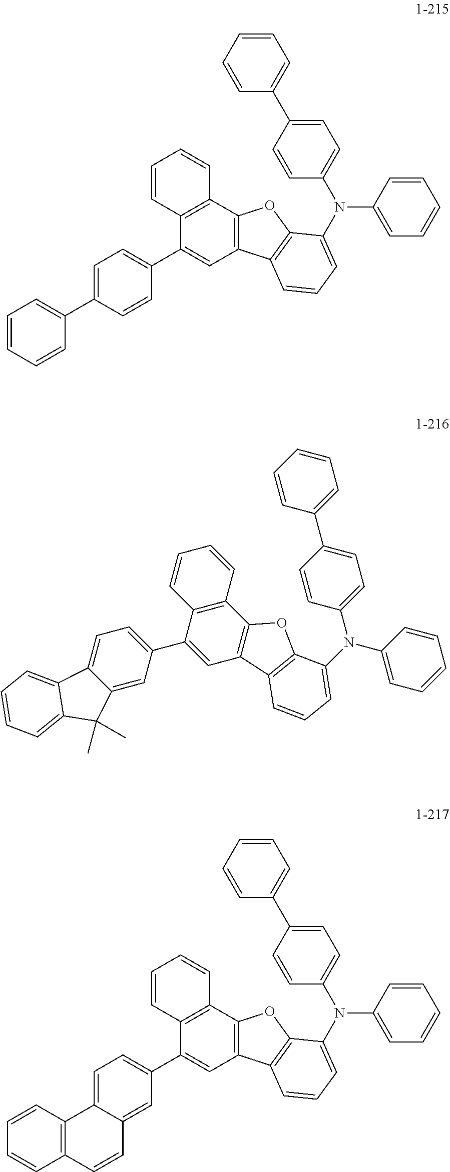 [SMILES: c1ccc(-c2ccc(-c3cc4c5cccc(N(c6ccccc6)c6ccc(-c7ccccc7)cc6)c5oc4c4ccccc34)cc2)cc1 ; CC1(C)c2ccccc2-c2ccc(-c3cc4c5cccc(N(c6ccccc6)c6ccc(-c7ccccc7)cc6)c5oc4c4ccccc34)cc21 ; c1ccc(-c2ccc(N(c3ccccc3)c3cccc4c3oc3c5ccccc5c(-c5ccc6c(ccc7ccccc76)c5)cc43)cc2)cc1] 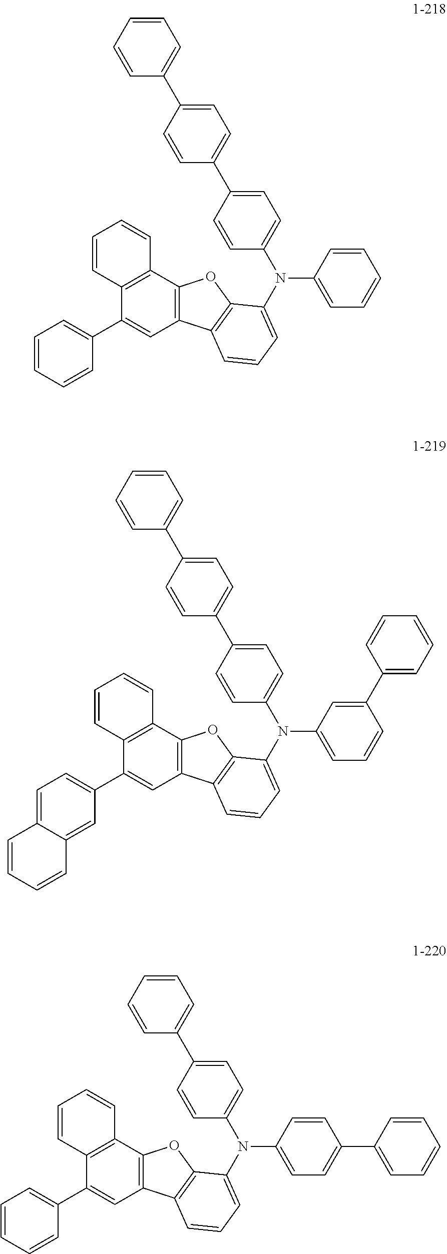 [SMILES: c1ccc(-c2ccc(-c3ccc(N(c4ccccc4)c4cccc5c4oc4c6ccccc6c(-c6ccccc6)cc54)cc3)cc2)cc1 ; c1ccc(-c2ccc(-c3ccc(N(c4cccc(-c5ccccc5)c4)c4cccc5c4oc4c6ccccc6c(-c6ccc7ccccc7c6)cc54)cc3)cc2)cc1 ; c1ccc(-c2ccc(N(c3ccc(-c4ccccc4)cc3)c3cccc4c3oc3c5ccccc5c(-c5ccccc5)cc43)cc2)cc1] 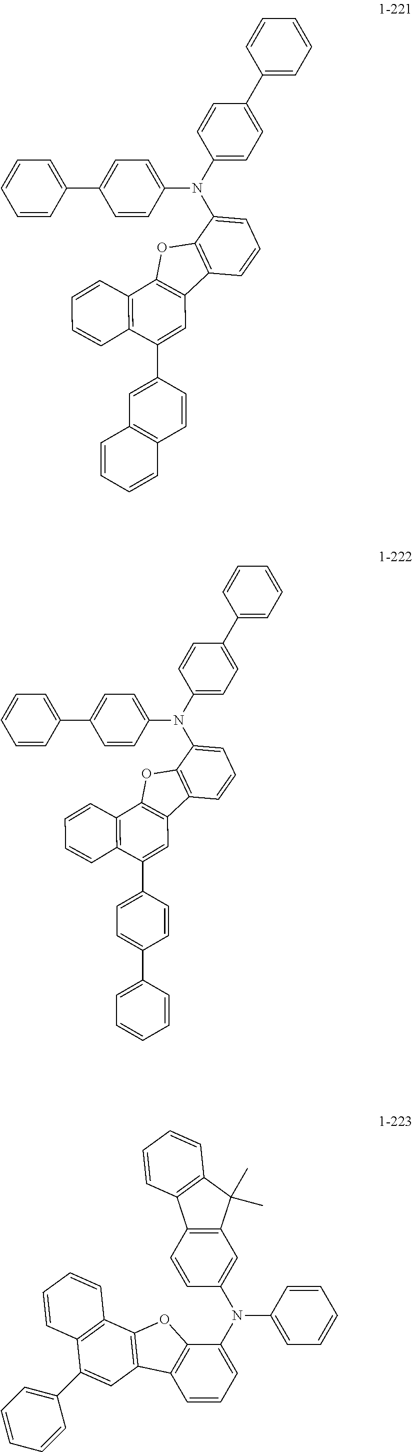 [SMILES: c1ccc(-c2ccc(N(c3ccc(-c4ccccc4)cc3)c3cccc4c3oc3c5ccccc5c(-c5ccc6ccccc6c5)cc43)cc2)cc1 ; c1ccc(-c2ccc(-c3cc4c5cccc(N(c6ccc(-c7ccccc7)cc6)c6ccc(-c7ccccc7)cc6)c5oc4c4ccccc34)cc2)cc1 ; CC1(C)c2ccccc2-c2ccc(N(c3ccccc3)c3cccc4c3oc3c5ccccc5c(-c5ccccc5)cc43)cc21] 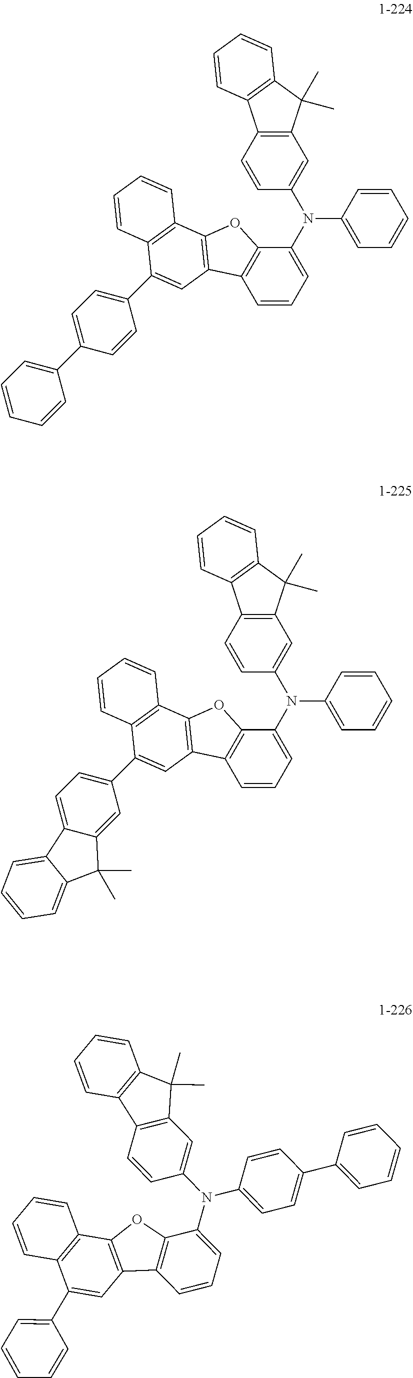 [SMILES: CC1(C)c2ccccc2-c2ccc(N(c3ccccc3)c3cccc4c3oc3c5ccccc5c(-c5ccc(-c6ccccc6)cc5)cc43)cc21 ; CC1(C)c2ccccc2-c2ccc(-c3cc4c5cccc(N(c6ccccc6)c6ccc7c(c6)C(C)(C)c6ccccc6-7)c5oc4c4ccccc34)cc21 ; CC1(C)c2ccccc2-c2ccc(N(c3ccc(-c4ccccc4)cc3)c3cccc4c3oc3c5ccccc5c(-c5ccccc5)cc43)cc21] 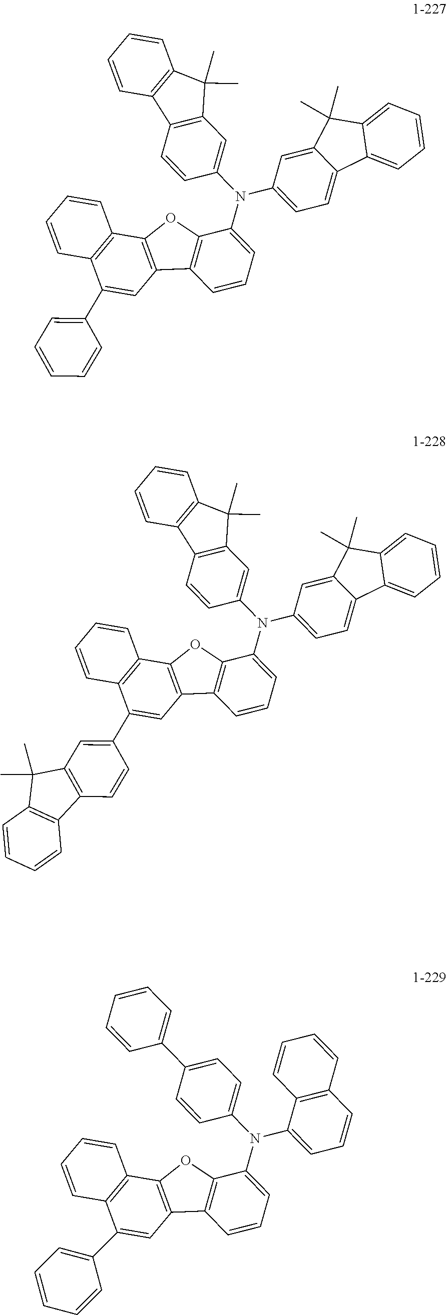 [SMILES: CC1(C)c2ccccc2-c2ccc(N(c3ccc4c(c3)C(C)(C)c3ccccc3-4)c3cccc4c3oc3c5ccccc5c(-c5ccccc5)cc43)cc21 ; CC1(C)c2ccccc2-c2ccc(-c3cc4c5cccc(N(c6ccc7c(c6)C(C)(C)c6ccccc6-7)c6ccc7c(c6)C(C)(C)c6ccccc6-7)c5oc4c4ccccc34)cc21 ; c1ccc(-c2ccc(N(c3cccc4ccccc34)c3cccc4c3oc3c5ccccc5c(-c5ccccc5)cc43)cc2)cc1] 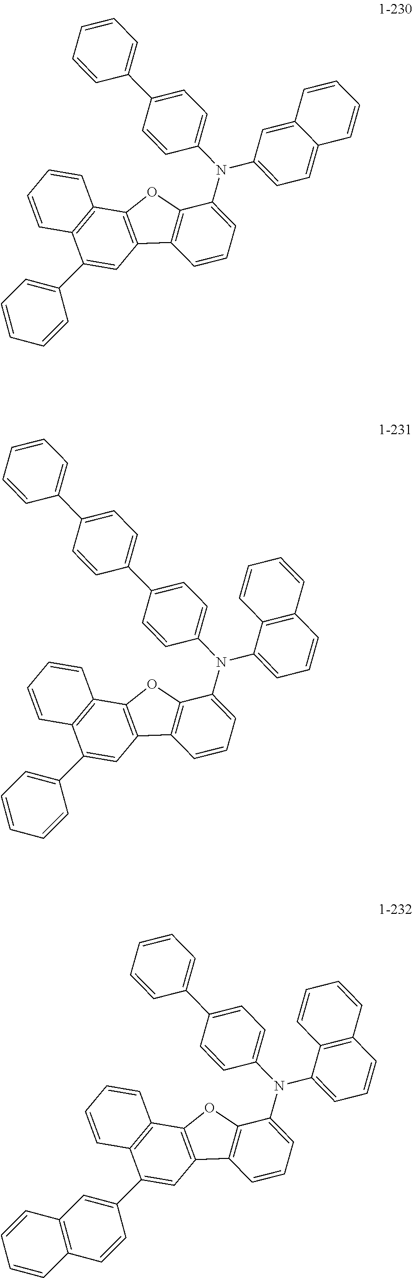 [SMILES: c1ccc(-c2ccc(N(c3ccc4ccccc4c3)c3cccc4c3oc3c5ccccc5c(-c5ccccc5)cc43)cc2)cc1 ; c1ccc(-c2ccc(-c3ccc(N(c4cccc5ccccc45)c4cccc5c4oc4c6ccccc6c(-c6ccccc6)cc54)cc3)cc2)cc1 ; c1ccc(-c2ccc(N(c3cccc4ccccc34)c3cccc4c3oc3c5ccccc5c(-c5ccc6ccccc6c5)cc43)cc2)cc1] 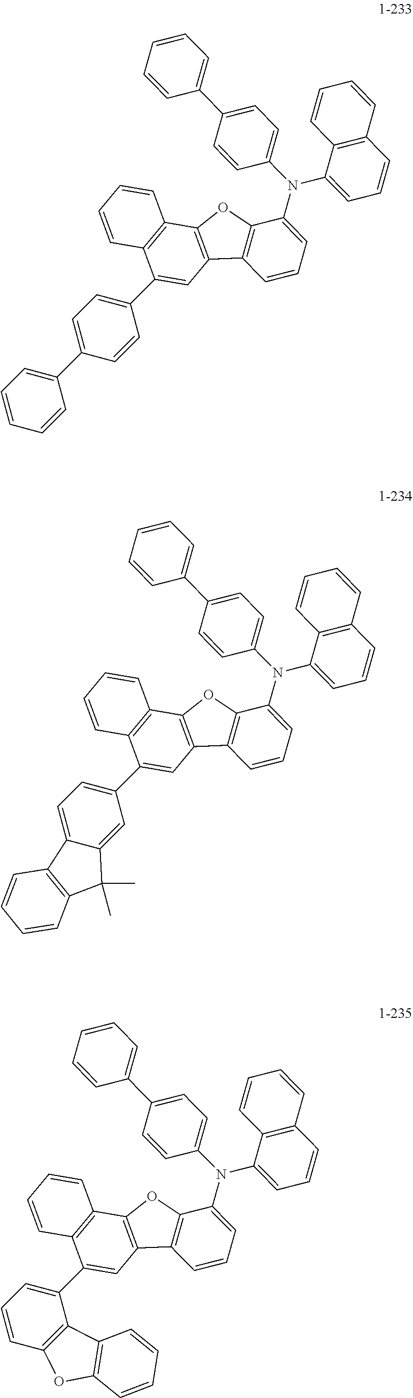 [SMILES: c1ccc(-c2ccc(-c3cc4c5cccc(N(c6ccc(-c7ccccc7)cc6)c6cccc7ccccc67)c5oc4c4ccccc34)cc2)cc1 ; CC1(C)c2ccccc2-c2ccc(-c3cc4c5cccc(N(c6ccc(-c7ccccc7)cc6)c6cccc7ccccc67)c5oc4c4ccccc34)cc21 ; c1ccc(-c2ccc(N(c3cccc4ccccc34)c3cccc4c3oc3c5ccccc5c(-c5cccc6oc7ccccc7c56)cc43)cc2)cc1] 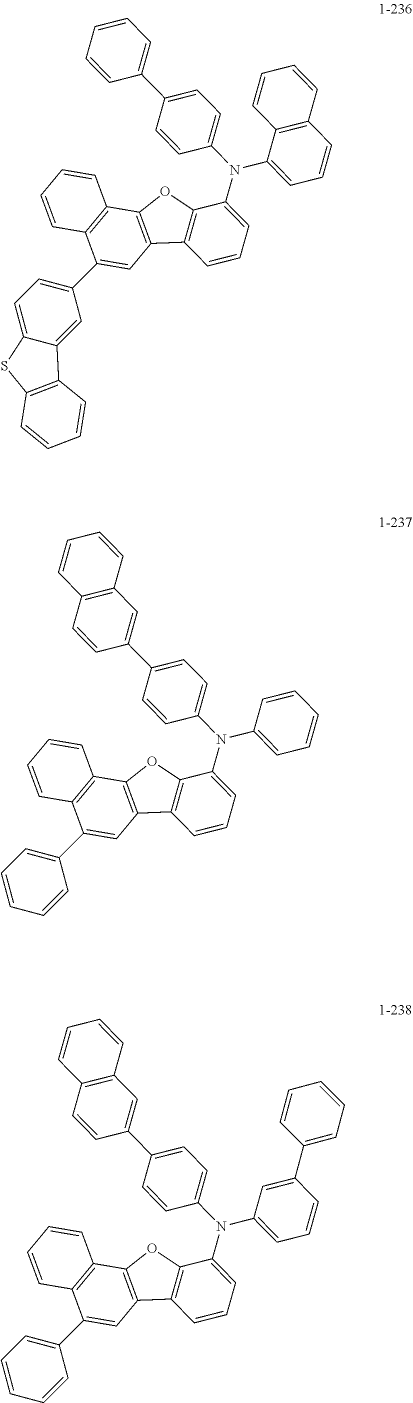 [SMILES: c1ccc(-c2ccc(N(c3cccc4ccccc34)c3cccc4c3oc3c5ccccc5c(-c5ccc6sc7ccccc7c6c5)cc43)cc2)cc1 ; c1ccc(-c2cc3c4cccc(N(c5ccccc5)c5ccc(-c6ccc7ccccc7c6)cc5)c4oc3c3ccccc23)cc1 ; c1ccc(-c2cccc(N(c3ccc(-c4ccc5ccccc5c4)cc3)c3cccc4c3oc3c5ccccc5c(-c5ccccc5)cc43)c2)cc1] 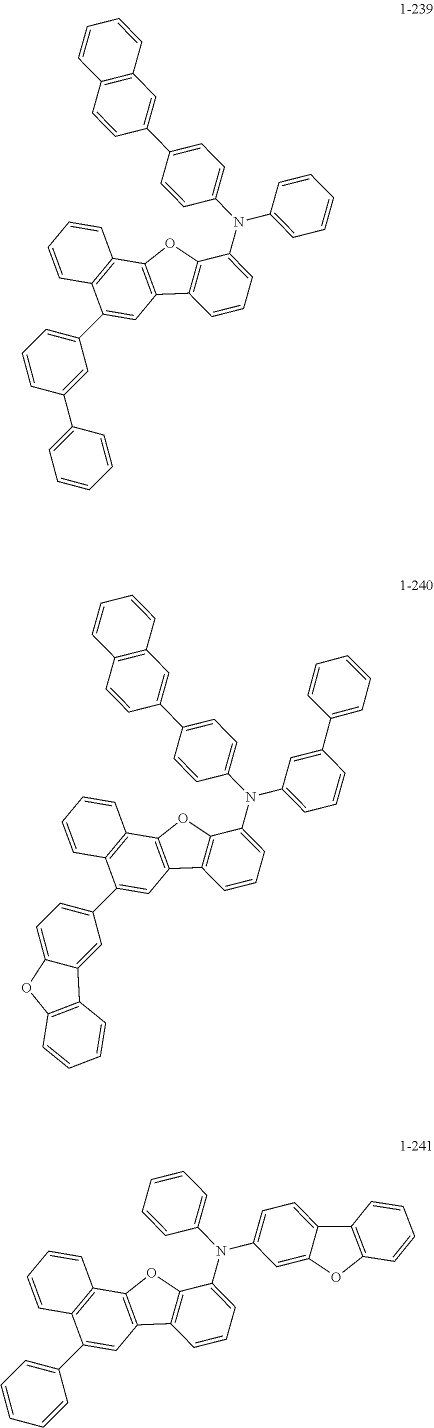 [SMILES: c1ccc(-c2cccc(-c3cc4c5cccc(N(c6ccccc6)c6ccc(-c7ccc8ccccc8c7)cc6)c5oc4c4ccccc34)c2)cc1 ; c1ccc(-c2cccc(N(c3ccc(-c4ccc5ccccc5c4)cc3)c3cccc4c3oc3c5ccccc5c(-c5ccc6oc7ccccc7c6c5)cc43)c2)cc1 ; c1ccc(-c2cc3c4cccc(N(c5ccccc5)c5ccc6c(c5)oc5ccccc56)c4oc3c3ccccc23)cc1] 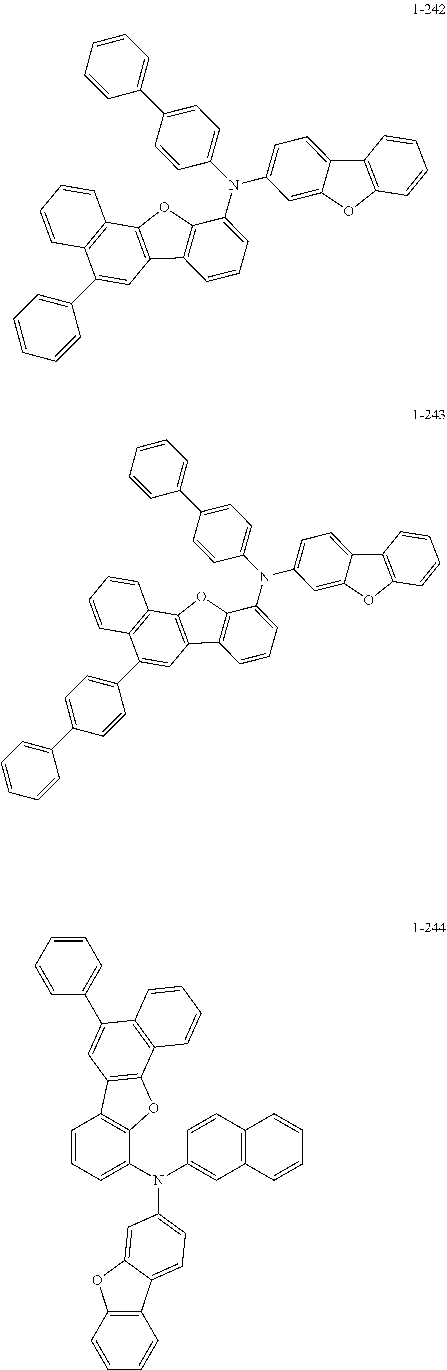 [SMILES: c1ccc(-c2ccc(N(c3ccc4c(c3)oc3ccccc34)c3cccc4c3oc3c5ccccc5c(-c5ccccc5)cc43)cc2)cc1 ; c1ccc(-c2ccc(-c3cc4c5cccc(N(c6ccc(-c7ccccc7)cc6)c6ccc7c(c6)oc6ccccc67)c5oc4c4ccccc34)cc2)cc1 ; c1ccc(-c2cc3c4cccc(N(c5ccc6ccccc6c5)c5ccc6c(c5)oc5ccccc56)c4oc3c3ccccc23)cc1] 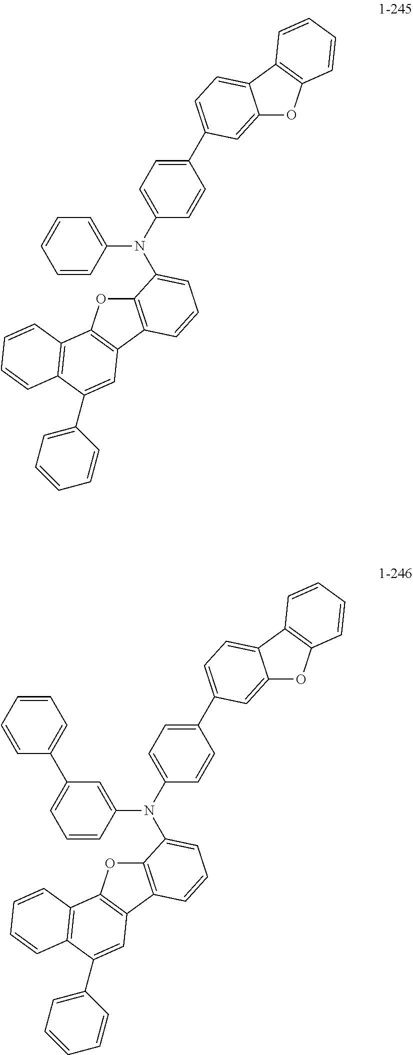 [SMILES: c1ccc(-c2cc3c4cccc(N(c5ccccc5)c5ccc(-c6ccc7c(c6)oc6ccccc67)cc5)c4oc3c3ccccc23)cc1 ; c1ccc(-c2cccc(N(c3ccc(-c4ccc5c(c4)oc4ccccc45)cc3)c3cccc4c3oc3c5ccccc5c(-c5ccccc5)cc43)c2)cc1] 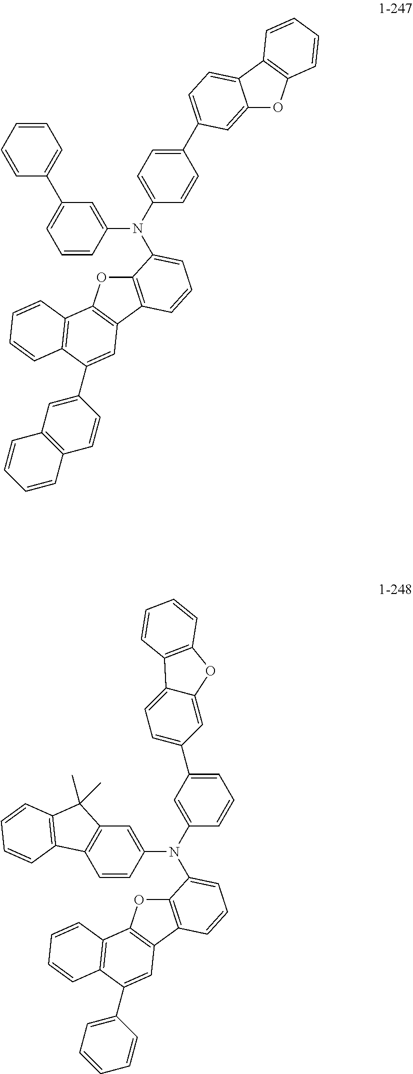 [SMILES: c1ccc(-c2cccc(N(c3ccc(-c4ccc5c(c4)oc4ccccc45)cc3)c3cccc4c3oc3c5ccccc5c(-c5ccc6ccccc6c5)cc43)c2)cc1 ; CC1(C)c2ccccc2-c2ccc(N(c3cccc(-c4ccc5c(c4)oc4ccccc45)c3)c3cccc4c3oc3c5ccccc5c(-c5ccccc5)cc43)cc21] 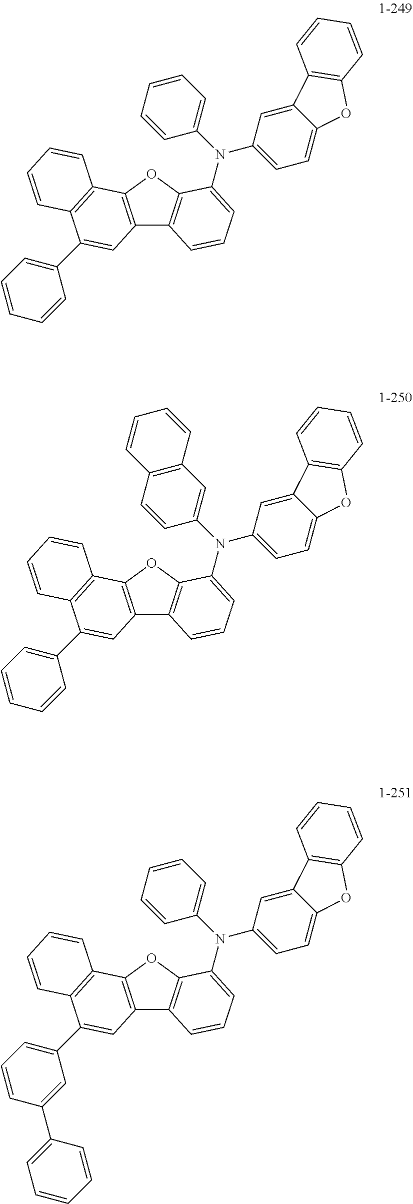 [SMILES: c1ccc(-c2cc3c4cccc(N(c5ccccc5)c5ccc6oc7ccccc7c6c5)c4oc3c3ccccc23)cc1 ; c1ccc(-c2cc3c4cccc(N(c5ccc6ccccc6c5)c5ccc6oc7ccccc7c6c5)c4oc3c3ccccc23)cc1 ; c1ccc(-c2cccc(-c3cc4c5cccc(N(c6ccccc6)c6ccc7oc8ccccc8c7c6)c5oc4c4ccccc34)c2)cc1] 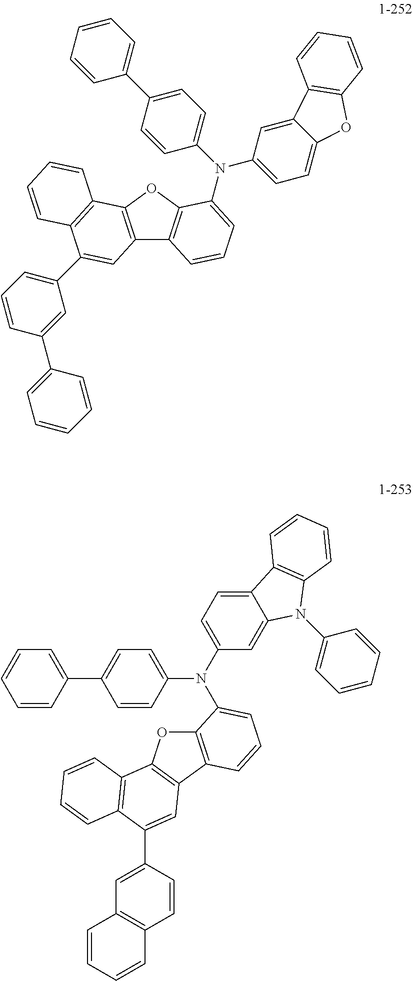 [SMILES: c1ccc(-c2ccc(N(c3ccc4oc5ccccc5c4c3)c3cccc4c3oc3c5ccccc5c(-c5cccc(-c6ccccc6)c5)cc43)cc2)cc1 ; c1ccc(-c2ccc(N(c3ccc4c5ccccc5n(-c5ccccc5)c4c3)c3cccc4c3oc3c5ccccc5c(-c5ccc6ccccc6c5)cc43)cc2)cc1] 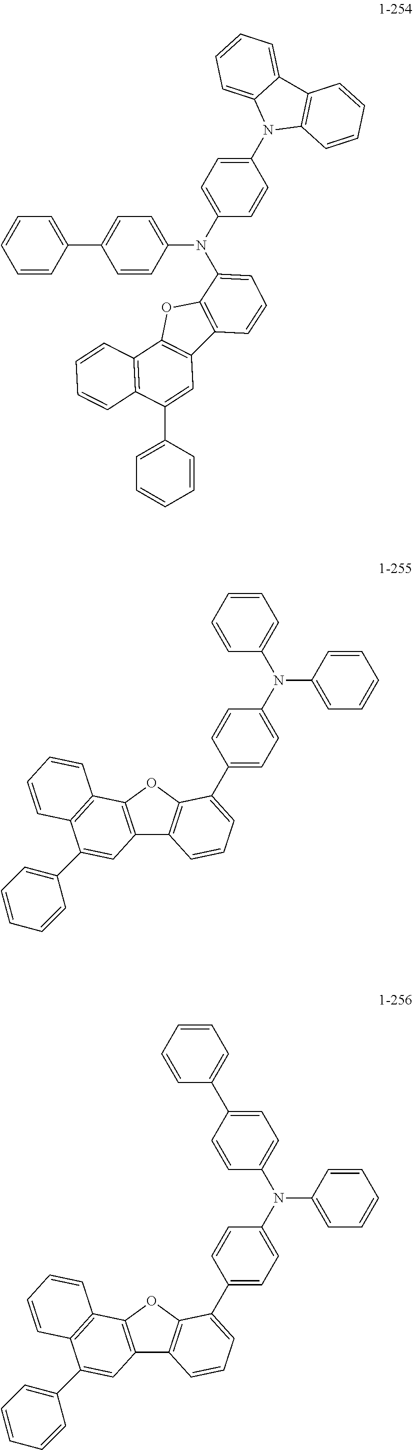 [SMILES: c1ccc(-c2ccc(N(c3ccc(-n4c5ccccc5c5ccccc54)cc3)c3cccc4c3oc3c5ccccc5c(-c5ccccc5)cc43)cc2)cc1 ; c1ccc(-c2cc3c4cccc(-c5ccc(N(c6ccccc6)c6ccccc6)cc5)c4oc3c3ccccc23)cc1 ; c1ccc(-c2ccc(N(c3ccccc3)c3ccc(-c4cccc5c4oc4c6ccccc6c(-c6ccccc6)cc54)cc3)cc2)cc1] 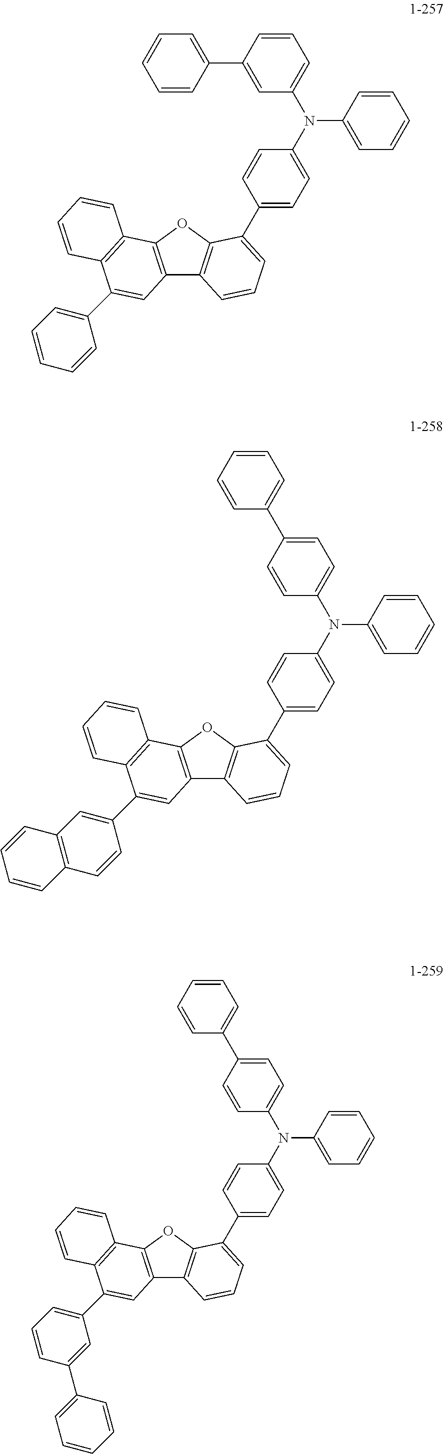 [SMILES: c1ccc(-c2cccc(N(c3ccccc3)c3ccc(-c4cccc5c4oc4c6ccccc6c(-c6ccccc6)cc54)cc3)c2)cc1 ; c1ccc(-c2ccc(N(c3ccccc3)c3ccc(-c4cccc5c4oc4c6ccccc6c(-c6ccc7ccccc7c6)cc54)cc3)cc2)cc1 ; c1ccc(-c2ccc(N(c3ccccc3)c3ccc(-c4cccc5c4oc4c6ccccc6c(-c6cccc(-c7ccccc7)c6)cc54)cc3)cc2)cc1] 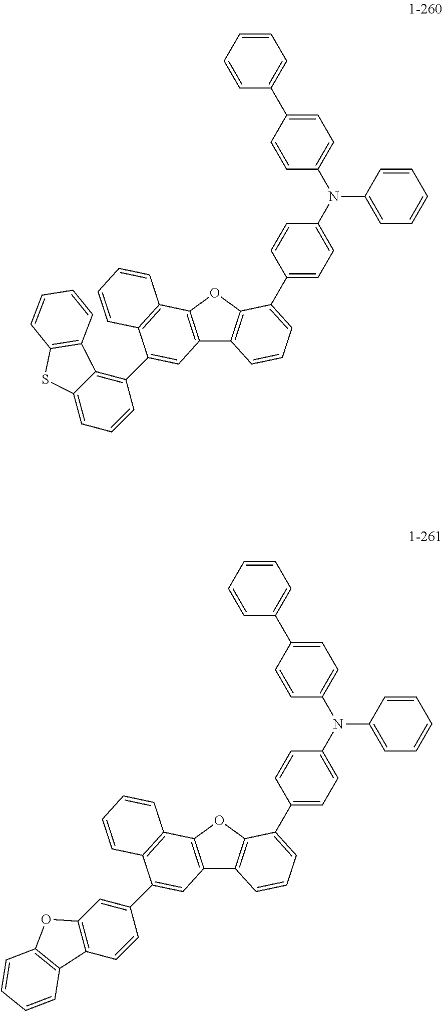 [SMILES: c1ccc(-c2ccc(N(c3ccccc3)c3ccc(-c4cccc5c4oc4c6ccccc6c(-c6cccc7sc8ccccc8c67)cc54)cc3)cc2)cc1 ; c1ccc(-c2ccc(N(c3ccccc3)c3ccc(-c4cccc5c4oc4c6ccccc6c(-c6ccc7c(c6)oc6ccccc67)cc54)cc3)cc2)cc1] 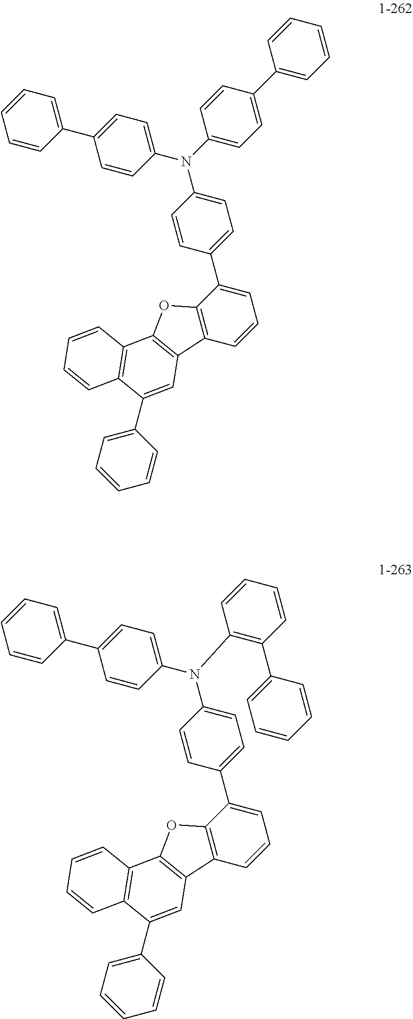 [SMILES: c1ccc(-c2ccc(N(c3ccc(-c4ccccc4)cc3)c3ccc(-c4cccc5c4oc4c6ccccc6c(-c6ccccc6)cc54)cc3)cc2)cc1 ; c1ccc(-c2ccc(N(c3ccc(-c4cccc5c4oc4c6ccccc6c(-c6ccccc6)cc54)cc3)c3ccccc3-c3ccccc3)cc2)cc1] 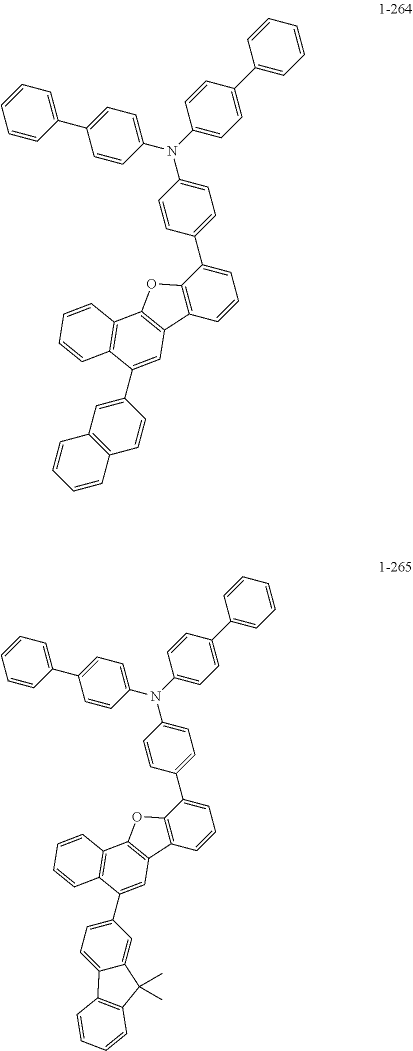 [SMILES: c1ccc(-c2ccc(N(c3ccc(-c4ccccc4)cc3)c3ccc(-c4cccc5c4oc4c6ccccc6c(-c6ccc7ccccc7c6)cc54)cc3)cc2)cc1 ; CC1(C)c2ccccc2-c2ccc(-c3cc4c5cccc(-c6ccc(N(c7ccc(-c8ccccc8)cc7)c7ccc(-c8ccccc8)cc7)cc6)c5oc4c4ccccc34)cc21] 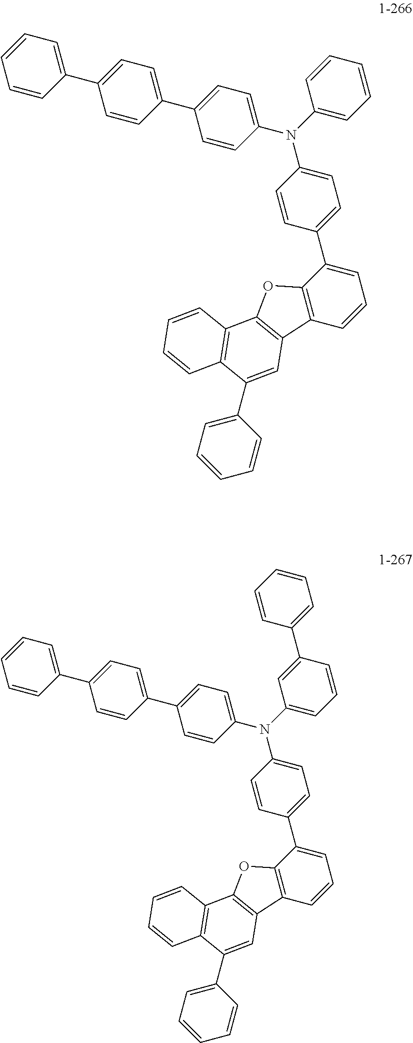 [SMILES: c1ccc(-c2ccc(-c3ccc(N(c4ccccc4)c4ccc(-c5cccc6c5oc5c7ccccc7c(-c7ccccc7)cc65)cc4)cc3)cc2)cc1 ; c1ccc(-c2ccc(-c3ccc(N(c4ccc(-c5cccc6c5oc5c7ccccc7c(-c7ccccc7)cc65)cc4)c4cccc(-c5ccccc5)c4)cc3)cc2)cc1] 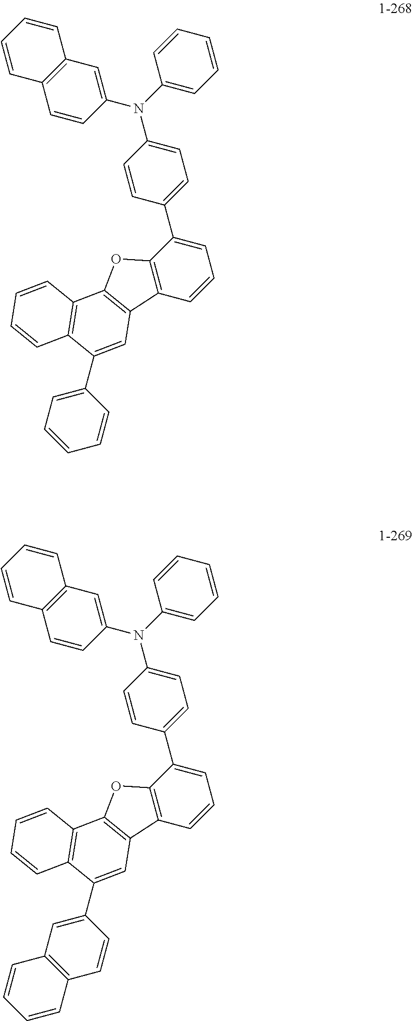 [SMILES: c1ccc(-c2cc3c4cccc(-c5ccc(N(c6ccccc6)c6ccc7ccccc7c6)cc5)c4oc3c3ccccc23)cc1 ; c1ccc(N(c2ccc(-c3cccc4c3oc3c5ccccc5c(-c5ccc6ccccc6c5)cc43)cc2)c2ccc3ccccc3c2)cc1] 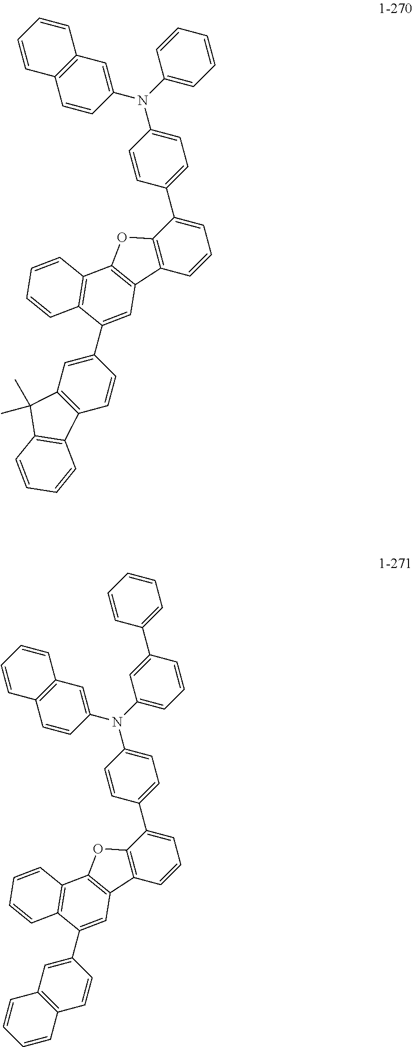 [SMILES: CC1(C)c2ccccc2-c2ccc(-c3cc4c5cccc(-c6ccc(N(c7ccccc7)c7ccc8ccccc8c7)cc6)c5oc4c4ccccc34)cc21 ; c1ccc(-c2cccc(N(c3ccc(-c4cccc5c4oc4c6ccccc6c(-c6ccc7ccccc7c6)cc54)cc3)c3ccc4ccccc4c3)c2)cc1] 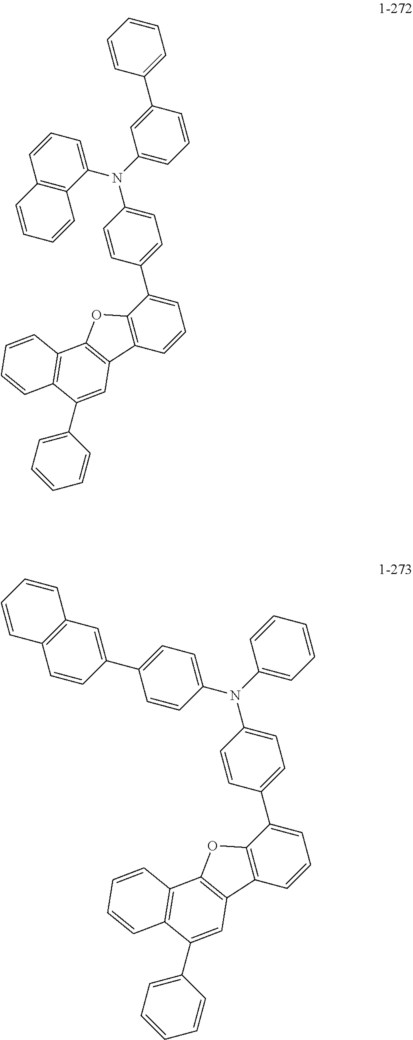 [SMILES: c1ccc(-c2cccc(N(c3ccc(-c4cccc5c4oc4c6ccccc6c(-c6ccccc6)cc54)cc3)c3cccc4ccccc34)c2)cc1 ; c1ccc(-c2cc3c4cccc(-c5ccc(N(c6ccccc6)c6ccc(-c7ccc8ccccc8c7)cc6)cc5)c4oc3c3ccccc23)cc1] 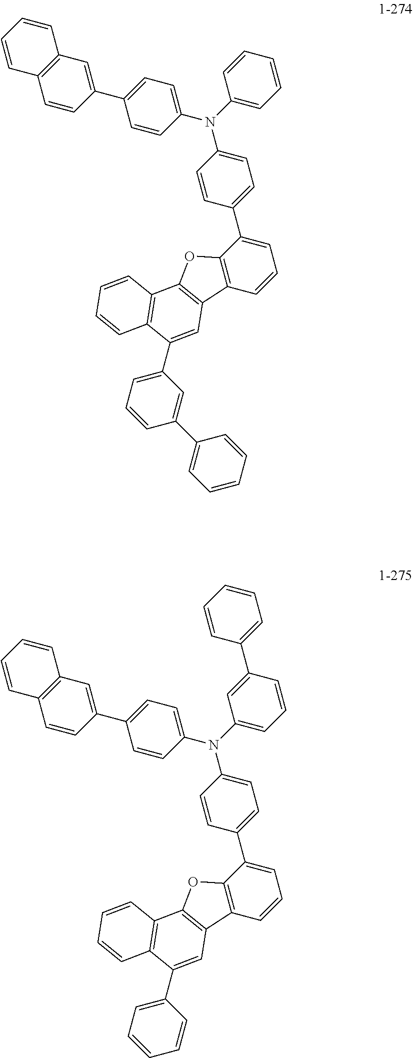 [SMILES: c1ccc(-c2cccc(-c3cc4c5cccc(-c6ccc(N(c7ccccc7)c7ccc(-c8ccc9ccccc9c8)cc7)cc6)c5oc4c4ccccc34)c2)cc1 ; c1ccc(-c2cccc(N(c3ccc(-c4ccc5ccccc5c4)cc3)c3ccc(-c4cccc5c4oc4c6ccccc6c(-c6ccccc6)cc54)cc3)c2)cc1] 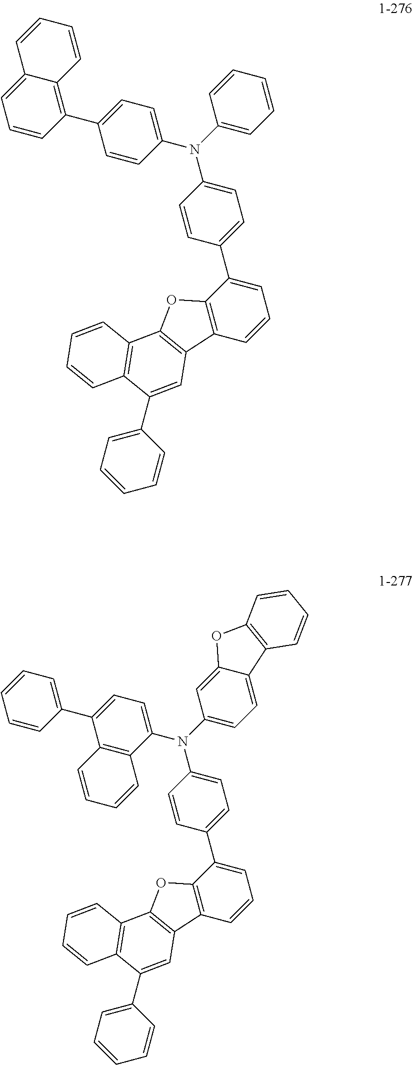 [SMILES: c1ccc(-c2cc3c4cccc(-c5ccc(N(c6ccccc6)c6ccc(-c7cccc8ccccc78)cc6)cc5)c4oc3c3ccccc23)cc1 ; c1ccc(-c2ccc(N(c3ccc(-c4cccc5c4oc4c6ccccc6c(-c6ccccc6)cc54)cc3)c3ccc4c(c3)oc3ccccc34)c3ccccc23)cc1] 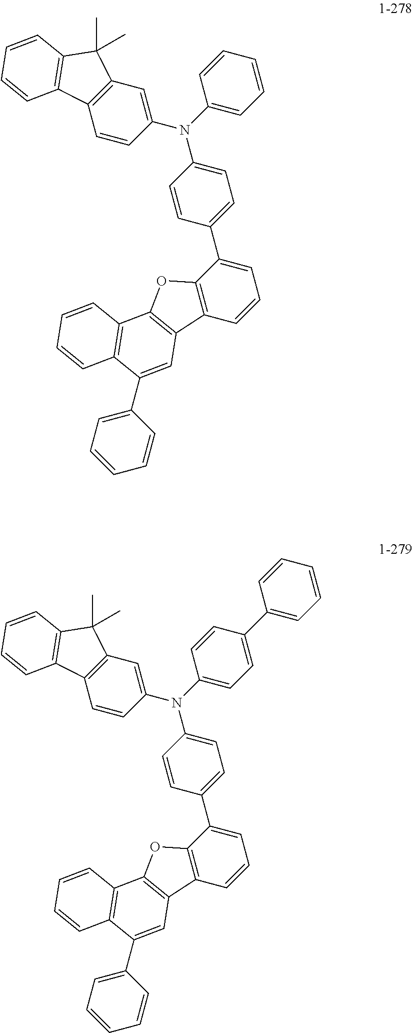 [SMILES: CC1(C)c2ccccc2-c2ccc(N(c3ccccc3)c3ccc(-c4cccc5c4oc4c6ccccc6c(-c6ccccc6)cc54)cc3)cc21 ; CC1(C)c2ccccc2-c2ccc(N(c3ccc(-c4ccccc4)cc3)c3ccc(-c4cccc5c4oc4c6ccccc6c(-c6ccccc6)cc54)cc3)cc21] 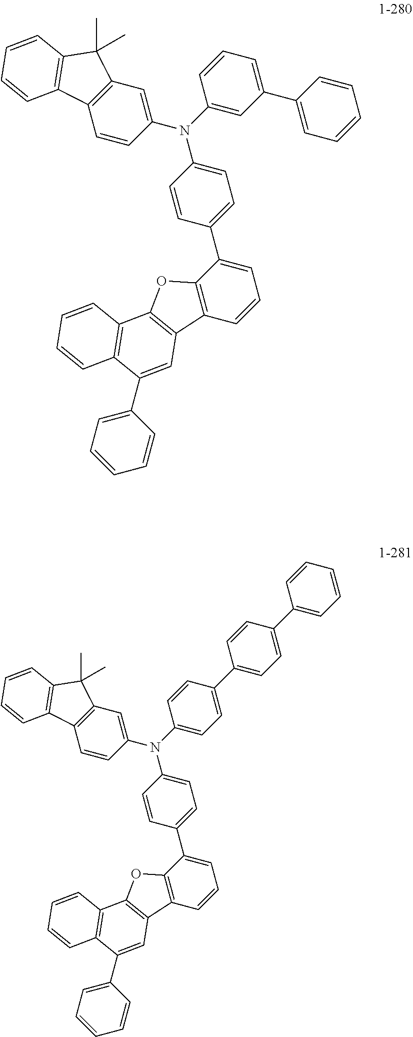 [SMILES: CC1(C)c2ccccc2-c2ccc(N(c3ccc(-c4cccc5c4oc4c6ccccc6c(-c6ccccc6)cc54)cc3)c3cccc(-c4ccccc4)c3)cc21 ; CC1(C)c2ccccc2-c2ccc(N(c3ccc(-c4ccc(-c5ccccc5)cc4)cc3)c3ccc(-c4cccc5c4oc4c6ccccc6c(-c6ccccc6)cc54)cc3)cc21] 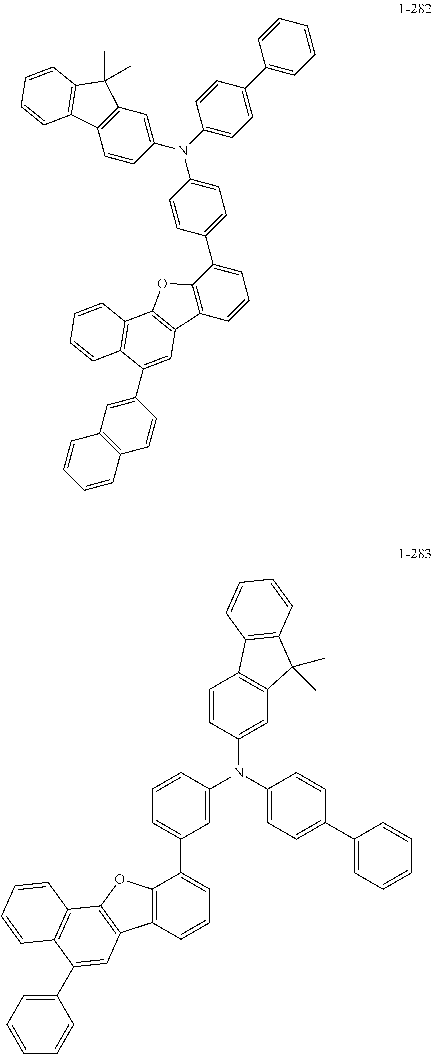 [SMILES: CC1(C)c2ccccc2-c2ccc(N(c3ccc(-c4ccccc4)cc3)c3ccc(-c4cccc5c4oc4c6ccccc6c(-c6ccc7ccccc7c6)cc54)cc3)cc21 ; CC1(C)c2ccccc2-c2ccc(N(c3ccc(-c4ccccc4)cc3)c3cccc(-c4cccc5c4oc4c6ccccc6c(-c6ccccc6)cc54)c3)cc21] 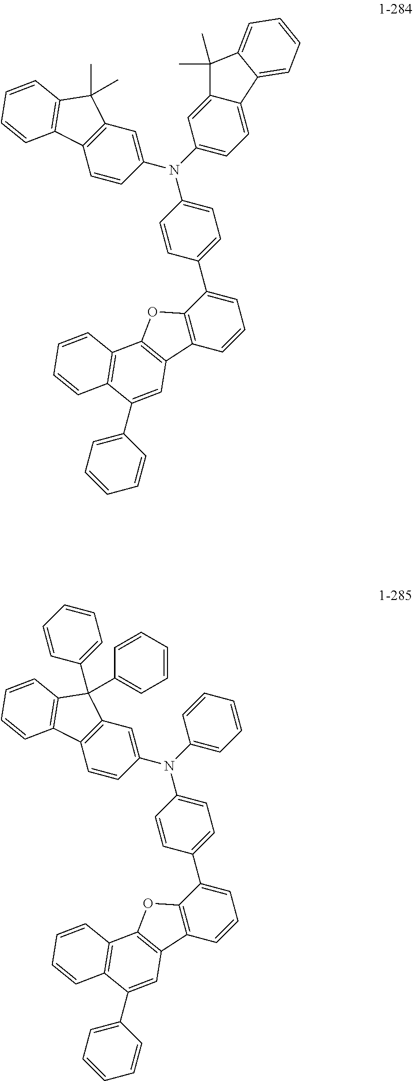 [SMILES: CC1(C)c2ccccc2-c2ccc(N(c3ccc(-c4cccc5c4oc4c6ccccc6c(-c6ccccc6)cc54)cc3)c3ccc4c(c3)C(C)(C)c3ccccc3-4)cc21 ; c1ccc(-c2cc3c4cccc(-c5ccc(N(c6ccccc6)c6ccc7c(c6)C(c6ccccc6)(c6ccccc6)c6ccccc6-7)cc5)c4oc3c3ccccc23)cc1] 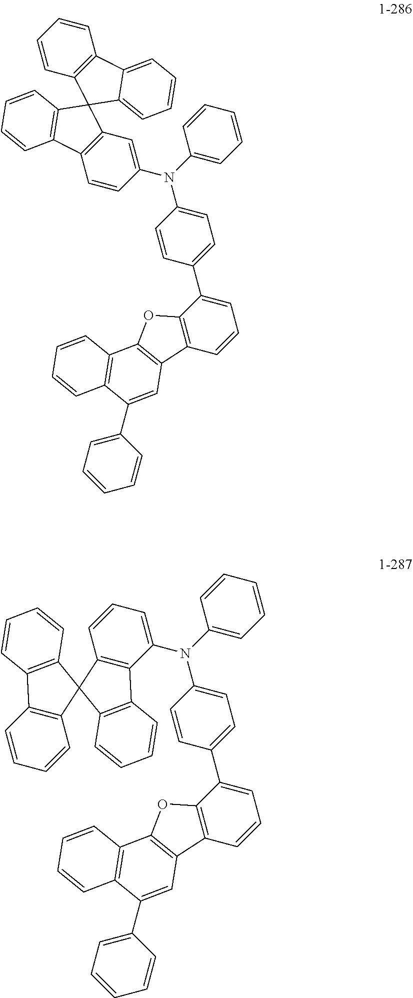 [SMILES: c1ccc(-c2cc3c4cccc(-c5ccc(N(c6ccccc6)c6ccc7c(c6)C6(c8ccccc8-c8ccccc86)c6ccccc6-7)cc5)c4oc3c3ccccc23)cc1 ; c1ccc(-c2cc3c4cccc(-c5ccc(N(c6ccccc6)c6cccc7c6-c6ccccc6C76c7ccccc7-c7ccccc76)cc5)c4oc3c3ccccc23)cc1] 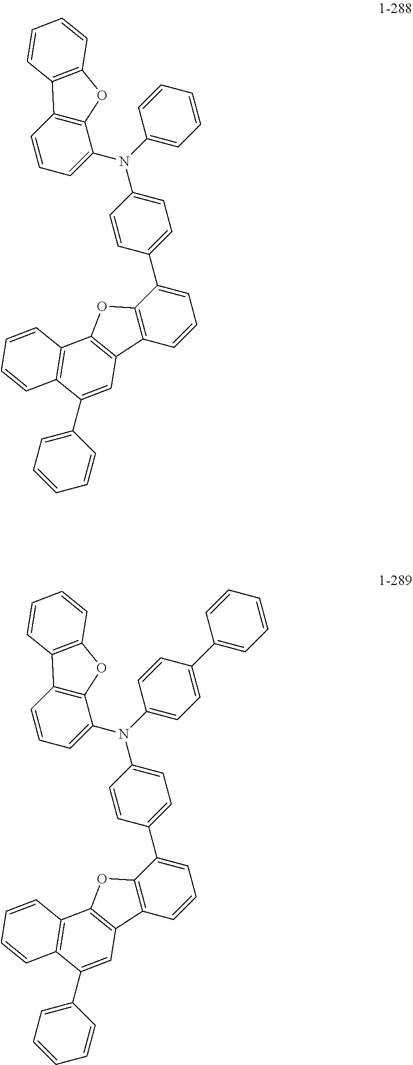 [SMILES: c1ccc(-c2cc3c4cccc(-c5ccc(N(c6ccccc6)c6cccc7c6oc6ccccc67)cc5)c4oc3c3ccccc23)cc1 ; c1ccc(-c2ccc(N(c3ccc(-c4cccc5c4oc4c6ccccc6c(-c6ccccc6)cc54)cc3)c3cccc4c3oc3ccccc34)cc2)cc1] 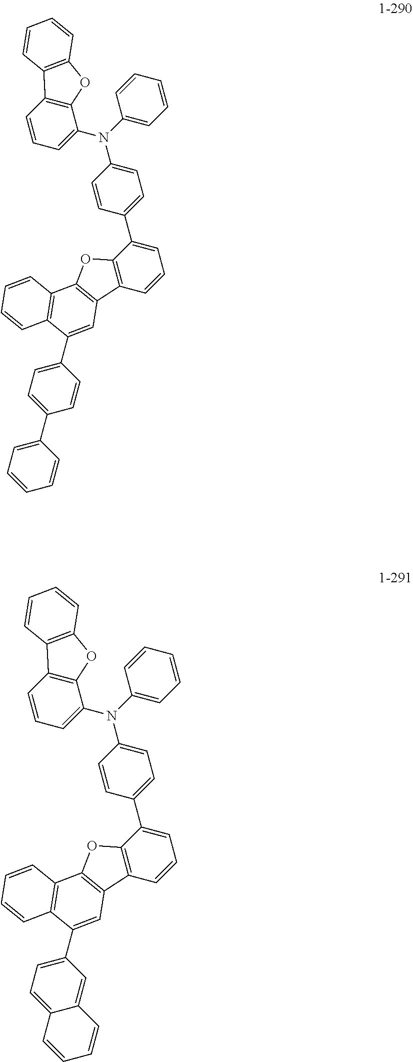 [SMILES: c1ccc(-c2ccc(-c3cc4c5cccc(-c6ccc(N(c7ccccc7)c7cccc8c7oc7ccccc78)cc6)c5oc4c4ccccc34)cc2)cc1 ; c1ccc(N(c2ccc(-c3cccc4c3oc3c5ccccc5c(-c5ccc6ccccc6c5)cc43)cc2)c2cccc3c2oc2ccccc23)cc1] 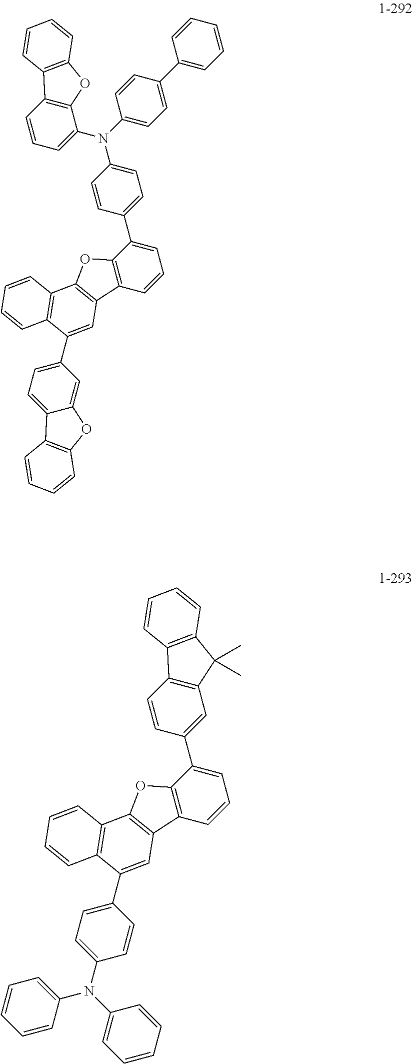 [SMILES: c1ccc(-c2ccc(N(c3ccc(-c4cccc5c4oc4c6ccccc6c(-c6ccc7c(c6)oc6ccccc67)cc54)cc3)c3cccc4c3oc3ccccc34)cc2)cc1 ; CC1(C)c2ccccc2-c2ccc(-c3cccc4c3oc3c5ccccc5c(-c5ccc(N(c6ccccc6)c6ccccc6)cc5)cc43)cc21] 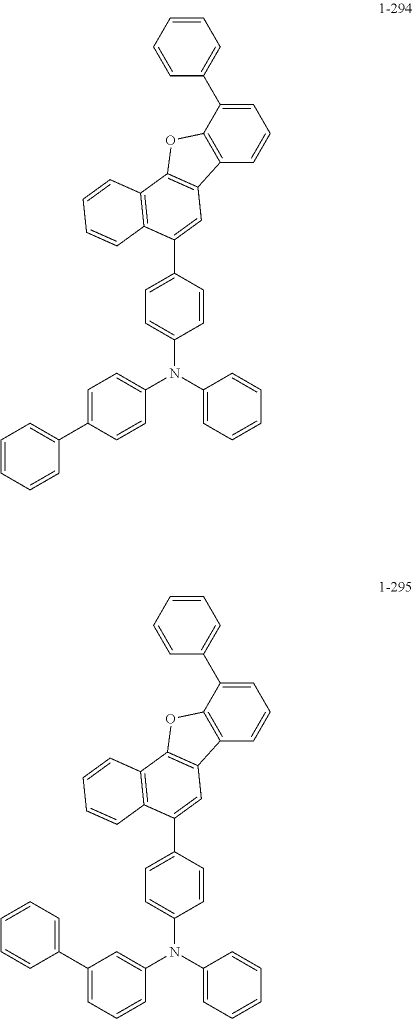 [SMILES: c1ccc(-c2ccc(N(c3ccccc3)c3ccc(-c4cc5c6cccc(-c7ccccc7)c6oc5c5ccccc45)cc3)cc2)cc1 ; c1ccc(-c2cccc(N(c3ccccc3)c3ccc(-c4cc5c6cccc(-c7ccccc7)c6oc5c5ccccc45)cc3)c2)cc1] 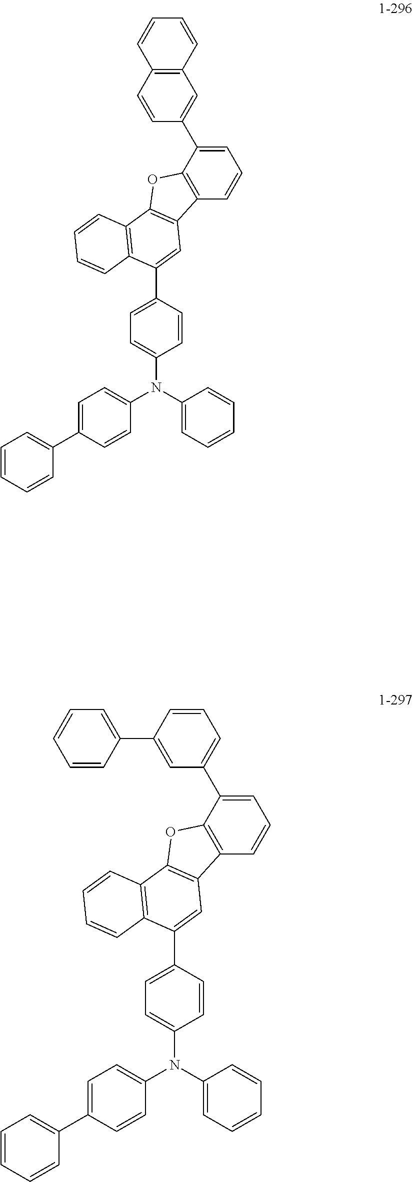 [SMILES: c1ccc(-c2ccc(N(c3ccccc3)c3ccc(-c4cc5c6cccc(-c7ccc8ccccc8c7)c6oc5c5ccccc45)cc3)cc2)cc1 ; c1ccc(-c2ccc(N(c3ccccc3)c3ccc(-c4cc5c6cccc(-c7cccc(-c8ccccc8)c7)c6oc5c5ccccc45)cc3)cc2)cc1] 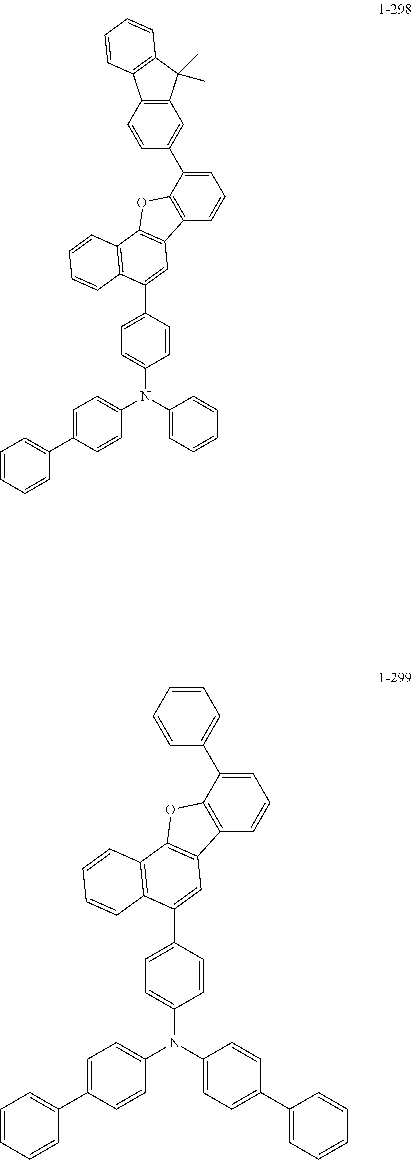 [SMILES: CC1(C)c2ccccc2-c2ccc(-c3cccc4c3oc3c5ccccc5c(-c5ccc(N(c6ccccc6)c6ccc(-c7ccccc7)cc6)cc5)cc43)cc21 ; c1ccc(-c2ccc(N(c3ccc(-c4ccccc4)cc3)c3ccc(-c4cc5c6cccc(-c7ccccc7)c6oc5c5ccccc45)cc3)cc2)cc1] 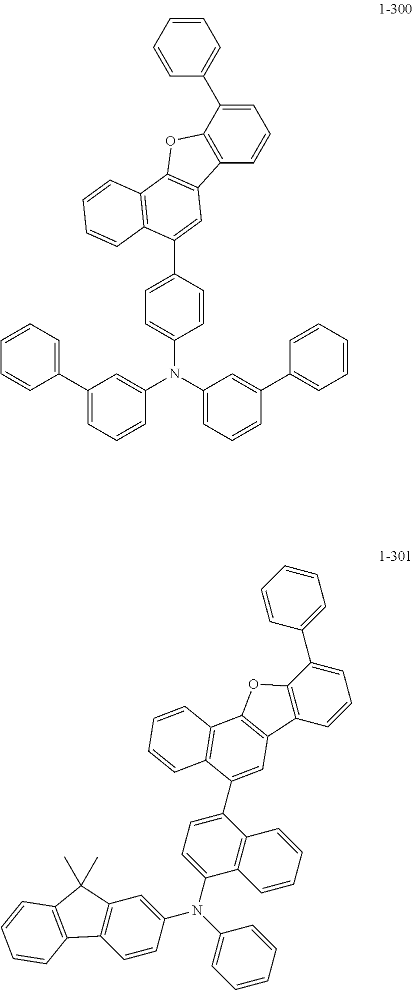 [SMILES: c1ccc(-c2cccc(N(c3ccc(-c4cc5c6cccc(-c7ccccc7)c6oc5c5ccccc45)cc3)c3cccc(-c4ccccc4)c3)c2)cc1 ; CC1(C)c2ccccc2-c2ccc(N(c3ccccc3)c3ccc(-c4cc5c6cccc(-c7ccccc7)c6oc5c5ccccc45)c4ccccc34)cc21] 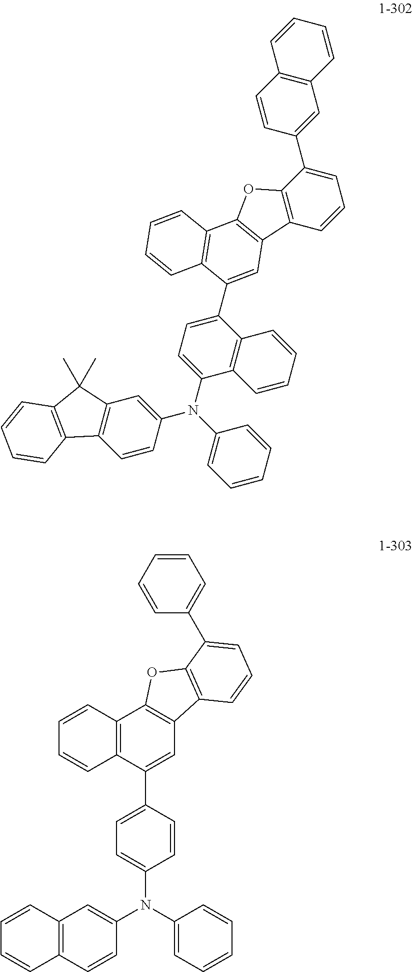 [SMILES: CC1(C)c2ccccc2-c2ccc(N(c3ccccc3)c3ccc(-c4cc5c6cccc(-c7ccc8ccccc8c7)c6oc5c5ccccc45)c4ccccc34)cc21 ; c1ccc(-c2cccc3c2oc2c4ccccc4c(-c4ccc(N(c5ccccc5)c5ccc6ccccc6c5)cc4)cc32)cc1] 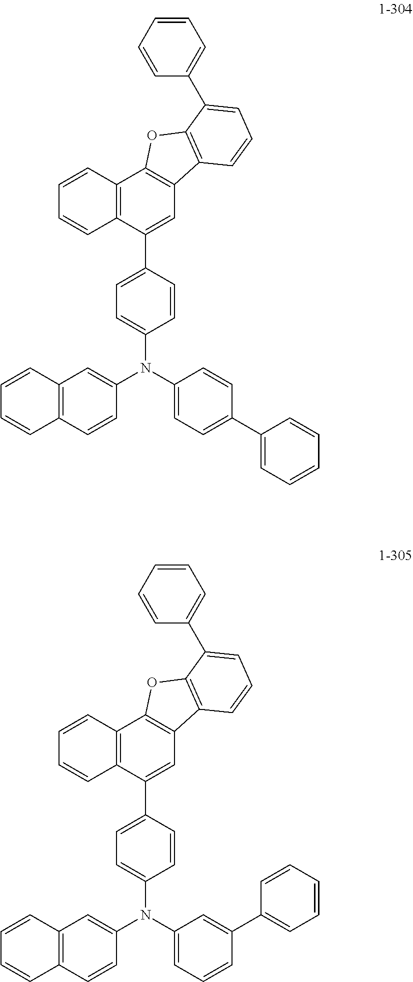 [SMILES: c1ccc(-c2ccc(N(c3ccc(-c4cc5c6cccc(-c7ccccc7)c6oc5c5ccccc45)cc3)c3ccc4ccccc4c3)cc2)cc1 ; c1ccc(-c2cccc(N(c3ccc(-c4cc5c6cccc(-c7ccccc7)c6oc5c5ccccc45)cc3)c3ccc4ccccc4c3)c2)cc1] 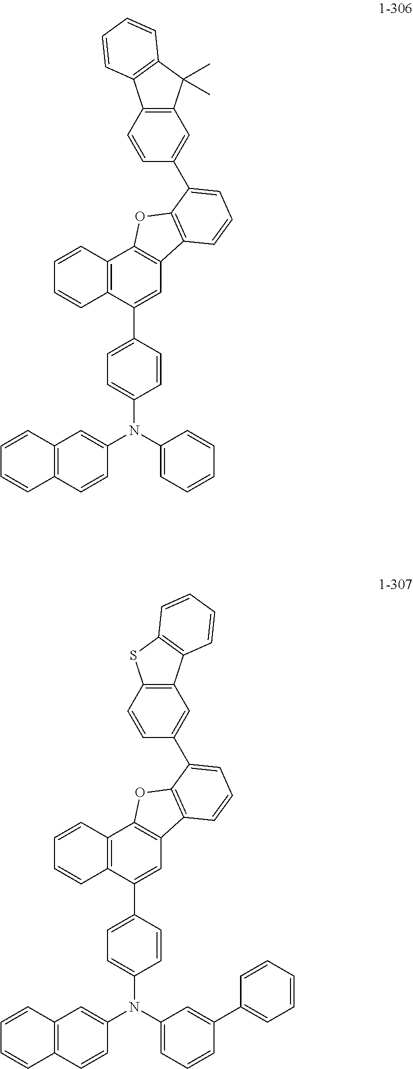 [SMILES: CC1(C)c2ccccc2-c2ccc(-c3cccc4c3oc3c5ccccc5c(-c5ccc(N(c6ccccc6)c6ccc7ccccc7c6)cc5)cc43)cc21 ; c1ccc(-c2cccc(N(c3ccc(-c4cc5c6cccc(-c7ccc8sc9ccccc9c8c7)c6oc5c5ccccc45)cc3)c3ccc4ccccc4c3)c2)cc1] 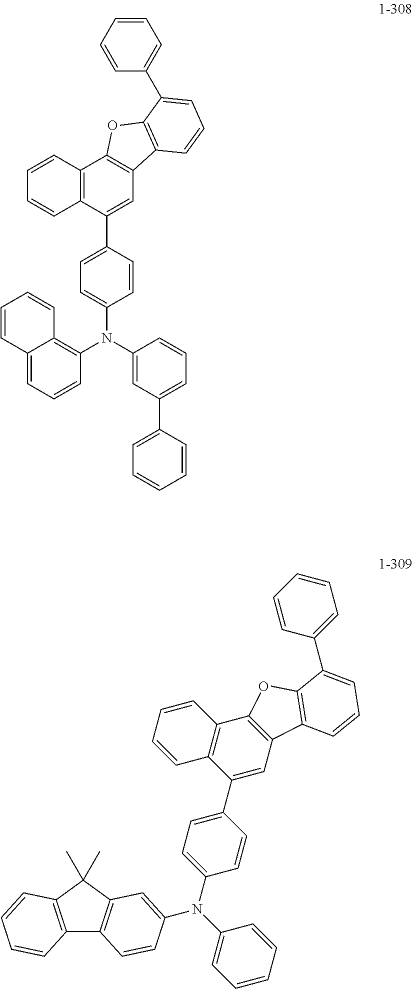 [SMILES: c1ccc(-c2cccc(N(c3ccc(-c4cc5c6cccc(-c7ccccc7)c6oc5c5ccccc45)cc3)c3cccc4ccccc34)c2)cc1 ; CC1(C)c2ccccc2-c2ccc(N(c3ccccc3)c3ccc(-c4cc5c6cccc(-c7ccccc7)c6oc5c5ccccc45)cc3)cc21] 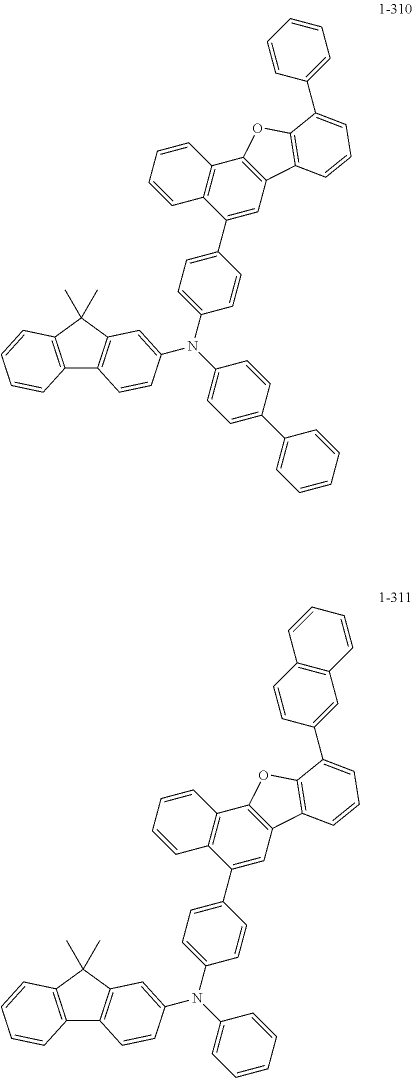 [SMILES: CC1(C)c2ccccc2-c2ccc(N(c3ccc(-c4ccccc4)cc3)c3ccc(-c4cc5c6cccc(-c7ccccc7)c6oc5c5ccccc45)cc3)cc21 ; CC1(C)c2ccccc2-c2ccc(N(c3ccccc3)c3ccc(-c4cc5c6cccc(-c7ccc8ccccc8c7)c6oc5c5ccccc45)cc3)cc21] 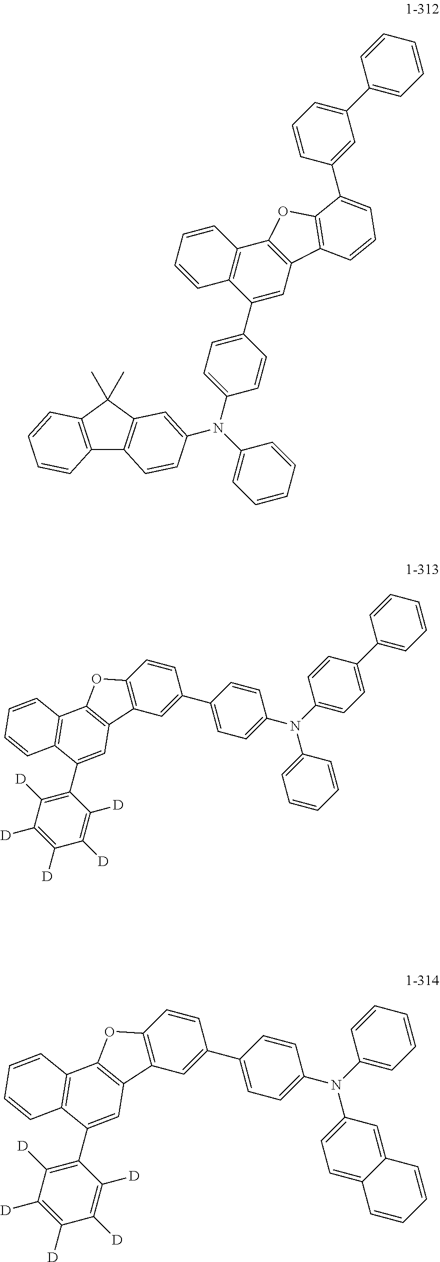 [SMILES: CC1(C)c2ccccc2-c2ccc(N(c3ccccc3)c3ccc(-c4cc5c6cccc(-c7cccc(-c8ccccc8)c7)c6oc5c5ccccc45)cc3)cc21 ; [2H]c1c([2H])c([2H])c(-c2cc3c4cc(-c5ccc(N(c6ccccc6)c6ccc(-c7ccccc7)cc6)cc5)ccc4oc3c3ccccc23)c([2H])c1[2H] ; [2H]c1c([2H])c([2H])c(-c2cc3c4cc(-c5ccc(N(c6ccccc6)c6ccc7ccccc7c6)cc5)ccc4oc3c3ccccc23)c([2H])c1[2H]] 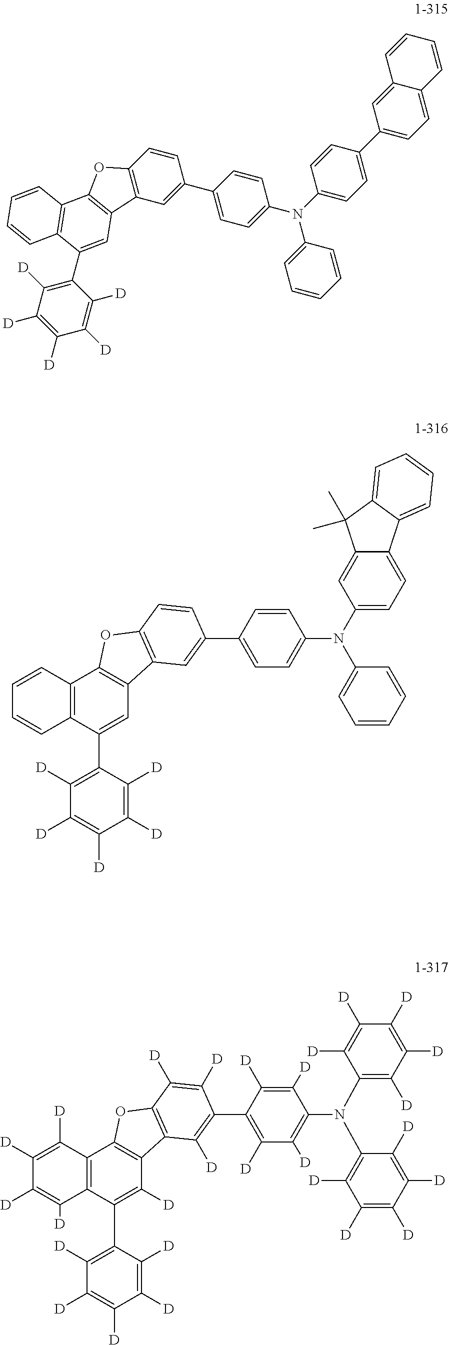 [SMILES: [2H]c1c([2H])c([2H])c(-c2cc3c4cc(-c5ccc(N(c6ccccc6)c6ccc(-c7ccc8ccccc8c7)cc6)cc5)ccc4oc3c3ccccc23)c([2H])c1[2H] ; [2H]c1c([2H])c([2H])c(-c2cc3c4cc(-c5ccc(N(c6ccccc6)c6ccc7c(c6)C(C)(C)c6ccccc6-7)cc5)ccc4oc3c3ccccc23)c([2H])c1[2H] ; [2H]c1c([2H])c([2H])c(-c2c([2H])c3c(oc4c([2H])c([2H])c(-c5c([2H])c([2H])c(N(c6c([2H])c([2H])c([2H])c([2H])c6[2H])c6c([2H])c([2H])c([2H])c([2H])c6[2H])c([2H])c5[2H])c([2H])c43)c3c([2H])c([2H])c([2H])c([2H])c23)c([2H])c1[2H]] 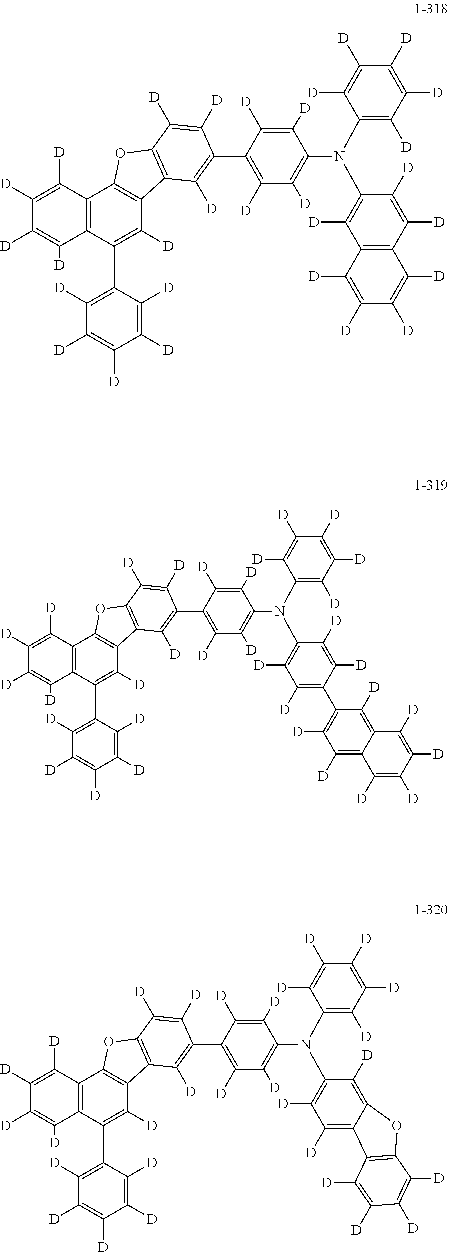 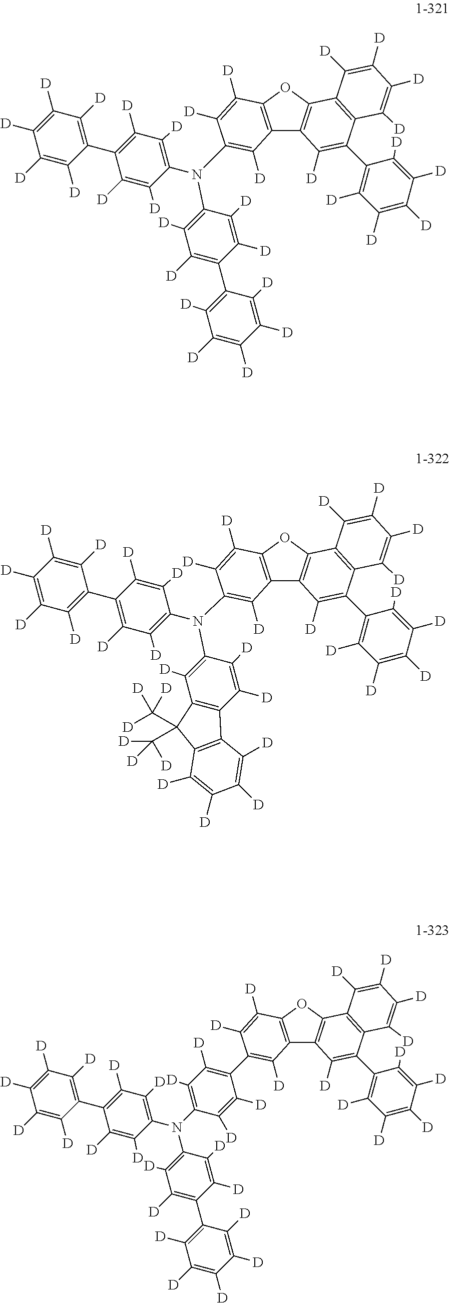 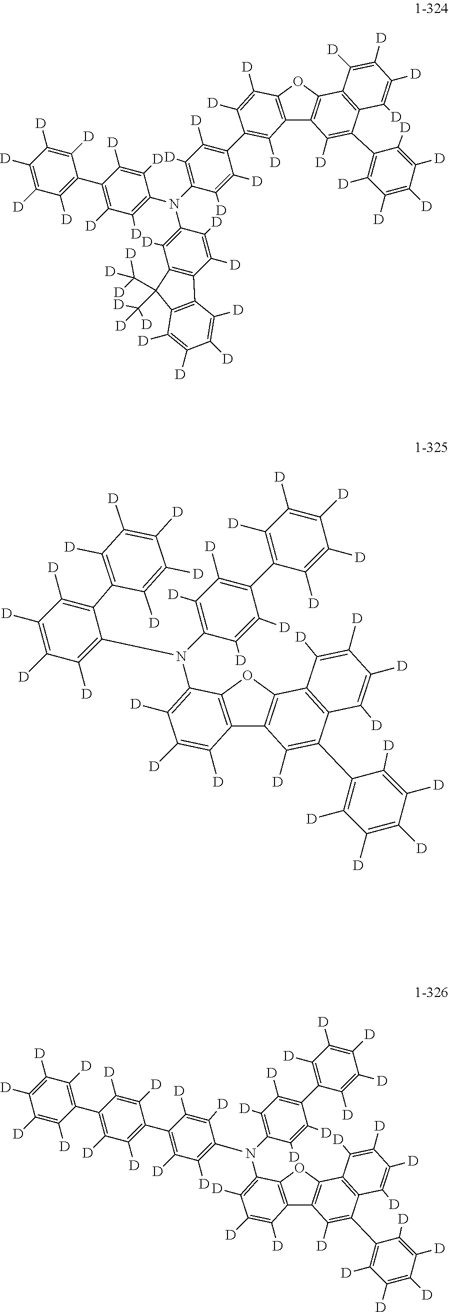 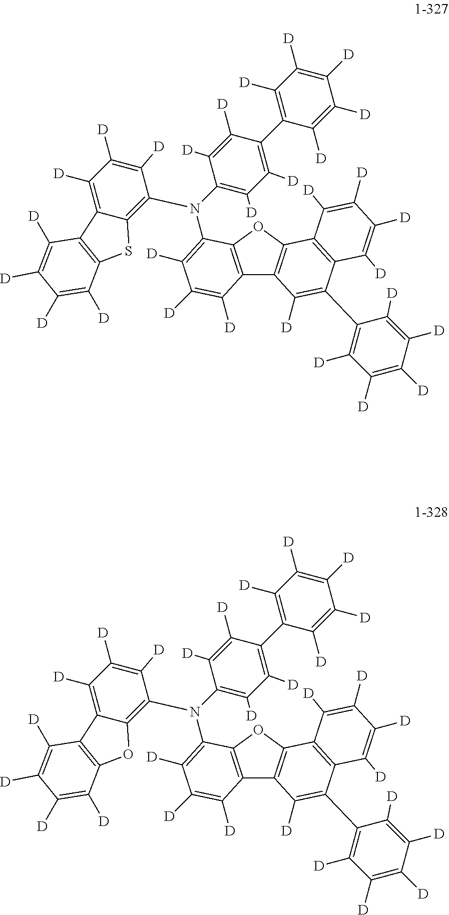 [SMILES: [2H]c1c([2H])c([2H])c(-c2c([2H])c([2H])c(N(c3c([2H])c([2H])c([2H])c4c3oc3c5c([2H])c([2H])c([2H])c([2H])c5c(-c5c([2H])c([2H])c([2H])c([2H])c5[2H])c([2H])c34)c3c([2H])c([2H])c([2H])c4c3sc3c([2H])c([2H])c([2H])c([2H])c34)c([2H])c2[2H])c([2H])c1[2H] ; [2H]c1c([2H])c([2H])c(-c2c([2H])c([2H])c(N(c3c([2H])c([2H])c([2H])c4c3oc3c([2H])c([2H])c([2H])c([2H])c34)c3c([2H])c([2H])c([2H])c4c3oc3c5c([2H])c([2H])c([2H])c([2H])c5c(-c5c([2H])c([2H])c([2H])c([2H])c5[2H])c([2H])c34)c([2H])c2[2H])c([2H])c1[2H]]
